(19) United States
(12) Patent Application Publication
(10) Pub. No.: US 2026/0165028 A1
(43) Pub. Date: Jun. 11, 2026

(54) LIGHT-EMITTING ELEMENT, FUSED POLYCYCLIC COMPOUND, AND ELECTRONIC APPARATUS

(71) Applicant: Samsung Display Co., Ltd., Yongin-si (KR)

(72) Inventors: Hirokazu KUWABARA, Yokohama-shi (JP); Keigo HOSHI, Yokohama-shi (JP); Yoshiro SUGITA, Yokohama-shi (JP)

(21) Appl. No.: 19/413,594

(22) Filed: Dec. 9, 2025

(30) Foreign Application Priority Data
Dec. 11, 2024 (JP) 2024-216326

(51) Int. Cl. H10K 85/60; C07F 5/02; C09K 11/02; C09K 11/06; H10K 50/12

(52) U.S. Cl. CPC H10K 85/658; C07F 5/027; C09K 11/02; C09K 11/06; H10K 85/6572; C09K 2211/1007; C09K 2211/1018; H10K 50/121

(57) ABSTRACT

A light-emitting element includes a first electrode, a second electrode on the first electrode, and an emission layer between the first electrode and the second electrode and including a first compound represented by Formula 1:

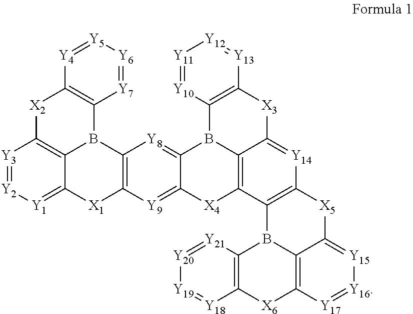

### CROSS-REFERENCE TO RELATED APPLICATION

The present application claims priority to and the benefit of Japanese Patent Application No. JP 2024-216326, filed on Dec. 11, 2024, in the Japan Patent Office, the entire content of which is incorporated herein by reference.

### BACKGROUND

### 1. Field

One or more embodiments of the present disclosure relate to a light-emitting element, a fused polycyclic compound, and an electronic apparatus, for example, to a light-emitting element, a fused polycyclic compound used in the light-emitting element, and an electronic apparatus including the light-emitting element.

### 2. Description of the Related Art

An electronic apparatus may include an image display device. Recently, among image display devices, organic electroluminescence display devices have been widely adopted and are under active development. These organic electroluminescence display devices, which are different from liquid crystal display devices, are self-luminous display devices that realize display of images by recombining holes and electrons respectively injected from a first and second electrodes in an emission layer to make a light-emitting material containing an organic compound emit light in the emission layer.

In the application of organic electroluminescent elements to display devices, low driving voltage, high luminous efficiency, and long lifespan are desired or required for the organic electroluminescent elements, and thus there is a continuous demand or desire for development of a material for the organic electroluminescent element that is capable of stably providing such properties, such as low driving voltage, high luminous efficiency, and long lifespan.

For example, to implement highly efficient organic electroluminescent elements, technology for phosphorescence emission using the energy of triplet state, or technology for fluorescence emission using a phenomenon of triplet-triplet annihilation (TTA), in which singlet excitons are generated by the collision of triplet excitons, have been recently developed or researched, and development or research of materials for thermally activated delayed fluorescence (TADF) using a phenomenon of delayed fluorescence is in progress.

### SUMMARY

One or more aspects of embodiments of the present disclosure are directed toward a light-emitting element with improved luminescence efficiency and improved element lifespan.

One or more aspects of embodiments of the present disclosure are directed toward a fused polycyclic compound capable of improving the luminescence efficiency and the element lifespan of the light-emitting element.

One or more aspects of embodiments of the present disclosure are directed toward an electronic apparatus that has excellent or suitable display quality by including the light-emitting element with improved efficiency and lifespan.

Additional aspects will be set forth in part in the description which follows and, in part, will be apparent from the description, or may be learned by practice of the presented embodiments.

According to one or more embodiments of the present disclosure, an electronic apparatus includes a display panel including (e.g., containing) a plurality of light-emitting elements, wherein at least one selected from among the plurality of light-emitting elements includes a first electrode, a second electrode on (e.g., arranged on) the first electrode, and an emission layer between (e.g., arranged between) the first electrode and the second electrode and including (e.g., containing) a first compound represented by Formula 1.

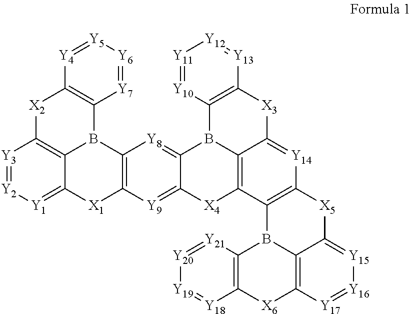

In Formula 1, X₁ to X₆ may each independently be O, S, or NRₓ, and Y₁ to Y₂₁ may each independently be N or CR_{y}. In Formula 1, Rₓ may be a substituted or unsubstituted aryl group having 6 to 30 ring-forming carbon atoms or a substituted or unsubstituted heteroaryl group having 2 to 30 ring-forming carbon atoms, R_{y} may be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, the electronic apparatus may include a display device including the display panel and configured to display an image, the display device may include a first emission region, a second emission region, and a third emission region configured to emit light in different wavelength ranges and separated from one another on a plane, and the first emission region, the second emission region, and the third emission region may be regions in which light generated from the plurality of light-emitting elements is emitted, respectively.

In one or more embodiments, the plurality of light-emitting elements may include a first light-emitting element arranged corresponding to the first emission region, a second light-emitting element arranged corresponding to the second emission region, and the third light-emitting element arranged corresponding to the third emission region.

In one or more embodiments, the display device may include a plurality of display surfaces each having a different main display direction of an image.

In one or more embodiments, the electronic apparatus may include a plurality of display devices each controlled or selected independently and displaying an image, and at least one selected from among the plurality of the display devices may include the display panel.

In one or more embodiments, the electronic apparatus may further include at least one of a processor, a memory, or a power module.

In one or more embodiments, the electronic apparatus may include the display panel, and may be at least one of a television, a monitor, an outdoor billboard, a personal computer, a laptop computer, a personal digital assistant, a device for a vehicle, a game console, a smartphone, a tablet computer, a smart watch, or a camera.

According to one or more embodiments of the disclosure, a light-emitting element includes a first electrode, a second electrode on (e.g., arranged on) the first electrode, an emission layer between (e.g., arranged between) the first electrode and the second electrode and including a first compound represented by Formula 1.

In one or more embodiments, the first compound may be represented by Formula 2.

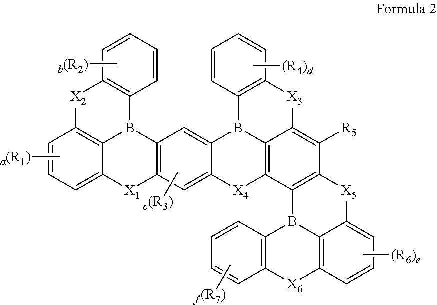

In Formula 2, R₁ to R₇ may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula 2, a and e may each independently be an integer of 0 or greater and 3 or less, b, d, and f may each independently be an integer of 0 or greater and 4 or less, c may be an integer of 0 or greater and 2 or less, and X₁ to X₆ may be the same as defined in Formula 1.

In one or more embodiments, the first compound may be represented by Formula 3.

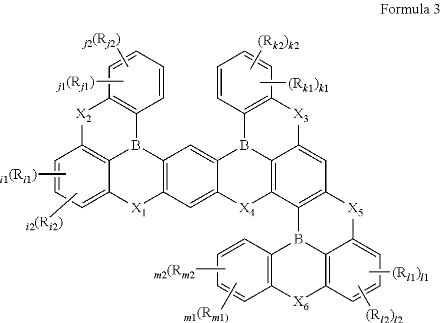

In Formula 3, Rᵢ₁, Rⱼ₁, Rₖ₁, Rₗ₁, and Rₘ₁ may each independently be hydrogen or deuterium, and Rᵢ₂, Rⱼ₂, Rₖ₂, Rₗ₂, and Rₘ₂ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula 3, i1 and l1 may each independently be an integer of 0 to 3, j1, k1, and m1 may each independently be an integer of 0 to 4, i2, j2, k2, l2, and m2 may each independently be 0 or 1, and X₁ to X₆ may be the same as defined in Formula 1.

In one or more embodiments, for example, in Formula 3, Rᵢ₂, Rⱼ₂, Rₖ₂, Rₗ₂, and Rₘ₂ may each independently be a substituted or unsubstituted methyl group, a substituted or unsubstituted t-butyl group, or a substituted or unsubstituted phenyl group, or a substituted or unsubstituted carbazole group.

In one or more embodiments, the first compound may be represented by Formula 4.

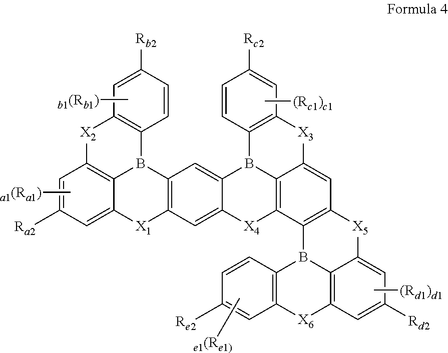

In Formula 4, Rₐ₁, Rₐ₂, R_{b1}, R_{b2}, R_{c1}, R_{c2}, R_{d1}, R_{d2}, Rₑ₁, and Rₑ₂ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, a1 and d1 may each independently be an integer of 0 or greater and 2 or less, b1, c1, and e1 may each independently be an integer of 0 or greater and 3 or less, and X₁ to X₆ may be the same as defined in Formula 1.

In one or more embodiments, for example, in Formula 4, Rₐ₁, Rₐ₂, R_{b1}, R_{b2}, R_{c1}, R_{c2}, R_{d1}, R_{d2}, Rₑ₁, and Rₑ₂ may each independently be hydrogen or deuterium.

In one or more embodiments, for example, in Formula 4, at least one selected from among Rₐ₂, R_{b2}, R_{c2}, R_{d2}, and Rₑ₂ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, for example, in Formula 1, at least one selected from among X₁ to X₆ may be O, and the rest may be NRₓ.

In one or more embodiments, for example, in Formula 1, at least two selected from among X₁ to X₆ may be NRₓ, and the rest may be O.

In one or more embodiments, for example, in Formula 1, Rₓ may be a substituted or unsubstituted phenyl group, a substituted or unsubstituted biphenyl group, or a substituted or unsubstituted terphenyl group.

In one or more embodiments, at least one of hydrogens in the first compound may be substituted with deuterium.

In one or more embodiments, the emission layer may further include at least one of a second compound represented by Formula HT-1, a third compound represented by Formula ET-1, or a fourth compound represented by Formula D-1.

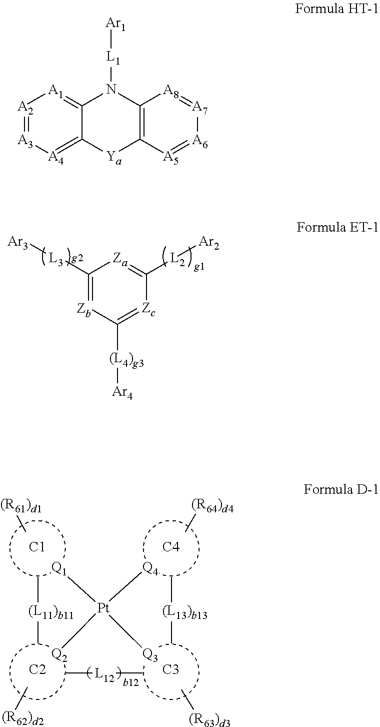

According to one or more embodiments of the present disclosure, a fused polycyclic compound represented by Formula 1 is provided.

For example, the fused polycyclic compounds described herein, including those represented by Formulas 1 through 4 and their specific embodiments, are designed to enhance electronic and photophysical properties within the emission layer of a light-emitting element. By incorporating these compounds—alone or in combination with host, electron-transporting materials, hole-transporting materials and sensitizer such as those represented by Formulas HT-1, ET-1, and D-1—the disclosed light-emitting elements may achieve improved charge balance, enhanced exciton confinement, and reduced non-radiative decay. These improvements contribute to higher external quantum efficiency, lower driving voltage, and extended operational lifetime, thereby enabling the development of electronic apparatuses with superior display performance and energy efficiency across a wide range of applications.

### BRIEF DESCRIPTION OF DRAWINGS

The accompanying drawings are included to provide a further understanding of the present disclosure, and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a block diagram of an electronic apparatus according to one or more embodiments of the present disclosure;

FIG. 2 illustrates schematic views of an electronic apparatus according to one or more embodiments of the present disclosure;

FIG. 3 is a plan view of a display device according to one or more embodiments of the present disclosure;

FIG. 4 is a cross-sectional view of a display device according to one or more embodiments of the present disclosure;

FIG. 5 is a cross-sectional view schematically illustrating a light-emitting element according to one or more embodiments of the present disclosure;

FIGS. 6 and 7 are each a cross-sectional view illustrating a display device according to one or more embodiments of the present disclosure;

FIG. 8 is a cross-sectional view of a display device according to one or more embodiments of the present disclosure;

FIG. 9 is a cross-sectional view of a display device according to one or more embodiments of the present disclosure;

FIG. 10 is a perspective view of an electronic apparatus according to one or more embodiments of the present disclosure;

FIG. 11 is a perspective view of an electronic apparatus according to one or more embodiments of the present disclosure;

FIG. 12 is a drawing illustrating a vehicle in which a display device according to one or more embodiments is arranged;

FIG. 13A is a drawing for a highest occupied molecular orbital (HOMO) distribution of Example Compound 403 of the present disclosure;

FIG. 13B is a drawing for a lowest occupied molecular orbital (LUMO) distribution of Example Compound 403 of the present disclosure;

FIG. 14A is a drawing for a HOMO distribution of Comparative Example Compound X7 of the present disclosure; and

FIG. 14B is a drawing for a LUMO distribution of Comparative Example Compound X7 of the present disclosure.

### DETAILED DESCRIPTION

The present disclosure may be modified in one or more suitable ways and may take one or more suitable forms, and specific/example embodiments are illustrated in the drawings and will be described in more detail in the text. However, this is not intended to limit the present disclosure to a specific disclosure form, but should be understood to include all modifications, equivalents, or substitutes included in the spirit and technical scope of the disclosure.

In describing each drawing, similar or like reference numerals or symbols are used for similar or like elements, and duplicative descriptions thereof may not be provided for conciseness. In the accompanying drawings, the dimensions of structural elements may be shown enlarged or reduced from the actual size for clarity of the disclosure. It will be understood that, although the terms “first”, “second”, and/or the like may be used herein to describe one or more suitable elements, the elements are not to be limited by these terms. These terms are only used to distinguish one element from another element. For instance, a first element could be termed a second element without departing from the scope of the disclosure. Similarly, a second element could be termed a first element. In this disclosure, the singular expressions “a”, “an”, “one”, and “the” are intended to include the plural forms as well, unless the context clearly indicates otherwise. Further, the utilization of “may” when describing embodiments of the present disclosure refers to “one or more embodiments of the present disclosure”.

In this disclosure, it will be further understood that the terms “comprise(s)/comprising,” “include(s)/including,” and/or “has(have)/having,” if (e.g., when) used in this disclosure, specify the presence of stated features, numbers, steps, operations, elements, components, or combinations thereof, but do not preclude the possibility of the presence or addition of one or more other features, numbers, steps, operations, elements, components, and/or combinations thereof. Additionally, the terms “comprise(s)/comprising,” “include(s)/including,” “has(have)/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

In this disclosure, if (e.g., when) it is stated that a part, such as a layer, film, region, or plate, is “on” or “on upper part of” another part, this includes not only embodiments in which it is “directly above” and/or “directly on” the other part, but also embodiments in which there are one or more other parts in between. Similarly, if (e.g., when) it is stated that a part, such as a layer, film, region, or plate, is “under” or “on lower part” of another part, this includes not only embodiments in which it is “directly under” the other part, but also embodiments in which there are one or more other parts in between. However, “directly on” or “directly under” may refer to that there are no additional layers, films, regions, plates, and/or the like, between a layer, a film, a region, a plate, and/or the like and the other part. For example, “directly on” or “directly under” may refer to two layers or two members are arranged without utilizing an additional member such as an adhesive member therebetween. Furthermore, in this disclosure, the term “arranged on” or “on” may include placement not only on the upper part but also on the lower part.

In this disclosure, the term “substituted or unsubstituted” may refer to being substituted or unsubstituted with one or more substituents selected from the group consisting of deuterium, a halogen, a cyano group, nitro group, a hydroxyl group, an amino group, an amine group, a silyl group, an oxy group, a thiol group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the example substituents may be substituted or unsubstituted. For example, a biphenyl group may be interpreted as an aryl group, and may also be interpreted as a phenyl group substituted with a phenyl group.

In this disclosure, the phrase “to be bonded to an adjacent group to form a ring” may refer to being bonded to an adjacent group to form a substituted or unsubstituted hydrocarbon ring or a substituted or unsubstituted heterocycle. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may each be a monocyclic ring or a polycyclic ring. In one or more embodiments, the ring formed by adjacent groups being bonded to each other may be connected to another ring to form a spiro structure.

In this disclosure, the “adjacent group” may refer to a substituent substituted for an atom directly connected to an atom substituted with the corresponding substituent, another substituent substituted for an atom substituted with the corresponding substituent, or a substituent most adjacent to the corresponding substituent three-dimensionally. For example, two methyl groups in 1,2-dimethylbenzene may be interpreted as the “adjacent groups” to each other, and two ethyl groups in 1,1-diethylcyclopentane may be interpreted as the “adjacent groups” to each other. In addition, two methyl groups in 4,5-dimethylphenanthrene may be interpreted as the “adjacent groups” to each other.

In this disclosure, examples of a halogen may include fluorine, chlorine, bromine, or iodine.

In this disclosure, an alkyl group may be linear or branched. The alkyl group may have 1 to 50, 1 to 30, 1 to 20, 1 to 10, or 1 to 6 carbon atoms. Examples of the alkyl group may include a methyl group, an ethyl group, an n-propyl group, an isopropyl group, an n-butyl group, an s-butyl group, a t-butyl group, an i-butyl group, a 2-ethylbutyl group, 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In this disclosure, a cycloalkyl group may refer to a cyclic alkyl group. The cycloalkyl group may have 3 to 50, 3 to 30, 3 to 20, or 3 to 10 carbon atoms. Examples of the cycloalkyl group includes a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, 2-adamantyl group, an isobornyl group, a bicycloheptyl group, and/or the like, but embodiments of the present disclosure are not limited thereto.

In this disclosure, an alkenyl group refers to a hydrocarbon group containing one or more carbon-carbon double bonds in the middle or end of an alkyl group having 2 or more carbon atoms. The alkenyl group may be linear or branched. The number of carbon atoms may be 2 to 30, 2 to 20, or 2 to 10 carbon atoms, but is not particularly limited. Examples of the alkenyl group includes a vinyl group, a 1-butenyl group, a 1-pentenyl group, a 1,3-butadienyl aryl group, a styrenyl group, a styryl vinyl group, and/or the like, but embodiments of the present disclosure are not limited thereto.

In this disclosure, an alkynyl group refers to a hydrocarbon group containing one or more carbon-carbon triple bonds in the middle or end of an alkyl group having 2 or more carbon atoms. The alkynyl group may be linear or branched. The number of carbon atoms may be 2 to 30, 2 to 20, or 2 to 10, but is not particularly limited. Examples of the alkynyl group may include an ethynyl group, a propynyl group, and/or the like, but embodiments of the present disclosure are not limited thereto.

In this disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In this disclosure, an aryl group refers to any functional group or substituent derived from an aromatic hydrocarbon ring. The aryl group may be a monocyclic aryl group or a polycyclic aryl group. The aryl group may have 6 to 30, 6 to 20, or 6 to 15 ring-forming carbon atoms. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzo fluoranthenyl group, a chrysenyl group, and/or the like, but embodiments of the present disclosure are not limited thereto.

In this disclosure, a fluorenyl group may be substituted, and two substituents may combine to form a spiro structure. Examples of the substituted fluorenyl group are as follows. However, embodiments of the present disclosure are not limited thereto.

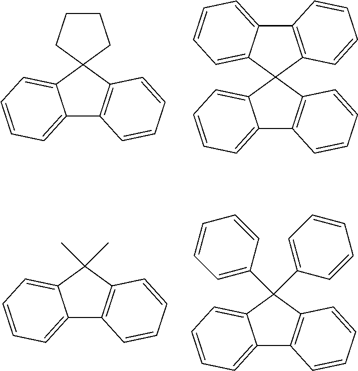

In this disclosure, a heterocyclic group refers to any functional group or substituent derived form a ring containing one or more selected from among B, O, N, P, Si, S, and Se as hetero atom(s). The heterocyclic group may include an aliphatic heterocyclic group and/or an aromatic heterocyclic group. The aromatic heterocyclic group may be a heteroaryl group. The aliphatic heterocycle and the aromatic heterocycle may each be a monocyclic ring or a polycyclic ring.

In this disclosure, the heterocyclic group may include one or more selected from among B, O, N, P, Si, S, and Se, as hetero atom(s). When the heterocyclic group includes two or more hetero atoms, the two or more hetero atoms may be the same as or different from each other. The heterocyclic group may be a monocyclic heterocyclic group or a polycyclic heterocyclic group, which refers to including a heteroaryl group. The heterocyclic group may have 2 to 30, 2 to 20, or 2 to 10 ring-forming carbon atoms.

In this disclosure, the aliphatic heterocyclic group may include one or more selected from among B, O, N, P, Si, S, and Se, as hetero atom(s). The aliphatic heterocyclic group may have 2 to 30, 2 to 20, or 2 to 10 ring-forming carbon atoms. Examples of the aliphatic heterocyclic group include an oxiranyl group, a thiiranyl group, a pyrrolidinyl group, a piperidinyl group, a tetrahydrofuran group, a tetrahydrothiophene group, a thianyl group, a tetrahydropyran group, a 1,4-dioxanyl group, and/or the like, but embodiments of the present disclosure are not limited thereto.

In this disclosure, a heteroaryl group may include one or more selected from among B, O, N, P, Si, S and Se, as hetero atom(s). When the heteroaryl group includes two or more hetero atoms, the two or more hetero atoms may be the same as, or different from each other. The heteroaryl group may be a monocyclic heterocyclic group or a polycyclic heterocyclic group. The heteroaryl group may have 2 to 30, 2 to 20, or 2 to 10 ring-forming carbon atoms. Examples of the heteroaryl group include a thiophene group, a furan group, a pyrrole group, an imidazole group, a pyridine group, bipyridine group, a pyrimidine group, a triazine group, a triazole group, an acridyl group, a pyridazine group, a pyrazinyl group, a quinoline group, quinazoline group, a quinoxaline group, a phenoxazine group, a phthalazine group, a pyrido pyrimidine group, a pyrido a pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, dibenzosilole group, a dibenzofuran group, and/or the like, but embodiments of the present disclosure are not limited thereto.

In this disclosure, the description on the aryl group described above may be applied to an arylene group, except that the arylene group is a divalent group. The description on the heteroaryl group described above may be applied to a heteroarylene group, except that the heteroarylene group is a divalent group.

In this disclosure, a silyl group includes an alkyl silyl group and/or an aryl silyl group. Examples of the silyl group include a trimethylsilyl group, a triethylsilyl group, a t-butyldimethylsilyl group, a dimethylsilyl group, a propyldimethylsilyl group, a triphenylsilyl group, a diphenylsilyl group, a phenylsilyl group, and/or the like, but embodiments of the present disclosure are not limited thereto.

In this disclosure, an acyl group may have 1 to 40, 1 to 30, 1 to 20, or 1 to 10 carbon atoms, but the number of carbon atoms is not particularly limited. Examples of the acyl group include acetyl, ethylcarbonyl, isopropylcarbonyl, naphthylenecarbonyl, cyclopentylcarbonyl, cyclohexylcarbonyl, phenylcarbonyl, and/or the like, but embodiments of the present disclosure are not limited thereto. For example, in one or more embodiments, the acyl group may have a structure below, but embodiments of the present disclosure are not limited thereto.

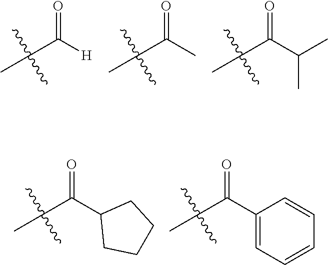

In this disclosure, a sulfinyl group and a sulfonyl group may each have 1 to 30 carbon atoms, but the number of carbon atoms is not particularly limited. The sulfinyl group may include an alkyl sulfinyl group and/or an aryl sulfinyl group. The sulfonyl group may include an alkyl sulfonyl group and/or an aryl sulfonyl group.

In this disclosure, a thio group may include an alkyl thio group and/or an aryl thio group. The thio group may refer to that a sulfur atom is bonded to the alkyl group or aryl group defined as above. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but embodiments of the present disclosure are not limited thereto.

In this disclosure, an oxy group may refer to that an oxygen atom is bonded to the alkyl group or aryl group defined as above. The oxy group may include an alkoxy group and/or an aryl oxy group. The alkoxy group may be a linear chain, a branched chain, or a ring. The alkoxy group may have, for example 1 to 20, or 1 to 10 carbon atoms, but the number of carbon atoms is not particularly limited. Examples of the oxy group include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

In this disclosure, a boron group may refer to that a boron atom is bonded to the alkyl group or aryl group defined as above. The boron group includes an alkyl boron group and/or an aryl boron group. Examples of the boron group include a dimethylboron group, a diethylboron group. a t-butylmethylboron group, a diphenylboron group, a phenylboron group, and/or the like, but embodiments of the present disclosure are not limited thereto.

In this disclosure, an amine group may have 1 to 30 carbon atoms, but the number of carbon atoms is not particularly limited. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, and/or the like, but embodiments of the present disclosure are not limited thereto.

In this disclosure, the alkyl group of an alkylthio group, an alkylsulfoxy group, an alkylaryl group, an alkylamino group, an alkylboron group, an alkylsilyl group, and an alkylamine group is the same as the examples of the alkyl group previously described.

In this disclosure, the aryl group of an aryloxy group, an arylthio group, an arylsulfoxy group, an arylamino group, an arylboron group, an arylsilyl group, and an arylamine group is the same as the aryl group previously described.

In this disclosure, a direct linkage may refer to a single bond.

In this disclosure,

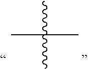

and “-*” refer to a position to be connected.

Hereinafter, embodiments of the disclosure will be described with reference to the accompanying drawings.

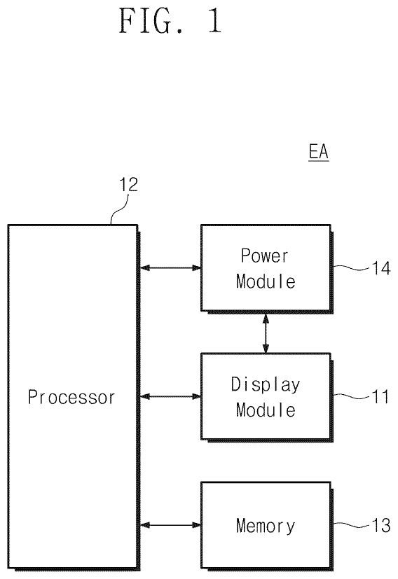

FIG. 1 is a block diagram of an electronic apparatus according to one or more embodiments of the present disclosure. Referring to FIG. 1, an electronic apparatus EA according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

In the memory 13, data information necessary for an operation of the processor 12 and/or the display module 11 may be stored. When the processor 12 runs an application stored in the memory 13, image data signals and/or input control signals may be transmitted to the display module 11, and the display module 11 may process the received signals to output image information through a display screen. The display module 11 may include a display panel displaying images.

The power module 14 may include a power supply module such as a power adapter or a battery device, and a power-converting module that converts power supplied by the power supply module and generates power necessary for the operation of the electronic apparatus EA.

At least one among the components of the electronic apparatus EA, described herein, may be included in a display panel according to one or more embodiments, which will be described later, or in a display device according to one or more embodiments including the display panel. In addition, some of individual modules, included in one functional module, may be included in the display device, and others may be provided separately from the display device. For example, the display device may include the display module 11, and the processor 12, the memory 13, and the power module 14 may be provided in the form of a device other than the display device, in the electronic apparatus EA.

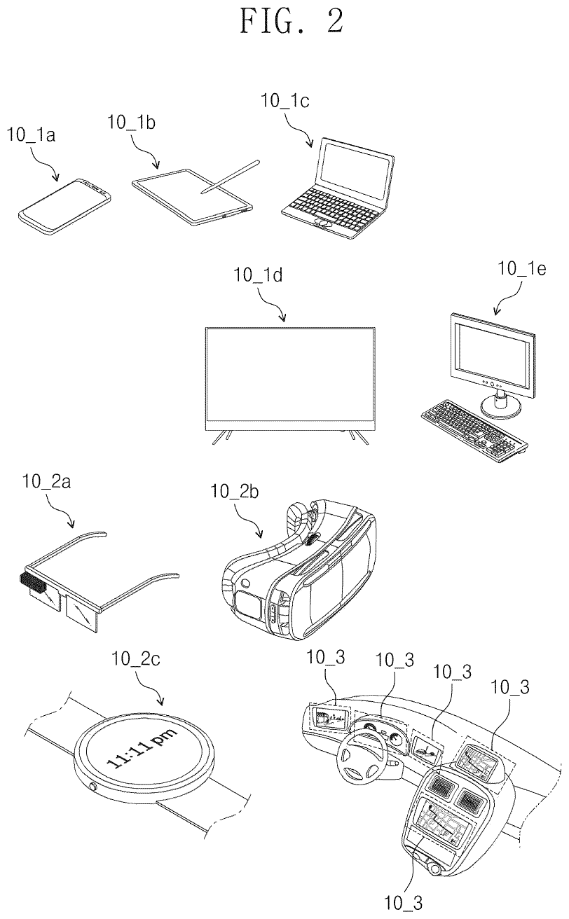

FIG. 2 shows schematic views of an electronic apparatus according to one or more embodiments of the present disclosure.

Referring to FIG. 2, one or more suitable electronic apparatuses including the display device according to one or more embodiments may not only include electronic apparatuses for displaying images, such as a smartphone 10_1a, a tablet PC 10_1b, a laptop computer 10_1c, a TV 10_1d, and a desktop monitor 10_1e, but also include wearable electronic apparatuses, such as smart glasses 10_2a, a head mounted display 10_2b, and a smart watch 10_2c, and electronic apparatuses for vehicle 10_3 such as a car dashboard, a center fascia, a center information display (CID) arranged on the dashboard of a vehicle, and a room mirror display of the vehicle, and/or the like.

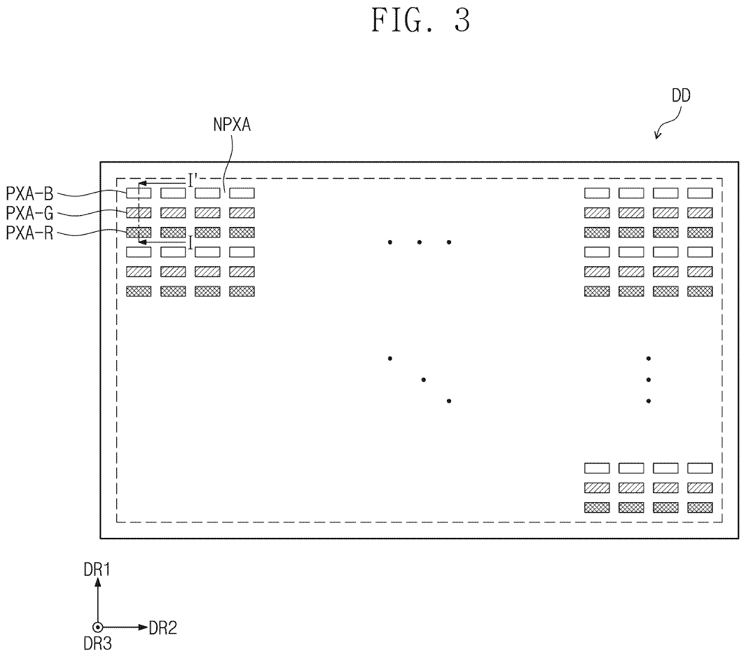

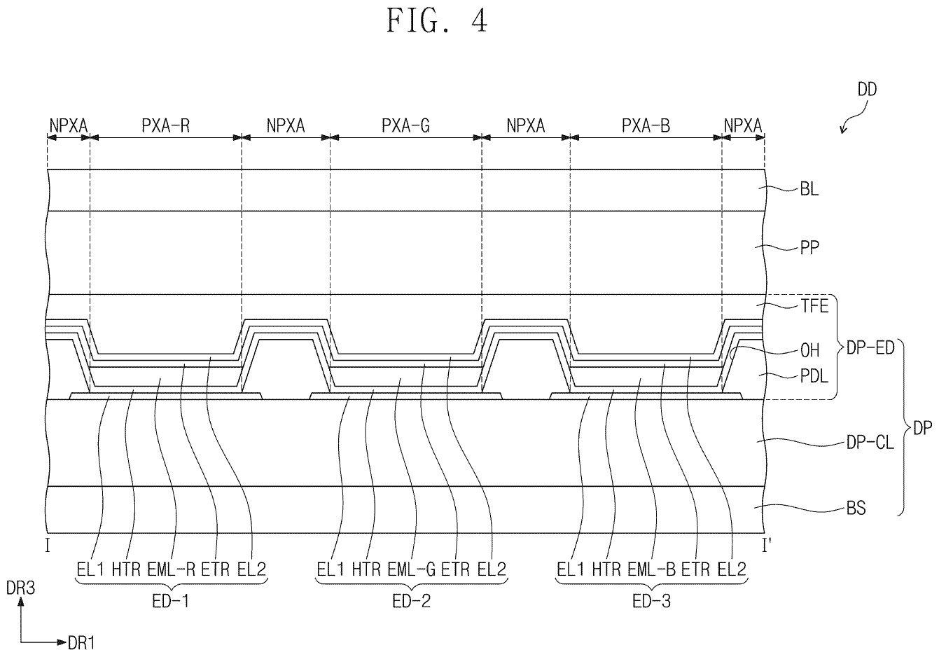

FIG. 3 is a plan view illustrating a display device DD according to one or more embodiments of the present disclosure. FIG. 4 is a cross-sectional view of the display device DD according to one or more embodiments of the present disclosure. FIG. 4 is a cross-sectional view illustrating a portion corresponding to the line I-I′ of FIG. 3. The display device DD according to one or more embodiments may be included in the electronic apparatus EA previously described. The display device DD may be a portion that provides an image in the electronic apparatus EA.

The display device DD may include a display panel DP and an optical layer PP arranged on the display panel DP. The display panel DP may include light-emitting elements ED-1, ED-2, and ED-3. The display device DD may include a plurality of light-emitting elements ED-1, ED-2, and ED-3. The optical layer PP may be arranged on the display panel DP, and may control reflected light of external light on the display panel DP. The optical layer PP may include, for example, a polarization layer, or include a color filter layer. In one or more embodiments, the optical layer PP may not be provided in the display device DD.

A base substrate BL may be arranged on the optical layer PP. The base substrate BL may be a member that provides a base surface on which the optical layer PP is arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display element layer DP-ED and the base substrate BL. The filling layer may be an organic material layer. The filling layer may include at least one of an acrylate-based resin, a silicon-based resin, or an epoxy-based resin.

The display panel DP may include a base layer BS, a circuit layer DP-CL provided onto the base layer BS, and the display element layer DP-ED. The display element layer DP-ED may include a pixel-defining film PDL, the light-emitting elements ED-1, ED-2, and ED-3 respectively arranged between the pixel-defining film PDL, and an encapsulation layer TFE arranged on the light-emitting elements ED-1, ED-2, and ED-3.

The base layer BS may be a member that provides a base surface on which the display element layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors. The transistors may each include a control electrode, an input electrode, and an output electrode. For example, in one or more embodiments, the circuit layer DP-CL may include switching transistor(s) and driving transistor(s) for driving the light-emitting elements ED-1, ED-2, and ED-3 of the display element layer DP-ED.

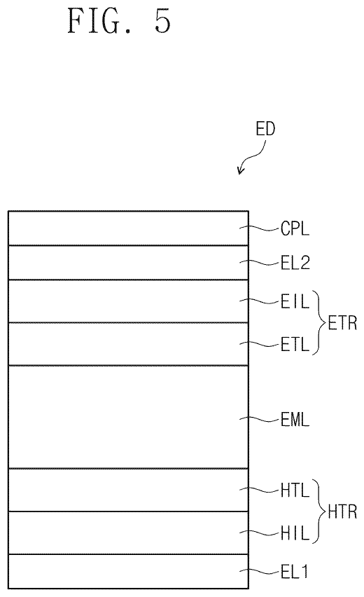

The light-emitting elements ED-1, ED-2, and ED-3 may each independently have a structure of a light-emitting element ED according to one or more embodiments shown in FIGS. 5 to 8 to be described later. Each of the light-emitting elements ED-1, ED-2, and ED-3 may include a first electrode EL1, a hole transport region HTR, respective emission layers EML-R, EML-G, or EML-B, an electron transport region ETR, and a second electrode EL2.

FIG. 4 illustrates one or more embodiments in which the respective emission layers EML-R, EML-G, and EML-B of the light-emitting elements ED-1, ED-2, and ED-3 are arranged in openings OH defined in the pixel-defining film PDL, and the hole transport region HTR, the electron transport region ETR, and the second electrode EL2 are each provided as a common layer for the entire light-emitting elements ED-1, ED-2, and ED-3. However, embodiments of the present disclosure are not limited thereto, for example, in one or more embodiments, the hole transport region HTR and the electron transport region ETR may each be provided by being patterned inside the openings OH defined in the pixel-defining film PDL. For example, in one or more embodiments, the hole transport region HTR, the respective emission layer EML-R, EML-G, and EML-B, the electron transport region ETR, and/or the like of the light-emitting element ED-1, ED-2, and ED-3 may be provided by being patterned through inkjet printing.

The encapsulation layer TFE may cover the light-emitting elements ED-1, ED-2, and ED-3. The encapsulation layer TFE may seal the display element layer DP-ED. The encapsulation layer TFE may be a thin-film encapsulation layer. The encapsulation layer TFE may be one layer or a stack of multiple layers. The encapsulation layer TFE may include at least one insulation layer. The encapsulation layer TFE according to one or more embodiments may include at least one inorganic film (hereinafter, inorganic encapsulation film). In addition, the encapsulation layer TFE according to one or more embodiments may include at least one organic film (hereinafter, organic encapsulation film) and at least one inorganic encapsulation film.

The inorganic encapsulation film protects the display element layer DP-ED from moisture/oxygen, and the organic encapsulation film protects the display element layer DP-ED from foreign substances such as dust particles. The inorganic encapsulation film may include silicon nitride, silicon oxynitride, silicon oxide, titanium oxide, aluminum oxide, and/or the like, but embodiments of the present disclosure are not limited particularly thereto. The organic encapsulation film may include an acrylate-based compound, an epoxy-based compound, and/or the like. In one or more embodiments, the organic encapsulation film may include an organic material capable of photopolymerization, but embodiments of the present disclosure are not limited particularly thereto.

The encapsulation layer TFE may be arranged on the second electrode EL2, and may be arranged by filling the opening OH.

Referring to FIG. 3 and FIG. 4, the display device DD may include a non-emission region NPXA and emission regions PXA-R, PXA-G, and PXA-B. The emission regions PXA-R, PXA-G, and PXA-B may be regions where light generated from the respective light-emitting elements ED-1, ED-2, and ED-3 is emitted. The emission regions PXA-R, PXA-G, and PXA-B may be spaced and/or apart (e.g., spaced apart or separated) from one another on a plane.

The emission regions PXA-R, PXA-G, and PXA-B may be regions separated by the pixel-defining film PDL. The non-emission region NPXA may be regions positioned between adjacent emission regions PXA-R, PXA-G, and PXA-B, and corresponding to the pixel-defining film PDL. In one or more embodiments, the emission regions PXA-R, PXA-G, and PXA-B may each correspond to a pixel. The light-emitting elements ED-1, ED-2, and ED-3 may be separated by the pixel-defining film PDL. The respective emission layers EML-R, EML-G, and EML-B of the light-emitting elements ED-1, ED-2, and ED-3 may be arranged separately in the opening OH defined in the pixel-defining film PDL.

The emission regions PXA-R, PXA-G, and PXA-B may be divided into a plurality of groups according to the color of light generated from the light-emitting elements ED-1, ED-2, and ED-3. FIG. 3 and FIG. 4 illustrate that the display device DD according to one or more embodiments includes three emission regions PXA-R, PXA-G, and PXA-B respectively emitting red color light, green color light, and blue color light. For example, the display device DD according to one or more embodiments may include a red emission region PXA-R, a green emission region PXA-G, and a blue emission region PXA-B that are distinguished from one another.

In the display device DD according to one or more embodiments, a plurality of light-emitting elements ED-1, ED-2, and ED-3 may be to emit light in different wavelength ranges. For example, the display device DD according to one or more embodiments may include a first light-emitting element ED-1 that emits red color light, a second light-emitting element ED-2 that emits green color light, and a third light-emitting element ED-3 that emits blue color light. For example, in one or more embodiments, the red emission region PXA-R, the green emission region PXA-G, and the blue emission region PXA-B of the display device DD may respectively correspond to the first light-emitting element ED-1, the second light-emitting element ED-2, and the third light-emitting element ED-3.

However, embodiments of the present disclosure are not limited thereto, and the first to third light-emitting elements ED-1, ED-2, and ED-3 may be to emit light in substantially the same wavelength range, or at least one may be to emit light in a different wavelength range. For example, in one or more embodiments, all of the first to third light-emitting elements ED-1, ED-2, and ED-3 may be to emit the blue color light.

The emission regions PXA-R, PXA-G, and PXA-B of the display device DD according to one or more embodiments may be arranged in a stripe form. Referring to FIG. 3, a plurality of red emission regions PXA-R may be arranged with each other along a second direction axis DR2, a plurality of green emission regions PXA-G may be arranged with each other along the second direction axis DR2, and a plurality of blue emission regions PXA-B may be arranged with each other along the second directional axis DR2. In addition, the red emission region PXA-R, the green emission region PXA-G, and the blue emission region PXA-B may be alternately arranged in this order along a first direction axis DR1.

FIG. 3 and FIG. 4 illustrate that the emission regions PXA-R, PXA-G, and PXA-B have similar areas, but embodiments of the present disclosure are not limited thereto, and the areas of the emission regions PXA-R, PXA-G, and PXA-B may differ from one another according to the wavelength range of light emitted. In this regard, the areas of the emission regions PXA-R, PXA-G, and PXA-B may each refer to an area if (e.g., when) viewed toward a plane defined by the first direction axis DR1 and the second direction axis DR2 (e.g., the area in plan view).

In one or more embodiments, an arrangement form of the emission regions PXA-R, PXA-G, and PXA-B is not limited to what is illustrated in FIG. 3, and the order in which the red emission region PXA-R, the green emission region PXA-G, and the blue emission region PXA-B are arranged may be provided in one or more suitable combinations according to the display quality characteristics to be desired or required for the display device DD. For example, the arrangement form of the emission regions PXA-R, PXA-G, and PXA-B may be a PENTILE© arrangement form (for example, an RGBG matrix, an RGBG structure, or an RGBG matrix structure) or a Diamond Pixel™ arrangement form. (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In one or more embodiments, the areas of the emission regions PXA-R, PXA-G, and PXA-B may be different from one another. For example, in one or more embodiments, the area of the green emission region PXA-G may be smaller than the area of the blue emission region PXA-B, but embodiments of the present disclosure are not limited thereto.

Hereinafter, FIG. 5 is a cross-sectional view schematically illustrating a light-emitting element according to one or more embodiments of the present disclosure.

The light-emitting element ED according to one or more embodiments may include a first electrode EL1, a second electrode EL2 opposite to (e.g., facing) the first electrode EL1, and at least one functional layer arranged between the first electrode EL1 and the second electrode EL2. The light-emitting element ED according to one or more embodiments may include a fused polycyclic compound according to one or more embodiments, which will be described later, in the at least one functional layer.

The light-emitting element ED may include a hole transport region HTR, an emission layer EML, an electron transport region ETR, and/or the like stacked in sequence as the at least one functional layer. For example, the light-emitting element ED according to one or more embodiments may include the first electrode EL1, the hole transport region HTR, the emission layer EML, the electron transport region ETR, and the second electrode EL2 stacked in sequence (e.g., in the stated order). In one or more embodiments, the light-emitting element ED may further include a capping layer CPL arranged above (e.g., on) the second electrode EL2.

The light-emitting element ED according to one or more embodiments may include the fused polycyclic compound according to one or more embodiments, which will be described later, in the at least one functional layer included in the light-emitting element ED. In the light-emitting element ED according to one or more embodiments, the fused polycyclic compound according to one or more embodiments may be included in at least one of the hole transport region HTR, the emission layer EML, or the electron transport region ETR. For example, in the light-emitting element ED according to one or more embodiments, the emission layer EML may include the fused polycyclic compound according to one or more embodiments.

The first electrode EL1 has conductivity (e.g., is a conductor). The first electrode EL1 may include a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

In embodiments in which the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), and/or the like. In embodiments in which the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound thereof or a mixture thereof (for example, a mixture of Ag and Mg). In one or more embodiments, the first electrode EL1 may have a multi-layer structure including a reflective film or transflective film including one or more of the above-mentioned materials, and a transparent conductive film including indium tin oxide (ITO), indium zinc oxide (IZO), zinc oxide (ZnO), indium tin zinc oxide (ITZO), and/or the like. For example, in one or more embodiments, the first electrode EL1 may have a three-layer structure of ITO/Ag/ITO, but embodiments of the present disclosure are not limited thereto. In one or more embodiments, the first electrode EL1 may include one of the above-described metal materials, a combination of at least two metal materials selected from among the above-described metal materials, an oxide of the above-described metal materials, and/or the like. The first particle EL1 may have a thickness of about 700 ångströms (Å) to about 10000 Å. For example, in one or more embodiments, the thickness of the first electrode EL1 may be about 1000 Å to about 3000 Å.

The hole transport region HTR may be provided on the first electrode EL1. The hole transport region HTR may include at least one of a hole injection layer HIL, a hole transport layer HTL, a buffer layer or an auxiliary emission layer, or an electron-blocking layer EBL. The hole transport region HTR may have a thickness of, for example, about 50 Å to about 15000 Å.

The hole transport region HTR may have a single layer made of a single material, a single layer made of a plurality of different materials, or a multi-layer structure including a plurality of layers made of a plurality of different materials.

For example, in one or more embodiments, the hole transport region HTR may have a single-layer structure of a hole injection layer HIL or a hole transport layer HTL, or may have a single-layer structure including a hole injection material and/or a hole transport material. In one or more embodiments, the hole transport region HTR may have a single-layer structure including a plurality of different materials, or may have a structure of a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron-blocking layer, sequentially stacked from the first electrode EL1 (e.g., in the stated order), but embodiments of the present disclosure are not limited thereto.

The hole transport region HTR may be formed using one or more suitable methods including vacuum deposition, spin coating, casting, Langmuir-Blodgett (LB), inkjet printing, laser printing, laser induced thermal imaging (LITI), and/or the like.

In one or more embodiments, the hole transport region HTR may include a compound represented by Formula H-1.

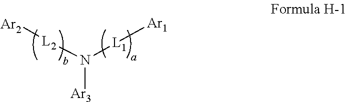

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 or greater and 10 or less. In one or more embodiments, if (e.g., when) a or b is an integer of 2 or greater, L₁ in plurality and/or L₂ in plurality may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ contains an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds of Compound Group H. However, the compounds listed in Compound Group H are mere examples, and the compound represented by Formula H-1 is not limited to those listed in Compound Group H.

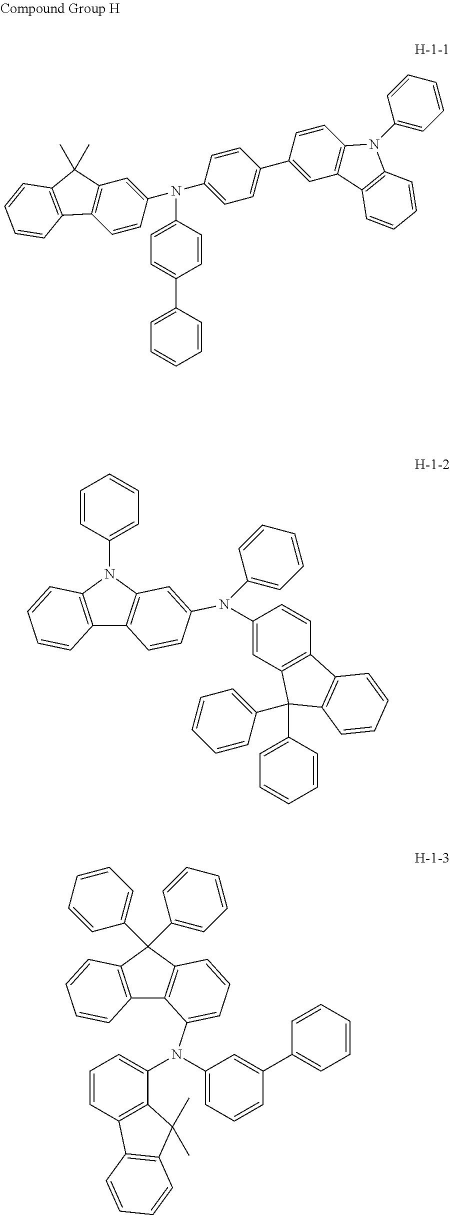 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

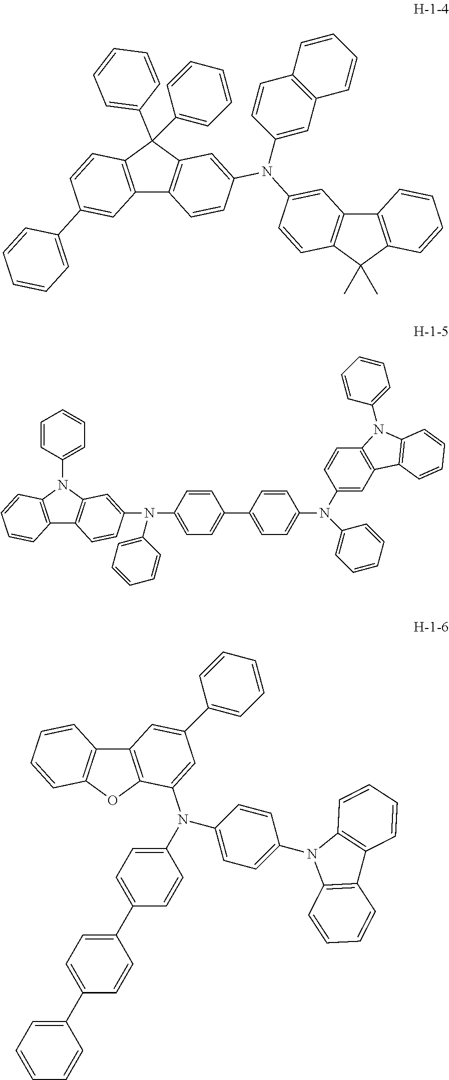 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

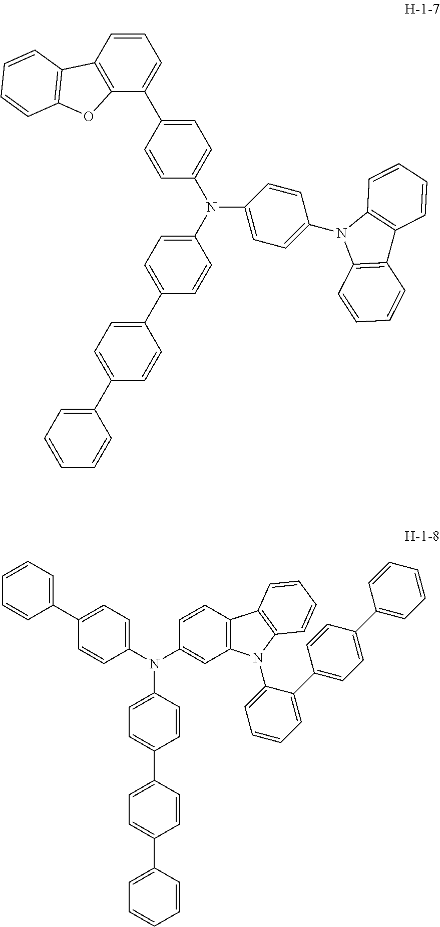 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1]

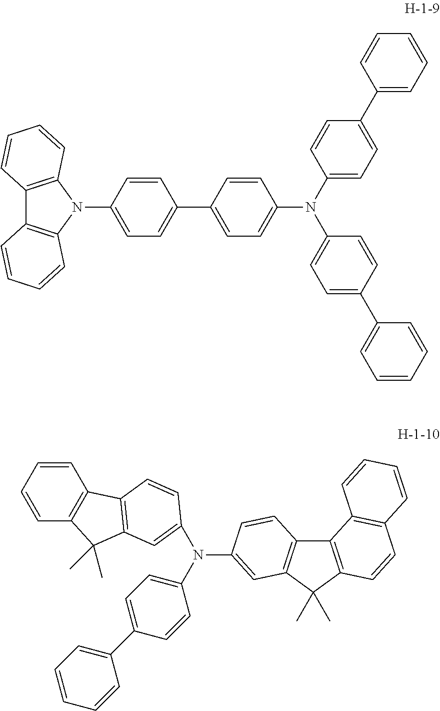 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

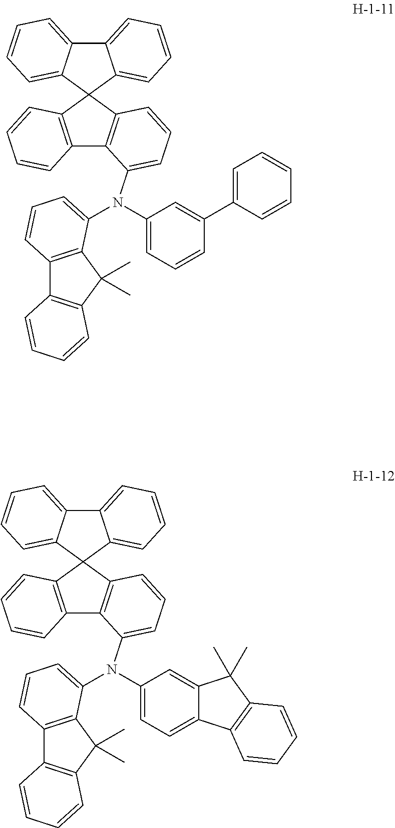 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

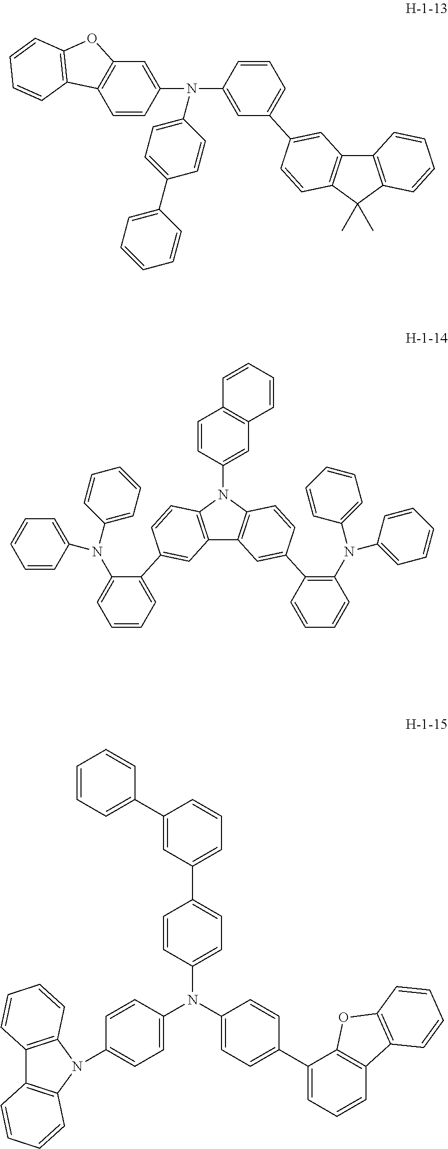 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

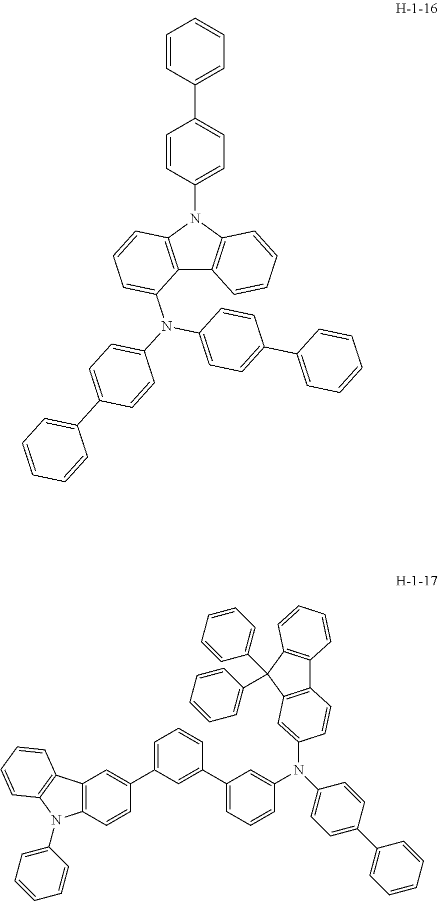 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

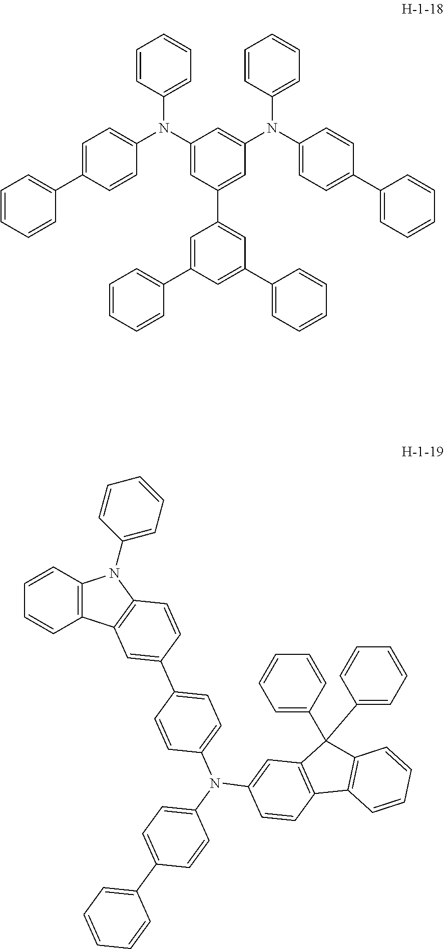 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include one or more selected from among a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate (PANI/PSS), N,N′-di(naphthalen-1-yl)-N,N′-diphenyl-benzidine (NPB), polyetherketone containing triphenylamine (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), and/or the like.

In one or more embodiments, the hole transport region HTR may include one or more selected from among a carbazole-based derivative such as N-phenylcarbazole and polyvinylcarbazole, a fluorene-based derivative, N,N′-bis(3-methylphenyl)-N,N′-diphenyl-[1,1′-biphenyl]-4,4′-diamine (TPD), a triphenylamine-based derivative such as 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), N,N′-Bis(naphthalen-1-yl)-N,N′-bis(phenyl)-2,2′-dimethylbenzidine (α-NPD), and/or the like.

The hole transport region HTR may include one or more of the above-described compounds of the hole transport region in at least one of a hole injection layer HIL, a hole transport layer HTL, or an electron-blocking layer.

The hole transport region HTR may have a thickness of about 100 Å to about 10000 Å, for example, about 100 Å to about 5000 Å. If (e.g., when) the hole transport region HTR includes a hole injection layer HIL, a thickness of the hole injection layer HTL may be, for example, about 30 Å to about 1000 Å. If (e.g., when) the hole transport region HTR includes a hole transport layer HTL, a thickness of the hole transport layer HTL may be, for example, about 30 Å to about 1000 Å. For example, if (e.g., when) the hole transport region HTR includes an electron-blocking layer, a thickness of the electron-blocking layer may be about 10 Å to about 1000 Å. If (e.g., when) the thicknesses of the hole transport region HTR, the hole injection layer HIL, the hole transport layer HTL, and the electron-blocking layer fall within the above-described ranges, respectively, satisfactory hole transport characteristics may be achieved without a substantial increase in driving voltage.

In one or more embodiments, in addition to the above-mentioned materials, the hole transport region HTR may further include a charge-generating material for improvement of conductivity (e.g., electric conductivity). The charge-generating material may be dispersed evenly or unevenly in the hole transport region HTR. The charge-generating material may be, for example, a p-dopant. The p-dopant may include at least one of a halogenated metal compound (e.g., a metal halide), a quinone derivative, a metal oxide, or a compound containing a cyano group, but embodiments of the present disclosure are not limited thereto. For example, in one or more embodiments, the p-dopant may include a halogenated metal compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as a tungsten oxide and/or a molybdenum oxide, a compound containing a cyano group such as dipyrazino[2,3-f: 2′, 3′-h]quinoxaline-2,3,6,7,10,11-hexacarbonitrile (HATCN) and/or4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, in one or more embodiments, the hole transport region HTR may further include at least one of a buffer layer or an electron-blocking layer in addition to the hole injection layer HIL and the hole transport layer HTL. The buffer layer may compensate for a resonance distance according to the wavelength of light emitted from the emission layer EML to thereby increase light-emitting efficiency. For a material included in the buffer layer, a material that may be included in the hole transport region HTR may be used. The electron-blocking layer is a layer that prevents electron injection from the electron transport region ETR to the hole transport region HTR.

The emission layer EML may be provided on the hole transport region HTR. The emission layer EML may have a thickness of, for example, about 100 Å to about 1000 Å, or about 100 Å to about 300 Å. The emission layer EML may have a single layer made of a single material, a single layer made of a plurality of different materials, or a multi-layer structure including a plurality of layers made of a plurality of different materials.

The light-emitting element ED according to one or more embodiments may include a fused polycyclic compound represented by Formula 1 in at least one functional layer arranged between the first electrode EL1 and the second electrode EL2. In the light-emitting element ED according to one or more embodiments, the emission layer EML may include the fused polycyclic compound according to one or more embodiments. In one or more embodiments, the emission layer EML may include the fused polycyclic compound according to one or more embodiments, as a dopant. The fused polycyclic compound according to one or more embodiments may be a dopant material of the emission layer EML. In this disclosure, the fused polycyclic compound according to one or more embodiments may be referred to as a first compound.

The fused polycyclic compound according to one or more embodiments may include three boron atoms as ring-forming atoms. In one or more embodiments, in the fused polycyclic compound, a 5-ring first fused cyclic moiety (e.g., first fused cyclic compound) including a first boron atom as a ring-forming atom, a second fused cyclic moiety (e.g., second fused cyclic compound) including a second boron atom as a ring-forming atom, and a third fused cyclic moiety (e.g., third fused cyclic compound) including a third boron atom as a ring-forming atom may be connected (e.g., fused) to each other. For example, the first fused cyclic moiety (e.g., first fused cyclic compound) may be represented by FR-1, the second fused cyclic moiety (e.g., second fused cyclic compound) may be represented by FR-2, and the third fused cyclic moiety (e.g., third fused cyclic compound) may be represented by FR-3. The fused polycyclic compound according to one or more embodiments may have the first to third fused cyclic moieties respectively represented by FR-1 to FR-3 that are connected (e.g., fused) to each other.

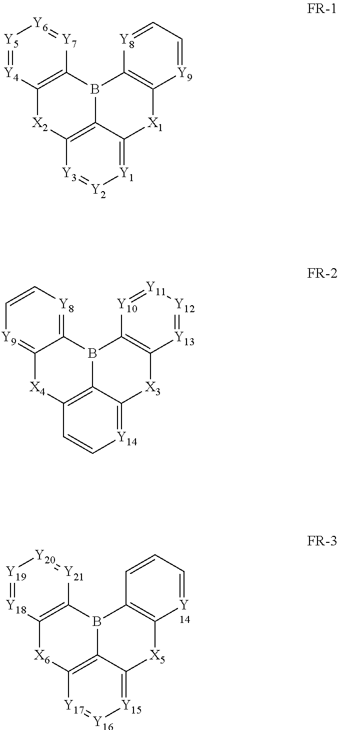

In the fused polycyclic compound according to one or more embodiments, the first fused cyclic moiety and the second fused cyclic moiety may be connected (e.g., fused) by sharing one ring, and the second fused cyclic moiety and the third fused cyclic moiety may be connected (e.g., fused) by sharing one ring. For example, the second fused cyclic moiety may be connected (e.g., fused) to each of the first fused cyclic moiety and the third fused cyclic moiety, and the first fused cyclic moiety and the third fused cyclic moiety may not be connected to each other. In one or more embodiments, the first fused cyclic moiety represented by FR-1 and the second fused cyclic moiety represented by FR-2 may be connected (e.g., fused) by sharing a ring including Y₈ and Y₉ as ring-forming atoms. The second fused cyclic moiety represented by FR-2 and the third fused cyclic moiety represented by FR-3 may be connected (e.g., fused) by sharing a ring including Y₁₄ as a ring-forming atom. In this disclosure, the structure, formed by the first to third fused cyclic moieties being connected/fused to each other, may be referred to as a “fused cyclic core”. Meanwhile, in FR-1, FR-2, and FR-3, for X₁ to X₆ and Y₁ to Y₂₁, the same content as defined in Formula 1, which will be described later, may be applied.

The fused polycyclic compound according to one or more embodiments may be represented by Formula 1.

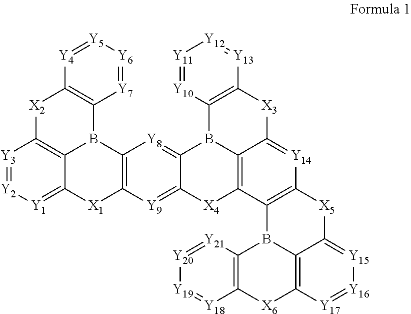

In Formula 1, X₁ to X₆ may each independently be O, S, or NRₓ. In one or more embodiments, X₁ to X₆ may each independently be O or NRₓ. In one or more embodiments, at least one selected from among X₁ to X₆ may be O, and the rest may be NRₓ. For example, in one or more embodiments, any one selected from among X₁ to X₆ may be O, and the remainder of X₁ to X₆ that is not O may be NRₓ. In this regard, NRₓ in plurality may be the same as or different from each other. In one or more embodiments, at least two selected from among X₁ to X₆ may be O, and the rest may be NRₓ. For example, in one or more embodiments, two, three, or four selected from among X₁ to X₆ may be O, and the remainder of X₁ to X₆ that is not O may be NRₓ. In this regard, NRₓ in plurality may be the same as or different from each other.

In Formula 1, Y₁ to Y₂₁ may each independently be N or CR_{y}. In one or more embodiments, Y₁ to Y₂₁ may be all CR_{y}. However, embodiments of the present disclosure are not limited thereto, for example, at least one selected from among Y₁ to Y₂₁ may be N, and the remainder of Y₁ to Y₂₁ that is not N may be CR_{y}.

In Formula 1, Rₓ may be a substituted or unsubstituted aryl group having 6 to 30 ring-forming carbon atoms or a substituted or unsubstituted heteroaryl group having 2 to 30 ring-forming carbon atoms. In one or more embodiments, Rₓ may be a substituted or unsubstituted aryl group having 6 to 30 ring-forming carbon atoms. For example, in one or more embodiments, Rₓ may be a substituted or unsubstituted phenyl group, a substituted or unsubstituted biphenyl group, or a substituted or unsubstituted terphenyl group, but embodiments of the present disclosure are not limited thereto.

In Formula 1, R_{y} may be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, R_{y} may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R_{y} may be hydrogen, deuterium, a substituted or unsubstituted methyl group, a substituted or unsubstituted t-butyl group, a substituted or unsubstituted phenyl group, or a substituted or unsubstituted carbazole group, but embodiments of the present disclosure are not limited thereto.

In one or more embodiments, the first compound represented by Formula 1 may be represented by Formula 2. The first compound represented by Formula 2 may correspond to the case where Y₁ to Y₂₁ are all CR_{y} in Formula 1. The fused polycyclic compound according to one or more embodiments may be represented by Formula 2.

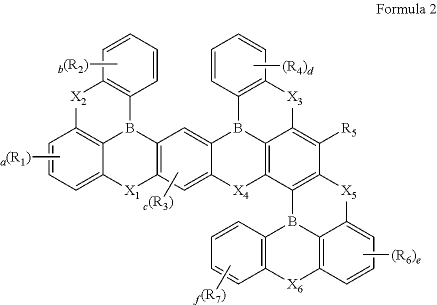

In Formula 2, R₁ to R₇ may each independently be hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In one or more embodiments, R₁ to R₇ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, R₁ to R₇ may each independently be hydrogen, deuterium, a substituted or unsubstituted methyl group, a substituted or unsubstituted t-butyl group, a substituted or unsubstituted phenyl group, or a substituted or unsubstituted carbazole group, but embodiments of the present disclosure are not limited thereto.

In Formula 2, a and e may each independently be an integer of 0 or greater and 3 or less. In Formula 2, if (e.g., when) each of a and e is 0, the fused polycyclic compound according to one or more embodiments may not be substituted with each of R₁ and R₆. If (e.g., when) each of a and e is 3, and each of R₁ and R₆ is hydrogen, the embodiment may be the same as the embodiment in which each of a and e is 0. If (e.g., when) each of a and e is an integer of 2 or greater, R₁ and R₆ each provided in plurality may be the same as each other, or at least one selected from among R₁ and R₆ each in plurality may be different.

In Formula 2, b, d, and f may each independently be an integer of 0 or greater and 4 or less. In Formula 2, if (e.g., when) each of b, d, and f is 0, the fused polycyclic compound according to one or more embodiments may not be substituted with each of R₂, R₄, and R₇. If (e.g., when) each of b, d, and f is 4, and each of R₂, R₄, and R₇ is hydrogen, the embodiment may be the same as the embodiment in which each of b, d, and f is 0. If (e.g., when) each of b, d, and f is an integer of 2 or greater, R₂, R₄, and R₇ each provided in plurality may be the same as each other, or at least one selected from among R₂, R₄, and R₇ each in plurality may be different.

In Formula 2, c may be an integer of 0 or greater and 2 or less. In Formula 2, if (e.g., when) c is 0, the fused polycyclic compound according to one or more embodiments may not be substituted with R₃. If (e.g., when) c is 2, and all of R₃ are hydrogens, the embodiment may be the same as the embodiment in which c is 0. When c is an integer of 2, R₃ provided in plurality may be all the same, or at least one selected from among the plurality of R₃(s) may be different.

In Formula 2, for X₁ to X₆, the same content as described in Formula 1 may be applied.

In one or more embodiments, the first compound represented by Formula 1 may be represented by Formula 3. For example, the fused polycyclic compound according to one or more embodiments may be represented by Formula 3.

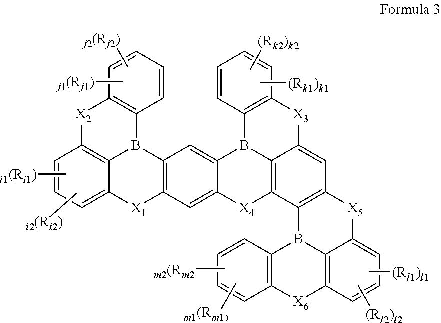

In Formula 3, Rᵢ₁, Rⱼ₁, Rₖ₁, Rᵢ₁, and Rₘ₁ may each independently be hydrogen or deuterium. In one or more embodiments, all of Rᵢ₁, Rⱼ₁, Rₖ₁, Rᵢ₁, and Rₘ₁ may be hydrogens. However, embodiments of the present disclosure are not limited thereto, for example, at least one selected from among Rᵢ₁, Rⱼ₁, Rₖ₂, Rᵢ₁, or Rₘ₁ may be deuterium, and the rest may be hydrogens.

In Formula 3, Rᵢ₂, Rⱼ₂, Rₖ₂, Rₗ₂, and Rₘ₂ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Rᵢ₂, Rⱼ₂, Rₖ₂, Rₗ₂, and Rₘ₂ may each independently be a substituted or unsubstituted methyl group, a substituted or unsubstituted t-butyl group, or a substituted or unsubstituted phenyl group, or a substituted or unsubstituted carbazole group, but embodiments of the present disclosure are not limited thereto.

In Formula 3, i1 and l1 may each independently be an integer of 0 or greater and 3 or less. In Formula 3, if (e.g., when) each of i1 and l1 is 0, the fused polycyclic compound according to one or more embodiments may not be substituted with each of Rᵢ₁ and Rₗ₁. If (e.g., when) each of i1 and l1 is 3, and each of Rᵢ₁ and Rₗ₁ is hydrogen, the embodiment may be the same as the embodiment in which each of i1 and l1 is 0. If (e.g., when) each of i1 and l1 is an integer of 2 or greater, Rᵢ₁ and Rₗ₁ each provided in plurality may be the same as each other, or at least one selected from among Rᵢ₁ and Rₗ₁ each in plurality may be different.

In Formula 3, j1, k1, and m1 may each independently be an integer of 0 or greater and 4 or less. In Formula 3, if (e.g., when) each of j1, k1, and m1 is 0, the fused polycyclic compound according to one or more embodiments may not be substituted with each of Rⱼ₁, Rₖ₁, and Rₘ₁. If (e.g., when) each of j1, k1, and m1 is 4, and each of Rⱼ₁, Rₖ₁, and Rₘ₁ is hydrogen, the embodiment may be the same as the embodiment in which each of j1, k1, and m1 is 0. If (e.g., when) each of j1, k1, and m1 is an integer of 2 or greater, Rⱼ₁, Rₖ₁, and Rₘ₁ each provided in plurality may be the same as each other, or at least one selected from among Rⱼ₁, Rₖ₁, and Rₘ₁ each in plurality may be different.

In Formula 3, i2, j2, k2, l2, and m2 may each independently be 0 or 1. In Formula 3, if (e.g., when) each of i2, j2, k2, l2, and m2 is 0, the fused polycyclic compound according to one or more embodiments may not be substituted with Rᵢ₂, Rⱼ₂, Rₖ₂, Rₗ₂, and Rₘ₂. In Formula 3, at least one of i2, j2, k2, l2, or m2 may be 1. For example, one, two, three, or four selected from among i2, j2, k2, l2, and m2 may each be 1. For example, in the fused polycyclic compound according to one or more embodiments, a fused cyclic core may be substituted with one, two, three, or four substituents selected from among Rᵢ₂, Rⱼ₂, Rₖ₂, Rₗ₂, and Rₘ₂.

In Formula 3, for X₁ to X₆, the same content as described in Formula 1 may be applied.

In one or more embodiments, the first compound represented by Formula 1 may be represented by Formula 4. The fused polycyclic compound according to one or more embodiments may be represented by Formula 4.

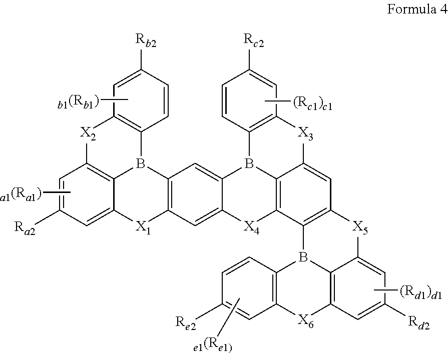

In Formula 4, Rₐ₁, Rₐ₂, R_{b1}, R_{b2}, R_{c1}, R_{c2}, R_{d1}, R_{d2}, Rₑ₁, and Rₑ₂ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Rₐ₁, Rₐ₂, R_{b1}, R_{b2}, R_{c1}, R_{c2}, R_{d1}, R_{d2}, Rₑ₁, and Rₑ₂ may each independently be hydrogen, deuterium, a substituted or unsubstituted methyl group, a substituted or unsubstituted t-butyl group, a substituted or unsubstituted phenyl group, or a substituted or unsubstituted carbazole group.

In one or more embodiments, Rₐ₁, Rₐ₂, R_{b1}, R_{b2}, R_{c1}, R_{c2}, R_{d1}, R_{d2}, Rₑ₁, and Rₑ₂ may each independently be hydrogen or deuterium. For example, in one or more embodiments, all of Rₐ₁, Rₐ₂, R_{b1}, R_{b2}, R_{c1}, R_{c2}, R_{d1}, R_{d2}, Rₑ₁, and Rₑ₂ may be hydrogens. However, embodiments of the present disclosure are not limited thereto, for example, in one or more embodiments, at least one of Rₐ₁, Rₐ₂, R_{b1}, R_{b2}, R_{c1}, R_{c2}, R_{d1}, R_{d2}, Rₑ₁, or Rₑ₂ may be deuterium.

In one or more embodiments, at least one of Rₐ₂, R_{b2}, R_{c2}, R_{d2}, or Rₑ₂ may be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, at least one of Rₐ₂, R_{b2}, R_{c2}, R_{d2}, and Rₑ₂ may be a substituted or unsubstituted methyl group, a substituted or unsubstituted t-butyl group, or a substituted or unsubstituted phenyl group, or a substituted or unsubstituted carbazole group. If (e.g., when) at least one of Rₐ₂, R_{b2}, R_{c2}, R_{d2}, or Rₑ₂ is an alkyl group, an aryl group, and/or a heteroaryl group, Rₐ₁, R_{b1}, R_{c1}, R_{d1}, and Rₑ₁ may each be hydrogen or deuterium, but embodiments of the present disclosure are not limited thereto.

In Formula 4, a1 and d1 may each independently be an integer of 0 or greater and 2 or less, In Formula 4, if (e.g., when) each of a1 and d1 is 0, the fused polycyclic compound according to one or more embodiments may not be substituted with each of Rₐ₁ and R_{d1}. If (e.g., when) each of a1 and d1 is 2, and each of Rₐ₁ and R_{d1} is hydrogen, the embodiment may be the same as the embodiment in which each of a1 and d1 is 0. If (e.g., when) each of a1 and d1 is an integer of 2, Rₐ₁ and R_{d1} each provided in plurality may be the same as each other, or at least one selected from among Rₐ₁ and R_{d1} each in plurality may be different.

In Formula 4, b1, c1, and e1 may each independently be an integer of 0 or greater and 3 or less. In Formula 4, if (e.g., when) each of b1, c1, and e1 is 0, the fused polycyclic compound according to one or more embodiments may not be substituted with each of R_{b1}, R_{c1}, and Rₑ₁. If (e.g., when) each of b1, c1, and e1 is 3, and each of R_{b1}, R_{c1}, and Rₑ₁ is hydrogen, the embodiment may be the same as the embodiment in which each of b1, c1, and e1 is 0. If (e.g., when) each of b1, c1, and e1 is an integer of 2 or greater, R_{b1}, R_{c1}, and Rₑ₁ each provided in plurality may be the same as each other, or at least one selected from among R_{b1}, R_{c1}, and Rₑ₁ each in plurality may be different.

In Formula 4, for X₁ to X₆, the same content as described in Formula 1 may be applied.

In one or more embodiments, at least one of hydrogens in the first compound may be substituted with deuterium. The fused polycyclic compound according to one or more embodiments, represented by each of Formula 1, Formula 2, Formula 3, and Formula 4, may include at least one deuterium as a substituent.

The fused polycyclic compound according to one or more embodiments may be any one selected from among compounds listed in Compound Group 1. The at least one functional layer included in the light-emitting element ED according to one or more embodiments may include at least one fused polycyclic compound selected from among the compounds listed in Compound Group 1. The light-emitting element ED according to one or more embodiments may include at least one fused polycyclic compound selected from among the compounds listed in Compound Group 1 in the emission layer EML.

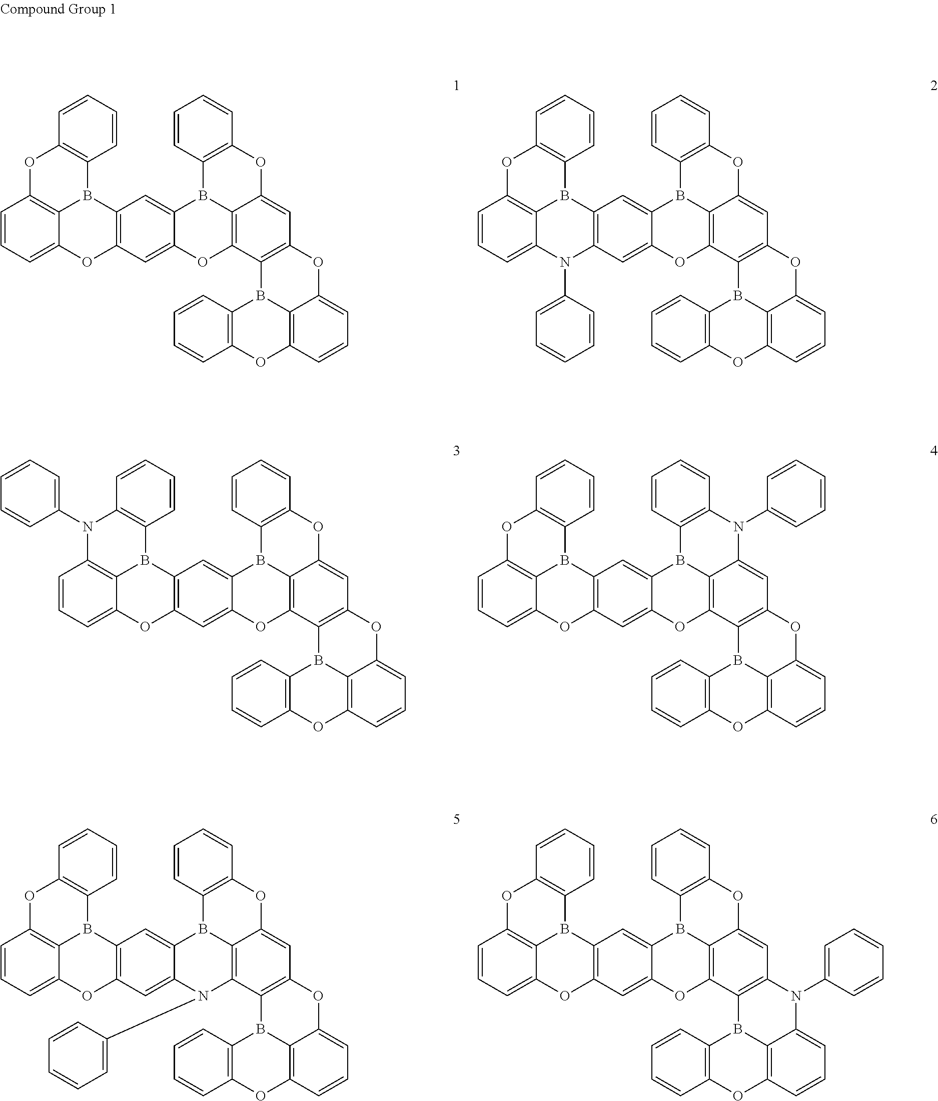

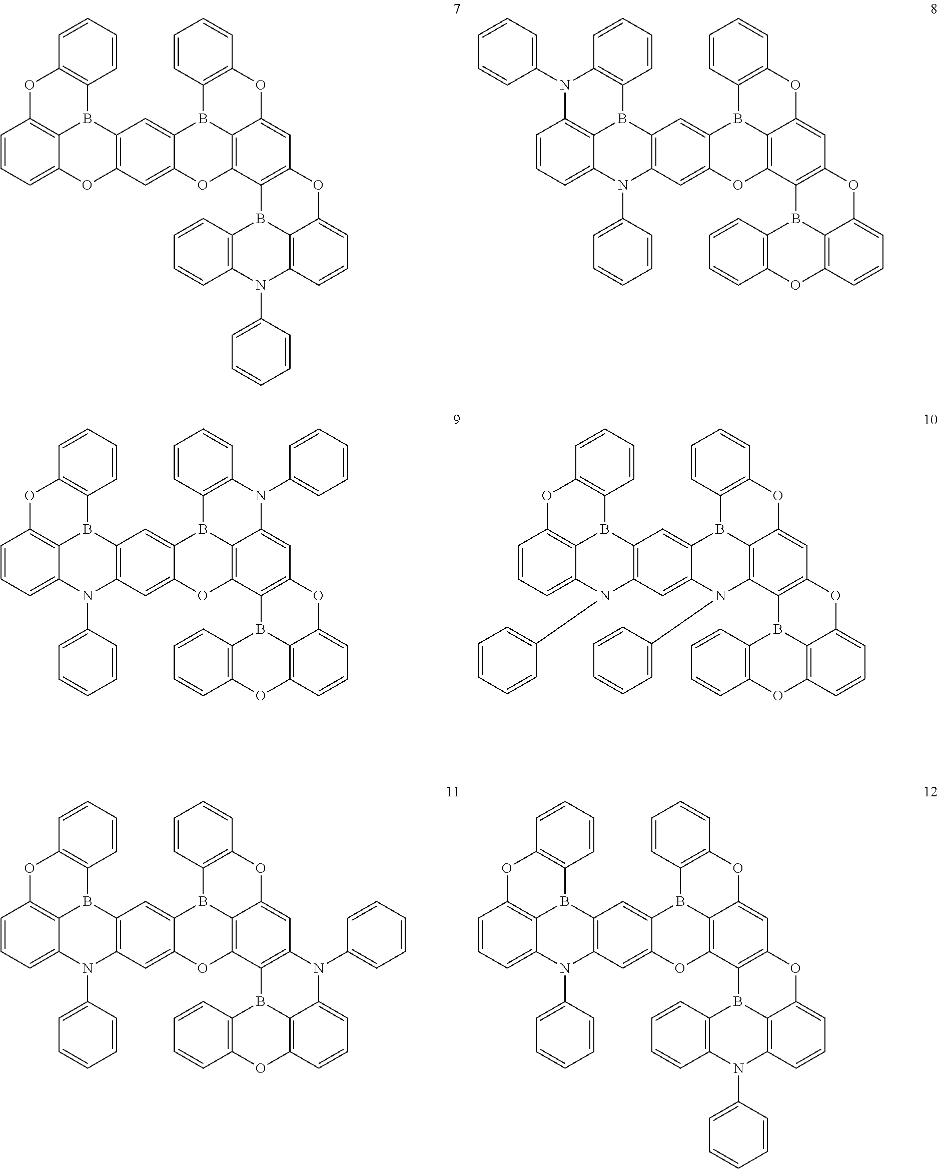

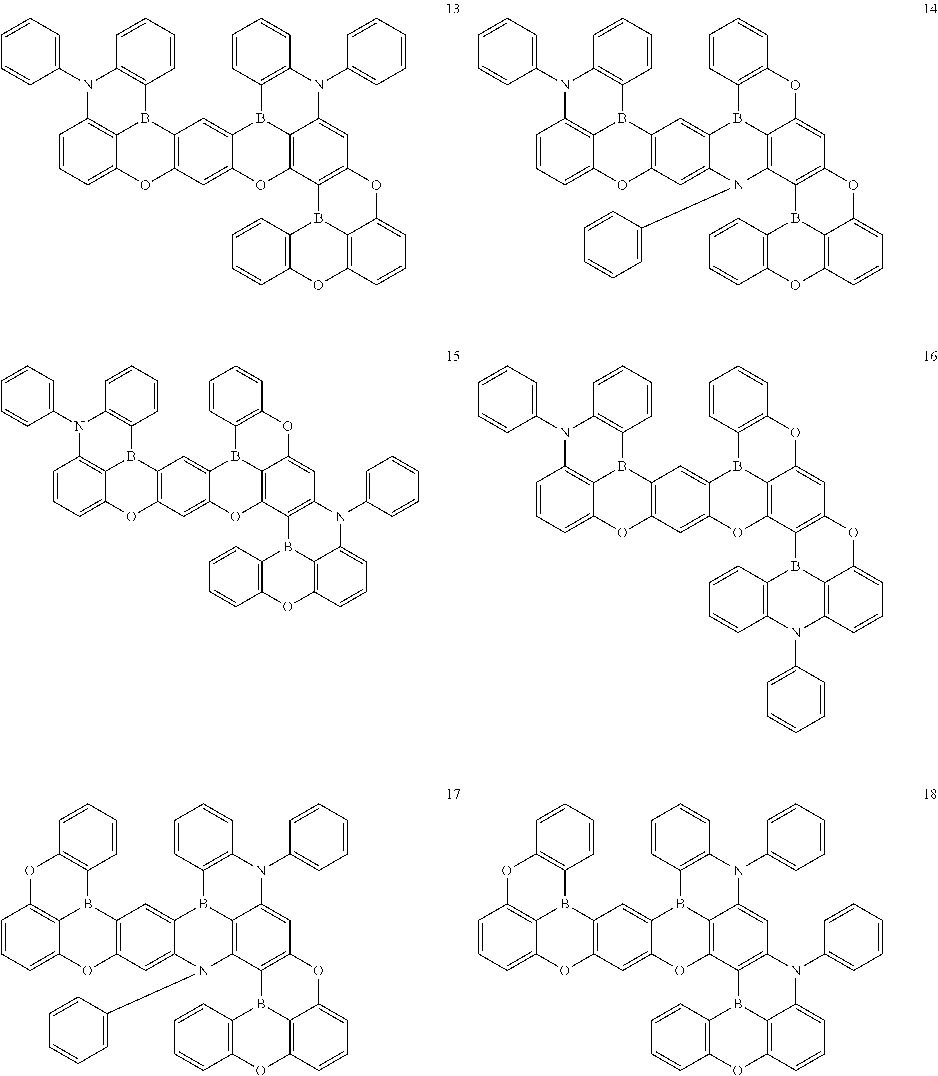

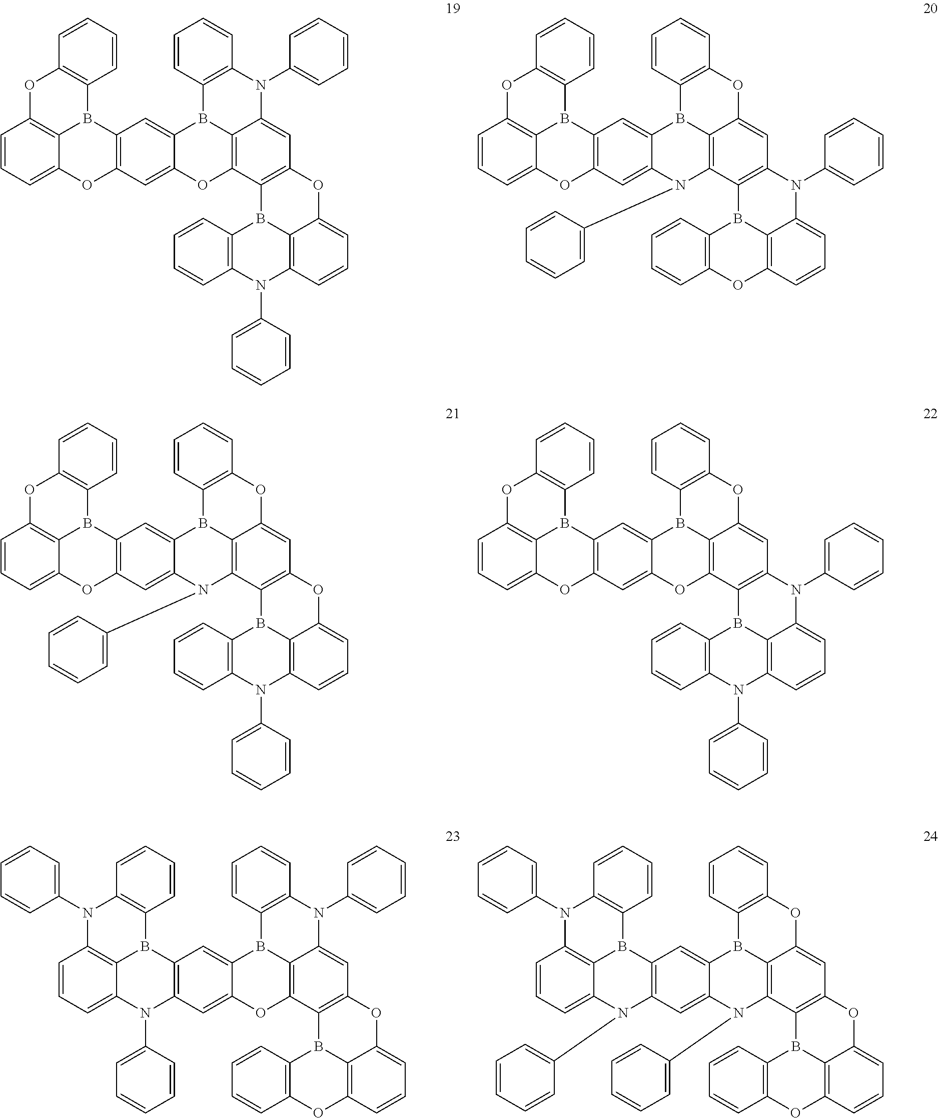

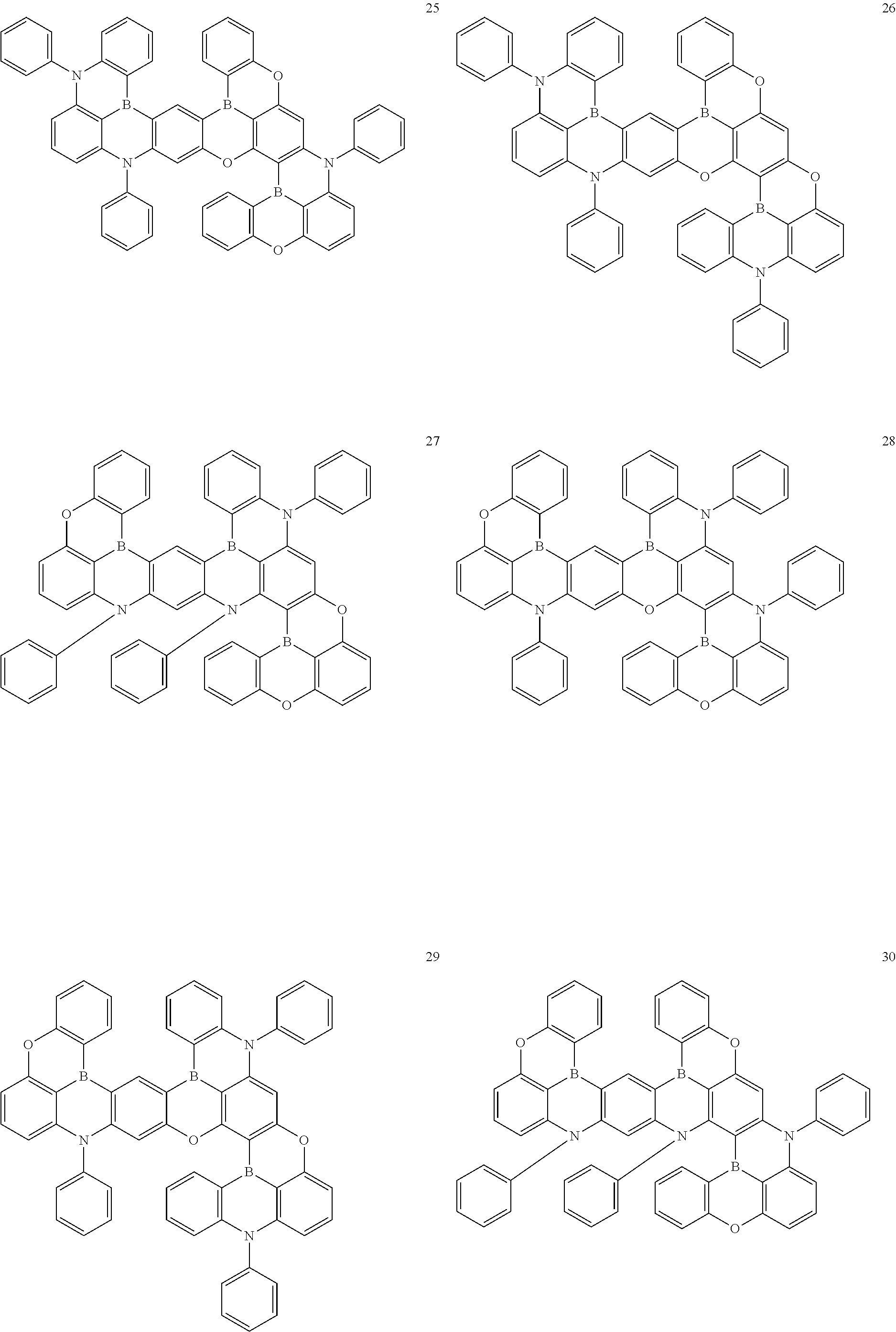

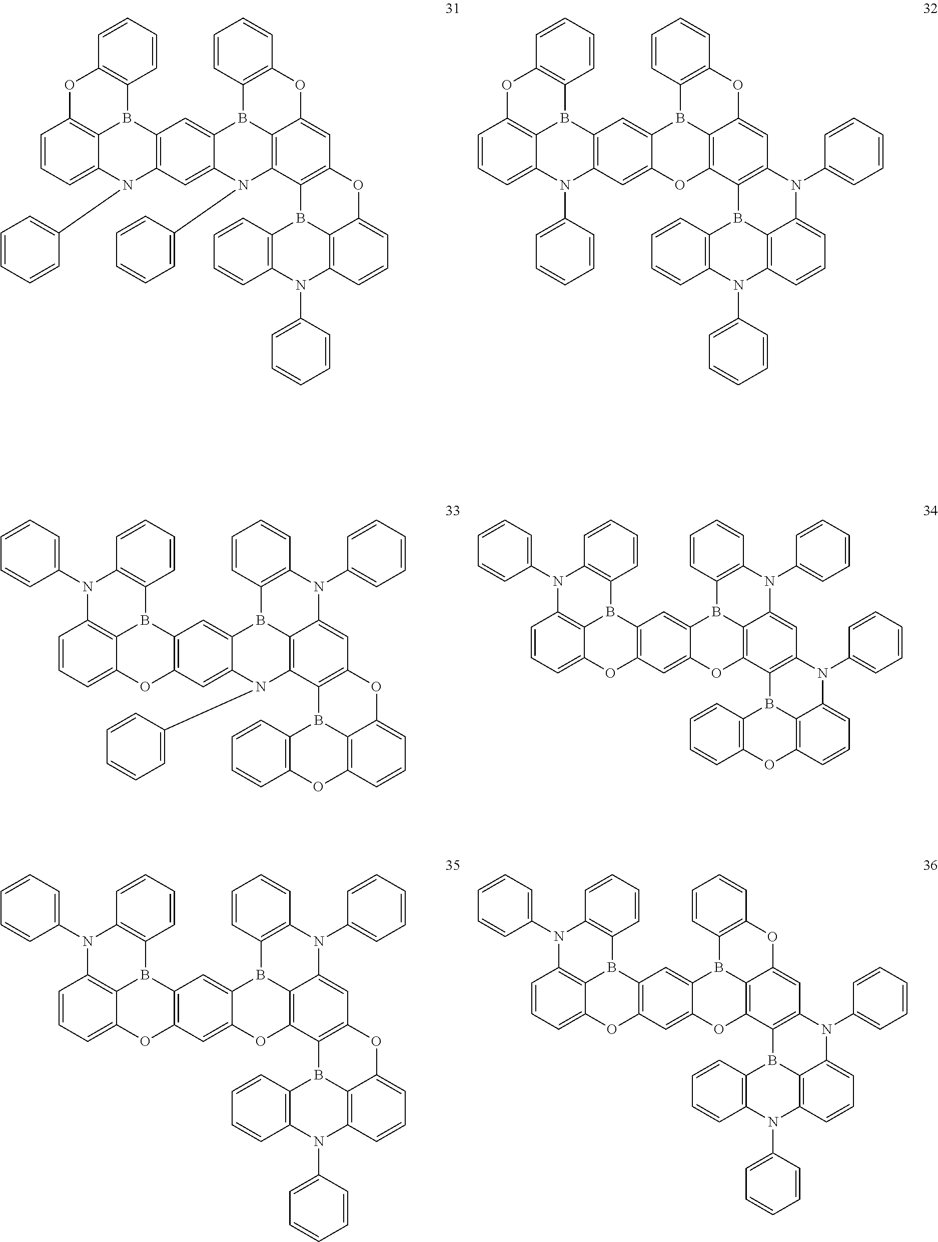

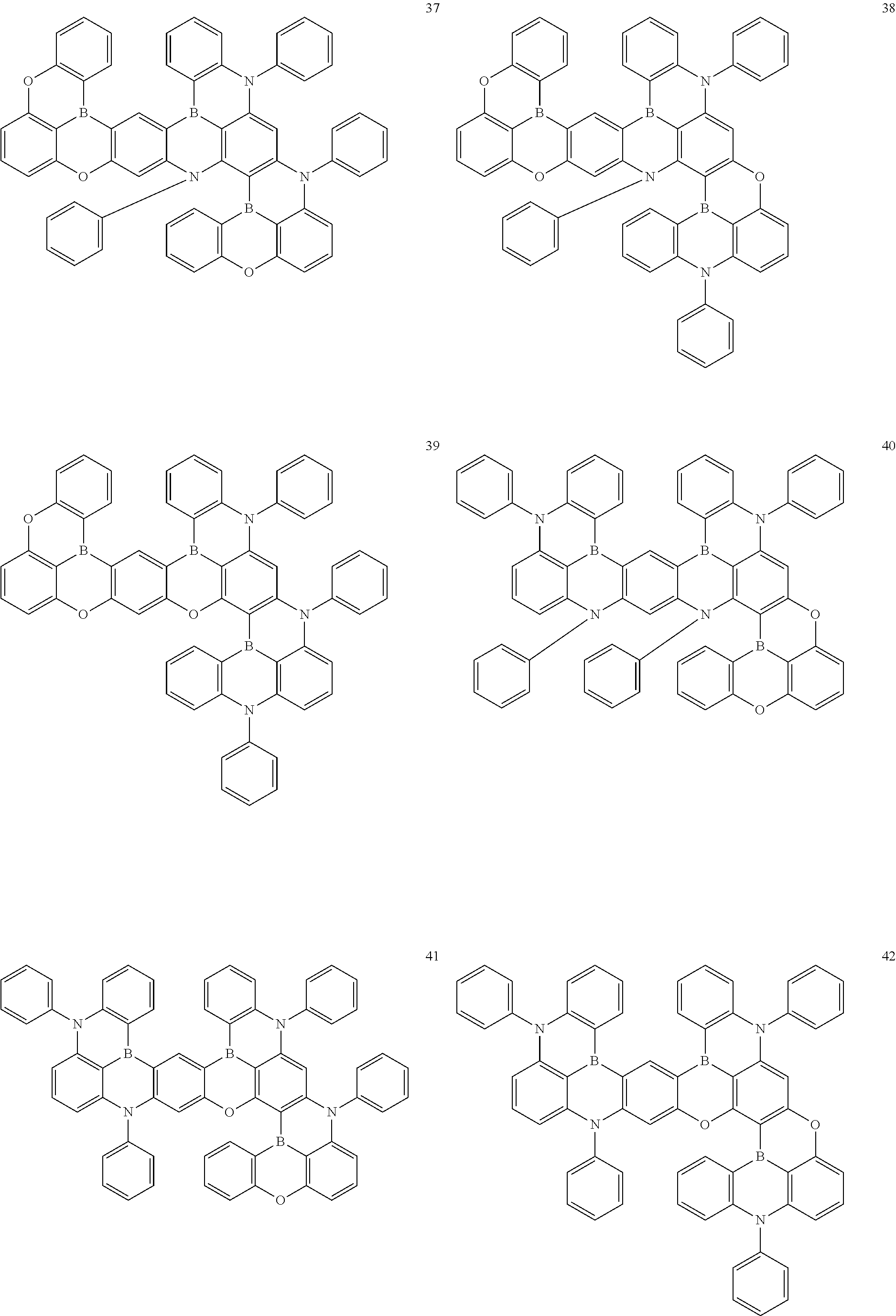

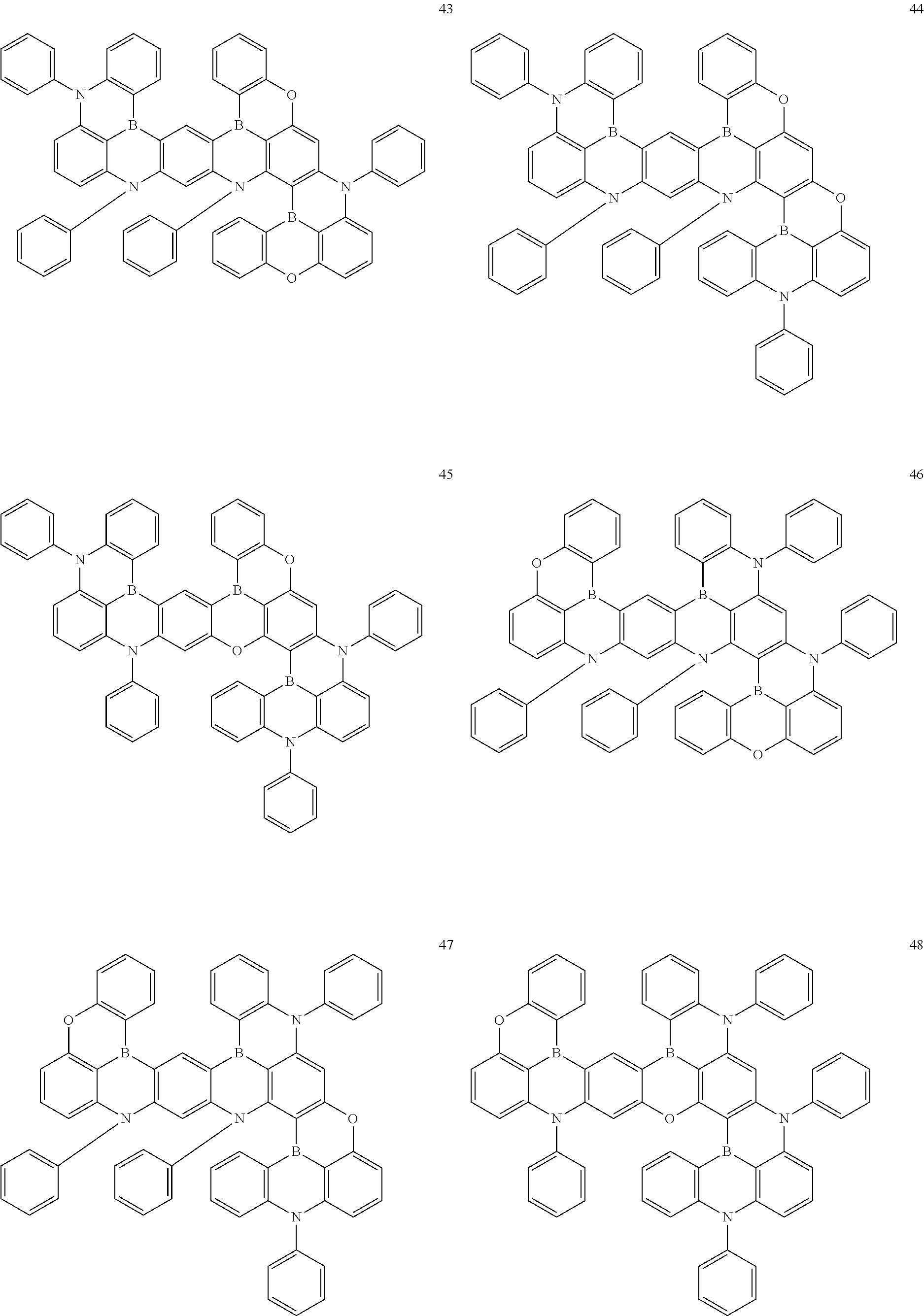

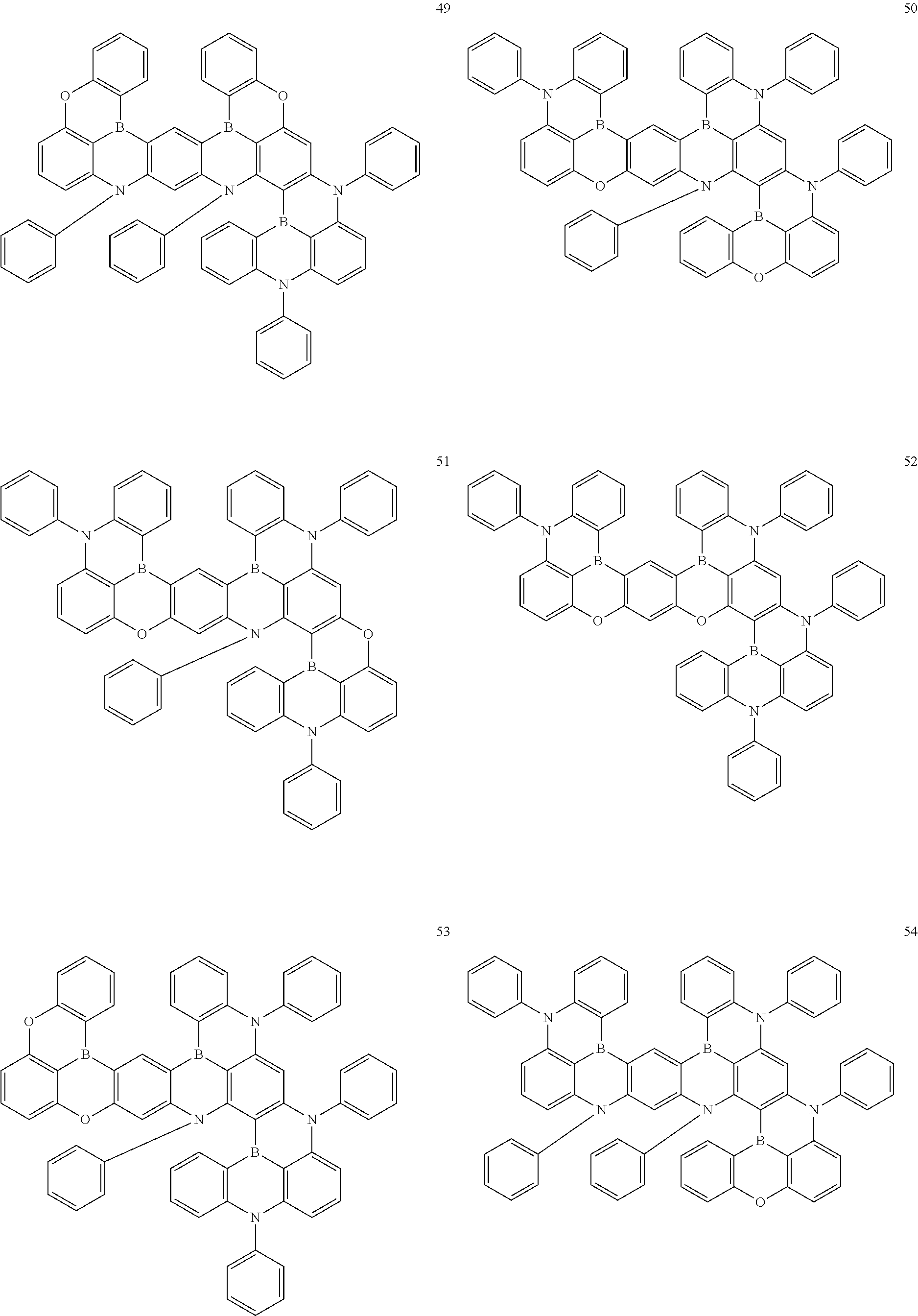

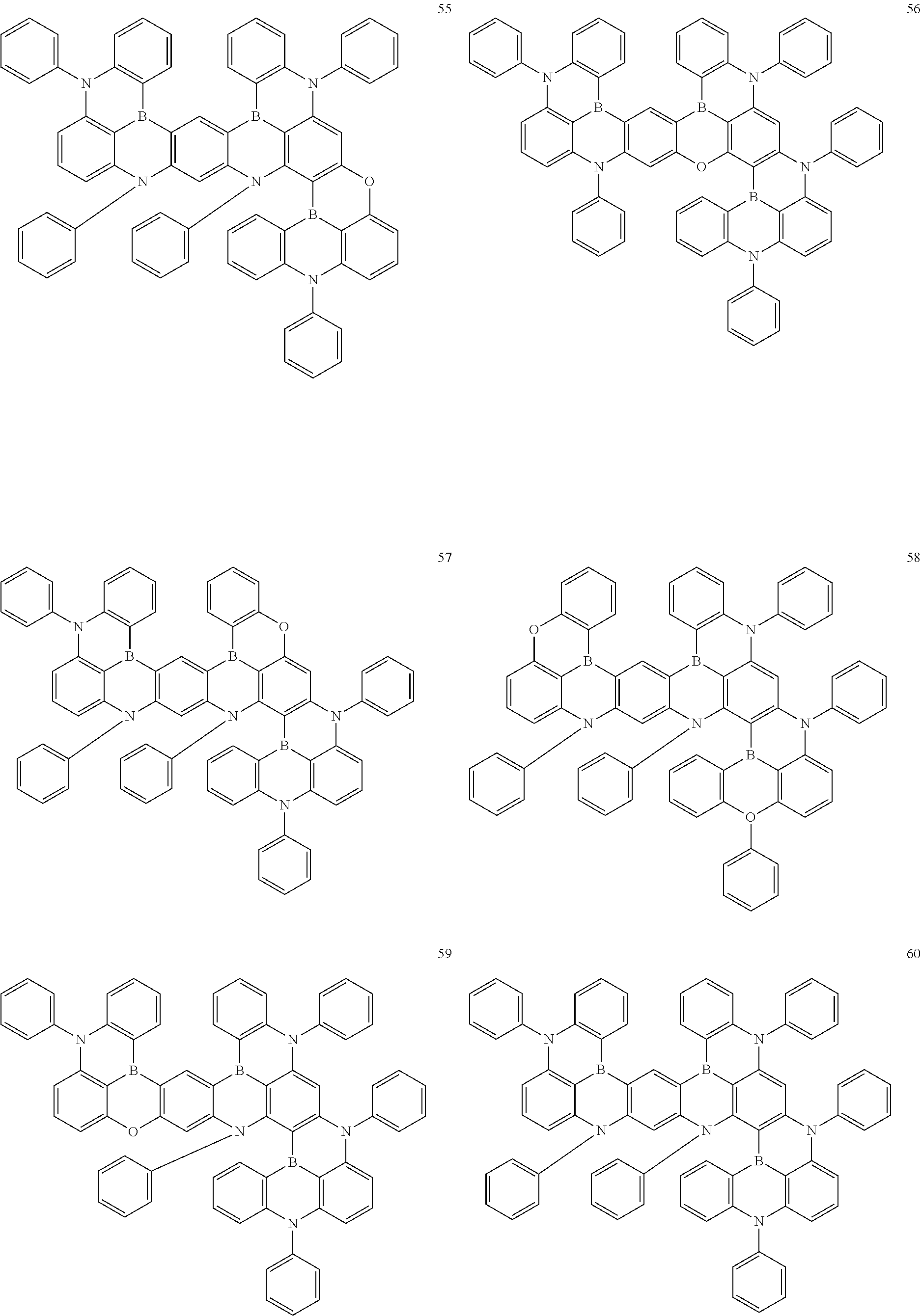

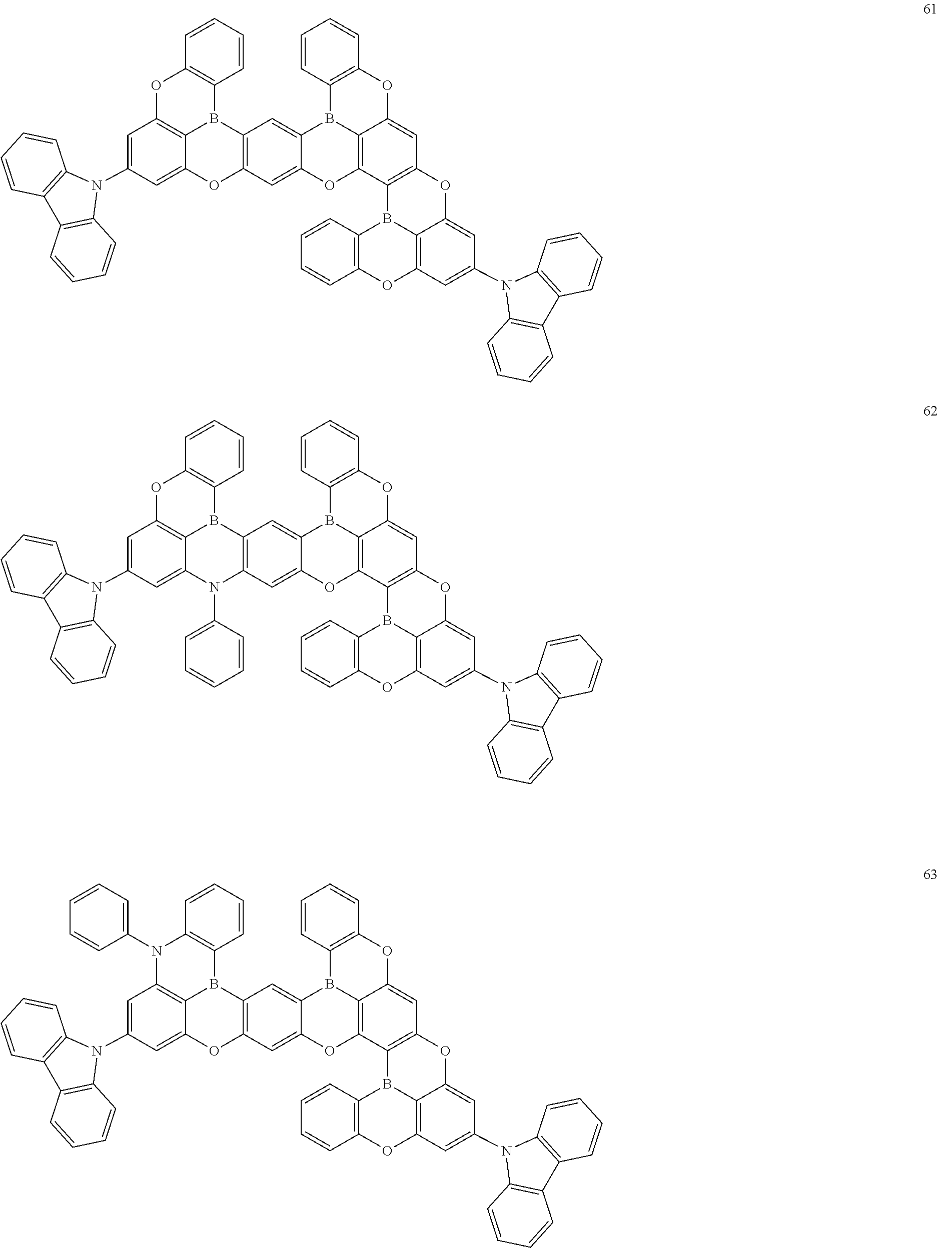 [SMILES: c1ccc2c(c1)Oc1cc(-n3c4ccccc4c4ccccc43)cc3c1B2c1cc2c(cc1O3)Oc1c3c(cc4c1B1c5ccccc5Oc5cc(-n6c7ccccc7c7ccccc76)cc(c51)O4)Oc1ccccc1B23 ; c1ccc(N2c3cc4c(cc3B3c5ccccc5Oc5cc(-n6c7ccccc7c7ccccc76)cc2c53)B2c3ccccc3Oc3cc5c(c(c32)O4)B2c3ccccc3Oc3cc(-n4c6ccccc6c6ccccc64)cc(c32)O5)cc1 ; c1ccc(N2c3ccccc3B3c4cc5c(cc4Oc4cc(-n6c7ccccc7c7ccccc76)cc2c43)Oc2c3c(cc4c2B2c6ccccc6Oc6cc(-n7c8ccccc8c8ccccc87)cc(c62)O4)Oc2ccccc2B53)cc1]

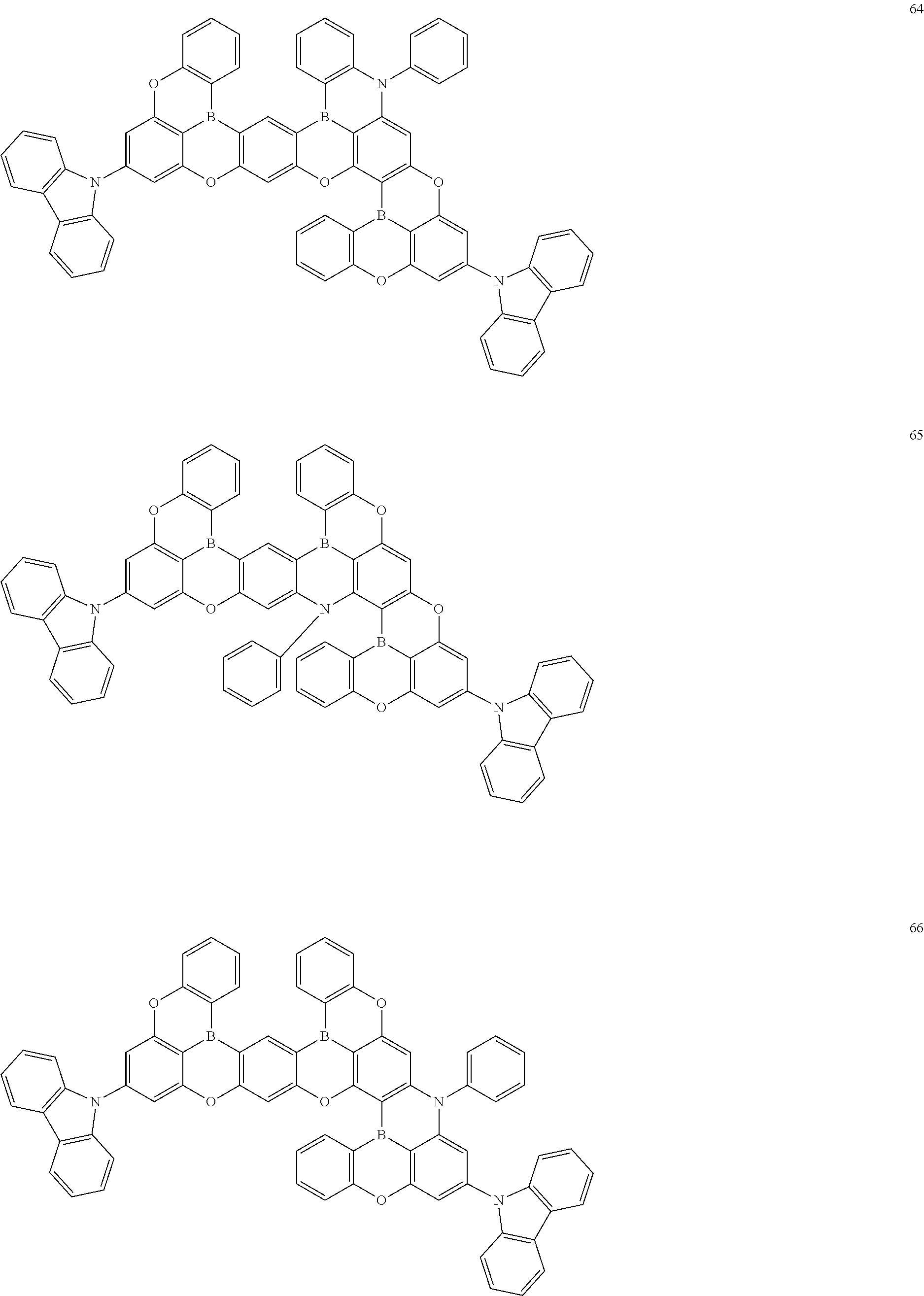 [SMILES: c1ccc(N2c3ccccc3B3c4cc5c(cc4Oc4c6c(cc2c43)Oc2cc(-n3c4ccccc4c4ccccc43)cc3c2B6c2ccccc2O3)Oc2cc(-n3c4ccccc4c4ccccc43)cc3c2B5c2ccccc2O3)cc1 ; c1ccc(N2c3cc4c(cc3B3c5ccccc5Oc5cc6c(c2c53)B2c3ccccc3Oc3cc(-n5c7ccccc7c7ccccc75)cc(c32)O6)B2c3ccccc3Oc3cc(-n5c6ccccc6c6ccccc65)cc(c32)O4)cc1 ; c1ccc(N2c3cc(-n4c5ccccc5c5ccccc54)cc4c3B(c3ccccc3O4)c3c2cc2c4c3Oc3cc5c(cc3B4c3ccccc3O2)B2c3ccccc3Oc3cc(-n4c6ccccc6c6ccccc64)cc(c32)O5)cc1]

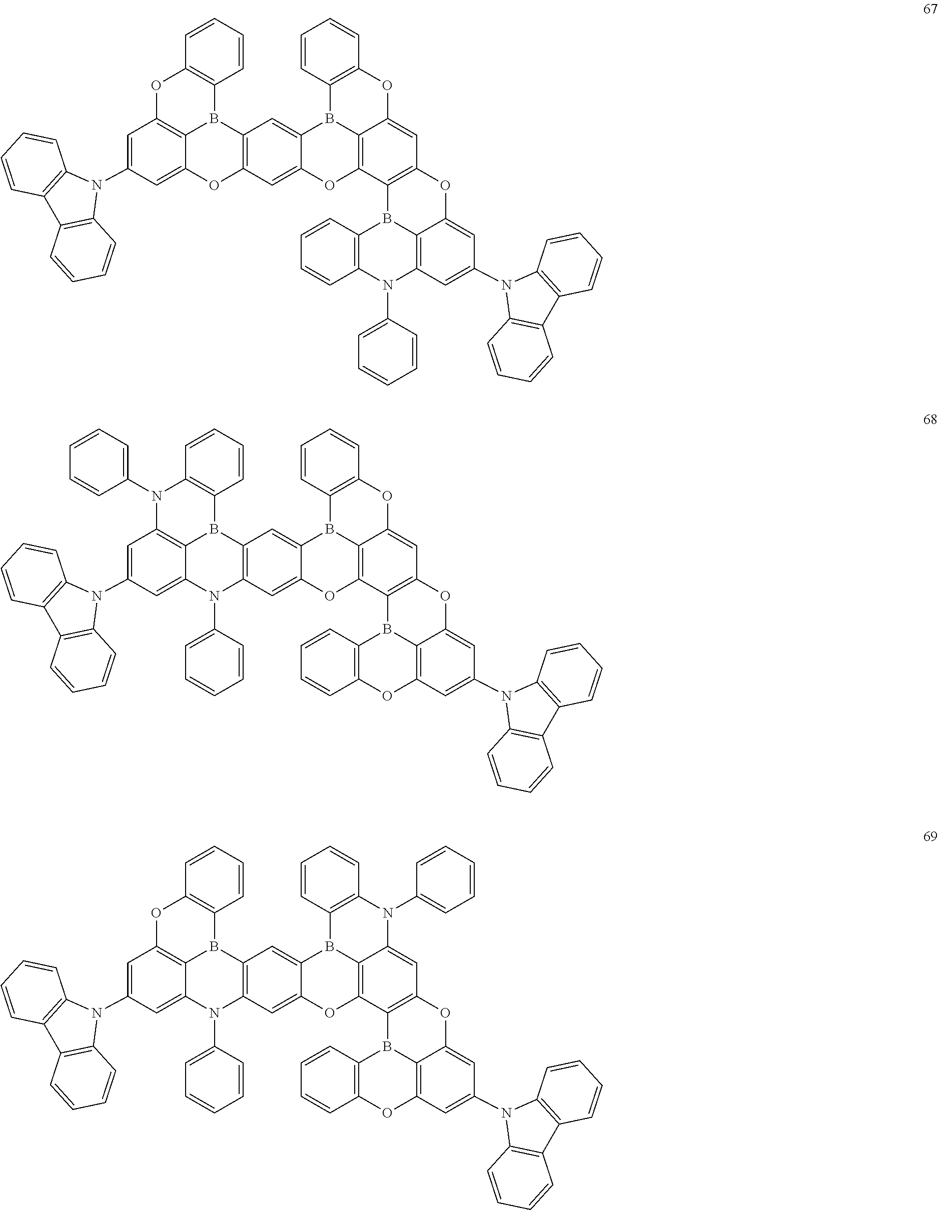 [SMILES: c1ccc(N2c3ccccc3B3c4c(cc(-n5c6ccccc6c6ccccc65)cc42)Oc2cc4c5c(c23)Oc2cc3c(cc2B5c2ccccc2O4)B2c4ccccc4Oc4cc(-n5c6ccccc6c6ccccc65)cc(c42)O3)cc1 ; c1ccc(N2c3ccccc3B3c4cc5c(cc4N(c4ccccc4)c4cc(-n6c7ccccc7c7ccccc76)cc2c43)Oc2c3c(cc4c2B2c6ccccc6Oc6cc(-n7c8ccccc8c8ccccc87)cc(c62)O4)Oc2ccccc2B53)cc1 ; c1ccc(N2c3cc4c(cc3B3c5ccccc5Oc5cc(-n6c7ccccc7c7ccccc76)cc2c53)B2c3ccccc3N(c3ccccc3)c3cc5c(c(c32)O4)B2c3ccccc3Oc3cc(-n4c6ccccc6c6ccccc64)cc(c32)O5)cc1]

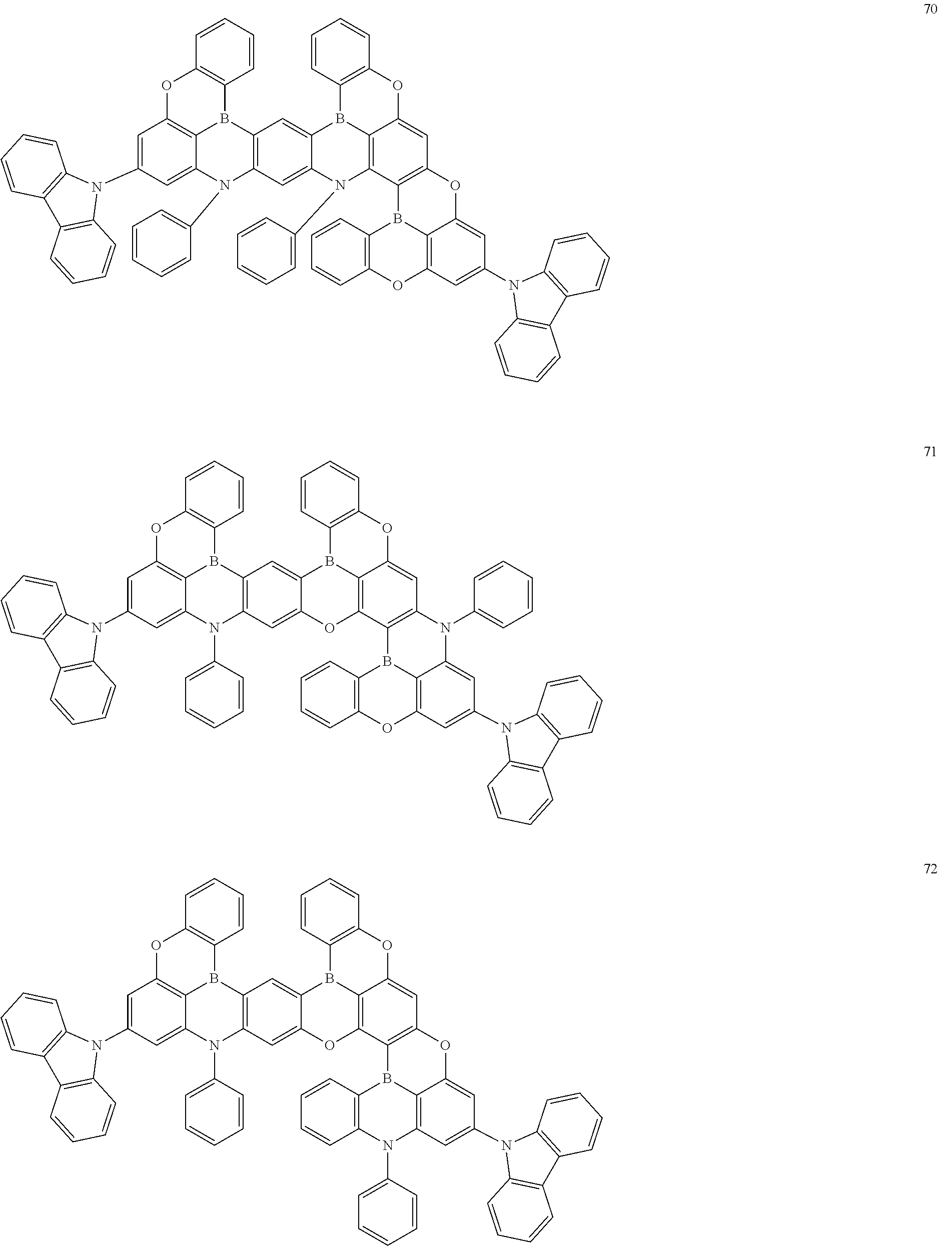 [SMILES: c1ccc(N2c3cc4c(cc3B3c5ccccc5Oc5cc(-n6c7ccccc7c7ccccc76)cc2c53)B2c3ccccc3Oc3cc5c(c(c32)N4c2ccccc2)B2c3ccccc3Oc3cc(-n4c6ccccc6c6ccccc64)cc(c32)O5)cc1 ; c1ccc(N2c3cc4c(cc3B3c5ccccc5Oc5cc(-n6c7ccccc7c7ccccc76)cc2c53)B2c3ccccc3Oc3cc5c(c(c32)O4)B2c3ccccc3Oc3cc(-n4c6ccccc6c6ccccc64)cc(c32)N5c2ccccc2)cc1 ; c1ccc(N2c3cc4c(cc3B3c5ccccc5Oc5cc(-n6c7ccccc7c7ccccc76)cc2c53)B2c3ccccc3Oc3cc5c(c(c32)O4)B2c3ccccc3N(c3ccccc3)c3cc(-n4c6ccccc6c6ccccc64)cc(c32)O5)cc1]

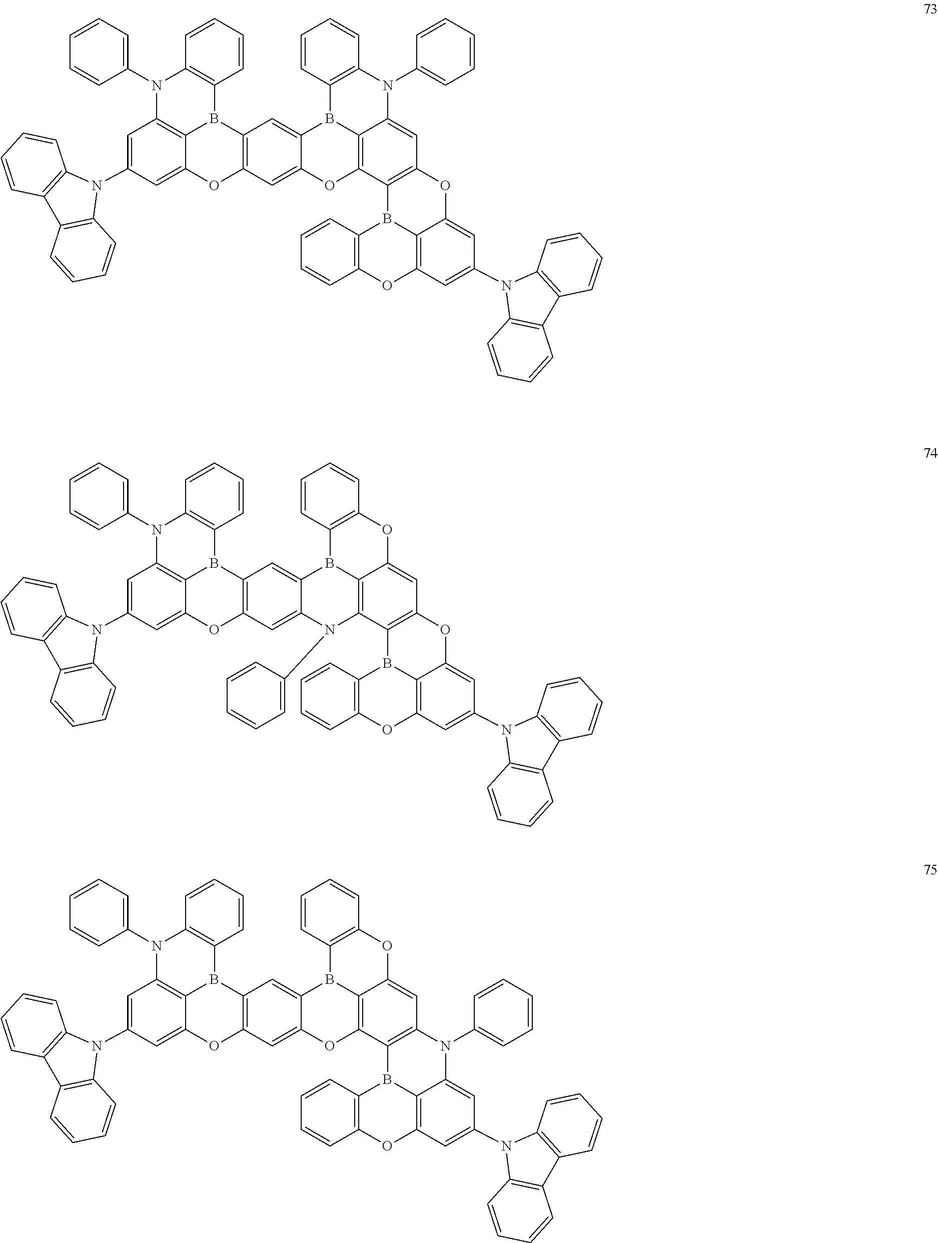 [SMILES: c1ccc(N2c3ccccc3B3c4cc5c(cc4Oc4cc(-n6c7ccccc7c7ccccc76)cc2c43)Oc2c3c(cc4c2B5c2ccccc2N4c2ccccc2)Oc2cc(-n4c5ccccc5c5ccccc54)cc4c2B3c2ccccc2O4)cc1 ; c1ccc(N2c3ccccc3B3c4cc5c(cc4Oc4cc(-n6c7ccccc7c7ccccc76)cc2c43)N(c2ccccc2)c2c3c(cc4c2B2c6ccccc6Oc6cc(-n7c8ccccc8c8ccccc87)cc(c62)O4)Oc2ccccc2B53)cc1 ; c1ccc(N2c3ccccc3B3c4cc5c(cc4Oc4cc(-n6c7ccccc7c7ccccc76)cc2c43)Oc2c3c(cc4c2B2c6ccccc6Oc6cc(-n7c8ccccc8c8ccccc87)cc(c62)N4c2ccccc2)Oc2ccccc2B53)cc1]

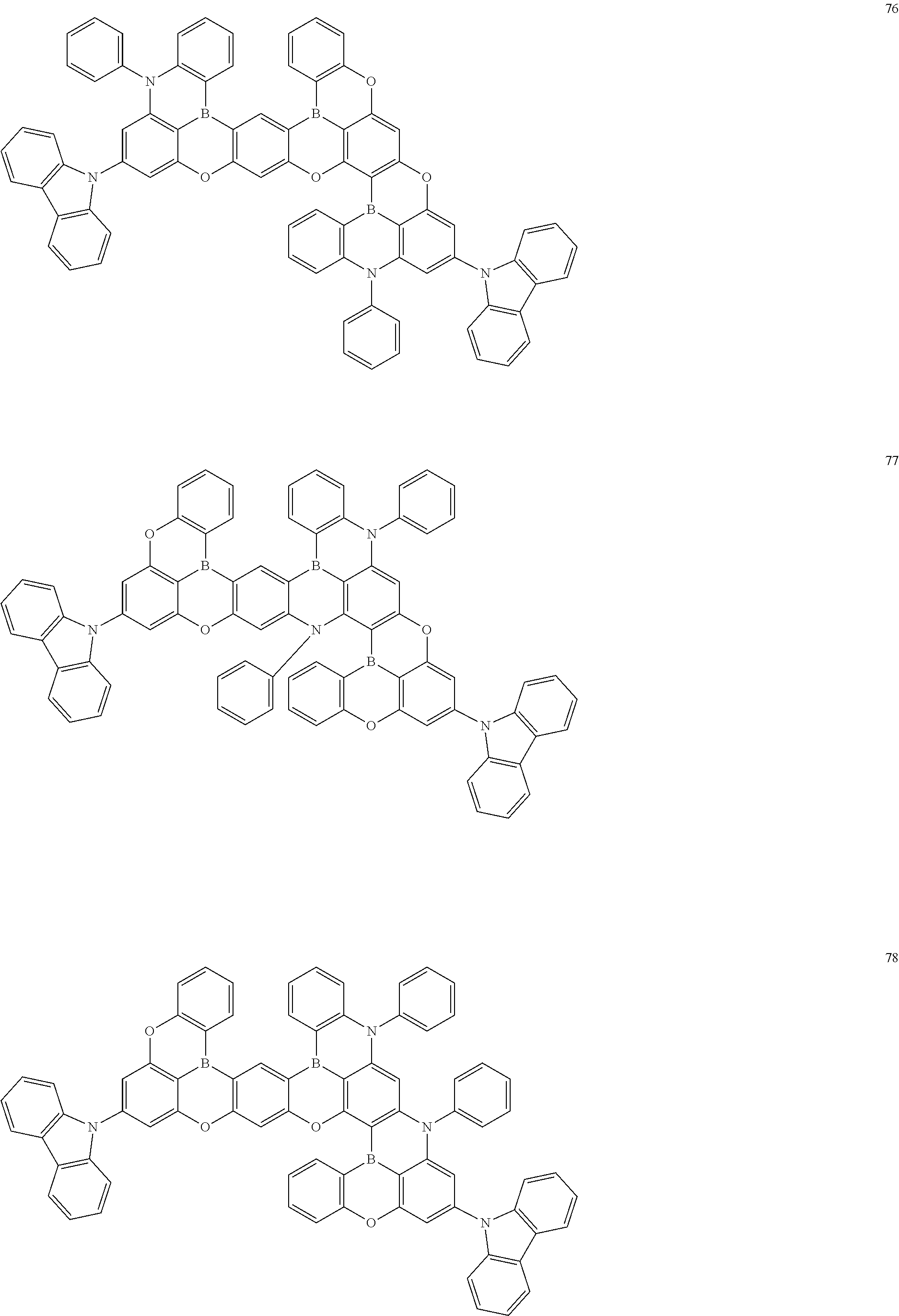 [SMILES: c1ccc(N2c3ccccc3B3c4cc5c(cc4Oc4cc(-n6c7ccccc7c7ccccc76)cc2c43)Oc2c3c(cc4c2B2c6ccccc6N(c6ccccc6)c6cc(-n7c8ccccc8c8ccccc87)cc(c62)O4)Oc2ccccc2B53)cc1 ; c1ccc(N2c3ccccc3B3c4cc5c(cc4N(c4ccccc4)c4c6c(cc2c43)Oc2cc(-n3c4ccccc4c4ccccc43)cc3c2B6c2ccccc2O3)Oc2cc(-n3c4ccccc4c4ccccc43)cc3c2B5c2ccccc2O3)cc1 ; c1ccc(N2c3ccccc3B3c4cc5c(cc4Oc4c3c2cc2c4B3c4ccccc4Oc4cc(-n6c7ccccc7c7ccccc76)cc(c43)N2c2ccccc2)Oc2cc(-n3c4ccccc4c4ccccc43)cc3c2B5c2ccccc2O3)cc1]

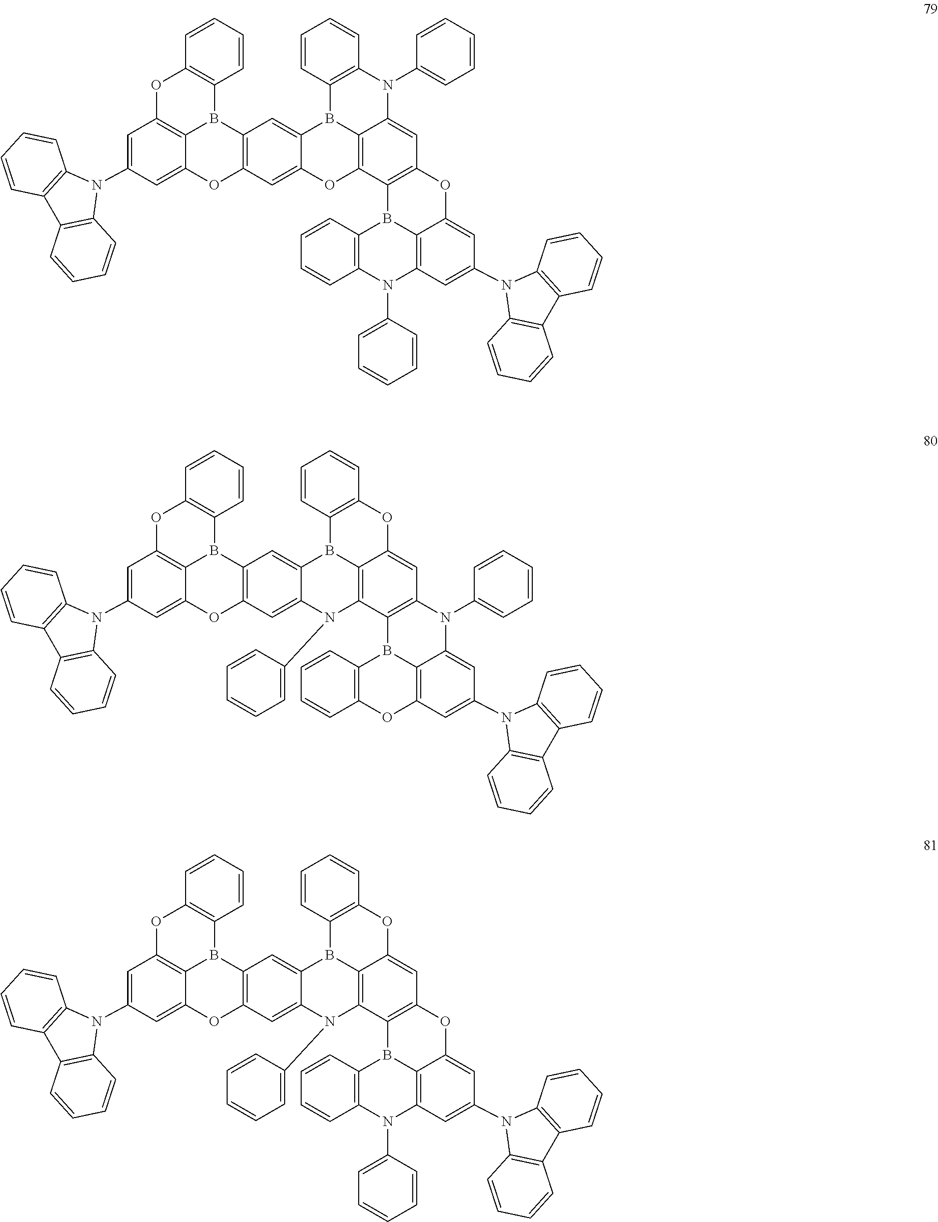

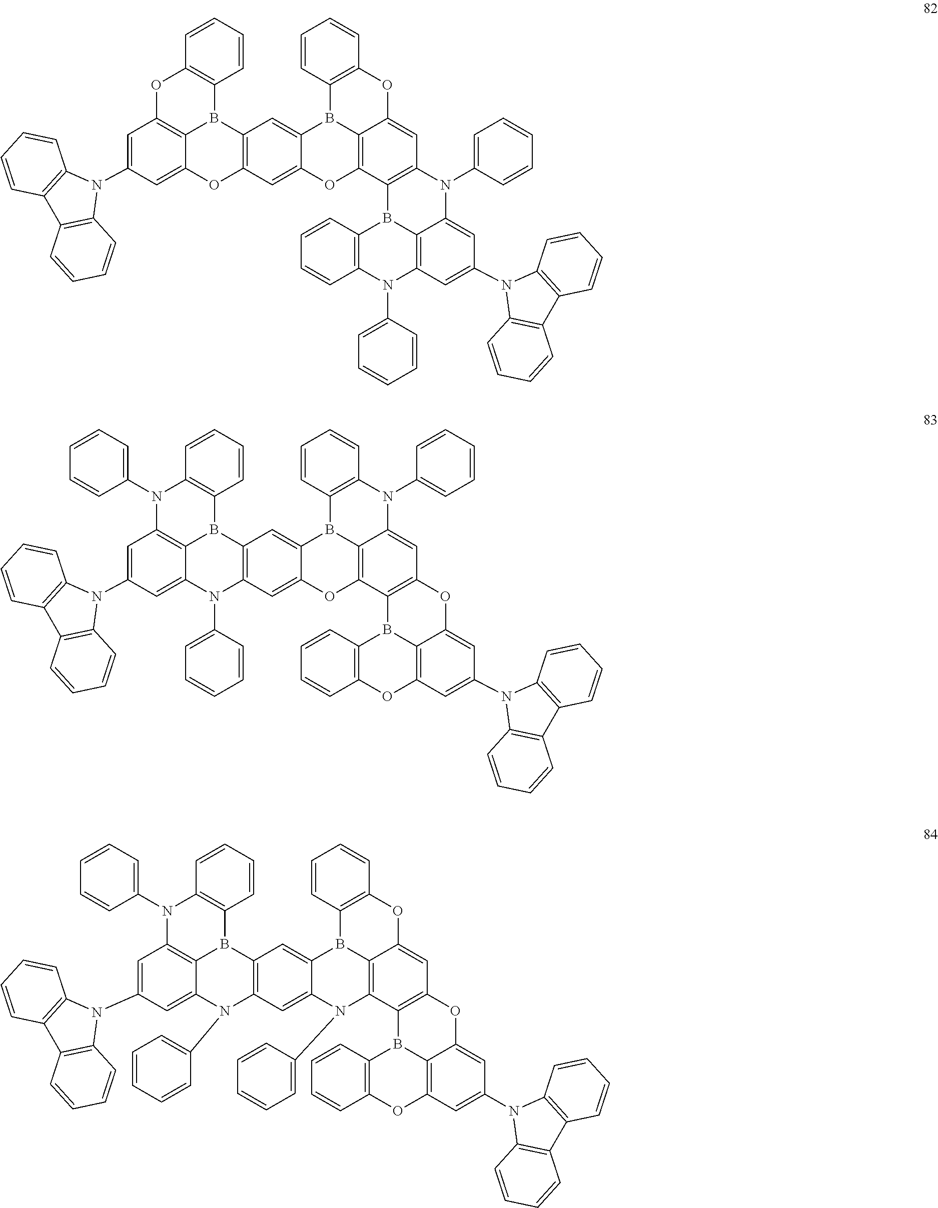 [SMILES: c1ccc(N2c3ccccc3B3c4c2cc(-n2c5ccccc5c5ccccc52)cc4N(c2ccccc2)c2cc4c5c(c23)Oc2cc3c(cc2B5c2ccccc2O4)B2c4ccccc4Oc4cc(-n5c6ccccc6c6ccccc65)cc(c42)O3)cc1 ; c1ccc(N2c3ccccc3B3c4cc5c(cc4N(c4ccccc4)c4cc(-n6c7ccccc7c7ccccc76)cc2c43)Oc2c3c(cc4c2B5c2ccccc2N4c2ccccc2)Oc2cc(-n4c5ccccc5c5ccccc54)cc4c2B3c2ccccc2O4)cc1 ; c1ccc(N2c3ccccc3B3c4cc5c(cc4N(c4ccccc4)c4cc(-n6c7ccccc7c7ccccc76)cc2c43)N(c2ccccc2)c2c3c(cc4c2B2c6ccccc6Oc6cc(-n7c8ccccc8c8ccccc87)cc(c62)O4)Oc2ccccc2B53)cc1]

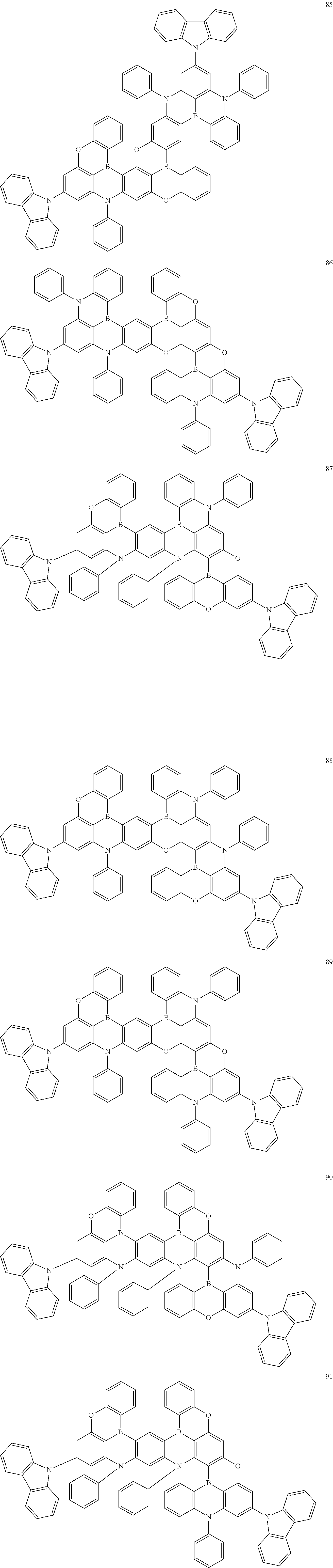

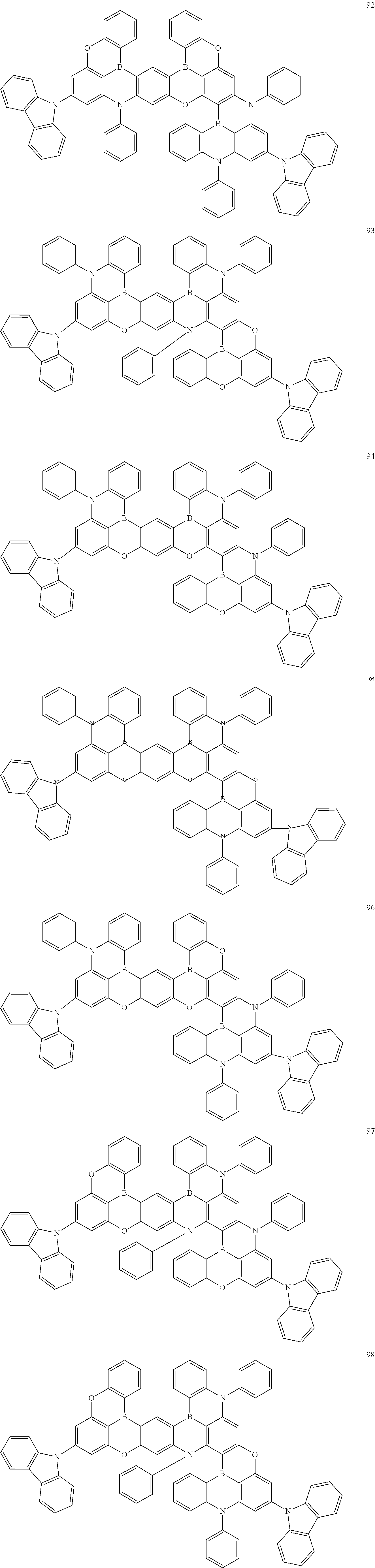

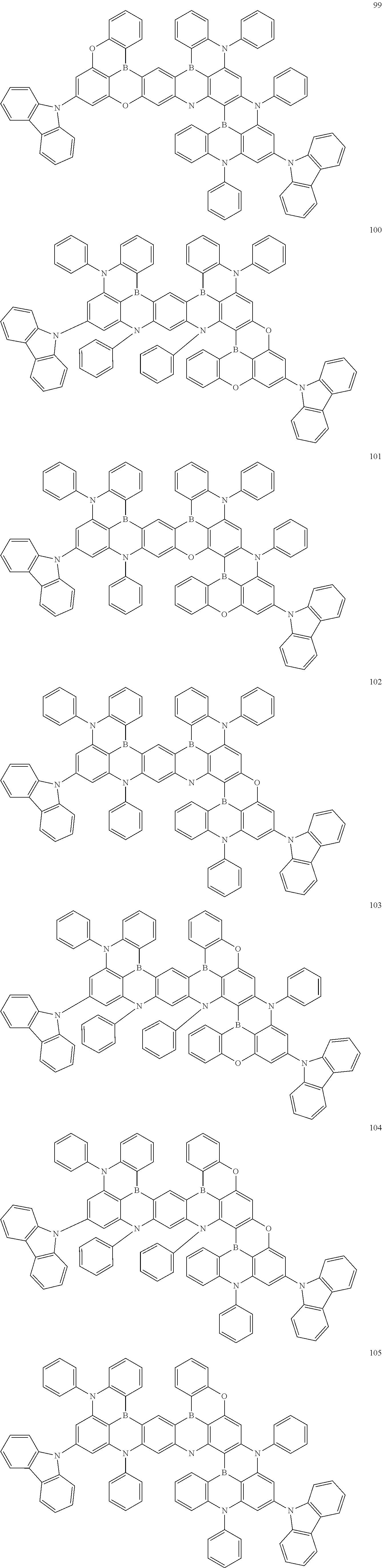

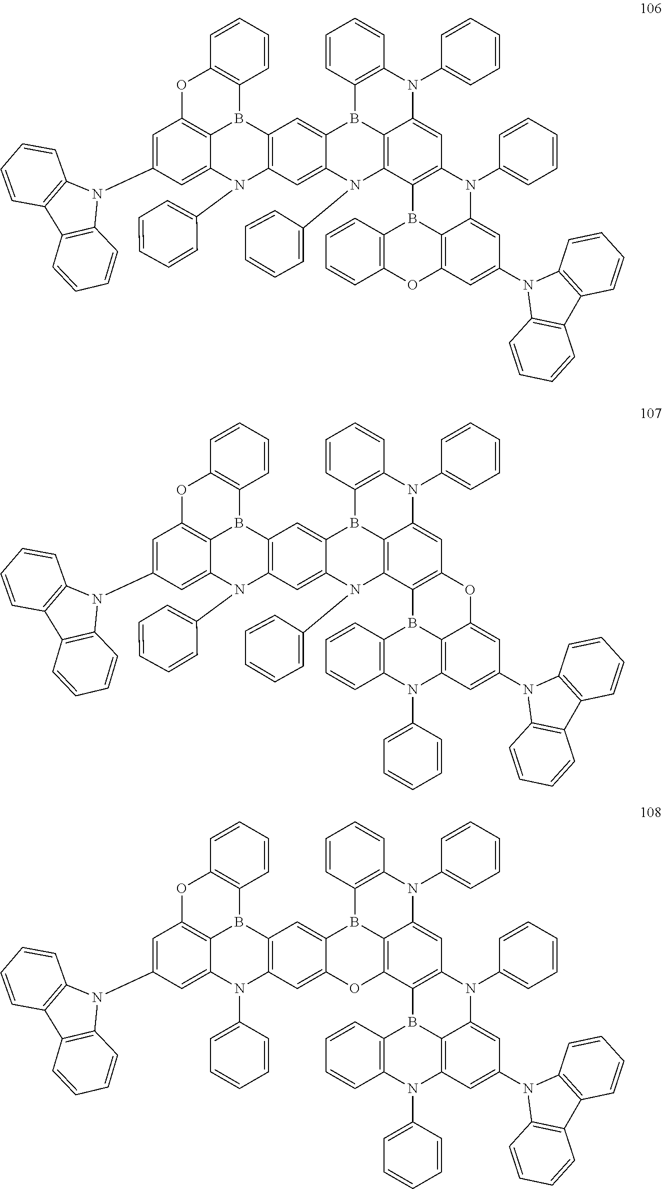

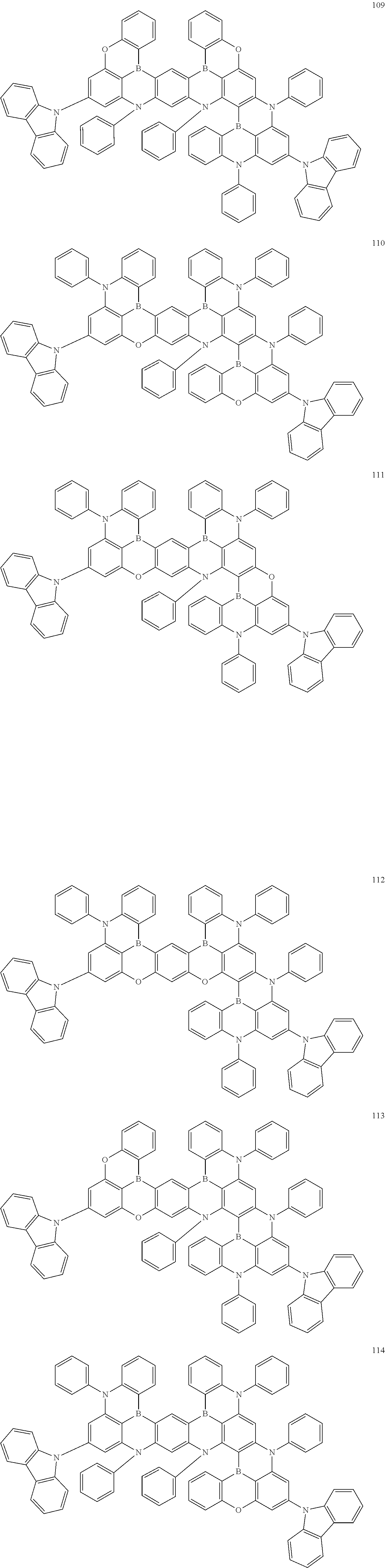

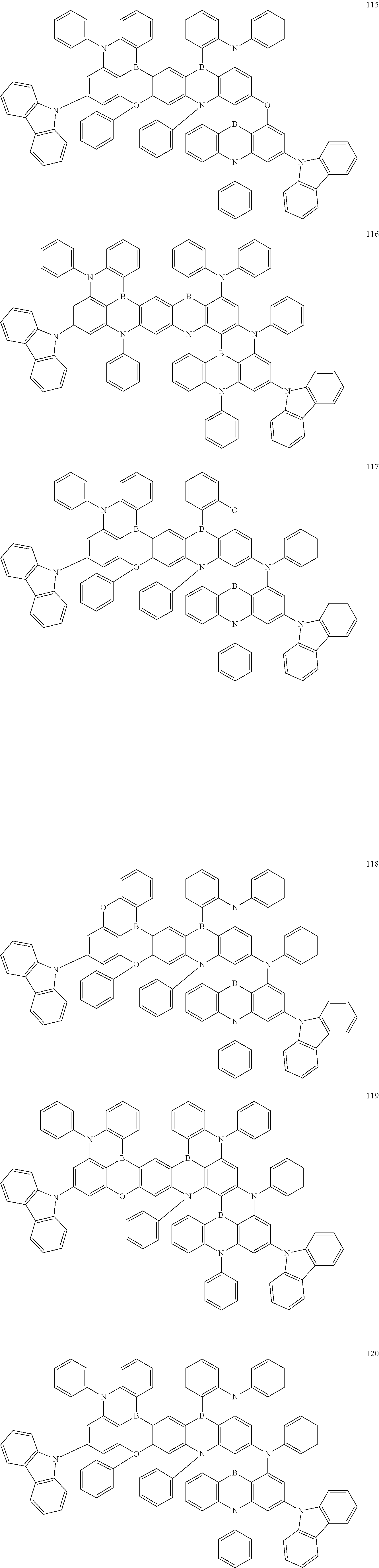

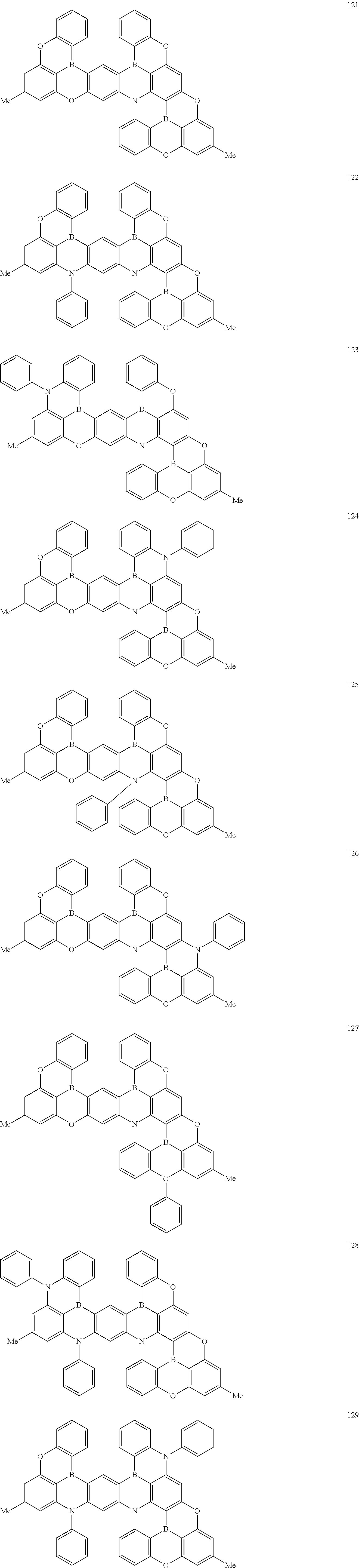

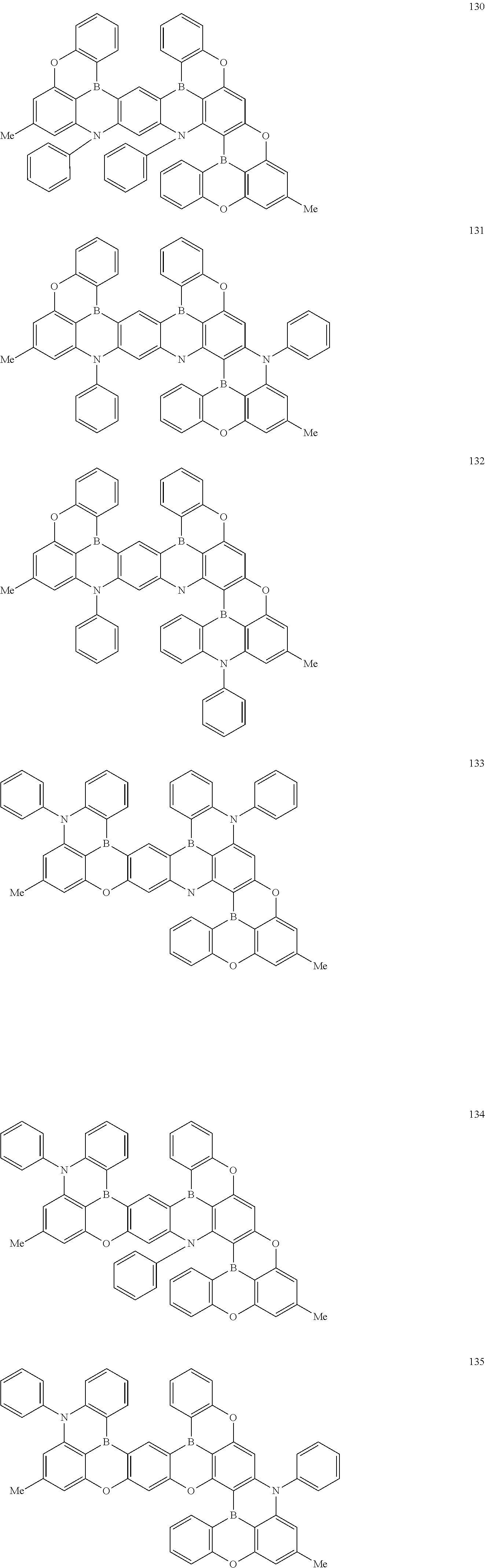

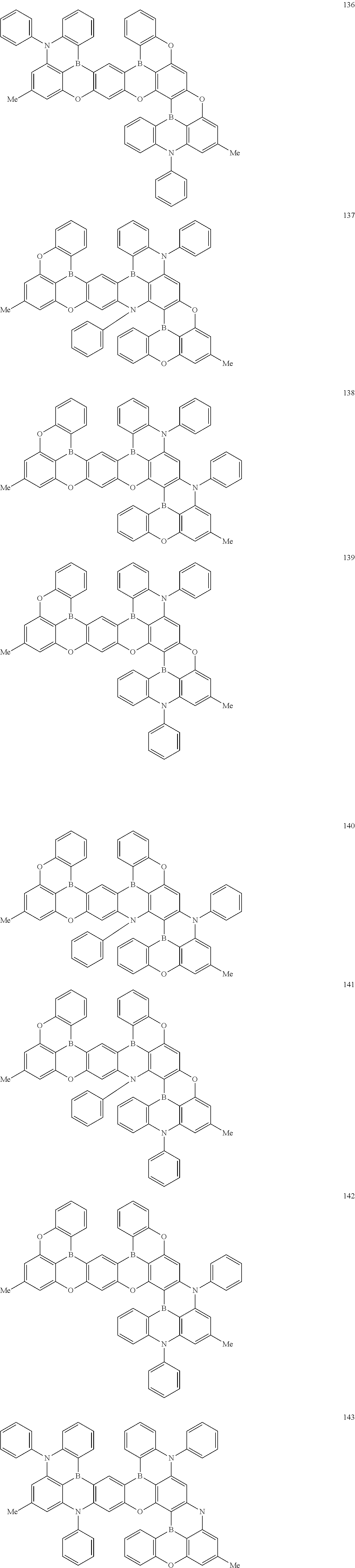

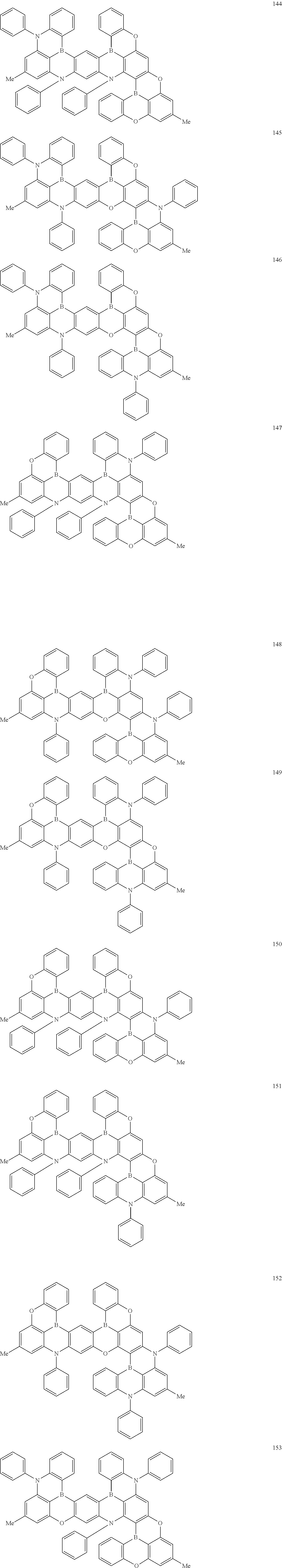

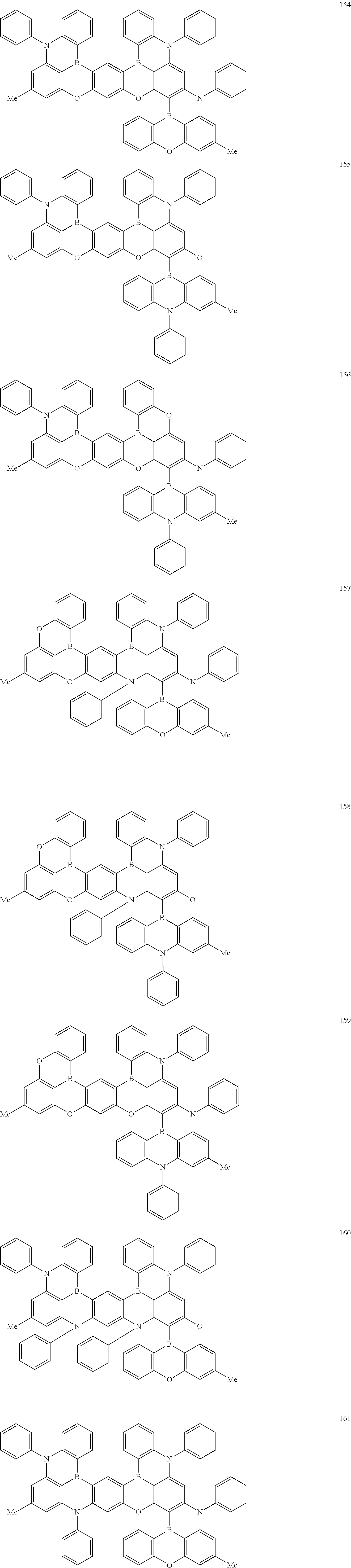

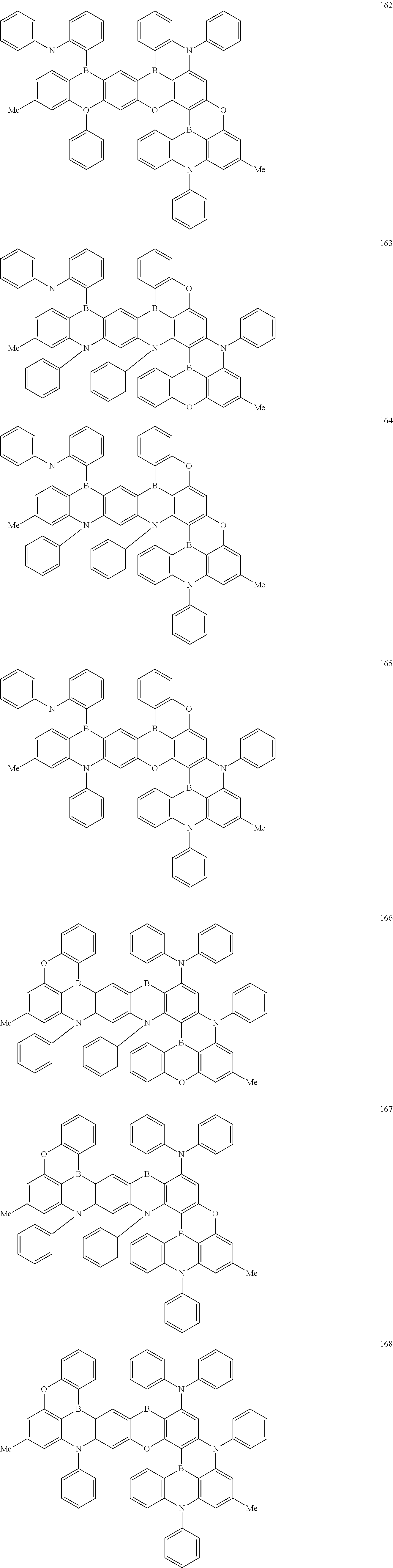

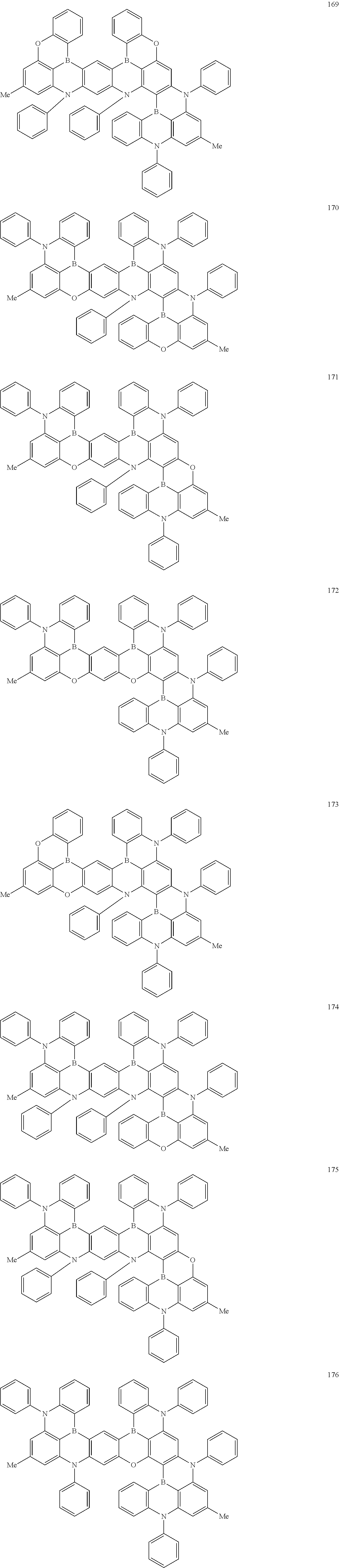

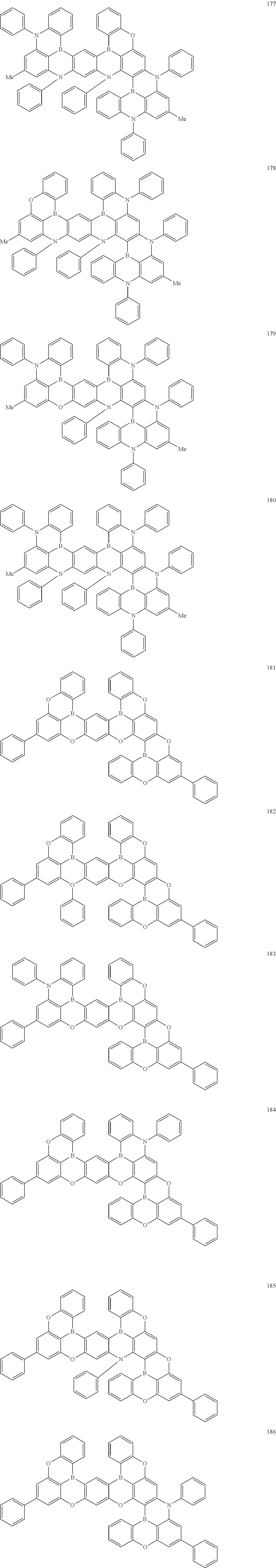

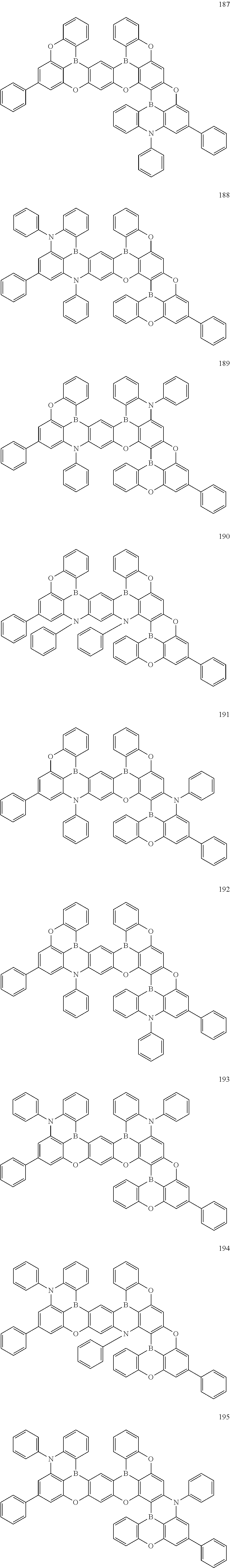

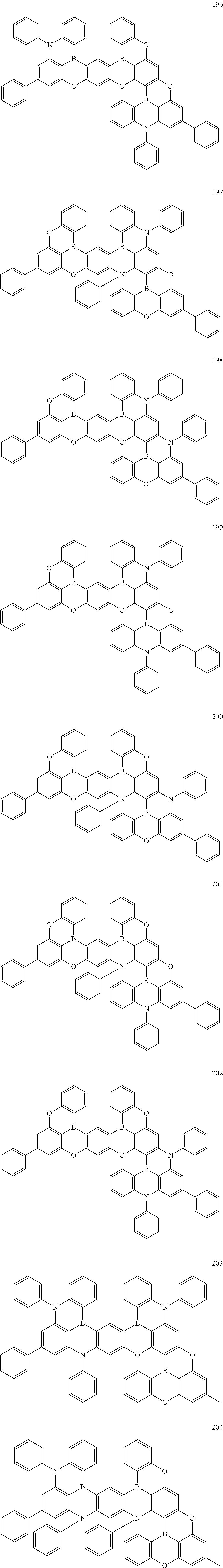

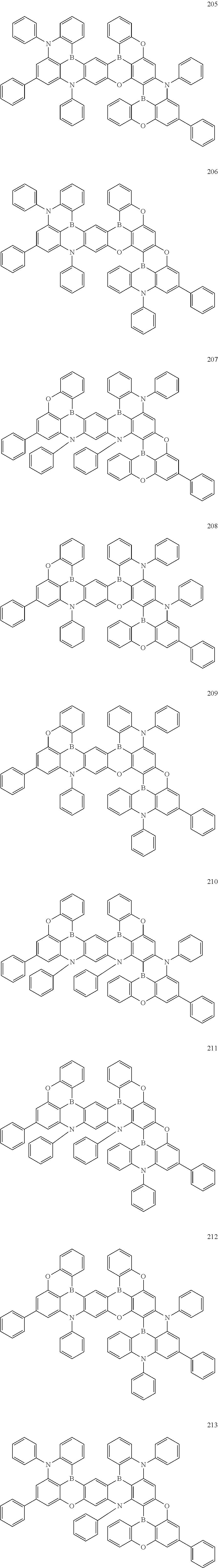

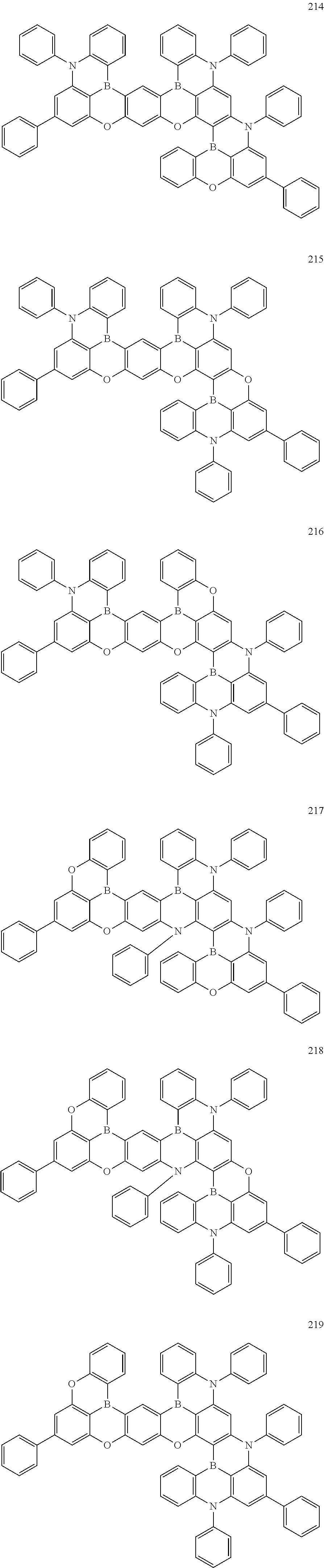

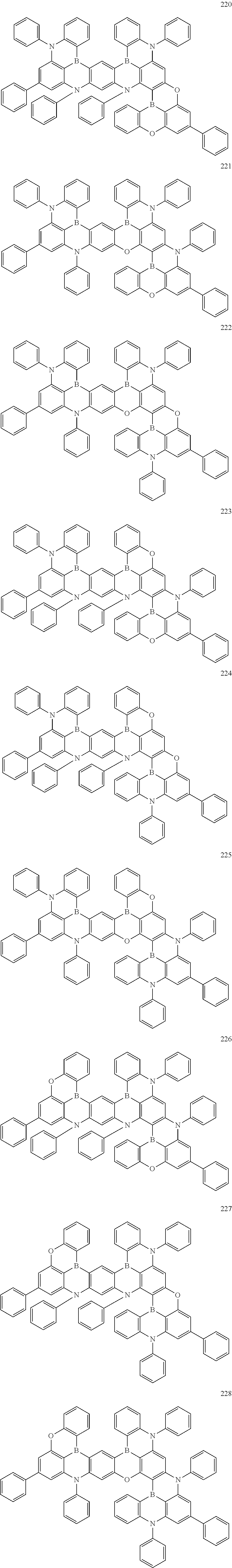

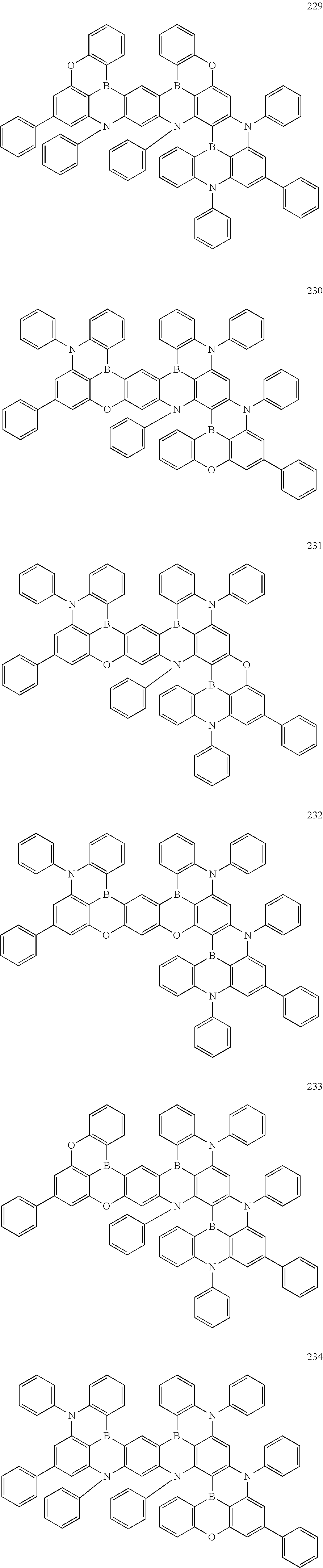

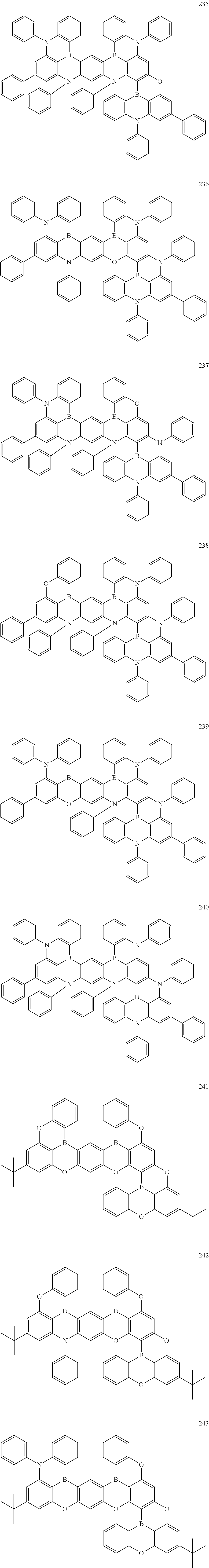

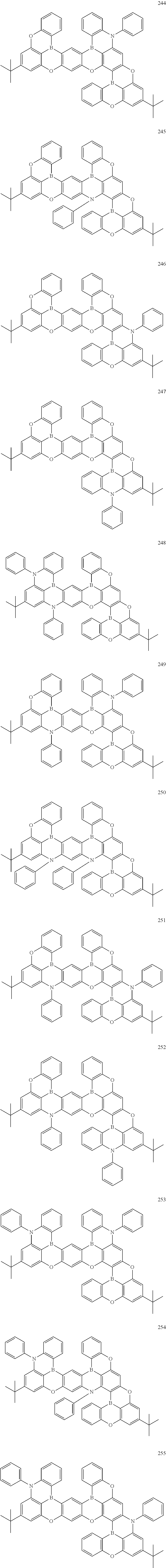

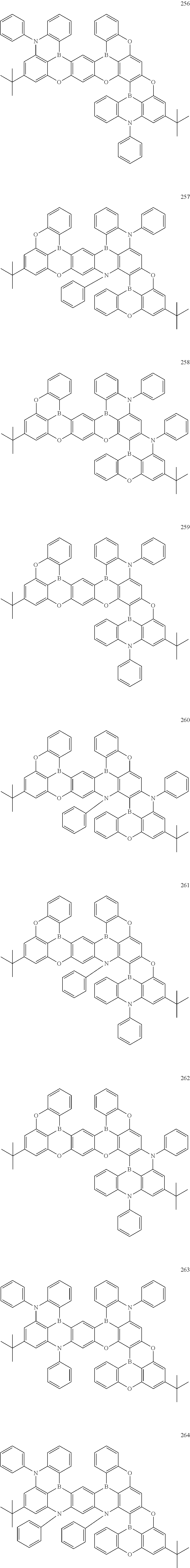

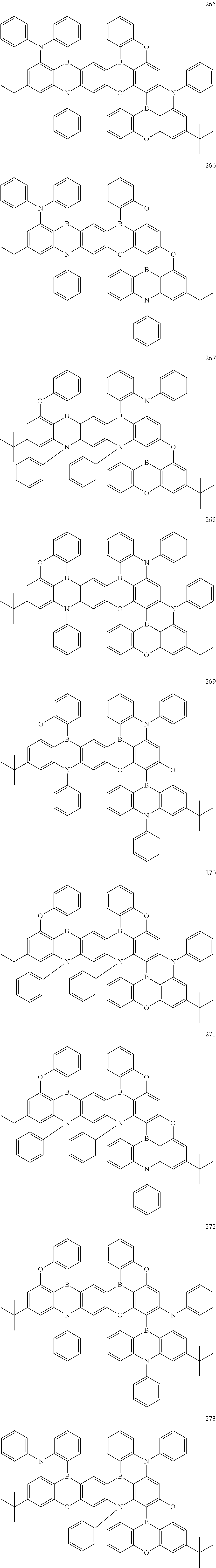

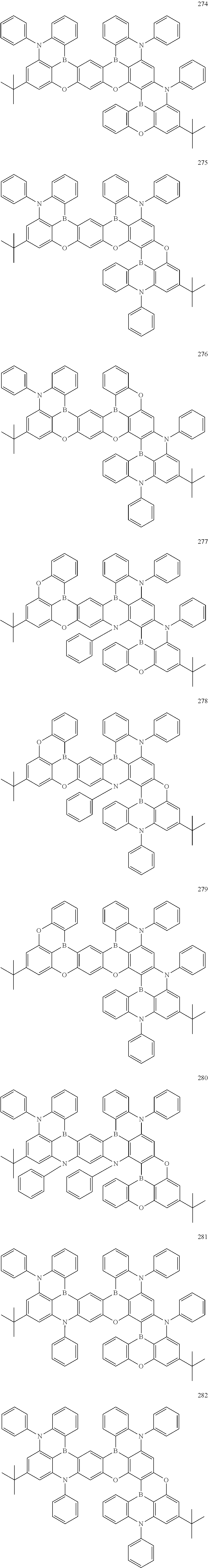

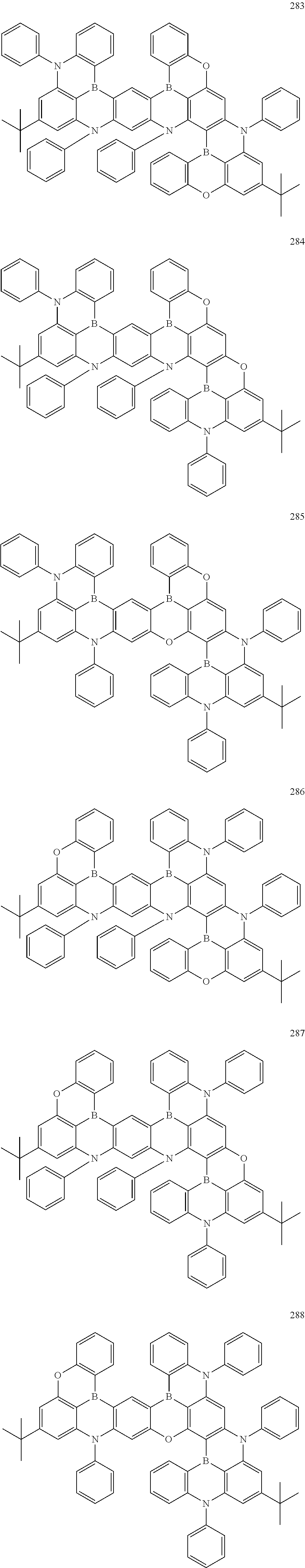

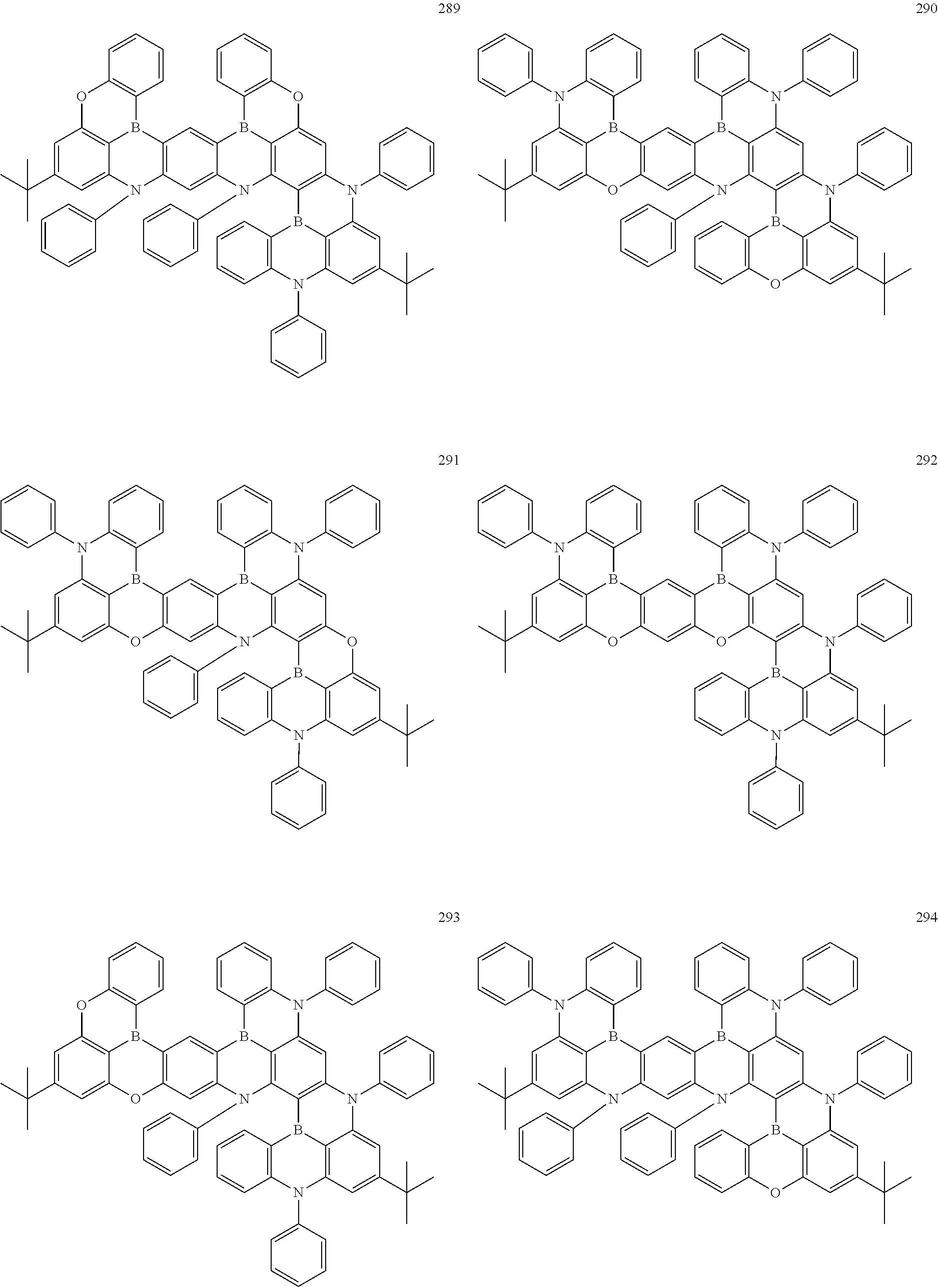

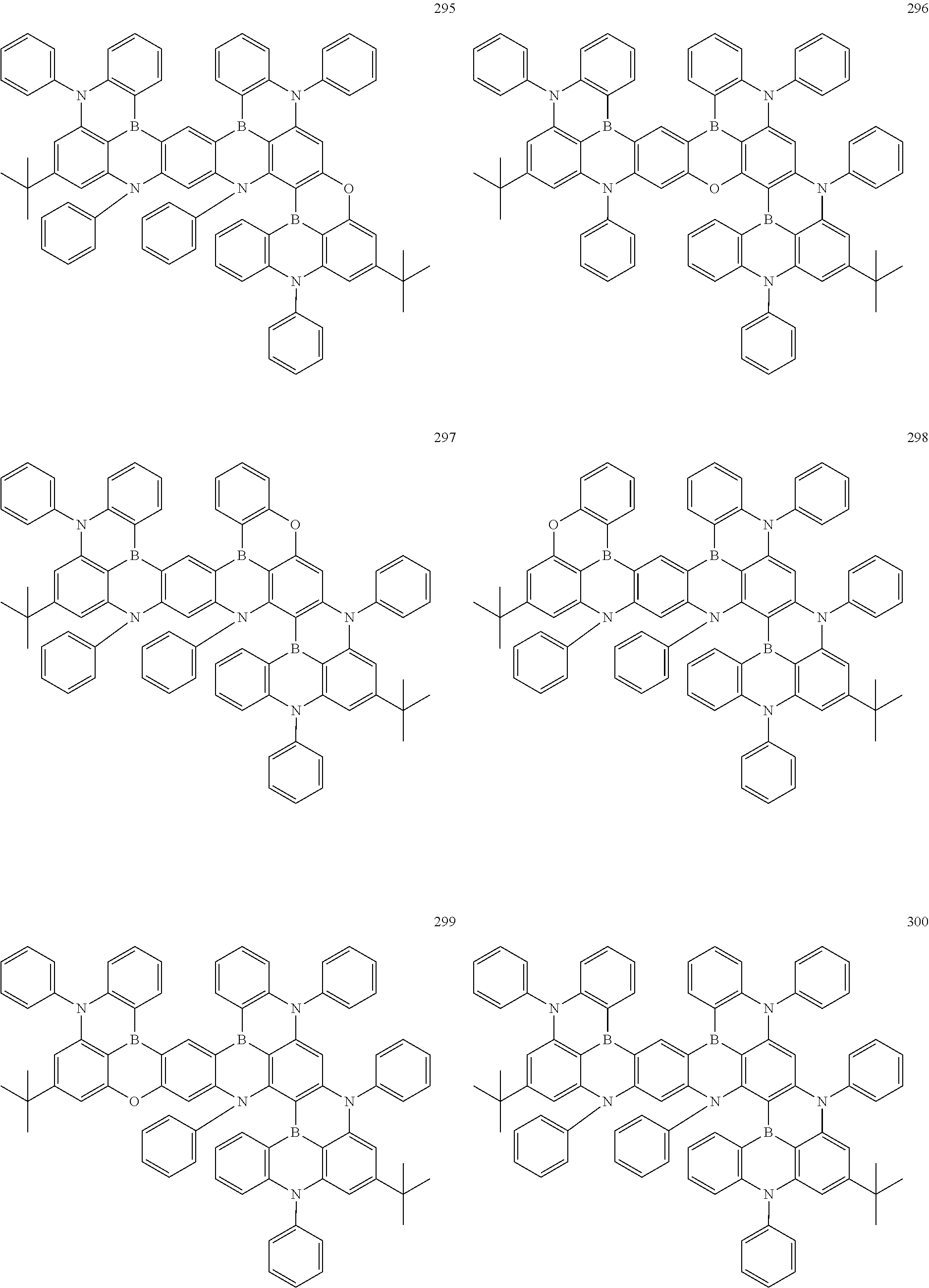

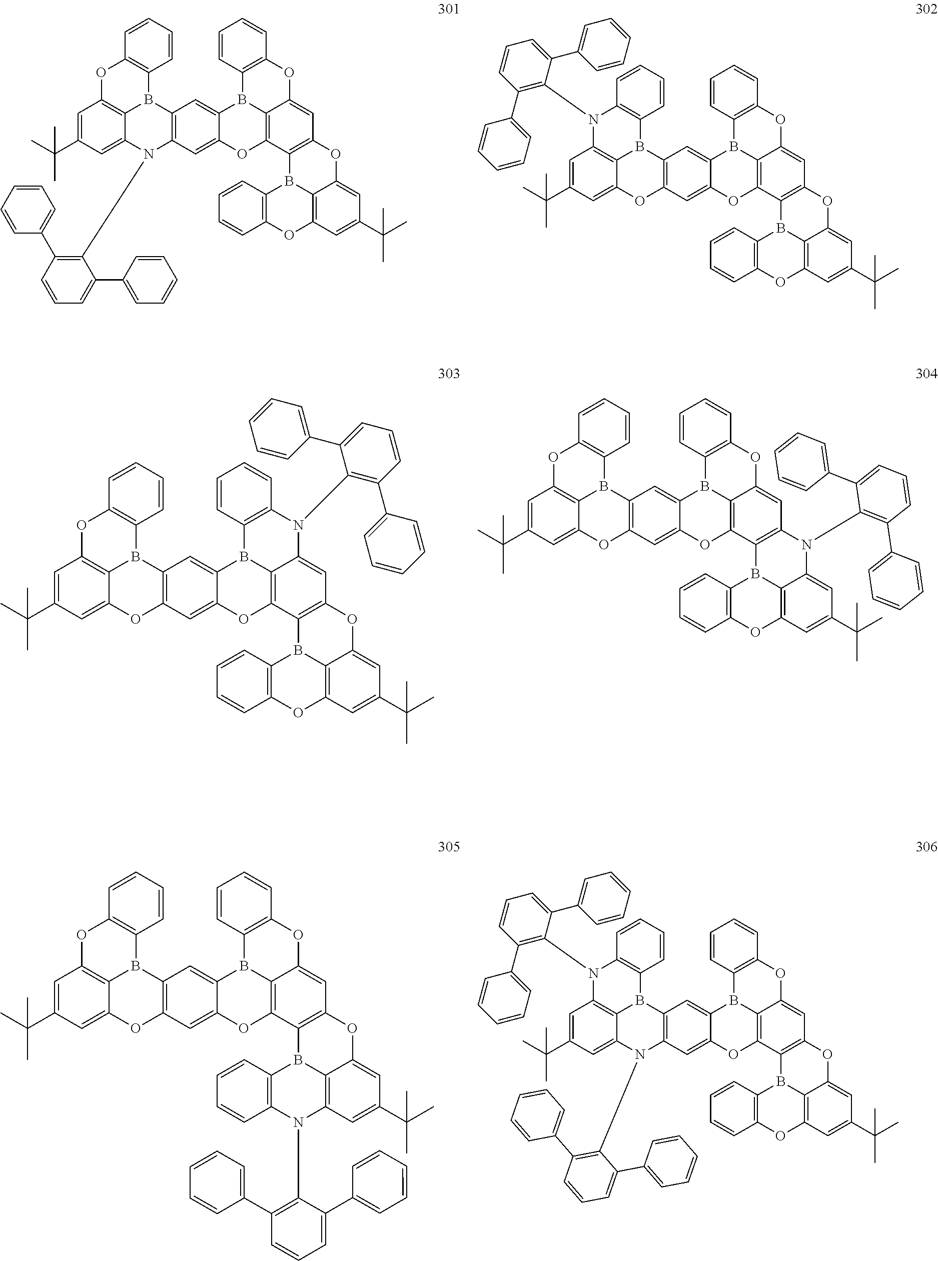

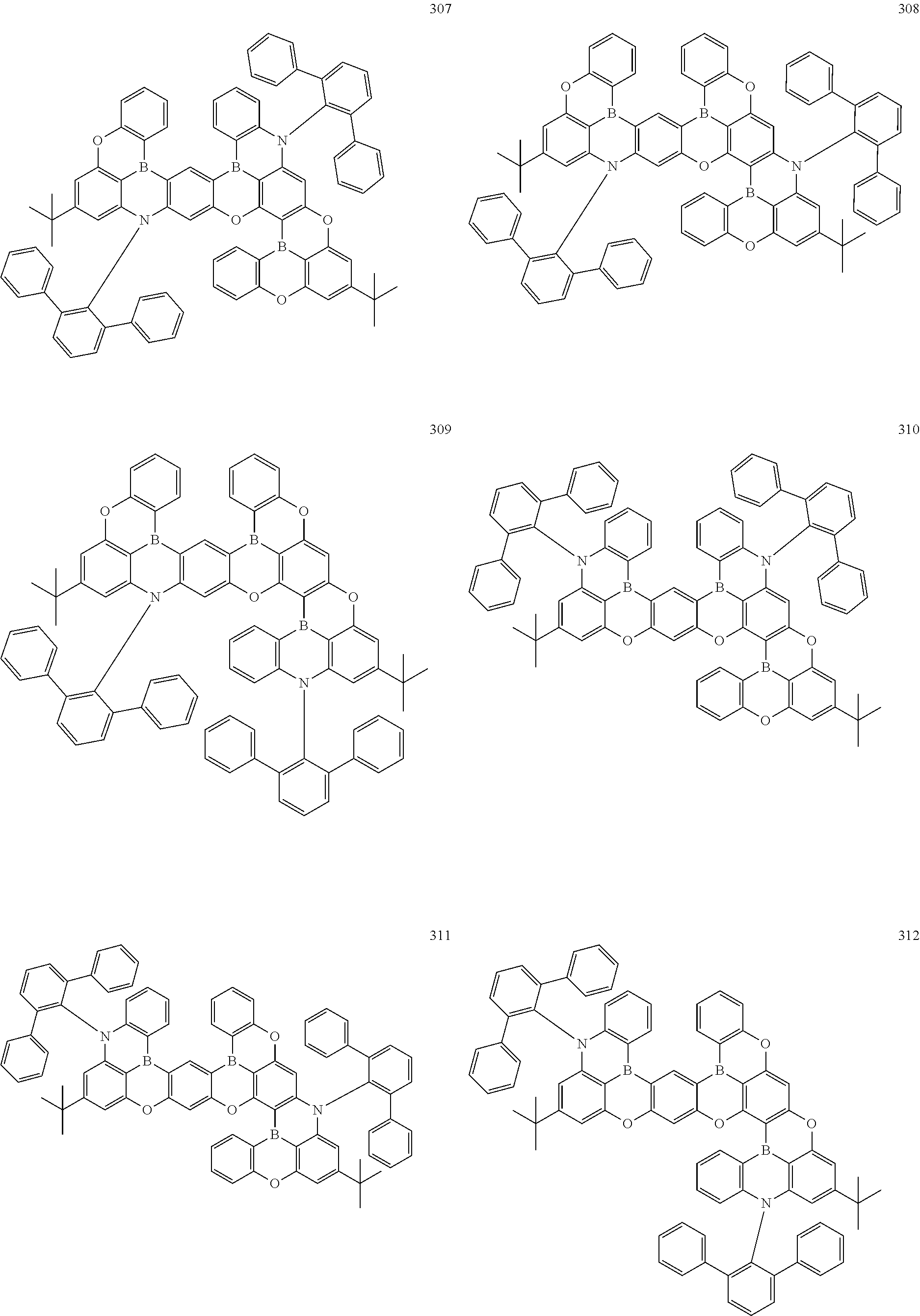

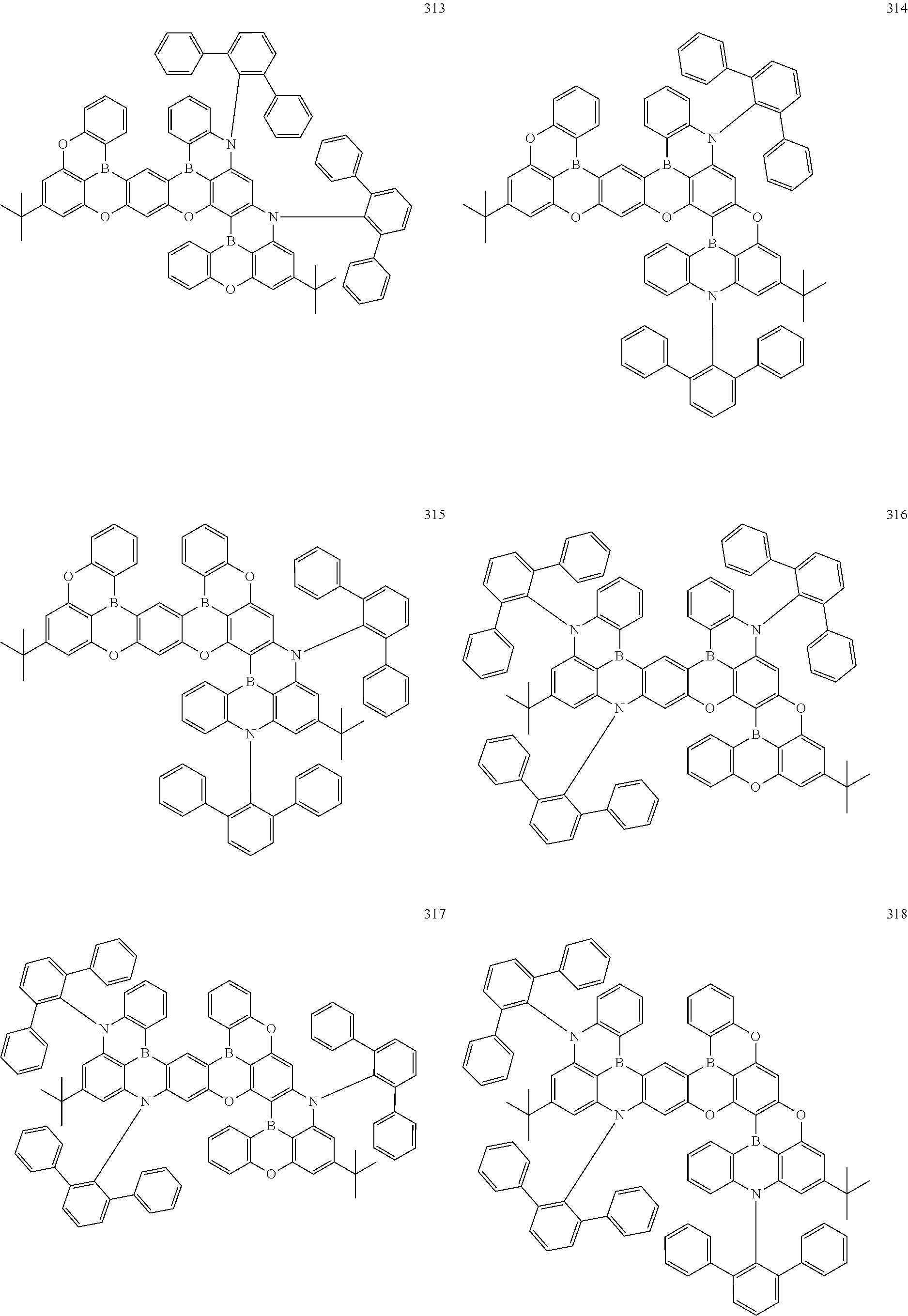

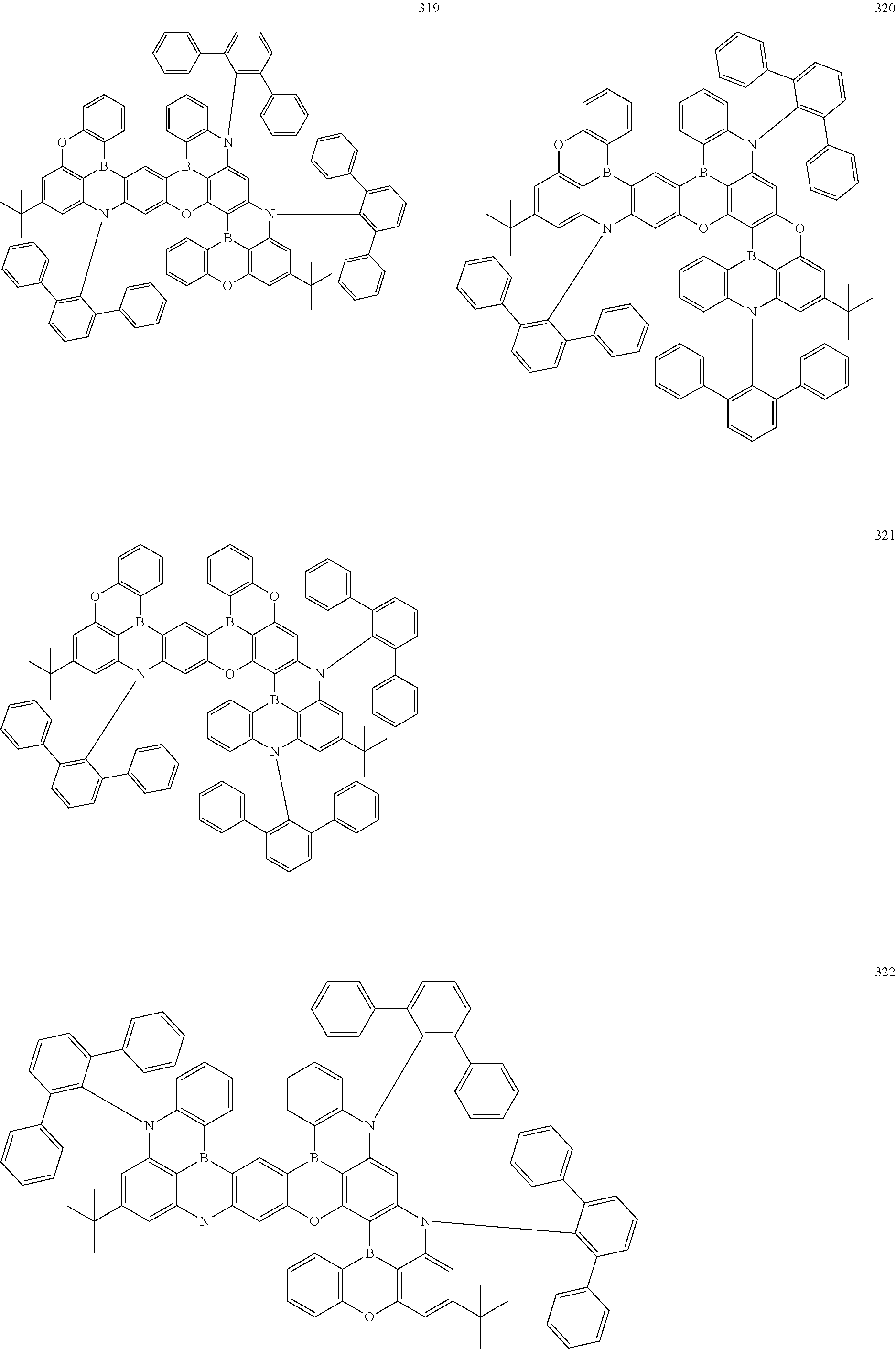

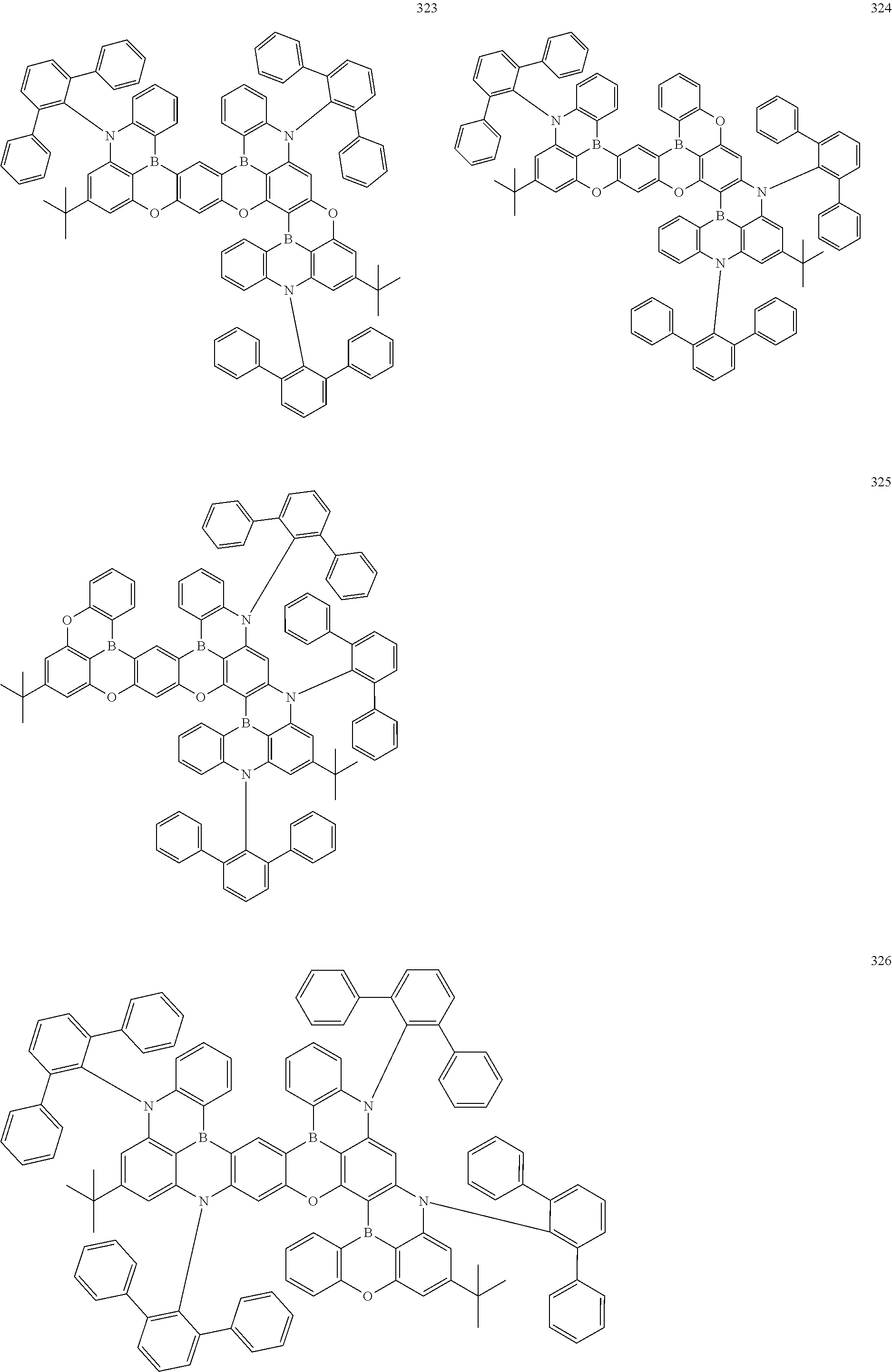

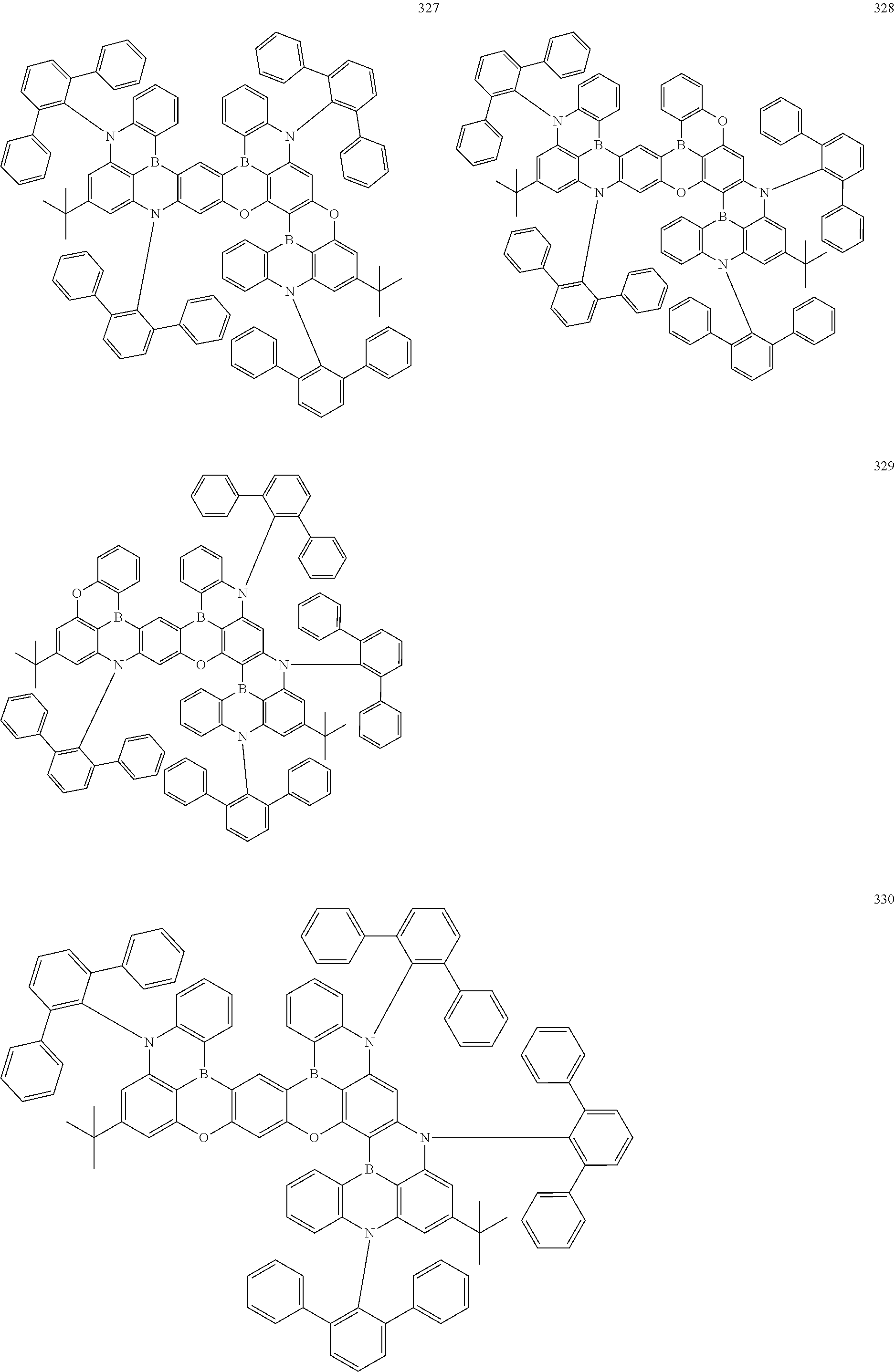

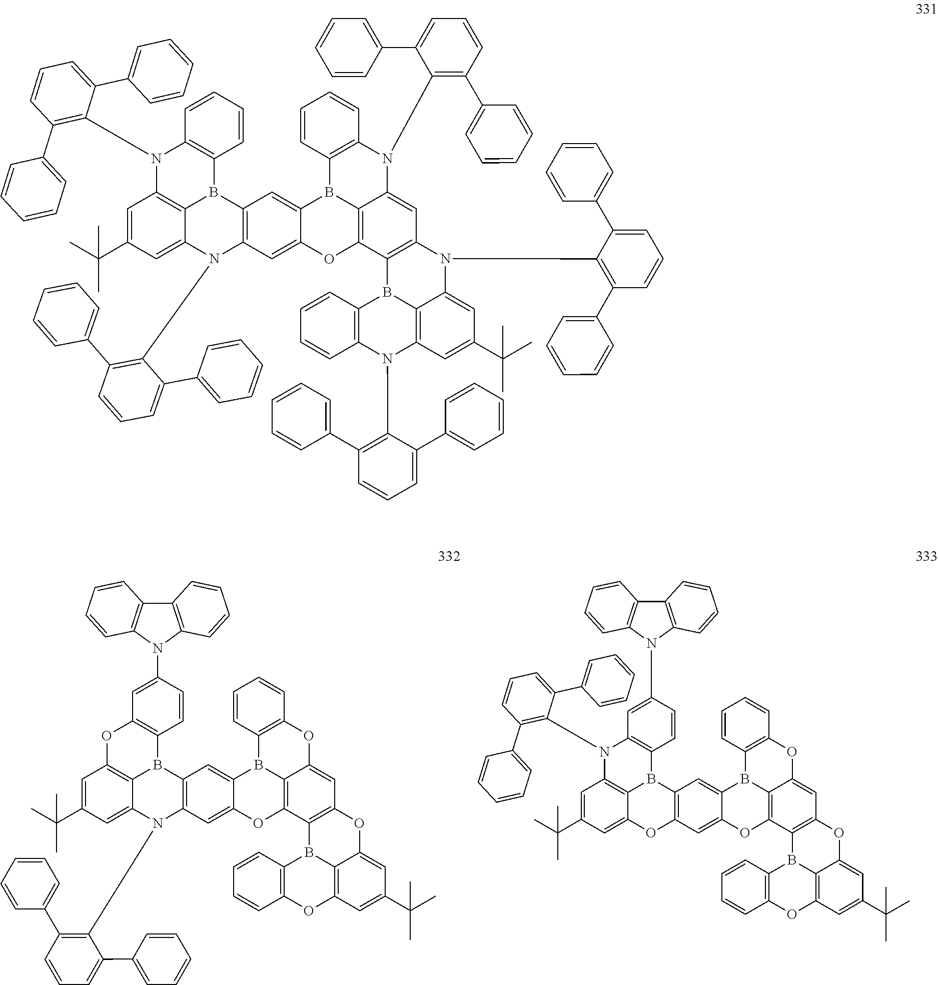

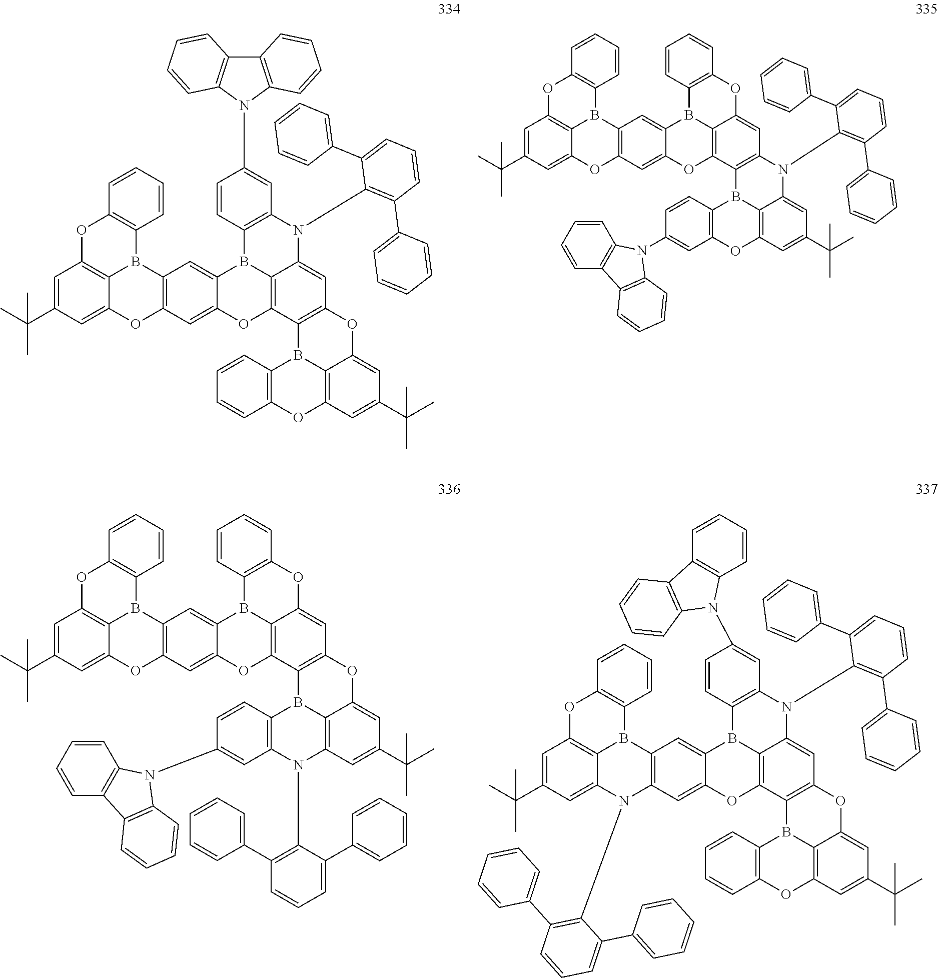

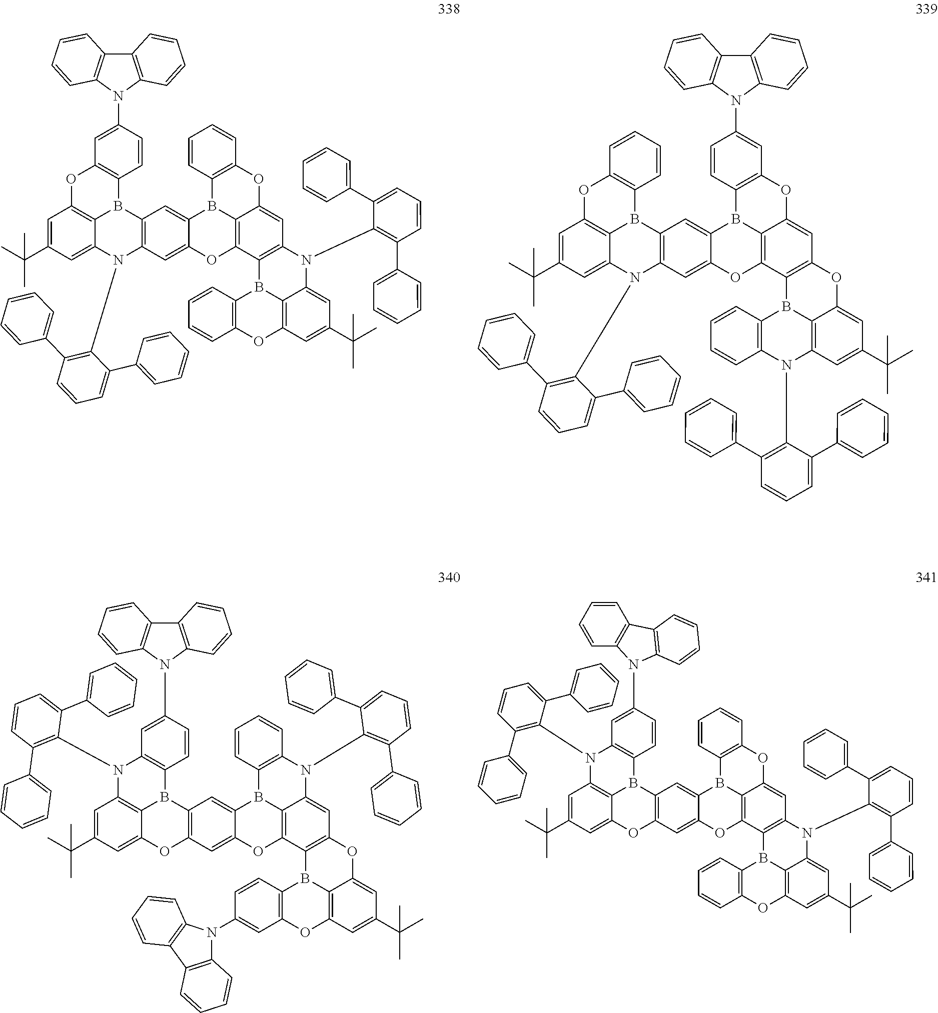

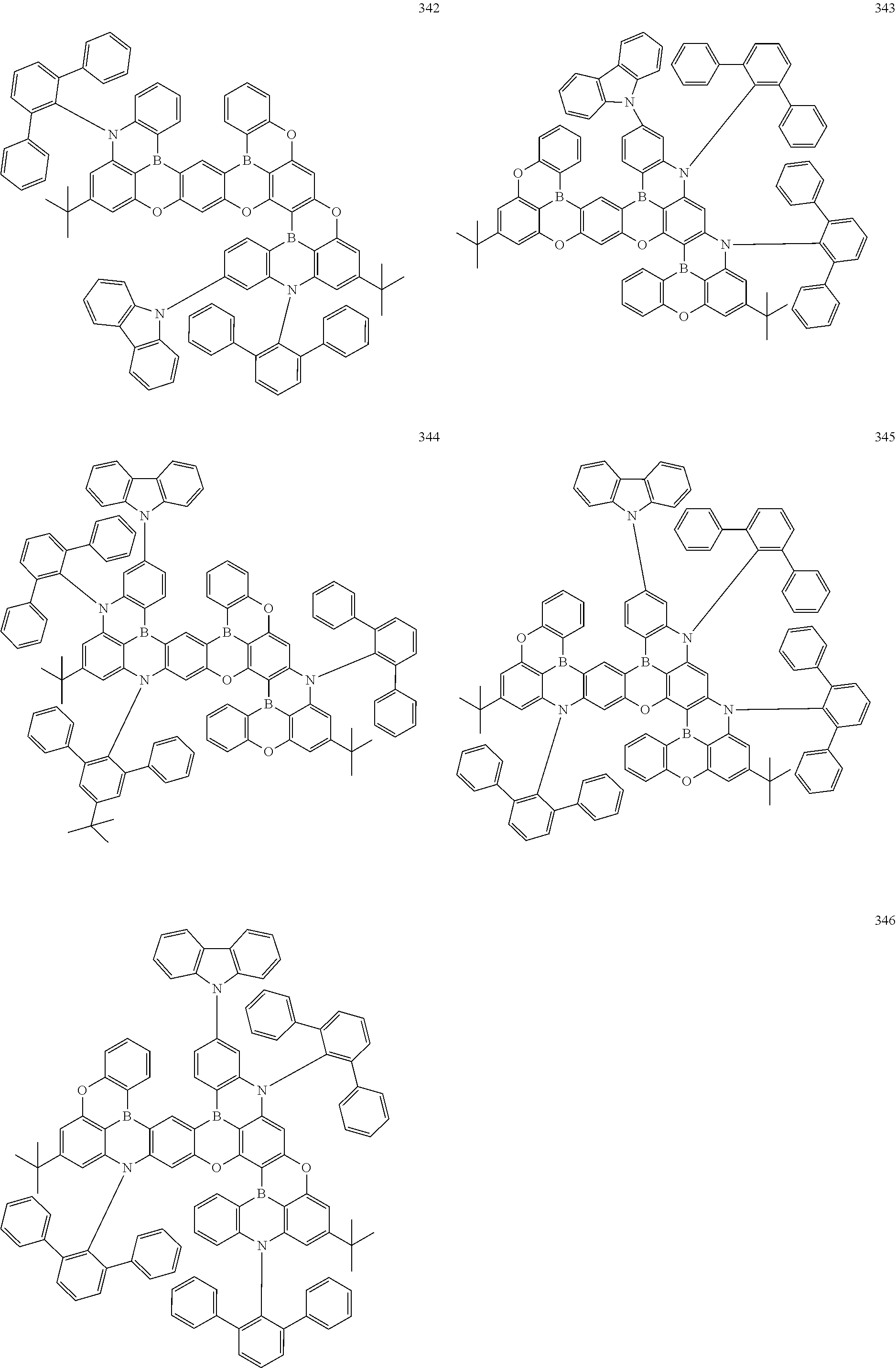

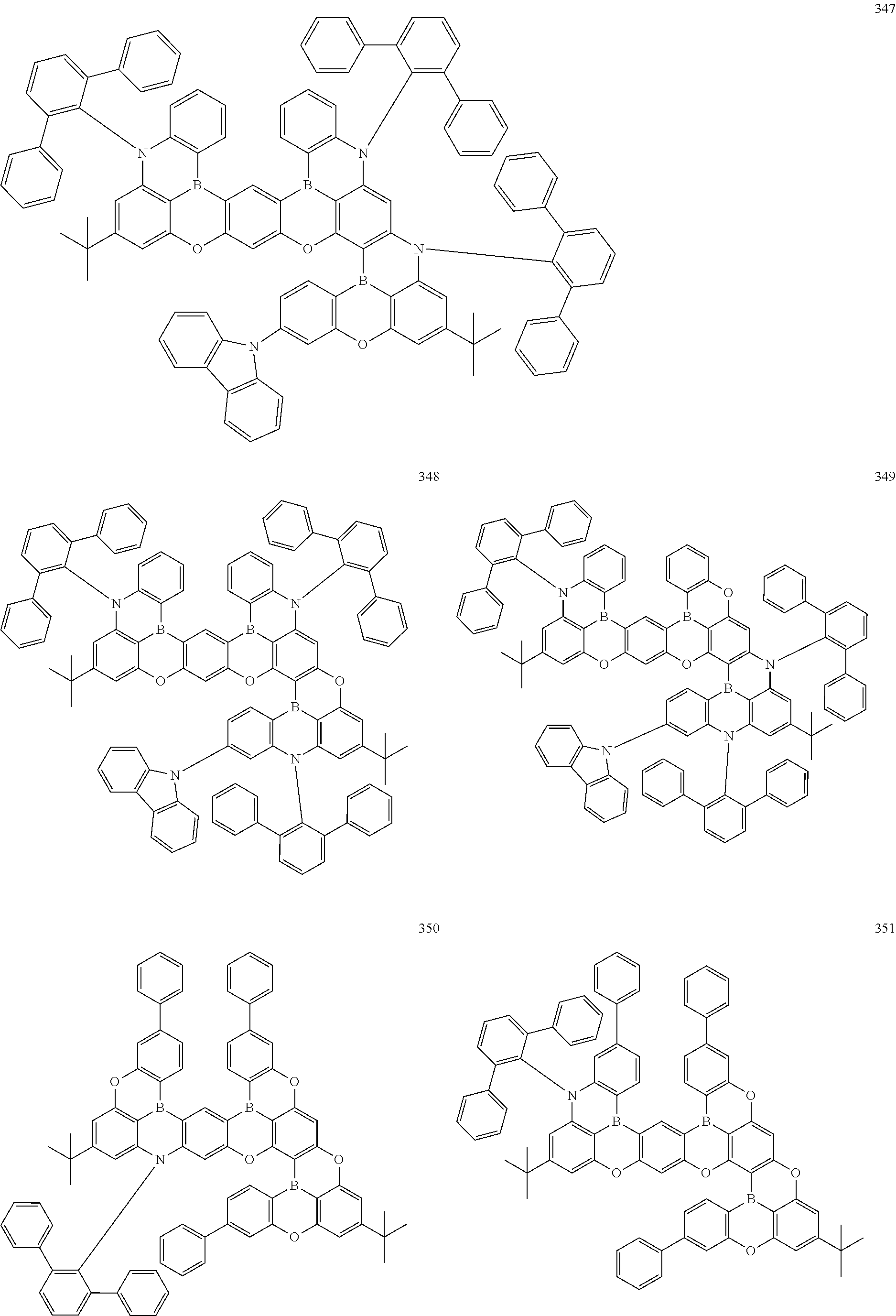

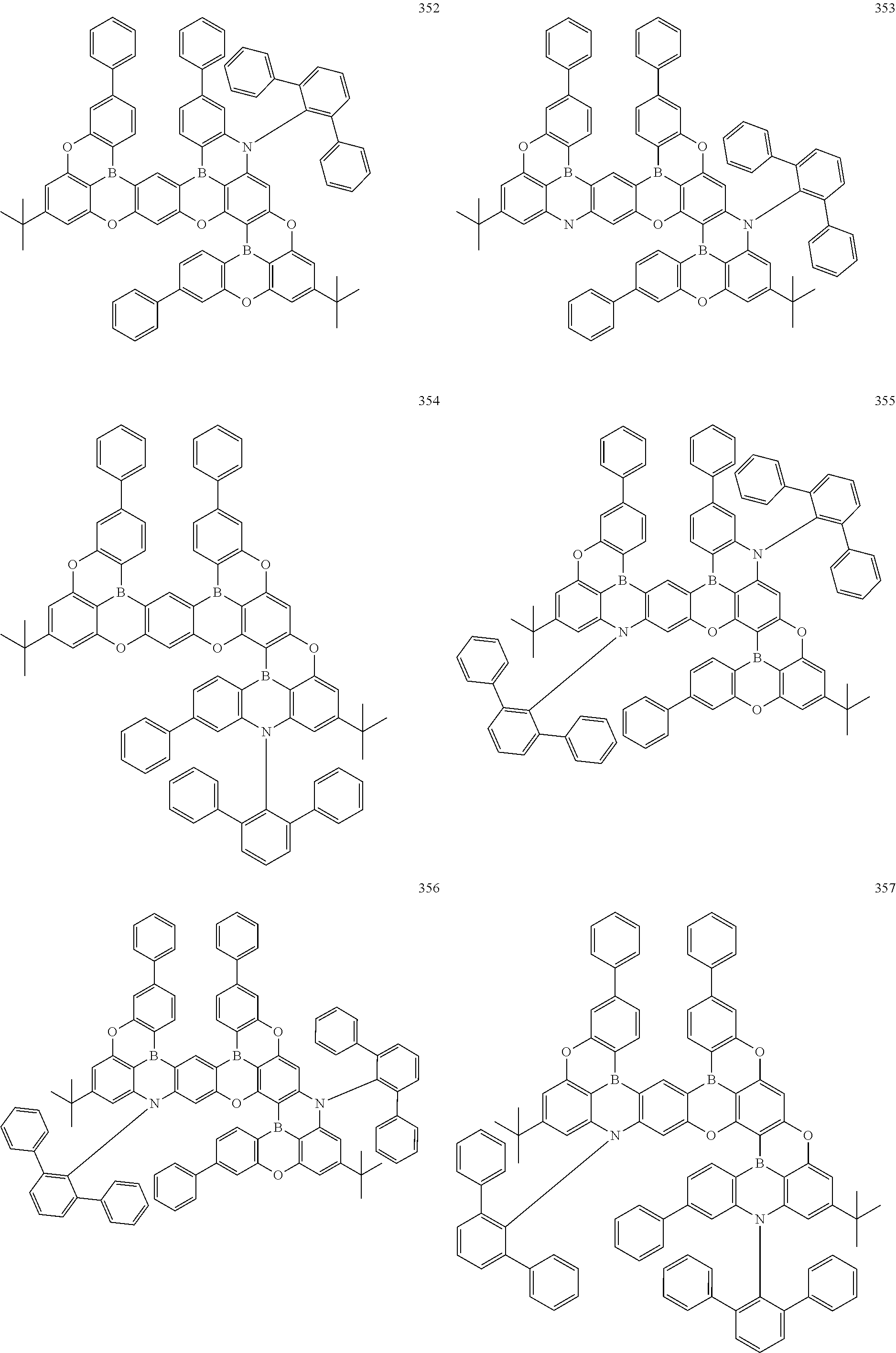

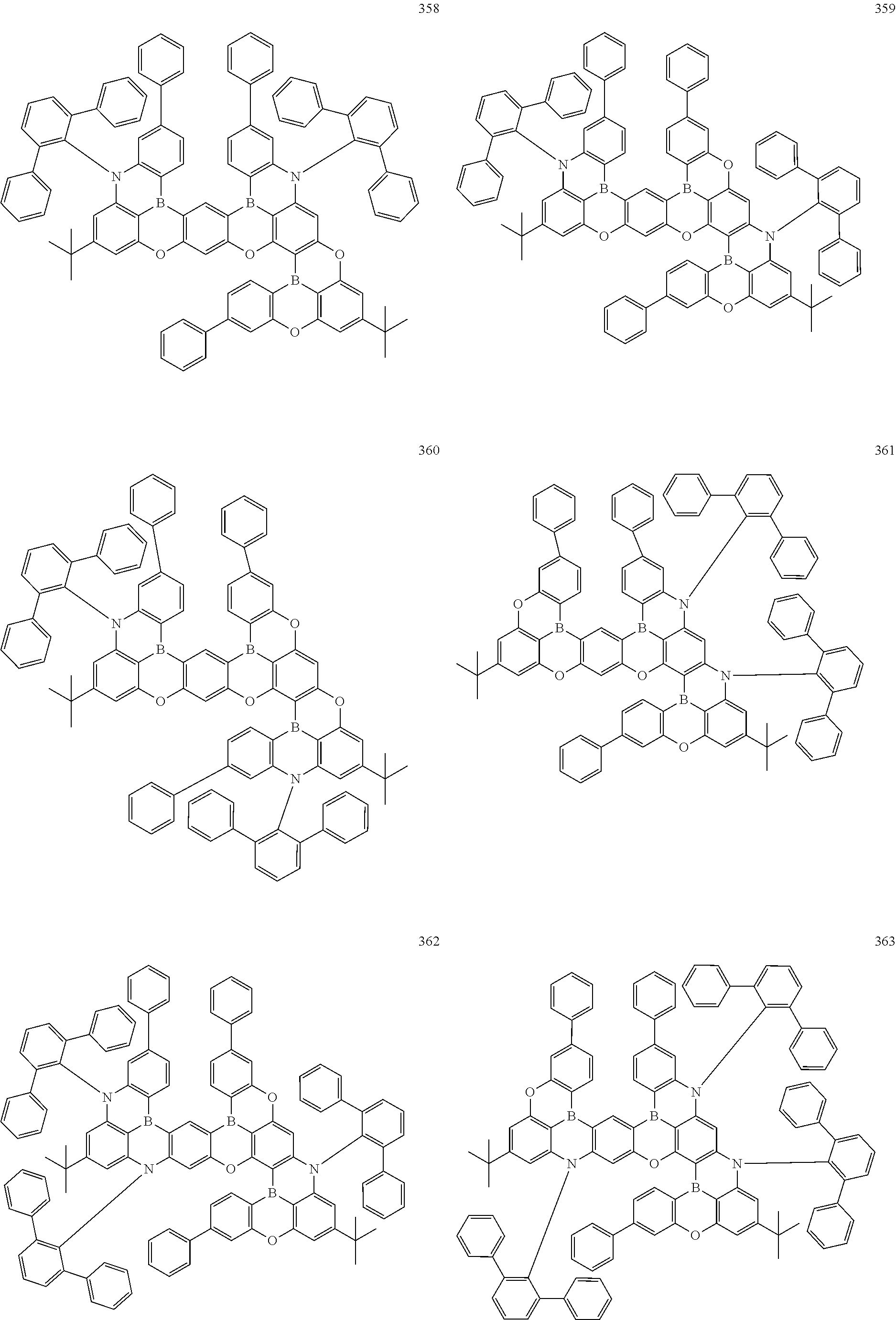

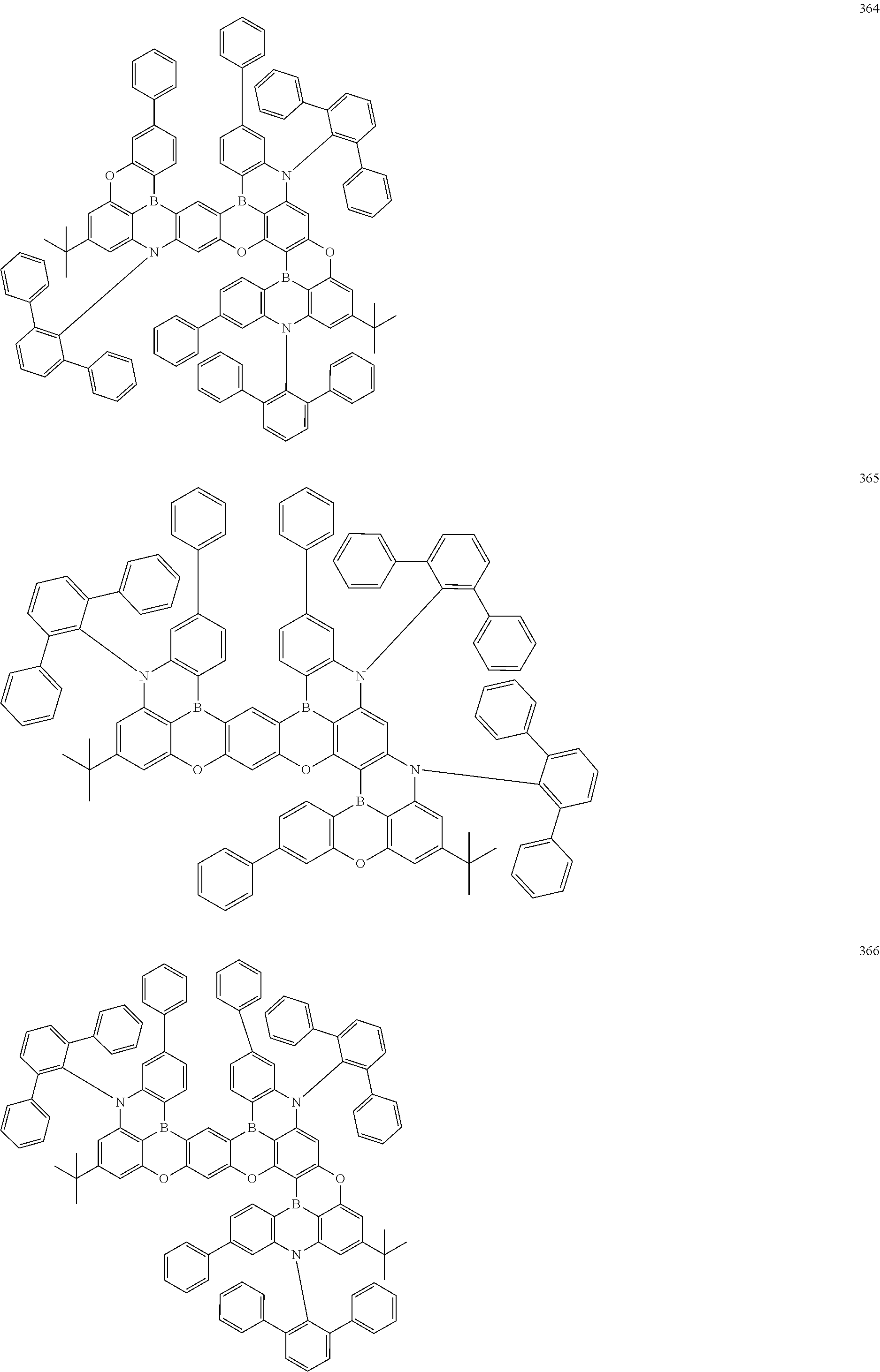

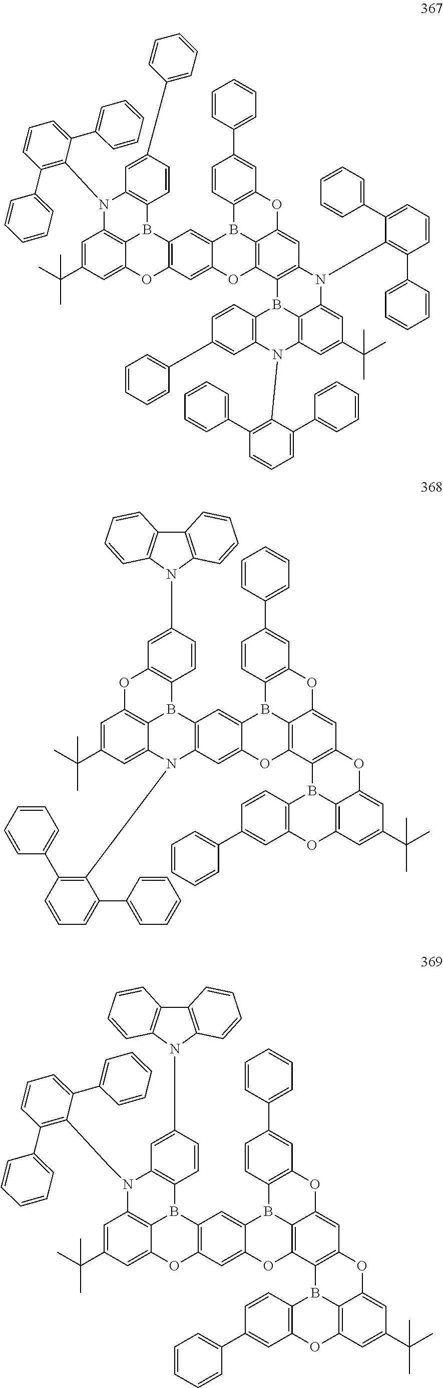

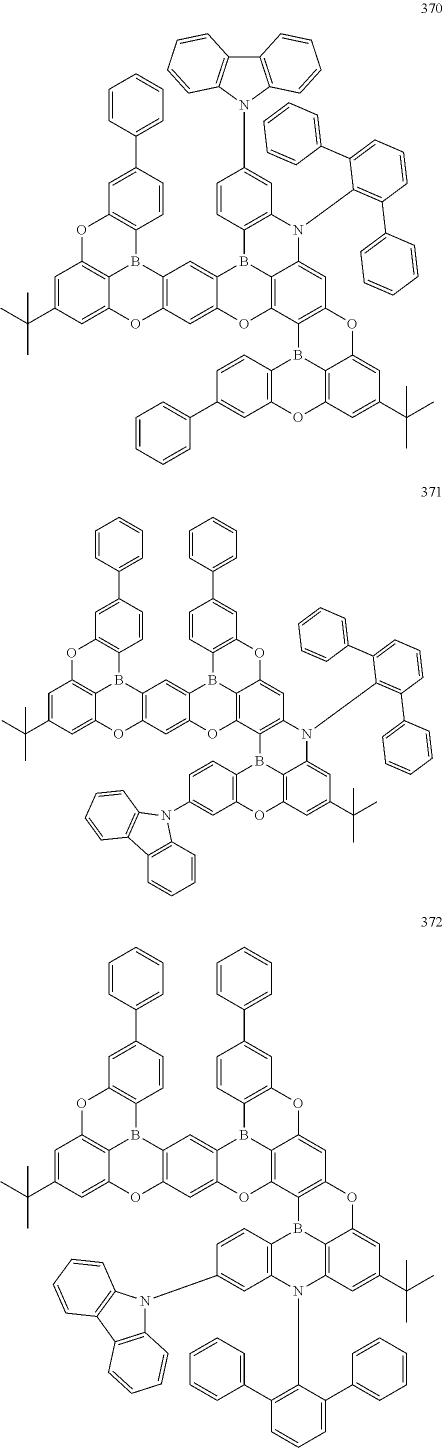

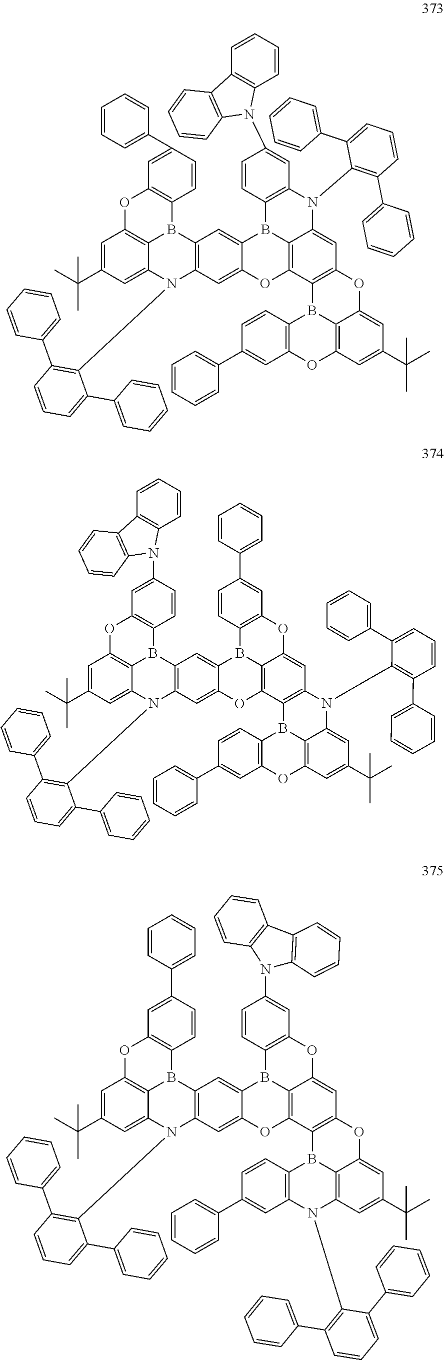

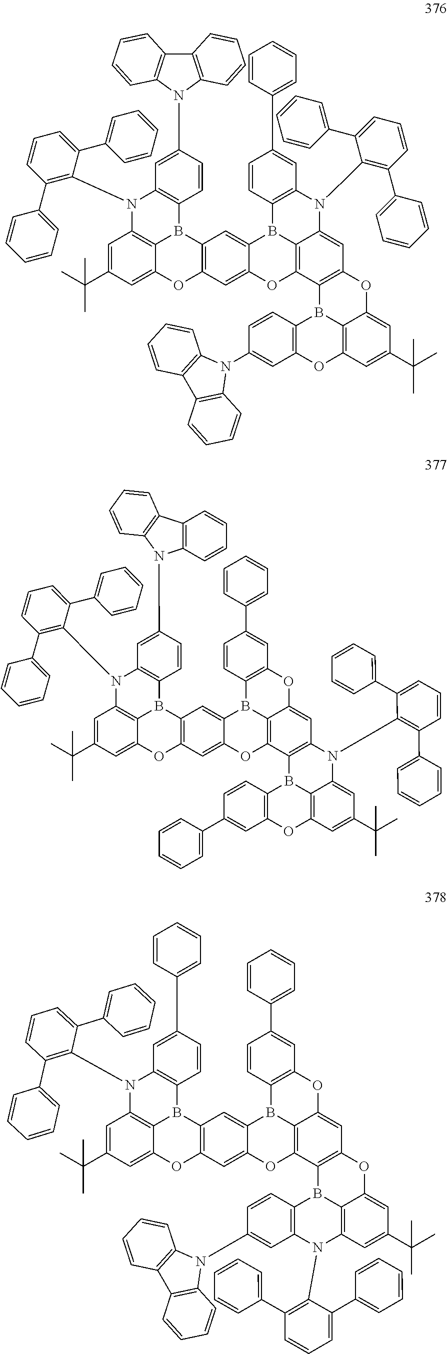

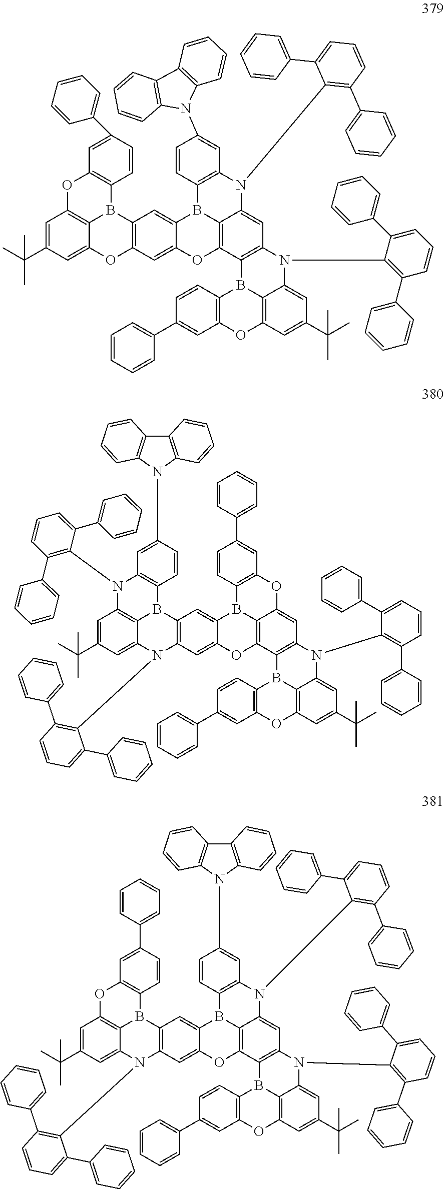

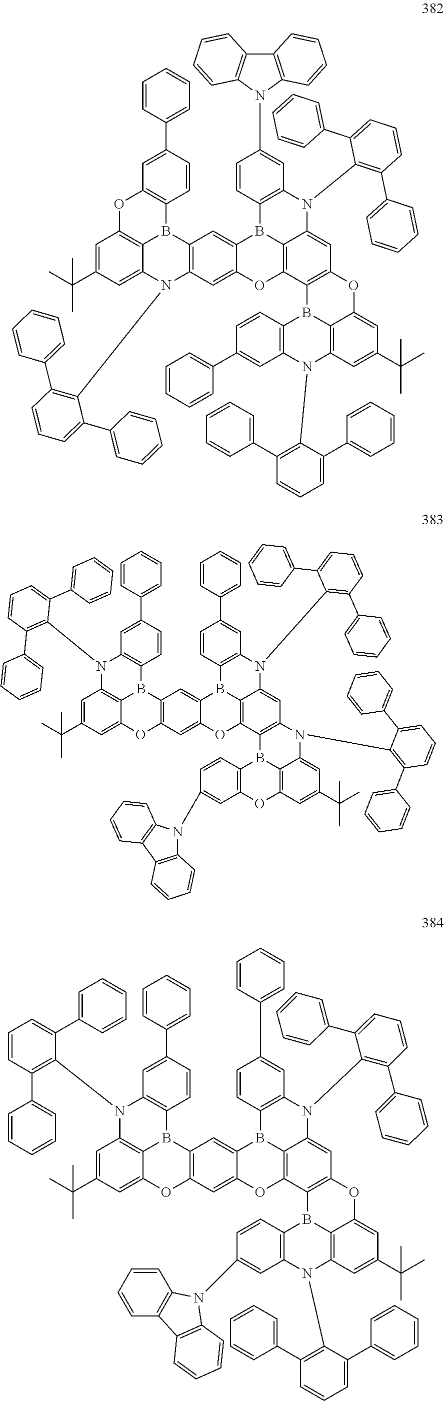

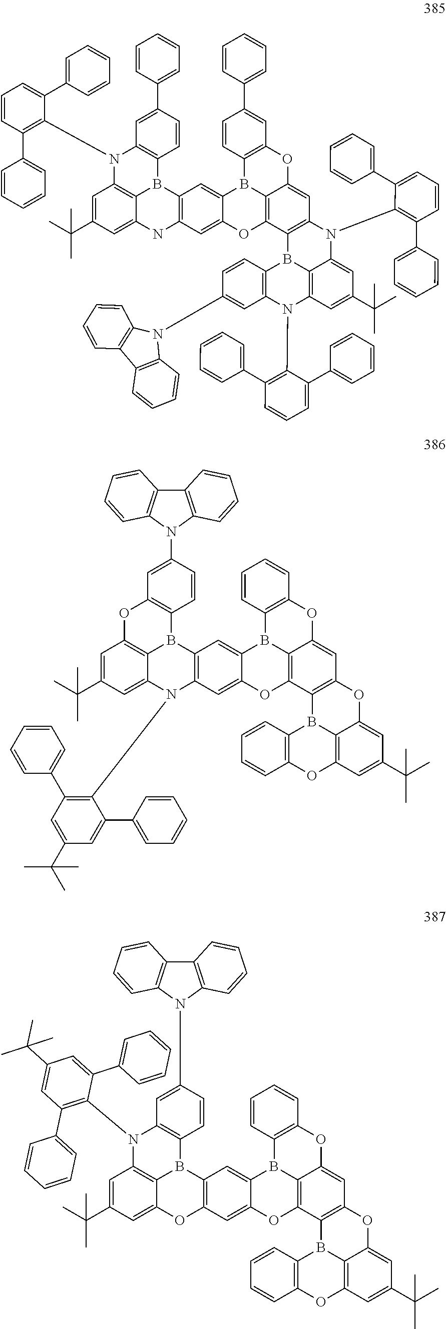

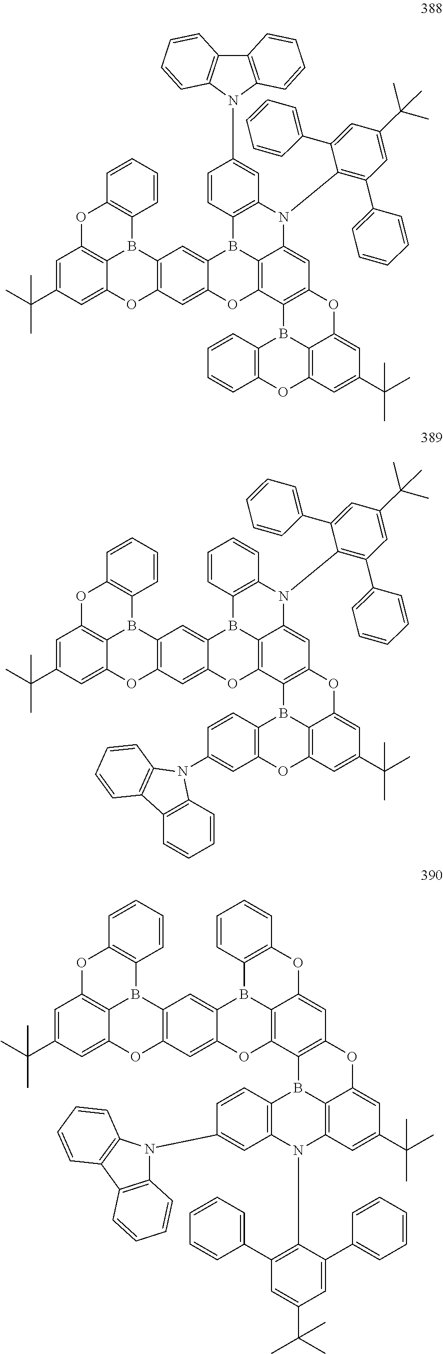

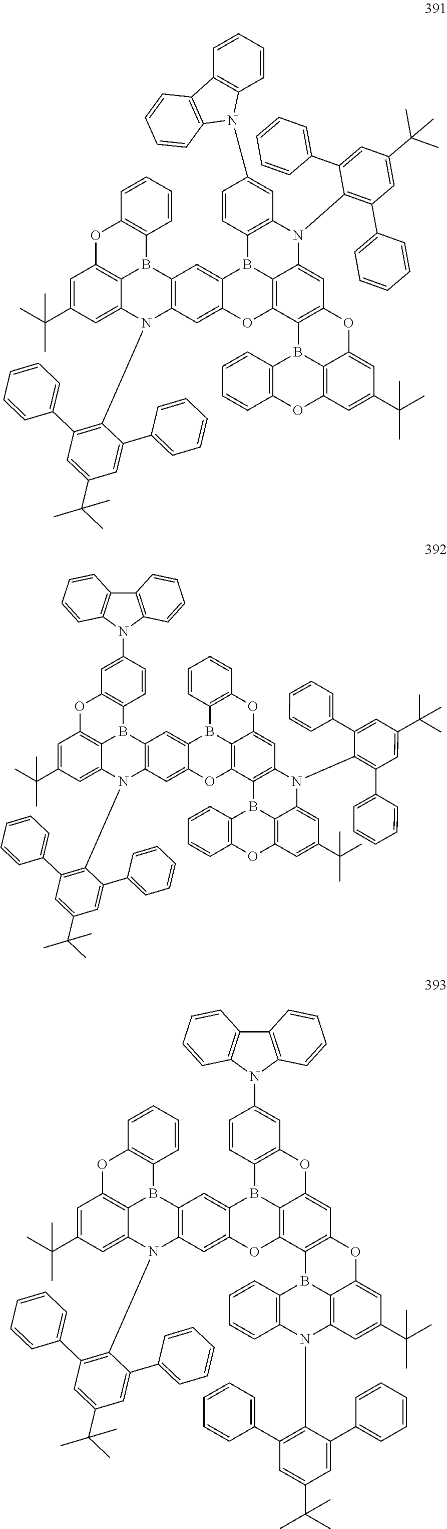

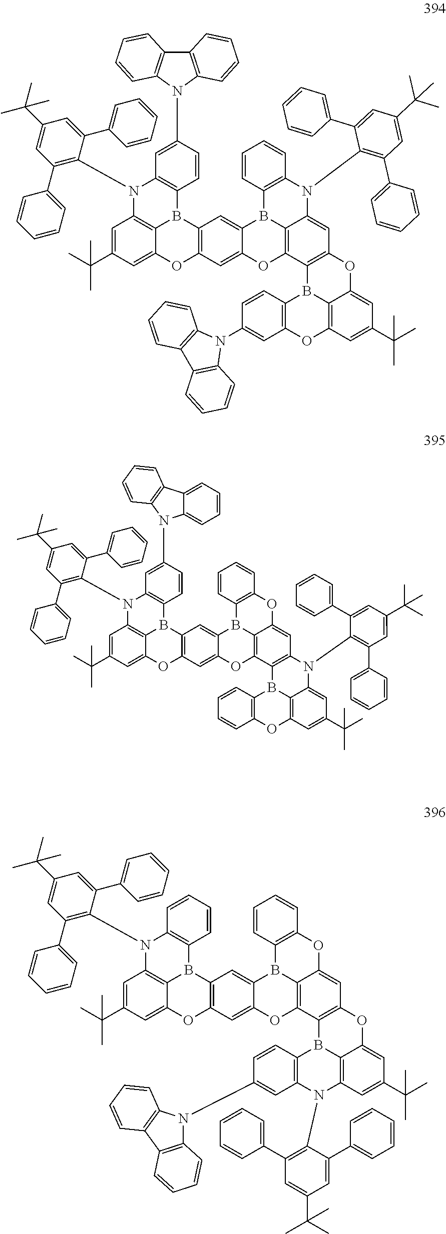

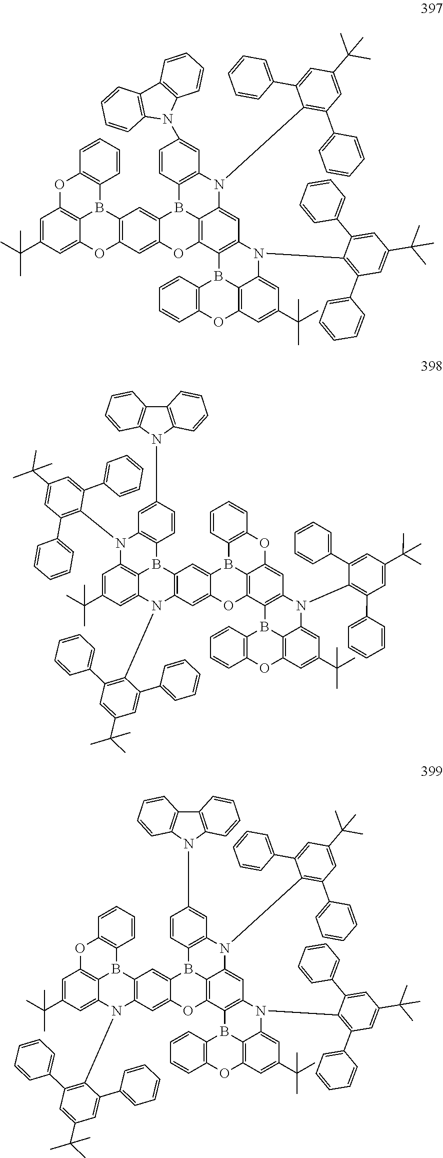

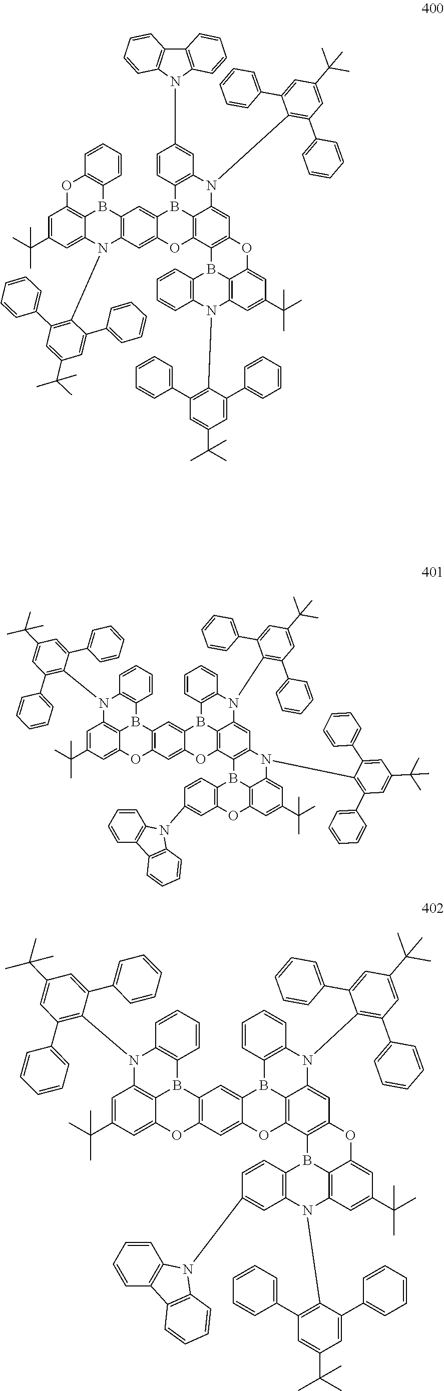

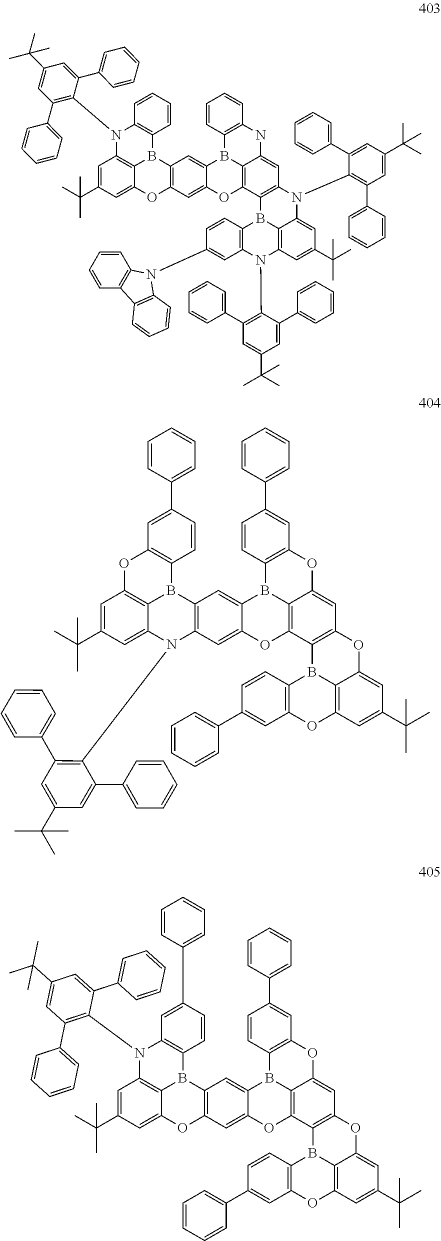

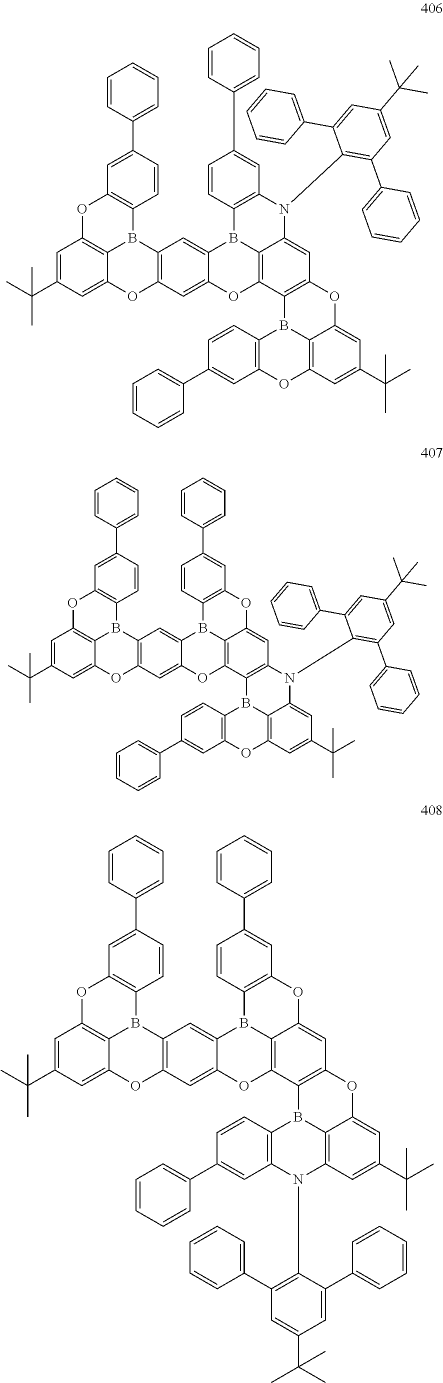

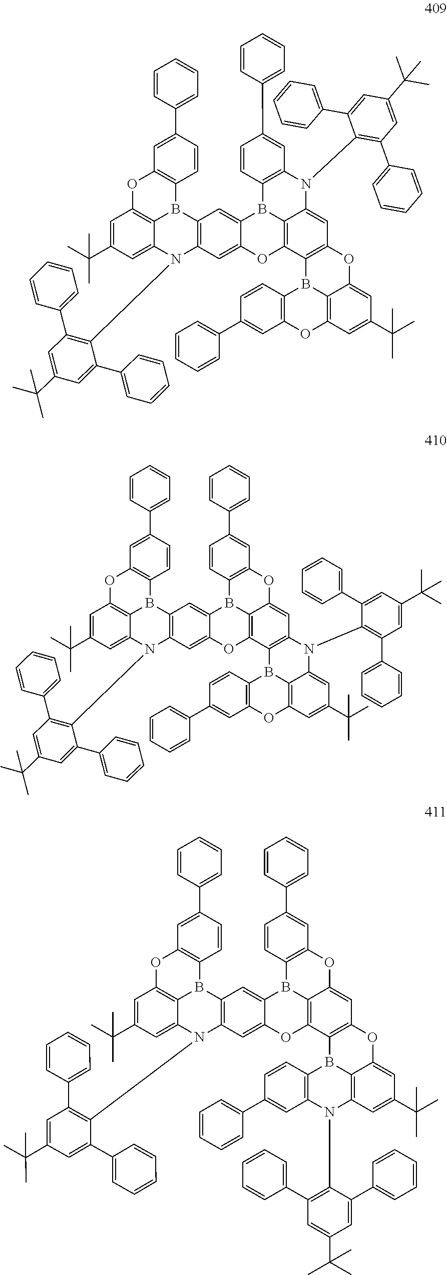

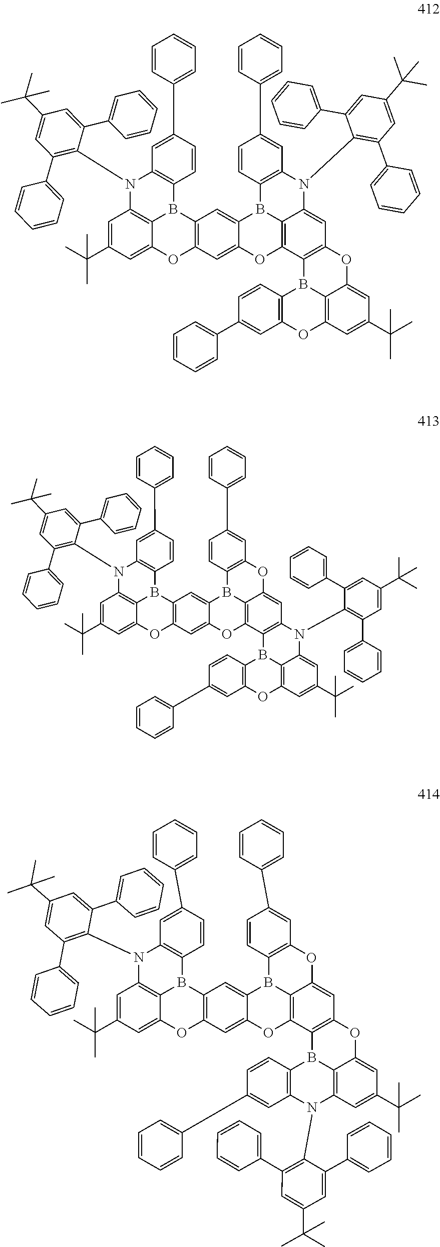

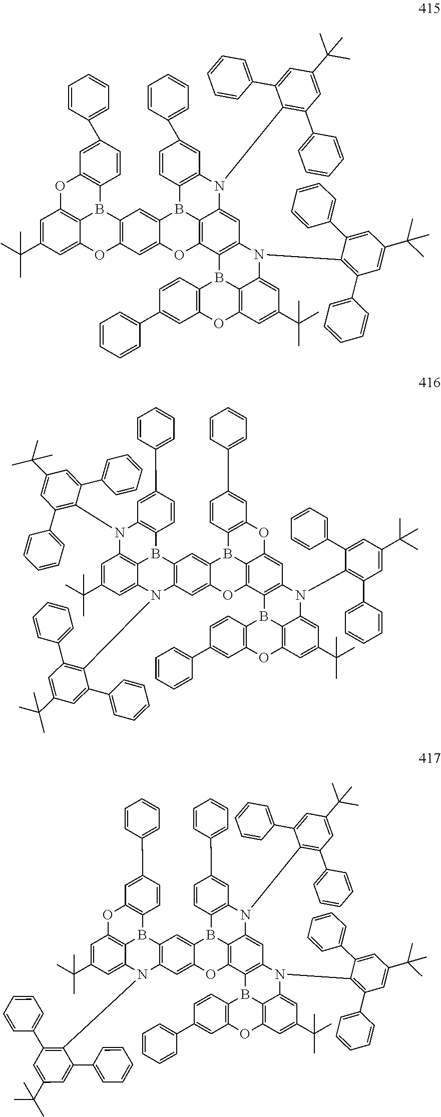

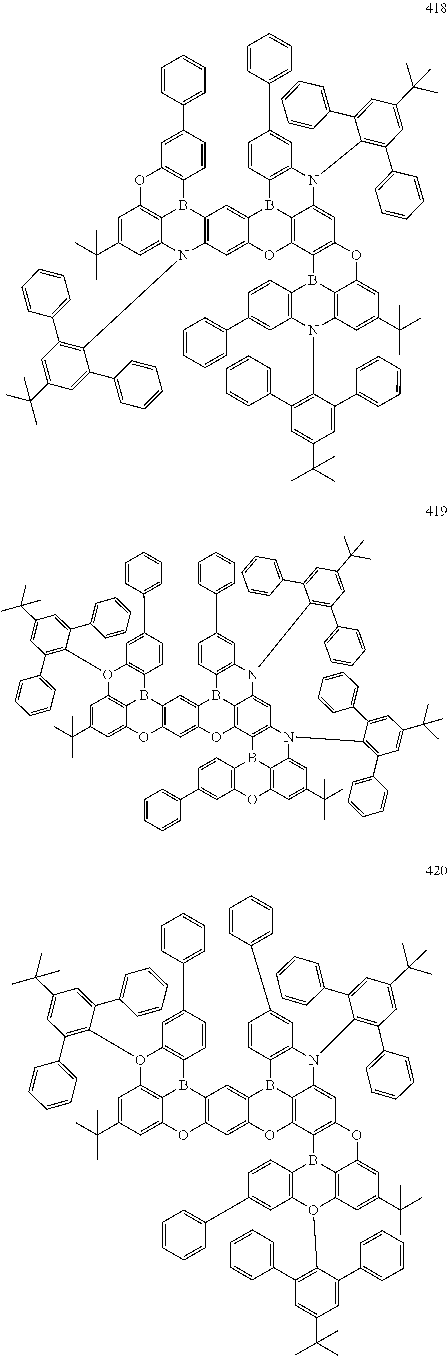

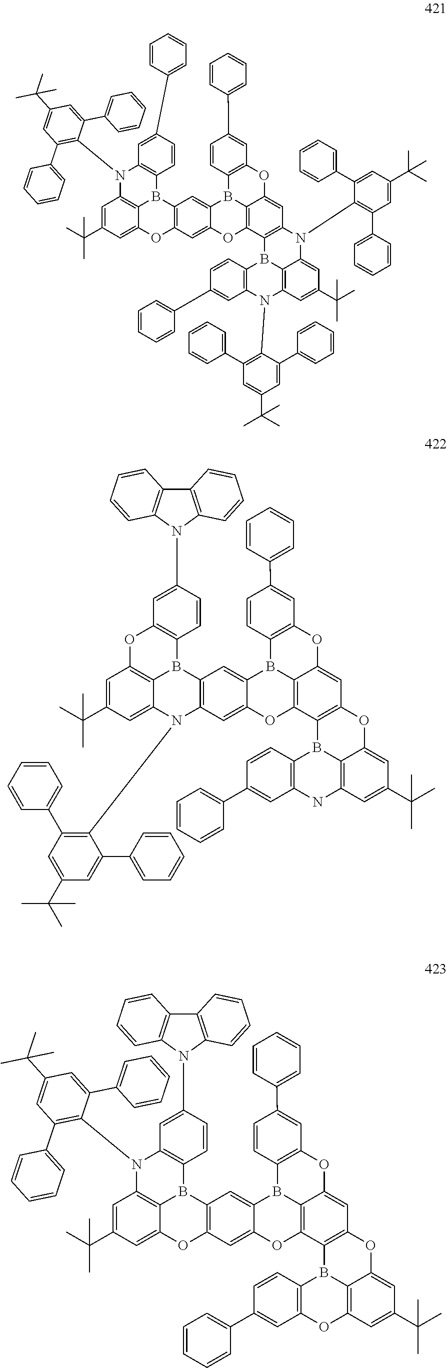

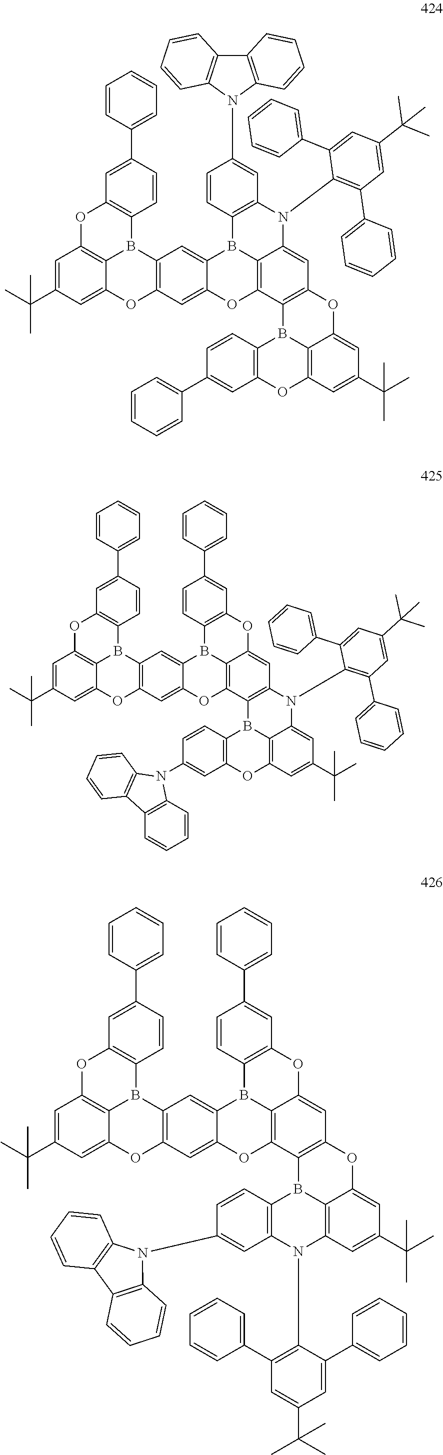

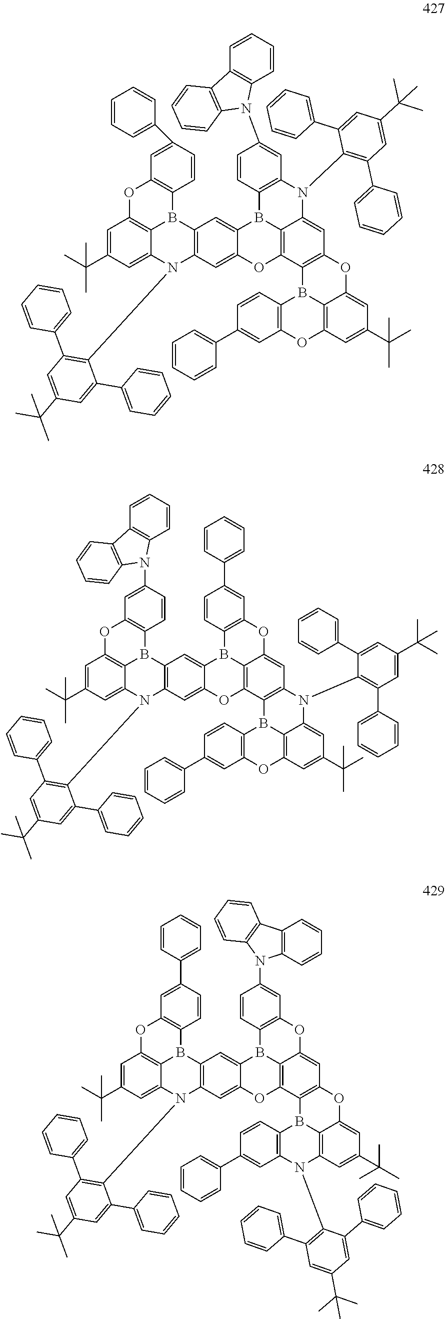

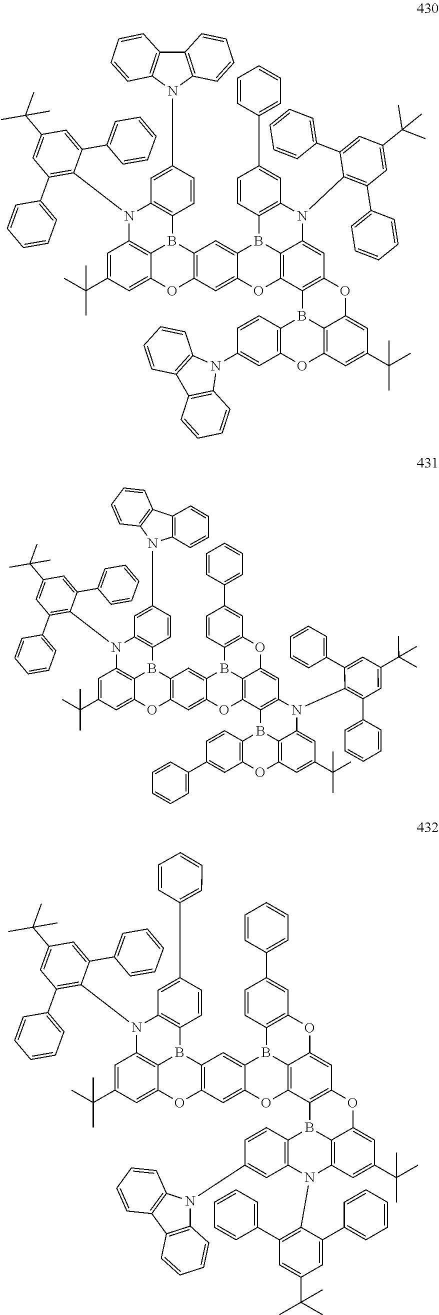

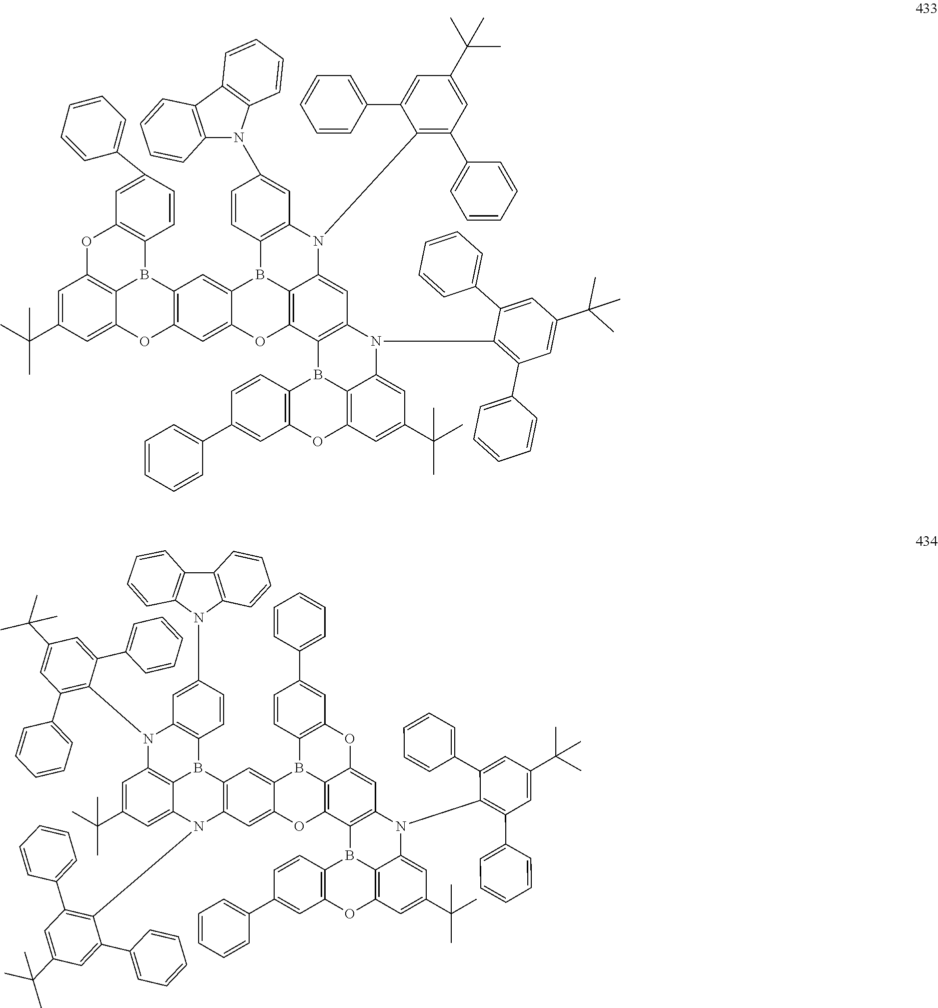

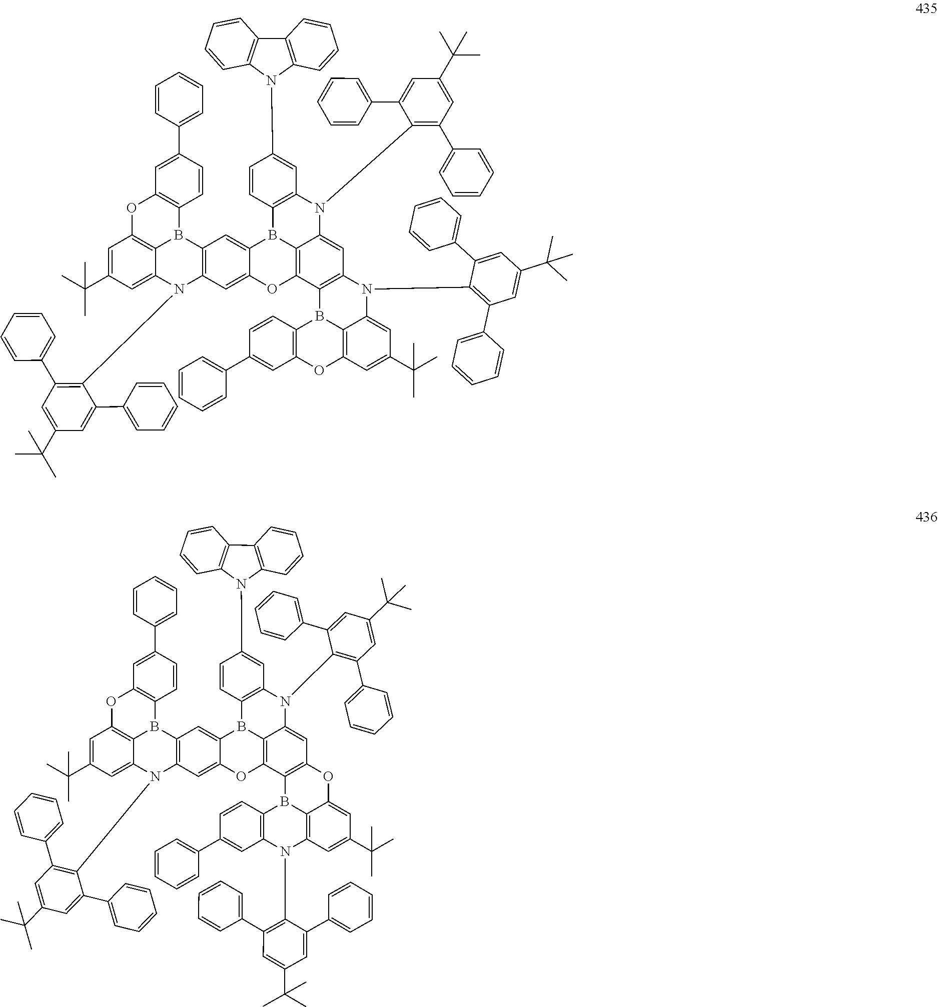

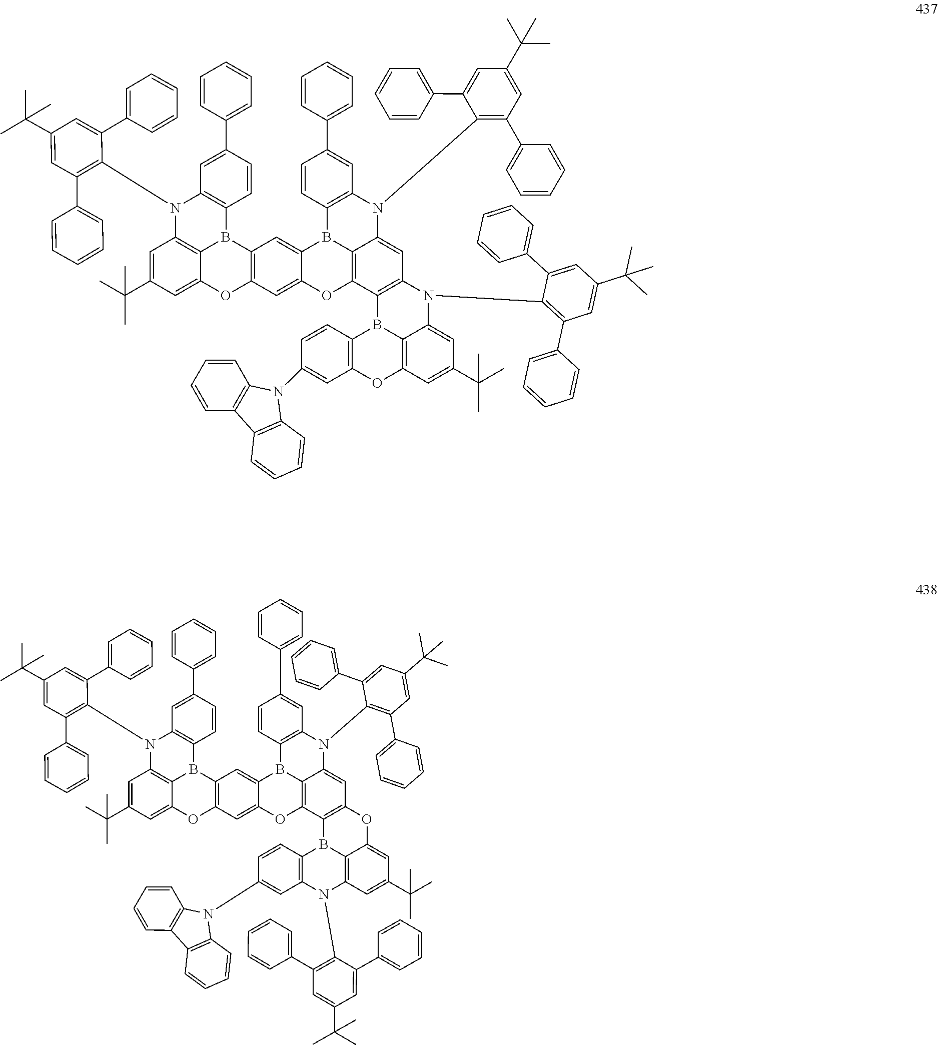

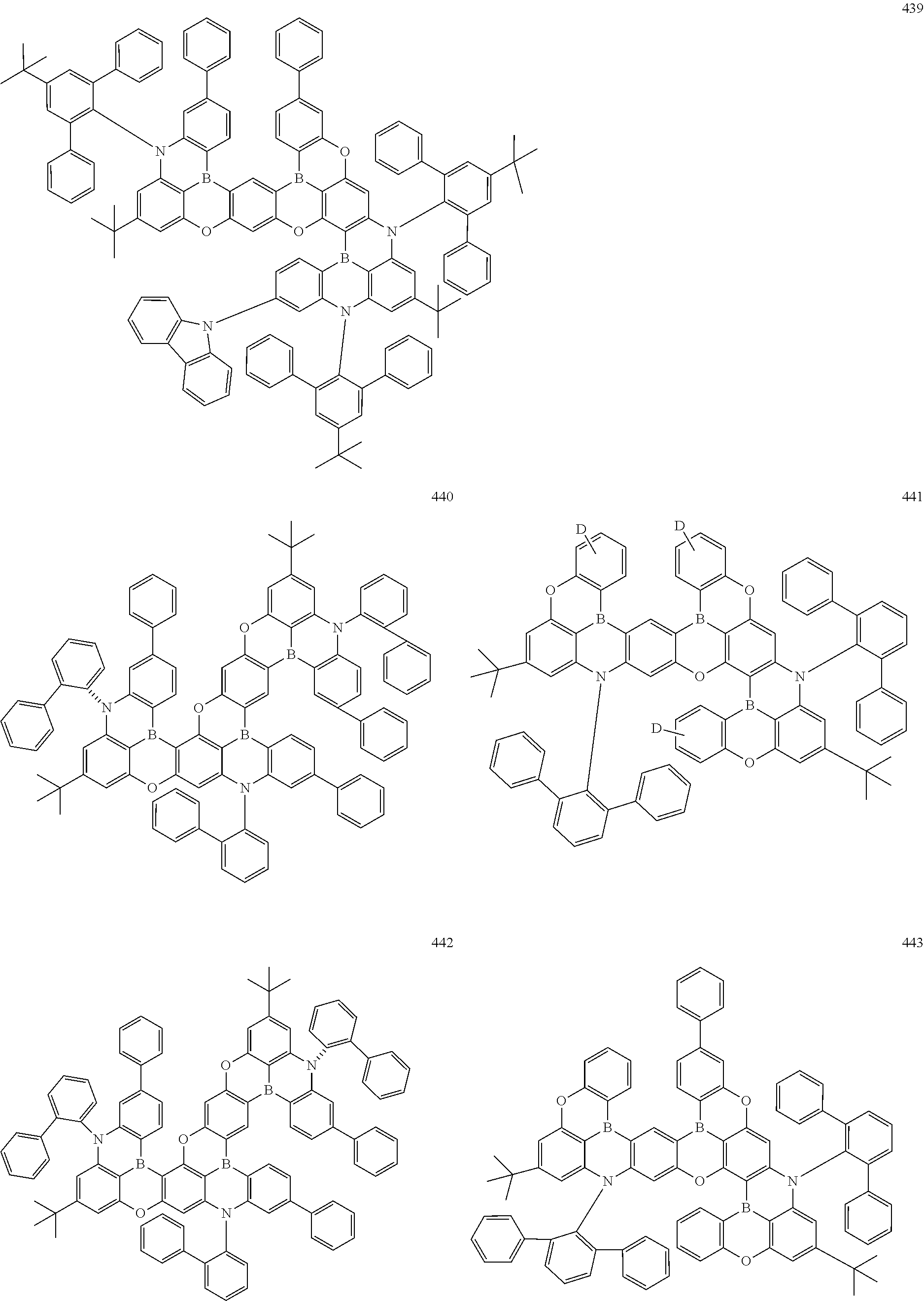

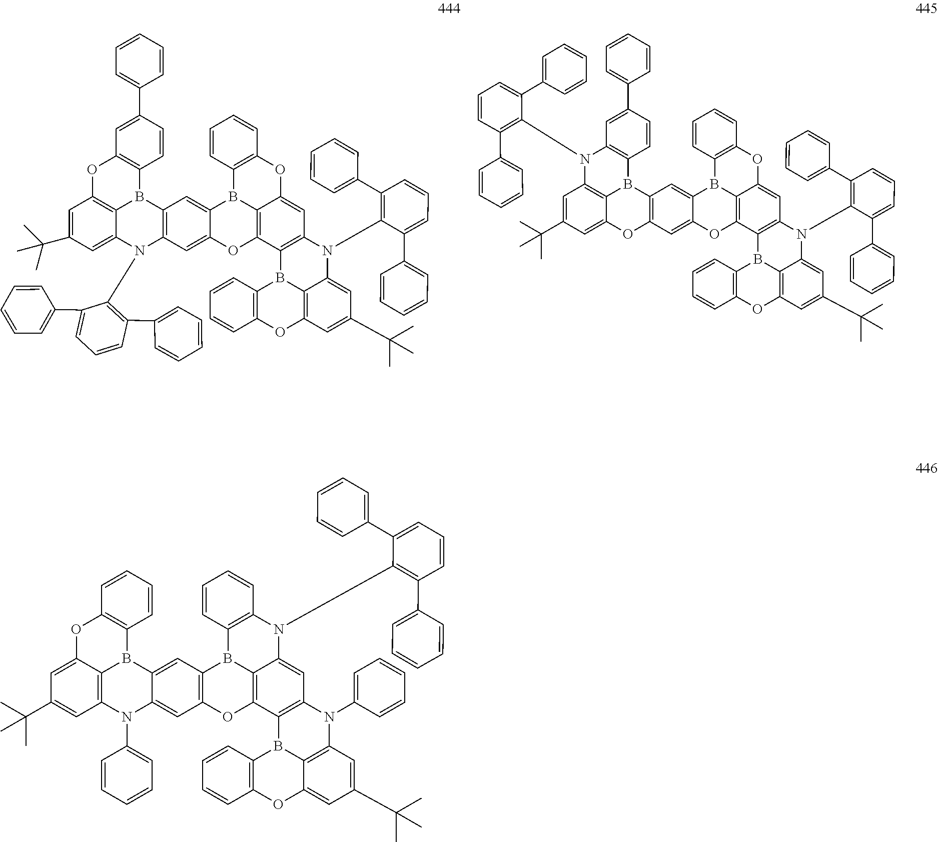

In the particular example compounds presented in Compound Group 1, “D” refers to deuterium.

The fused polycyclic compound according to one or more embodiments may include a core structure in which three fused cyclic moieties are connected (e.g., fused) to include three boron atoms, and may thus have high efficiency and long lifespan.

In the fused polycyclic compound according to one or more embodiments, the second fused cyclic moiety including the second boron atom may connect the first fused cyclic moiety including the first boron atom and the third fused cyclic moiety including the third boron atom. The second fused cyclic moiety may be connected (fused) to the first fused cyclic moiety by sharing one ring. In addition, the second fused cyclic moiety may be connected (fused) to the third fused cyclic moiety by sharing one ring. Accordingly, the fused polycyclic compound according to one or more embodiments may have a structure in which the first to third fused cyclic moieties are connected (e.g., fused) to each other.

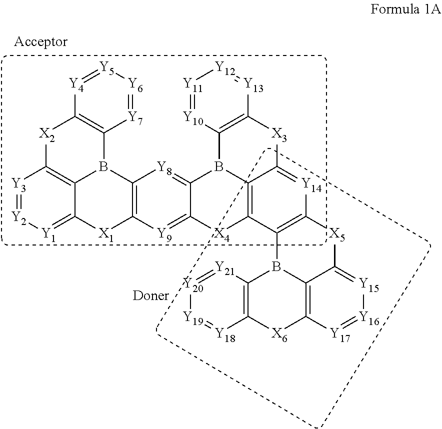

Formula 1A represents an electron acceptor portion and an electron doner portion in Formula 1 according to one or more embodiments. Referring to Formula 1A, in the fused polycyclic compound according to one or more embodiments, a portion where the first fused cyclic moiety and the second fused cyclic moiety are connected (e.g., fused) may be the electron acceptor, and a portion of the third fused cyclic moiety may be the electron doner. Because the first fused cyclic moiety and the second fused cyclic moiety functioning as the electron acceptor and the third fused cyclic moiety functioning as the electron doner are included in a molecular structure, the fused polycyclic compound according to one or more embodiments may have improved multiple resonance characteristics. Accordingly, the fused polycyclic compound according to one or more embodiments may have high luminescence strength, and high absorbance.

In addition, the fused polycyclic compound according to one or more embodiments may have the lowest unoccupied molecular orbital (LUMO) at the portion where the first fused cyclic moiety and the second fused cyclic moiety are connected (e.g., fused), and have the highest occupied molecular orbital (HOMO) at the portion of the third fused cyclic moiety. The fused polycyclic compound according to one or more embodiments may not have LUMO and HOMO evenly distributed in the fused cyclic core, and each of LUMO and HOMO may be distributed biasedly in one portion. For example, the fused polycyclic compound according to one or more embodiments may provide charge transfer (CT) property to the fused cyclic core due to HOMO-LUMO separation, thereby improving luminescence characteristics and contributing to long lifespan of the light-emitting element ED.

In the fused polycyclic compound according to one or more embodiments, a portion including the first and second boron atoms marked with a dashed and dotted line (-⋅-⋅-108 ) in Formula 1A may represent the electron acceptor and LUMO, and a portion including the third boron atom marked with a dotted line (-----) in Formula 1A may represent the electron doner and HOMO.

The fused polycyclic compound according to one or more embodiments may have a core structure where three 5-ring fused cyclic moieties each including one boron atom are connected (e.g., fused), so that delayed fluorescence lifespan may become shorter, thereby contributing to long lifespan of the light-emitting element ED. Furthermore, by having the core structure where three fused cyclic moieties are connected (e.g., fused), the fused polycyclic compound according to one or more embodiments may have improved multiple resonance property and improved stokes-shift, thereby improving material stability and luminescence characteristics of the fused polycyclic compound. Therefore, the light-emitting element ED, including the fused polycyclic compound according to one or more embodiments as a light-emitting material, may exhibit high efficiency and long lifespan characteristics.

In one or more embodiments, the emission spectrum of the fused polycyclic compound according to one or more embodiments, represented by Formula 1, may have a full width at half maximum of about 20 nanometers (nm) to about 40 nm, or of about 20 nm to about 30 nm. Because the emission spectrum of the first compound, represented by Formula 1, has a full width at half maximum in the above-mentioned range, if (e.g., when) the first compound is applied as a dopant material of the light-emitting element ED, excellent or suitable color purity may be exhibited.

In one or more embodiments, the fused polycyclic compound according to one or more embodiments, represented by Formula 1, may be a thermally activated delayed fluorescence luminescent material. In addition, the fused polycyclic compound according to one or more embodiments, represented by Formula 1, may be a thermally activated delayed fluorescent dopant having a difference (ΔE_{ST}) between the lowest triplet excited state energy level (T1) and the lowest singlet excited state energy level (S1) of about 0.2 eV or less. However, embodiments of the present disclosure are not limited thereto.

In one or more embodiments, the fused polycyclic compound according to one or more embodiments, represented by Formula 1, may have a structure in which the first to third fused cyclic moieties are connected (e.g., fused). By controlling the connection structure, substituents, ring-forming atoms, and/or the like of the first to third fused cyclic moieties, singlet energy level and triplet energy level of the overall compound may be appropriately or suitably controlled or selected. Through this, the fused polycyclic compound according to one or more embodiments of the disclosure may have improved thermally activated delayed fluorescence characteristics.

The fused polycyclic compound according to one or more embodiments, represented by Formula 1, may be a light-emitting material having a central emission wavelength in a wavelength range of about 430 nm to about 490 nm. For example, the fused polycyclic compound according to one or more embodiments, represented by Formula 1, may be a blue-color thermally activated delayed fluorescence (TADF) dopant. However, embodiments of the present disclosure are not limited thereto, and the fused polycyclic compound according to one or more embodiments may be used as a dopant material that emits light in one or more suitable wavelength ranges, such as a red-color light-emitting dopant and/or a green-color light-emitting dopant, if (e.g., when) used as a light-emitting material.

In the light-emitting element ED according to one or more embodiments, the emission layer EML may be to emit delayed fluorescence. For example, the emission layer EML may be to emit thermally activated delayed fluorescence (TADF). However, embodiments of the present disclosure are not limited thereto, and the emission layer EML may also emit phosphorescence or fluorescence.

In one or more embodiments, the emission layer EML of the light-emitting element ED may be to emit blue color light. For example, the emission layer EML of the organic electroluminescent light-emitting element ED, according to one or more embodiments, may be to emit blue color light in a wavelength range of about 490 nm or less. However, embodiments of the present disclosure are not limited thereto, and the emission layer EML may also emit green color light or red color light.

In one or more embodiments, the fused polycyclic compound represented by Formula 1 may be included in the emission layer EML. The fused polycyclic compound according to one or more embodiments may be included in the emission layer EML as a dopant material. The fused polycyclic compound according to one or more embodiments may be a thermally activated delayed fluorescence material. The fused polycyclic compound according to one or more embodiments may be used as a thermally activated delayed fluorescence dopant. For example, in the light-emitting element ED according to one or more embodiments, the emission layer EML may include at least one selected from among the fused polycyclic compounds listed in Compound Group 1, described above, as the thermally activated delayed fluorescence dopant. However, the use of the fused polycyclic compound according to one or more embodiments is not limited thereto.

In one or more embodiments, the emission layer EML may include a plurality of compounds. The emission layer EML according to one or more embodiments may include the fused polycyclic compound represented by Formula 1, that is, the first compound, and may further include at least one of a second compound represented by Formula HT-1, a third compound represented by Formula ET-1, or a fourth compound represented by Formula D-1.

In one or more embodiments, the emission layer EML may include the first compound represented by Formula 1, and may further include at least one of the second compound represented by Formula HT-1 or the third compound represented by Formula ET-1.

In one or more embodiments, the emission layer EML may include the second compound represented by Formula HT-1. In one or more embodiments, the second compound may be used as a hole-transporting host material of the emission layer EML.

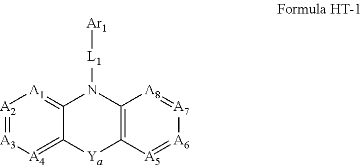

In Formula HT-1, A₁ to A₈ may each independently be N or CR₅₁. For example, in one or more embodiments, A₁ to A₈ may be all CR₅₁. In one or more embodiments, any one selected from among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted hetero arylene group having 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. For example, in Formula HT-1, two 6-membered rings (e.g., two benzene rings) connected to a nitrogen atom may be connected through a direct linkage,

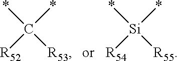

In Formula HT-1, if (e.g., when) Yₐ is a direct linkage, the compound represented by Formula HT-1 may include a carbazole moiety.

In Formula HT-1, Ar₁ may be a substituted or unsubstituted aryl group having 6 to 30 ring-forming carbon atoms or a substituted or unsubstituted hetero aryl group having 2 to 30 ring-forming carbon atoms. For example, in one or more embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₅₁ to R₅₅ may each independently be bonded to an adjacent group to form a ring. For example, in one or more embodiments, R₅₁ to R₅₅ may each independently be hydrogen or deuterium. In one or more embodiments, R₅₁ to R₅₅ may each independently be an unsubstituted methyl group or an unsubstituted phenyl group.

In one or more embodiments, the second compound represented by Formula HT-1 may be any one selected from among compounds listed in Compound Group 2. The emission layer EML may include at least one selected from among the compounds listed in Compound Group 2 as a hole-transporting host material.

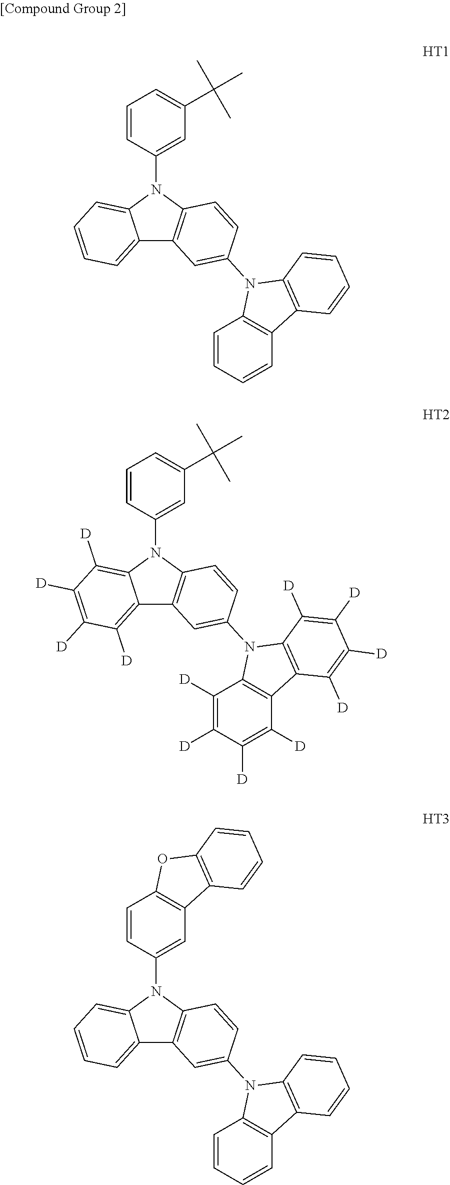 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

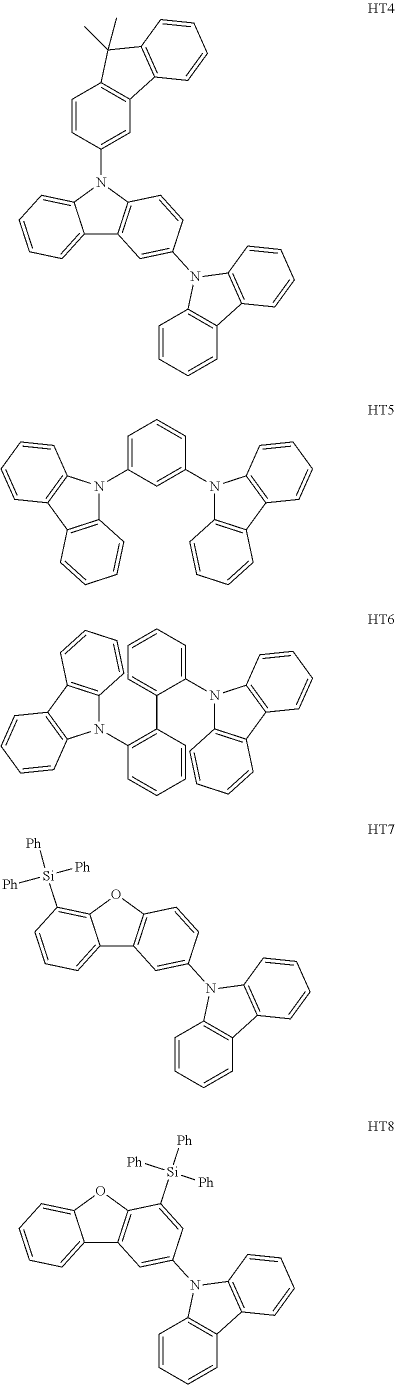

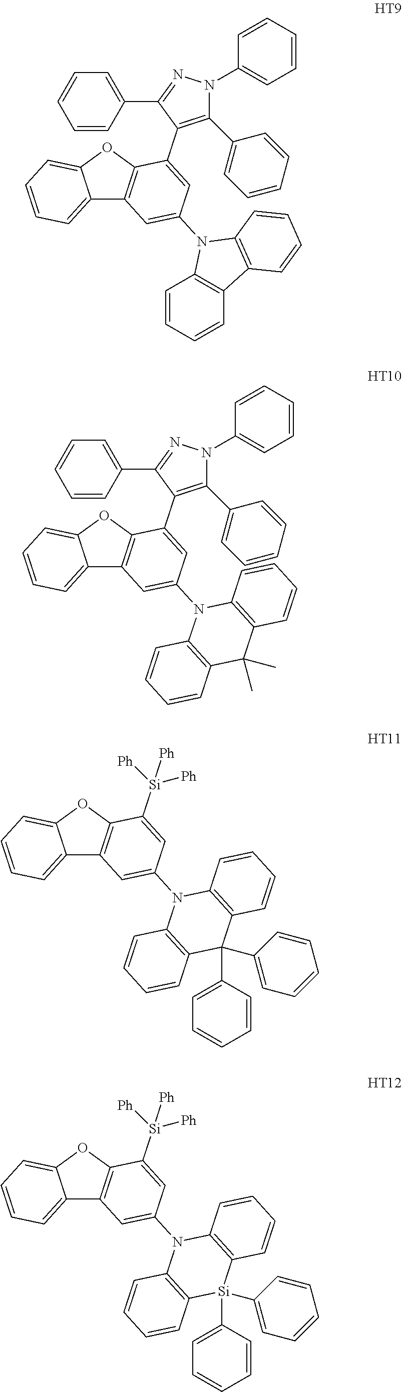 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

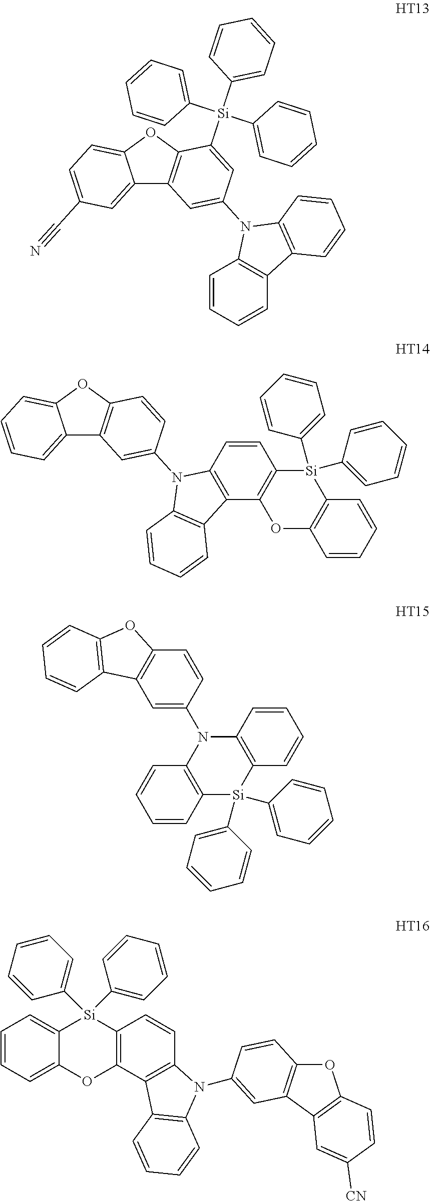 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

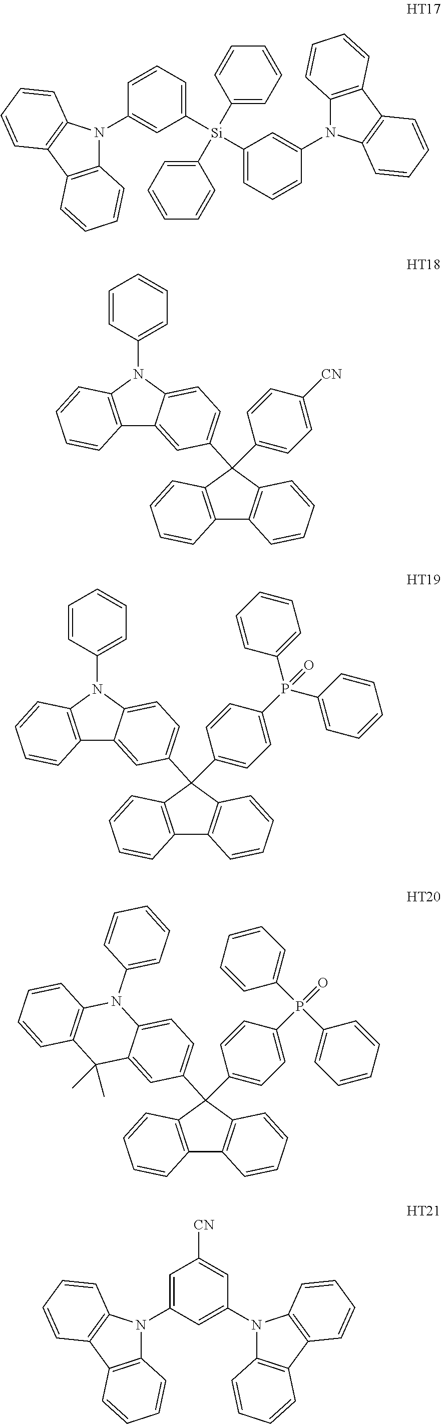 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1]

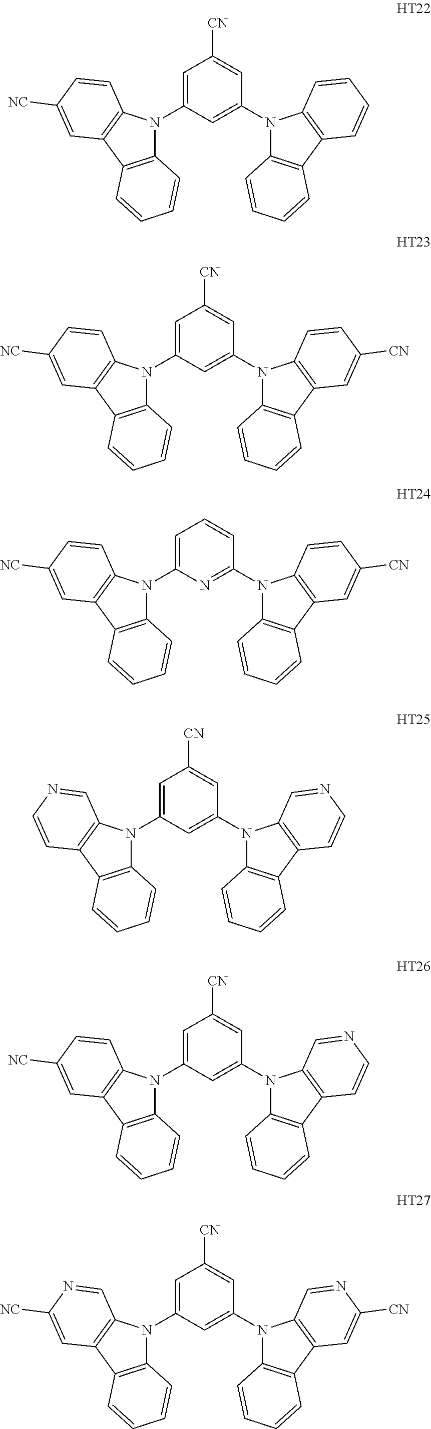 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1]

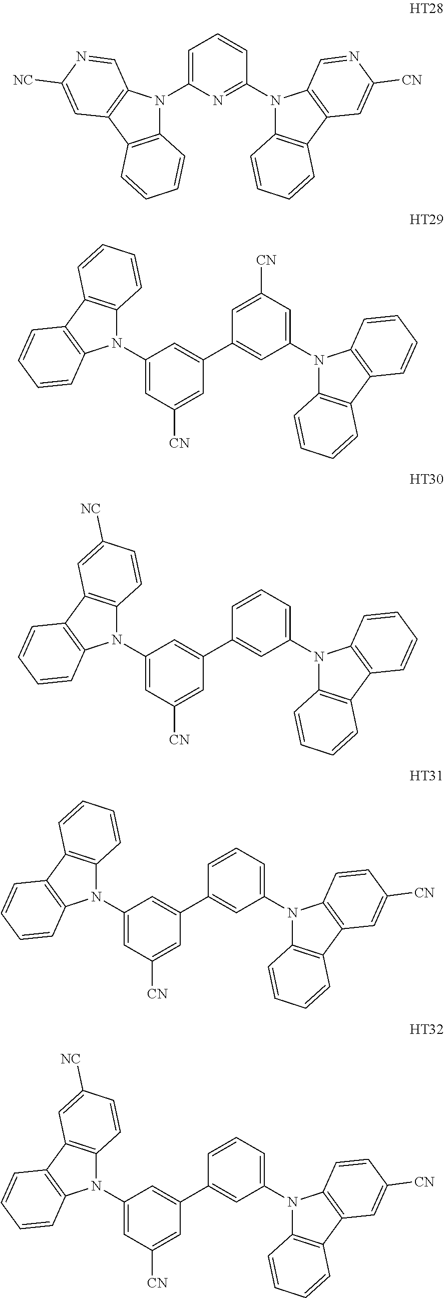 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

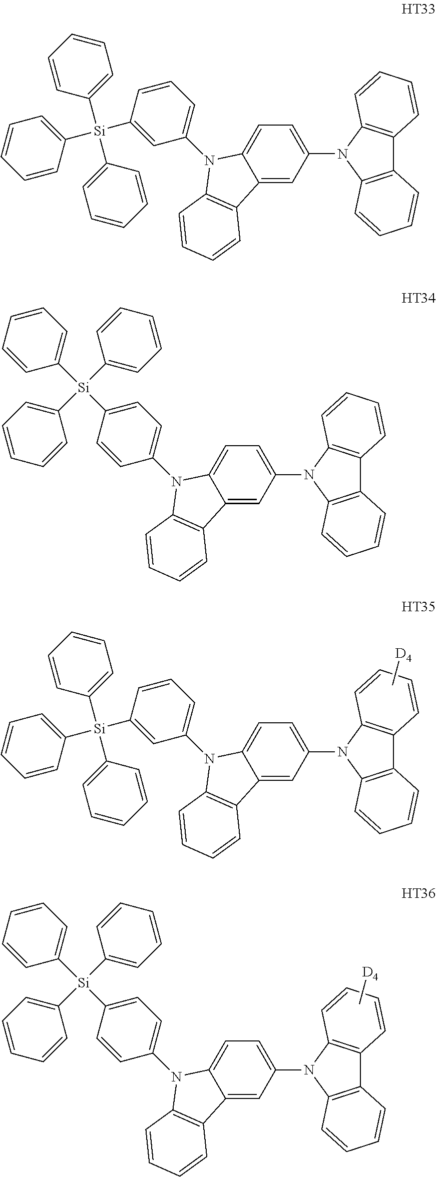

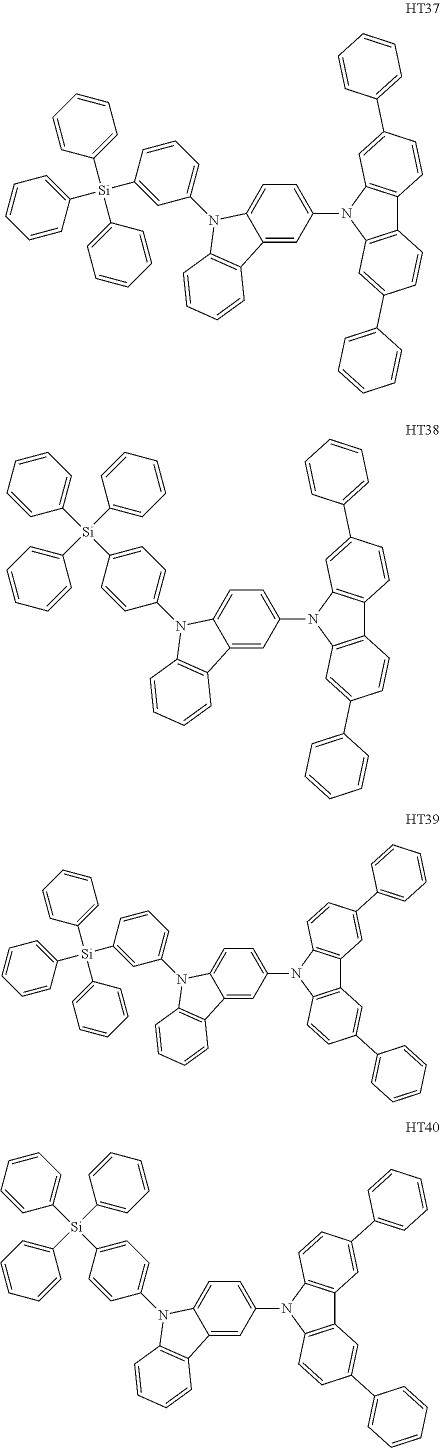 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

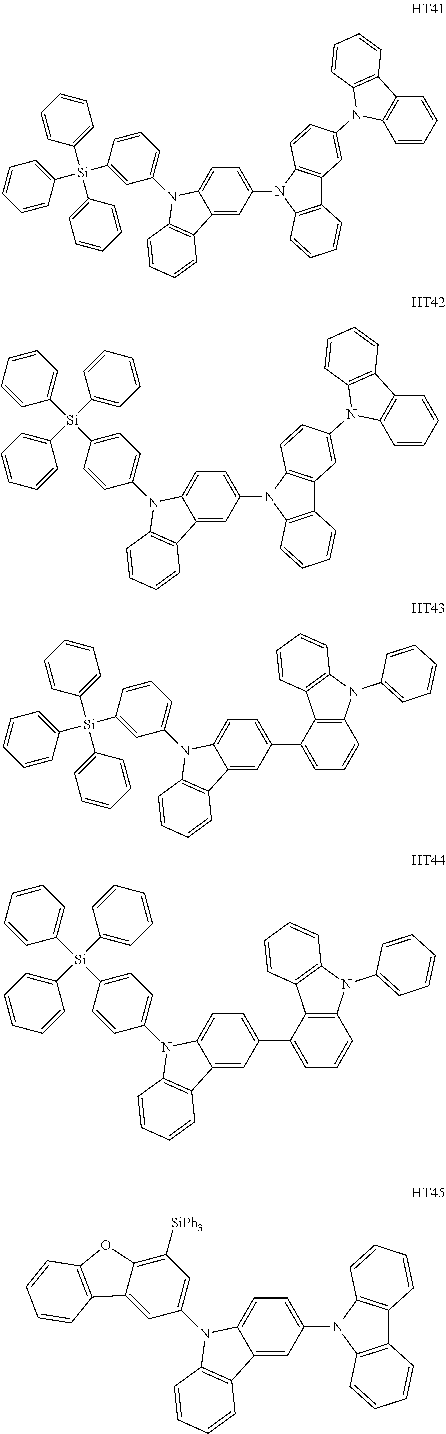

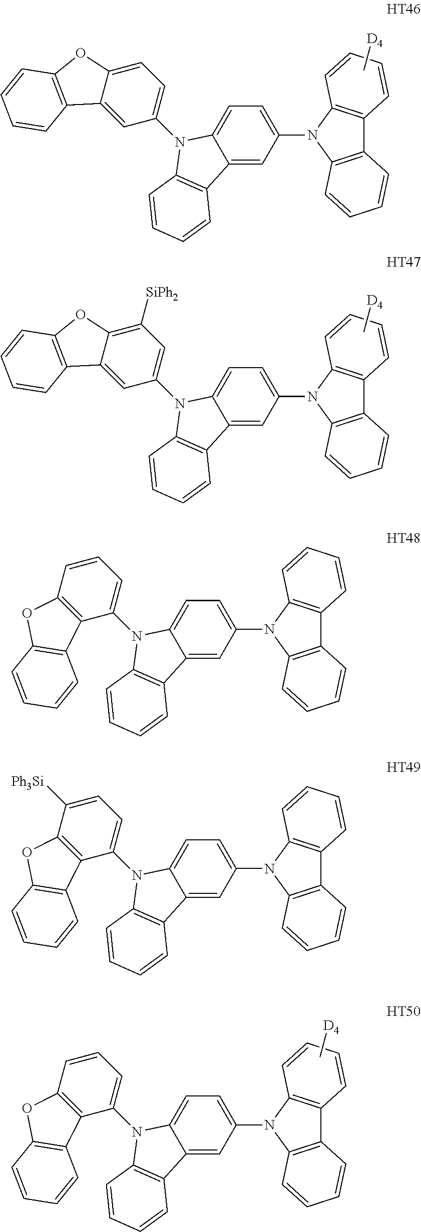

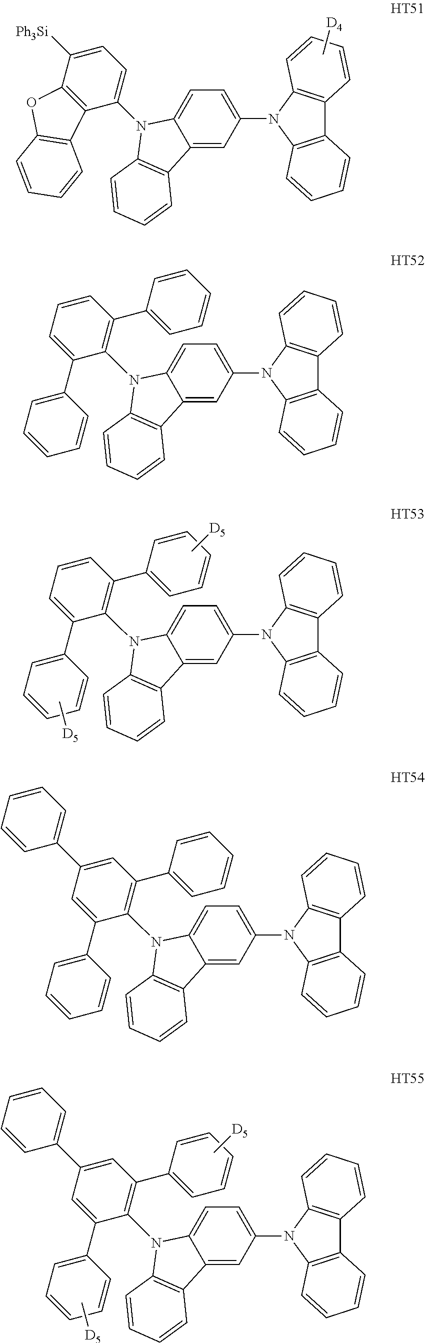

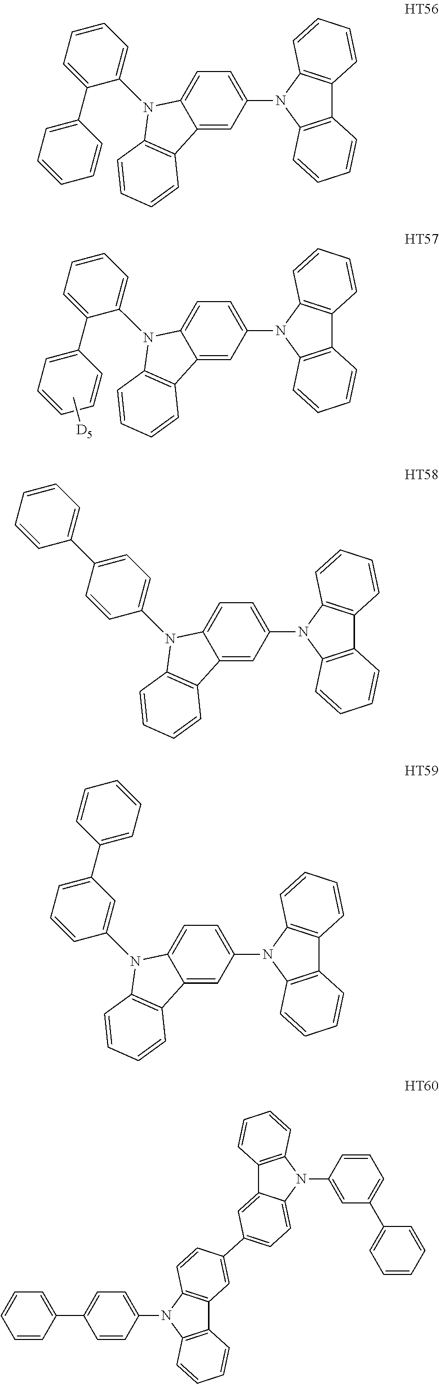

In the particular example compounds presented in Compound Group 2, “D” refers to deuterium, and “Ph” may be an unsubstituted phenyl group.

In one or more embodiments, the emission layer EML may include the third compound represented by Formula ET-1. For example, the third compound may be used as an electron-transporting host material of the emission layer EML.

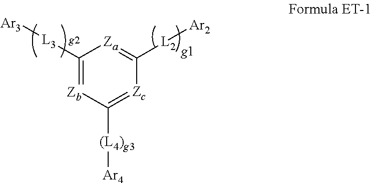

In Formula ET-1, at least one selected from among Zₐ to Z_{c} is N, and the rest are CR₅₆. For example, in one or more embodiments, any one selected from among Zₐ to Z_{c} may be N, and the other two may each independently be CR₅₆. In these embodiments, the third compound represented by Formula ET-1 may include a pyridine moiety. In one or more embodiments, two selected from among Zₐ to Z_{c} may be N, and the other one may be CR₅₆. In these embodiments, the third compound represented by Formula ET-1 may include a pyrimidine moiety. In one or more embodiments, Zₐ to Z_{c} may be all N. In these embodiments, the third compound represented by Formula ET-1 may include a triazine moiety.

In Formula ET-1, R₅₆ may be hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, g1 to g3 may each independently be an integer of 0 or greater and 10 or less.

In Formula ET-1, Ar₂ to Ar₄ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) each of b1 to b3 is an integer of 2 or greater, L₂ to L₄ each in plurality may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be any one selected from among compounds in Compound Group 3. The light-emitting element ED according to one or more embodiments may include at least one (e.g., may be any one) selected from among the compounds in Compound Group 3.

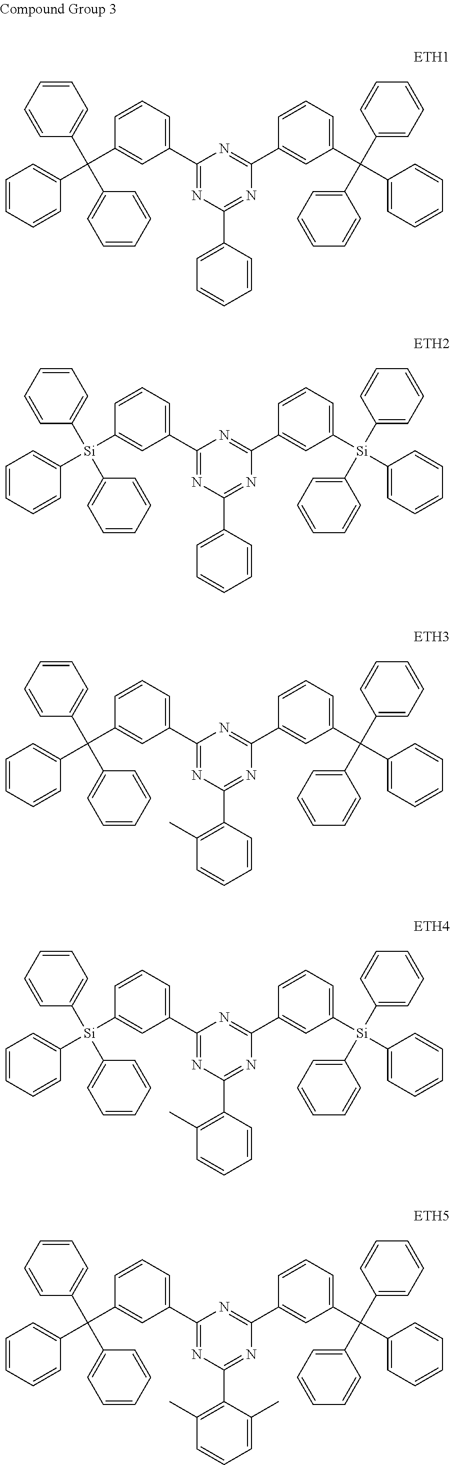

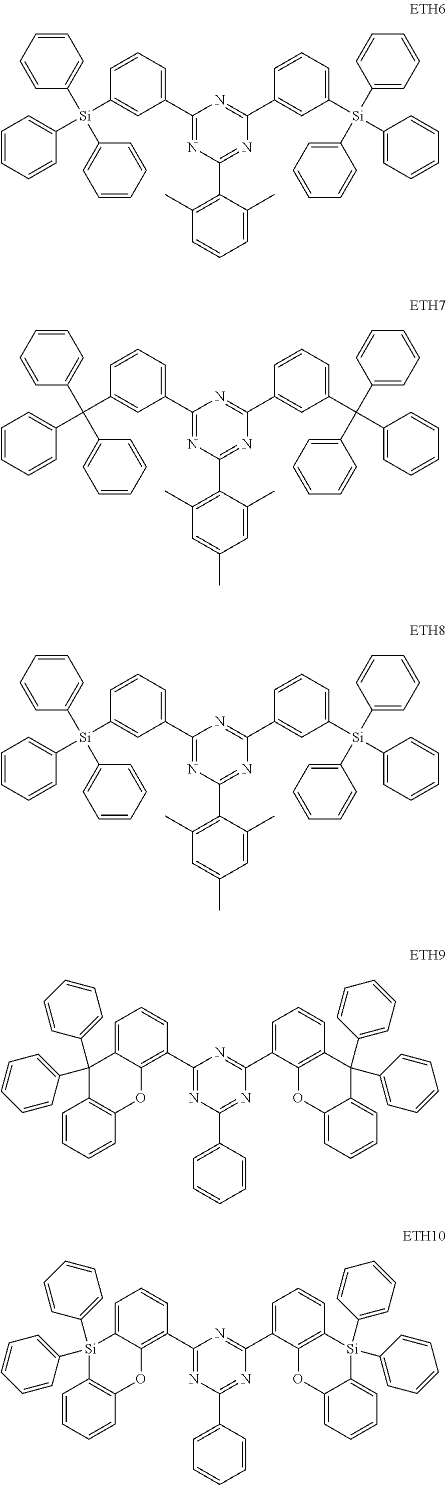

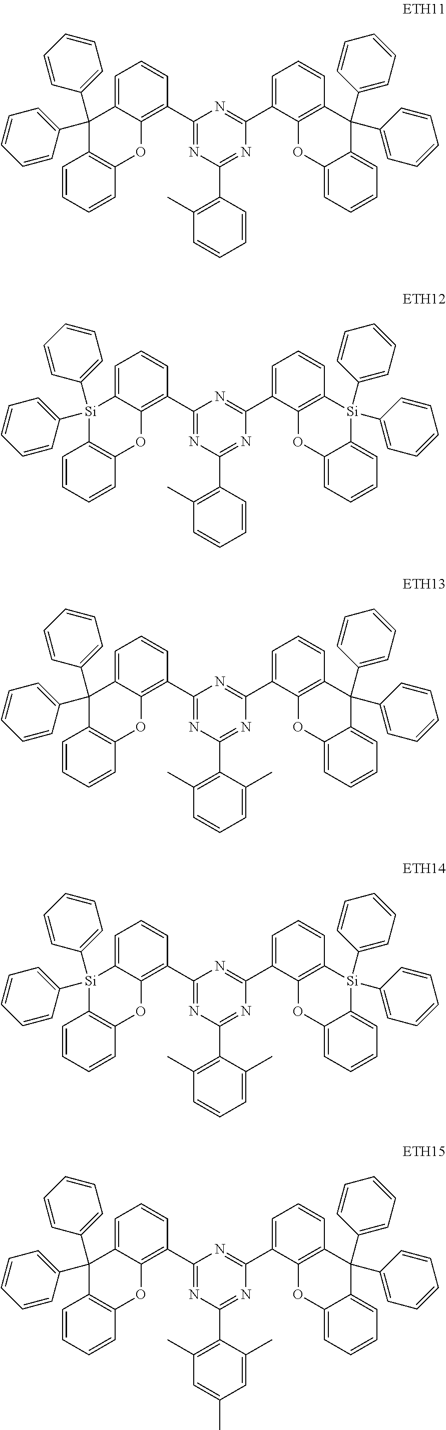

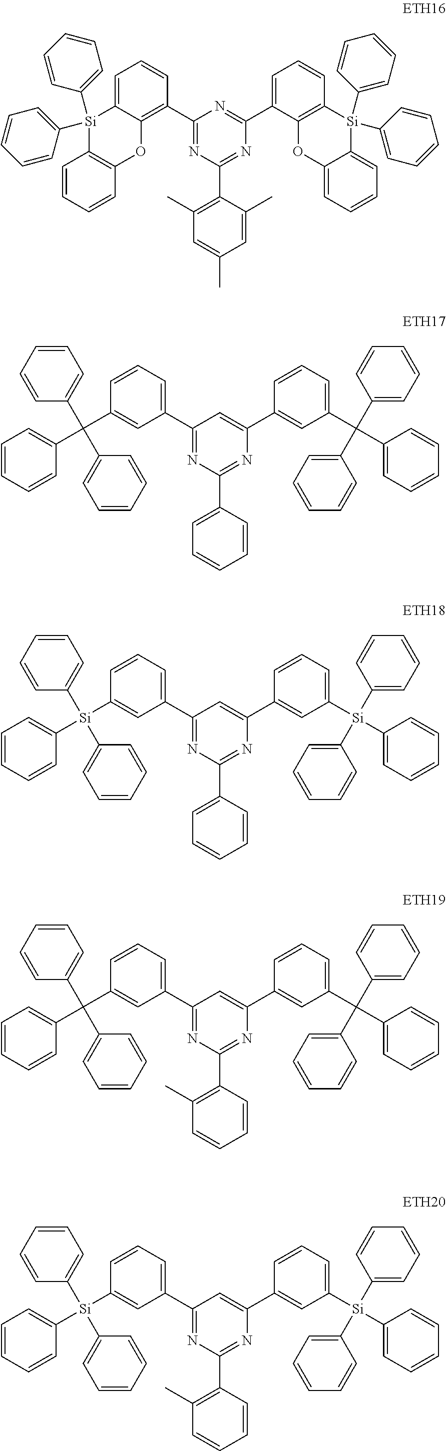

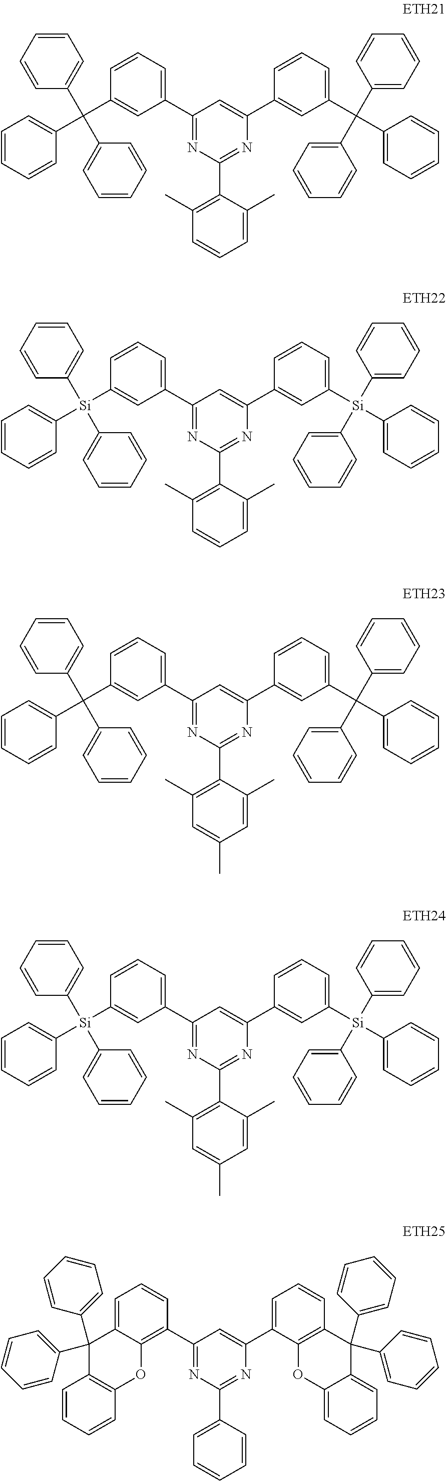

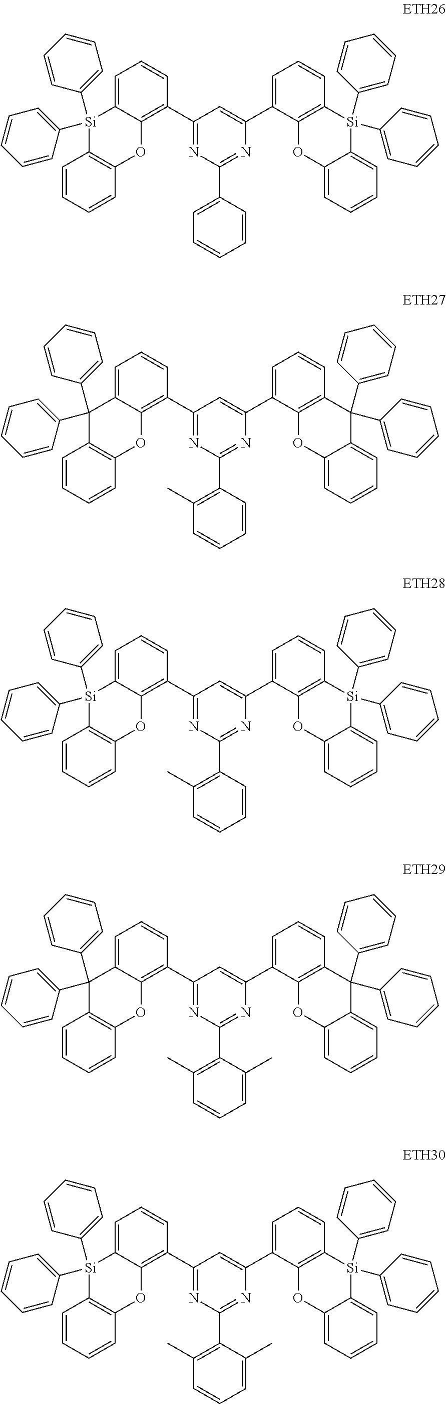

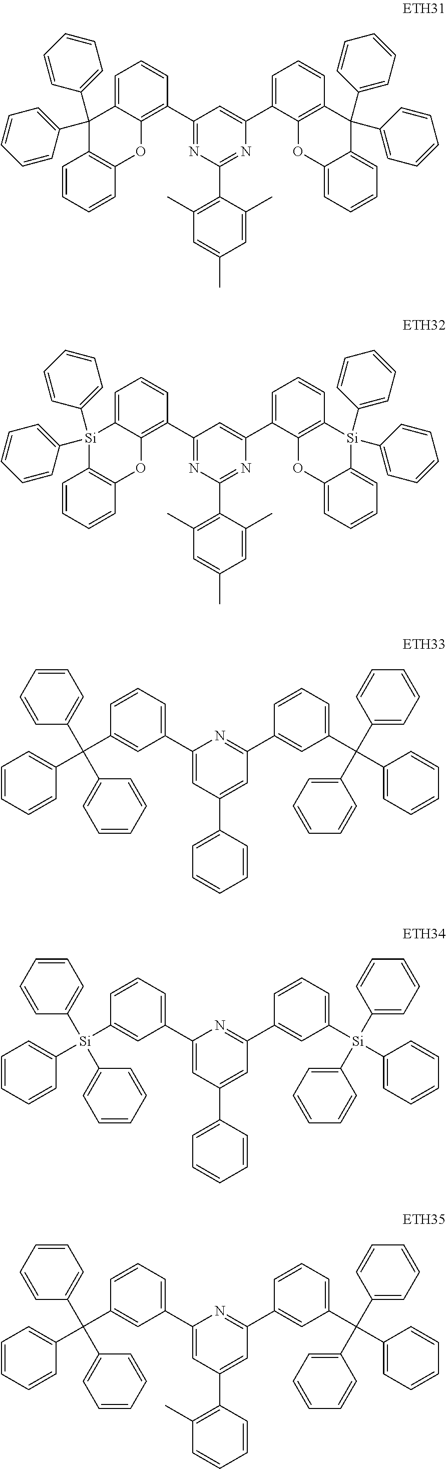

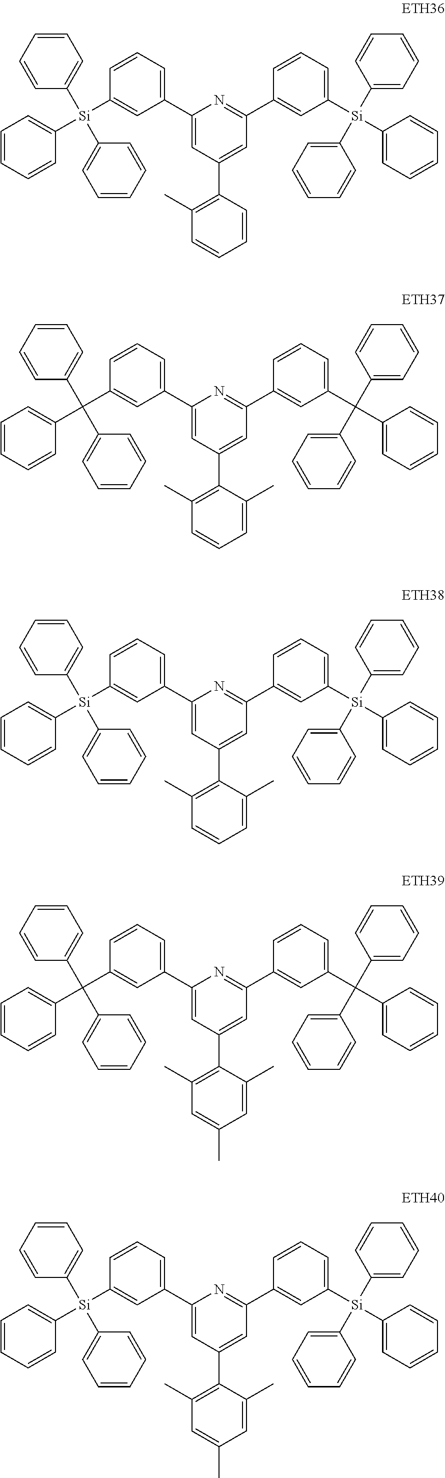

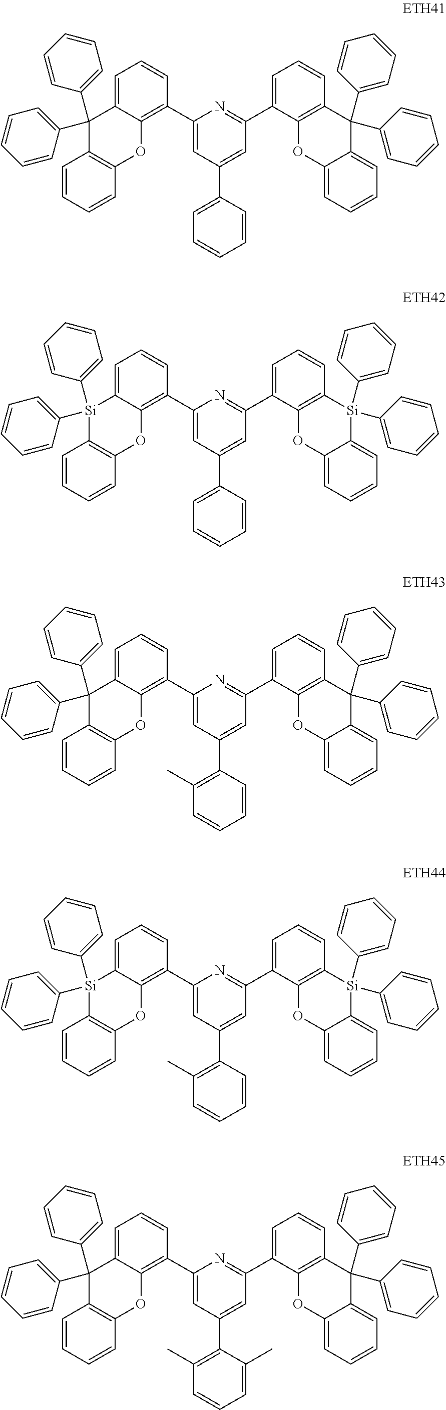

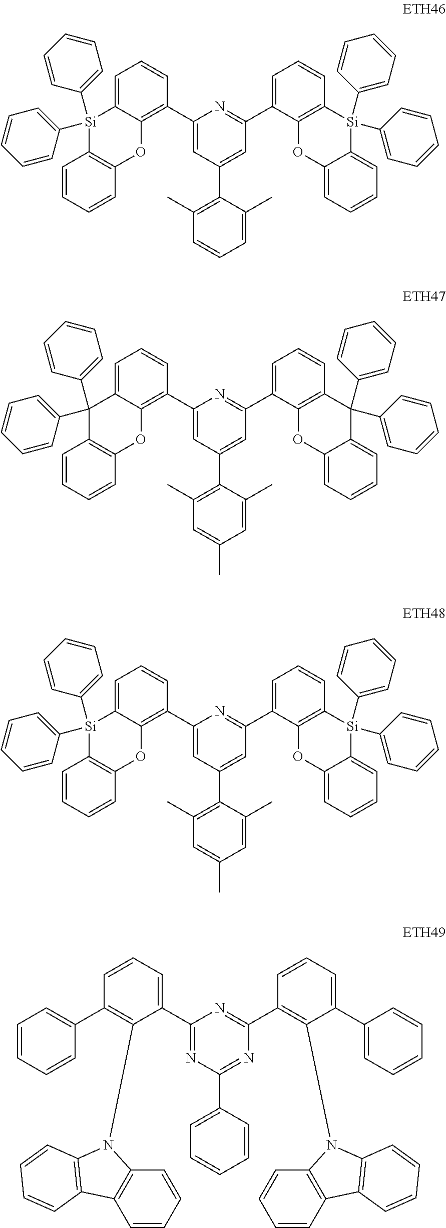 [SMILES: Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1 ; c1ccc(-c2nc(-c3cccc(-c4ccccc4)c3-n3c4ccccc4c4ccccc43)nc(-c3cccc(-c4ccccc4)c3-n3c4ccccc4c4ccccc43)n2)cc1]

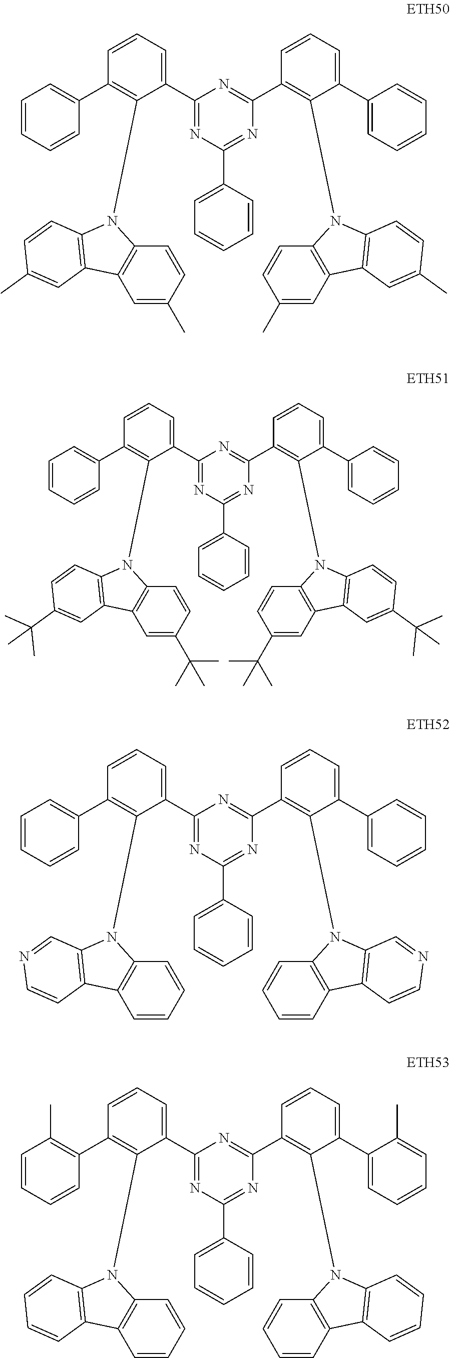

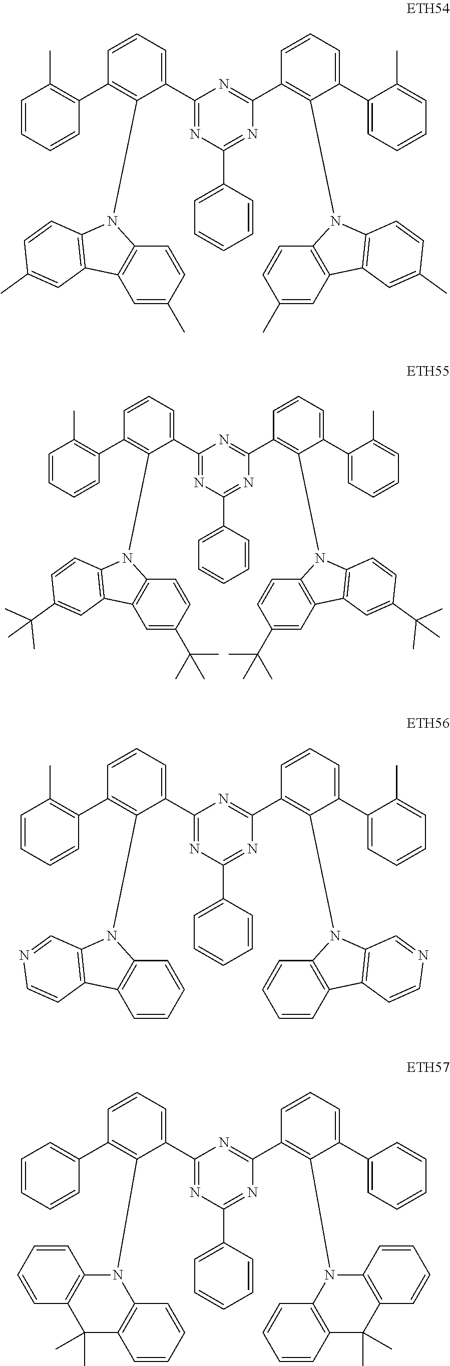

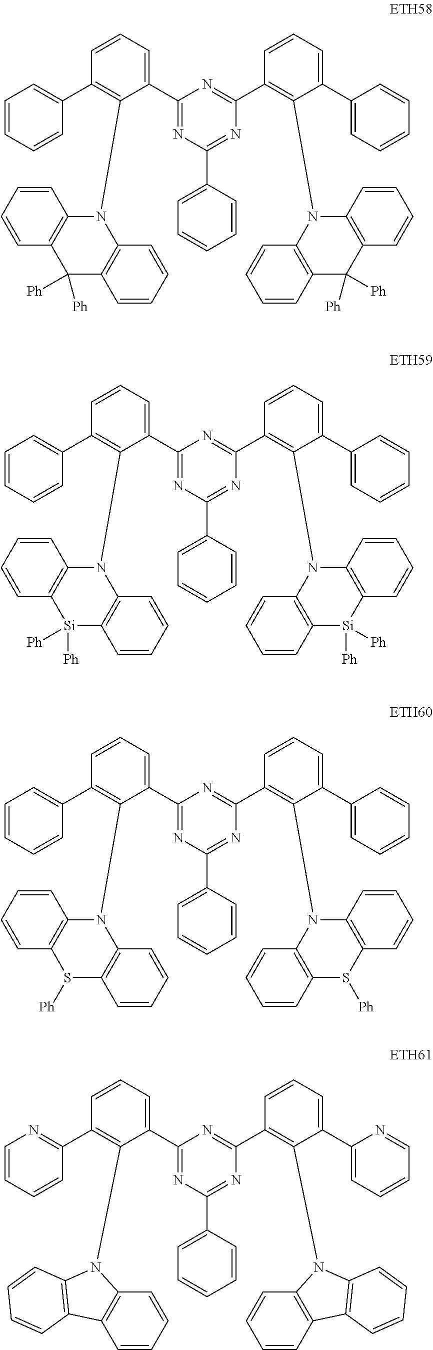

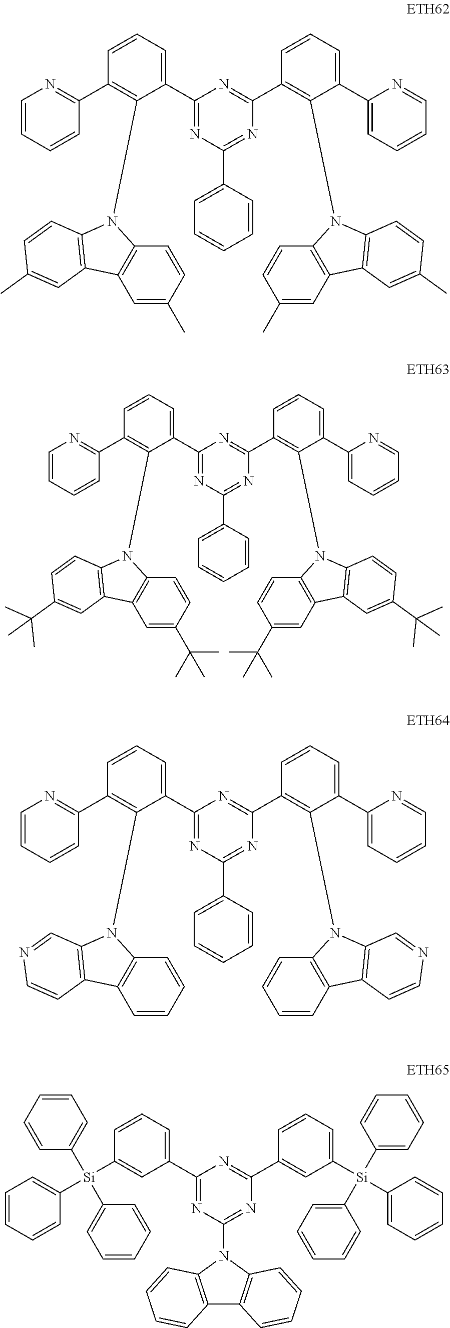

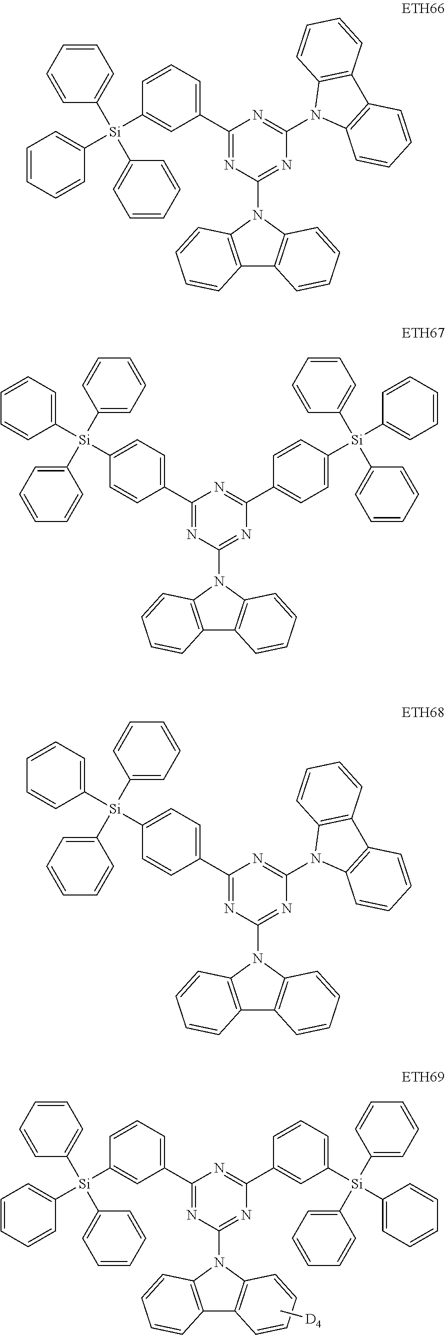

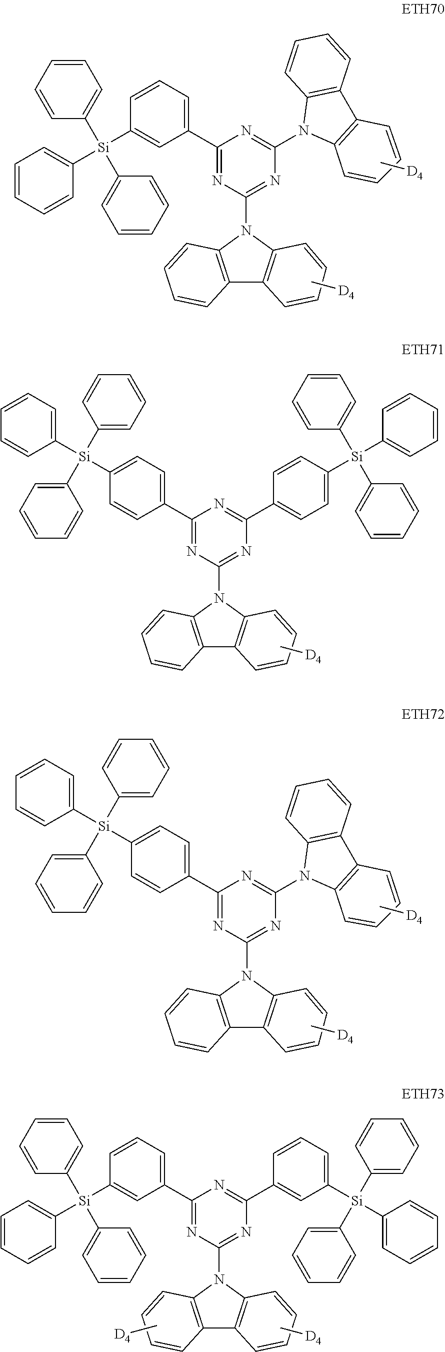

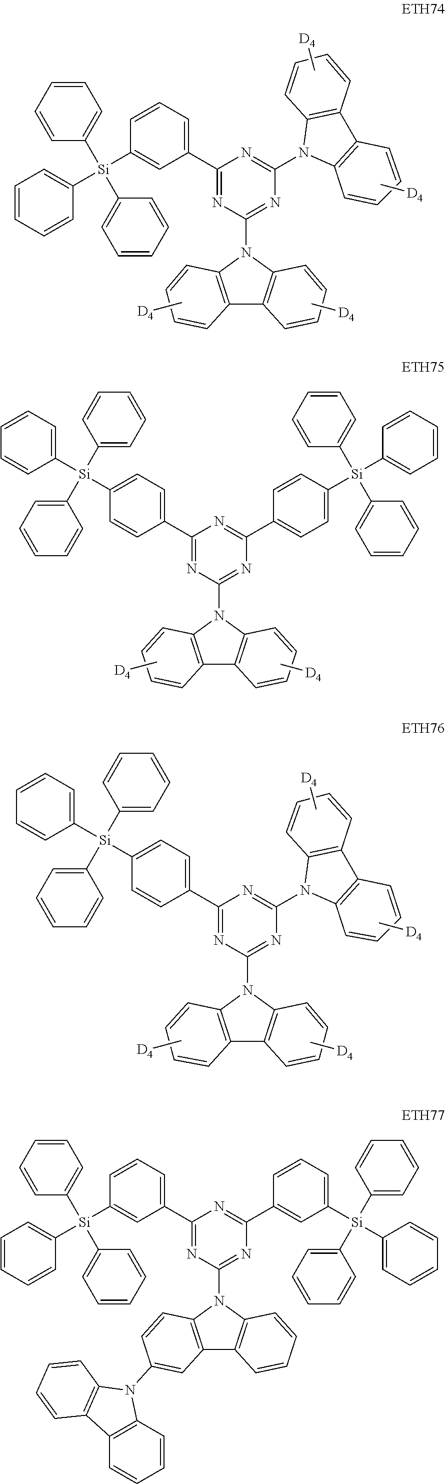

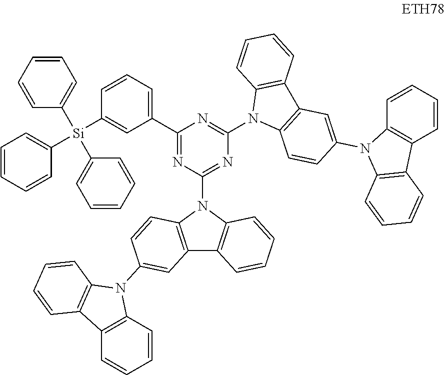 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1]

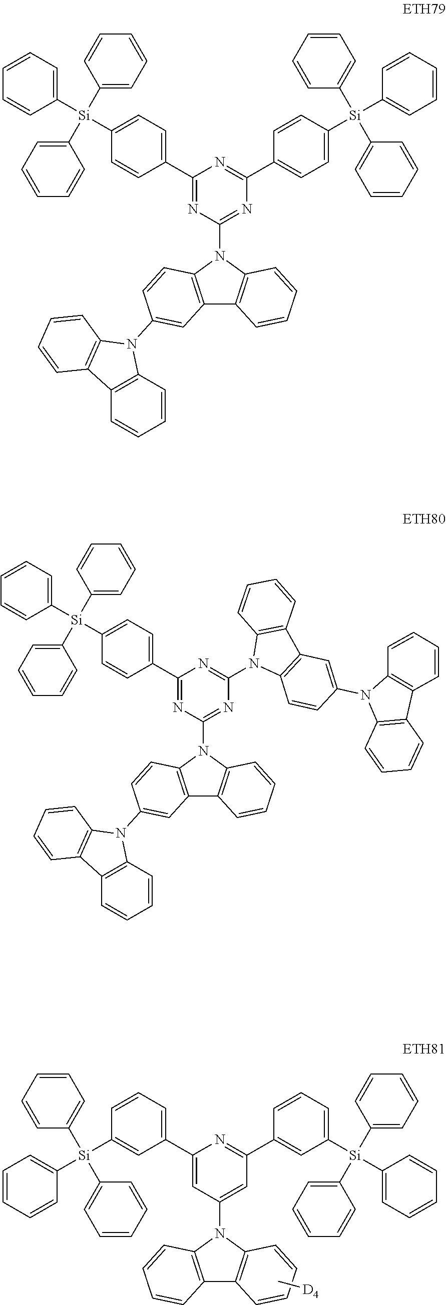

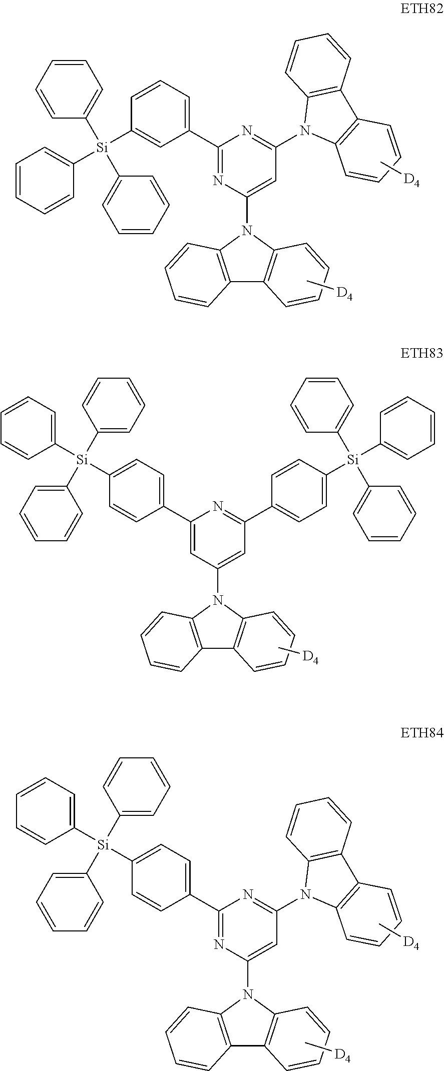

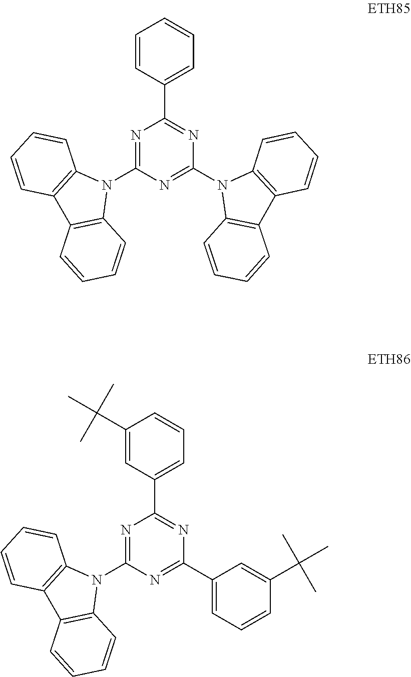 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In the particular example compounds presented in Compound Group 3, “D” refers to deuterium, and “Ph” refers to an unsubstituted phenyl group.

In one or more embodiments, the emission layer EML may include the second compound and the third compound, and the second compound and the third compound may form exciplex. In the emission layer EML, the exciplex may be formed by a hole-transporting host and an electron-transporting host. In this regard, the triplet energy of the exciplex formed by the hole-transporting host and the electron-transporting host may correspond to a difference in energy level between the lowest unoccupied molecular orbital (LUMO) of the electron-transporting host and the highest occupied molecular orbital (HOMO) of the hole-transporting host.

For example, in one or more embodiments, the triplet energy level (T1) of the exciplex formed by the hole-transporting host and the electron-transporting host may have an absolute value of about 2.4 eV or greater and about 3.0 eV or less. In addition, the triplet energy of the exciplex may have a smaller value than that of the energy gap of each host material. The exciplex may have a triplet energy of about 3.0 eV or less which is an energy gap of the hole-transporting host and the electron-transporting host.

In one or more embodiments, the emission layer EML may include the fourth compound in addition to the above-described first compound to third compound. The fourth compound may be used as a phosphorescent sensitizer of the emission layer EML. Energy may be transferred from the fourth compound to the first compound to cause emission.

For example, in one or more embodiments, the emission layer EML may include an organic metal complex containing platinum (Pt) as a central metal atom and ligands bonded to the central metal atom, as the fourth compound. In the light-emitting element ED according to one or more embodiments, the emission layer EML may include a compound represented by Formula D-1 as the fourth compound.

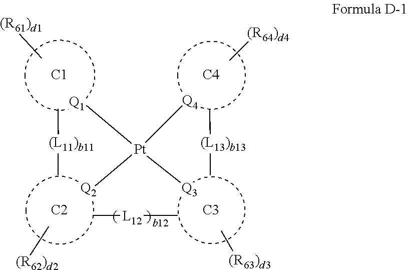

In Formula D-1, Q₁ to Q₄ may each independently be C or N.

In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage, *—O—*, *—S—*,

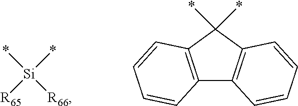

a substituted or unsubstituted alkylene group having 1 to 20 carbon atoms, a substituted or unsubstituted arylene group having 6 to 30 ring-forming carbon atoms, or a substituted or unsubstituted hetero arylene group having 2 to 30 ring-forming carbon atoms. In L₁₁ to L₁₃, “-*” refers to a portion to be connected to C1 to C4.

In Formula D-1, b11 to b13 may each independently be 0 or 1. If (e.g., when) b11 is 0, C1 and C2 may not be connected to each other. If (e.g., when) b12 is 0, C2 and C3 may not be connected to each other. If (e.g., when) b13 is 0, C3 and C4 may not be connected to each other.

In Formula D-1, R₆₁ to R₆₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₆₁ to R₆₆ may each independently be bonded to an adjacent group to form a ring. In one or more embodiments, R₆₁ to R₆₆ may each independently be a substituted or unsubstituted methyl group or a substituted or unsubstituted t-butyl group.

In Formula D-1, d1 to d4 may each independently be an integer of 0 or greater and 4 or less. In Formula D-1, if (e.g., when) each of d1 to d4 is 0, the fourth compound may not be substituted with R₆₁ to R₆₄. If (e.g., when) each of d1 to d4 is 4, and each of R₆₁ to R₆₄ is hydrogen, the embodiment may be the same as the embodiment in which each of d1 to d4 is 0. If (e.g., when) each of d1 to d4 is an integer of 2 or greater, R₆₁ to R₆₄ each provided in plurality may be the same as each other, or at least one selected from among R₆₁ to R₆₄ each in plurality may be different.

In Formula D-1, C₁ to C₄ may each independently be a substituted or unsubstituted hydrocarbon ring or a substituted or unsubstituted heterocycle represented by any one selected from among C-1 to C-5.

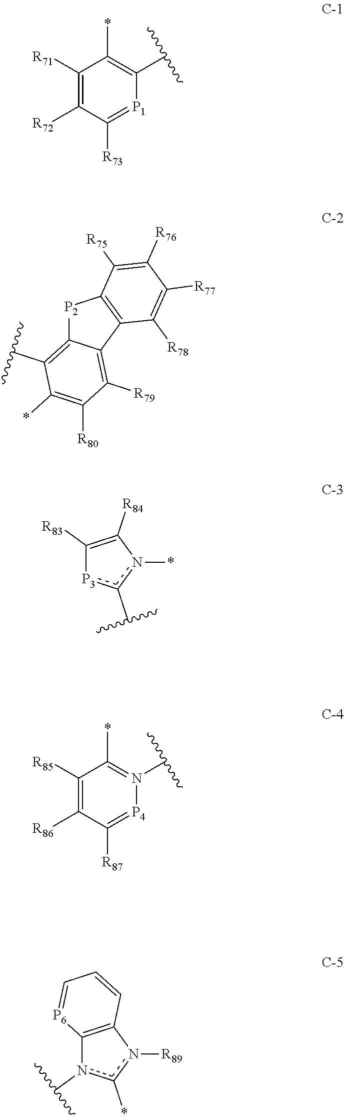

In C-1 to C-5, P₁ may be C—* or CR₇₄, P₂ may be N—* or NR₈₁, P₃ may be N—* or NR₈₂, and P₄ may be C—* or CR₈₈, and P₆ may be C—* or CR₉₀. R₇₁ to R₉₀ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may each independently be bonded to an adjacent group to form a ring.

In addition, in C-1 to C-5,

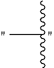

corresponds to a portion connected to Pt that is the central metal atom, and “-*” corresponds to a portion connected to an adjacent ring group (C1 to C4) or an adjacent linker (L₁₁ to L₁₃).

The emission layer EML according to one or more embodiments may include the first compound that is the fused polycyclic compound, and at least one selected from among the second to fourth compounds. For example, in one or more embodiments, the emission layer EML may include the first compound, the second compound, and the third compound. In the emission layer EML, the second compound and the third compound may form exciplex, and energy may be transferred from the exciplex to the first compound to cause emission.

In one or more embodiments, the emission layer EML may include the first compound, the second compound, the third compound, and the fourth compound. In the emission layer EML, the second compound and the third compound may form exciplex, and energy may be transferred from the exciplex to the fourth compound and the first compound to cause emission. In one or more embodiments, the fourth compound may be a sensitizer. In the light-emitting element ED according to one or more embodiments, the fourth compound included in the emission layer EML may function as a sensitizer, and serve to transfer the energy from a host to the first compound that is a light-emitting dopant. For example, in one or more embodiments, the fourth compound, which serves as an auxiliary dopant, may accelerate the energy transfer to the first compound that is a light-emitting dopant, thereby increasing the luminescence ratio of the first compound. Therefore, the emission layer EML according to one or more embodiments may have improved luminescence efficiency. In addition, if (e.g., when) the energy transfer to the first compound increases, excitons formed in the emission layer EML may be to emit light quickly without being stagnant inside the emission layer EML, thereby reducing degradation of the element. Therefore, the light-emitting element ED according to one or more embodiments may have increased lifespan.

The light-emitting element ED according to one or more embodiments may include all of the first compound, the second compound, the third compound, and the fourth compound, and therefore, the emission layer EML may include two host materials and two dopant material in combination. In the light-emitting element ED according to one or more embodiments, the emission layer EML may concurrently include the second compound and the third compound which are two different hosts, the first compound that emits delayed fluorescence, and the fourth compound containing an organic metal complex, thereby exhibiting excellent or suitable luminescence efficiency characteristics.

In one or more embodiments, the fourth compound represented by Formula D-1 may be at least one (e.g., any one) selected from among compounds listed in Compound Group 4. The emission layer EML may include at least one selected from among the compounds listed in Compound Group 4 as a sensitizer material.

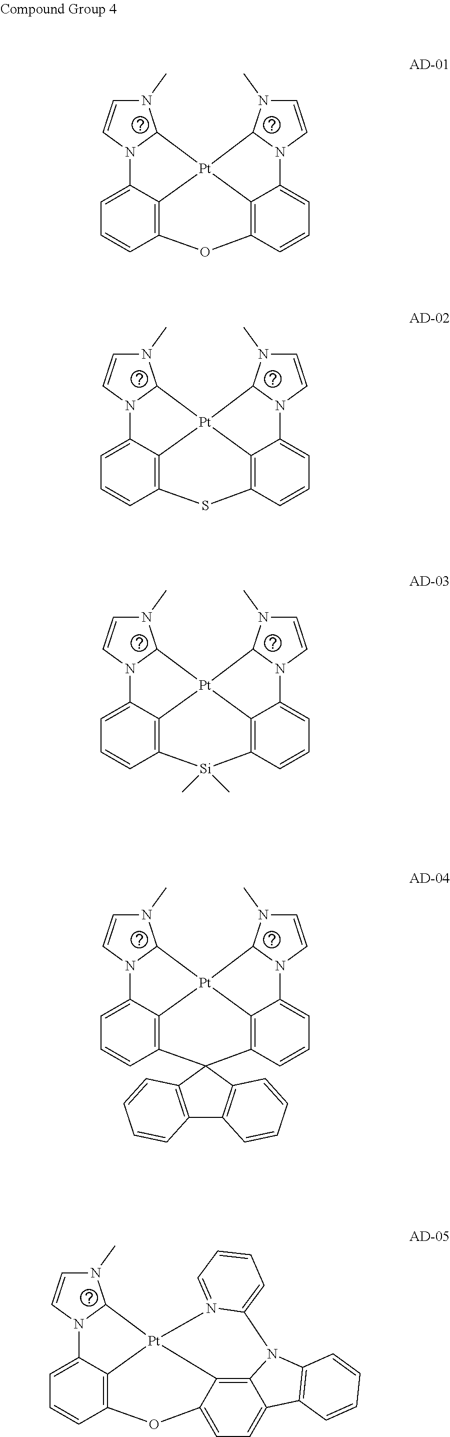

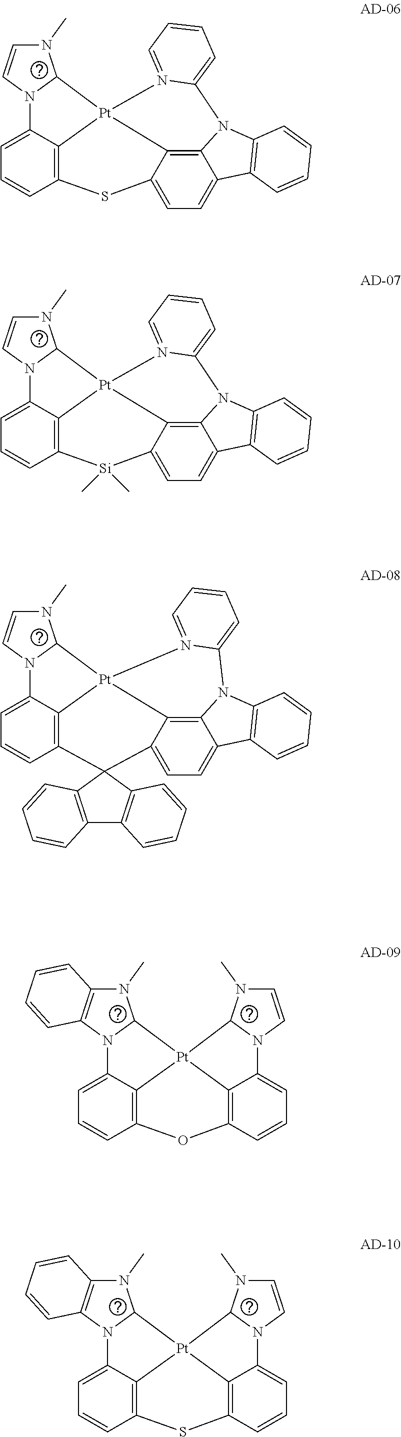

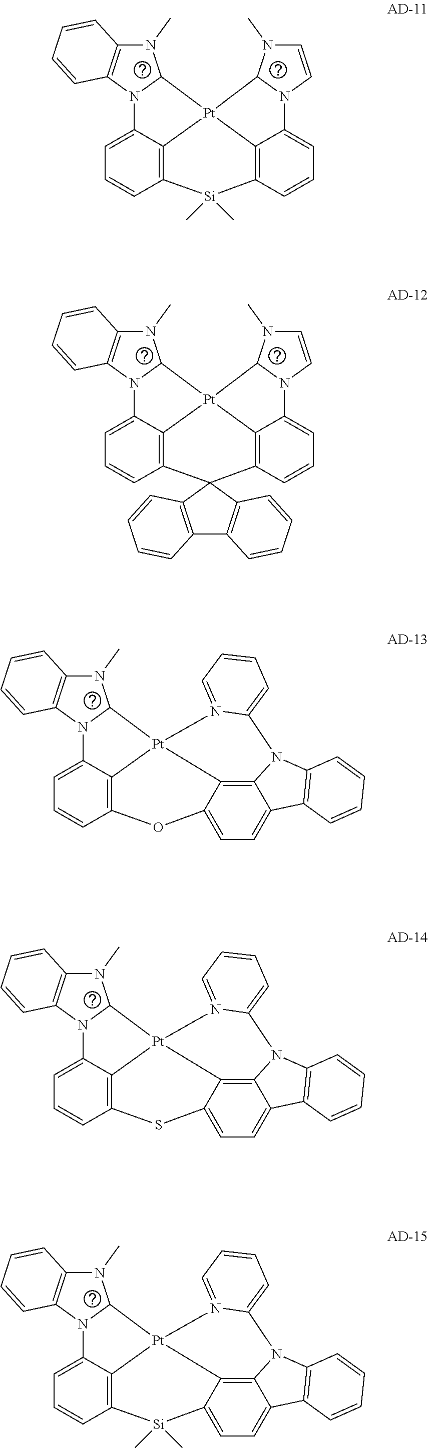

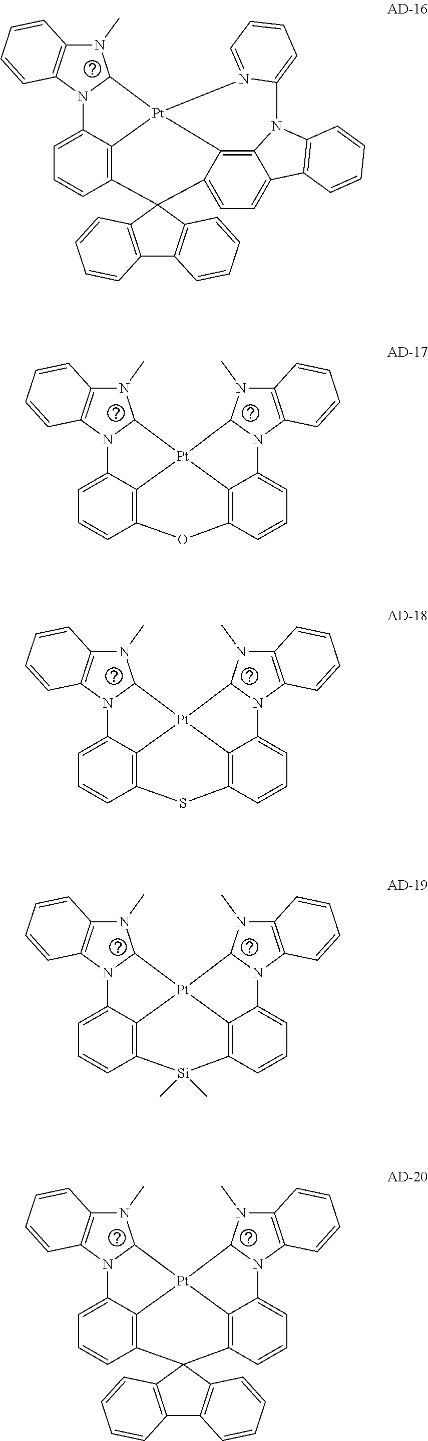

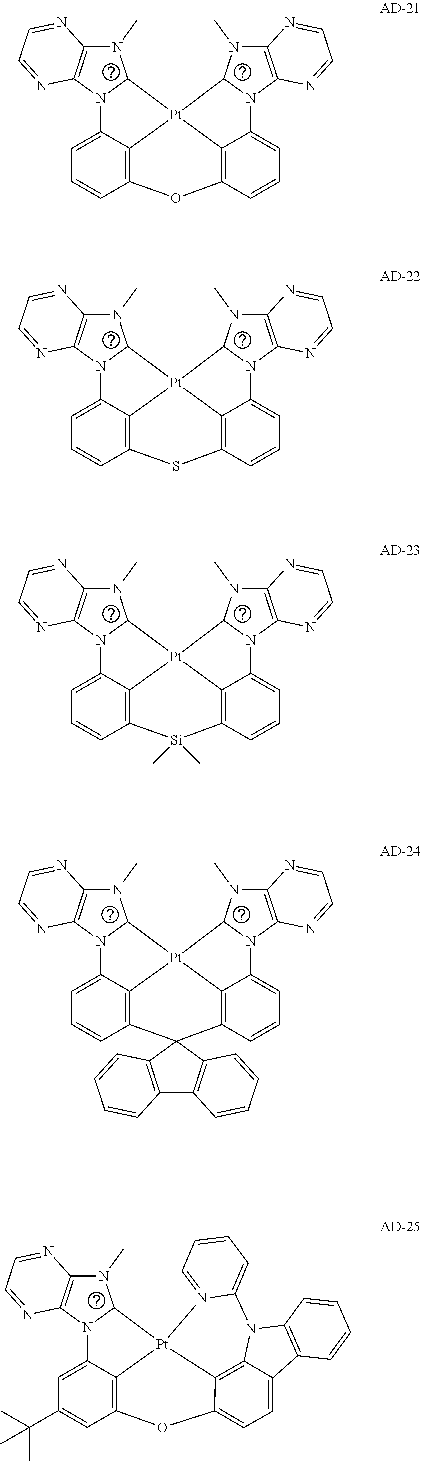

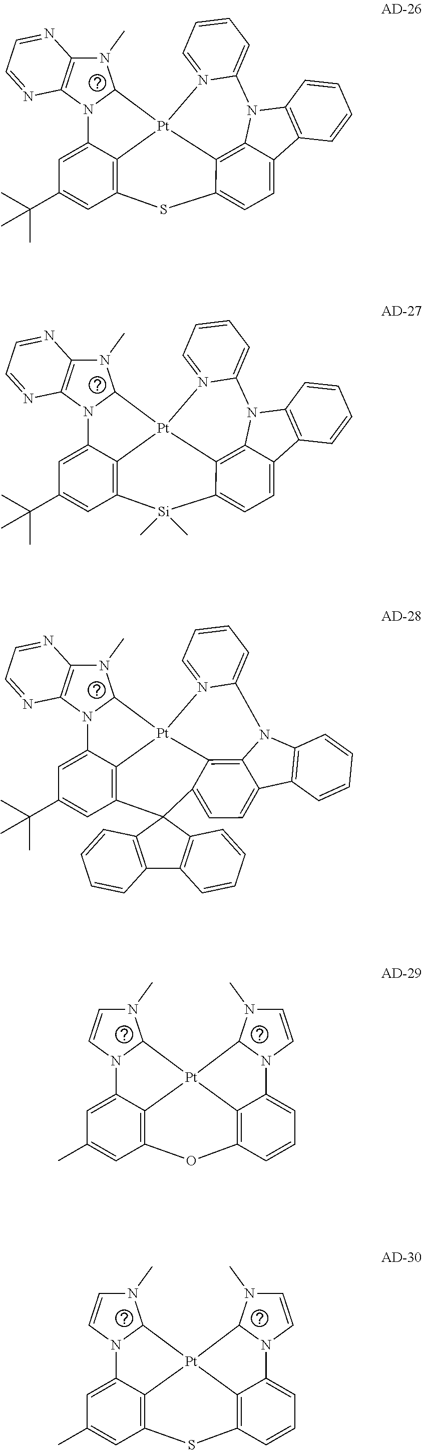

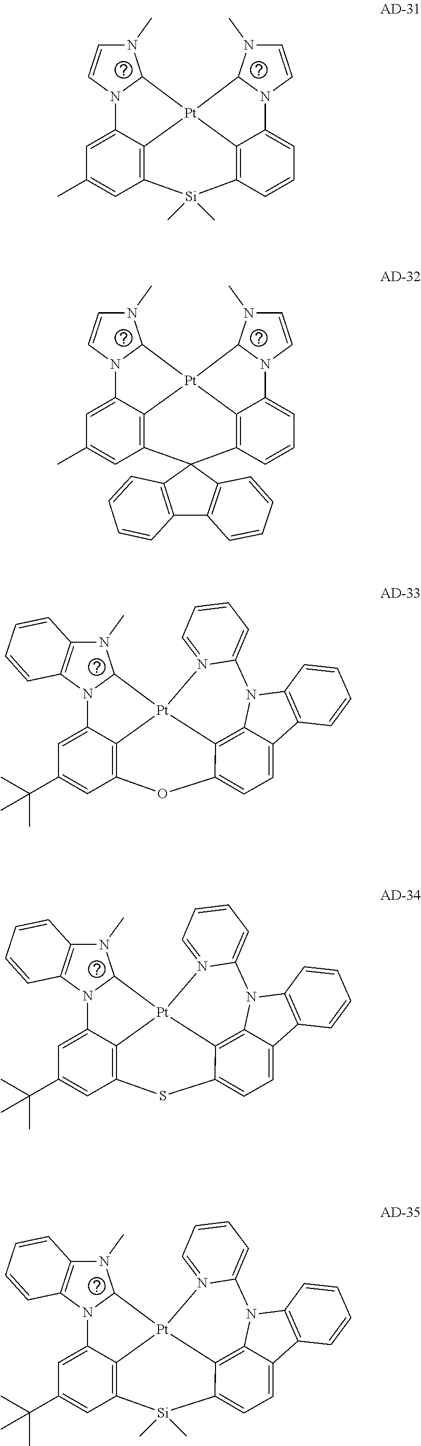

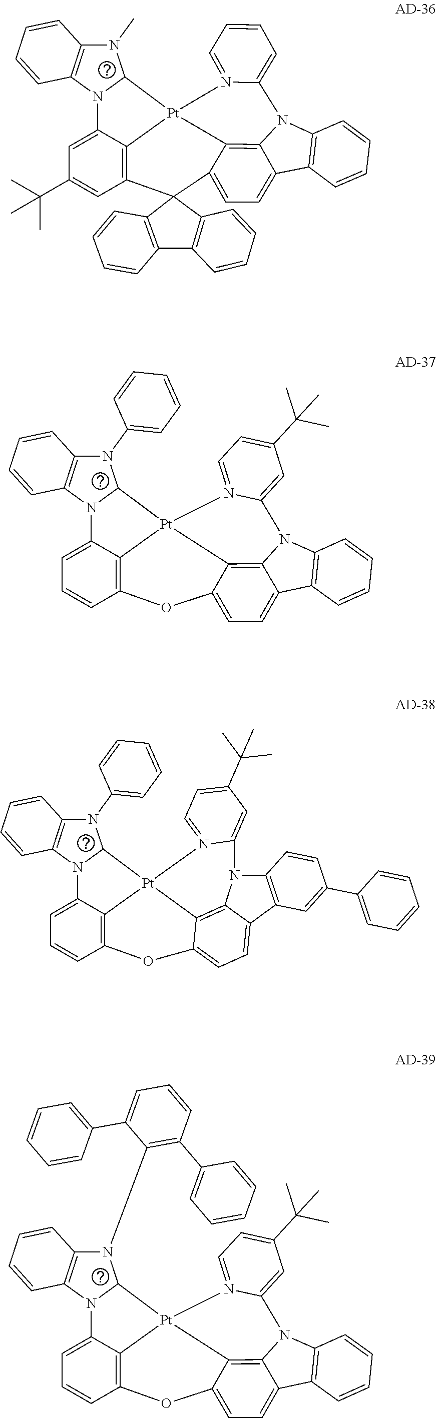

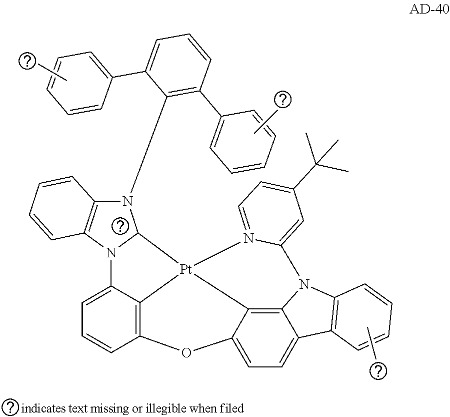

In the particular example compounds presented in Compound Group 4, “D” refers to deuterium.

In one or more embodiments, the light-emitting element ED may include a plurality of emission layers. The plurality of emission layers may be provided by being stacked in sequence, and for example, in one or more embodiments, the light-emitting element ED including the plurality of emission layers may be to emit white color light (e.g., combined white color light). The light-emitting element including the plurality of emission layers may be a light-emitting element having a tandem structure. In embodiments in which the light-emitting element ED includes the plurality of emission layers, at least one emission layer EML may include the first compound represented by Formula 1 according to one or more embodiments. In addition, if (e.g., when) the light-emitting element ED includes the plurality of emission layers, at least one emission layer EML may include all of the first compound, the second compound, the third compound, and the fourth compound as described above.

In the light-emitting element ED according to one or more embodiments, if (e.g., when) the emission layer EML includes all of the first compound, the second compound, the third compound, and the fourth compound described above, the content (e.g., amount) of the first compound may be about 0.1 wt % or greater and about 5 wt % or less on the basis of a total weight of the first compound, the second compound, the third compound, and the fourth compound. However, embodiments of the present disclosure are not limited thereto. When the content (e.g., amount) of the first compound falls within the above-described range, energy transfer from the second compound and the third compound to the first compound may increase, and accordingly, the luminescence efficiency and lifespan of the element may be improved.

In the emission layer EML, the content (e.g., amount) of the second compound and the third compound may correspond to the remaining content (e.g., amount) excluding the weight of the first compound and the fourth compound. For example, in the emission layer EML, the content (e.g., amount) of the second compound and the third compound may be about 65 wt % or greater and about 95 wt % or less on the basis of the total weight of the first compound, the second compound, the third compound, and the fourth compound.

On the basis of the total weight of the second compound and the third compound, a weight ratio of the second compound to the third compound may be about 3:7 to about 7:3.

When the content (e.g., amount) of the second compound and the third compound falls within the above-described ratio range, charge balance characteristics may be improved in the emission layer EML, thereby increasing luminescence efficiency and lifespan of the element. When the content (e.g., amount) of the second compound and the third compound falls out of the above-described ratio range, charge balance in the emission layer EML may be broken and the luminescence efficiency may be reduced, so that the element may be easily degraded.

In one or more embodiments, when the emission layer EML includes the fourth compound, the content (e.g., amount) of the fourth compound may be about 4 wt % or greater and about 30 wt % or less on the basis of the total weight of the first compound, the second compound, the third compound, and the fourth compound in the emission layer EML. However, embodiments of the present disclosure are not limited thereto. When the content (e.g., amount) of the fourth compound falls within the content (e.g., amount) range described above, energy transfer from a host to the first compound that is a light-emitting dopant may increase, so that the emission ratio may be improved, and accordingly, the luminescence efficiency of the emission layer EML may be improved. When the first compound, the second compound, the third compound, and the fourth compound included in the emission layer EML satisfy the above-described range of the content (e.g., amount) ratios, excellent or suitable luminescence efficiency and long lifespan may be achieved.

In the light-emitting element ED according to one or more embodiments, the emission layer EML may include at least one of an anthracene derivative, a pyrene derivative, fluoranthene derivative, a chrysene derivative, a dihydrobenzanthracene derivative, or a triphenylene derivative. For example, in one or more embodiments, the emission layer EML may include the anthracene derivative and/or the pyrene derivative.

In the light-emitting element ED according to embodiments illustrated in FIGS. 5 to 8, the emission layer EML may further include a suitable host and/or dopant, in addition to the above-described host and dopant, for example, in one or more embodiments, the emission layer EML may include a compound represented by Formula E-1. The compound represented by Formula E-1 may be used as a fluorescent host material.

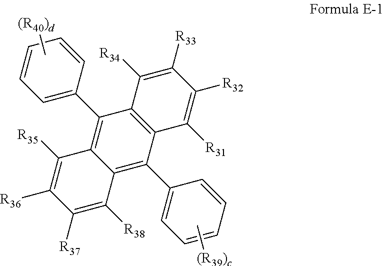

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In one or more embodiments, one or more selected from among R₃₁ to R₄₀ may each independently be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 or greater and 5 or less.

The compound represented by Formula E-1 may be any one selected from among Compound E1 to Compound E19.

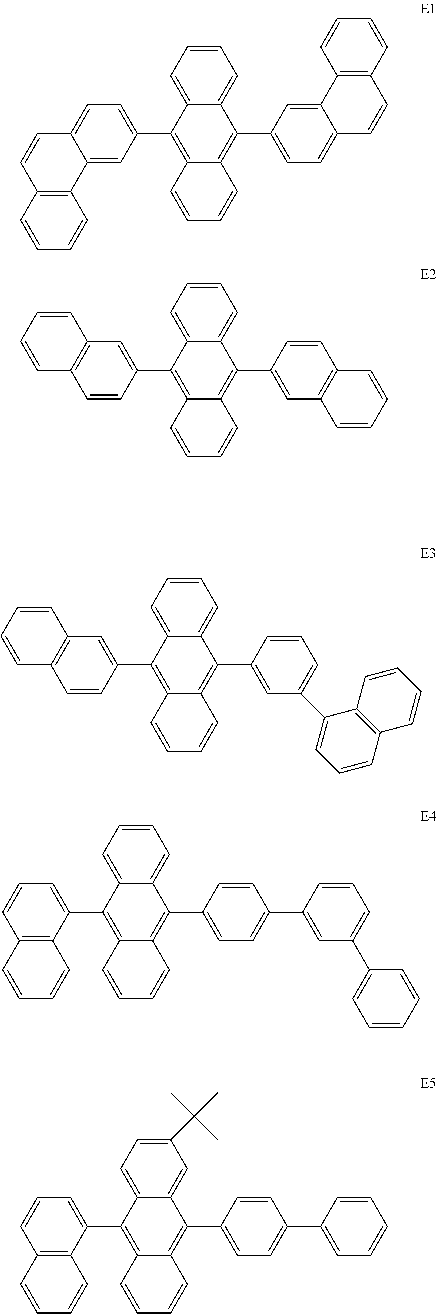

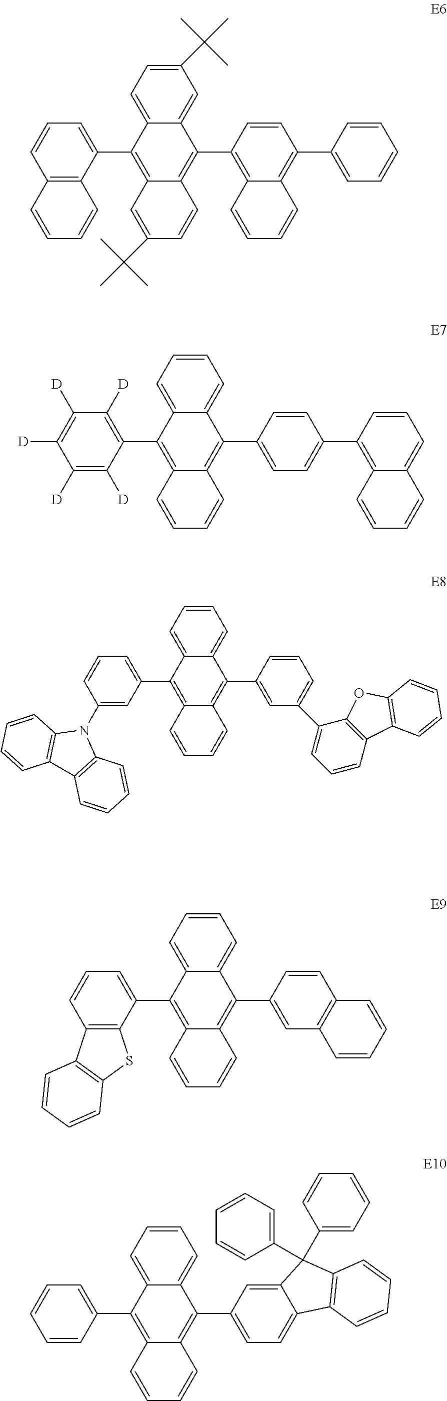

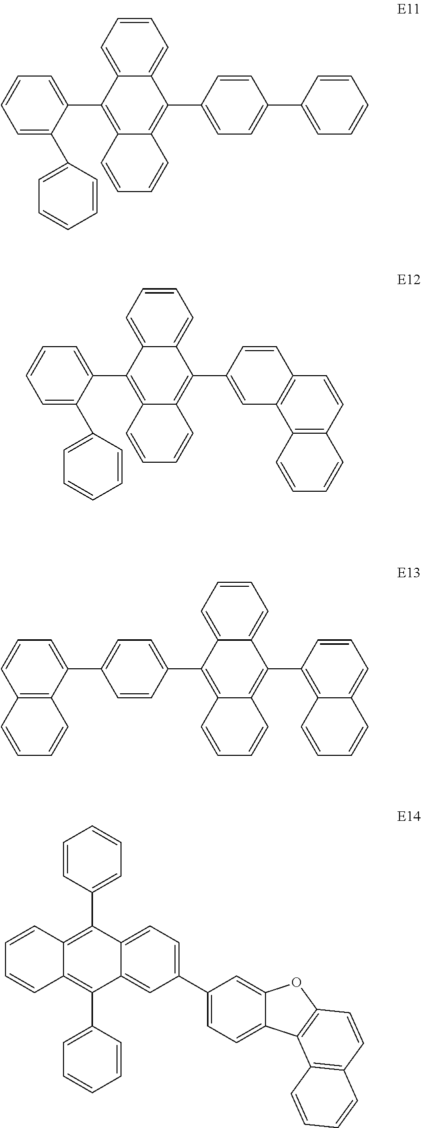

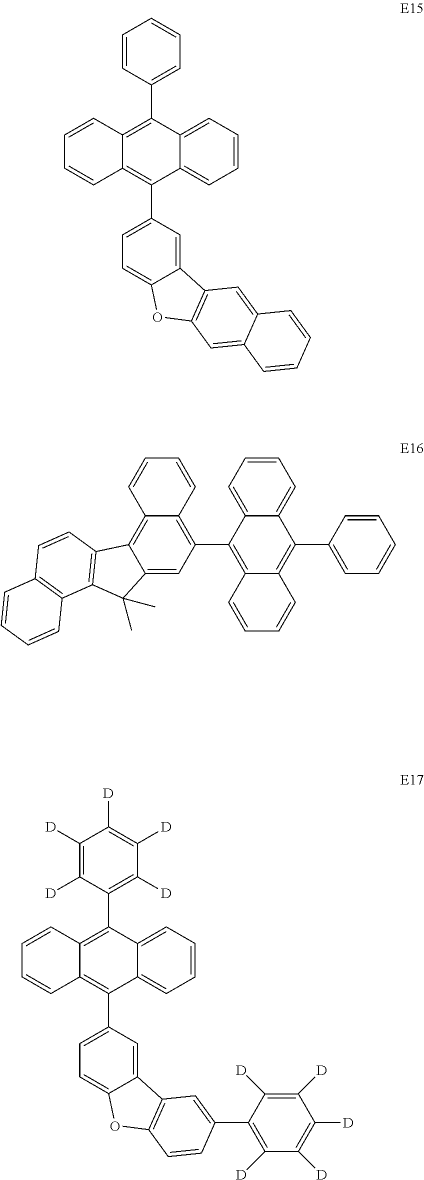

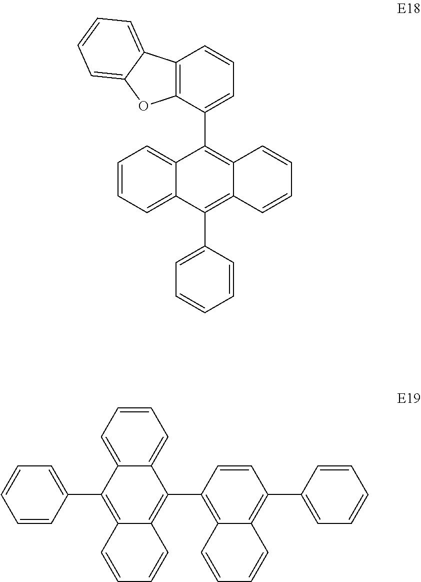

The emission layer EML according to one or more embodiments may include a compound represented by Formula E-2a or Formula E-2b. The compound represented by Formula E-2a or Formula E-2b may be used as a phosphorescent host material.

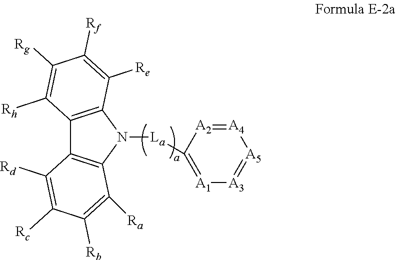

In Formula E-2a, a may be an integer of 0 or greater and 10 or less, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, Lₐ in plurality may each independently be a substituted or unsubstituted arylene group having 6 to 30 ring-forming carbon atoms or a substituted or unsubstituted heteroarylene group having 2 to 30 ring-forming carbon atoms.

In addition, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In one or more embodiments, one or more selected from among Rₐ to Rᵢ may be each independently boded to an adjacent group to form a hydrocarbon ring or a heterocycle containing N, O, S, and/or the like, as ring-forming atoms.

In one or more embodiments, In Formula E-2a, two or three selected from among A₁ to A₅ may be N, and the rest may be CRᵢ.

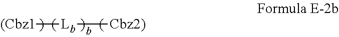

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. b may be an integer of 0 or greater and 10 or less, and if (e.g., when) b is an integer of 2 or greater, L_{b} in plurality may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are mere examples, and the compound represented by Formula E-2a or Formula E-2b is not limited to those listed in Compound Group E-2.

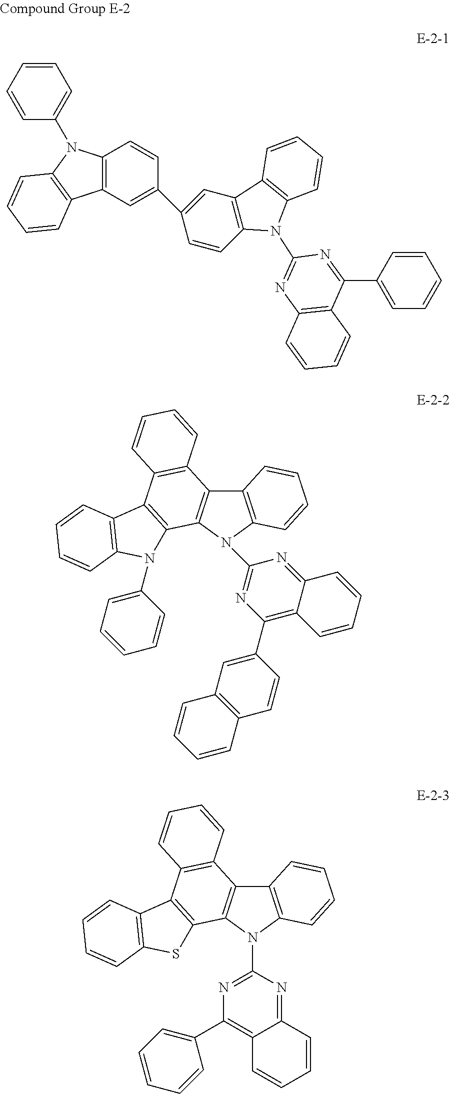

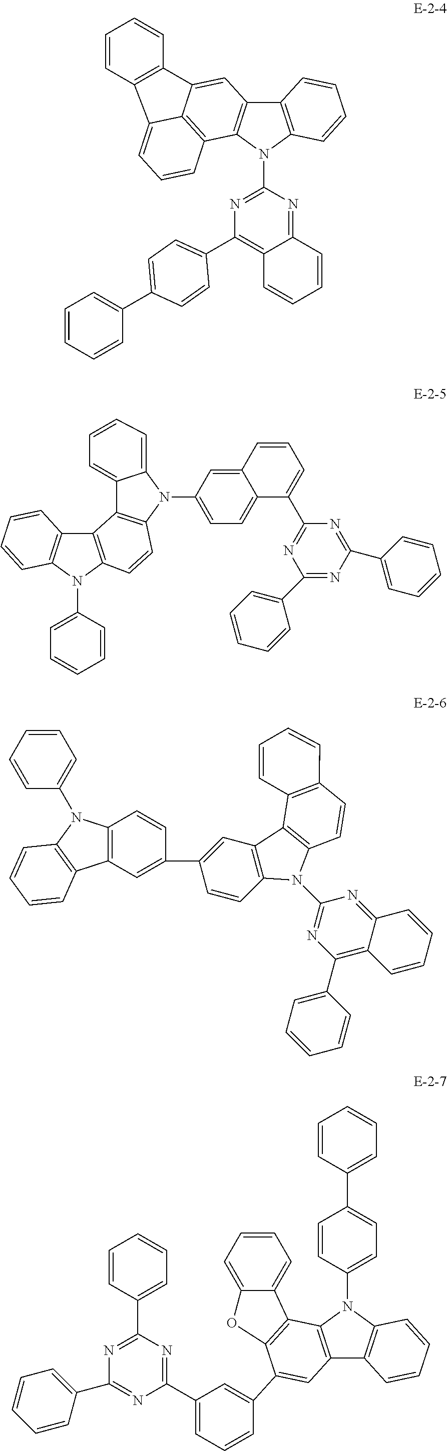 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

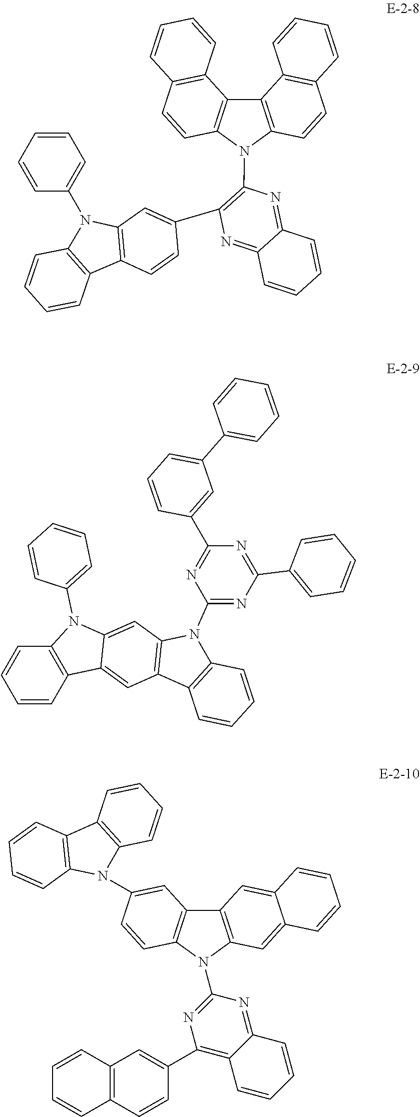 [SMILES: c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

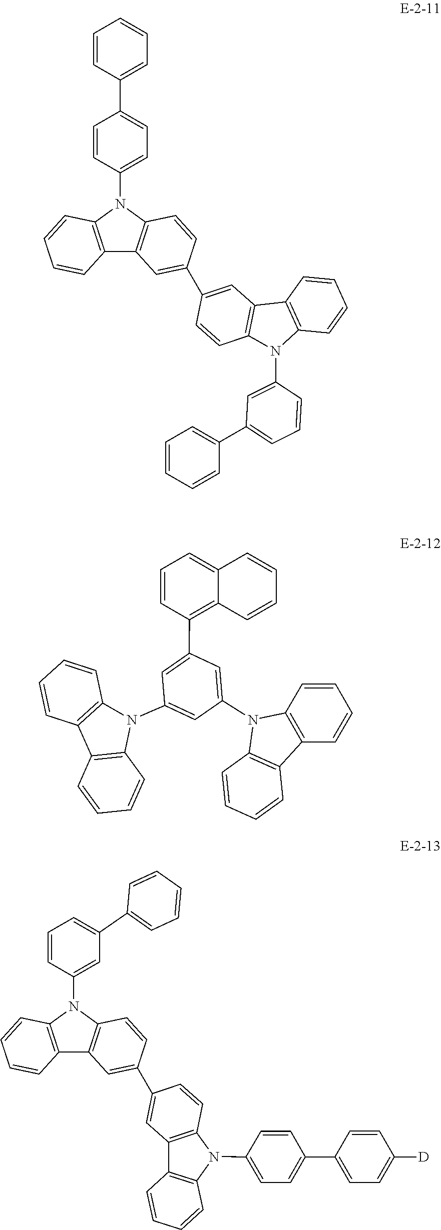 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1]

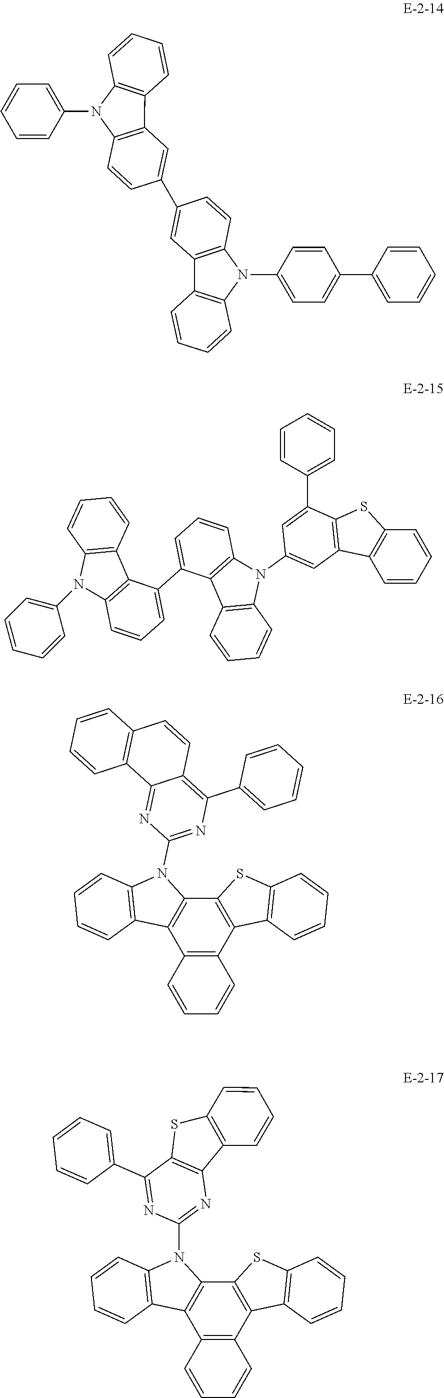 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1]

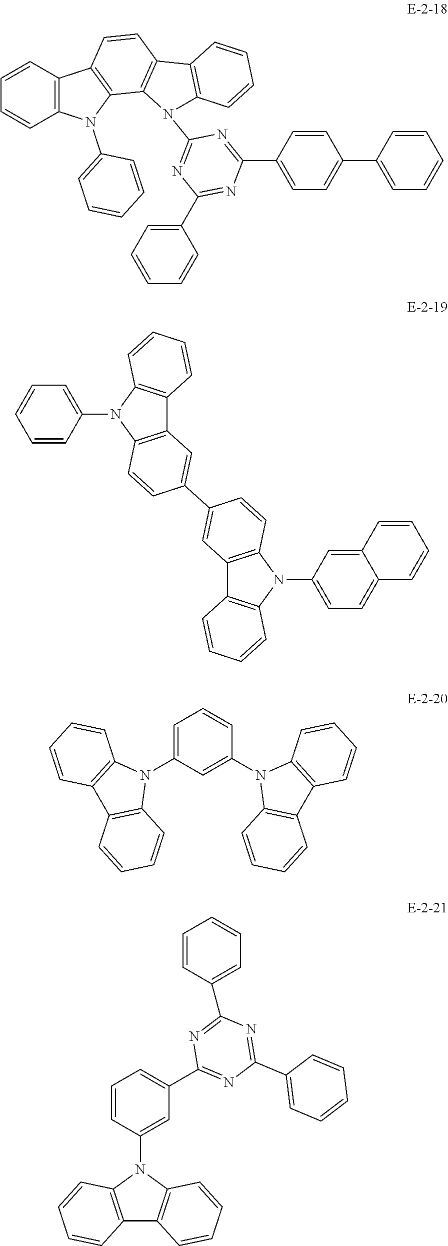 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

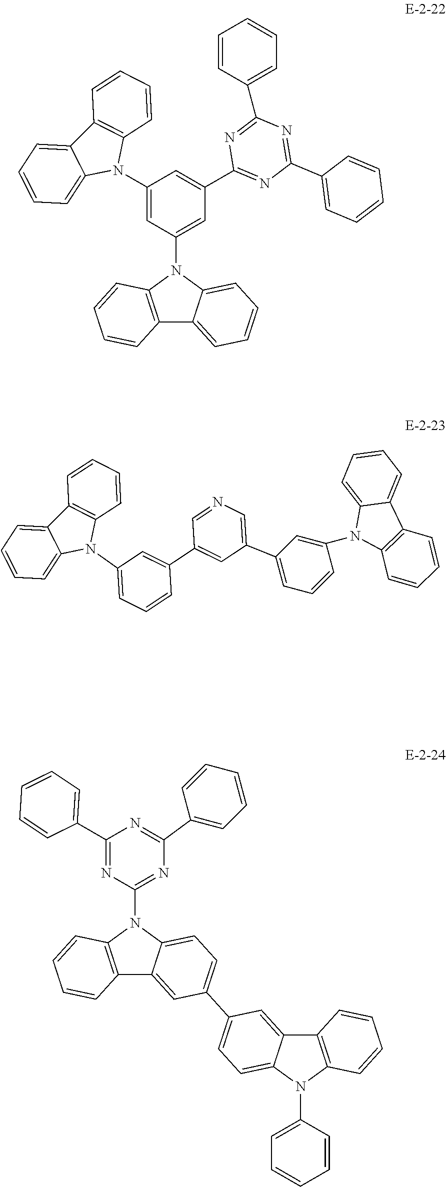 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material suitable in the relevant art as a host material. For example, as a host material, the emission layer EML may include at least one of bis(4-(9H-carbazol-9-yl) phenyl) diphenylsilane (BCPDS), (4-(1-(4-(diphenylamino) phenyl) cyclohexyl) phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto, for example, tris(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like, may be used as a host material.

In one or more embodiments, the emission layer EML may include a compound represented by Formula M-a. The compound represented by Formula M-a may be used as a phosphorescent dopant material.

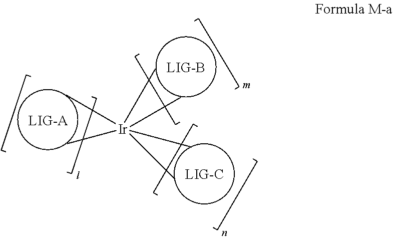

In Formula M-a, l, m, and n may each independently be an integer of 0 or greater and 3 or less, and l+m+n is 3. In Formula M-a, LIG-A, LIG-B, and LIG-C may each independently correspond to a ligand group represented by any one selected from among LG1 to LG5.

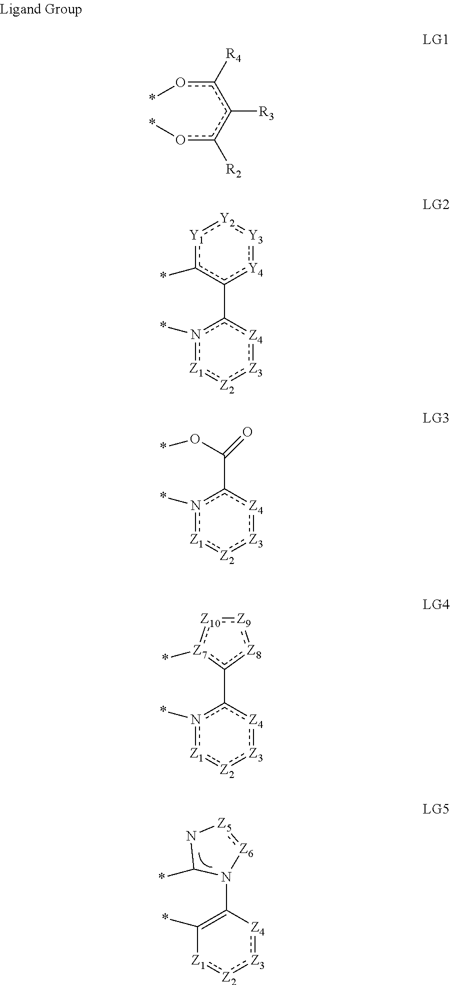

In the ligand group, Y₁ to Y₄ and Z₁ to Z₆ may each independently be CR₁ or N, and Z₇ to Z₁₀ may each independently be CR₁, N, or S. R₁ to R₄ may each independently be hydrogen, deuterium, a halogen, a cyano group, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. When one or more selected from among R₁ to R₄ are bonded to an adjacent group to form a ring, the formed ring may be a saturated hydrocarbon or unsaturated hydrocarbon ring. The ring formed by R₁ to R₄ being bonded to an adjacent group may be bonded to an adjacent ring to form a fused cyclic ring.

In the ligand group, “-*” refers to a position to be bonded to Ir.

The compound represented by Formula M-a may be used as a phosphorescent dopant. The compound represented by Formula M-a may be any one selected from among Compounds M-a1 to M-a25. However, Compounds M-a1 to M-a25 are mere examples, and the compound represented by Formula M-a is not limited to those represented by Compounds M-a1 to M-a25.

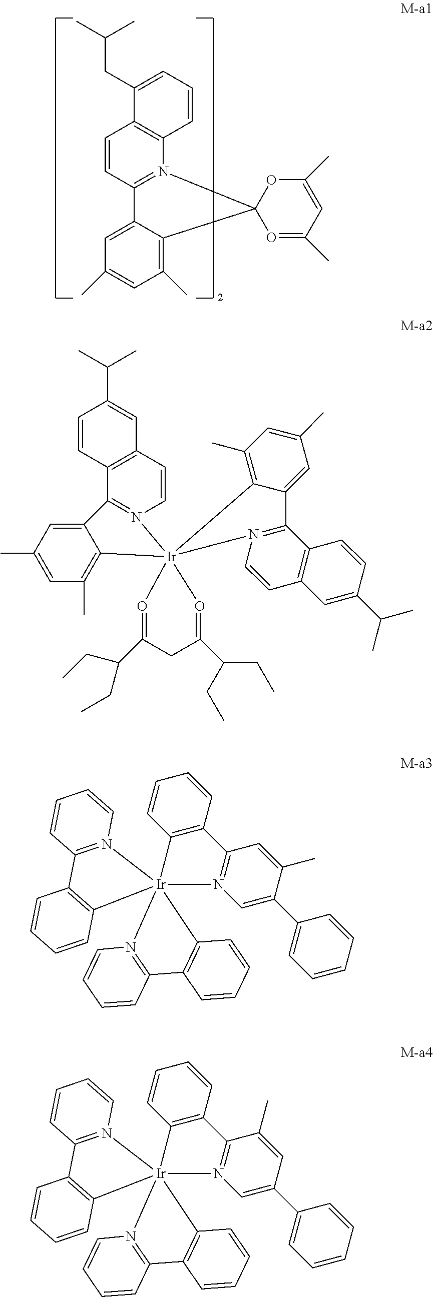

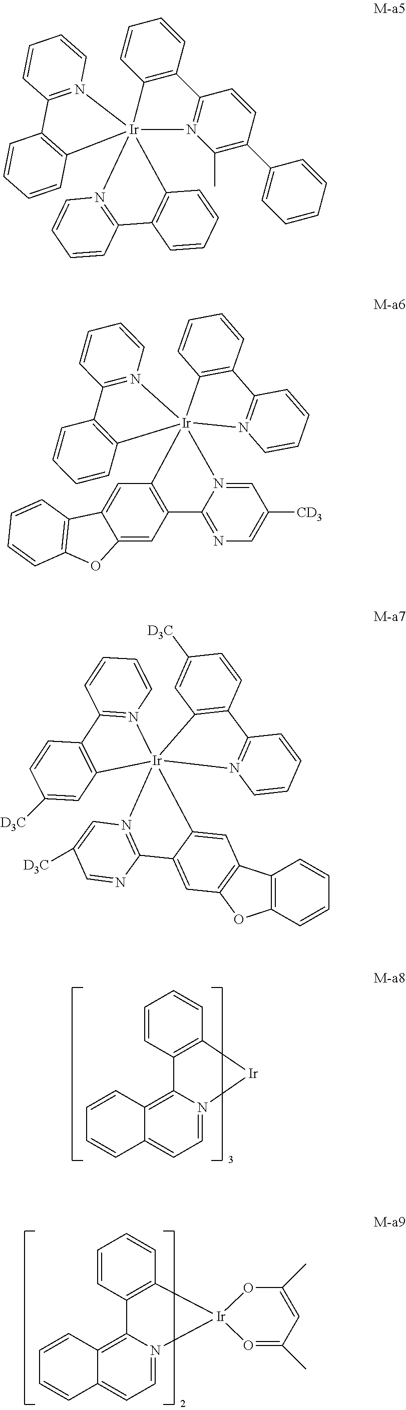

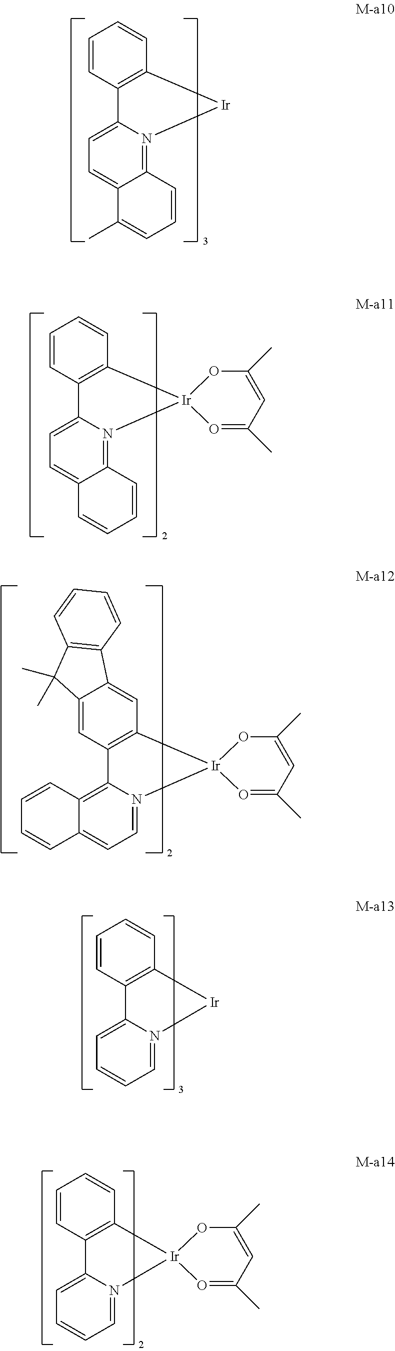

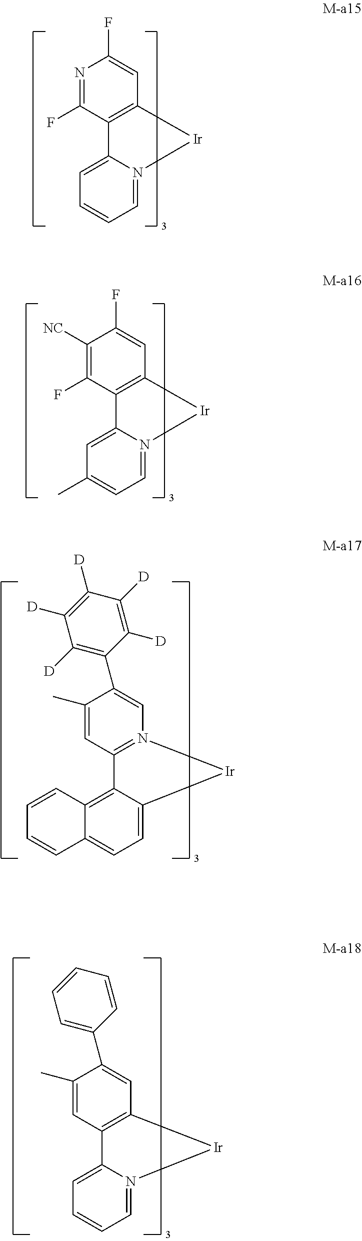

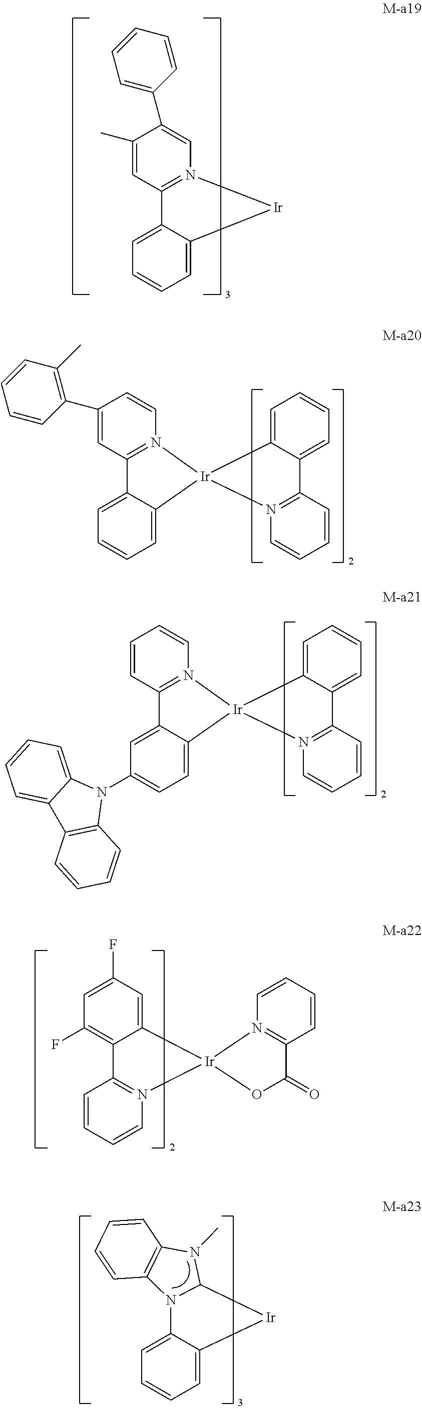

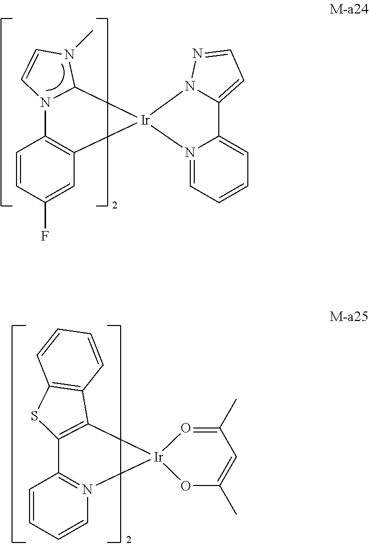

In one or more embodiments, the emission layer EML may include a compound represented by any one selected from among Formula F-a to Formula F-c. The compound represented by Formula F-a to Formula F-c may be used as a fluorescent dopant material.

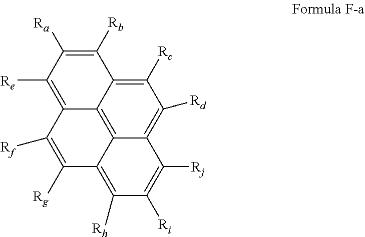

In Formula F-a, two selected from among Rₐ to Rⱼ may each independently be substituted with *—NAr₁Ar₂. The rest not substituted with *—NAr₁Ar₂ among Rₐ to Rⱼ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted hetero aryl group having 2 to 30 ring-forming carbon atoms. In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, at least one of Ar₁ or Ar₂ may be a heteroaryl group containing O or S as a ring-forming atom.

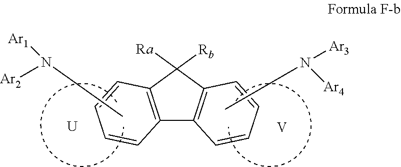

In Formula F-b, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In one or more embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, if (e.g., when) the number of U or V is 1, one ring constitutes a part of a fused cycle at a portion marked with U or V, and if (e.g., when) the number of U or V is 0, the ring marked with U or V may not exist. For example, if (e.g., when) the number of U is 0 and the number of V is 1, or if (e.g., when) the number of U is 1 and the number of V is 0, the fused cycle having a fluorene core in Formula F-b may be a 4-ring cyclic compound. In one or more embodiments, if (e.g., when) the number of each of U and V is 0, the fused cycle of Formula F-b may be a 3-ring cyclic compound. In one or more embodiments, if (e.g., when) the number of each of U and V is 1, the fused cycle of Formula F-b having a fluorene core may be a 5-ring cyclic compound.

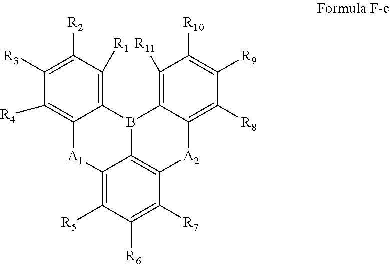

In Formula F-c, A₁ and A₂ may each independently be O, S, Se, or NRₘ, Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In one or more embodiments, in Formula F-c, A₁ and A₂ may each independently be bonded to substituents of an adjacent ring to form a fused cycle. For example, if (e.g., when) A₁ and A₂ may each independently be NRₘ, in one or more embodiments, A₁ may be bonded to R₄ or R₅ to form a ring. In one or more embodiments, A₂ may be bonded to R₇ or R₈ to form a ring.

In one or more embodiments, the emission layer EML may further include, as a suitable dopant material, one or more selected from among styryl derivatives (for example, 1, 4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and derivatives thereof (for example, 2, 5, 8, 11-tetra-t-butylperylene (TBP)), pyrene and derivatives thereof (for example, 1, 1-dipyrene, 1, 4-dipyrenylbenzene, 1, 4-bis(N, N-diphenylamino)pyrene), and/or the like.

In one or more embodiments, the emission layer EML may further include a suitable phosphorescence dopant material. For example, for the phosphorescence dopant, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used. In one or more embodiments, iridium(III) bis(4,6-difluorophenylpyridinato-N,C2′)picolinate (Flrpic), bis(2,4-difluorophenylpyridinato)-tetrakis(1-pyrazolyl)borate iridium(III) (Flr6), or platinum octaethyl porphyrin (PtOEP) may be used as the phosphorescence dopant. However, embodiments of the present disclosure are not limited thereto.

In one or more embodiments, the emission layer EML may include a quantum dot.

In this disclosure, the quantum dot refers to a semiconductor compound crystal. The quantum dot may be to emit light with one or more suitable emission wavelengths according to the size of crystals. The quantum dot may also emit light with one or more suitable emission wavelengths by adjusting an element ratio in a quantum dot compound.

The quantum dot may have a diameter of, for example, about 1 nm to about 10 nm. In the present disclosure, when quantum dots or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

The quantum dot may be synthesized by a wet chemical process, a metal organic chemical vapor deposition process, a molecular beam epitaxy process, or a similar process therewith.

The wet chemical process is a method of mixing an organic solvent and a precursor material of a quantum dot and then growing quantum dot particle crystals. When the crystal grows, the organic solvent may naturally serve as a dispersant coordinated on a surface of the quantum dot crystal, and may control the growth of the crystals. Therefore, the wet chemical process may control the growth of quantum dot particles more easily than the vapor deposition such as the metal organic chemical vapor deposition (MOCVD) or the molecular beam epitaxy (MBE), and the growth of quantum dot particles may be controlled or selected through a process at lower cost.

The emission layer according to one or more embodiments of the disclosure may include a quantum dot material. In one or more embodiments, the quantum dot may have a core/shell structure. The core of the quantum dot may be selected from among a Group II-VI compound, a Group III-V compound, a Group III-VI compound, a Group I-III-VI compound, a Group IV-VI compound, a Group IV element, a Group IV compound, a Group I-II-VI compound, a Group II-IV-VI compound, a Group I-II-IV-VI compound, a Group III-II-V compound, a Group II-IV-V compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. In one or more embodiments, the Group II-VI compound may further include a Group I metal and/or a Group IV element. The Group I-I-VI compound may be selected from among CuSnS and/or CuZnS, and the Group II-IV-VI compound may be selected from among ZnSnS, and/or the like. The Group I-II-IV-VI compound may be selected from among a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may be selected from among a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ and CuInGaS₂.

The Group III-V compound may be selected from the group consisting of: a binary compound selected from the group consisting of GaN, GaP, GaAs, GaSb, AlN, AIP, AIAs, AISb, InN, InP, InAs, InSb, and a mixture thereof; a ternary compound selected from the group consisting of GaNP, GaNAs, GaNSb, GaPAs, GaPSb, AlNP, AlNAs, AlNSb, AIPAs, AIPSb, InGaP, InAlP, InNP, InNAs, InNSb, InPAs, and InPSb, and a mixture thereof; a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and a mixture thereof. In one or more embodiments, the Group III-V compound may further include a Group II metal. For example, as the Group III—II-V compound, InZnP, and/or the like may be selected.

The Group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof; and a mixture thereof.

Examples of the Group II-IV-V semiconductor compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in a multi-element compound such as the binary compound, the ternary compound, or the quaternary compound may exist in a particle with an even concentration or uneven concentration. For example, the formula representing a semiconductor compound may refer to the type (kind) of elements included in the compound, and the element ratio in the compound may vary. For example, AgInGaS₂ may refer to AgInₓGa₁₋ₓS₂ (where, x is a real number of 0 to 1).

In one or more embodiments, the binary compound, the ternary compound, or the quaternary compound may exist in a particle with even concentration, or may exist separately in partially different states of concentration distributions in a same particle. Also, one quantum dot may surround (or may be around) another quantum dot to form a core-shell structure. In one or more embodiments, the core-shell structure may have a concentration gradient in which the concentration of an element present in the shell decreases toward the core.

In one or more embodiments, the quantum dot may have a core-shell structure including a core containing nano crystals described above and a shell around (e.g., surrounding) the core. The shell of the quantum dot may serve as a protection layer that prevents chemical denaturation of the core to maintain semiconductor characteristics, and/or serve as a charging layer for providing electrophoretic characteristics to the quantum dot. The shell may have a single layer or multiple layers. Examples of the shell of the quantum dot may include a metal or non-metal oxide, a semiconductor compound, or a combination thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but embodiments of the disclosure are not limited thereto.

In addition, examples of the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

The quantum dot may have a full width at half maximum (FWHM) of an emission spectrum of about 45 nm or less, about 40 nm or less, or about 30 nm or less, and within this range, color purity or color reproducibility of the quantum dot may be improved. In addition, light emitted through such a quantum dot may be emitted in all directions, thereby improving the wide viewing angle.

In addition, the shape of the quantum dot may be a generally-used shape in the relevant art, and is not particularly limited, for example, the quantum dot may include a spherical type (kind) nanoparticle, a pyramid type (kind) nanoparticle, a multi-arm type (kind) nanoparticle, a cubic nanoparticle, a nanotube, a nanowire, a nanofiber, a nano plate-like particle, and/or the like.

By adjusting the size of the quantum dot or adjusting the element ratio in the quantum dot compound, the energy band gap of the quantum dot may be controlled or selected, so that light in one or more suitable wavelength ranges may be obtained in a quantum-dot emission layer. Therefore, by using the above-described quantum dot (using quantum dots in different sizes or with different element ratios in the quantum dot compound), a light-emitting element that emits light with one or more suitable wavelengths may be achieved. For example, by adjusting the size of the quantum dot and/or the element ratio in the quantum dot compound, light of red color, green color, and/or blue color may be selected to be emitted. In addition, the quantum dots may be provided such that one or more suitable color light combines to emit white color light.

In the light-emitting element ED according to one or more embodiments illustrated in FIG. 5, an electron transport region ETR may be provided on the emission layer EML. The electron transport region ETR may include at least one of a hole-blocking layer, an electron transport layer ETL, or an electron injection layer EIL, but embodiments of the present disclosure are not limited thereto.

The electron transport region ETR may have a single layer made of a single material, a single layer made of a plurality of different materials, or a multi-layer structure including a plurality of layers made of a plurality of different materials.

For example, in one or more embodiments, the electron transport region ETR may have a single-layer structure of an electron injection layer EIL or an electron transport layer ETL, or may have a single-layer structure including an electron injection material and/or an electron transport material. In one or more embodiments, the electron transport region ETR may have a single-layer structure including a plurality of different materials, or may have a structure of electron transport layer ETL/electron injection layer EIL, or a structure of hole-blocking layer/electron transport layer ETL/electron injection layer EIL stacked in sequence from the emission layer EML, but embodiments of the present disclosure are not limited thereto. The electron transport region ETR may have a thickness of, for example, about 1000 Å to about 1500 Å.

The electron transport region ETR may be formed using one or more suitable methods including vacuum deposition, spin coating, casting, Langmuir-Blodgett (LB) deposition, inkjet printing, laser printing, laser induced thermal imaging (LITI), and/or the like.

In one or more embodiments, the electron transport region ETR may include a compound represented by Formula ET-2.

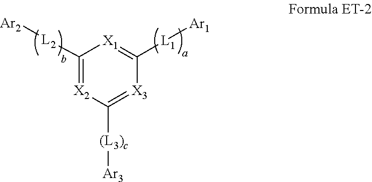

In Formula ET-2, at least one selected from among X₁ to X₃ may be N, and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) each of a to c is an integer of 2 or greater, L₁ to L₃ each provided in plurality may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, for example, in one or more embodiments, the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1, 10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), berylliumbis(benzoquinolin-10-olate (Bebq₂), 9,10-di(naphthalen-2-yl)anthracene (ADN), 1,3-bis[3,5-di(pyridin-3-yl)phenyl]benzene (BmPyPhB), 4′-(4-(4-(4,6-diphenyl-1,3,5-triazin-2-yl)phenyl)naphthalen-1-yl)-[1,1′-biphenyl]-4-carbonitrile (CNNPTRZ), and/or a mixture thereof.

In one or more embodiments, the electron transport region ETR may include any one selected from among the compounds in Compound Group 3.

In one or more embodiments, the electron transport region ETR may include at least one selected from among Compounds ET1 to ET36.

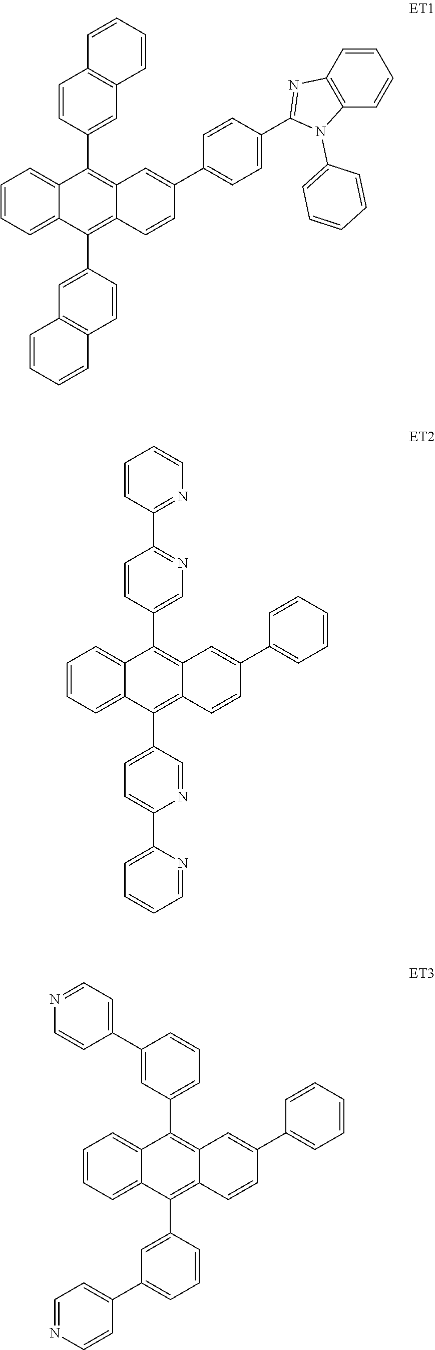 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

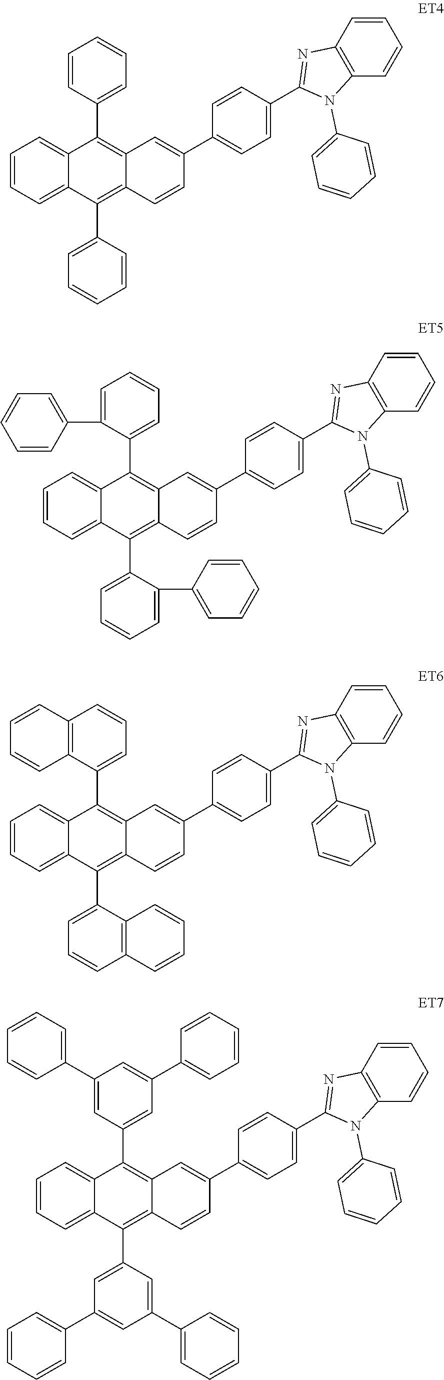 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

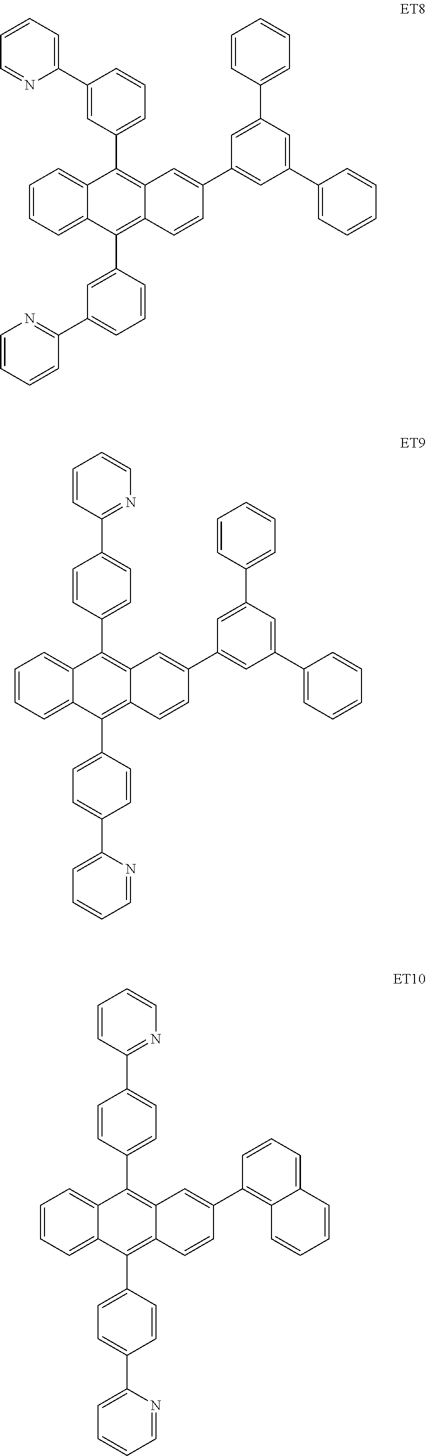 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

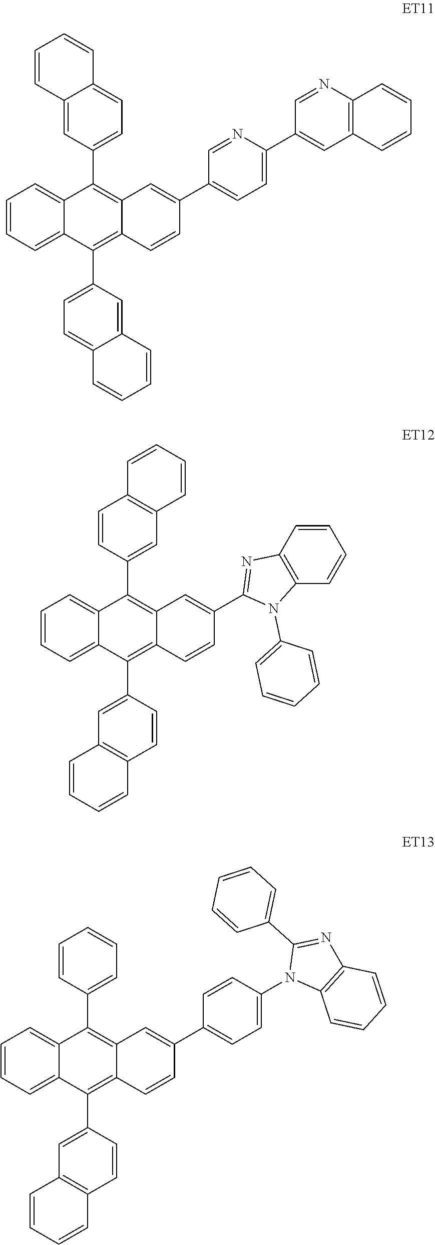 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

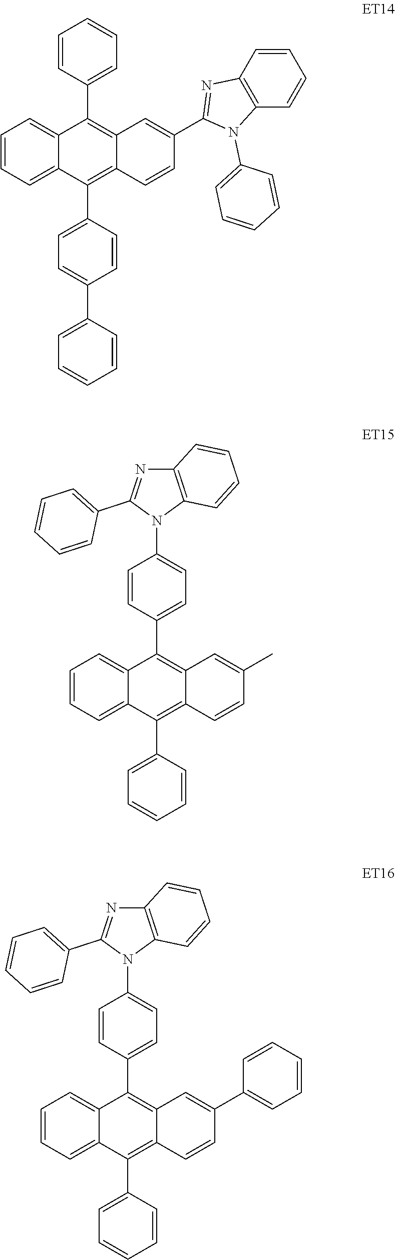 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

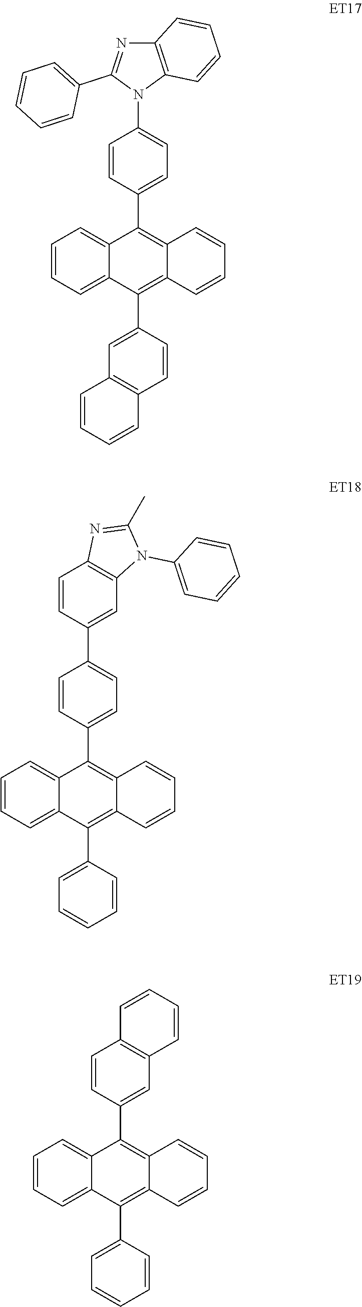

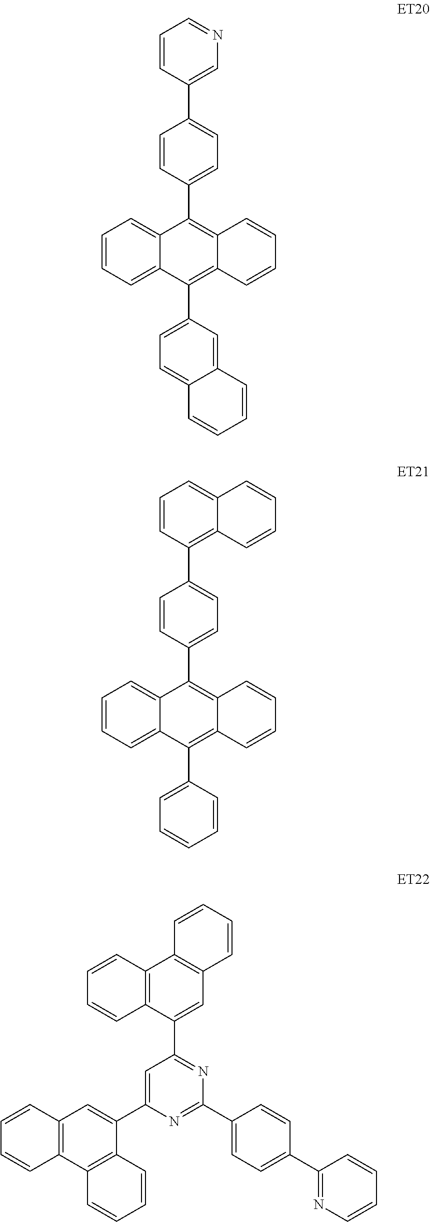

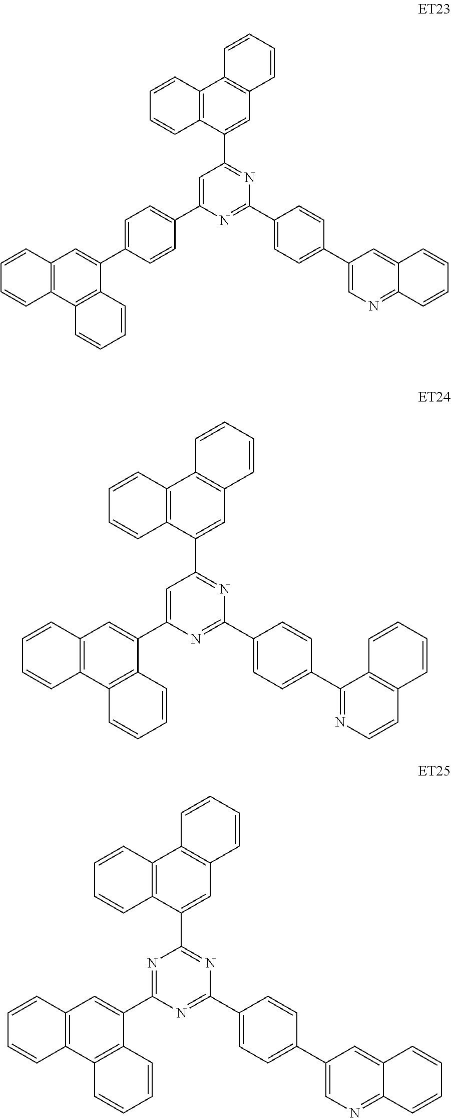 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

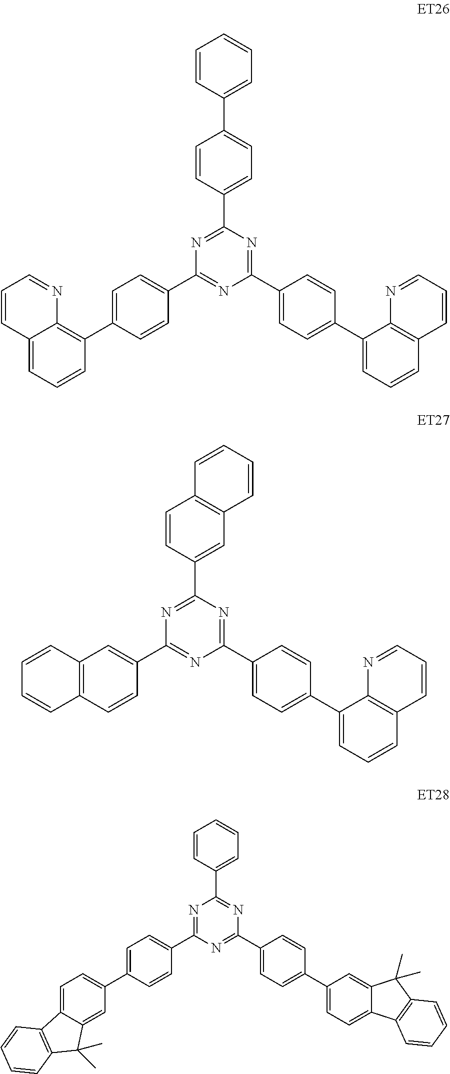 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

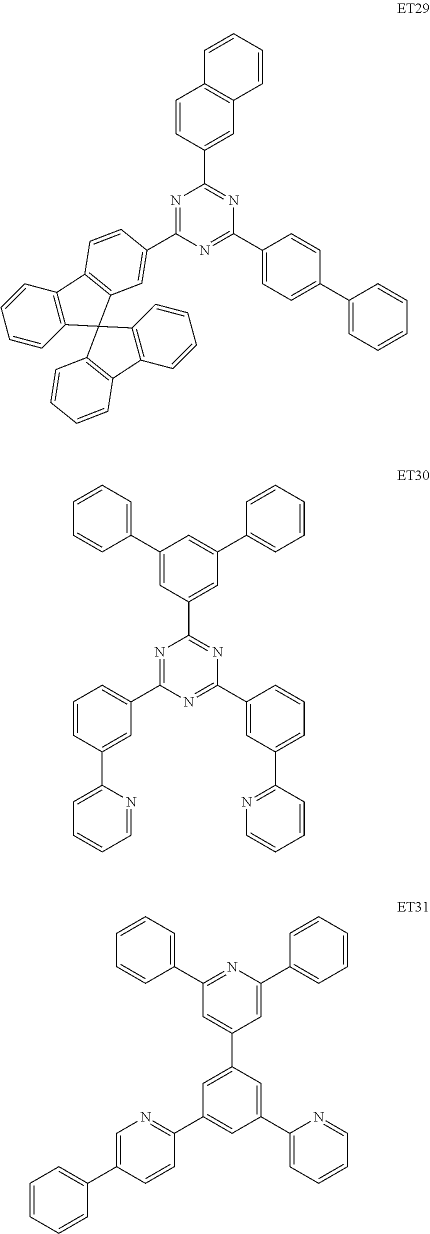 [SMILES: c1ccc(-c2ccc(-c3nc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

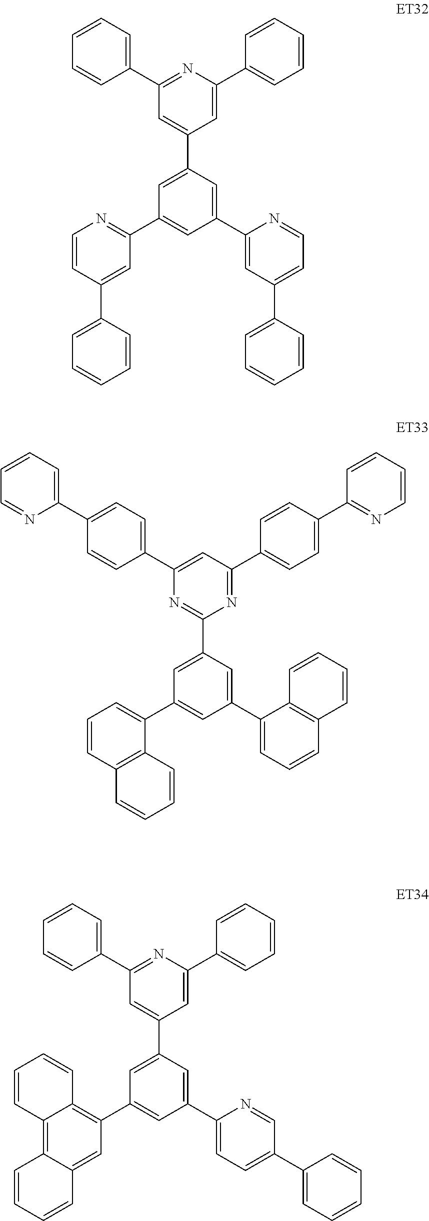 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

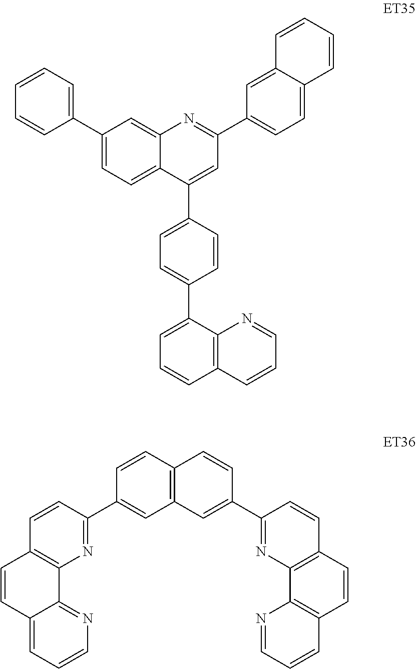 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In one or more embodiments, the electron transport region ETR may include 20a halogenated metal (e.g. a metal halide) such as LiF, NaCl, CsF, RbCl, RbI, CuI, and/or KI, a lanthanide metal such as Yb, or a co-deposition material of the halogenated metal and the lanthanide metal. For example, in one or more embodiments, the electron transport region ETR may include KI:Yb, R_{b1}:Yb, and LiF:Yb as the co-deposition material. In one or more embodiments, for the electron transport region ETR, a metal oxide such as Li₂O and BaO, lithium-8-hydroxyquinolinolate (Liq), and/or the like may be used, but embodiments of the present disclosure are not limited thereto. In one or more embodiments, the electron transport region ETR may also include a mixed material of an electron transport material and an organo metal salt with insulation. The organo metal salt may be a material having an energy band gap of about 4 eV or greater. For example, the organo metal salt may include a metal acetate, a metal benzoate, a metal acetoacetate, a metal acetylacetonate, and/or a metal stearate.

In addition to one or more of the above-mentioned materials, in one or more embodiments, the electron transport region ETR may further include at least one of 2,9-dimethyl-4,7-diphenyl-1, 10-phenanthroline (BCP), diphenyl(4-(triphenylsilyl)phenyl)phosphine oxide (TSPO1), or 4,7-diphenyl-1, 10-phenanthroline (Bphen), but embodiments of the present disclosure are not limited thereto.

The electron transport region ETR may include one or more of the above-described compounds of the electron transport region in at least one of the electron injection layer EIL, the electron transport layer ETL, or the hole-blocking layer.

If (e.g., when) the electron transport region ETR includes the electron transport layer ETL, a thickness of the electron transport layer ETL may be about 100 Å to about 1000 Å, for example, about 150 Å to about 500 Å. When the thickness of the electron transport layer ETL falls within the above-described ranges, satisfactory electron transport characteristics may be achieved without a substantial increase in driving voltage. If (e.g., when) the electron transport region ETR includes the electron injection layer ETL, a thickness of the electron injection layer ETL may be about 1 Å to about 100 Å, or about 3 Å to about 90 Å. When the thickness of the electron injection layer EIL falls within the above-described ranges, satisfactory electron injection characteristics may be achieved without a substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, in case that the first electrode EL1 is an anode, the second electrode EL2 may be a cathode, and in case that the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), and/or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, a compound thereof, or a mixture thereof (for example, AgMg, AgYb, or MgYb). In one or more embodiments, the second electrode EL2 may have a multi-layer structure including a reflective film or a transflective film including one or more of the above-mentioned materials, and a transparent conductive film including indium tin oxide (ITO), indium zinc oxide (IZO), zinc oxide (ZnO), indium tin zinc oxide (ITZO), and/or the like. For example, in one or more embodiments, the second electrode EL2 may include one of the above-described metal materials, a combination of at least two metal materials selected from among the above-described metal materials, an oxide of the above-described metal materials, and/or the like.

In one or more embodiments, the second electrode EL2 may be connected to an auxiliary electrode. If (e.g., when) the second electrode EL2 is connected to the auxiliary electrode, resistance of the second electrode EL2 may be reduced.

In one or more embodiments, the capping layer CPL may be further arranged on the second electrode EL2 of the light-emitting element ED. The capping layer CPL may have multiple layers or a single layer.

In one or more embodiments, the capping layer CPL may be an organic layer or an inorganic layer. For example, if (e.g., when) the capping layer CPL includes an inorganic material, the inorganic material may include an alkali metal compound such as LiF, an alkali metal compound such as MgF₂, SiON, SiNₓ, SiO_{y}, and/or the like.

In one or more embodiments, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or may include an epoxy resin and/or an acrylate such as methacrylate. However, embodiments of the present disclosure are not limited thereto, for example, in one or more embodiments, the capping layer CPL may include at least one selected from among Compounds P1 to P5 as.

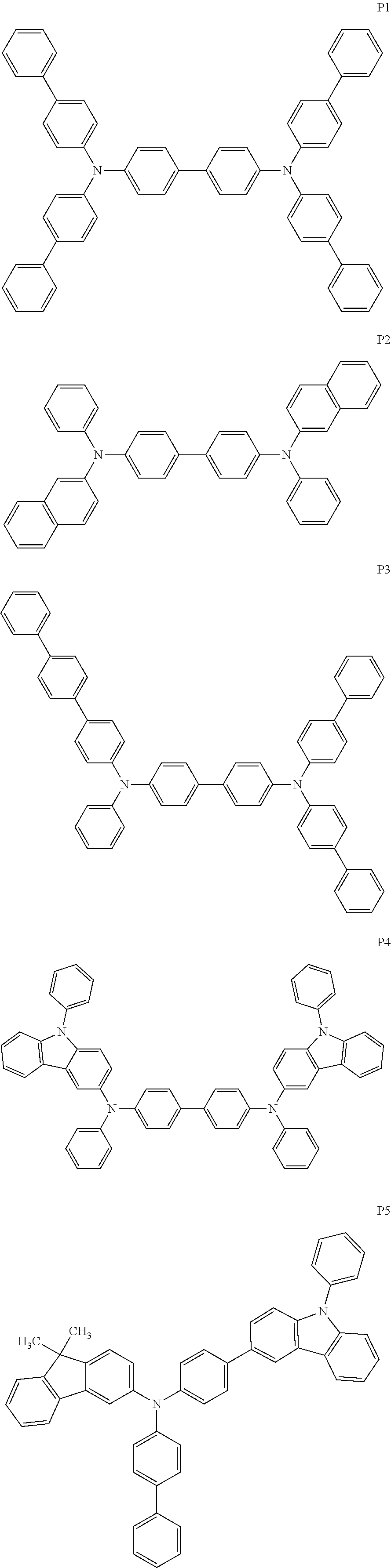 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the capping layer CPL may have a refractive index of about 1.6 or greater. For example, the refractive index of the capping layer CPL may be about 1.6 or greater for light in a wavelength range of about 550 nm to about 660 nm.

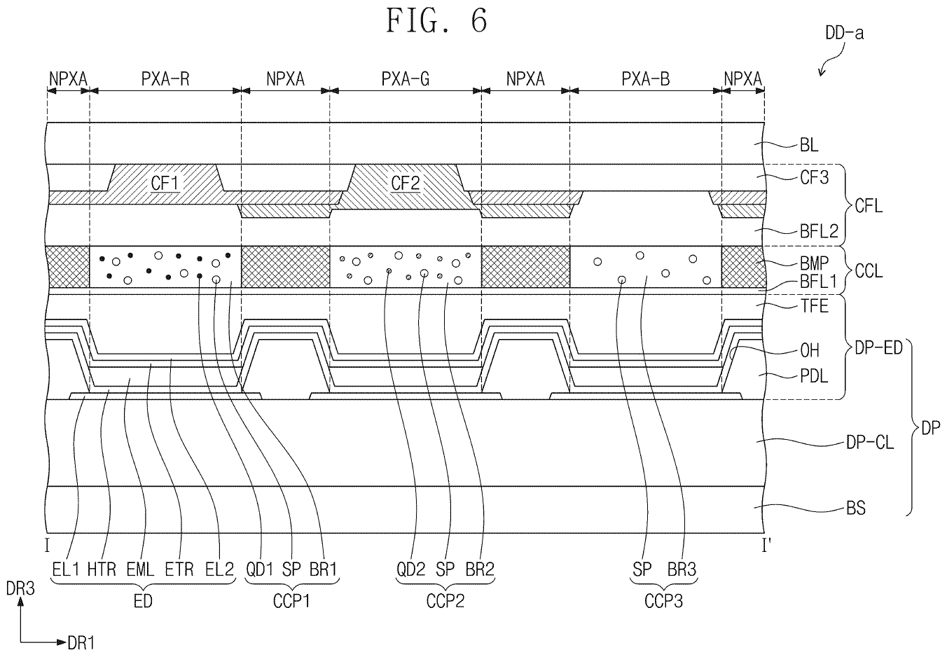

FIGS. 6 to 9 are cross-sectional views each illustrating a display device according to one or more embodiments of the present disclosure. In describing the display device according to one or more embodiments with reference to FIGS. 6 to 9, duplicate content previously described with reference to FIGS. 1 to 5 will not be described again, and differences will be mainly described.

Referring to FIG. 6, a display device DD-a according to one or more embodiments may include a display panel DP including a display element layer DP-ED, a light control layer CCL arranged on the display panel DP, and a color filter layer CFL. In one or more embodiments illustrated in FIG. 6, the display panel DP may include a base layer BS, a circuit layer DP-CL provided on the based layer BS, and a display element layer DP-ED provided onto the circuit layer DP-CL, and the display element layer DP-ED may include a light-emitting element ED.

The light-emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the structure of the light-emitting element in FIG. 5, described above, may be applied equally to a structure of the light-emitting element ED illustrated in FIG. 6.

The emission layer EML of the light-emitting element ED included in the display device DD-a according to one or more embodiments may include the fused polycyclic compound according to one or more embodiments described above.

Referring to FIG. 6, the emission layer EML may be arranged in an opening OH defined in a pixel-defining film PDL. For example, the emission layer EML separately by the pixel-defining film PDL, provided corresponding to each of emission regions PXA-R, PXA-G, and PXA-B, may be to emit light in substantially the same wavelength range. In the display device DD-a according to one or more embodiments, the emission layer EML may be to emit blue color light. In one or more embodiments, the emission layer EML may be provided to the entire emission regions PXA-R, PXA-G, and PXA-B as a common layer.

The light control layer CCL may be arranged on the display panel DP. The light control layer CCL may include a light converter. The light converter may be a quantum dot, a fluorescent substance, and/or the like. The light converter may convert the wavelength of light provided and emit the wavelength-converted light. For example, the light control layer CCL may be a layer including a quantum dot or a layer including a fluorescent substance.

The light control layer CCL may include a plurality of light control parts CCP1, CCP2, and CCP3. The light control parts CCP1, CCP2, and CCP3 may be spaced and/or apart (e.g., spaced apart or separated) from one another.

Referring to FIG. 6, a separating pattern BMP may be arranged between the light control parts CCP1, CCP2, and CCP3 spaced and/or apart from one another, but embodiments of the present disclosure are not limited thereto. FIG. 6 illustrates that the separating pattern BMP does not overlap the light control parts CCP1, CCP2, and CCP3, but, in one or more embodiments, edges of the light control parts CCP1, CCP2, and CCP3 may overlap at least a portion of the separating pattern BMP.

The light control layer CCL may include a first light control part CCP1 containing a first quantum dot QD1 that converts first color light provided from the light-emitting element ED to second color light, a second light control part CCP2 containing a second quantum dot QD2 that converts the first color light to third color light, and a third light control part CCP3 transmitting the first color light. In one or more embodiments, the first light control part CCP1 may provide red color light that is the second color light, and the second light control part CCP2 may provide green color light that is the third color light. The third light control part CCP3 may be to transmit blue color light that is the first color light, provided from the light-emitting element ED, to provide the blue color light. For example, the first quantum dot QD1 may be a red color quantum dot to emit red color light, and the second quantum dot QD2 may be a green color quantum dot to emit green color light. For the quantum dots QD1 and QD2, the same content on quantum dots described above may be applied.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) a (e.g., any) quantum dot and may include the scatterer SP.

The scatterer SP may be an inorganic particle. For example, the scatterer SP may include at least one of TiO₂, ZnO, Al₂O₃, SiO₂, or hollow silica. The scatterer SP may include any one selected from among TiO₂, ZnO, Al₂O₃, SiO₂, and the hollow silica, or may be a mixture of two or more materials selected from among TiO₂, ZnO, Al₂O₃, SiO₂, and the hollow silica.

The first light control part CCP1, the second light control part CCP2, and the third light control part CCP3 may respectively include base resins BR1. BR2, and BR3 that disperse the quantum dot QD1 and QD2 and the scatterer SP, accordingly. In one or more embodiments, the first light control part CCP1 may include the first quantum dot QD1 and the scatterer SP each dispersed in a first base resin BR1, the second light control part CCP2 may include the second quantum dot QD2 and the scatterer SP each dispersed in a second base resin BR2, and the third light control part CCP3 may include the scatterer SP dispersed in a third base resin BR3.

The base resin BR1, BR2, and BR3 may be a medium through which the quantum dot QD1 and QD2 and the scatterer SP are dispersed accordingly, and may each include one or more suitable resin compositions that may be generally referred to as a binder. For example, the base resin BR1, BR2, and BR3 may be each independently an acrylate-based resin, a urethane-based resin, a silicon-based resin, an epoxy-based resin, and/or the like. The base resin BR1, BR2, and BR3 may each be a transparent resin. In one or more embodiments, the first base resin BR1, the second base resin BR2, and the third base resin BR3 may be the same as or different from one another.

In one or more embodiments, the light control layer CCL may include a barrier layer BFL1. The barrier layer BFL1 may serve to prevent or reduce penetration of moisture and/or oxygen (hereinafter, referred to as ‘moisture/oxygen’). The barrier layer BFL1 may prevent or reduce the light control parts CCP1, CCP2, and CCP3 from being exposed to the moisture/oxygen. In one or more embodiments, the barrier layer BFL1 may cover the light control parts CCP1, CCP2, and CCP3. In one or more embodiments, a barrier layer BFL2 may also be provided between the light control parts CCP1, CCP2, and CCP3 and filters CF1, CF2, and CF3.

The barrier layers BFL1 and BFL2 may each include at least one inorganic layer. For example, in one or more embodiments, the barrier layers BFL1 and BFL2 may each be formed including an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film with light transmittance being secured. In one or more embodiments, the barrier layers BFL1 and BFL2 may each independently further include an organic film. The barrier layers BFL1 and BFL2 may each independently include a single layer or a plurality of layers.

In the display device DD-a according to one or more embodiments, the color filter layer CFL may be arranged on the light control layer CCL. For example, in one or more embodiments, the color filter layer CFL may be directly arranged on the light control layer CCL. In these embodiments, the barrier layer BFL2 may not be provided.

The color filter layer CFL may include first to third filters CF1, CF2, and CF3. The first to third filters CF1, CF2, and CF3 may be arranged corresponding to a red emission region PXA-R, a green emission region PXA-G, and a blue emission region PXA-B, respectively.

The color filter layer CFL may include a first filter CF1 transmitting the second color light, the second filter CF2 transmitting the third color light, and the third filter CF3 transmitting the first color light. For example, the first filter CF1 may be a red color filter, the second filter CF2 may be a green color filter, and the third filter CF3 may be a blue color filter. The filters CF1, CF2, and CF3 may each include a polymer photosensitive resin, and a pigment and/or a dye. For example, in one or more embodiments, the first filter CF1 may include a red pigment and/or a red dye, the second filter CF2 may include a green pigment and/or a green dye, and the third filter CF3 may include a blue pigment and/or a blue dye.

However, embodiments of the present disclosure are not limited thereto, for example, in one or more embodiments, the third filter CF3 may not include (e.g., may exclude) any pigment or any dye. The third filter CF3 may include a polymer photosensitive resin, and may not include (e.g., may exclude) any pigment or any dye. The third filter CF3 may be transparent. In one or more embodiments, the third filter CF3 may include a transparent photosensitive resin.

In addition, in one or more embodiments, the first filter CF1 and the second filter CF2 may be yellow filters. The first filter CF1 and the second filter CF2 may not be separated from each other and may be provided as one body.

In one or more embodiments, the color filter layer CFL may further include a light-blocking part. The light-blocking part may be a black matrix. The light-blocking part may include an organic light-blocking material and/or an inorganic light-blocking material each containing a black pigment and/or a black dye. The light-blocking part may prevent or reduce a light-leak phenomenon, and may set boundaries between the filters CF1, CF2, and CF3 adjacent to each other.

A base substrate BL may be arranged on the color filter layer CFL. The base substrate BL may be a member that provides a base surface on which the color filter layer CFL, the light control layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

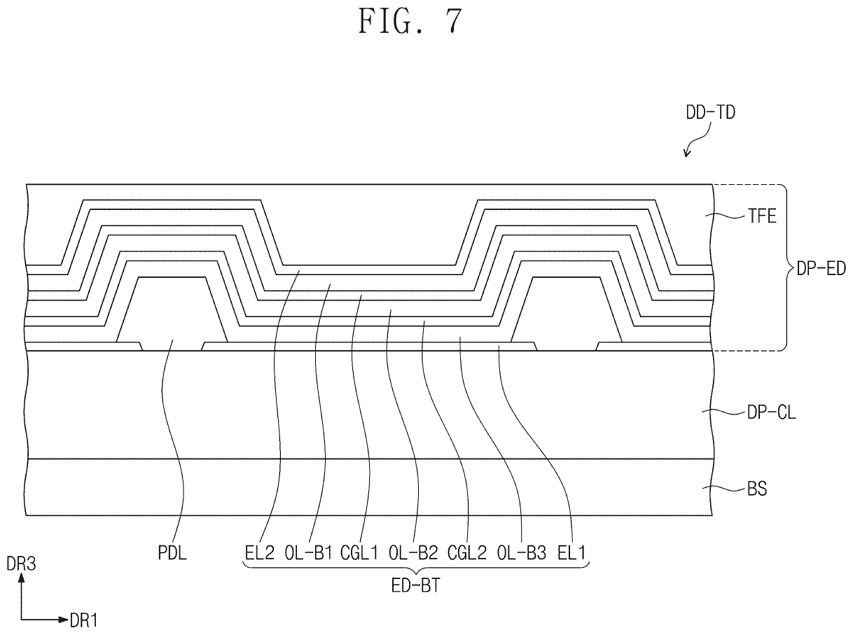

FIG. 7 is a cross-sectional view of a portion of a display device according to one or more embodiments of the present disclosure. In a display device DD-TD according to one or more embodiments, a light-emitting element ED-BT may include a plurality of emission structures OL-B1, OL-B2, and OL-B3. The light-emitting element ED-BT may include a first electrode EL1, a second electrode EL2, and the plurality of emission structures OL-B1, OL-B2, and OL-B3 stacked in sequence in a thickness direction between the first electrode EL1 and the second electrode EL2. The emission structures OL-B1, OL-B2, and OL-B3 may each include an emission layer EML (see FIG. 6), and a hole transport region HTR and an electron transport region ETR arranged with the emission layer EML (see FIG. 6) therebetween.

For example, the light-emitting element ED-BT included in the display device DD-TD according to one or more embodiments may be a light-emitting element in a tandem structure including a plurality of emission layers.

In one or more embodiments illustrated in FIG. 7, light emitted from each of the emission structures OL-B1, OL-B2, and OL-B3 may be blue color light. However, embodiments of the present disclosure are not limited thereto, for example, in one or more embodiments, the emission structures OL-B1, OL-B2, and OL-B3 may be to emit light in different wavelength ranges. For example, in one or more embodiments, the light-emitting element ED-BT, including the plurality of emission structures OL-B1, OL-B2, and OL-B3 that emit light in different wavelength ranges, may be to emit white color light (e.g., combined white light).

Charge-generating layers CGL1 and CGL2 may be respectively arranged between the emission structures OL-B1, OL-B2, and OL-B3 adjacent to each other. The charge-generating layers CGL1 and CGL2 may each include a p-type (kind) charge-generating layer and/or an n-type (kind) charge-generating layer.

The fused polycyclic compound according to one or more embodiments described above may be included in at least one selected from among the emission structures OL-B1, OL-B2, and OL-B3 included in the display device DD-TD according to one or more embodiments. For example, in one or more embodiments, at least one selected from among the plurality of emission layers included in the light-emitting element ED-BT may include the fused polycyclic compound according to one or more embodiments.

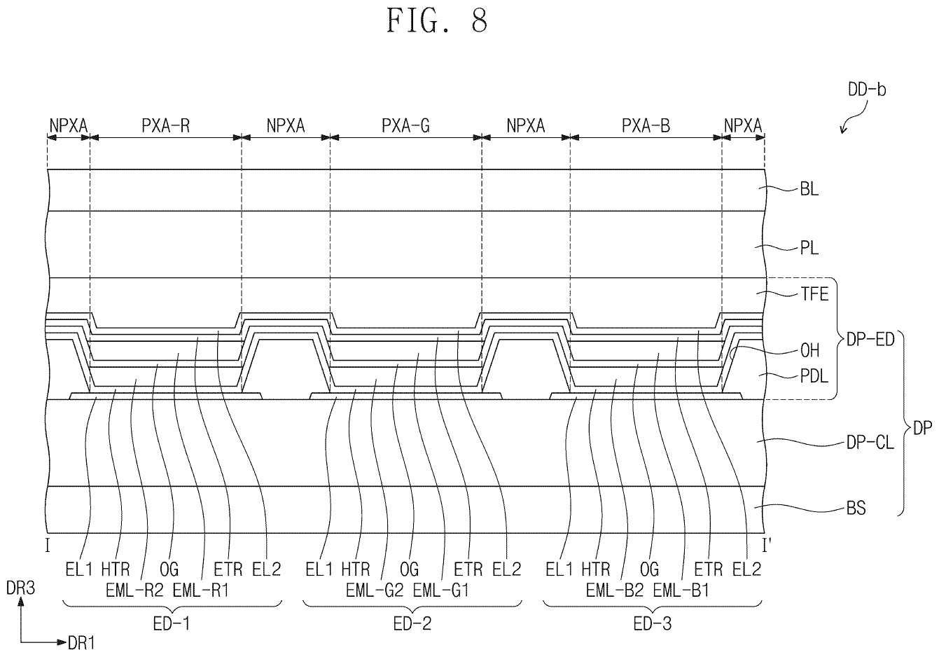

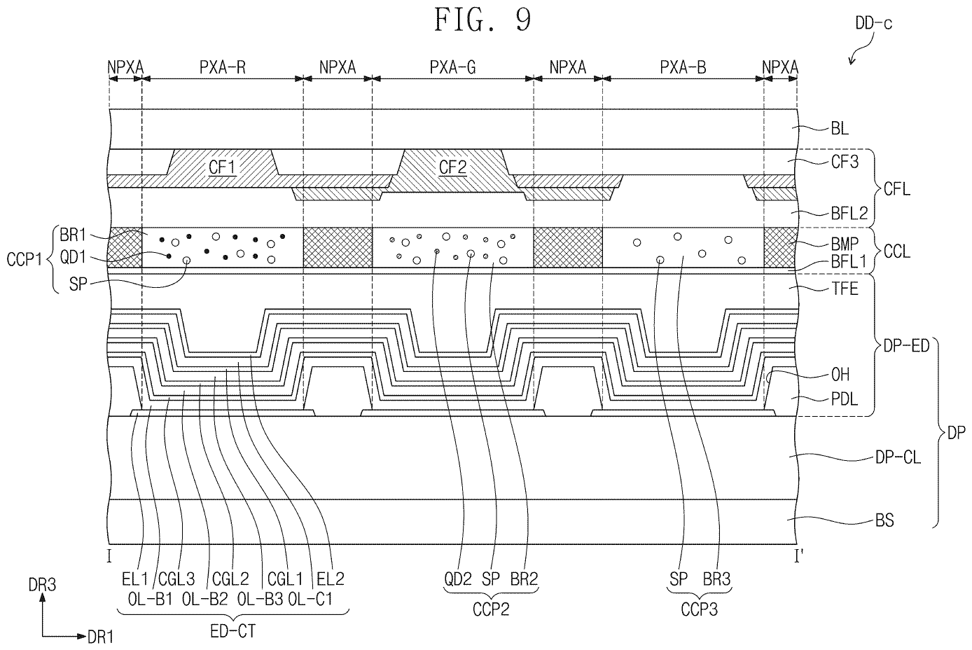

FIG. 8 is a cross-sectional view of a display device according to one or more embodiments of the present disclosure. FIG. 9 is a cross-sectional view of a display device according to one or more embodiments of the present disclosure.

Referring to FIG. 8, a display device DD-b according to one or more embodiments may include light-emitting elements ED-1, ED-2, and ED-3 in each of which two emission layers are stacked. Compared to the display device DD according to embodiments illustrated in FIG. 4, the embodiment illustrated in FIG. 8 is different in that each of first to third light-emitting elements ED-1, ED-2, and ED-3 includes two emission layers stacked in a thickness direction. The two emission layers of each of the first to third light-emitting elements ED-1, ED-2, and ED-3 may be to emit light in substantially the same wavelength range.

In one or more embodiments, the first light-emitting element ED-1 may include a first red-color emission layer EML-R1 and a second red-color emission layer EML-R2. The second light-emitting element ED-2 may include a first green-color emission layer EML-G1 and a second green-color emission layer EML-G2. In addition, the third light-emitting element ED-3 may include a first blue-color emission layer EML-B1 and a second blue-color emission layer EML-B2. An auxiliary emission part OG may be arranged between the first red-color emission layer EML-R1 and the second red-color emission layer EML-R2, between the first green-color emission layer EML-G1 and the second green-color emission layer EML-G2, and between the first blue-color emission layer EML-B1 and the second blue-color emission layer EML-B2.

The auxiliary emission part OG may include a single layer or multiple layers. The auxiliary emission part OG may include a charge-generating layer. For example, the auxiliary emission part OG may include an electron transport region, a charge-generating layer, and a hole transport region stacked in sequence (e.g., in the stated order). The auxiliary emission part OG may be provided as a common layer to the entire first to third light-emitting elements ED-1, ED-2, and ED-3. However, embodiments of the present disclosure are not limited thereto, and the auxiliary emission part OG may be provided by being patterned in an opening OH defined in a pixel-defining film PDL.

The first red-color emission layer EML-R1, the first green-color emission layer EML-G1, and the first blue-color emission layer EML-B1 may each be arranged between the auxiliary emission part OG and the electron transport region ETR. The second red-color emission layer EML-R2, the second green-color emission layer EML-G1, and the second blue-color emission layer EML-B2 may each be arranged between the hole transport region HTR and the auxiliary emission part OG.

For example, in one or more embodiments, the first light-emitting element ED-1 may include a first electrode EL1, a hole transport region HTR, a second red-color emission layer EML-R2, an auxiliary emission part OG, a first red-color emission layer EML-R1, an electron transport region ETR, and a second electrode EL2 stacked in sequence (e.g., in the stated order). The second light-emitting element ED-2 may include a first electrode EL1, the hole transport region HTR, a second green-color emission layer EML-G2, the auxiliary emission part OG, a first green-color emission layer EML-G1, the electron transport region ETR, and a second electrode EL2 stacked in sequence (e.g., in the stated order). The third light-emitting element ED-3 may include a first electrode EL1, the hole transport region HTR, a second blue-color emission layer EML-B2, the auxiliary emission part OG, a first blue-color emission layer EML-B1, the electron transport region ETR, and a second electrode EL2 stacked in sequence (e.g., in the stated order).

In one or more embodiments, an auxiliary optical layer PL may be arranged on a display element layer DP-ED. The auxiliary optical layer PL may include a polarizing layer. The auxiliary optical layer PL may be arranged on a display panel DP, and may control reflected light of external light on the display panel DP. In one or more embodiments, the auxiliary optical layer PL may not be provided in the display device.

At least one emission layer included in the display device DD-b according to one or more embodiments illustrated in FIG. 8 may include the fused polycyclic compound according to one or more embodiments described above. For example, in one or more embodiments, at least one of the first blue-color emission layer EML-B1 or the second blue-color emission layer EML-B2 may include the fused polycyclic compound according to one or more embodiments.

Unlike FIG. 7 and FIG. 8, FIG. 9 illustrates that a display device DD-c includes four emission structures OL-B1, OL-B2, OL-B3, and OL-C1. The light-emitting element ED-CT may include a first electrode EL1 and a second electrode EL2 opposite to (e.g., facing) each other, and first to fourth emission structures OL-B1, OL-B2, OL-B3, and OL-C1 stacked in sequence in a thickness direction between the first electrode EL1 and the second electrode EL2. Charge-generating layers CGL1, CGL2, and CGL3 may be arranged between the first to fourth emission structures OL-B1, OL-B2, OL-B3, and OL-C1. For example, a first charge-generating layer CGL1 may be arranged between the third emission structure OL-B3 and the fourth emission structure OL-C1. A second charge-generating layer CGL2 may be arranged between the second emission structure OL-B2 and the third emission structure OL-B3. The third charge-generating layer CGL3 may be arranged between the first emission structure OL-B1 and the second emission structure OL-B2. In one or more embodiments, the first to third emission structures OL-B1, OL-B2, and OL-B3 among the four emission structures may be to emit blue color light, and the fourth emission structure OL-CL may be to emit green color light. However, embodiments of the present disclosure are not limited thereto, for example, in one or more embodiments, the first to fourth emission structures OL-B1, OL-B2, OL-B3, and OL-C1 may be to emit light in different wavelength ranges.

The charge-generating layer CGL1, CGL2, and CGL3 arranged between the emission structures OL-B1, OL-B2, OL-B3, and OL-C1 adjacent to each other may include a p-type (kind) charge-generating layer and/or an n-type (kind) charge-generating layer.

The fused polycyclic compound according to one or more embodiments, described above, may be included in at least one selected from among the emission structures OL-B1, OL-B2, OL-B3, and OL-C1 included in the display device DD-c according to one or more embodiments. For example, in one or more embodiments, at least one selected from among the first to third emission structures OL-B1, OL-B2, and OL-B3 may include the fused polycyclic compound according to one or more embodiments.

The light-emitting element ED according to one or more embodiments of the present disclosure may include the fused polycyclic compound, according to one or more embodiments, represented by Formula 1 in at least one functional layer arranged between the first electrode EL1 and the second electrode EL2, thereby exhibiting excellent or suitable luminescence efficiency and improved lifespan characteristics. For example, the fused polycyclic compound according to one or more embodiments may be included in the emission layer EML of the light-emitting element ED according to one or more embodiments, and the light-emitting element according to one or more embodiments may have long lifespan characteristics. In one or more embodiments, an electronic apparatus may include a display device including a display panel containing a plurality of light-emitting elements, and a control part that controls the display device. The electronic apparatus according to one or more embodiments may include the fused polycyclic compound represented by Formula 1 in at least one selected from among the plurality of light-emitting elements. For example, the electronic apparatus according to one or more embodiments may include the fused polycyclic compound according to one or more embodiments in an emission layer of the light-emitting element. The electronic apparatus according to one or more embodiments may be activated in response to electrical signals. The electronic apparatus may include the display devices according to one or more embodiments. The electronic apparatus according to one or more embodiments may include the display device according to one or more embodiments described above.

The electronic apparatus may include not only a large-size electronic apparatus such as a television, a monitor, and/or an outdoor billboard, but also a small- and medium-size electronic apparatus such as a personal computer, a laptop computer, a personal digital assistant, a car navigation unit, a game console, a smartphone, a tablet computer, a smart watch, and/or a camera. In addition, these are presented only as examples, and the display device according to one or more embodiments may also be employed in another electronic apparatus as long as it does not deviate from the scope and spirit of the disclosure.

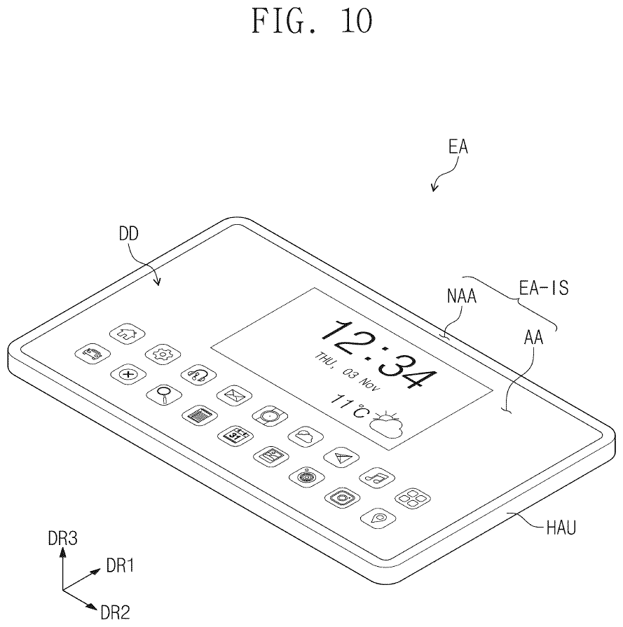

FIG. 10 illustrates a tablet device as an example of the electronic apparatus EA according to one or more embodiments. Electronic modules, a camera module, a power module, and/or the like mounted on a main board, may be arranged in a bracket/housing HAU, and/or the like together with a display device DD to thereby provide the tablet device.

In one or more embodiments, the electronic apparatus EA including the display device DD having a flat display surface is illustrated, but embodiments of the present disclosure are not limited thereto. In one or more embodiments, the electronic apparatus EA may include a curved display surface or a three-dimensional display surface. For example, the three-dimensional display surface may include a plurality of display regions indicating different directions, and may also include a bent display surface. The electronic apparatus EA according to these embodiments may be a flexible electronic apparatus. The flexible electronic apparatus may be a foldable electronic apparatus capable of folding.

As illustrated in FIG. 10, a display surface EA-IS includes an active region AA in which an image is displayed, and a bezel region NAA adjacent to the active region AA. The bezel region NAA is a region where an image is not displayed. FIG. 10 illustrates icon images as an example of the image. The active region AA may be referred to as a display region of the display device DD, and the bezel region NAA may be referred to as a non-display region of the display device DD.

The electronic apparatus EA according to one or more embodiments illustrated in FIG. 10 may include the display device DD according to one or more embodiments, described with reference to FIGS. 3 and 4, FIGS. 6 to 9, and/or the like. The display device DD may be accommodated in the housing HAU.

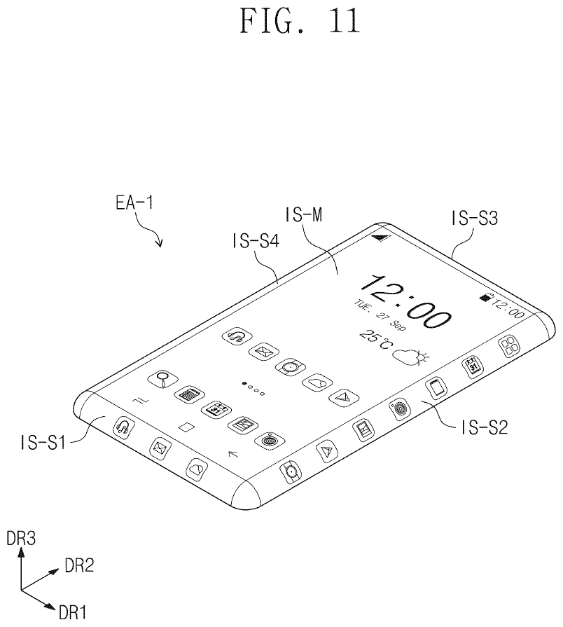

FIG. 11 illustrates a portable device as an example of an electronic apparatus EA-1 according to one or more embodiments. Referring to FIG. 11, the electronic apparatus EA-1 according to one or more embodiments may include a plurality of display surfaces. The electronic apparatus EA-1 according to one or more embodiments may include display surfaces IS-M, IS-S1, IS-S2, IS-S3, and IS-S4 whose main display directions differ from one another.

For example, in one or more embodiments, the electronic apparatus EA-1 may be a three-dimensional display device that includes an upper display surface IS-M and a plurality of side display surfaces IS-S1, IS-S2, IS-S3, and IS-S4. The plurality of side display surfaces IS-S1, IS-S2, IS-S3, and IS-S4 may each be a display surface extending from one side of the upper display surface IS-M. The electronic apparatus EA-1 according to one or more embodiments may include a main display surface providing images mainly in one direction, and a plurality of sub display surfaces each providing images in a different direction from the one direction. In one or more embodiments of the electronic apparatus EA-1 illustrated in FIG. 11, the main display surface may be the upper display surface IS-M, and the sub display surfaces may be the side display surfaces IS-S1, IS-S2, IS-S3, and IS-S4.

The side display surfaces IS-S1, IS-S2, IS-S3, and IS-S4 may each have a display surface which is not parallel to the upper display surface IS-M. In one or more embodiments, the plurality of side display surfaces S-S1, IS-S2, IS-S3, and IS-S4 may be display regions each of which is bent from one side of the upper display surface IS-M to extend, and for example, the plurality of side display surfaces S-S1, IS-S2, IS-S3, and IS-S4 may be bending display regions.

The electronic apparatus EA-1, according to one or more embodiments illustrated in FIG. 11, may include the display device, according to one or more embodiments, described with reference to FIGS. 3 and 4, FIGS. 6 to 9, and/or the like.

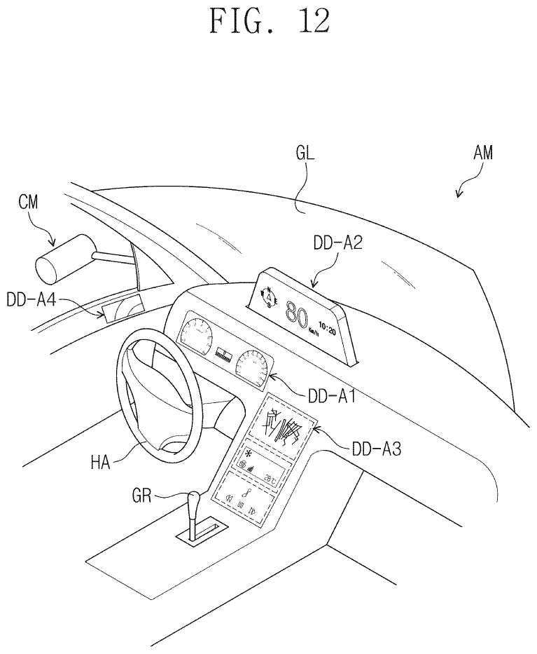

FIG. 12 is a drawing illustrating a vehicle AM as an example of an electronic apparatus in which first to fourth display devices DD-A1, DD-A2, DD-A3, and DD-A4 are arranged. The electronic apparatus according to one or more embodiments may include a plurality of display devices. At least one selected from among the first to fourth display devices DD-A1, DD-A2, DD-A3, and DD-A4 may include a configuration selected from among the configures of the display devices DD, DD-TD, DD-a, DD-b, and DD-c according to embodiments described with reference to FIGS. 3 and 4, and FIGS. 6 to 9, and/or the like.

FIG. 12 illustrates an automobile as the vehicle AM, but this is an example, and the first to fourth display devices DD-A1, DD-A2, DD-A3, and DD-A4 may be arranged in another vehicle such as a bicycle, a motorcycle, a train, a ship, or an airplane. In one or more embodiments, at least one selected from the first to fourth display devices DD-A1, DD-A2, DD-A3, and DD-A4, including the same configuration as those of the display device DD, DD-TD, DD-a, DD-TD, DD-b, and DD-c according to one or more embodiments, may be employed to a personal computer, a laptop computer, a personal digital assistant, a game console, a portable electronic device, a television, a monitor, an outdoor billboard, and/or the like. In addition, these are presented only as examples, and the display device may also be employed in other electronic apparatuses as long as it does not deviate from the scope and spirit of the disclosure.

At least one selected from among the first to fourth display devices DD-A1, DD-A2, DD-A3, and DD-A4 may include the light-emitting element ED according to one or more embodiments described with reference to FIG. 5. The light-emitting element ED according to one or more embodiments may include a fused polycyclic compound represented by Formula 1 according to one or more embodiments. At least one selected from among the first to fourth display devices DD-A1, DD-A2, DD-A3, and DD-A4 may include the light-emitting element ED containing the fused polycyclic compound according to one or more embodiments, and may thus have improved display lifespan.

Referring to FIG. 12, the vehicle AM may include a steering wheel HA and a gear GR for operation of the vehicle AM. In addition, the vehicle AM may include a front window GL arranged toward a driver.

The first display device DD-A1 may be arranged in a first region overlapping the steering wheel HA. For example, the first display device DD-A1 may be a digital cluster that displays first information of the vehicle AM. The first information may include a first scale indicating the driving speed of the vehicle AM, a second scale indicating the engine speed (that is, revolutions per minute (RPM)), an image indicating the fuel state, and/or the like. In one or more embodiments, the first scale and the second scale may be provided in digital images.

The second display device DD-A2 may be arranged in a second region opposite to (e.g., facing) a driver seat and overlapping the front window GL. The driver seat may be a seat where the steering wheel HA faces. For example, the second display device DD-A2 may be a head-up display (HDD) that displays second information of the vehicle AM. In one or more embodiments, the second display device DD-A2 may be optically transparent. The second information may include digital numbers indicating the driving speed of the vehicle AM, and may further include information on the current time, and/or the like. In one or more embodiments, the second information of the second display device DD-A2 may be displayed by being projected on the front window GL.

The third display device DD-A3 may be arranged in a third region adjacent to the gear GR. For example, the third display device DD-A3 may be a center information display (CID) for the vehicle that is arranged between the driver seat and a passenger seat, and displays third information. The passenger seat may be a seat spaced apart from the driver seat with the gear GR therebetween. The third information may include information on road conditions (for example, navigation information), music or radio play, dynamic movie or image play, temperature inside the vehicle AM, and/or the like.

The fourth display device DD-A4 may be arranged in a fourth region spaced apart from the steering wheel HA and the gear GR, and adjacent to a side portion of the vehicle AM. For example, the fourth display device DD-A4 may be a digital side mirror that displays fourth information. The fourth display device DD-A4 may display external image of the vehicle AM taken from a camera module CM arranged on the outside of the vehicle AM. The fourth information may include external images of the vehicle AM.

The first to fourth information described above are examples, and the first to fourth display devices DD-A1, DD-A2, DD-A3, and DD-A4 may further display information on the inside and outside of the vehicle AM. The first to fourth information may include information different from one another. However, embodiments of the present disclosure are not limited thereto, and some of the first to fourth information may include the same information to each other.

Hereinafter, with reference to Examples and Comparative Examples, the fused polycyclic compound according to one or more embodiments of the present disclosure and the light-emitting element according to one or more embodiments will be described in more detail. In addition, the following examples are intended to help understanding of the disclosure, and the scope of the disclosure is not limited thereto.

### Example

### 1. Synthesis of Fused Polycyclic Compound

First, a synthesis method of the fused polycyclic compound according to one or more embodiments will be described in more detail with reference to examples of the synthesis method of Compounds 311, 323, 344, 365, 392, and 403. In addition, the synthesis method of the fused polycyclic compound to be described hereinafter is an example, and the synthesis method of the fused polycyclic compound according to one or more embodiments of the present disclosure are not limited to the following examples.

### (1) Synthesis of Compound 311

Compound 311 according to one or more embodiments may be synthesized by Reaction Scheme 1 as an example.

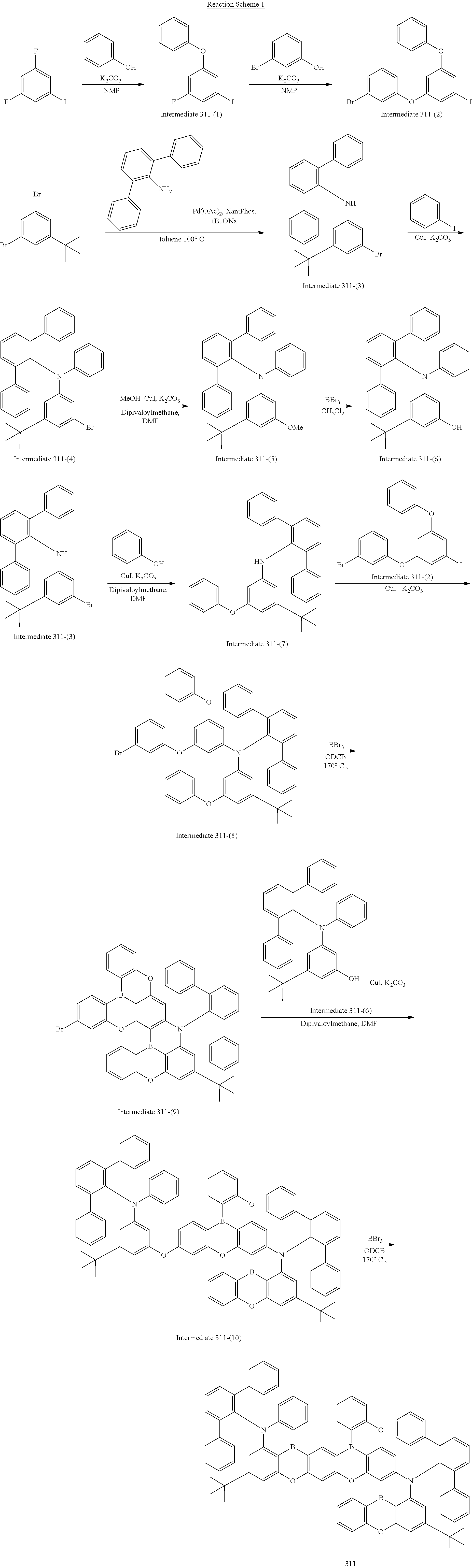

### Synthesis of Intermediate 311-(1)

Under an Ar atmosphere, 1,3-difluoro-5-iodobenzene (about 10.21 g, about 42.54 mmol), phenol (about 4.00 g, about 42.54 mmol), and K₂CO₃ (about 26.46 g, about 191.45 mmol) were added to about 102 mL of N-methylpyrrolidone (NMP), and heated for about 24 hours while maintaining the temperature at about 140° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 311-(1) (about 10.82 g, about 81% yield). The molecular weight of Intermediate 311-(1) was about 314 from Fast Atom Bombardment-Mass spectroscopy (FAB MS) measurement.

### Synthesis of Intermediate 311-(2)

Under an Ar atmosphere, Intermediate 311-(1) (about 10.21 g, about 32.51 mmol), 3-bromophenol (about 5.62 g, about 32.51 mmol), and K₂CO₃ (about 20.22 g, about 146.28 mmol) were added to about 102 mL of NMP, and heated for about 24 hours while maintaining the temperature at about 140° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 311-(2) (about 11.54 g, about 76% yield). The molecular weight of Intermediate 311-(2) was about 467 from FAB MS measurement.

### Synthesis of Intermediate 311-(3)

Under an Ar atmosphere, 1,3-dibromo-5-(tert-butyl)benzene (about 10.22 g, about 35 mmol), [1,1′:3′,1″-terphenyl]-2′-amine (about 8.59 g, about 35 mmol), Pd(OAc)₂ (about 0.24 g, about 1.05 mmol), 4,5-bis(diphenylphosphino)-9,9-dimethylxanthene (XantPhos) (about 1.22 g, about 2.1 mmol), and tBuONa (about 4.04 g, about 42 mmol) were added to about 174 mL of toluene, and heated and agitated for about 8 hours at about 100° C. After cooled, the resultant mixture was added with water, filtered through celite and separated by extraction, and the organic layer was concentrated. Purification was performed with silica gel column chromatography to obtain Intermediate 311-(3) (about 13.58 g about 85% yield). The molecular weight of Intermediate 311-(3) was about 456 from FAB MS measurement.

### Synthesis of Intermediate 311-(4)

Toluene in a small amount of about 10 mL was added to Intermediate 311-(3) (about 10.52 g, about 23.05 mmol), iodobenzene (about 47.02 g, about 230.48 mmol), CuI (about 10.97 g, about 57.62 mmol), and K₂CO₃ (about 47.78 g, about 345.73 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 311-(4) (about 8.71 g, about 71% yield). The molecular weight of Intermediate 311-(4) was about 533 from FAB MS measurement.

### Synthesis of Intermediate 311-(5)

Intermediate 311-(4) (about 11.15 g, about 20.94 mmol) and methanol (about 0.81 g, about 25.13 mmol), CuI (about 4.39 g, about 23.03 mmol), K₂CO₃ (about 11.57 g, about 83.75 mmol), and dipivaloylmethane (about 43.86 g, about 0.24 mmol) were added to N,N-dimethylformamide (DMF) (about 438 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 311-(5) (about 6.28 g, about 62% yield). The molecular weight of Intermediate 311-(5) was about 484 from FAB MS measurement.

### Synthesis of Intermediate 311-(6)

Under an Ar atmosphere, Intermediate 311-(5) (about 6.11 g, about 12.63 mmol) was dissolved in CH₂Cl₂ (about 126 mL), BBr₃ (about 7.91 g, about 31.58 mmol) was added thereto, and the solution was agitated for about 24 hours at about 0° C. The reaction solution was added to iced water (about 306 mL), agitated for about 1 hour, and then separated by extraction, and the organic layer was concentrated. Purification was performed with silica gel column chromatography to obtain Intermediate 311-(6) (about 3.03 g, about 51% yield). The molecular weight of Intermediate 311-(6) was about 470 from FAB MS measurement.

### Synthesis of Intermediate 311-(7)

Intermediate 311-(3) (about 11.15 g, about 24.43 mmol), phenol (about 2.76 g, about 29.31 mmol), CuI (about 5.12 g, about 26.87 mmol), K₂CO₃ (about 13.5 g, about 97.71 mmol), and dipivaloylmethane (about 51.18 g, about 0.28 mmol) were added to DMF (about 511 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 311-(7) (about 9.29 g, about 81% yield). The molecular weight of Intermediate 311-(7) was about 470 from FAB MS measurement.

### Synthesis of Intermediate 311-(8)

Toluene in a small amount of about 10 mL was added to Intermediate 311-(7) (about 2.01 g, about 4.28 mmol), Intermediate 311-(2) (about 19.99 g, about 42.8 mmol), CuI (about 2.04 g, about 10.7 mmol), and K₂CO₃ (about 8.87 g, about 64.2 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 311-(8) (about 2.46 g, about 71% yield). The molecular weight of Intermediate 311-(8) was about 809 from FAB MS measurement.

### Synthesis of Intermediate 311-(9)

Under an Ar atmosphere, Intermediate 311-(8) (about 4.21 g, about 5.21 mmol) was dissolved in 1,2-dichlorobenzene (ODCB) (about 52 mL), BBr₃ (about 2.61 g, about 10.41 mmol) was added thereto, and the solution was heated and agitated for about 10 hours at about 170° C. The reaction solution was cooled to room temperature, added with N,N-diisopropylethylamine (about 8.06 g, about 62.46 mmol) and water was added, the obtained was filtered through celite and separated by extraction, and the organic layer was concentrated. Purification was performed with silica gel column chromatography to obtain Intermediate 311-(9) (about 1.12 g, about 26% yield). The molecular weight of Intermediate 311-(9) was about 824 from FAB MS measurement.

### Synthesis of Intermediate 311-(10)

Intermediate 311-(9) (about 1.02 g, about 1.24 mmol), Intermediate 311-(6) (about 0.7 g, about 1.48 mmol), CuI (about 0.26 g, about 1.36 mmol), K₂CO₃ (about 0.68 g, about 4.95 mmol), and dipivaloylmethane (about 2.59 g, about 0.01 mmol) were added to DMF (about 25 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 311-(10) (about 1.07 g, about 71% yield). The molecular weight of Intermediate 311-(10) was about 1213 from FAB MS measurement.

### Synthesis of Compound 311

Under an Ar atmosphere, Intermediate 311-(10) (about 1.01 g, about 0.83 mmol) was dissolved in 1,2-dichlorobenzene (ODCB) (about 8 mL), BBr₃ (about 0.42 g, about 1.67 mmol) was added thereto, and the solution was heated and agitated for about 10 hours at about 170° C. The reaction solution was cooled to room temperature, added with N,N-diisopropylethylamine (about 1.29 g, about 9.99 mmol), water was added, the obtained was filtered through celite and separated by extraction, and the organic layer was concentrated. Purification was performed with silica gel column chromatography to obtain Compound 311 (about 0.59 g, about 58% yield). The molecular weight of Compound 311 was about 1221 from FAB MS measurement. Compound 311 to be described later was sublimed and purified to be used (about 320° C., about 2.3×10⁻³ Pa).

### (2) Synthesis of Compound 323

Compound 323 according to one or more embodiments may be synthesized by using intermediate compounds synthesized by the Reaction Scheme2 as an example.

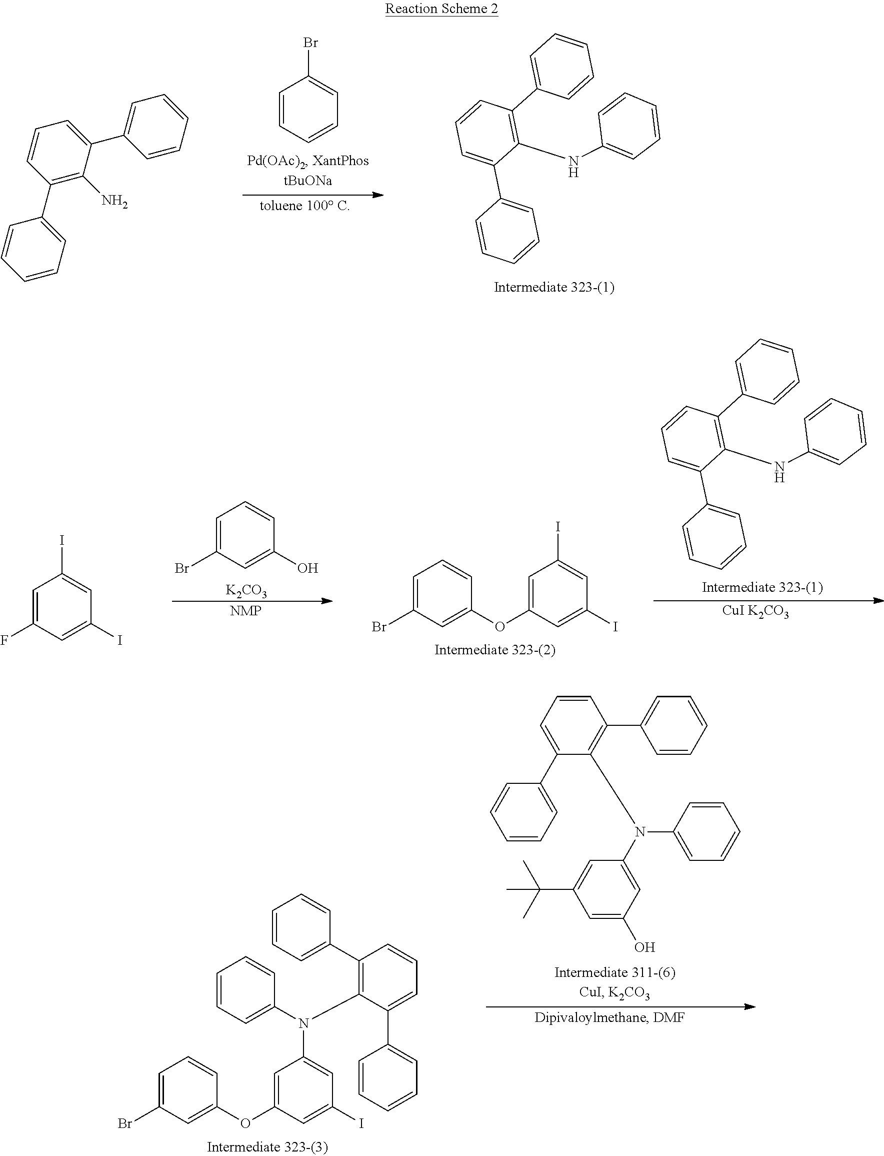

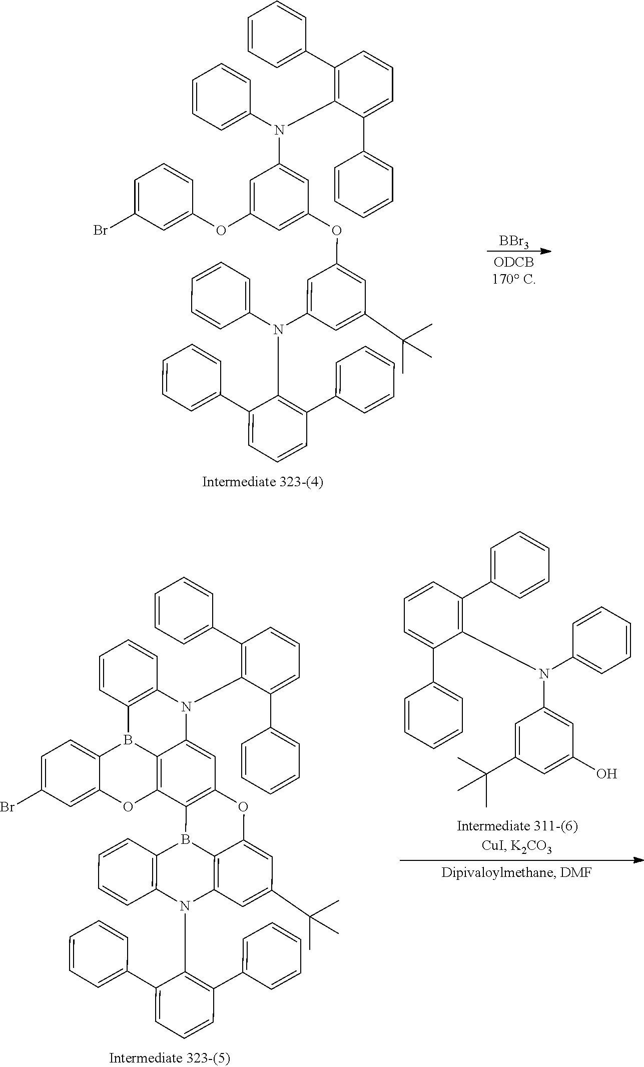 [SMILES: CC(C)(C)c1cc(Oc2cc(Oc3cccc(Br)c3)cc(N(c3ccccc3)c3c(-c4ccccc4)cccc3-c3ccccc3)c2)cc(N(c2ccccc2)c2c(-c3ccccc3)cccc2-c2ccccc2)c1 ; "BBr3" ; CC(C)(C)c1cc2c3c(c1)N(c1c(-c4ccccc4)cccc1-c1ccccc1)c1ccccc1B3c1c(cc3c4c1Oc1cc(Br)ccc1B4c1ccccc1N3c1c(-c3ccccc3)cccc1-c1ccccc1)O2 ; CC(C)(C)c1cc(O)cc(N(c2ccccc2)c2c(-c3ccccc3)cccc2-c2ccccc2)c1]

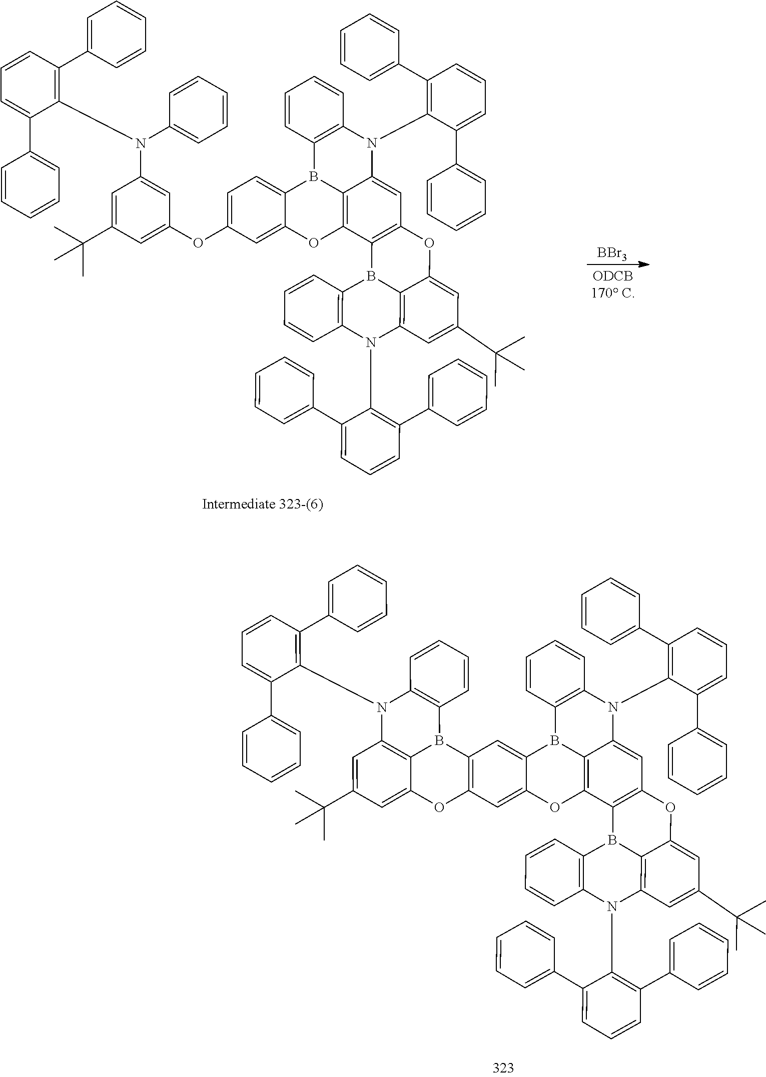 [SMILES: CC(C)(C)c1cc(Oc2ccc3c(c2)Oc2c4c(cc5c2B3c2ccccc2N5c2c(-c3ccccc3)cccc2-c2ccccc2)Oc2cc(C(C)(C)C)cc3c2B4c2ccccc2N3c2c(-c3ccccc3)cccc2-c2ccccc2)cc(N(c2ccccc2)c2c(-c3ccccc3)cccc2-c2ccccc2)c1 ; "BBr3" ; CC(C)(C)c1cc2c3c(c1)N(c1c(-c4ccccc4)cccc1-c1ccccc1)c1ccccc1B3c1cc3c(cc1O2)Oc1c2c(cc4c1B3c1ccccc1N4c1c(-c3ccccc3)cccc1-c1ccccc1)Oc1cc(C(C)(C)C)cc3c1B2c1ccccc1N3c1c(-c2ccccc2)cccc1-c1ccccc1]

### Synthesis of Intermediate 323-(1)

Under an Ar atmosphere, bromobenzene (about 11.04 g, about 70.31 mmol), [1,1′:3′,1″-terphenyl]-2′-amine (about 17.25 g, about 70.31 mmol), Pd(OAc)₂ (about 0.47 g, about 2.11 mmol), XantPhos (about 2.44 g, about 4.22 mmol), tBuONa (about 8.11 g, about 84.38 mmol) were added to about 351 mL of toluene, and heated and agitated for about 8 hours at about 100° C. After cooled, the resultant mixture was added with water, and filtered through celite and separated by extraction, and the organic layer was concentrated. Purification was performed with silica gel column chromatography to obtain Intermediate 323-(1) (about 18.31 g, about 81% yield). The molecular weight of Intermediate 323-(1) was about 321 from FAB MS measurement.

### Synthesis of Intermediate 323-(2)

Under an Ar atmosphere, 1-fluoro-3,5-diiodobenzene (about 50.13 g, about 159.6 mmol), 3-bromophenol (about 27.61 g, about 159.6 mmol), K₂CO₃ (about 99.26 g, about 718.19 mmol) were added to about 501 mL of NMP, and heated for about 24 hours while maintaining the temperature at about 140° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 323-(2) (about 57.4 g, about 77% yield). The molecular weight of Intermediate 323-(2) was about 467 from FAB MS measurement.

### Synthesis of Intermediate 323-(3)

Toluene in a small amount of about 10 mL was added to Intermediate 323-(1) (about 4.88 g, about 15.18 mmol), Intermediate 323-(2) (about 56.73 g, about 121.46 mmol), CuI (about 7.23 g, about 37.96 mmol), and K₂CO₃ (about 31.48 g, about 227.74 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 323-(3) (about 7.17 g, about 68% yield). The molecular weight of Intermediate 323-(3) was about 694 from FAB MS measurement.

### Synthesis of Intermediate 323-(4)

Intermediate 323-(3) (about 5.11 g, about 7.36 mmol), Intermediate 311-(6) (about 2.84 g, about 8.83 mmol), CuI (about 1.54 g, about 8.09 mmol), K₂CO₃ (about 4.07 g, about 29.44 mmol), and dipivaloylmethane (about 15.42 g, about 0.08 mmol) were added to DMF (about 154 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 323-(4) (about 5.64 g, about 74% yield). The molecular weight of Intermediate 323-(4) was about 1036 from FAB MS measurement.

### Synthesis of Intermediate 323-(5)

Under an Ar atmosphere, Intermediate 323-(4) (about 5.44 g, about 5.25 mmol) was dissolved in 1,2-dichlorobenzene (ODCB) (about 53 mL), BBr₃ (about 2.63 g, about 10.5 mmol) was added thereto, and the solution was heated and agitated for about 10 hours at about 170° C. After cooled, the reaction solution was cooled to room temperature, added with N,N-diisopropylethylamine (about 8.13 g, about 63 mmol) and water was added, the obtained was filtered through celite and separated by extraction, and the organic layer was concentrated. Purification was performed with silica gel column chromatography to obtain Intermediate 323-(5) (about 3.37 g, about 61% yield). The molecular weight of Intermediate 323-(5) was about 1052 from FAB MS measurement.

### Synthesis of Intermediate 323-(6)

Intermediate 323-(5) (about 3.09 g, about 2.94 mmol), Intermediate 311-(6) (about 1.66 g, about 3.53 mmol), CuI (about 0.62 g, about 3.23 mmol), K₂CO₃ (about 1.62 g, about 11.75 mmol), and dipivaloylmethane (about 6.16 g, about 0.03 mmol) were added to DMF (about 61 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 323-(6) (about 2.75 g, about 65% yield). The molecular weight of Intermediate 323-(6) was about 1440 from FAB MS measurement.

### Synthesis of Compound 323

Under an Ar atmosphere, Intermediate 323-(6) (about 2.55 g, about 1.77 mmol) was dissolved in 1,2-dichlorobenzene (ODCB) (about 18 mL), BBr₃ (about 0.89 g, about 3.54 mmol) was added thereto, and the solution was heated and agitated for about 10 hours at about 170° C. After cooled, the reaction solution was cooled to room temperature, added with N,N-diisopropylethylamine (about 2.74 g, about 21.24 mmol) and water was added, the obtained was filtered through celite and separated by extraction, and the organic layer was concentrated. Purification was performed with silica gel column chromatography to obtain Compound 323 (about 0.97 g, about 38% yield). The molecular weight of Compound 323 was about 1448 from FAB MS measurement. For evaluation of a light-emitting element, Compound 323 was sublimed and purified to be used (about 370° C., about 2.3×10⁻³ Pa).

### (3) Synthesis of Compound 344

Compound 344 according to one or more embodiments may be synthesized by Reaction Scheme 3 as an example.

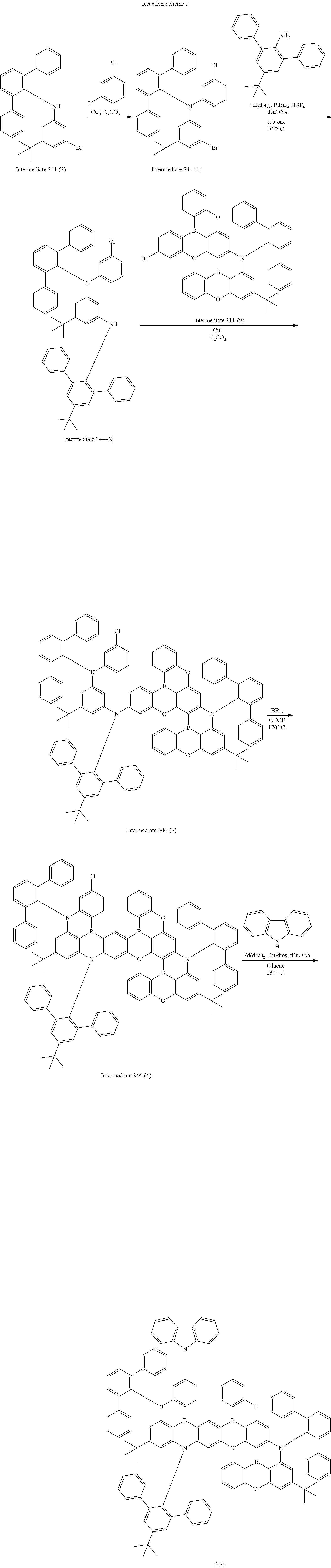

### Synthesis of Intermediate 344-(1)

Toluene in a small amount of about 10 mL was added to Intermediate 311-(3) (about 12.02 g, about 26.33 mmol), 1-chloro-3-iodobenzene (about 50.24 g, about 210.68 mmol), CuI (about 12.54 g, about 65.84 mmol), and K₂CO₃ (about 54.6 g, about 395.02 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 344-(1) (about 11.65 g, about 78% yield). The molecular weight of Intermediate 344-(1) was about 567 from FAB MS measurement.

### Synthesis of Intermediate 344-(2)

Under an Ar atmosphere, Intermediate 344-(1) (about 11.55 g, about 20.37 mmol), 5′-(tert-butyl)-[1,1′:3′,1″-terphenyl]-2′-amine (about 7.37 g, about 24.45 mmol), bis(dibenzylideneacetone)palladium(0) (Pd(dba)₂) (about 1.17 g, about 2.04 mmol), P(tBu)₃·HBF₄ (about 1.18 g, about 4.07 mmol), and tBuONa (about 4.5 g, about 46.85 mmol) were added to about 101 mL of toluene, and heated and agitated for about 8 hours at about 100° C. After cooled, the resultant mixture was added with water, filtered through celite and separated by extraction, and the organic layer was concentrated. Purification was performed with silica gel column chromatography to obtain Intermediate 344-(2) (about 13.15 g, about 82% yield). The molecular weight of Intermediate 344-(2) was about 787 from FAB MS measurement.

### Synthesis of Intermediate 344-(3)

Toluene in a small amount of about 10 mL was added to Intermediate 311-(9) (about 2.11 g, about 2.56 mmol), Intermediate 344-(2) (about 16.12 g, about 20.48 mmol), CuI (about 1.22 g, about 6.4 mmol), and K₂CO₃ (about 5.31 g, about 38.39 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 344-(3) (about 2.04 g, about 52% yield). The molecular weight of Intermediate 344-(3) was about 1531 from FAB MS measurement.

### Synthesis of Intermediate 344-(4)

Under an Ar atmosphere, Intermediate 344-(3) (about 1.81 g, about 1.18 mmol) was dissolved in 1,2-dichlorobenzene (ODCB) (about 12 mL), BBr₃ (about 0.59 g, about 2.36 mmol) was added thereto, and the solution was heated and agitated for about 10 hours at about 170° C. The reaction solution was cooled to room temperature, added with N,N-diisopropylethylamine (about 1.83 g, about 14.19 mmol), water was added, the obtained was filtered through celite and separated by extraction, and the organic layer was concentrated. Purification was performed with silica gel column chromatography to obtain Intermediate 344-(4) (about 0.69 g, about 38% yield). The molecular weight of Intermediate 344-(4) was about 1539 from FAB MS measurement.

### Synthesis of Compound 344

Under an Ar atmosphere, Intermediate 344-(4) (about 0.62 g, about 0.4 mmol), 9H-carbazole (about 0.08 g, about 0.48 mmol), Pd(dba)₂ (about 0.02 g, about 0.04 mmol), 2-dicyclohexylphosphino-2′,6′-diisopropoxybiphenyl (RuPhos) (about 0.04 g, about 0.08 mmol), and tBuONa (about 0.09 g, about 0.93 mmol) were added to about 2 mL of Xylene, and heated and agitated for about 24 hours at about 130° C. After cooled, the resultant mixture was added with water, filtered through celite and separated by extraction, and the organic layer was concentrated. Purification was performed with silica gel column chromatography to obtain Compound 344 (about 0.5 g, about 74% yield). The molecular weight of Compound 344 was about 1670 from FAB MS measurement. For evaluation of a light-emitting element, Compound 344 was sublimed and purified to be used (about 400° C., about 2.6×10⁻³ Pa).

### (4) Synthesis of Compound 365

Compound 365 according to one or more embodiments may be synthesized by Reaction Scheme 4 as an example.

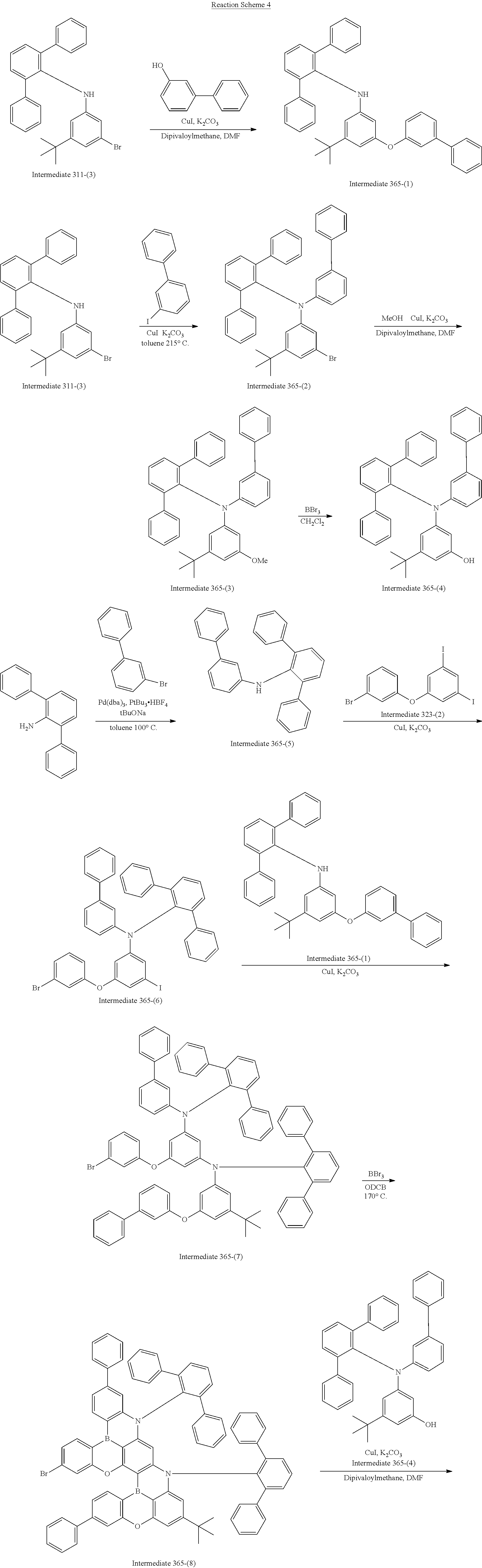

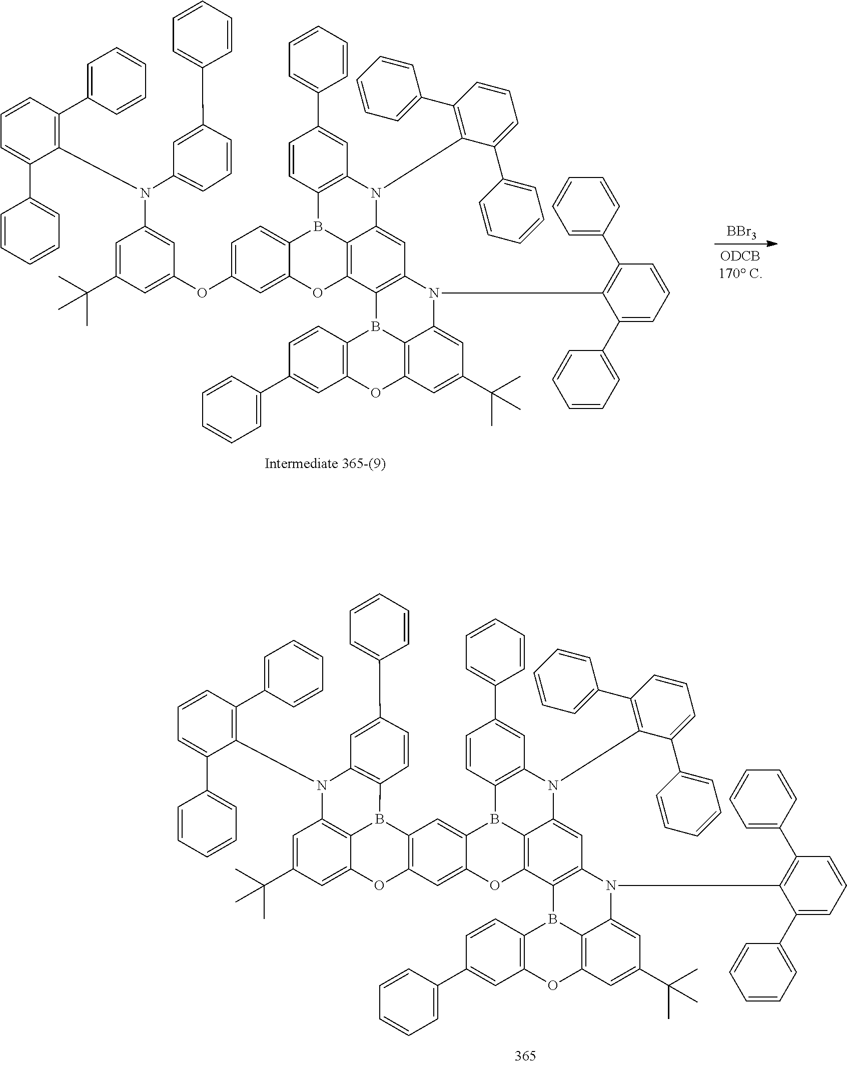 [SMILES: CC(C)(C)c1cc(Oc2ccc3c(c2)Oc2c4c(cc5c2B2c6ccc(-c7ccccc7)cc6Oc6cc(C(C)(C)C)cc(c62)N5c2c(-c5ccccc5)cccc2-c2ccccc2)N(c2c(-c5ccccc5)cccc2-c2ccccc2)c2cc(-c5ccccc5)ccc2B34)cc(N(c2cccc(-c3ccccc3)c2)c2c(-c3ccccc3)cccc2-c2ccccc2)c1 ; "BBr3" ; CC(C)(C)c1cc2c3c(c1)N(c1c(-c4ccccc4)cccc1-c1ccccc1)c1cc(-c4ccccc4)ccc1B3c1cc3c(cc1O2)Oc1c2c(cc4c1B1c5ccc(-c6ccccc6)cc5Oc5cc(C(C)(C)C)cc(c51)N4c1c(-c4ccccc4)cccc1-c1ccccc1)N(c1c(-c4ccccc4)cccc1-c1ccccc1)c1cc(-c4ccccc4)ccc1B32]

### Synthesis of Intermediate 365-(1)

Intermediate 311-(3) (about 7.58 g, about 16.61 mmol), [1,1′-biphenyl]-3-ol (about 3.39 g, about 19.93 mmol), CuI (about 3.48 g, about 18.27 mmol), K₂CO₃ (about 9.18 g, about 66.43 mmol), and dipivaloylm ethane (about 34.79 g, about 0.19 mmol) were added to DMF (about 347 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 365-(1) (about 6.07 g, about 67% yield). The molecular weight of Intermediate 365-(1) was about 546 from FAB MS measurement.

### Synthesis of Intermediate 365-(2)

Toluene in a small amount of about 10 mL was added to Intermediate 311-(3) (about 13.33 g, about 29.2 mmol), 3-iodo-1,1′-biphenyl (about 65.44 g, about 233.64 mmol), CuI (about 13.91 g, about 73.01 mmol), and K₂CO₃ (about 60.55 g, about 438.07 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 365-(2) (about 13.15 g, about 74% yield). The molecular weight of Intermediate 365-(2) was about 609 from FAB MS measurement.

### Synthesis of Intermediate 365-(3)

Intermediate 365-(2) (about 13.55 g, about 22.26 mmol), methanol (about 0.86 g, about 26.72 mmol), CuI (about 4.66 g, about 24.49 mmol), K₂CO₃ (about 12.31 g, about 89.05 mmol), and dipivaloylmethane (about 46.64 g, about 0.25 mmol) were added to DMF (about 466 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 365-(3) (about 8.85 g, about 71% yield). The molecular weight of Intermediate 365-(3) was about 560 from FAB MS measurement.

### Synthesis of Intermediate 365-(4)

Under an Ar atmosphere, Intermediate 365-(3) (about 8.77 g, about 15.67 mmol) was dissolved in CH₂Cl₂ (about 157 mL), BBr₃ (about 9.81 g, about 39.17 mmol) was added thereto, and the solution was agitated for about 24 hours at about 0° C. The reaction solution was added to iced water (about 439 mL), agitated for about 1 hour and separated by extraction, and the organic layer was concentrated. Purification was performed with silica gel column chromatography to obtain Intermediate 365-(4) (about 5.22 g, about 61% yield). The molecular weight of Intermediate 365-(4) was about 546 from FAB MS measurement.

### Synthesis of Intermediate 365-(5)

Under an Ar atmosphere, 3-bromo-1,1′-biphenyl (about 10.05 g, about 43.11 mmol), [1,1′: 3′, 1″-terphenyl]-2′-amine (about 12.69 g, about 51.74 mmol), Pd(dba)₂ (about 2.48 g, about 4.31 mmol), P(tBu)₃·HBF₄ (about 2.5 g, about 8.62 mmol), and tBuONa (about 9.53 g, about 99.16 mmol) were added to about 215 mL of toluene, and heated and agitated for about 8 hours at about 100° C. After cooled, the resultant mixture was added with water, and filtered through celite and separated by extraction, and the organic layer was concentrated. Purification was performed with silica gel column chromatography to obtain Intermediate 365-(5) (about 15.08 g, about 88% yield). The molecular weight of Intermediate 365-(5) was about 398 from FAB MS measurement.

### Synthesis of Intermediate 365-(6)

Toluene in a small amount of about 10 mL was added to Intermediate 365-(5) (about 5.33 g, about 13.41 mmol), Intermediate 323-(2) (about 53.73 g, about 107.27 mmol), CuI (about 6.38 g, about 33.52 mmol), and K₂CO₃ (about 27.8 g, about 201.12 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 365-(6) (about 7.65 g, about 74% yield). The molecular weight of Intermediate 365-(6) was about 771 from FAB MS measurement.

### Synthesis of Intermediate 365-(7)

Toluene in a small amount of about 10 mL was added to Intermediate 365-(6) (about 5.22 g, about 6.77 mmol), Intermediate 365-(1) (about 29.58 g, about 54.2 mmol), CuI (about 3.23 g, about 16.94 mmol), and K₂CO₃ (about 14.05 g, about 101.62 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 365-(7) (about 5.31 g, about 66% yield). The molecular weight of Intermediate 365-(7) was about 1188 from FAB MS measurement.

### Synthesis of Intermediate 365-(8)

Under an Ar atmosphere, Intermediate 365-(7) (about 5.12 g, about 4.31 mmol) was dissolved in 1,2-dichlorobenzene (ODCB) (about 43 mL), BBr₃ (about 2.16 g, about 8.62 mmol) was added thereto, and the solution was heated and agitated for about 10 hours at about 170° C. The reaction solution was cooled to room temperature, added with N,N-diisopropylethylamine (about 6.67 g, about 51.7 mmol) and water was added, the obtained was filtered through celite and separated by extraction, and the organic layer was concentrated. Purification was performed with silica gel column chromatography to obtain Intermediate 365-(8) (about 3.01 g, about 58% yield). The molecular weight of Intermediate 365-(8) was about 1204 from FAB MS measurement.

### Synthesis of Intermediate 365-(9)

Intermediate 365-(8) (about 2.87 g, about 2.38 mmol), Intermediate 365-(4) (about 1.56 g, about 2.86 mmol), CuI (about 0.5 g, about 2.62 mmol), K₂CO₃ (about 1.32 g, about 9.54 mmol), and dipivaloylmethane (about 4.99 g, about 0.03 mmol) were added to DMF (about 49 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 365-(9) (about 2.19 g, about 55% yield). The molecular weight of Intermediate 365-(9) was about 1669 from FAB MS measurement.

### Synthesis of Compound 365

Under an Ar atmosphere, Intermediate 365-(9) (about 1.85 g, about 1.11 mmol) was dissolved in 1,2-dichlorobenzene (ODCB) (about 11 mL), BBr₃ (about 0.56 g, about 2.22 mmol) was added thereto, and the solution was heated and agitated for about 10 hours at about 170° C. The reaction solution was cooled to room temperature, added with N,N-diisopropylethylamine (about 1.72 g, about 13.3 mmol) and water was added, the obtained was filtered through celite and separated by extraction, and the organic layer was concentrated. Purification was performed with silica gel column chromatography to obtain Compound 365 (about 0.95 g, about 51% yield). The molecular weight of Compound 365 was about 1676 from FAB MS measurement. For evaluation of a light-emitting element, Compound 365 was sublimed and purified to be used (about 400° C., about 2.7×10⁻³ Pa).

### (5) Synthesis of Compound 392

Compound 392 according to one or more embodiments may be synthesized by Reaction Scheme 5 as an example.

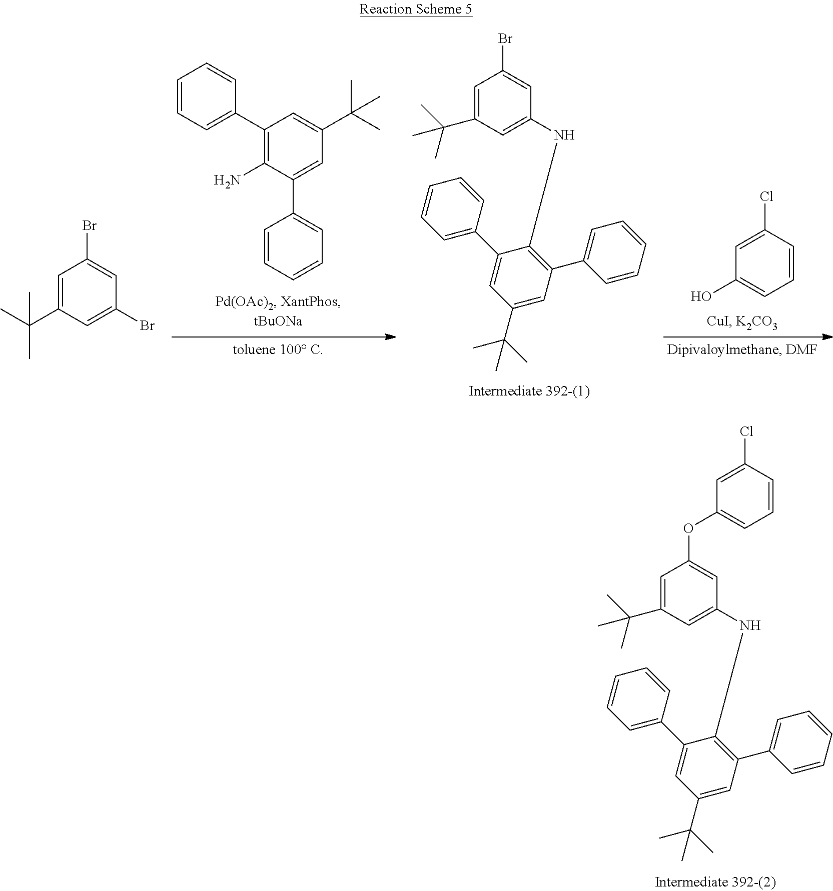

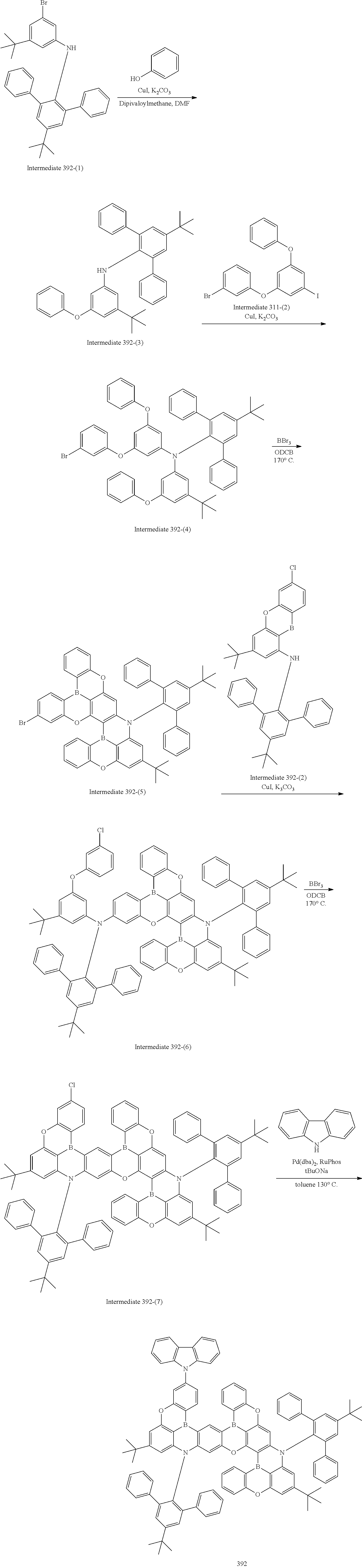

### Synthesis of Intermediate 392-(1)

Under an Ar atmosphere, 1,3-dibromo-5-(tert-butyl)benzene (about 11.15 g, about 38.18 mmol), 5′-(tert-butyl)-[1,1′:3′,1″-terphenyl]-2′-amine (about 12.08 g, about 40.09 mmol), Pd(OAc)₂ (about 0.26 g, about 1.15 mmol), XantPhos (about 1.33 g, about 2.29 mmol), and tBuONa (about 4.4 g, about 45.82 mmol) were added to about 190 mL of toluene, and heated and agitated for about 8 hours at about 100° C. After cooled, the resultant mixture was added with water, and filtered through celite and separated by extraction, and the organic layer was concentrated. Purification was performed with silica gel column chromatography to obtain Intermediate 392-(1) (about 18.20 g, about 93% yield). The molecular weight of Intermediate 392-(1) was about 513 from FAB MS measurement.

### Synthesis of Intermediate 392-(2)

Intermediate 392-(1) (about 17.82 g, about 34.77 mmol), 3-chlorophenol (about 5.36 g, about 41.72 mmol), CuI (about 7.28 g, about 38.24 mmol), K₂CO₃ (about 19.22 g, about 139.07 mmol), and dipivaloylmethane (about 72.84 g, about 0.4 mmol) were added to DMF (about 728 mL) to heat for about 24 hours while maintaining the temperature at about 100° C. After cooled, the resultant mixture was diluted with CH₂Cl₂, and then added with water, the obtained was filtered through celite and separated by extraction, and the organic layer was concentrated. Purification was performed with silica gel column chromatography to obtain Intermediate 392-(2) (about 13.24 g, about 68% yield). The molecular weight of Intermediate 392-(2) was about 560 from FAB MS measurement.

### Synthesis of Intermediate 392-(3)

Intermediate 392-(1) (about 10.16 g, about 19.82 mmol), phenol (about 2.24 g, about 23.79 mmol), CuI (about 4.15 g, about 21.81 mmol), K₂CO₃ (about 10.96 g, about 79.29 mmol), and dipivaloylmethane (about 41.53 g, about 0.23 mmol) were added to DMF (about 415 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 392-(3) (about 5.32 g, about 51% yield). The molecular weight of Intermediate 392-(3) was about 526 from FAB MS measurement.

### Synthesis of Intermediate 392-(4)

Toluene in a small amount of about 10 mL was added to Intermediate 392-(3) (about 7.13 g, about 13.56 mmol), Intermediate 311-(2) (about 50.68 g, about 108.49 mmol), CuI (about 6.46 g, about 33.9 mmol), and K₂CO₃ (about 28.12 g, about 203.43 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 392-(4) (about 9.03 g, about 77% yield). The molecular weight of Intermediate 392-(4) was about 865 from FAB MS measurement.

### Synthesis of Intermediate 392-(5)

Under an Ar atmosphere, Intermediate 392-(4) (about 8.56 g, about 9.9 mmol) was dissolved in 1,2-dichlorobenzene (ODCB) (about 99 mL), BBr₃ (about 4.96 g, about 19.79 mmol) was added thereto, and the solution was heated and agitated for about 10 hours at about 170° C. The reaction solution was cooled to room temperature, added with N,N-diisopropylethylamine (about 15.32 g, about 118.76 mmol) and water was added, the obtained was filtered through celite and separated by extraction, and the organic layer was concentrated. Purification was performed with silica gel column chromatography to obtain Intermediate 392-(5) (about 3.83 g, about 44% yield). The molecular weight of Intermediate 392-(5) was about 881 from FAB MS measurement.

### Synthesis of Intermediate 392-(6)

Toluene in a small amount of about 10 mL was added to Intermediate 392-(5) (about 3.53 g, about 4.01 mmol), Intermediate 392-(2) (about 17.97 g, about 32.07 mmol), CuI (about 1.91 g, about 10.02 mmol), and K₂CO₃ (about 8.31 g, about 60.14 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 392-(6) (about 1.91 g, about 35% yield). The molecular weight of Intermediate 392-(6) was about 1360 from FAB MS measurement.

### Synthesis of Intermediate 392-(7)

Under an Ar atmosphere, Intermediate 392-(6) (about 1.84 g, about 1.35 mmol) was dissolved in 1,2-dichlorobenzene (ODCB) (about 14 mL), BBr₃ (about 0.68 g, about 2.71 mmol) was added thereto, and the solution was heated and agitated for about 10 hours at about 170° C. The reaction solution was cooled to room temperature, added with N,N-diisopropylethylamine (about 2.09 g, about 16.24 mmol) and water was added, the obtained was filtered through celite and separated by extraction, and the organic layer was concentrated. Purification was performed with silica gel column chromatography to obtain Intermediate 392-(7) (about 0.59 g, about 32% yield). The molecular weight of Intermediate 392-(7) was about 1368 from FAB MS measurement.

### Synthesis of Compound 392

Under an Ar atmosphere, Intermediate 392-(7) (about 0.55 g, about 0.4 mmol), 9H-carbazole (about 0.08 g, about 0.48 mmol), Pd(dba)₂ (about 0.02 g, about 0.04 mmol), RuPhos (about 0.04 g, about 0.08 mmol), and tBuONa (about 0.09 g, about 0.93 mmol) were added to about 2 mL of Xylene, and heated and agitated for about 24 hours at about 130° C. After cooled, the resultant mixture was added with water, and filtered through celite and separated by extraction, and the organic layer was concentrated. Purification was performed with silica gel column chromatography to obtain Compound 392 (about 0.43 g, about 71% yield). The molecular weight of Compound 392 was about 1498 from FAB MS measurement. For evaluation of a light-emitting element to be described later, Compound 392 was sublimed and purified to be used (about 380° C., about 2.4×10⁻³ Pa).

### (6) Synthesis of Compound 403

Compound 403 according to one or more embodiments may be synthesized by Reaction Scheme 6 as an example.

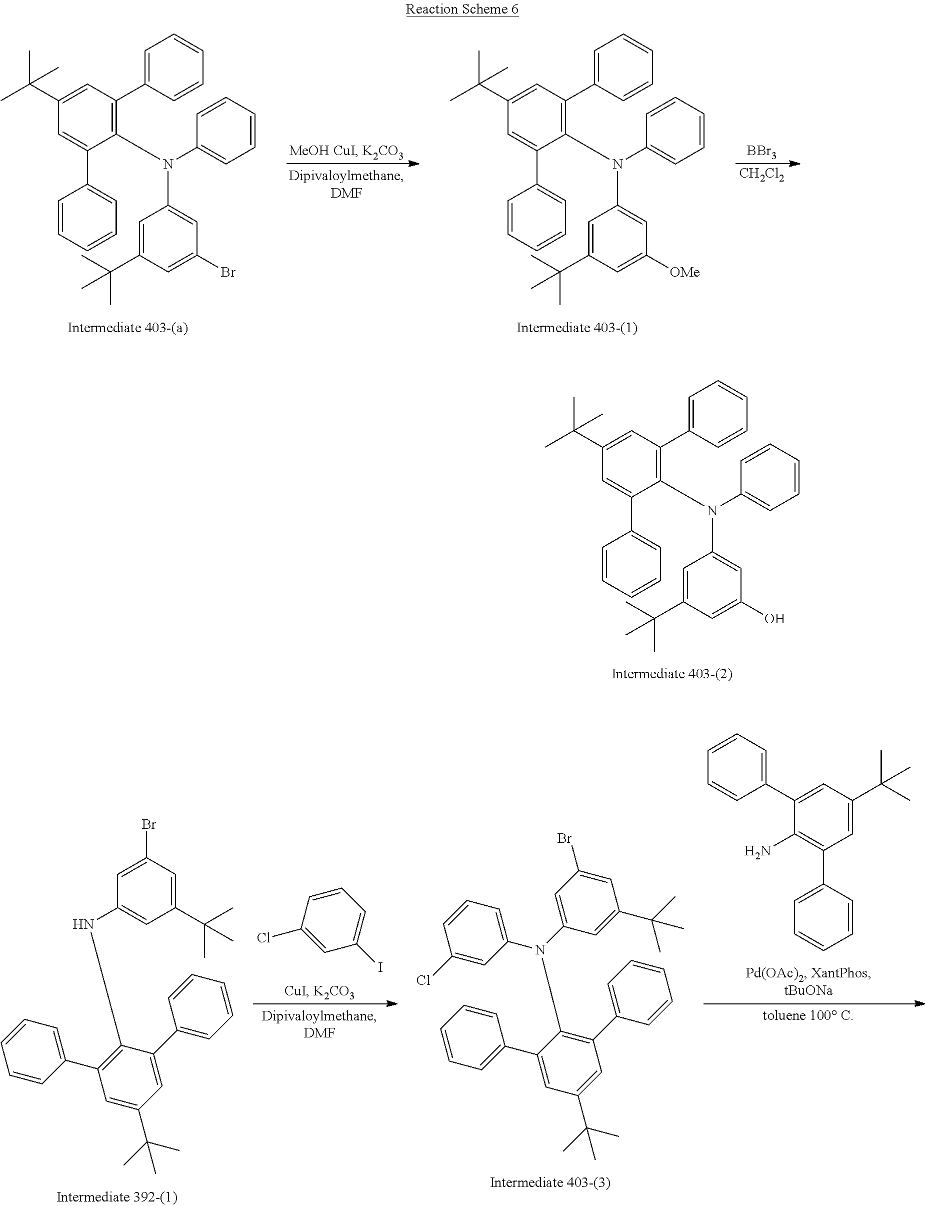

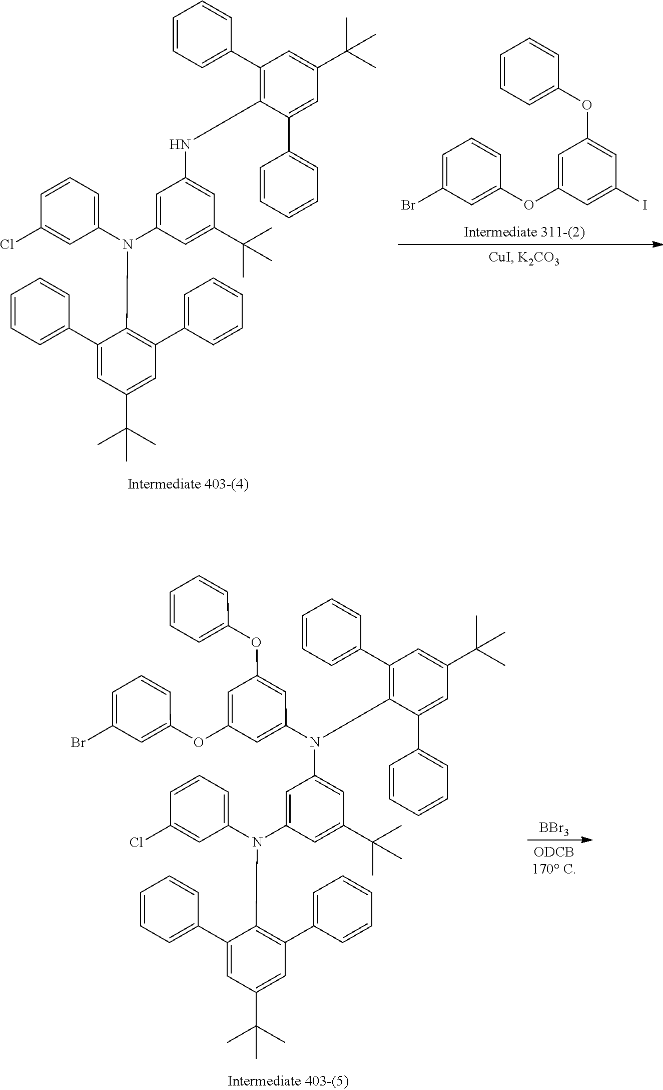 [SMILES: CC(C)(C)c1cc(Nc2c(-c3ccccc3)cc(C(C)(C)C)cc2-c2ccccc2)cc(N(c2cccc(Cl)c2)c2c(-c3ccccc3)cc(C(C)(C)C)cc2-c2ccccc2)c1 ; Brc1cccc(Oc2cc(I)cc(Oc3ccccc3)c2)c1 ; CC(C)(C)c1cc(N(c2cccc(Cl)c2)c2c(-c3ccccc3)cc(C(C)(C)C)cc2-c2ccccc2)cc(N(c2cc(Oc3ccccc3)cc(Oc3cccc(Br)c3)c2)c2c(-c3ccccc3)cc(C(C)(C)C)cc2-c2ccccc2)c1 ; "BBr3"]

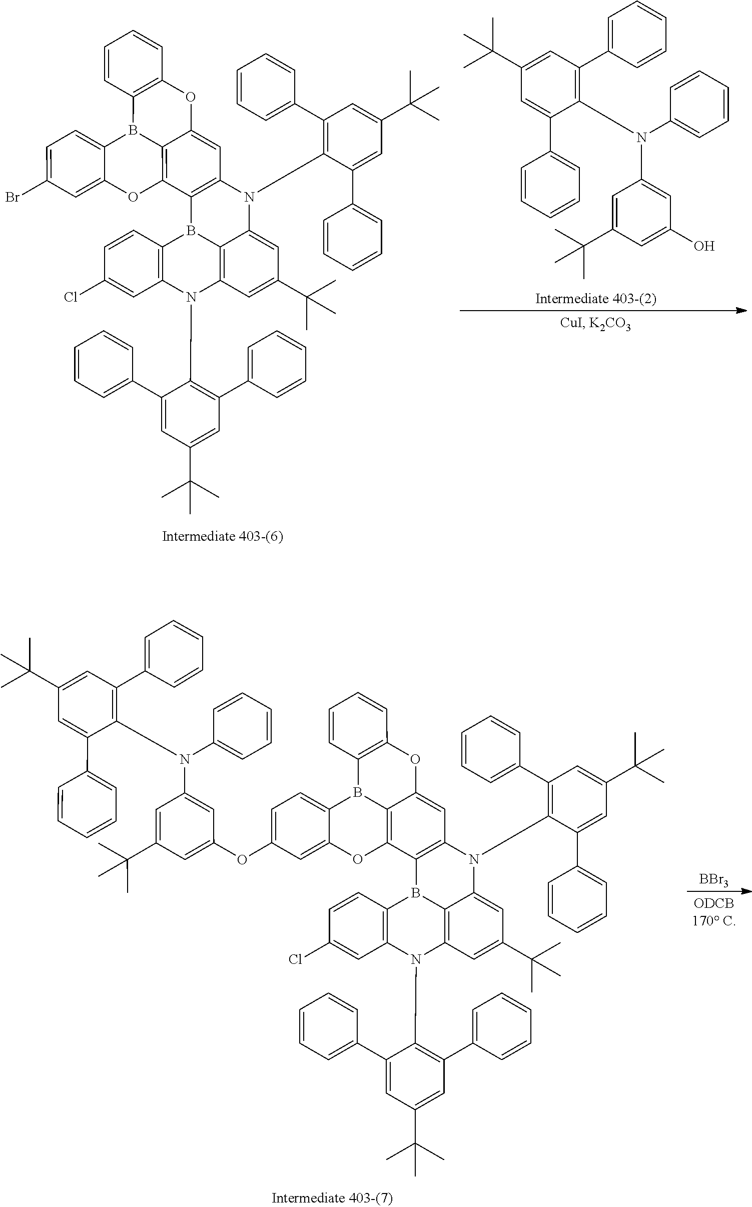

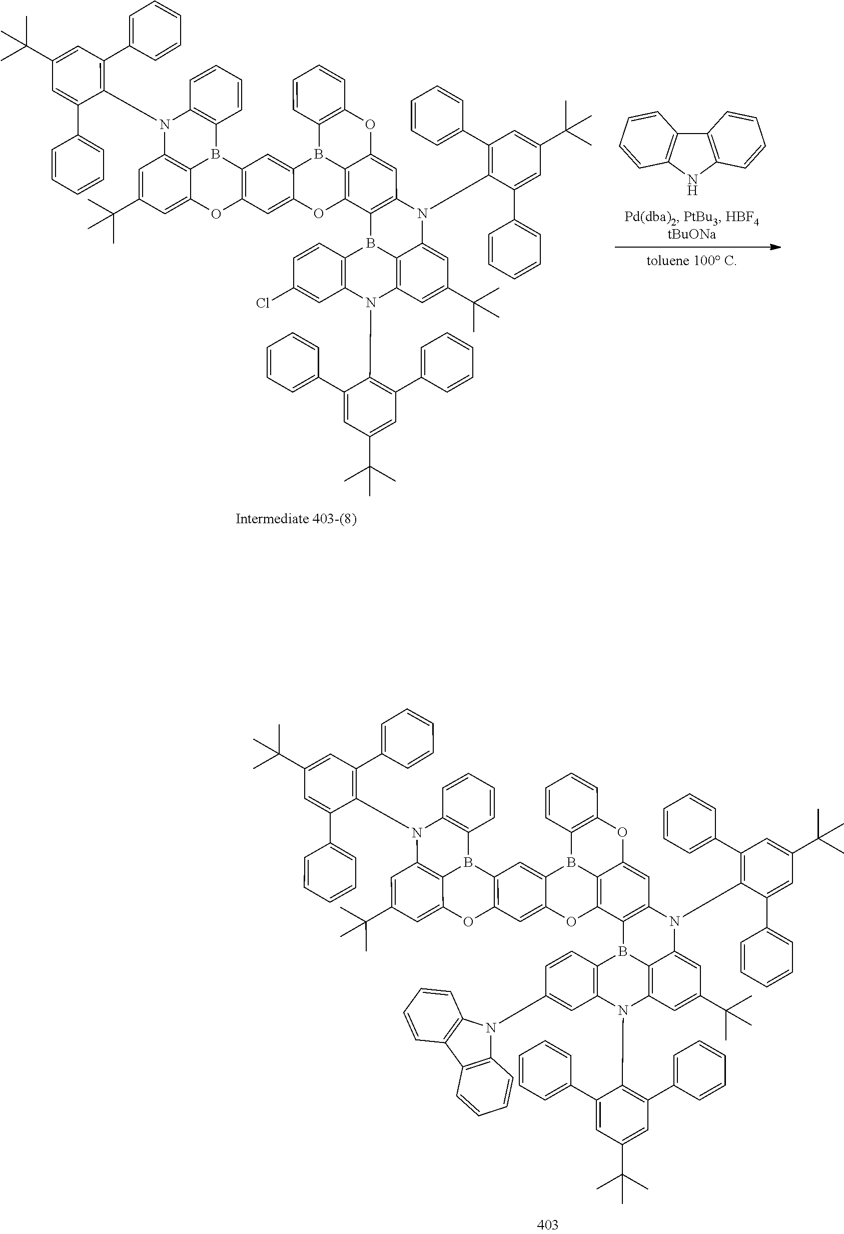

### Synthesis of Intermediate 403-(1)

Intermediate 403-(a) (about 8.54 g, about 14.51 mmol), methanol (about 0.56 g, about 17.41 mmol), CuI (about 3.04 g, about 15.96 mmol), K₂CO₃ (about 8.02 g, about 58.03 mmol), and dipivaloylmethane (about 30.39 g, about 0.16 mmol) were added to DMF (about 303 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 403-(1) (about 4.54 g, about 58% yield). The molecular weight of Intermediate 403-(1) was about 540 from FAB MS measurement.

### Synthesis of Intermediate 403-(2)

Under an Ar atmosphere, Intermediate 403-(1) (about 4.35 g, about 8.06 mmol) was dissolved in CH₂Cl₂ (about 81 mL), BBr₃ (about 5.05 g, about 20.15 mmol) was added thereto, and the solution was agitated for about 24 hours at about 0° C. The reaction solution was added to iced water (about 218 mL), and agitated for about 1 hour and then separated by extraction, and the organic layer was concentrated. Purification was performed with silica gel column chromatography to obtain Intermediate 403-(2) (about 3.05 g, about 72% yield). The molecular weight of Intermediate 403-(2) was about 526 from FAB MS measurement.

### Synthesis of Intermediate 403-(3)

Toluene in a small amount of about 10 mL was added to Intermediate 392-(1) (about 12.13 g, about 23.67 mmol), 1-chloro-3-iodobenzene (about 45.15 g, about 189.33 mmol), CuI (about 11.27 g, about 59.17 mmol), and K₂CO₃ (about 49.06 g, about 355 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 403-(3) (about 10.91 g, about 74% yield). The molecular weight of Intermediate 403-(3) was about 623 from FAB MS measurement.

### Synthesis of Intermediate 403-(4)

Under an Ar atmosphere, Intermediate 403-(3) (about 11.15 g, about 17.89 mmol), 5′-(tert-butyl)-[1,1′:3′,1″-terphenyl]-2′-amine (about 5.66 g, about 18.79 mmol), Pd(OAc)₂ (about 0.12 g, about 0.54 mmol), XantPhos (about 0.62 g, about 1.07 mmol), and tBuONa (about 2.06 g, about 21.47 mmol) were added to about 89 mL of toluene, and heated and agitated for about 8 hours at about 100° C. After cooled, the resultant mixture was added with water, and filtered through celite and separated by extraction, and the organic layer was concentrated. Purification was performed with silica gel column chromatography to obtain Intermediate 403-(4) (about 13.28 g, about 88% yield). The molecular weight of Intermediate 403-(4) was about 844 from FAB MS measurement.

### Synthesis of Intermediate 403-(5)

Toluene in a small amount of about 10 mL was added to Intermediate 403-(4) (about 6.01 g, about 7.12 mmol), Intermediate 311-(2) (about 26.62 g, about 56.99 mmol), CuI (about 3.39 g, about 17.81 mmol), and K₂CO₃ (about 14.77 g, about 106.86 mmol) to heat for about 24 hours while maintaining the temperature at about 215° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 403-(5) (about 5.98 g, about 71% yield). The molecular weight of Intermediate 403-(5) was about 1183 from FAB MS measurement.

### Synthesis of Intermediate 403-(6)

Under an Ar atmosphere, Intermediate 403-(5) (about 5.82 g, about 4.92 mmol) was dissolved in 1,2-dichlorobenzene (ODCB) (about 49 mL), BBr₃ (about 2.47 g, about 9.84 mmol) was added thereto, and the solution was heated and agitated for about 10 hours at about 170° C. The reaction solution was cooled to room temperature, added with N,N-diisopropylethylamine (about 7.62 g, about 59.05 mmol) and water was added, the obtained was filtered through celite and separated by extraction, and the organic layer was concentrated. Purification was performed with silica gel column chromatography to obtain Intermediate 403-(6) (about 1.83 g, about 31% yield). The molecular weight of Intermediate 403-(6) was about 1198 from FAB MS measurement.

### Synthesis of Intermediate 403-(7)

Intermediate 403-(6) (about 1.75 g, about 1.46 mmol), Intermediate 403-(2) (about 0.92 g, about 1.75 mmol), CuI (about 0.31 g, about 1.61 mmol), K₂CO₃ (about 0.81 g, about 5.84 mmol), and dipivaloylmethane (about 3.06 g, about 0.02 mmol) were added to DMF (about 30 mL) to heat for about 24 hours while maintaining the temperature at about 100° C. After cooled, the resultant mixture was diluted with CH₂Cl₂ and then water was added, the obtained was filtered through celite and separated by extraction, and the organic layer was concentrated. Purification was performed with silica gel column chromatography to obtain Intermediate 403-(7) (about 0.86 g, about 36% yield). The molecular weight of Intermediate 403-(7) was about 1643 from FAB MS measurement.

### Synthesis of Intermediate 403-(8)

Under an Ar atmosphere, Intermediate 403-(7) (about 0.79 g, about 0.48 mmol) was dissolved in 1,2-dichlorobenzene (ODCB) (about 5 mL), BBr₃ (about 0.24 g, about 0.96 mmol) was added thereto, and the solution was heated and agitated for about 10 hours at about 170° C. The reaction solution was cooled to room temperature, added with N,N-diisopropylethylamine (about 0.74 g, about 5.77 mmol) and water was added, the obtained was filtered through celite and separated by extraction, and the organic layer was concentrated. Purification was performed with silica gel column chromatography to obtain Intermediate 403-(8) (about 0.36 g, about 45% yield). The molecular weight of Intermediate 403-(8) was about 1651 from FAB MS measurement.

### Synthesis of Compound 403

Under an Ar atmosphere, Intermediate 403-(8) (about 0.35 g, about 0.21 mmol), 9H-carbazole (about 0.04 g, about 0.25 mmol), Pd(dba)₂ (about 0.01 g, about 0.02 mmol), P(tBu)₃·HBF₄ (about 0.01 g, about 0.04 mmol), and tBuONa (about 0.05 g, about 0.49 mmol) were added to about 1 mL of toluene, and heated and agitated for about 8 hours at about 100° C. After cooled, the resultant mixture was added with water, and filtered through celite and separated by extraction, and the organic layer was concentrated. Purification was performed with silica gel column chromatography to obtain Compound 403 (about 0.32 g, about 85% yield). The molecular weight of Compound 403 was about 1782 from FAB MS measurement. For evaluation of a light-emitting element, Compound 403 was sublimed and purified to be used (about 380° C., about 2.7×10⁻³ Pa).

### 2. Manufacturing and Evaluation of Light-Emitting Element

A light-emitting element according to one or more embodiments, which includes the fused polycyclic compound according to one or more embodiments in an emission layer, was manufactured in the following method. The fused polycyclic compound selected from among Compounds 311, 323, 344, 365, 392, and 403 that are example compounds synthesized in the above-described synthesis method was used as an emission layer dopant material to manufacture a respective light-emitting element according to Examples 1 to 6. Comparative Examples 1 to 7 correspond to the light-emitting elements manufactured by respectively using Comparative Example Compounds X1 to X7 as an emission layer dopant material.

### Example Compound

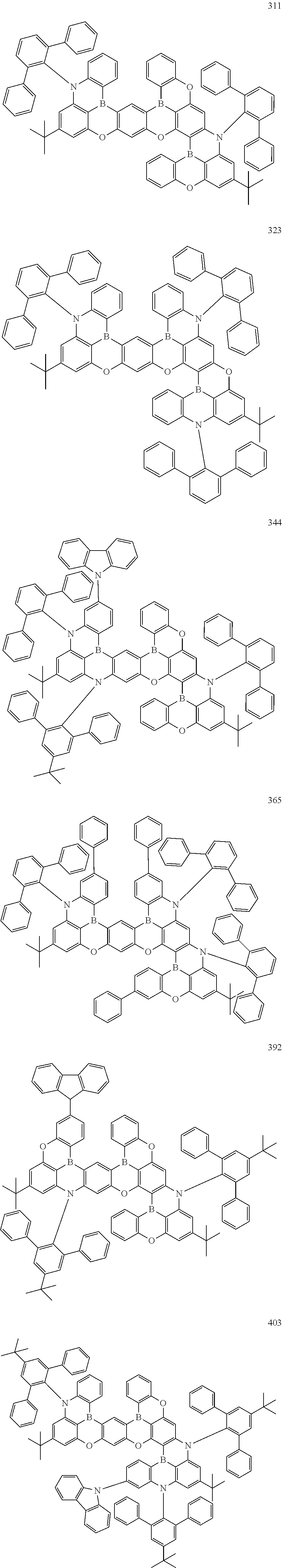

### Comparative Example Compound

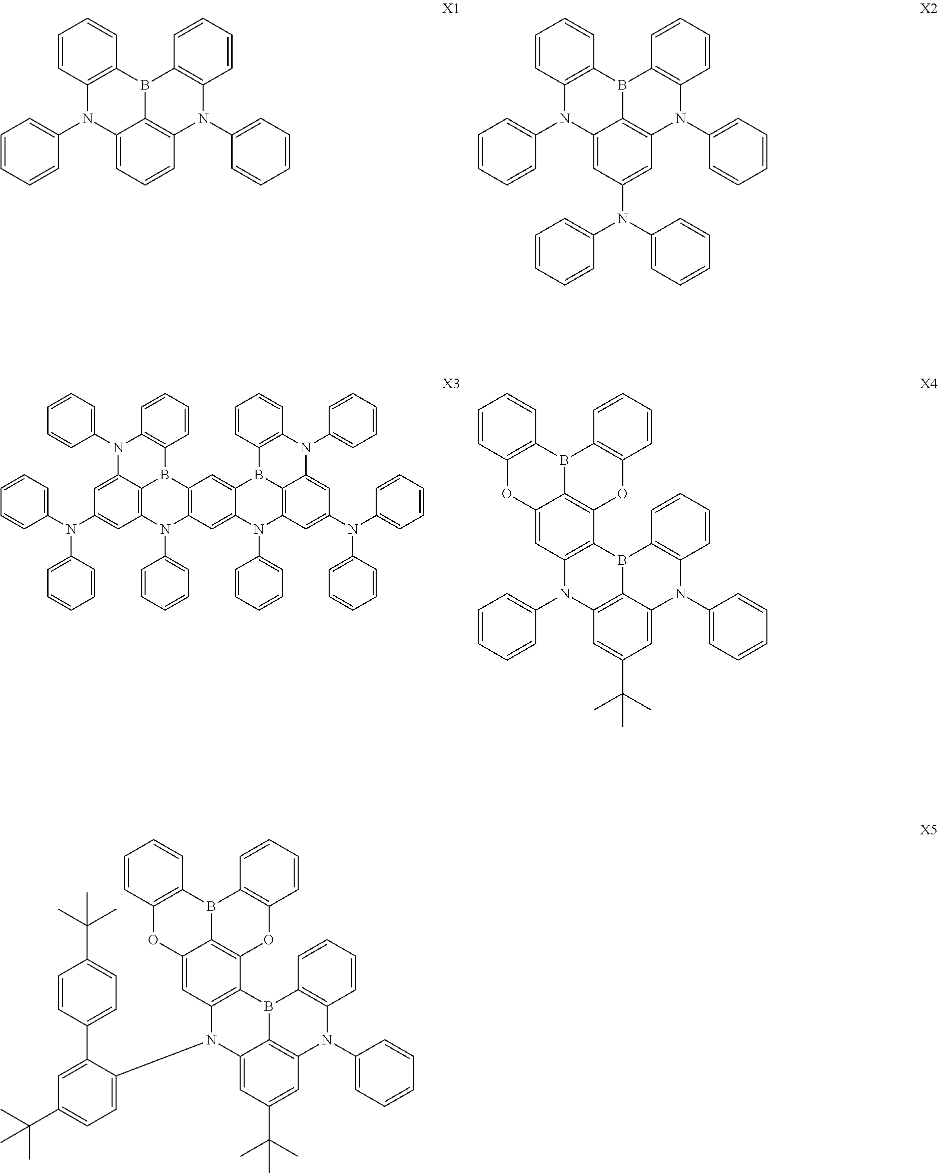 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; CC(C)(C)c1cc2c3c(c1)N(c1ccccc1)c1cc4c5c(c1B3c1ccccc1N2c1ccccc1)Oc1ccccc1B5c1ccccc1O4 ; CC(C)(C)c1ccc(-c2cc(C(C)(C)C)ccc2N2c3cc(C(C)(C)C)cc4c3B(c3ccccc3N4c3ccccc3)c3c2cc2c4c3Oc3ccccc3B4c3ccccc3O2)cc1]

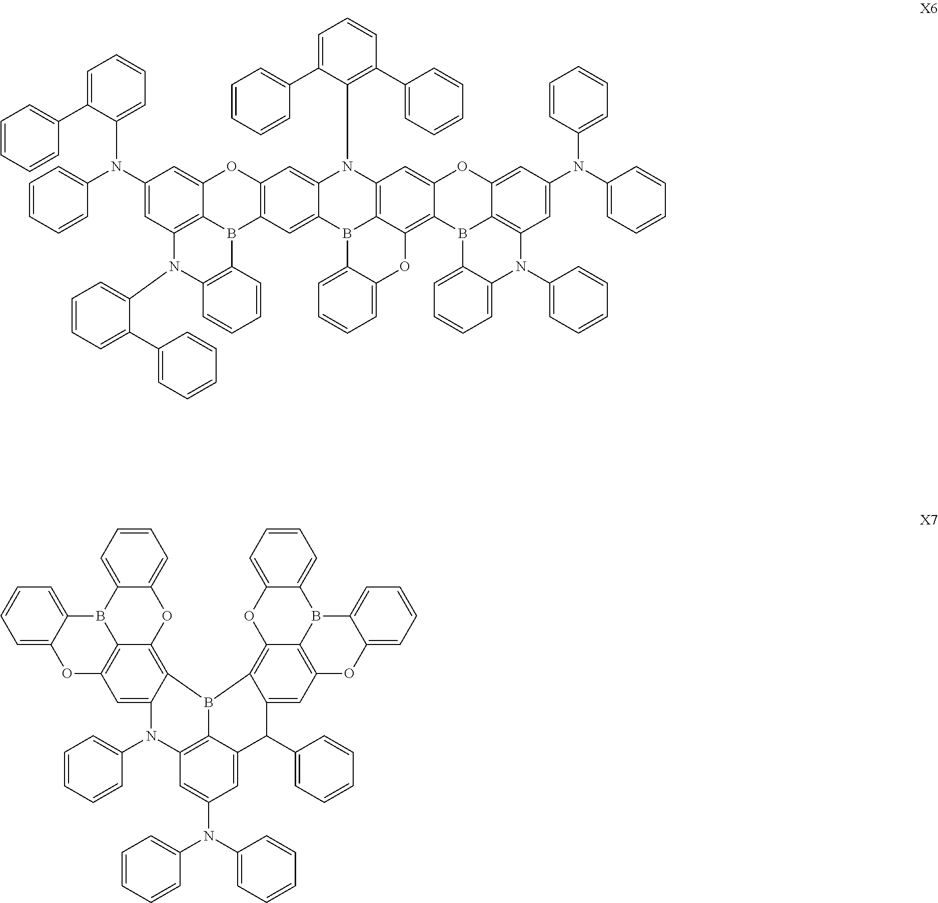 [SMILES: c1ccc(-c2ccccc2N(c2ccccc2)c2cc3c4c(c2)N(c2ccccc2-c2ccccc2)c2ccccc2B4c2cc4c(cc2O3)N(c2c(-c3ccccc3)cccc2-c2ccccc2)c2cc3c(c5c2B4c2ccccc2O5)B2c4ccccc4N(c4ccccc4)c4cc(N(c5ccccc5)c5ccccc5)cc(c42)O3)cc1 ; c1ccc(C2c3cc(N(c4ccccc4)c4ccccc4)cc4c3B(c3c2cc2c5c3Oc3ccccc3B5c3ccccc3O2)c2c(cc3c5c2Oc2ccccc2B5c2ccccc2O3)N4c2ccccc2)cc1]

### Manufacturing Light-Emitting Element

A first electrode was formed including ITO in a thickness of about 150 nm, and a hole injection layer was formed including dipyrazino[2,3-f: 2′,3′-h]quinox aline-2,3,6,7,10,11-hexacarbonitrile (HAT-CN) in a thickness of about 10 nm on the first electrode. On the hole injection layer, a hole transport layer was formed including N,N′-Bis(naphthalen-1-yl)-N,N′-bis(phenyl)-2,2′-dimethyl benzidine (α-NPD) in a thickness of about 80 nm, and an electron-blocking layer was formed including 1,3-bis(N-carbazolyl)benzene (mCP) in a thickness of about 5 nm on the hole transport layer. An emission layer, in which 3,3′-Di(9H-carbazol-9-yl)-1,1′-biphenyl (mCBP) was doped with an example compound or a comparative example compound in an amount of about 1 wt %, was formed on the electron-blocking layer in a thickness of about 20 nm. On the emission layer, an electron transport layer was formed including 2,2′,2″-(1,3,5-benzinetriyl)-tris(1-phenyl-1-H-benzimidazole) (TPBi) in a thickness of about 30 nm, and an electron injection layer was formed including LiF in a thickness of about 0.5 nm on the electron transport layer. On the electron injection layer, a second electrode was formed including Al in a thickness of about 100 nm. Each layer was formed by vacuum deposition under a vacuum atmosphere.

The compounds used for the manufacturing of the light-emitting elements according to the examples and comparative example were presented below. The following materials were suitable materials, and a commercialized product was sublimated and purified to be used in the manufacturing of the elements.

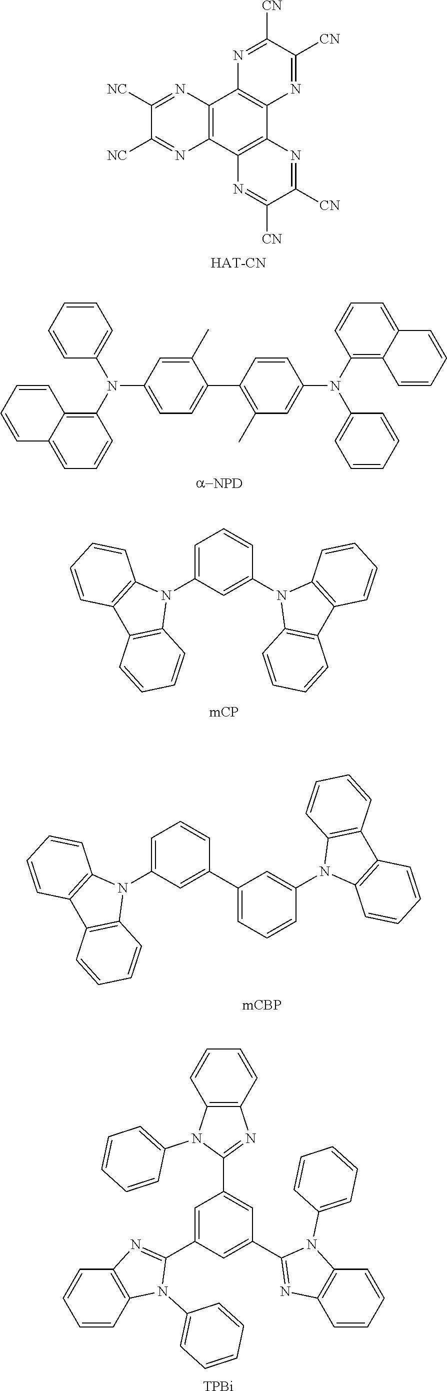

### Evaluation on Characteristics of Light-Emitting Element

Evaluation results on each of the light-emitting elements according to Examples 1 to 6 and Comparative Examples 1 to 7 were listed on Table 1. The maximum emission wavelength (λₘₐₓ) and the relative lifespan (LT50) of each of the manufactured light-emitting elements were compared, and the results were listed on Table 1.

From the results of evaluating the characteristics of each of the examples and comparative examples listed on Table 1, the maximum emission wavelength (λₘₐₓ) and the relative lifespan (LT50) were measured using an external quantum efficiency measurement device C9920-12 of Hamamatsu Photonics. The maximum emission wavelength (λₘₐₓ) indicates a wavelength at which the maximum value (i.e., maximum emission intensity) was observed in the emission spectrum. In addition, the relative lifespan (LT50) was a value obtained by evaluating the luminance half-life time at about 800 cd/m² of an initial luminance. The relative lifespan was expressed relatively based on the results of Comparative Example 3.

TABLE 1

| Manufacturing | | λₘₐₓ | LT50 |
|---|---|---|---|
| Example of Element | Dopant | (nm) | (relative lifespan) |
| Example 1 | Compound 311 | 457 | 3.5 |
| Example 2 | Compound 323 | 458 | 4.1 |
| Example 3 | Compound 344 | 458 | 3.8 |
| Example 4 | Compound 365 | 457 | 4.7 |
| Example 5 | Compound 392 | 456 | 3.1 |
| Example 6 | Compound 403 | 460 | 4.5 |
| Comparative | Comparative Example | 457 | 0.3 |
| Example 1 | Compound X1 | | |
| Comparative | Comparative Example | 446 | 0.2 |
| Example 2 | Compound X2 | | |
| Comparative | Comparative Example | 467 | 1.0 |
| Example 3 | Compound X3 | | |
| Comparative | Comparative Example | 455 | 0.8 |
| Example 4 | Compound X4 | | |
| Comparative | Comparative Example | 457 | 1.2 |
| Example 5 | Compound X5 | | |
| Comparative | Comparative Example | 468 | 1.5 |
| Example 6 | Compound X6 | | |
| Comparative | Comparative Example | 450 | 1.1 |
| Example 7 | Compound X7 | | |

Referring to the results on Table 1, it can be seen that the light-emitting elements according to the examples, in which the fused polycyclic compound according to one or more embodiments of the present disclosure was used as a light-emitting material, had improved relative lifespans by about 3.1 to about 4.7 times, compared to the light-emitting element according to the Comparative Example 3.

The compounds according to the examples have a core structure in which first to third fused cyclic moieties are connected (e.g., fused) to include three boron atoms. In each of the compounds according to the examples, its LUMO may be concentrated with a first boron atom and a second boron atom to be distributed at a portion where the first fused cyclic moiety and the second fused cyclic moiety are connected (e.g., fused), and its HOMO may be concentrated with a third boron atom to be distributed at a portion of the third fused cyclic moiety.

By including the fused polycyclic compound according to one or more embodiments as a light-emitting dopant of the thermally activated delayed fluorescence (TADF) light-emitting element, the light-emitting element according to one or more embodiments may achieve improved lifespan characteristics in a blue-color light wavelength range.

Comparing Examples 1 to 6 to Comparative Examples 1 to 7, long lifespan was achieved in each of the elements according to the examples. Through the characteristics that any one of the first fused cycle and the second fused cycle introduced in a molecular structure has a property of electron donor, and the other one has a property of electron acceptor, the example compounds according to Examples 1 to 6 may each have a structure of an incomplete charge transfer (CT) type (kind) formed in the molecule and have excellent or suitable multi-resonance characteristics, so that efficiency decrease may be prevented or reduced and long lifespan characteristics may be achieved.

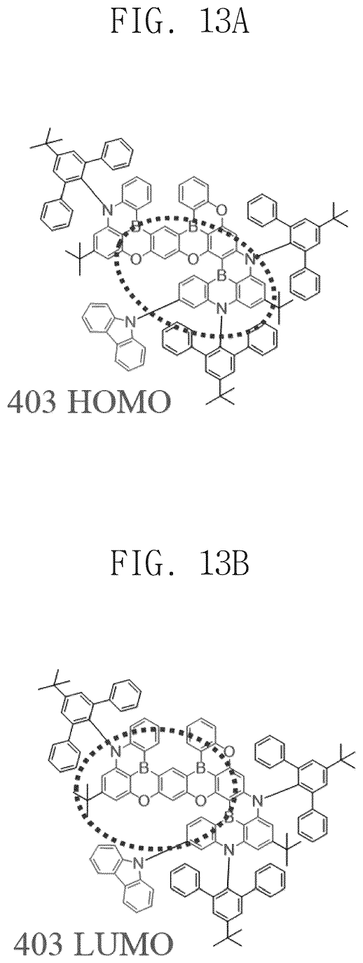

FIG. 13A is a drawing showing a HOMO distribution of Example Compound 403, and FIG. 13B is a drawing showing a LUMO distribution of Example Compound 403. In FIG. 13A, a dotted circle represents a schematic HOMO distribution, and in FIG. 13B, a dotted circle represents a schematic LUMO distribution. Referring to FIG. 13A and FIG. 13B, it can be seen that, in Example Compound 403, the HOMO distribution was observed at a portion of the third fused cyclic moiety having the third boron atom, and the LUMO distribution was observed at portions of the first and second fused cyclic moieties having the first and second boron atoms. From this, it can be seen that the charge transfer (CT)-type (kind) structure was formed in the molecule to form excellent or suitable multi-resonance structure.

In the case of Comparative Example 1 to Comparative Example 3, compared to the examples, the results showed reduced lifespan. Because Comparative Examples 1 to 3, according to Comparative Example Compounds X1 to X3, compared to the example compounds, each include a light-emitting material not having a structure in which the first to third fused cyclic moieties are connected (e.g., fused) to include three boron atoms, differently from the structures of the examples, luminescence characteristics may deteriorate. Accordingly, compared to the light-emitting elements according to the examples, the light-emitting elements according to Comparative Examples 1 to 3 may have reduced element lifespan.

In the case of Comparative Example Compounds X4 and X5, according to Comparative Examples 4 and 5, each having a structure in which two boron atoms were included and two fused cyclic structures were connected, the absorbance does not significantly increase, and thus luminescence characteristics were not good or suitable, and element lifespan decreased significantly, compared to those of the examples.

Comparative Example Compound X6 according to Comparative Example 6 had a core structure including three boron atoms, but the core structure formed by three fused cycles being connected was different from those of the example compounds, and thus exhibited decreased element lifespan, compared to the light-emitting elements according to the examples.

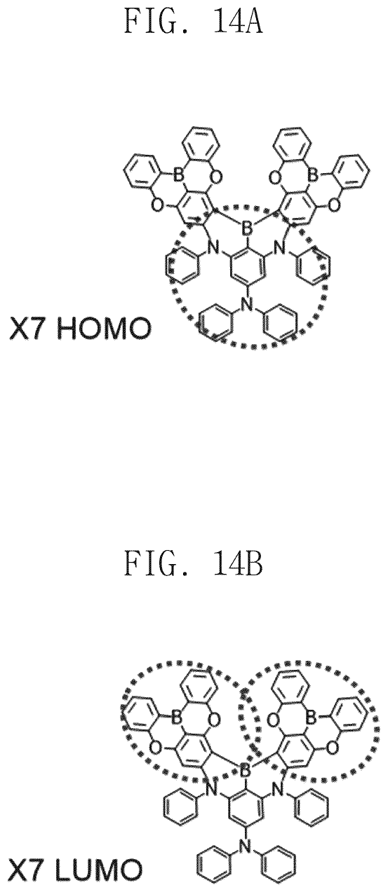

In addition, FIG. 14A is a drawing showing a HOMO distribution of Comparative Example Compound X7, and FIG. 14B is a drawing showing a LUMO distribution of Comparative Example Compound X7. In FIG. 14A, a dotted circle represents a schematic HOMO distribution, and in FIG. 14B, a dotted circle represents a schematic LUMO distribution. Referring to FIGS. 14A and 14B, it can be seen that, in Comparative Example Compound X7, the HOMO distribution was observed at a portion of the fused cycle including one boron atom and two nitrogen atoms, and the LUMO distribution was observed at a portion of each of the fused cycles including one boron atom and two oxygen atoms. Because of the non-integrated LUMO aspect, where the LUMO was distributed as if it was independently concentrated in each of the two fused cycles containing boron and oxygens, Comparative Example Compound X7 may lack LUMO conjugation, thereby deteriorating the luminescence characteristics of the compound. Accordingly, compared to the light-emitting element according to the example, the light-emitting elements according to Comparative Example 7 may have reduced element lifespan.

The light-emitting element according to one or more embodiments may exhibit element characteristics of high efficiency and improved long lifespan.

The fused polycyclic compound according to one or more embodiments may be included in an emission layer of the light-emitting element, thereby contributing to high efficiency and long lifespan of the light-emitting element.

The electronic apparatus according to one or more embodiments may have excellent or suitable display quality.

For example, as demonstrated by the foregoing description and evaluation results, the present disclosure provides fused polycyclic compounds and light-emitting elements that exhibit superior performance characteristics, including enhanced luminescence efficiency, reduced efficiency roll-off, and significantly extended operational lifetime, particularly in the blue emission region. These advantages are achieved through the unique molecular design of the disclosed compounds, which enables enhanced HOMO-LUMO distribution, improved charge balance, and effective exciton management within the emission layer. Accordingly, the disclosed compounds, light-emitting elements, and electronic apparatuses incorporating them offer a robust solution to the technical challenges faced in the development of high-performance organic electroluminescent devices, thereby enabling their application in a wide range of advanced display technologies.

In the present disclosure, expressions such as “at least one of,” “one of,” and “selected from,” when preceding a list of elements, modify the entire list of elements and do not modify the individual elements of the list. For example, “at least one of a, b, or c,” “at least one selected from among a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light-emitting element/light emitting element, the display apparatus/device, the electronic apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In the above, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the disclosure set forth in the appended claims.

Therefore, the technical scope of the disclosure is not to be limited to the content stated in the detailed description of the specification, but should be determined by the appended claims and equivalents thereof.

What is claimed is:

1. An electronic apparatus, comprising:
a display panel comprising a plurality of light-emitting elements,
wherein at least one selected from among the plurality of light-emitting elements comprises
a first electrode,
a second electrode on the first electrode, and
an emission layer between the first electrode and the second electrode and comprising a first compound represented by Formula 1: 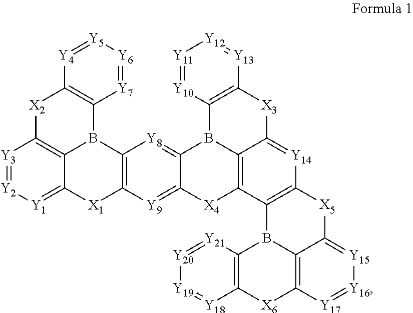
and
wherein, in Formula 1,
X₁ to X₆ are each independently O, S, or NRₓ,
Y₁ to Y₂₁ are each independently N or CR_{y},
Rₓ is a substituted or unsubstituted aryl group having 6 to 30 ring-forming carbon atoms or a substituted or unsubstituted heteroaryl group having 2 to 30 ring-forming carbon atoms, and
R_{y} is hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

2. The electronic apparatus of claim 1,
wherein the electronic apparatus comprises a display device comprising the display panel and configured to display an image,
the display device comprises a first emission region, a second emission region, and a third emission region configured to emit light in different wavelength ranges and separated from one another on a plane, and
the first emission region, the second emission region, and the third emission region are regions in which light generated from the plurality of light-emitting elements is configured to be emitted, respectively.

3. The electronic apparatus of claim 2, wherein the plurality of light-emitting elements comprises a first light-emitting element corresponding to the first emission region, a second light-emitting element corresponding to the second emission region, and a third light-emitting element corresponding to the third emission region.

4. The electronic apparatus of claim 2, wherein the display device comprises a plurality of display surfaces each having a different main display direction of an image.

5. The electronic apparatus of claim 1,
wherein the electronic apparatus comprises a plurality of display devices, each independently configured to display an image, and
at least one selected from among the plurality of the display devices comprises the display panel.

6. The electronic apparatus of claim 1,
wherein
the electronic apparatus is at least one of a television, a monitor, an outdoor billboard, a personal computer, a laptop computer, a personal digital assistant, a vehicular device, a game console, a smartphone, a tablet computer, a smart watch, or a camera.

7. A light-emitting element, comprising:
a first electrode;
a second electrode on the first electrode; and
an emission layer between the first electrode and the second electrode and comprising a first compound represented by Formula 1: 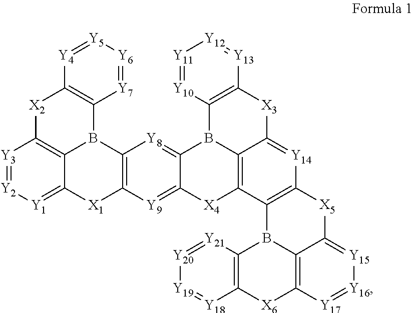
wherein, in Formula 1,
X₁ to X₆ are each independently O, S, or NRₓ,
Y₁ to Y₂₁ are each independently N or CR_{y},
Rₓ is a substituted or unsubstituted aryl group having 6 to 30 ring-forming carbon atoms or a substituted or unsubstituted heteroaryl group having 2 to 30 ring-forming carbon atoms, and
R_{y} is hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

8. The light-emitting element of claim 7, wherein the first compound is represented by Formula 2: 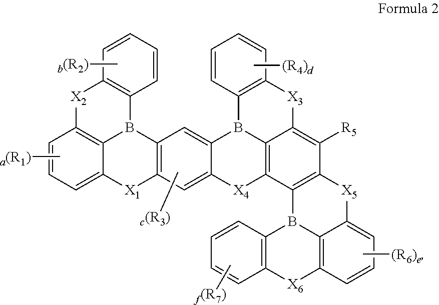
in Formula 2,
R₁ to R₇ being each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a and e being each independently an integer of 0 or greater and 3 or less,
b, d, and f being each independently an integer of 0 or greater and 4 or less,
c being an integer of 0 or greater and 2 or less, and
X₁ to X₆ being the same as defined in Formula 1.

9. The light-emitting element of claim 7, wherein the first compound is represented by Formula 3: 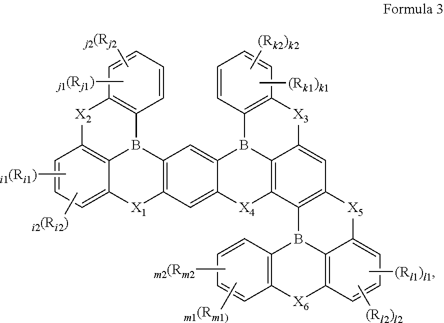
in Formula 3,
Rᵢ₁, Rⱼ₁, Rₖ₁, Rₗ₁, and Rₘ₁ are each independently hydrogen or deuterium,
Rᵢ₂, Rⱼ₂, Rₖ₂, Rₗ₂, and Rₘ₂ being each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
i1 and l1 being each independently an integer of 0 or greater and 3 or less,
j1, k1, and m1 being each independently an integer of 0 or greater and 4 or less,
i2, j2, k2, l2, and m2 being each independently 0 or 1, and
X₁ to X₆ being the same as defined in Formula 1.

10. The light-emitting element of claim 9, wherein Rᵢ₂, Rⱼ₂, Rₖ₂, Rₗ₂, and Rₘ₂ are each independently a substituted or unsubstituted methyl group, a substituted or unsubstituted t-butyl group, or a substituted or unsubstituted phenyl group, or a substituted or unsubstituted carbazole group.

11. The light-emitting element of claim 7, wherein the first compound is represented by Formula 4: 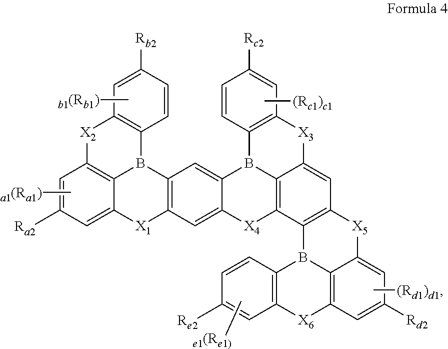
in Formula 4,
Rₐ₁, Rₐ₂, R_{b1}, R_{b2}, R_{c1}, R_{c2}, R_{d1}, R_{d2}, Rₑ₁, and Rₑ₂ being each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a1 and d1 being each independently an integer of 0 or greater and 2 or less,
b1, c1, and e1 being each independently an integer of 0 or greater and 3 or less, and
X₁ to X₆ being the same as defined in Formula 1.

12. The light-emitting element of claim 10, wherein at least one of Rₐ₂, R_{b2}, R_{c2}, R_{d2}, or Rₑ₂ is a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

13. The light-emitting element of claim 7, wherein at least one selected from among X₁ to X₆ is O, and the rest are NRₓ.

14. The light-emitting element of claim 7, wherein the emission layer further comprises at least one of a second compound represented by Formula HT-1, a third compound represented by Formula ET-1, or a fourth compound represented by Formula D-1: 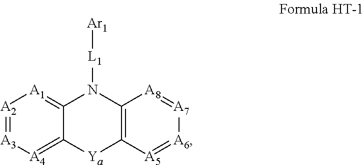
wherein, in Formula HT-1,
A₁ to A₈ are each independently N or CR₅₁,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, CR₅₂R₅₃, or SiR₅₄R₅₅,
Ar₁ is a substituted or unsubstituted aryl group having 6 to 30 ring-forming carbon atoms or a substituted or unsubstituted heteroaryl group having 2 to 30 ring-forming carbon atoms,
R₅₁ to R₅₅ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring; 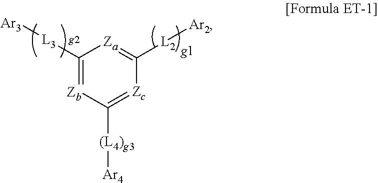
wherein, in Formula ET-1,
at least one selected from among Zₐ to Z_{c} is N, and the rest are CR₅₆,
R₅₆ is hydrogen, deuterium, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
g1 to g3 are each independently an integer of 0 or greater and 10 or less,
Ar₂ to Ar₄ are each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; and 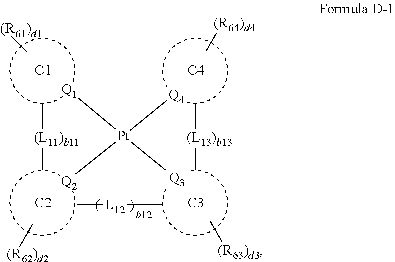
wherein, in Formula D-1
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, *—O—, *—S—*, 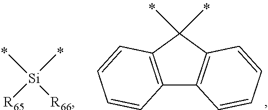
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
d1 to d4 are each independently an integer of 0 or greater and 4 or less.

15. The light-emitting element of claim 7, wherein the first compound is at least one selected from among compounds in Compound Group 1: 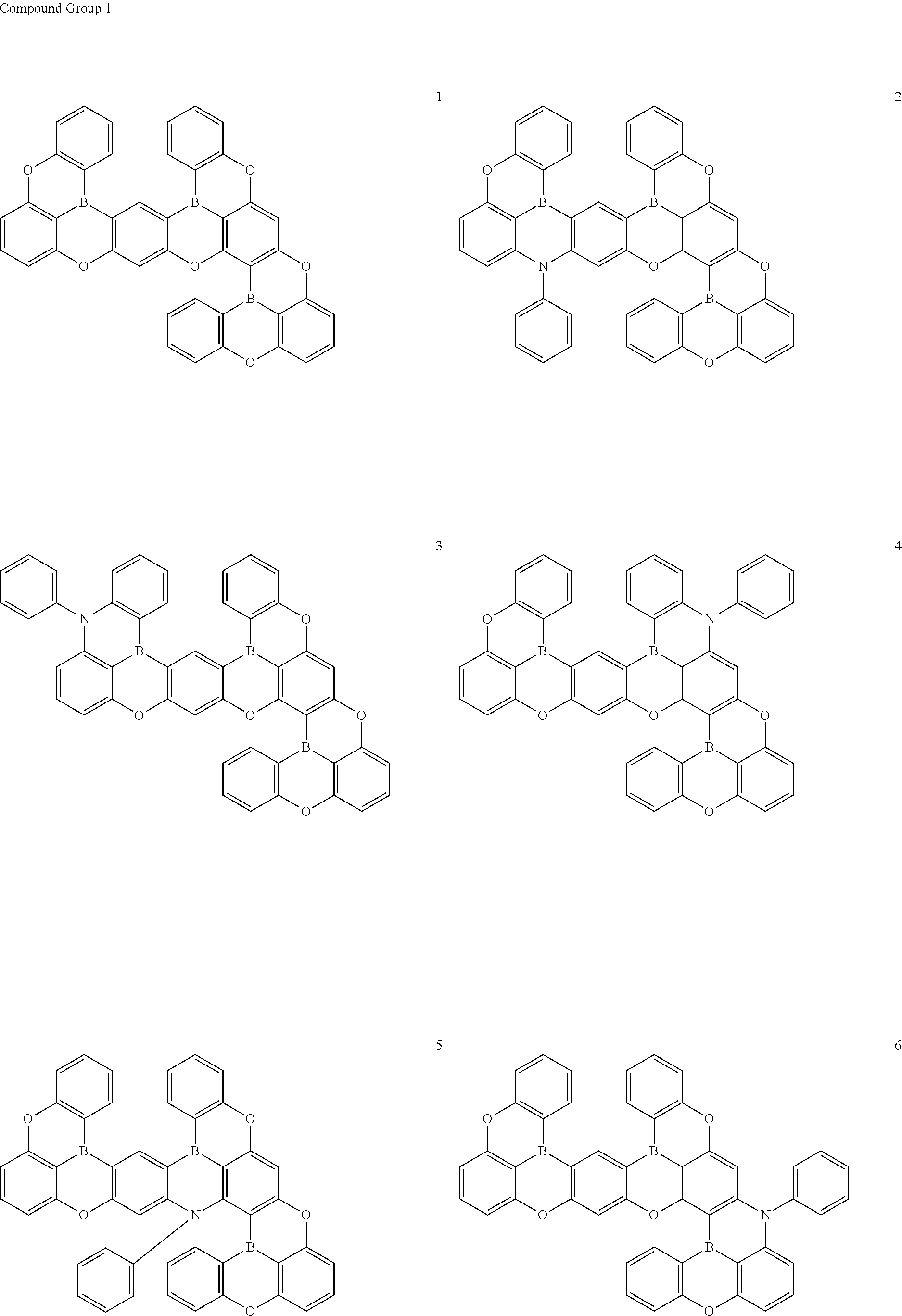 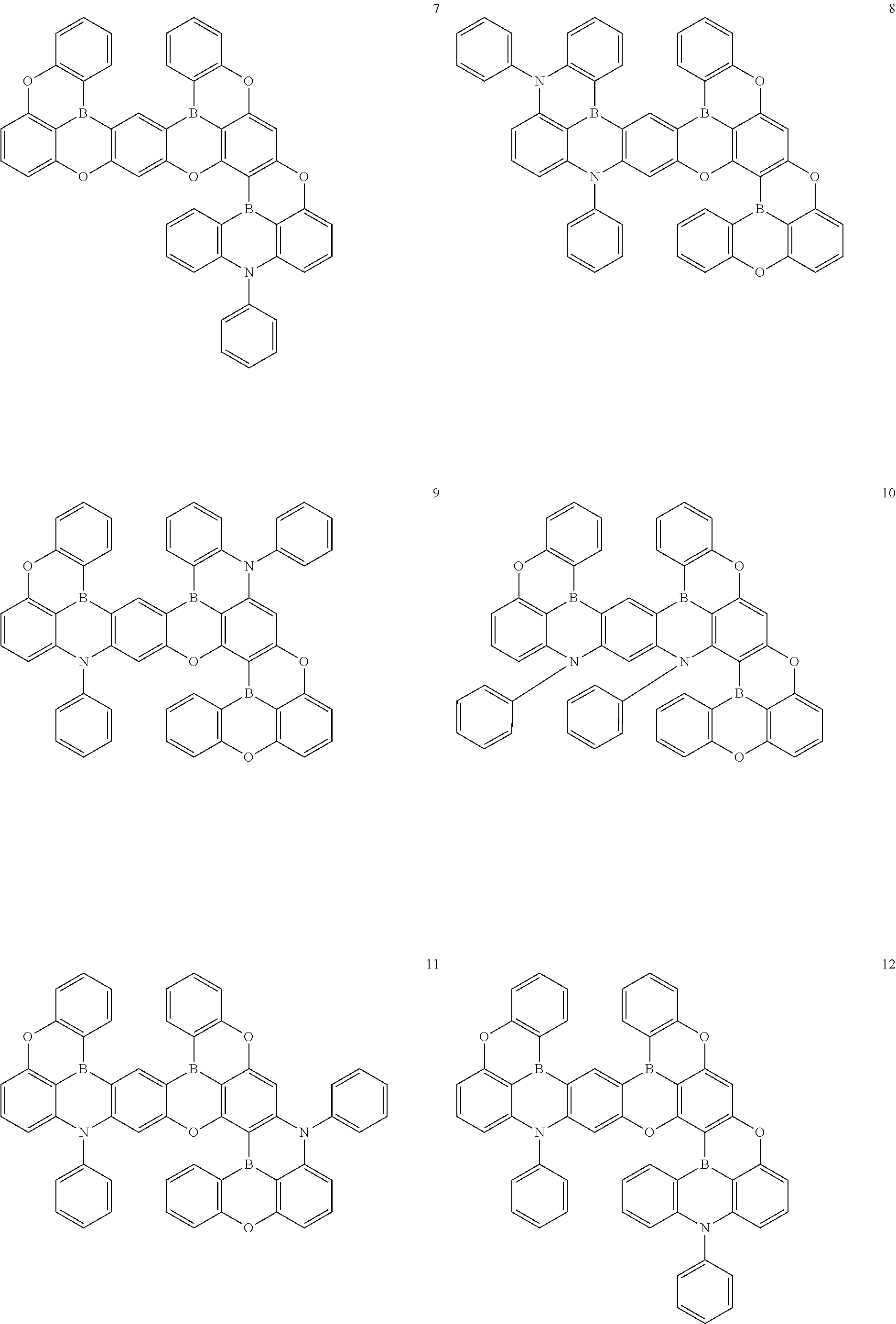 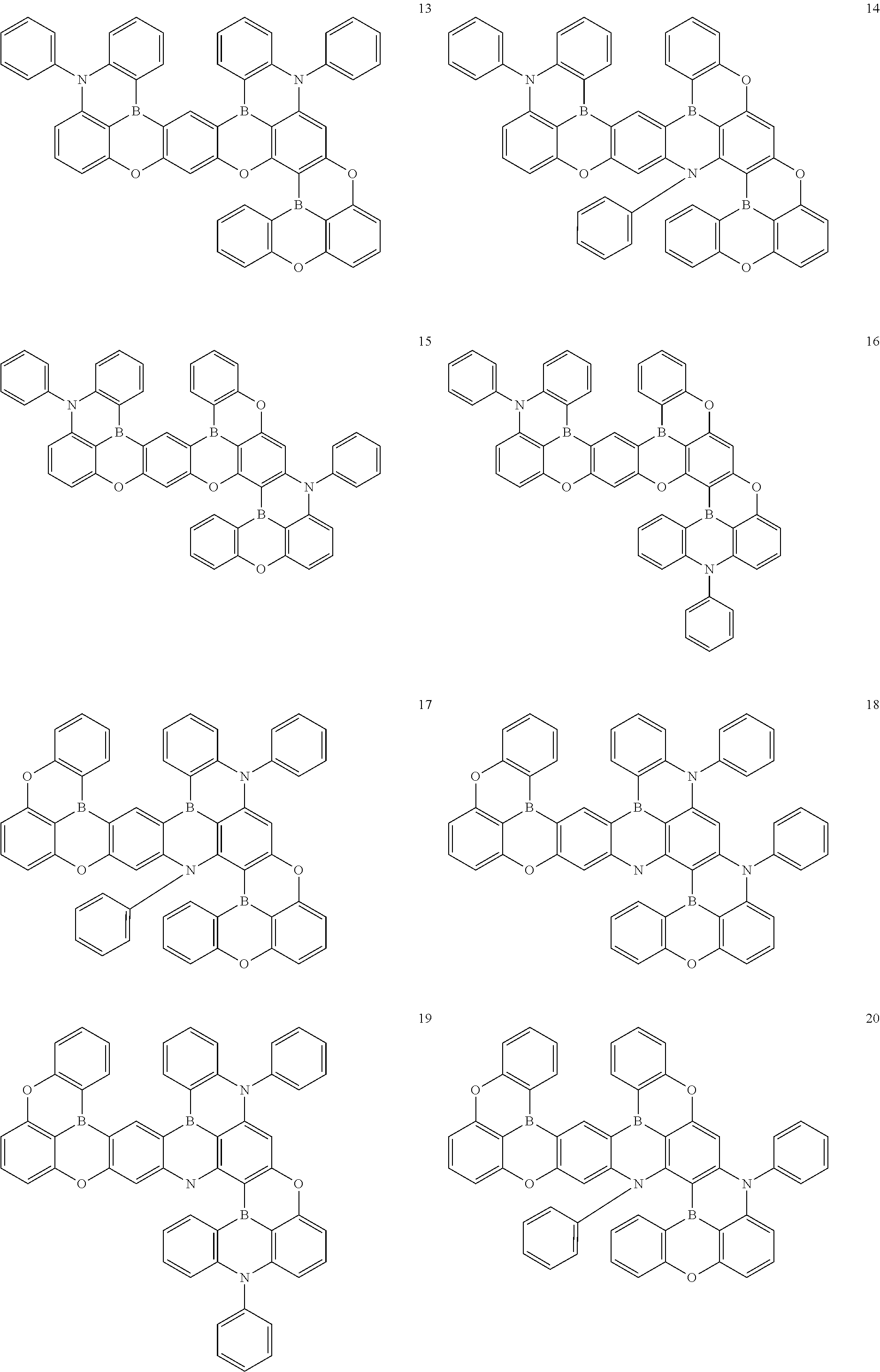 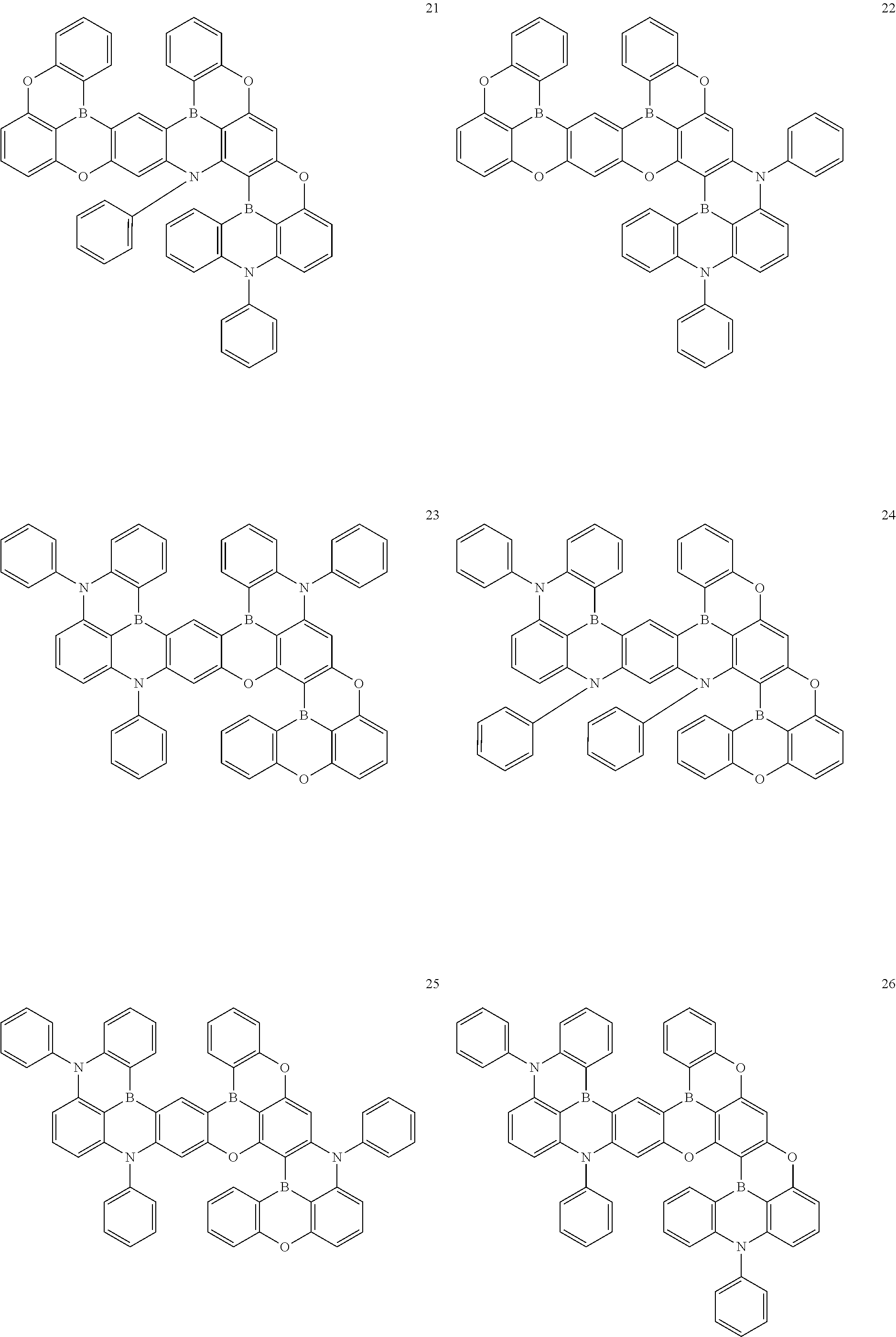 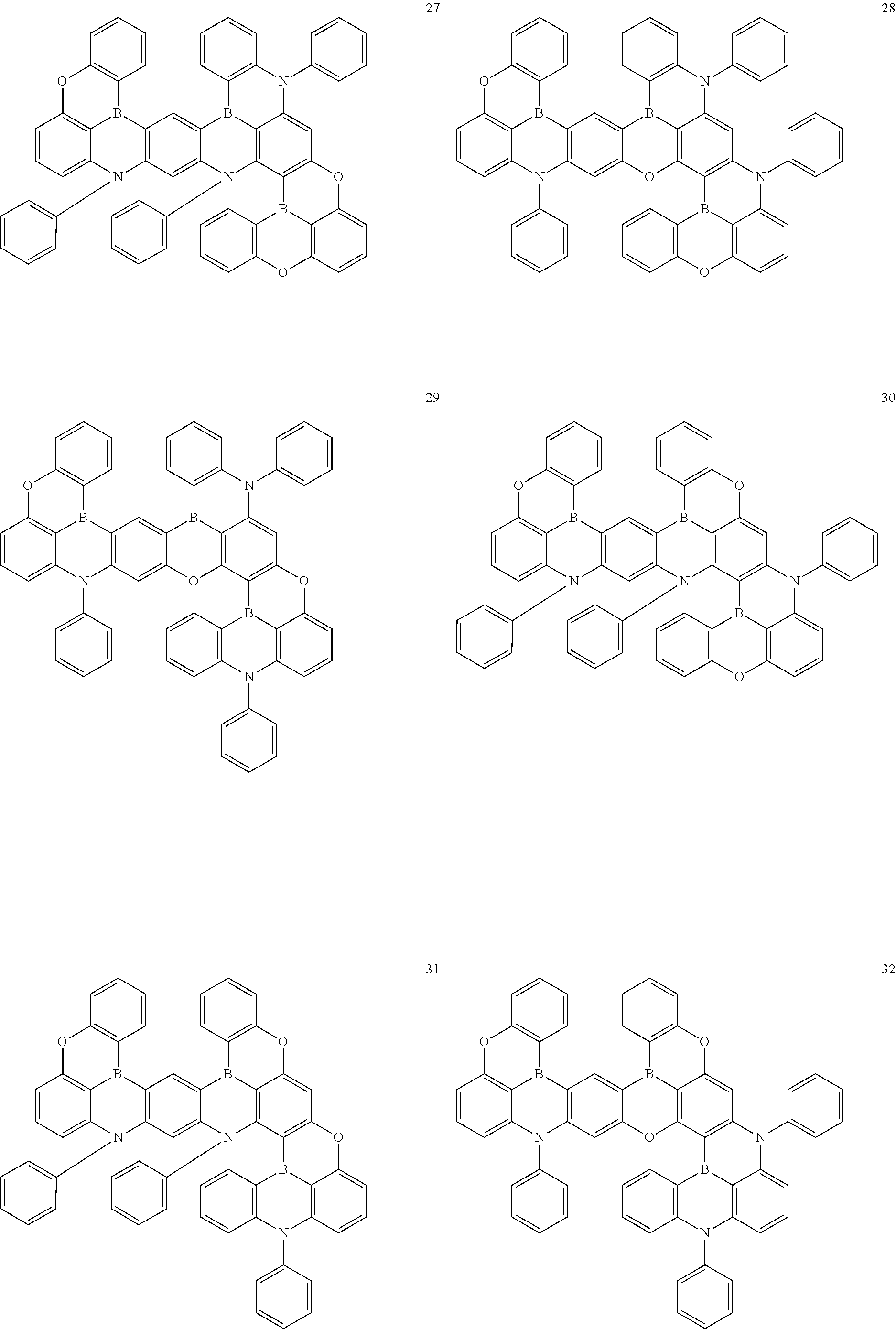 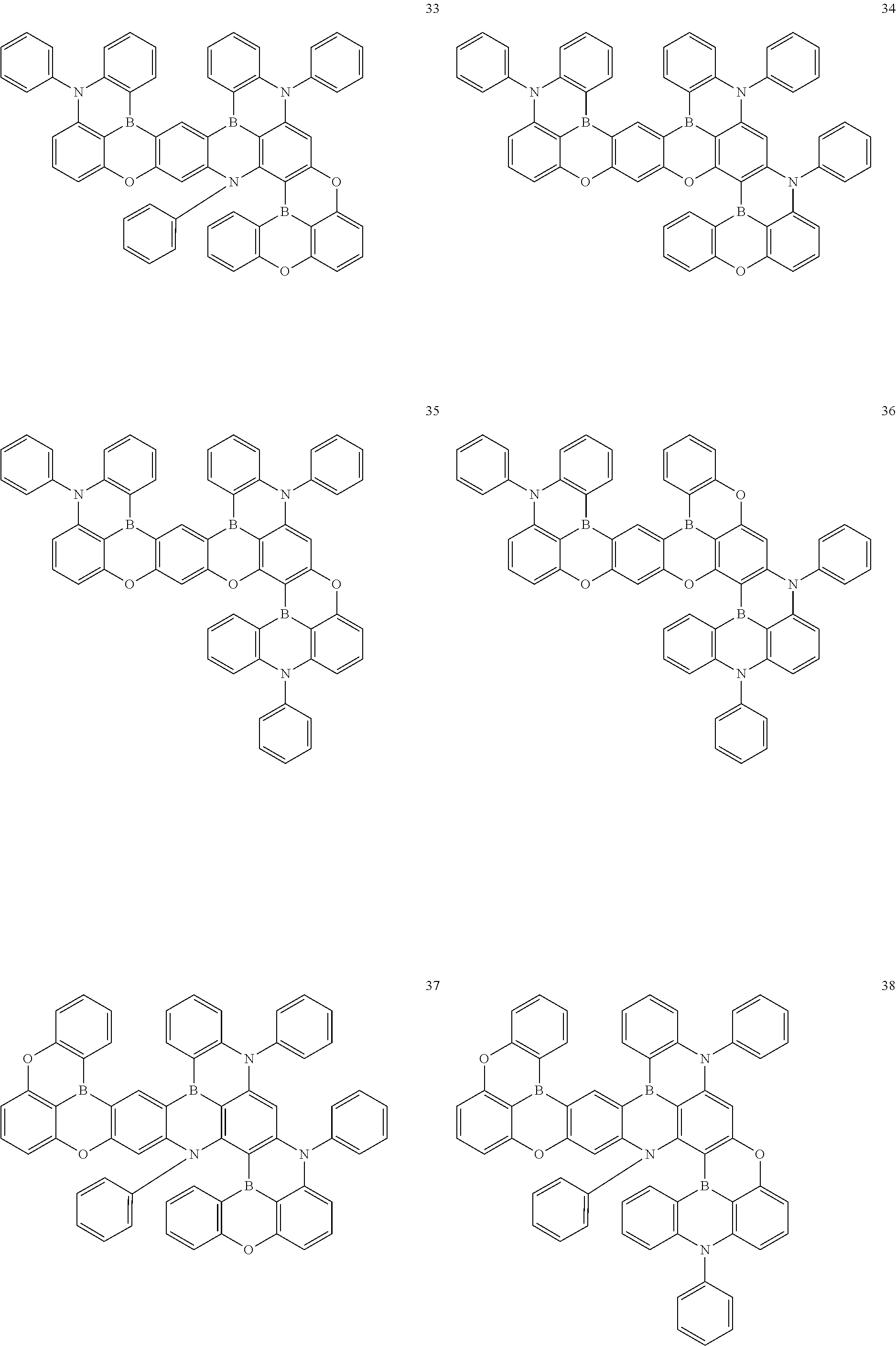 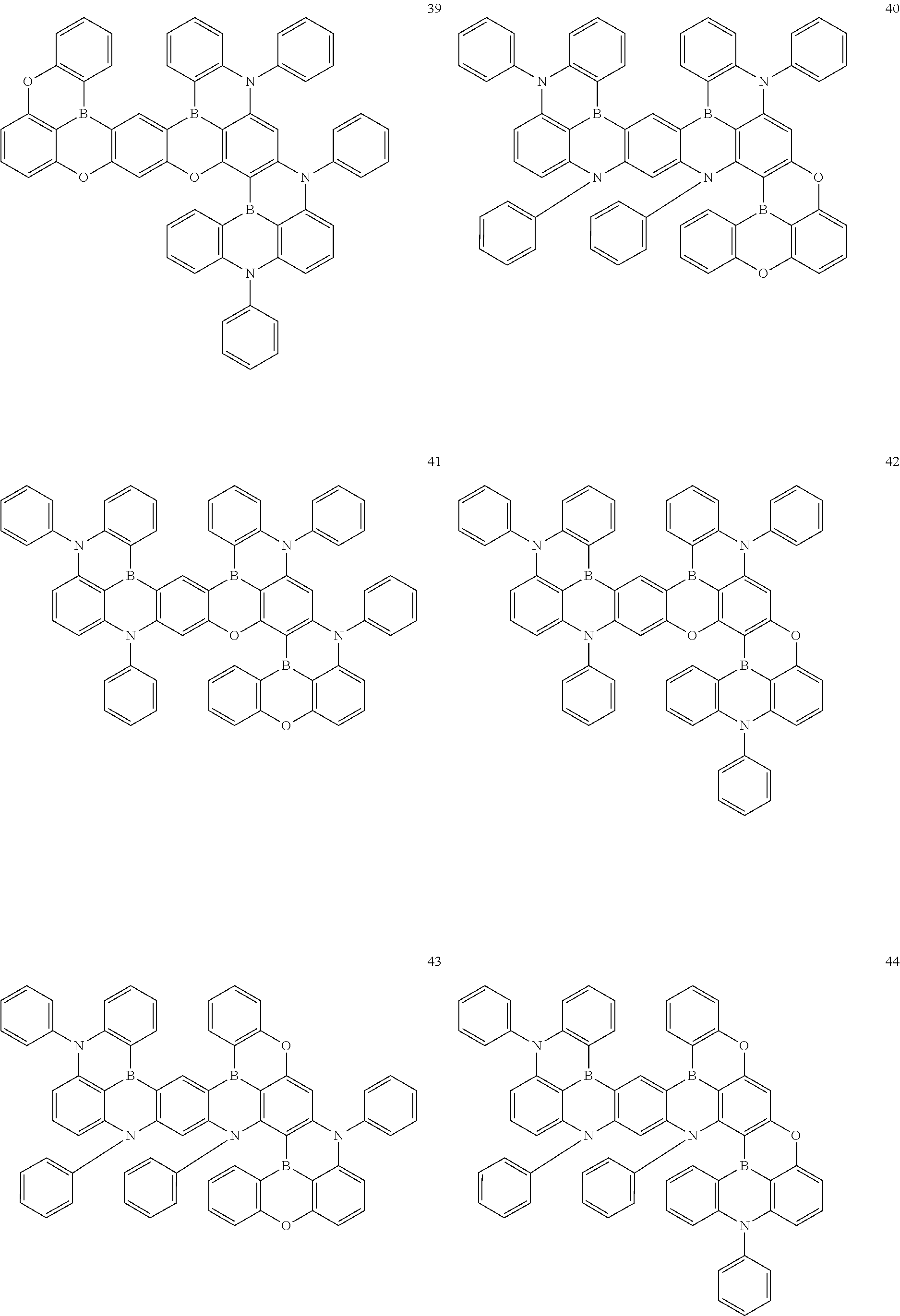 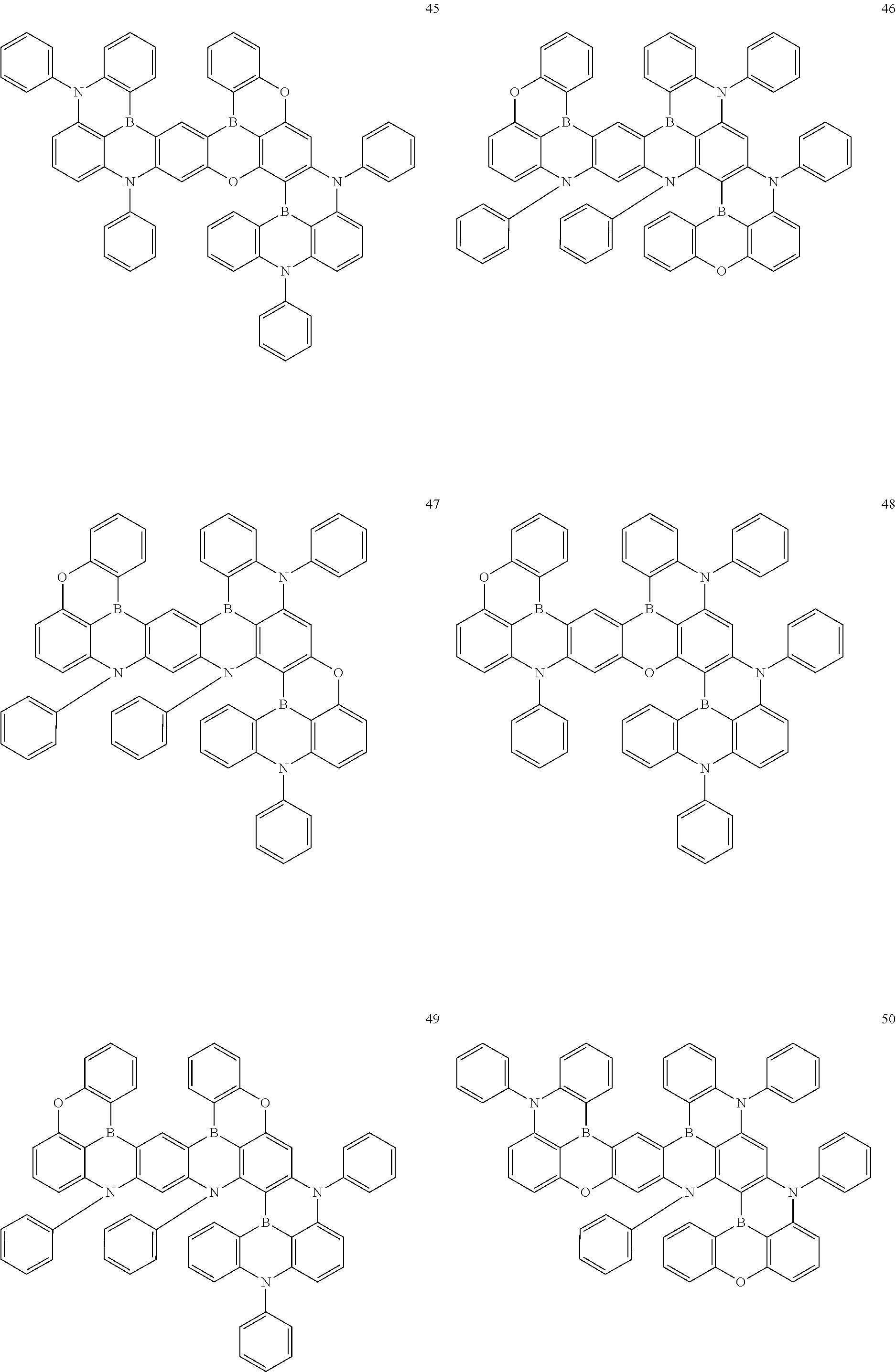 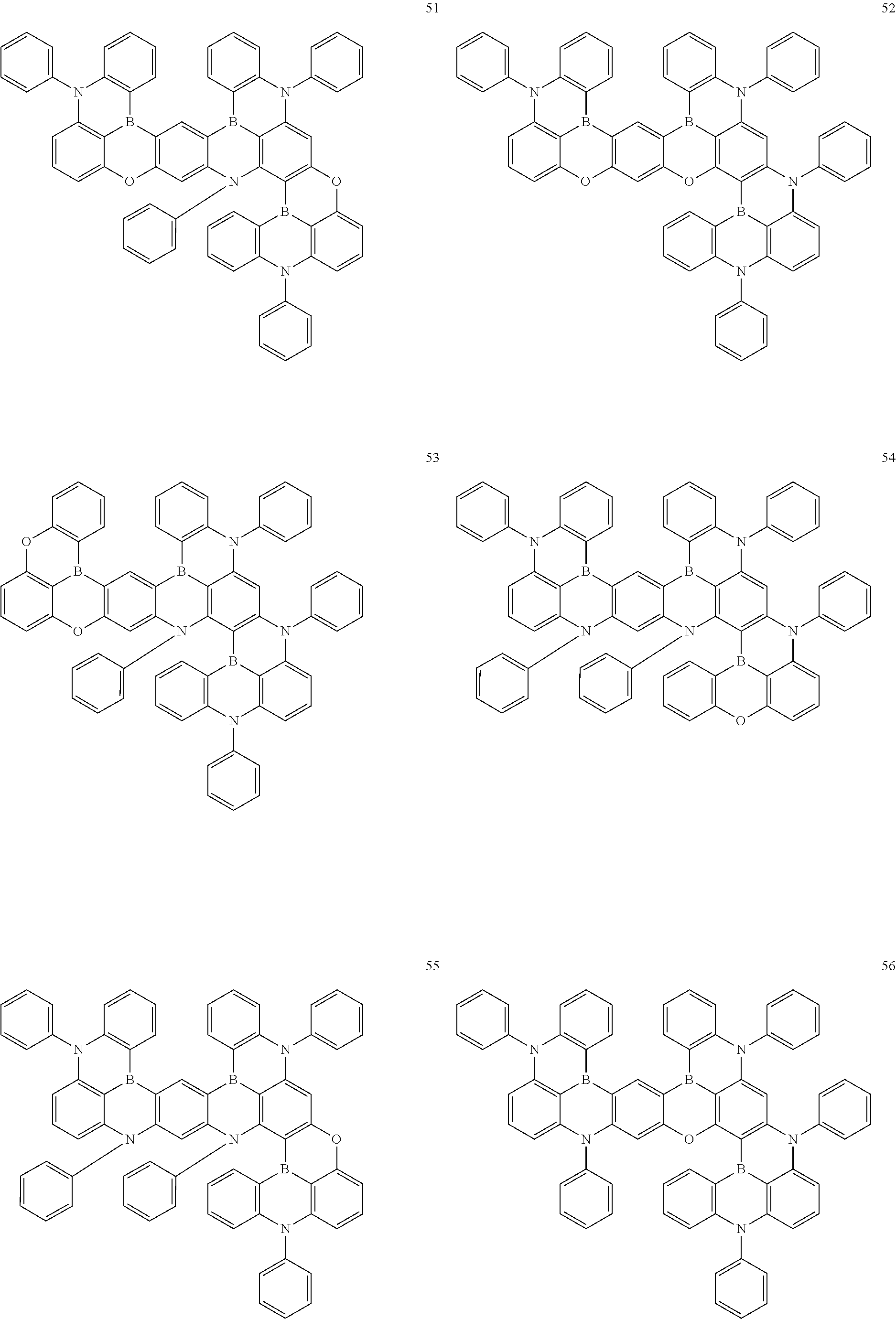 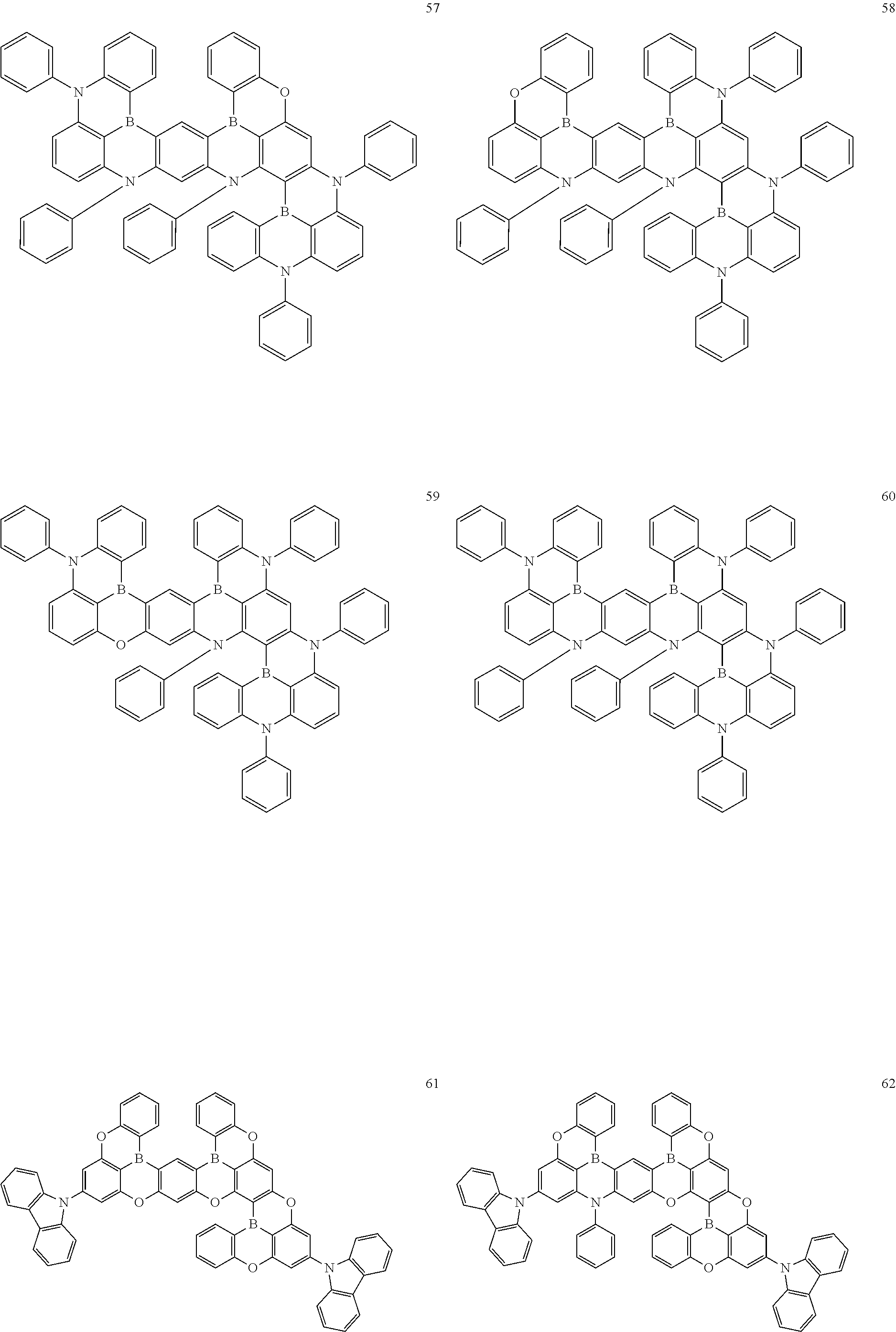 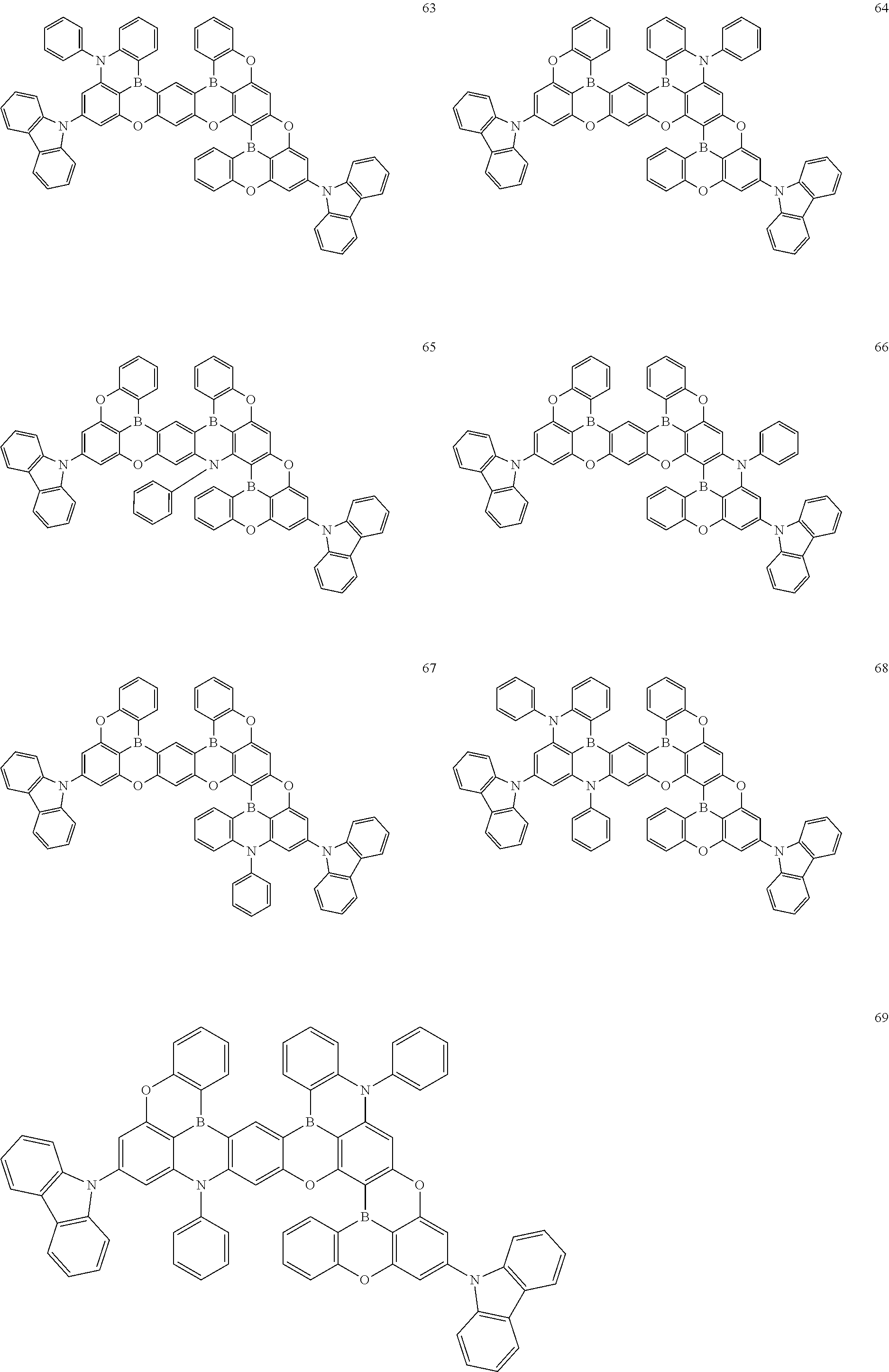 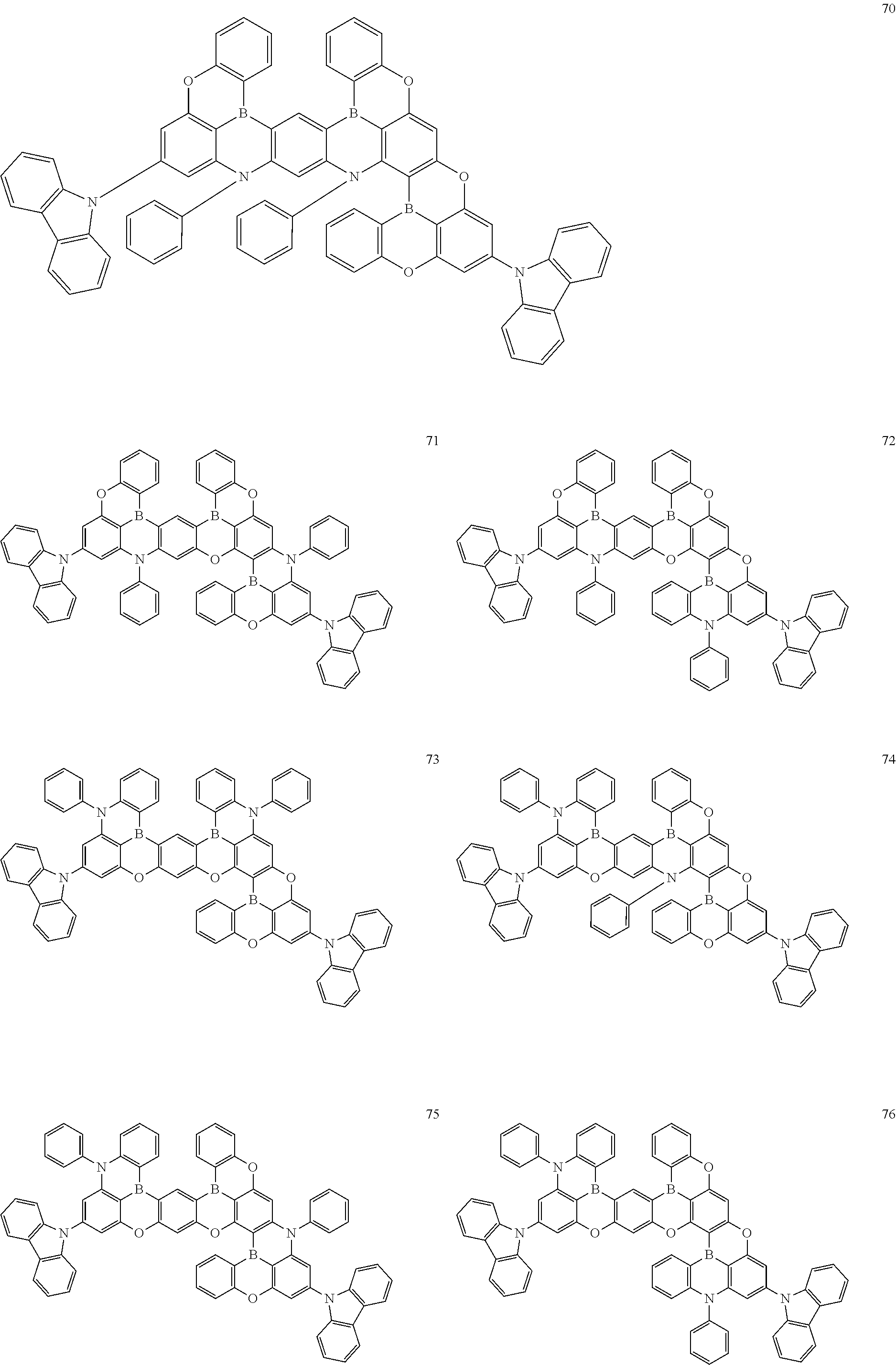 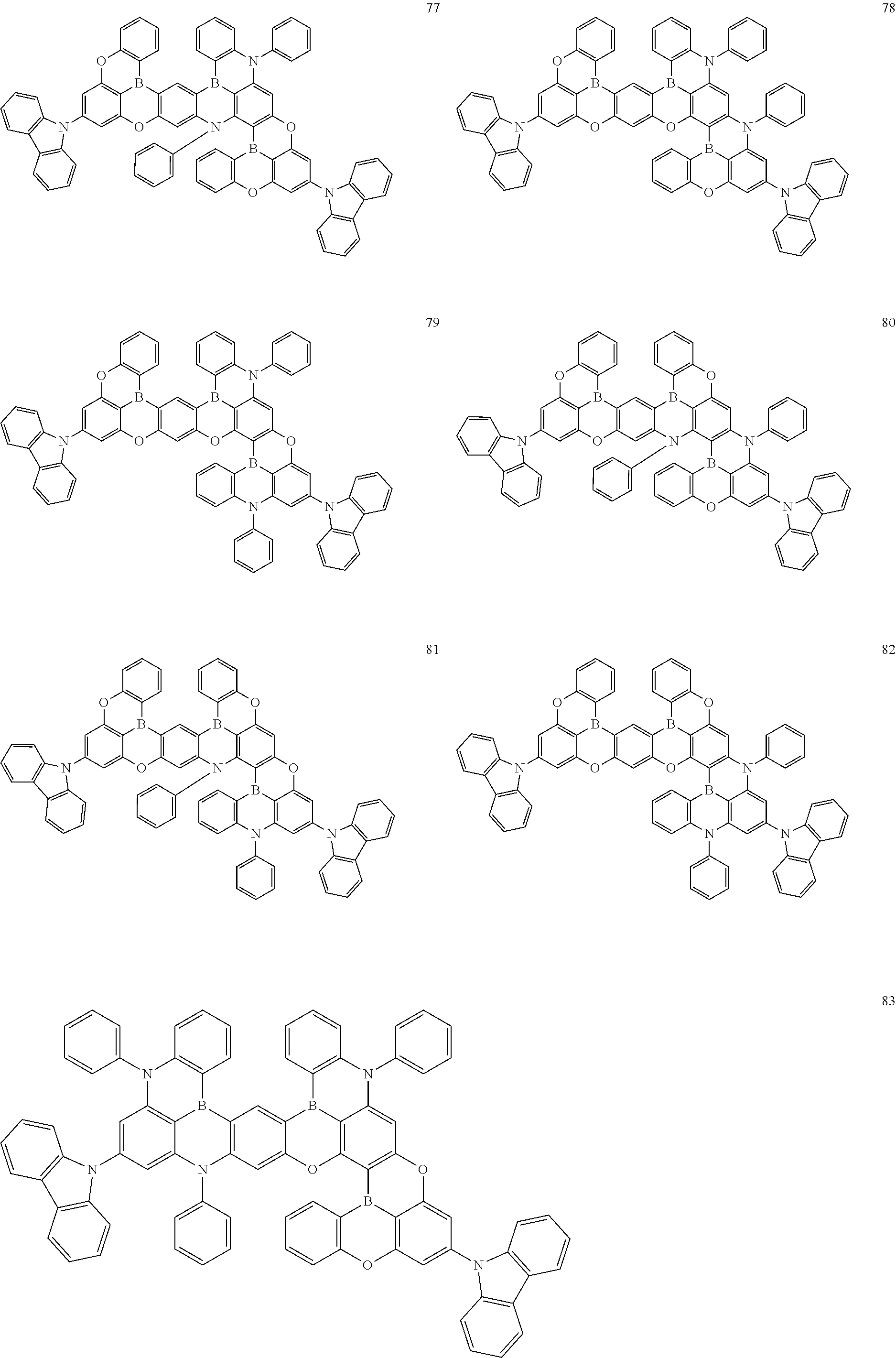 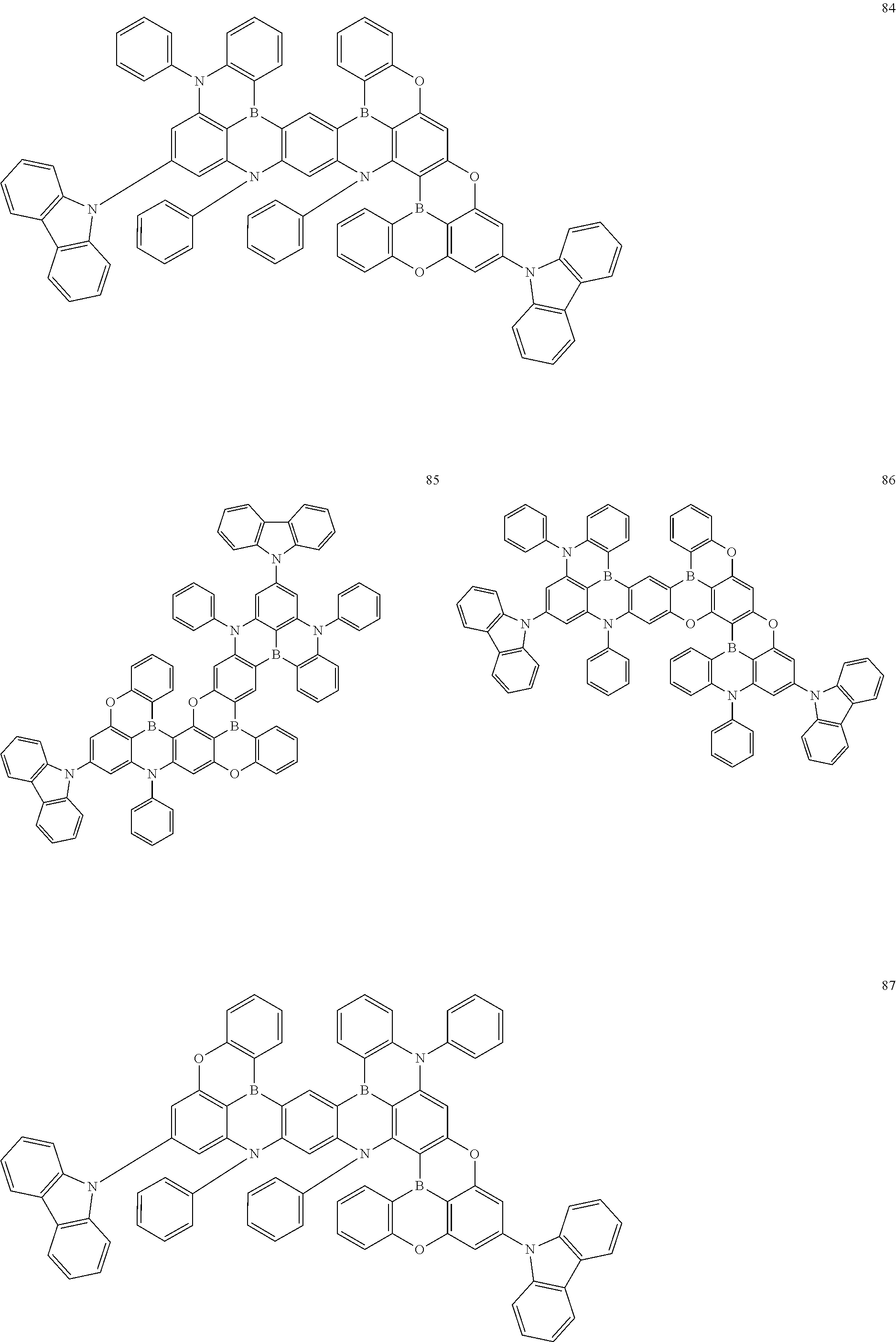 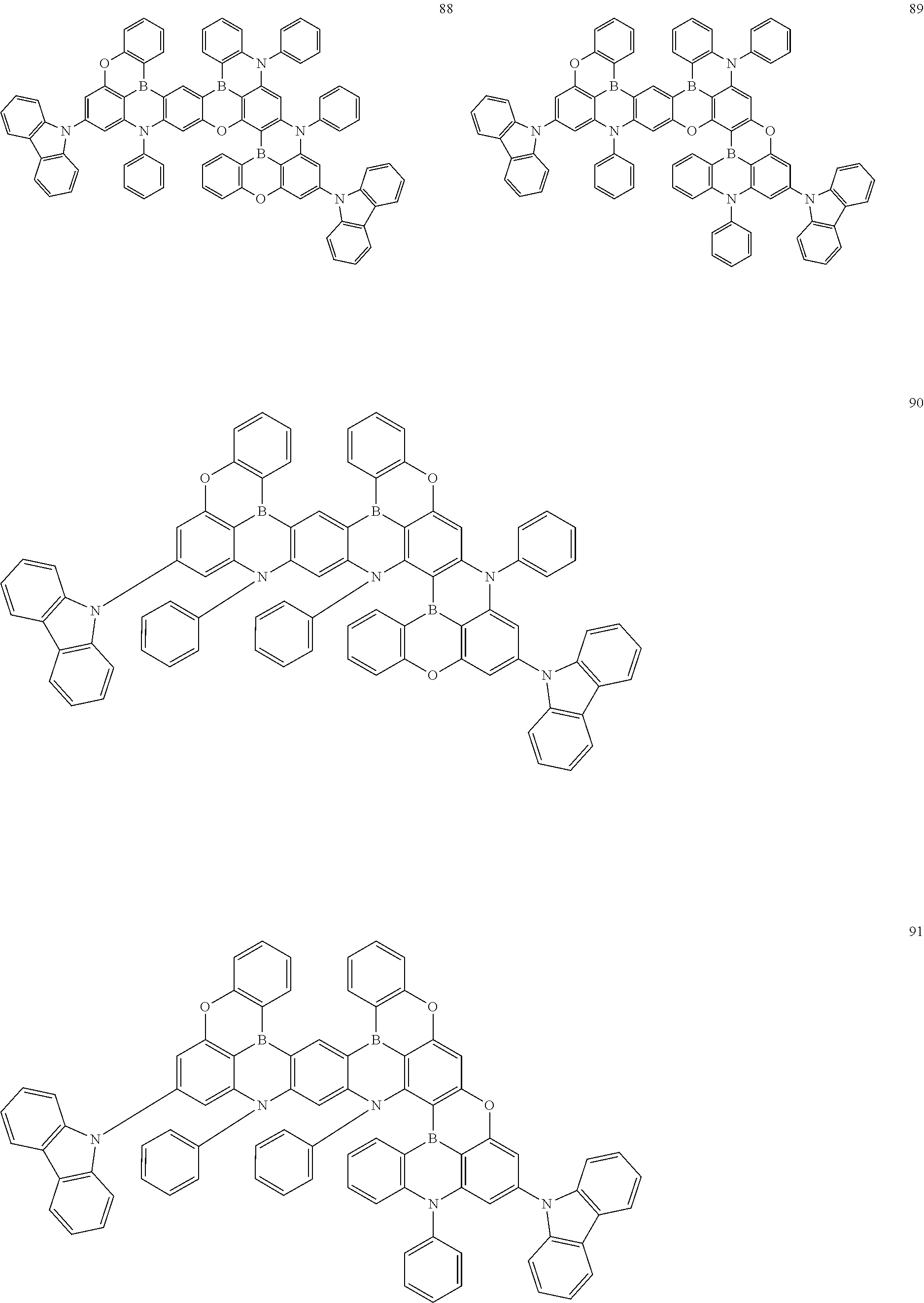 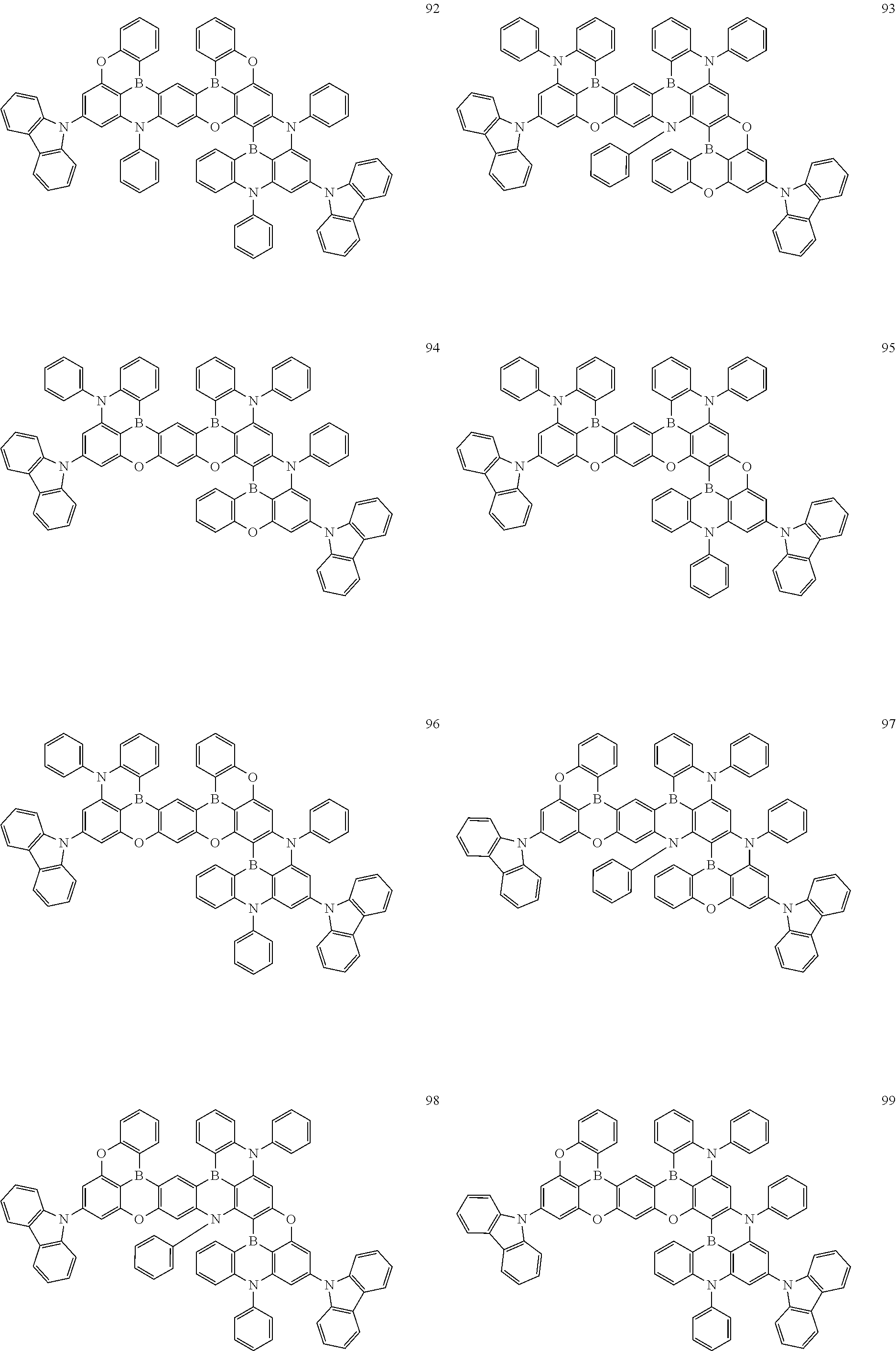 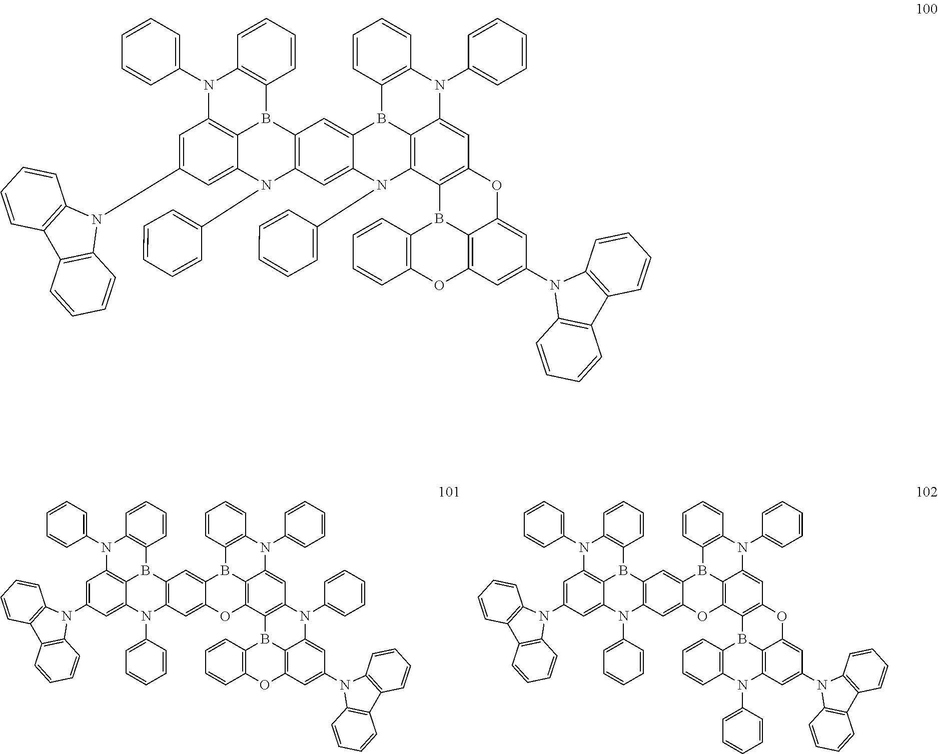 [SMILES: c1ccc(N2c3ccccc3B3c4cc5c(cc4N(c4ccccc4)c4cc(-n6c7ccccc7c7ccccc76)cc2c43)N(c2ccccc2)c2c3c(cc4c2B5c2ccccc2N4c2ccccc2)Oc2cc(-n4c5ccccc5c5ccccc54)cc4c2B3c2ccccc2O4)cc1 ; c1ccc(N2c3ccccc3B3c4cc5c(cc4N(c4ccccc4)c4cc(-n6c7ccccc7c7ccccc76)cc2c43)Oc2c3c(cc4c2B2c6ccccc6Oc6cc(-n7c8ccccc8c8ccccc87)cc(c62)N4c2ccccc2)N(c2ccccc2)c2ccccc2B53)cc1 ; c1ccc(N2c3ccccc3B3c4c(cc(-n5c6ccccc6c6ccccc65)cc42)Oc2cc4c5c(c23)Oc2cc3c(cc2B5c2ccccc2N4c2ccccc2)B2c4ccccc4N(c4ccccc4)c4cc(-n5c6ccccc6c6ccccc65)cc(c42)N3c2ccccc2)cc1] 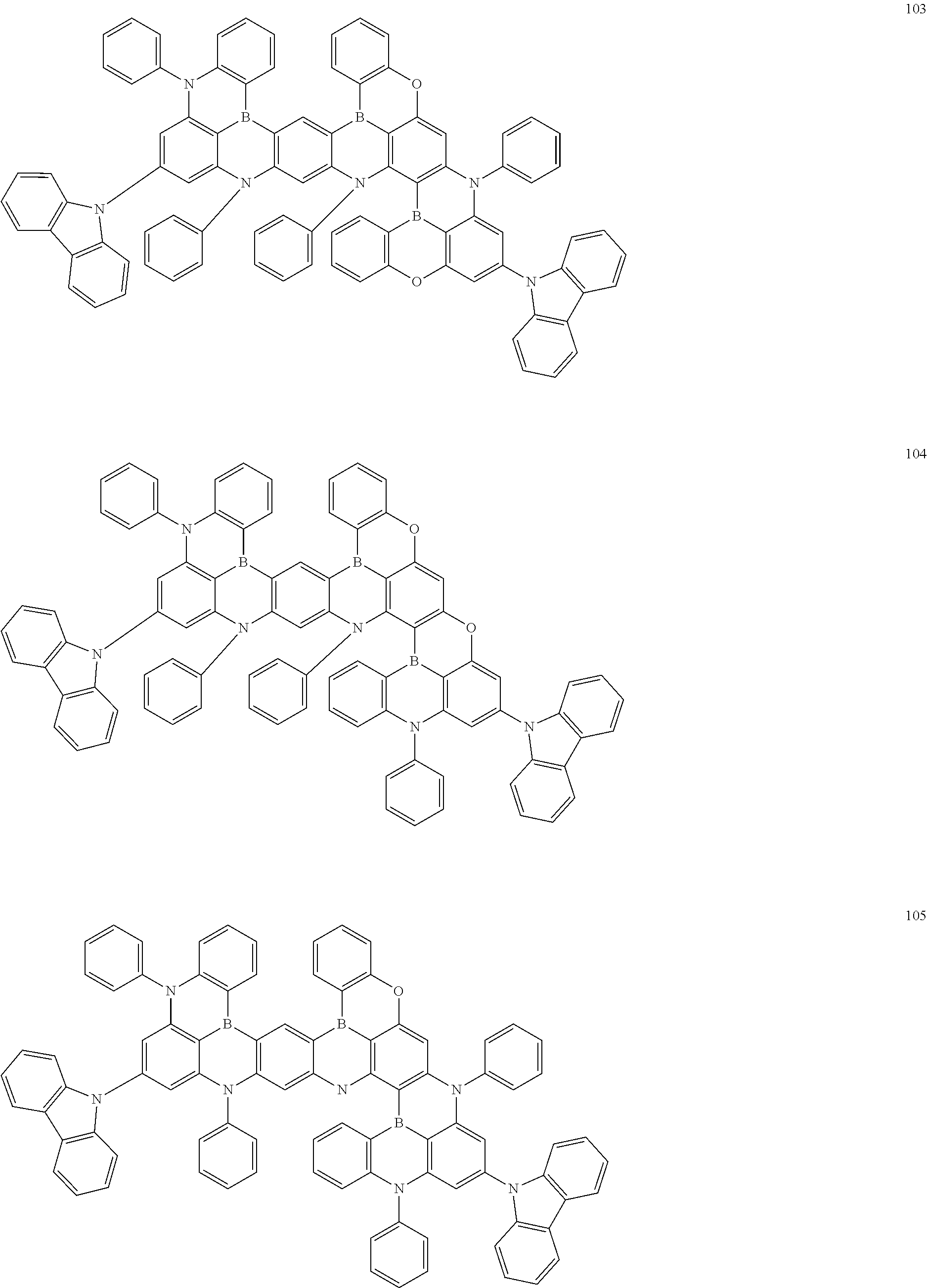 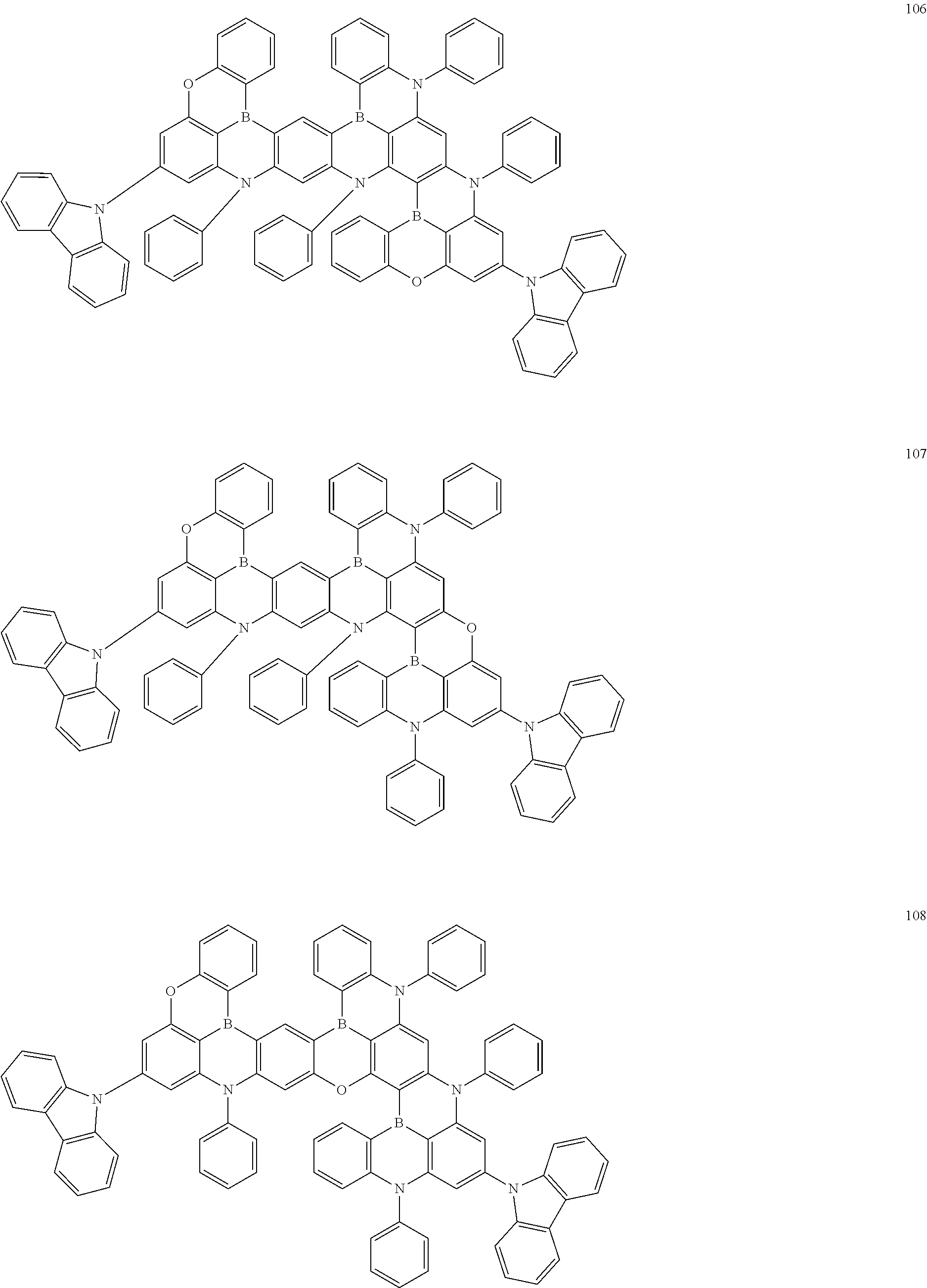 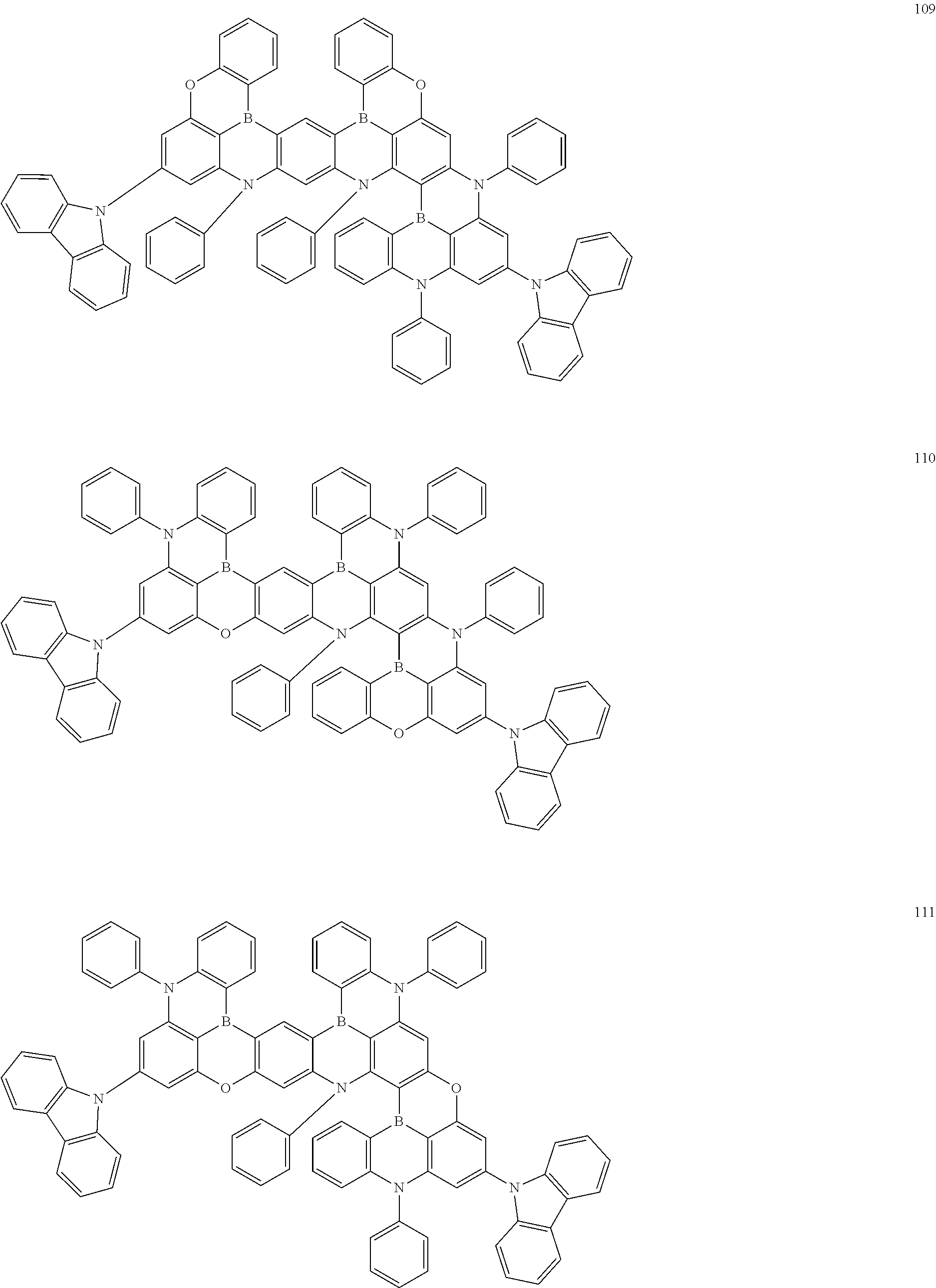 [SMILES: c1ccc(N2c3cc4c(cc3B3c5ccccc5Oc5cc(-n6c7ccccc7c7ccccc76)cc2c53)B2c3ccccc3Oc3cc5c(c(c32)N4c2ccccc2)B2c3ccccc3N(c3ccccc3)c3cc(-n4c6ccccc6c6ccccc64)cc(c32)N5c2ccccc2)cc1 ; c1ccc(N2c3ccccc3B3c4cc5c(cc4Oc4cc(-n6c7ccccc7c7ccccc76)cc2c43)N(c2ccccc2)c2c3c(cc4c2B2c6ccccc6Oc6cc(-n7c8ccccc8c8ccccc87)cc(c62)N4c2ccccc2)N(c2ccccc2)c2ccccc2B53)cc1 ; c1ccc(N2c3ccccc3B3c4cc5c(cc4Oc4cc(-n6c7ccccc7c7ccccc76)cc2c43)N(c2ccccc2)c2c3c(cc4c2B5c2ccccc2N4c2ccccc2)Oc2cc(-n4c5ccccc5c5ccccc54)cc4c2B3c2ccccc2N4c2ccccc2)cc1] 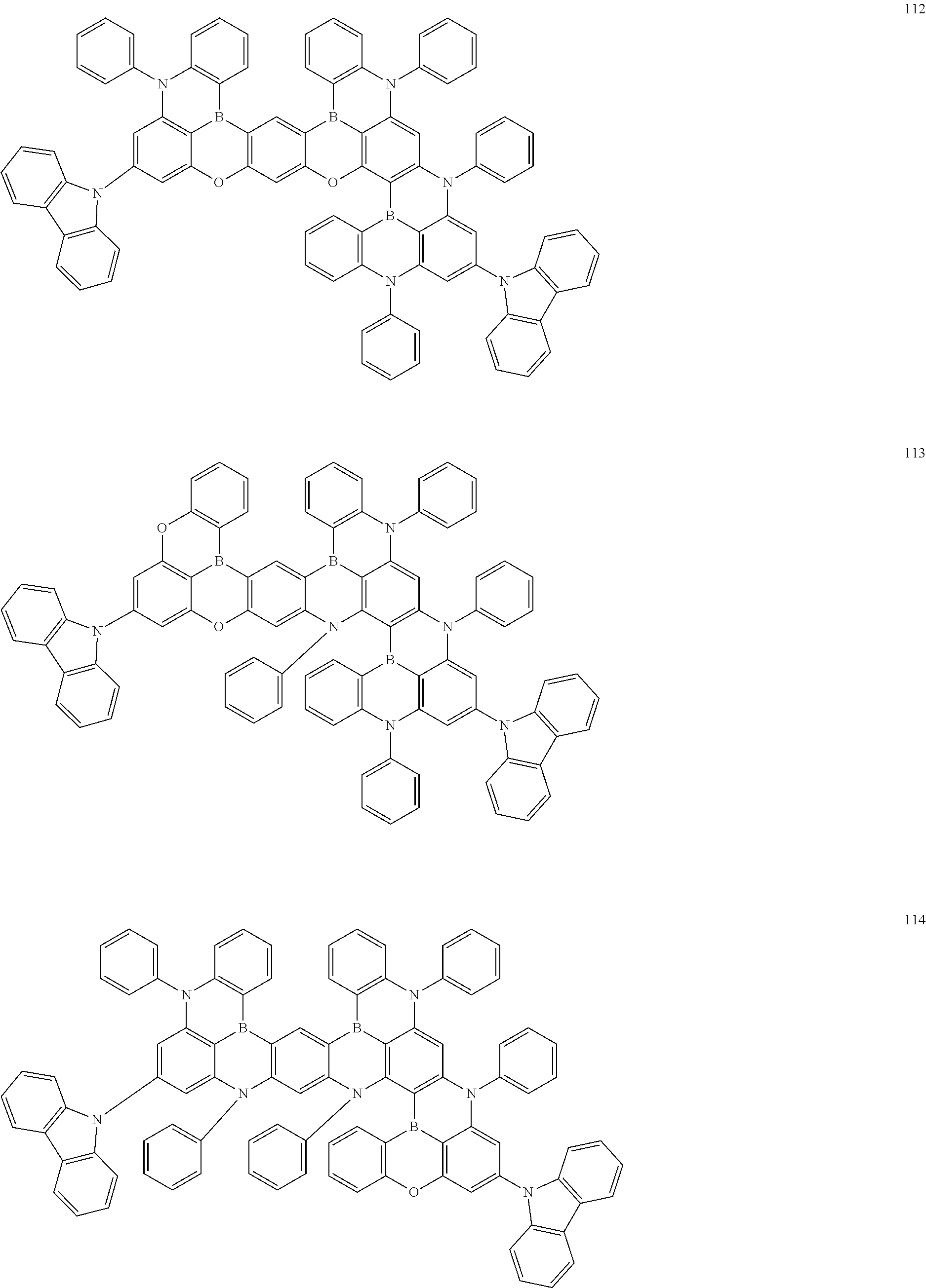 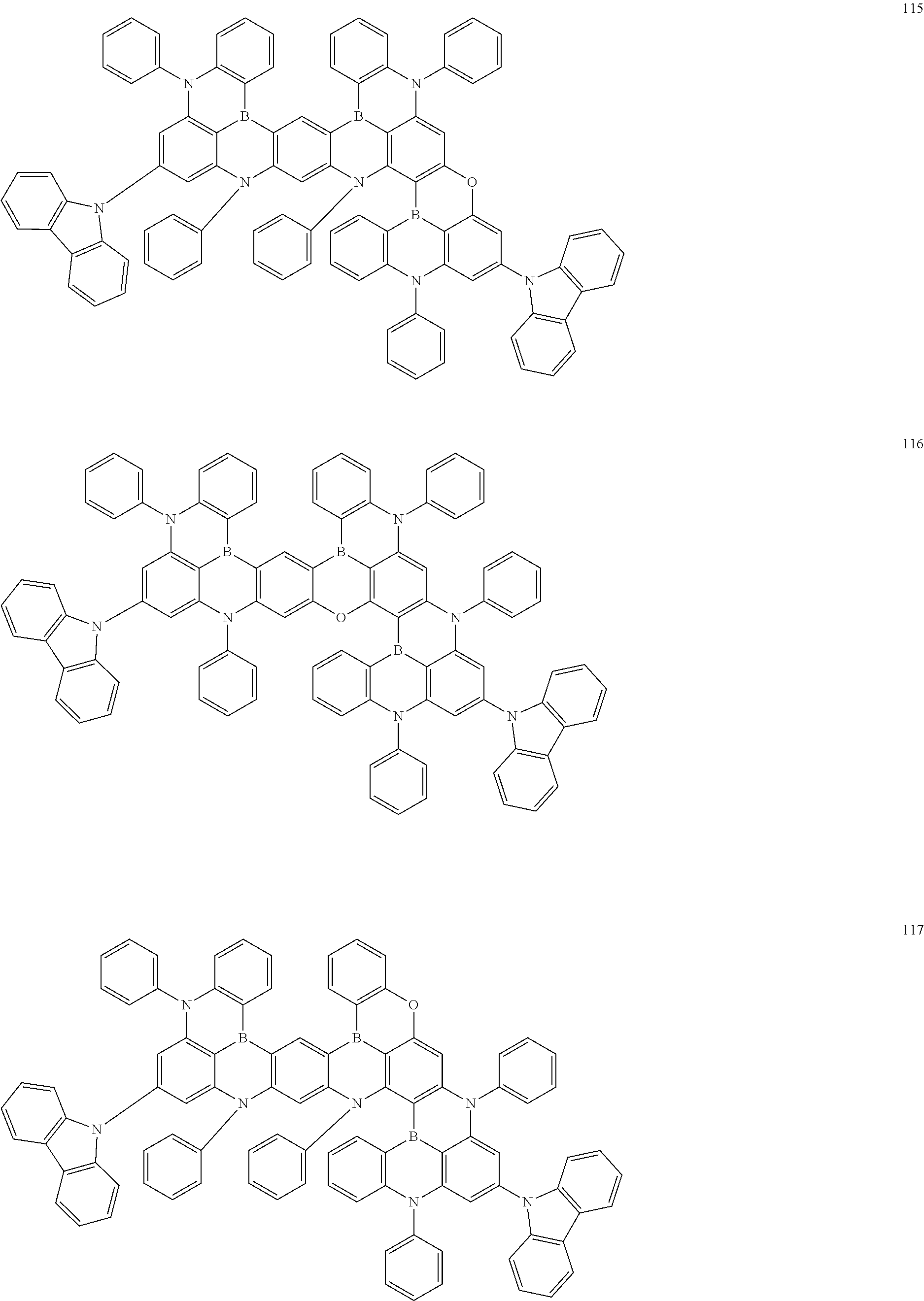 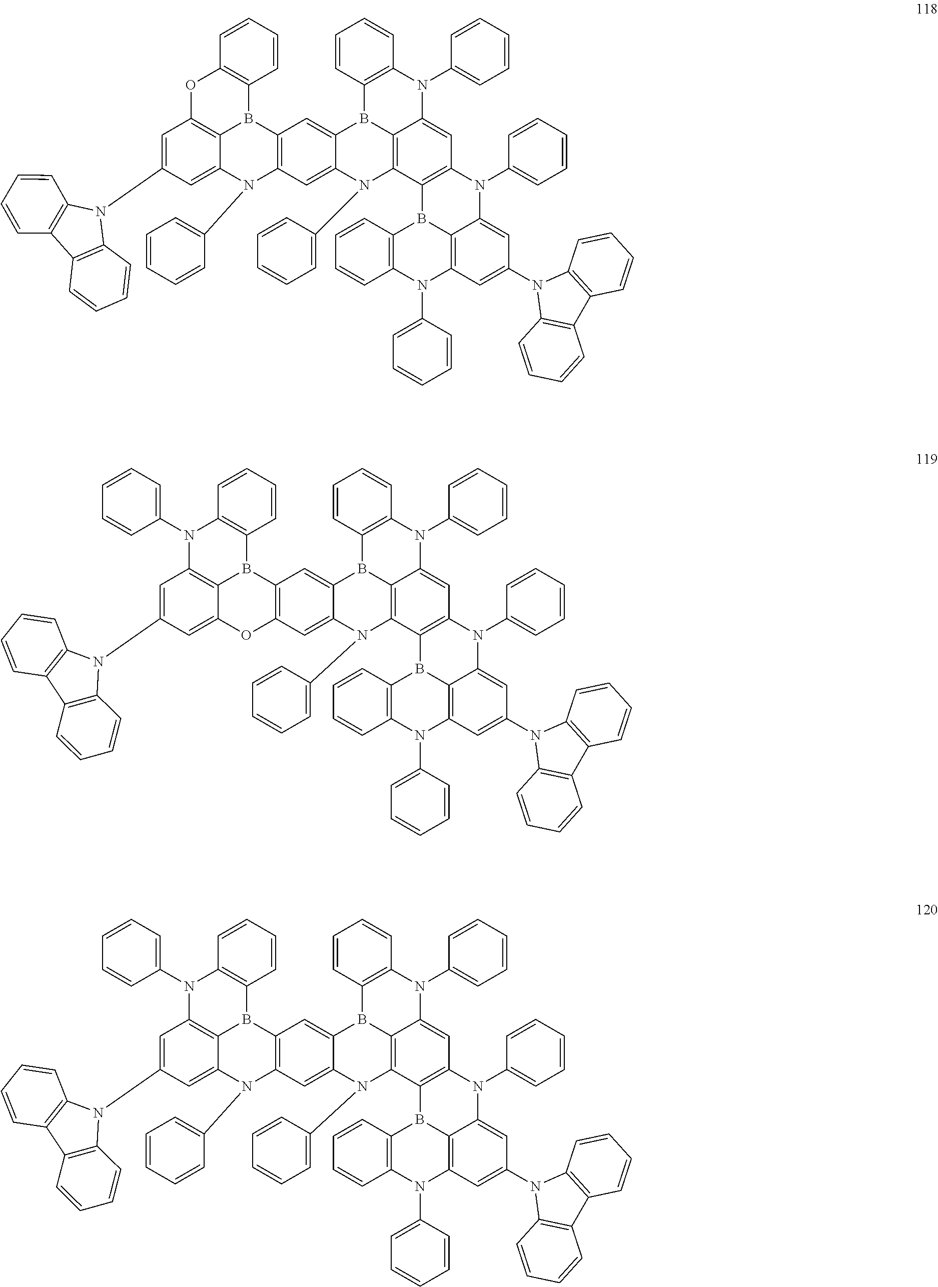 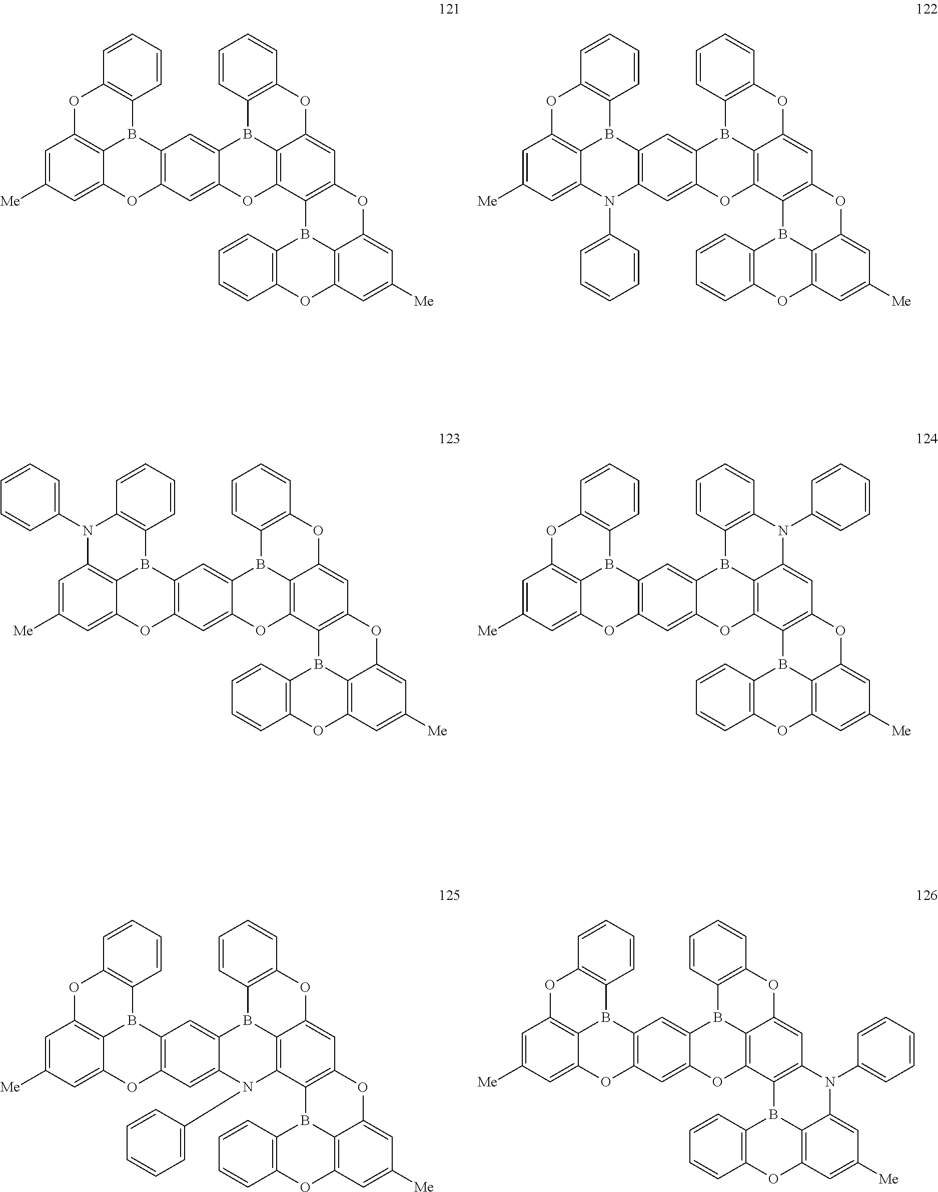 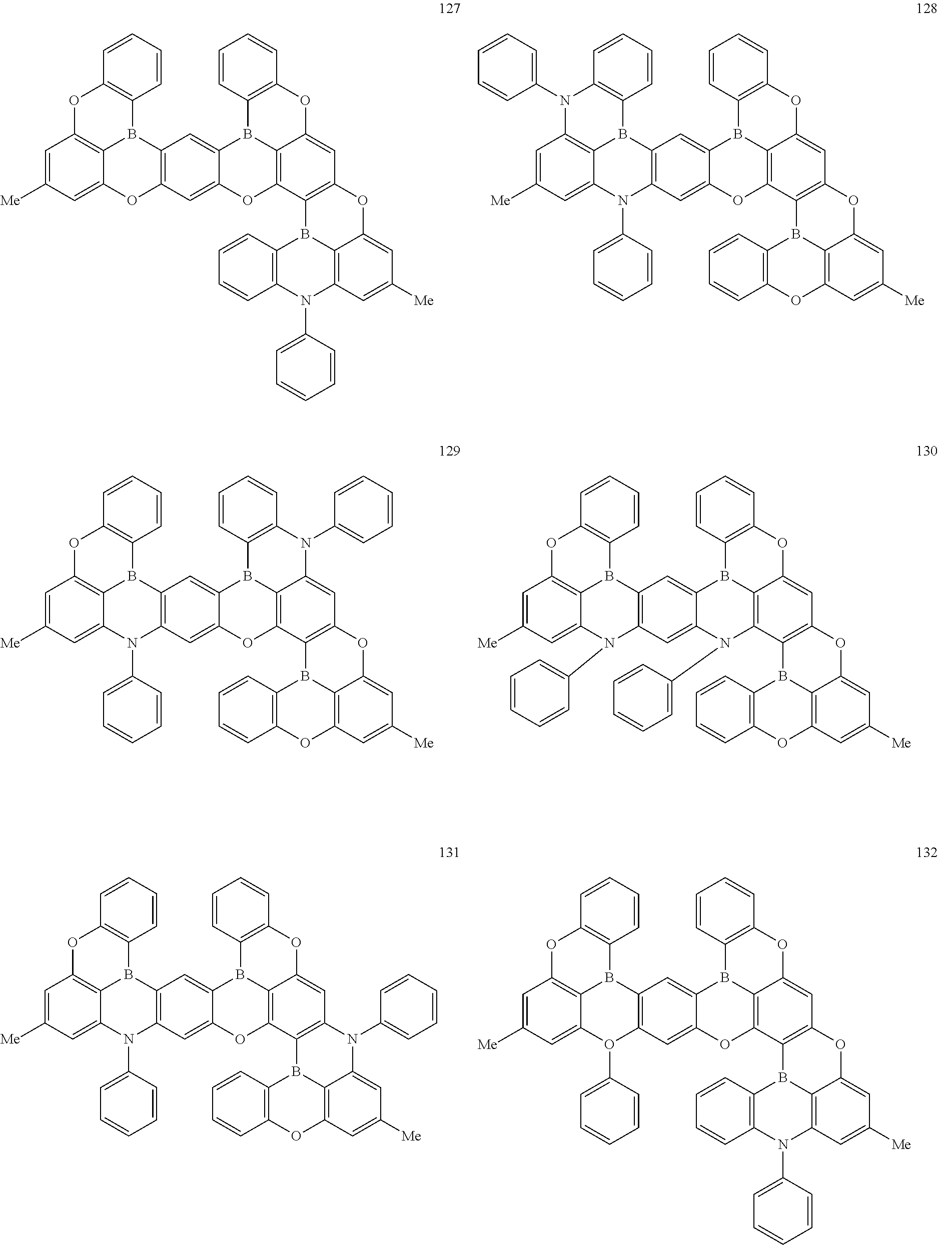 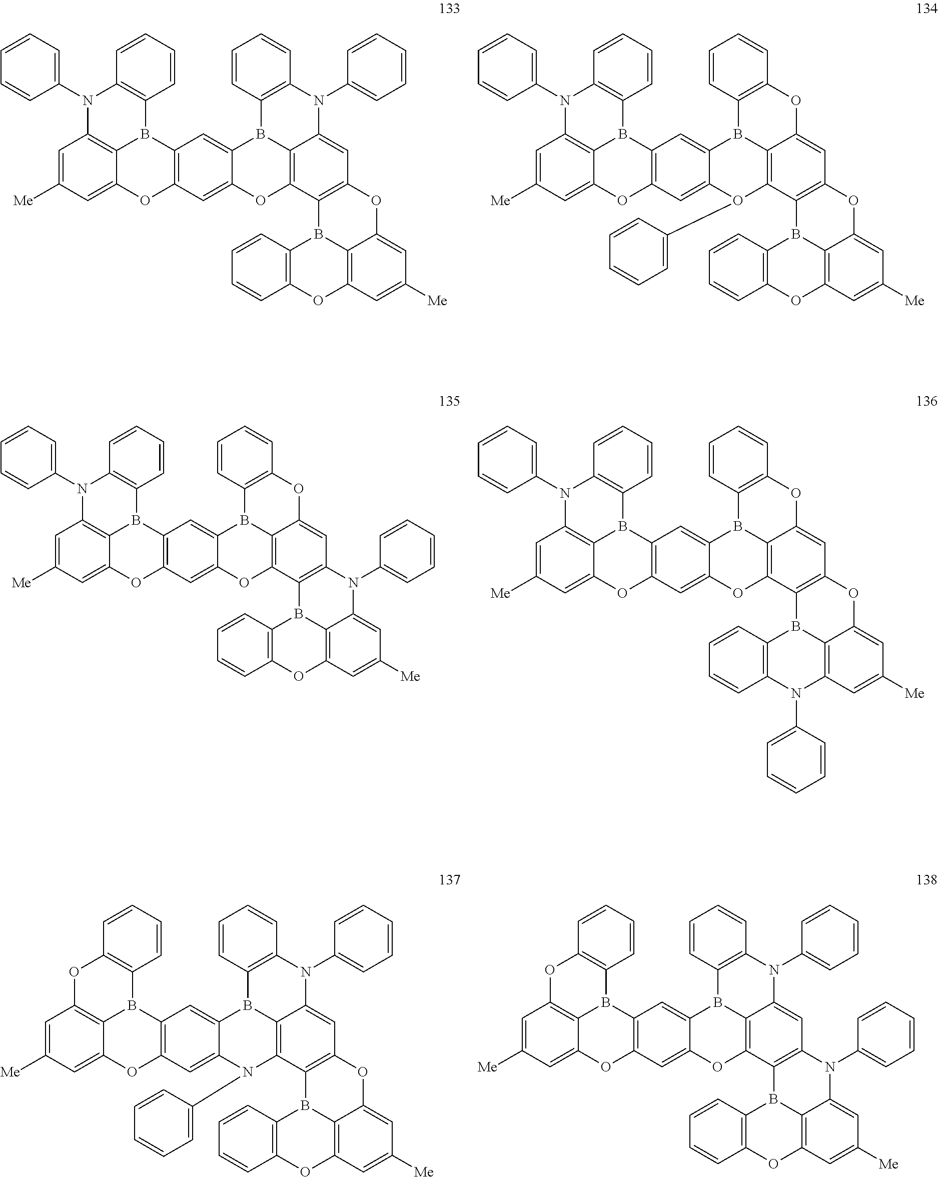 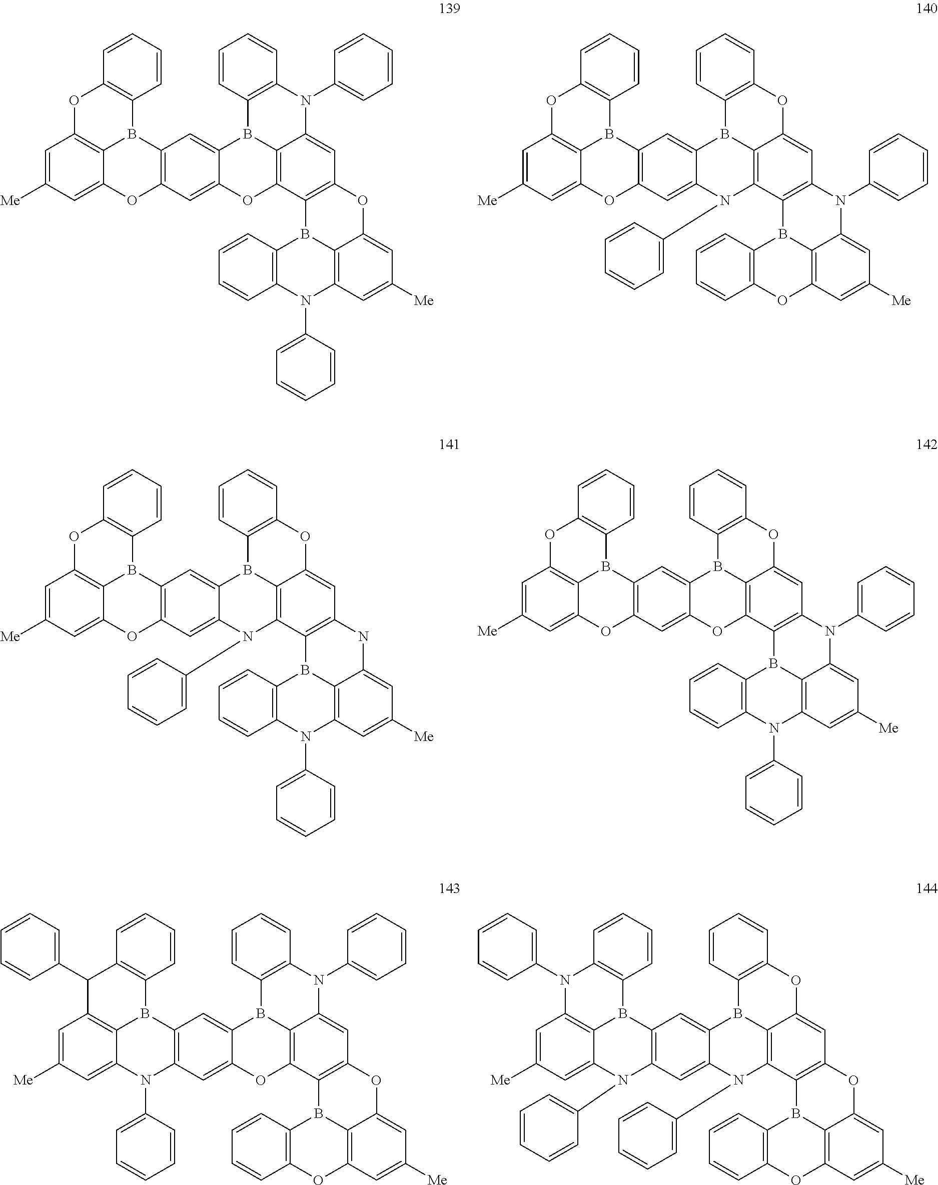 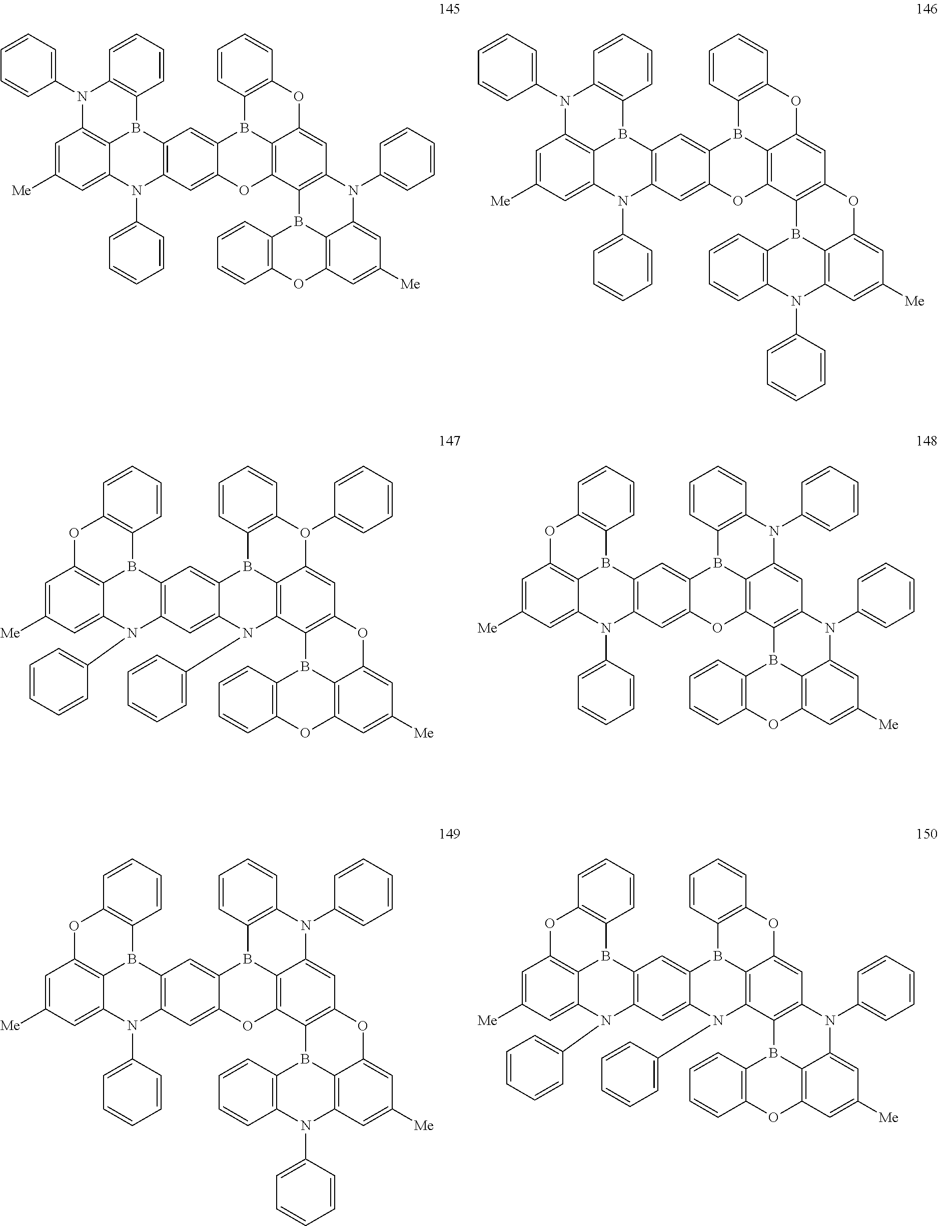 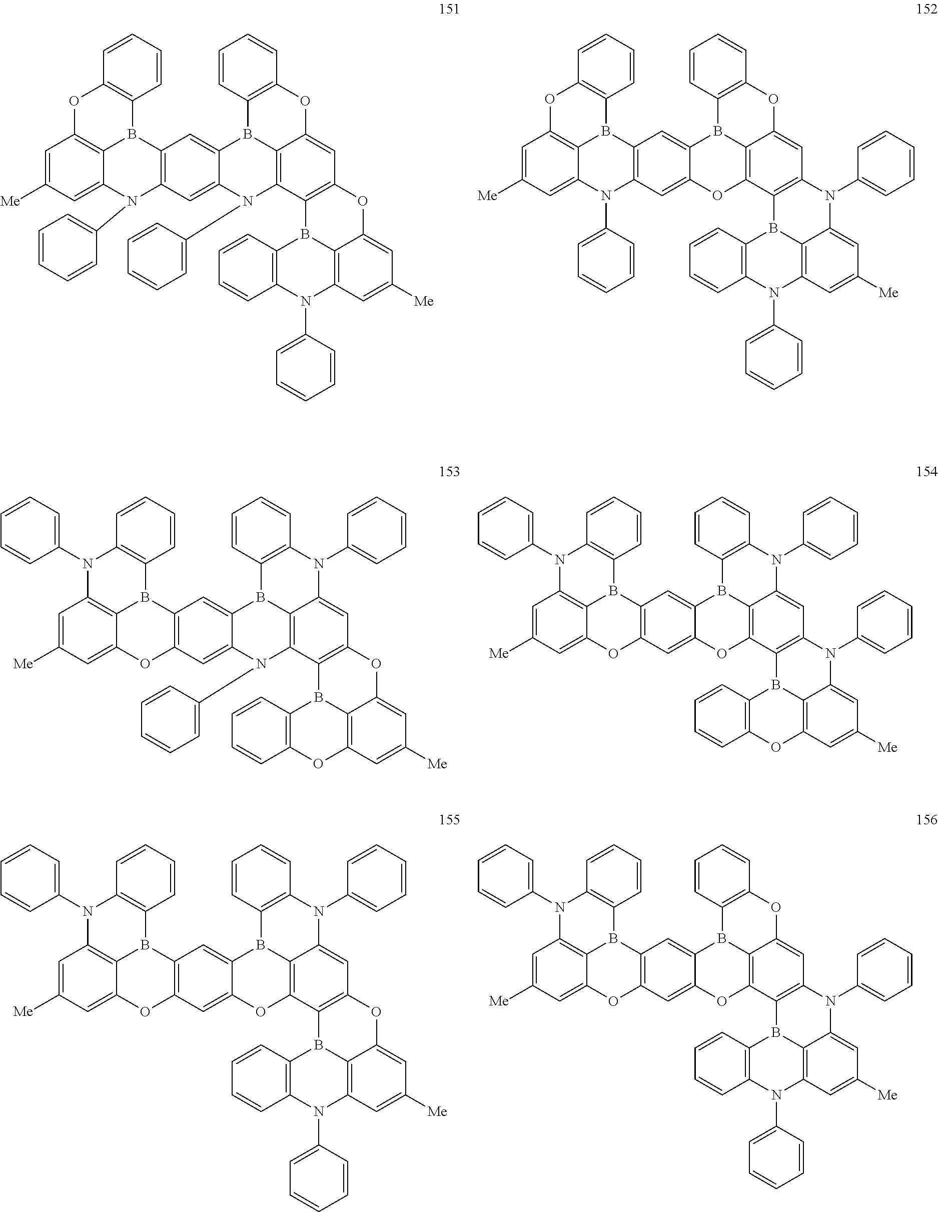 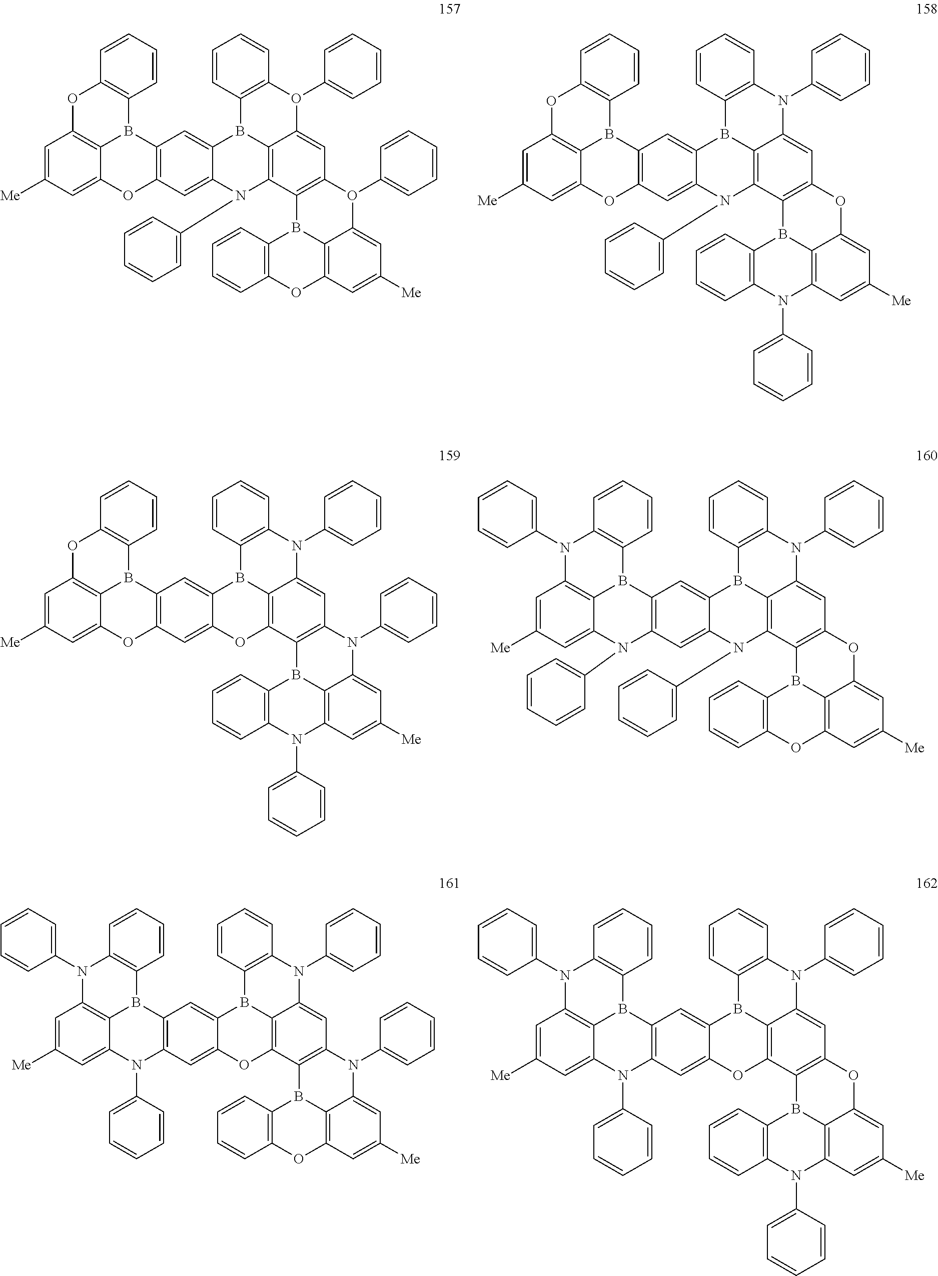 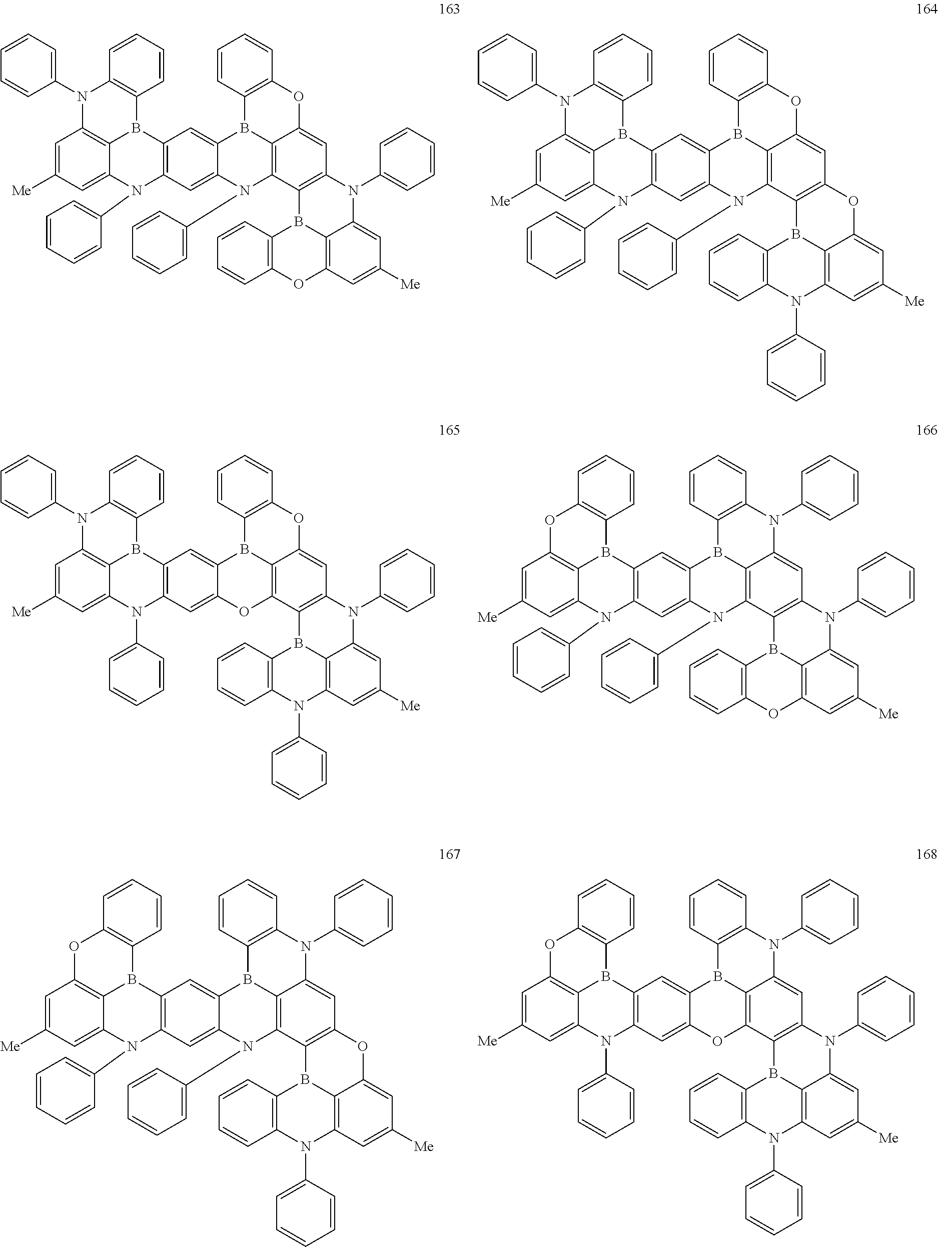 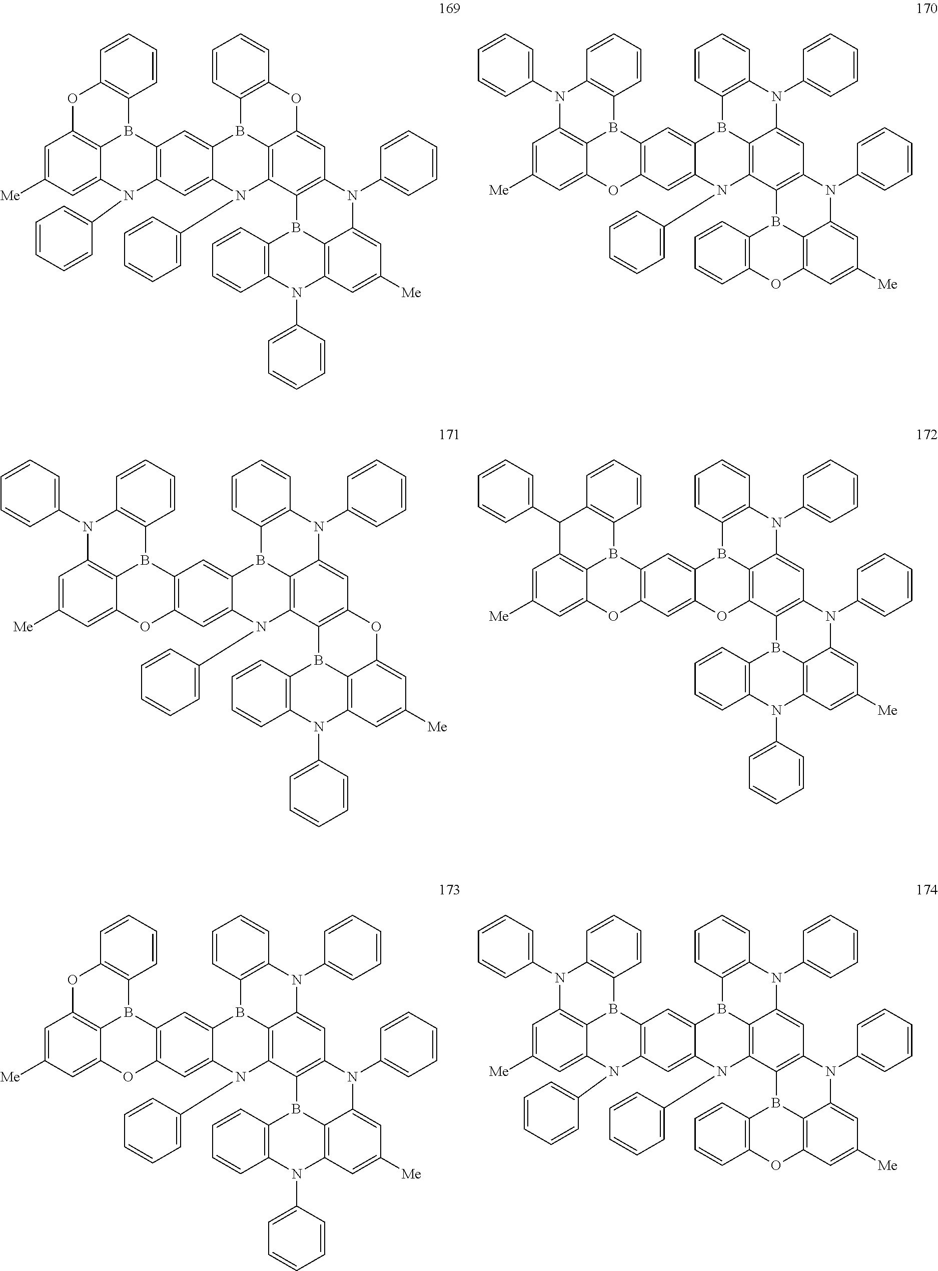 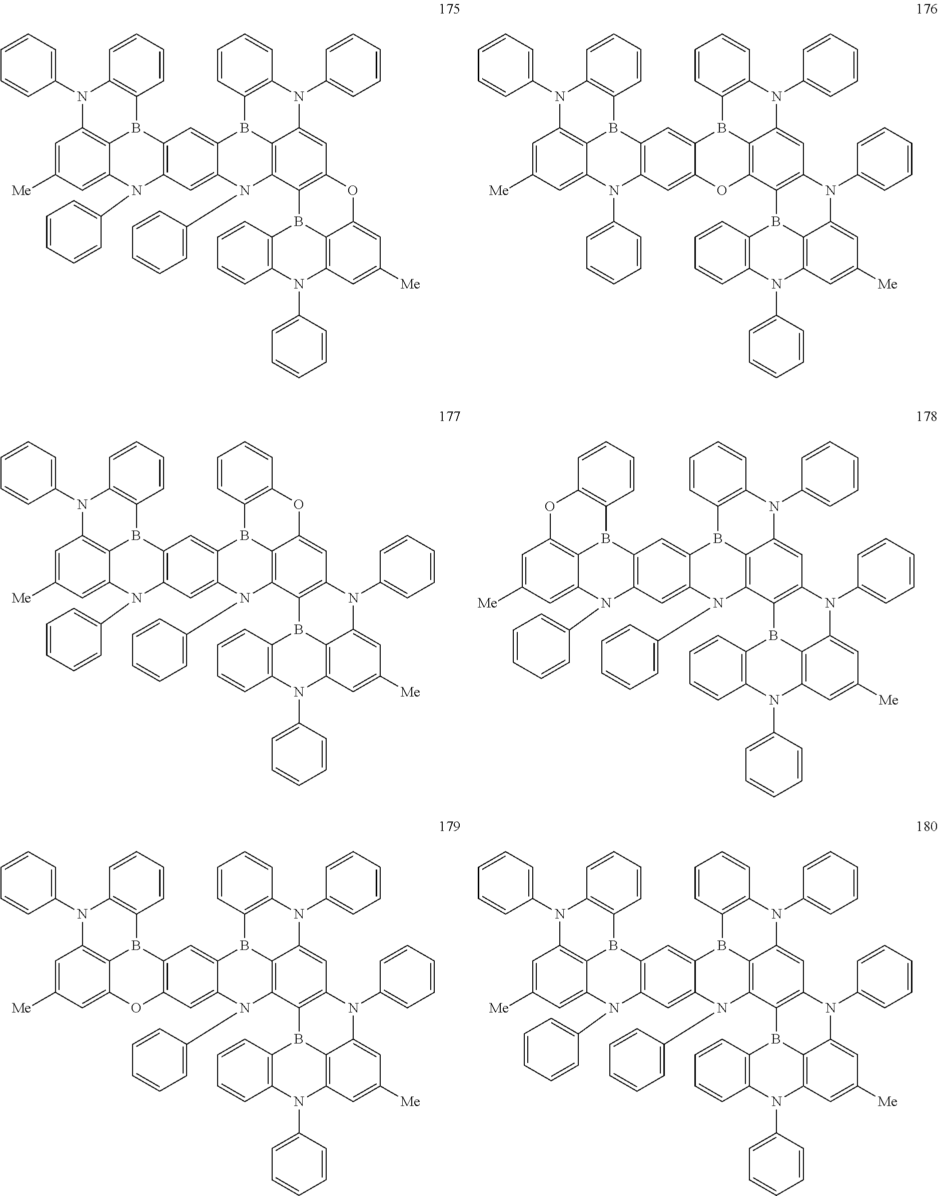 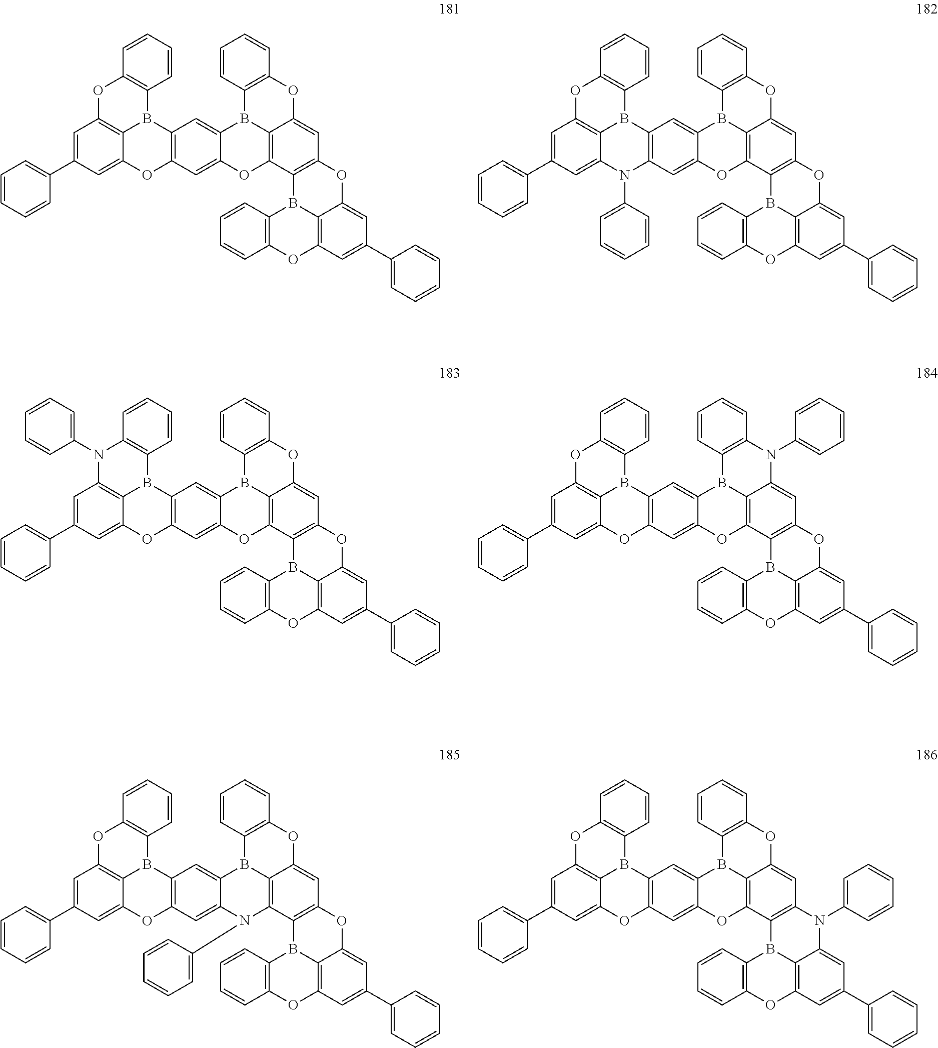 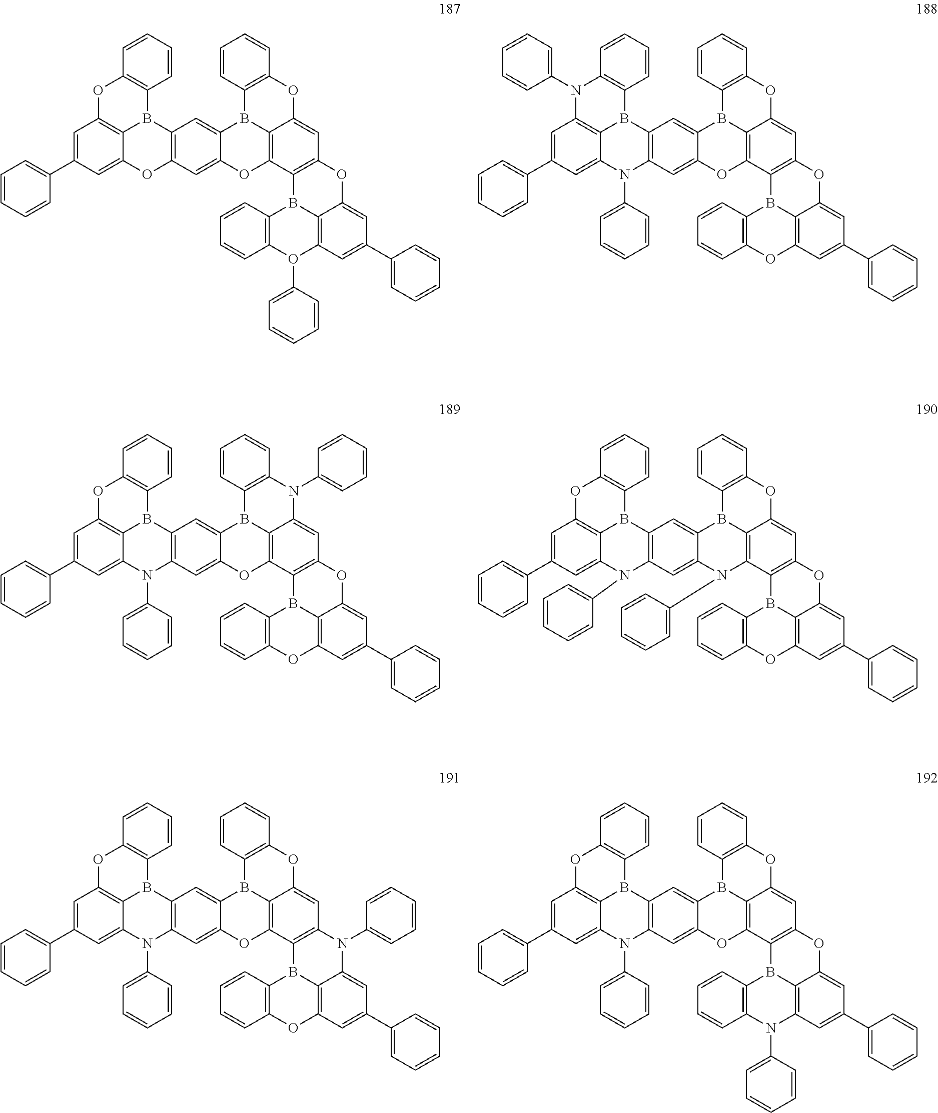 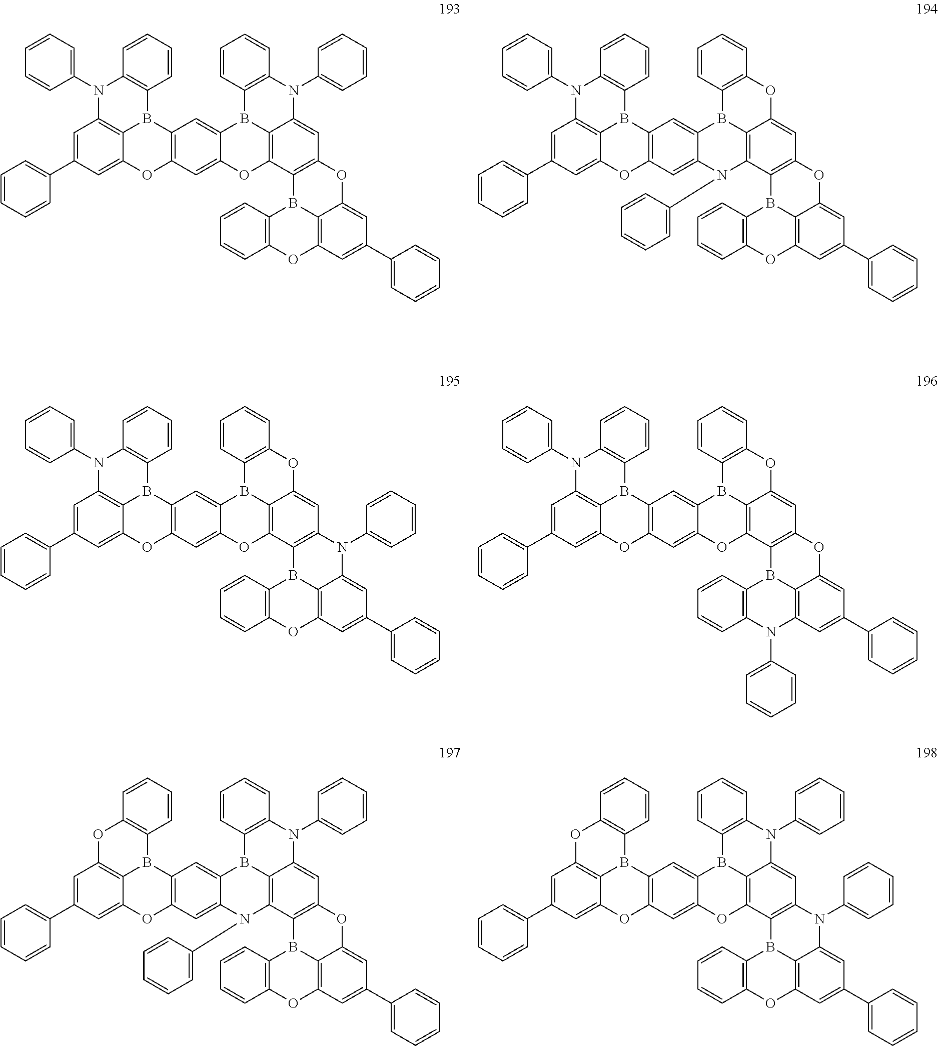 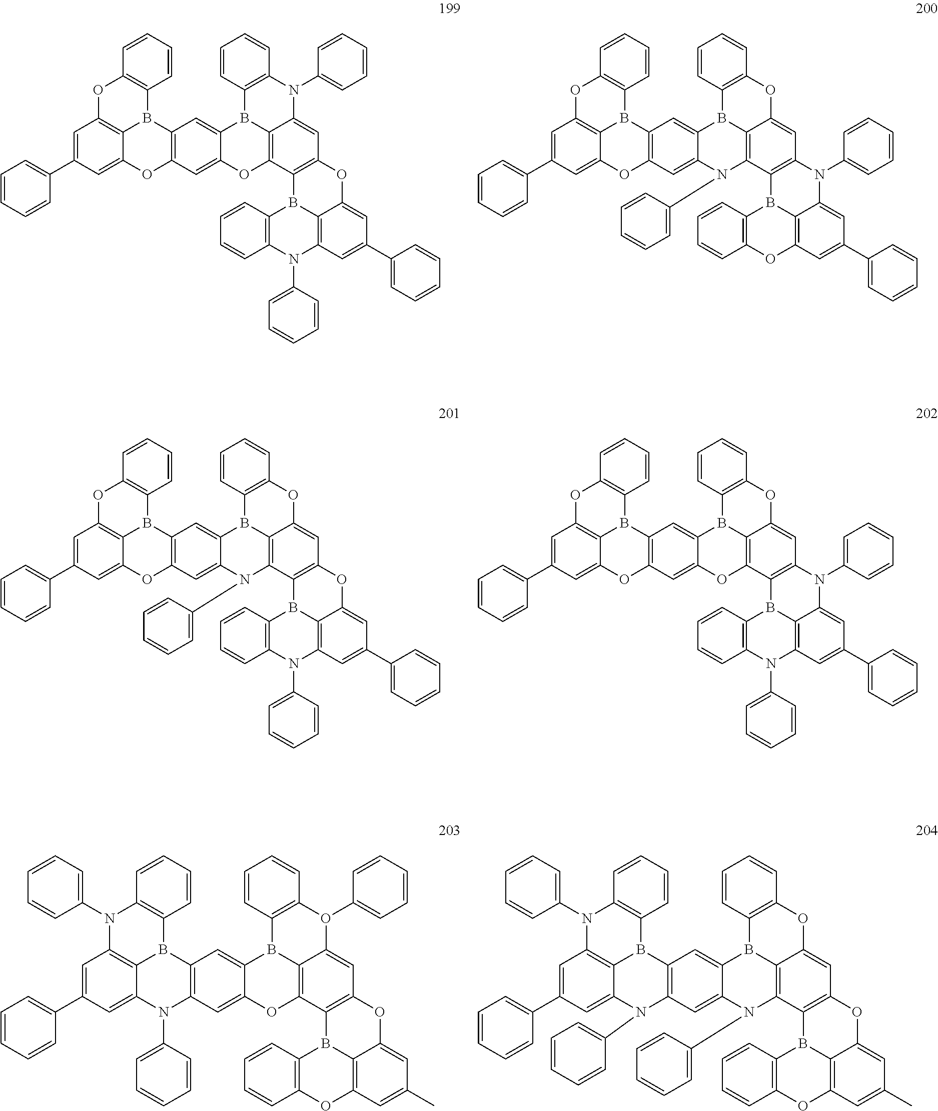 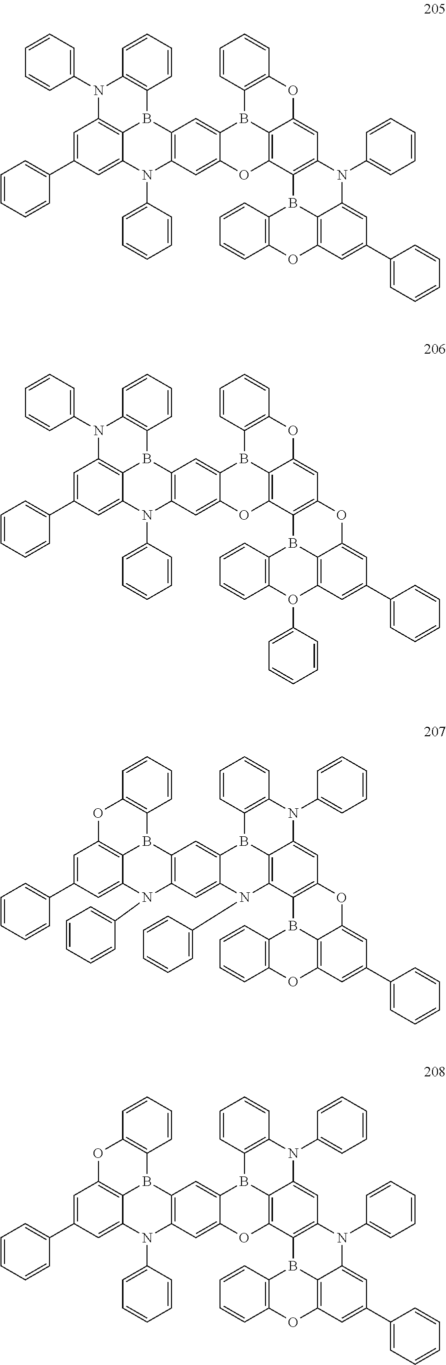 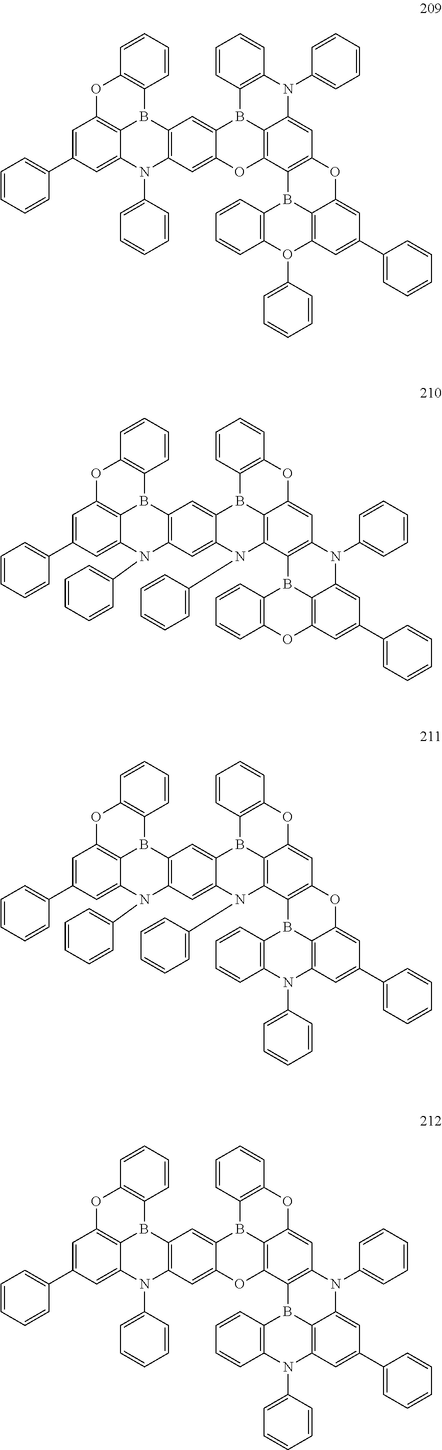 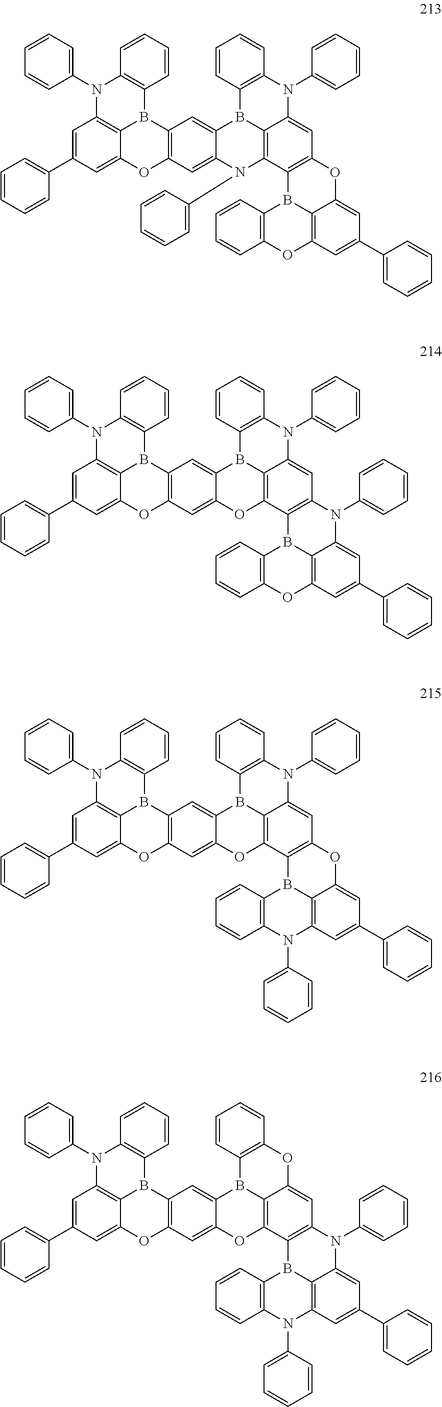 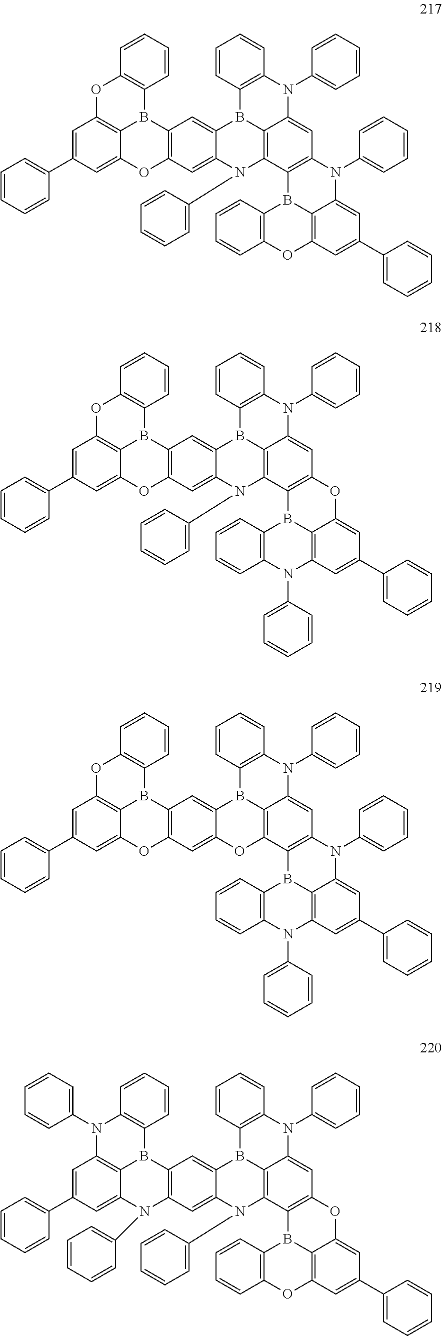 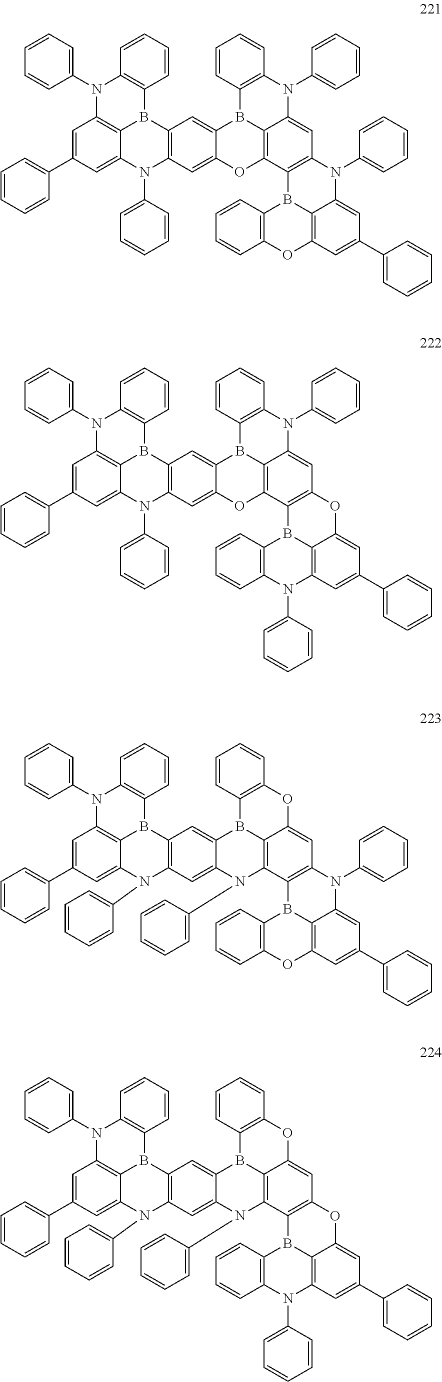 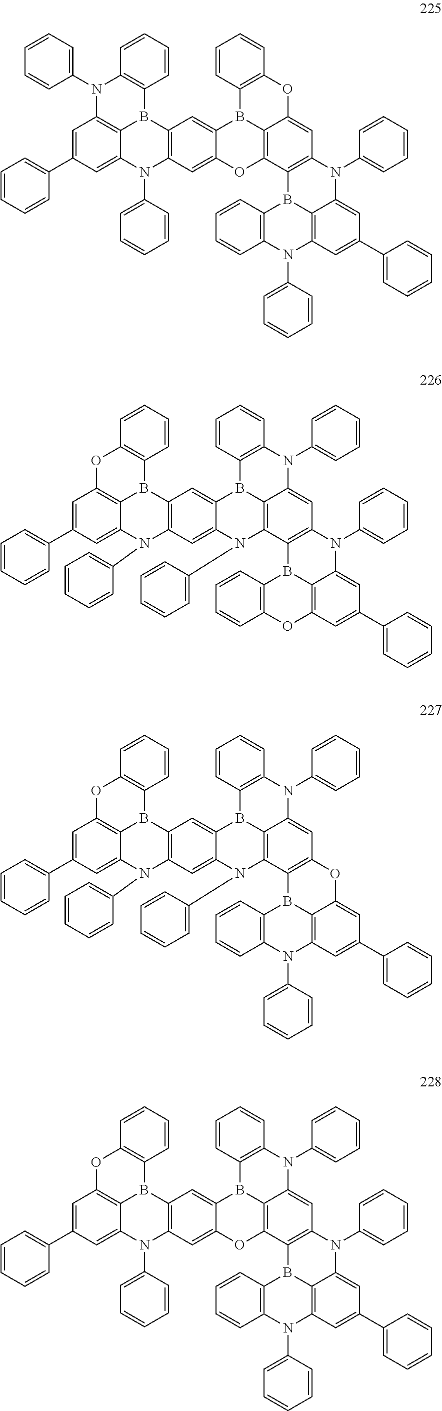 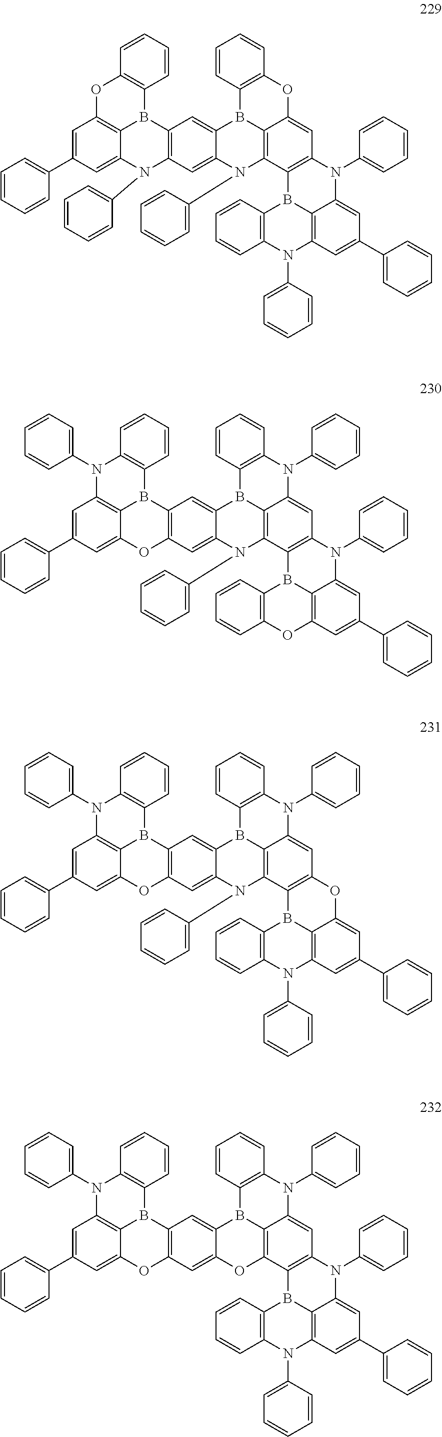 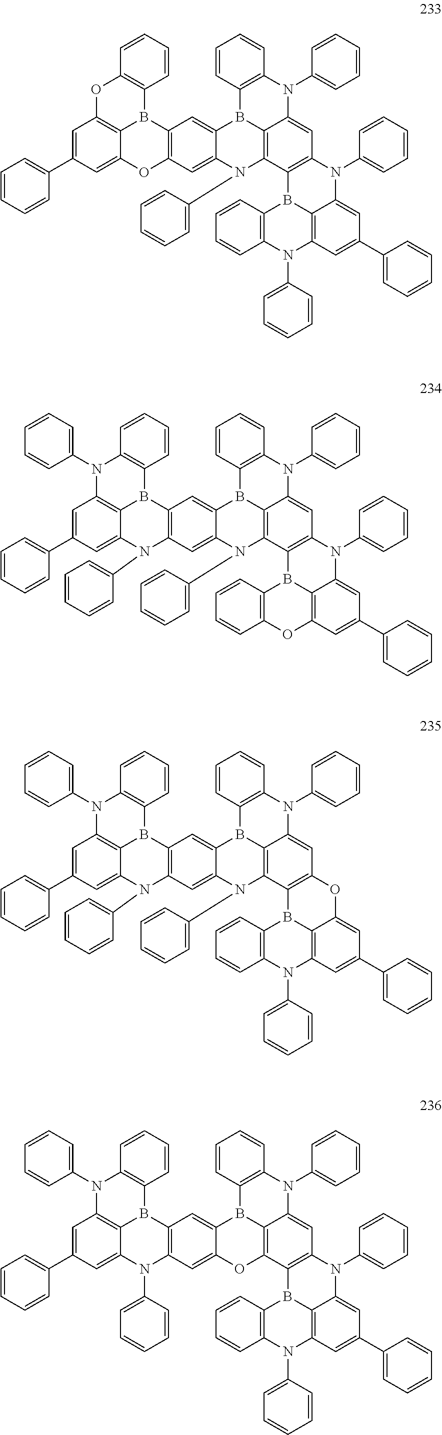 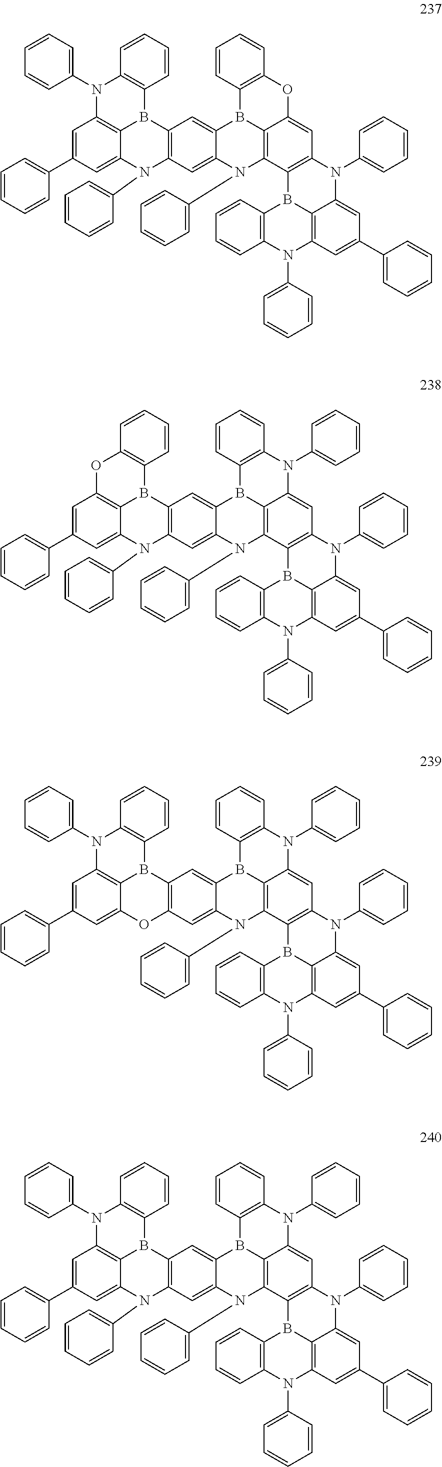 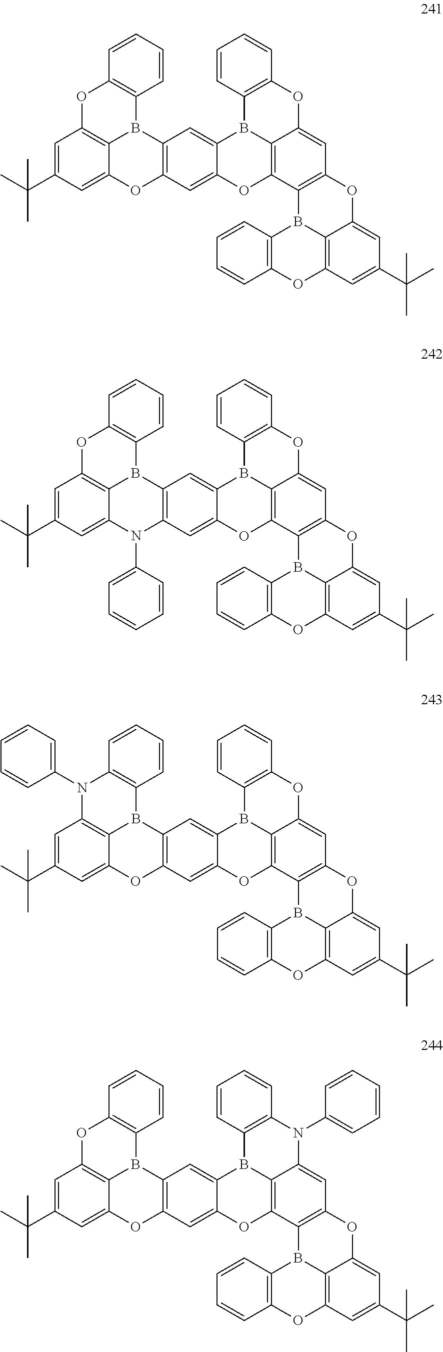 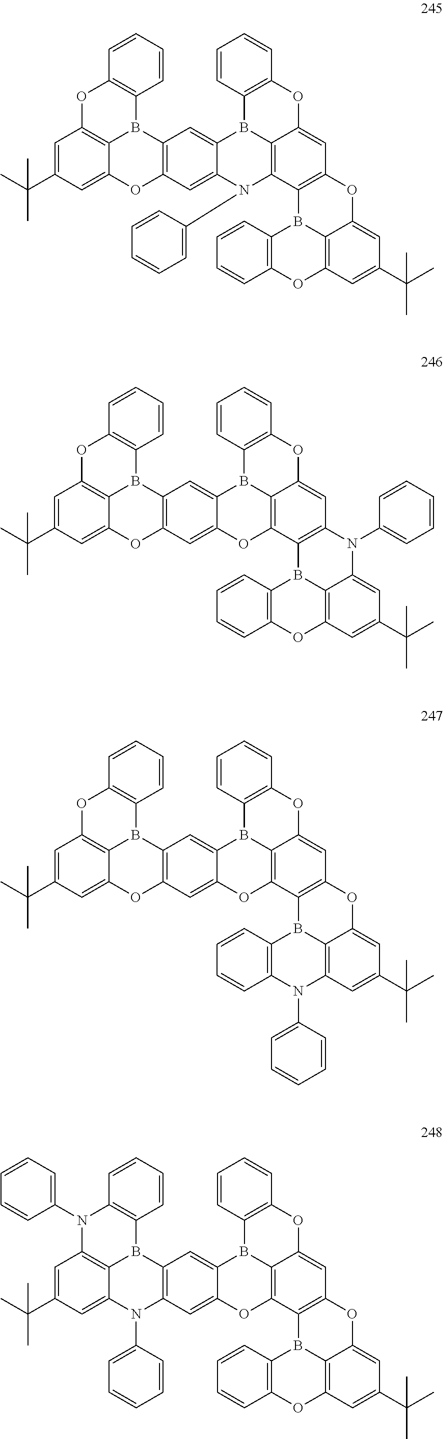 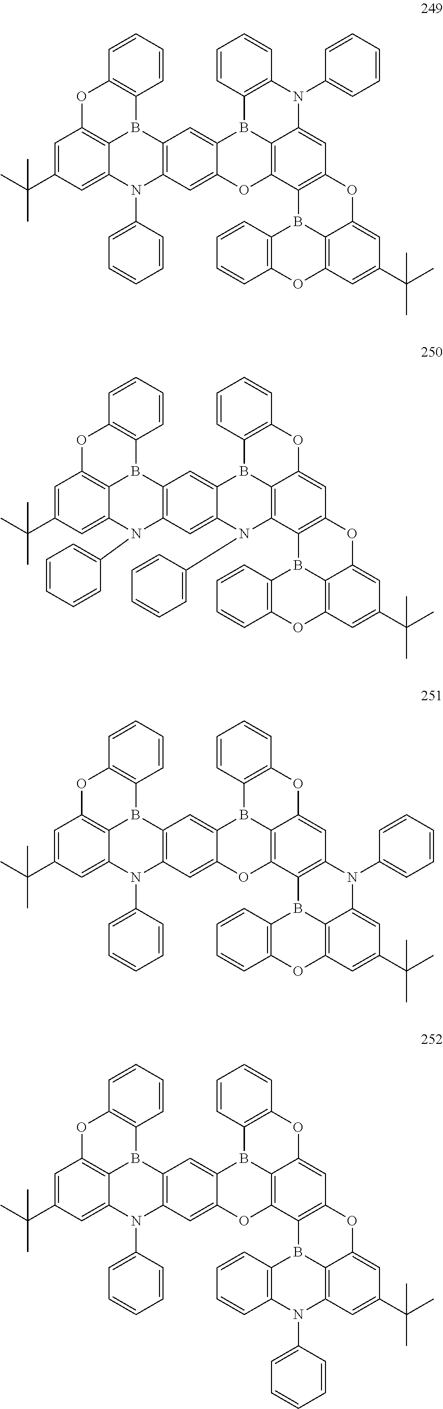 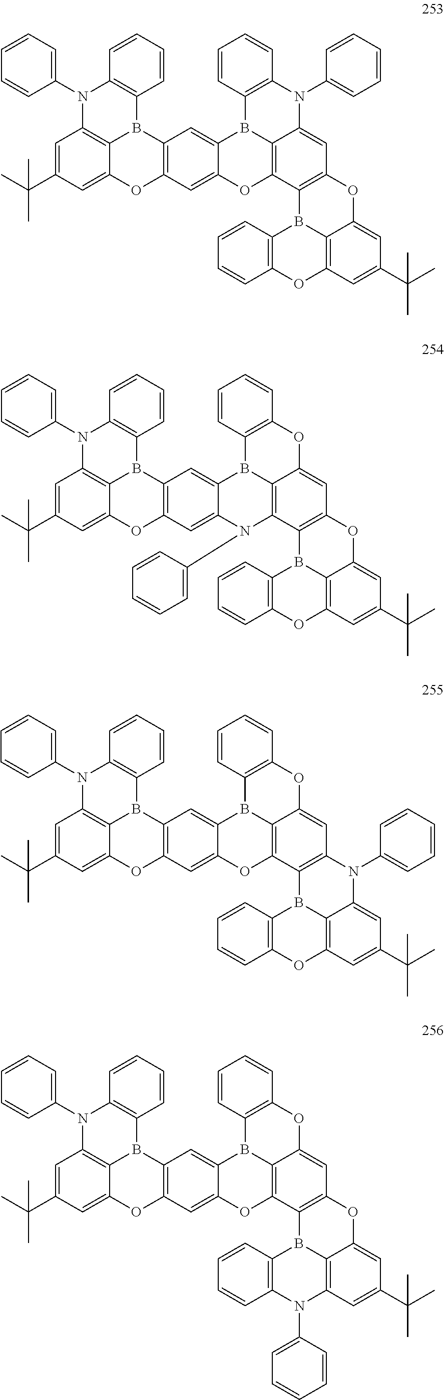 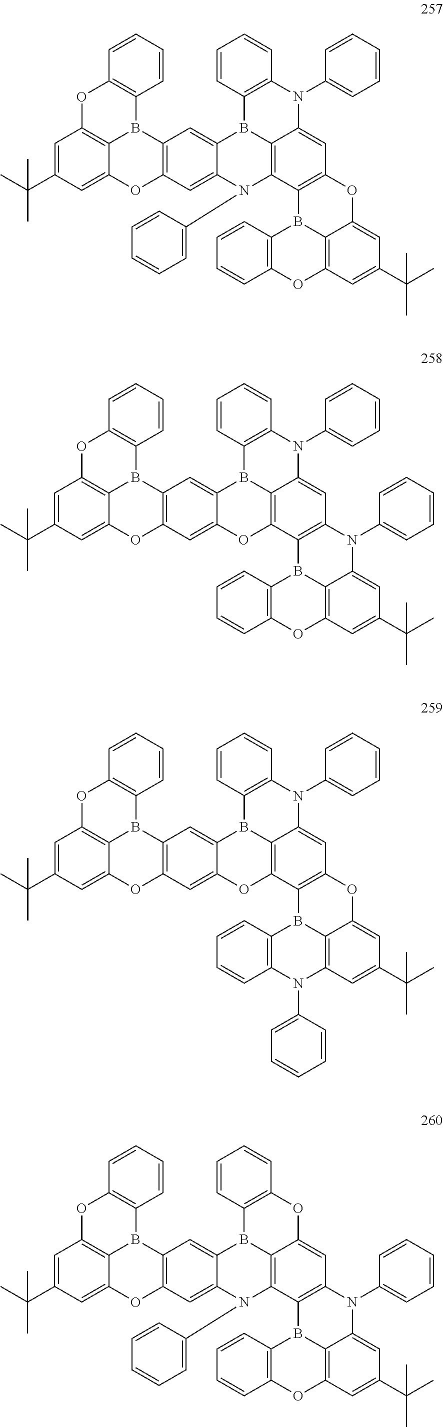 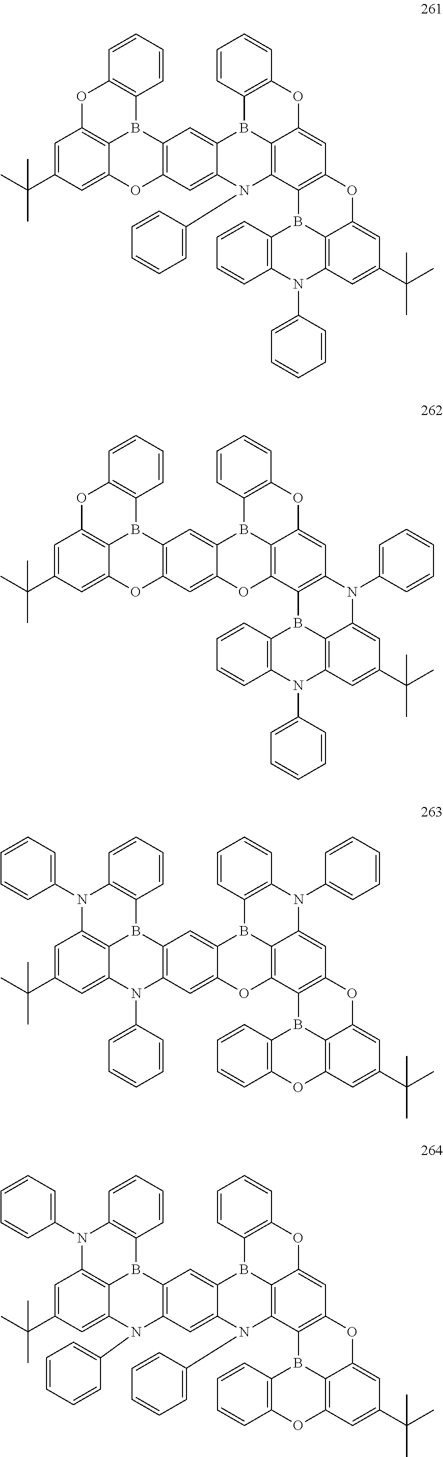 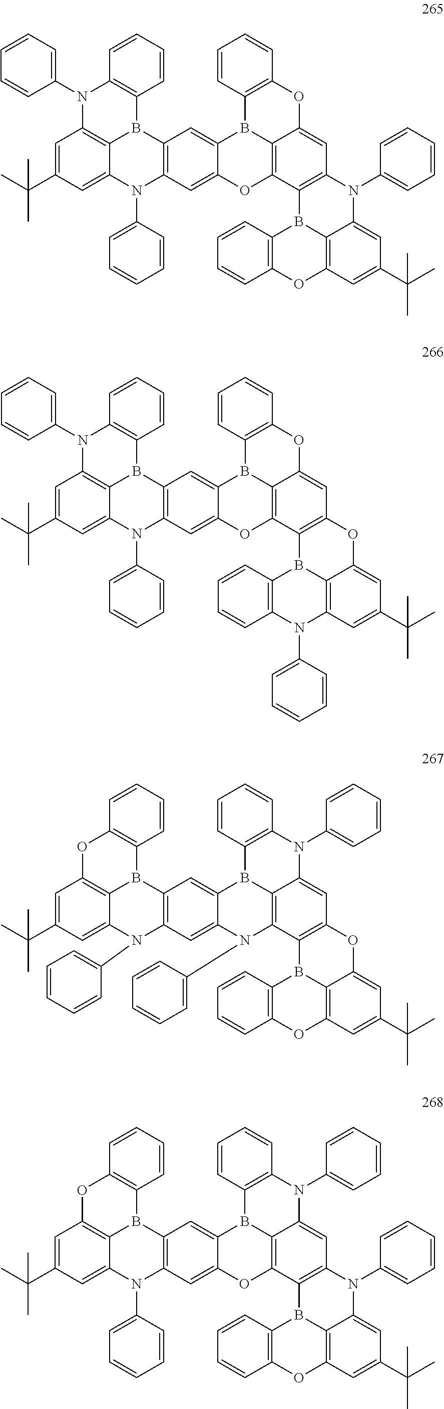 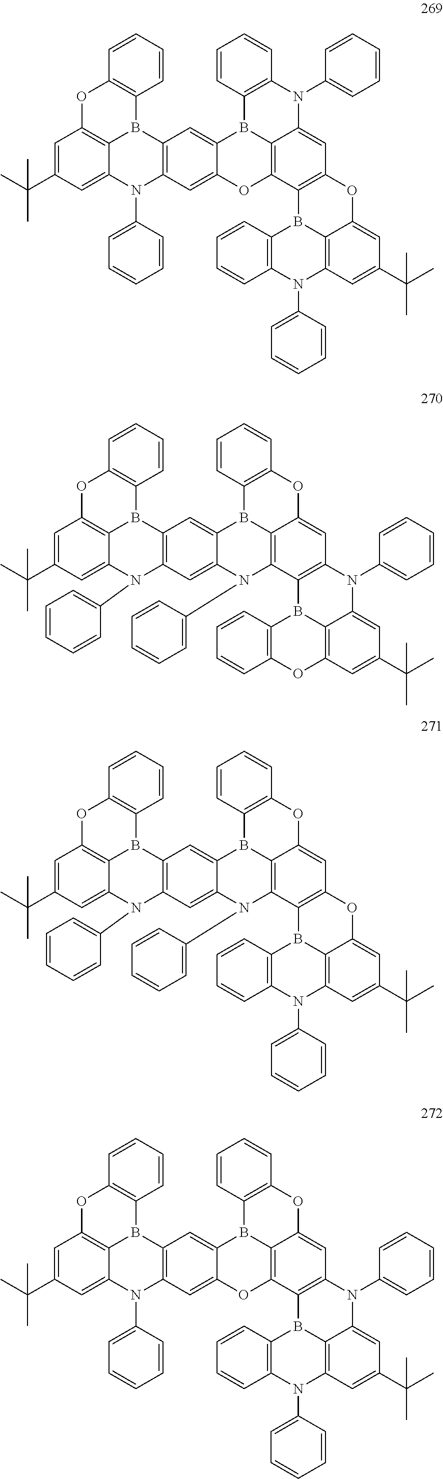 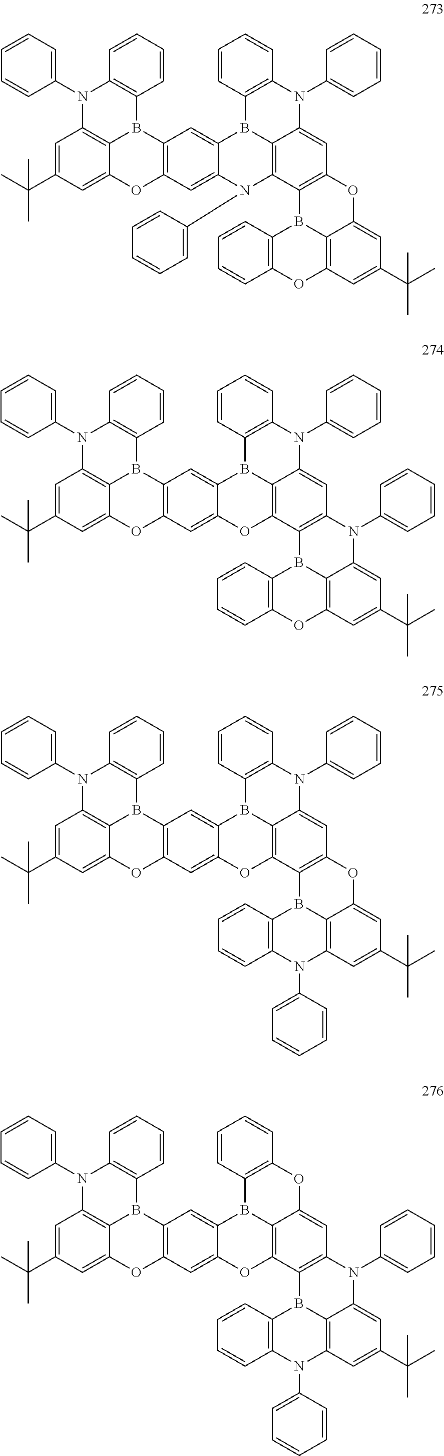 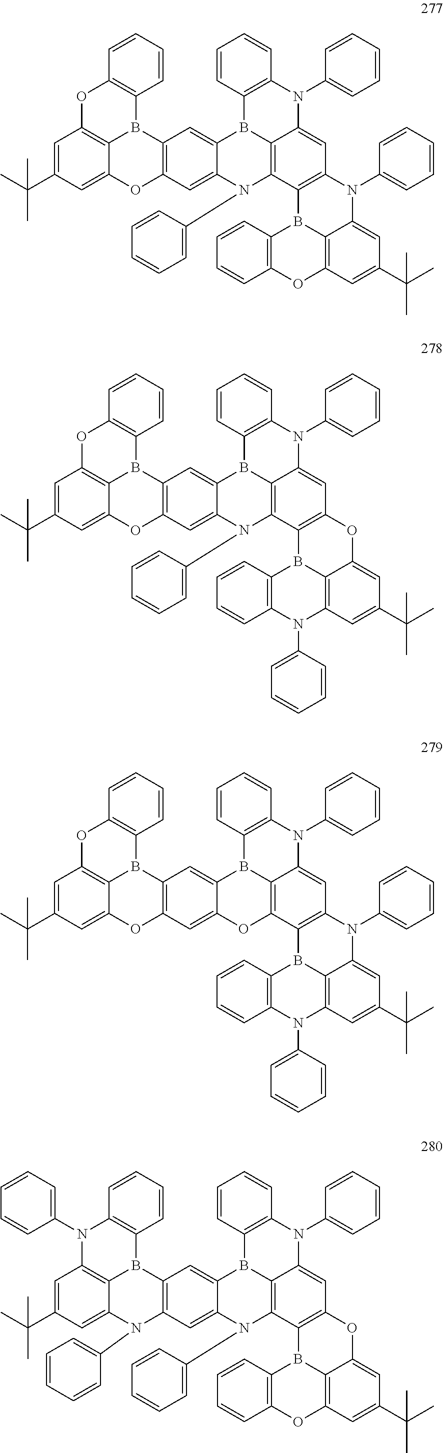 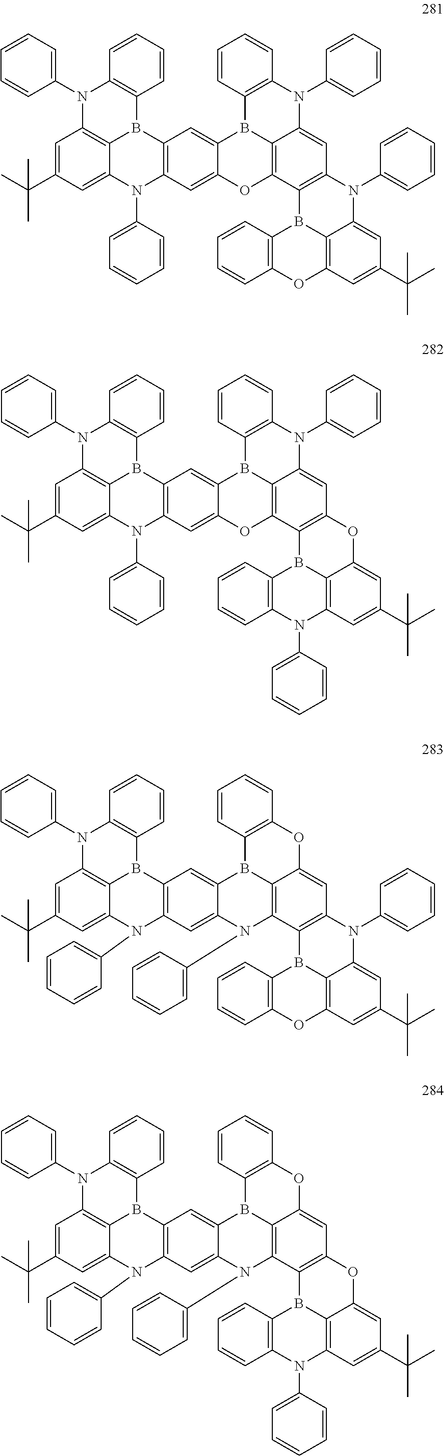 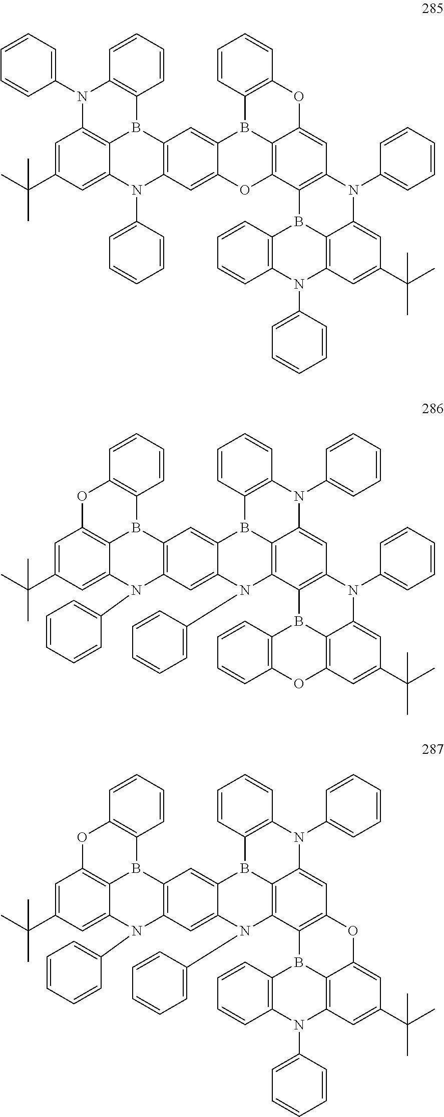 [SMILES: CC(C)(C)c1cc2c3c(c1)N(c1ccccc1)c1cc4c(cc1B3c1ccccc1N2c1ccccc1)B1c2ccccc2Oc2cc3c(c(c21)O4)B1c2ccccc2N(c2ccccc2)c2cc(C(C)(C)C)cc(c21)N3c1ccccc1 ; CC(C)(C)c1cc2c3c(c1)N(c1ccccc1)c1cc4c(cc1B3c1ccccc1O2)B1c2ccccc2N(c2ccccc2)c2cc3c(c(c21)N4c1ccccc1)B1c2ccccc2Oc2cc(C(C)(C)C)cc(c21)N3c1ccccc1 ; CC(C)(C)c1cc2c3c(c1)N(c1ccccc1)c1cc4c(cc1B3c1ccccc1O2)B1c2ccccc2N(c2ccccc2)c2cc3c(c(c21)N4c1ccccc1)B1c2ccccc2N(c2ccccc2)c2cc(C(C)(C)C)cc(c21)O3] 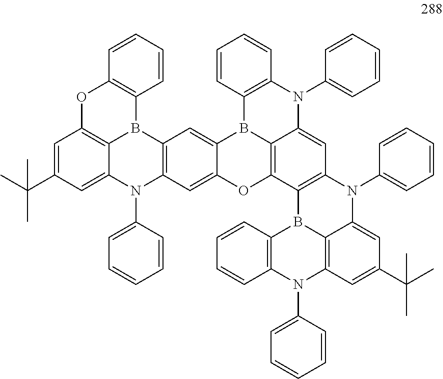 [SMILES: CC(C)(C)c1cc2c3c(c1)N(c1ccccc1)c1cc4c(cc1B3c1ccccc1O2)B1c2ccccc2N(c2ccccc2)c2cc3c(c(c21)O4)B1c2ccccc2N(c2ccccc2)c2cc(C(C)(C)C)cc(c21)N3c1ccccc1] 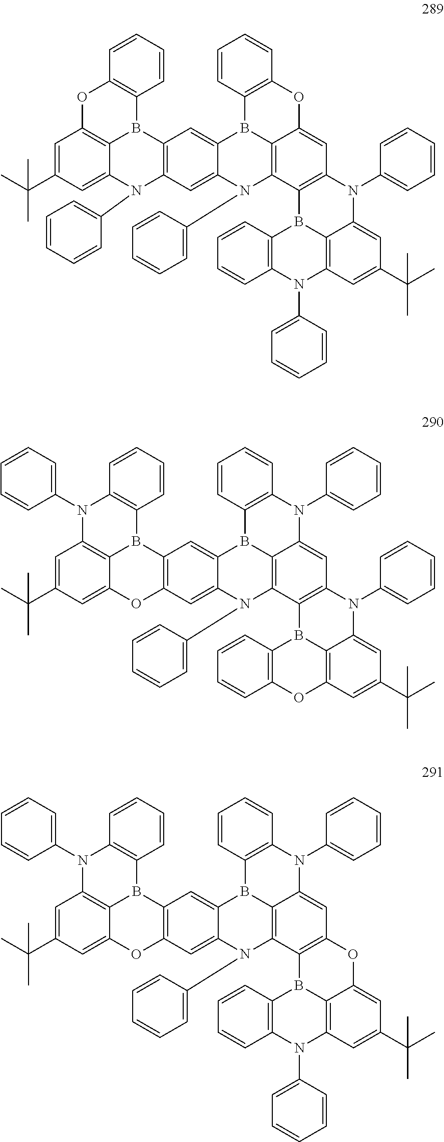 [SMILES: CC(C)(C)c1cc2c3c(c1)N(c1ccccc1)c1cc4c(cc1B3c1ccccc1O2)B1c2ccccc2Oc2cc3c(c(c21)N4c1ccccc1)B1c2ccccc2N(c2ccccc2)c2cc(C(C)(C)C)cc(c21)N3c1ccccc1 ; CC(C)(C)c1cc2c3c(c1)N(c1ccccc1)c1ccccc1B3c1cc3c(cc1O2)N(c1ccccc1)c1c2c(cc4c1B1c5ccccc5Oc5cc(C(C)(C)C)cc(c51)N4c1ccccc1)N(c1ccccc1)c1ccccc1B32 ; CC(C)(C)c1cc2c3c(c1)N(c1ccccc1)c1ccccc1B3c1cc3c(cc1O2)N(c1ccccc1)c1c2c(cc4c1B3c1ccccc1N4c1ccccc1)Oc1cc(C(C)(C)C)cc3c1B2c1ccccc1N3c1ccccc1] 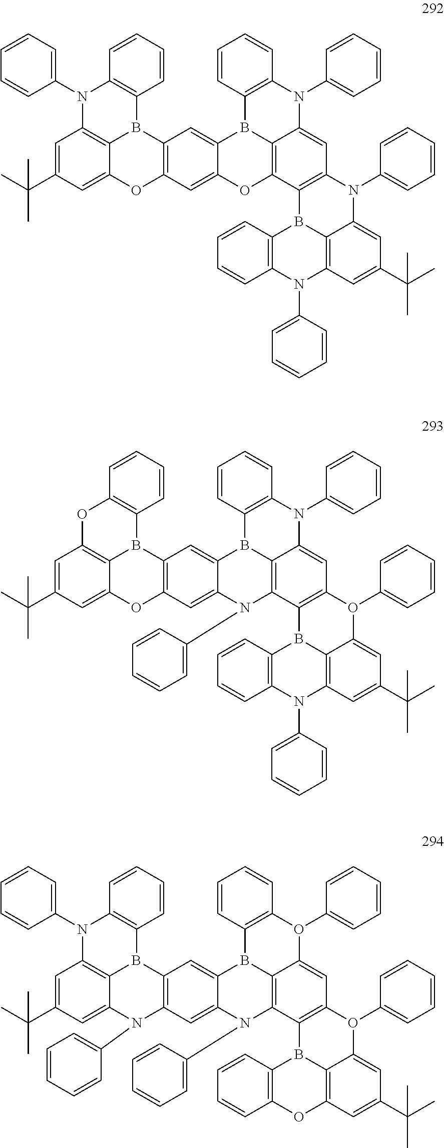 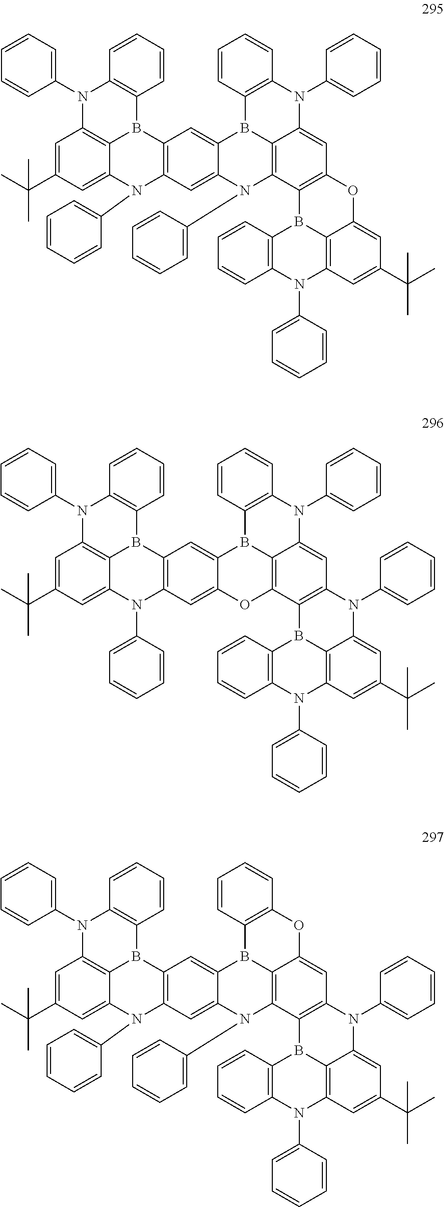 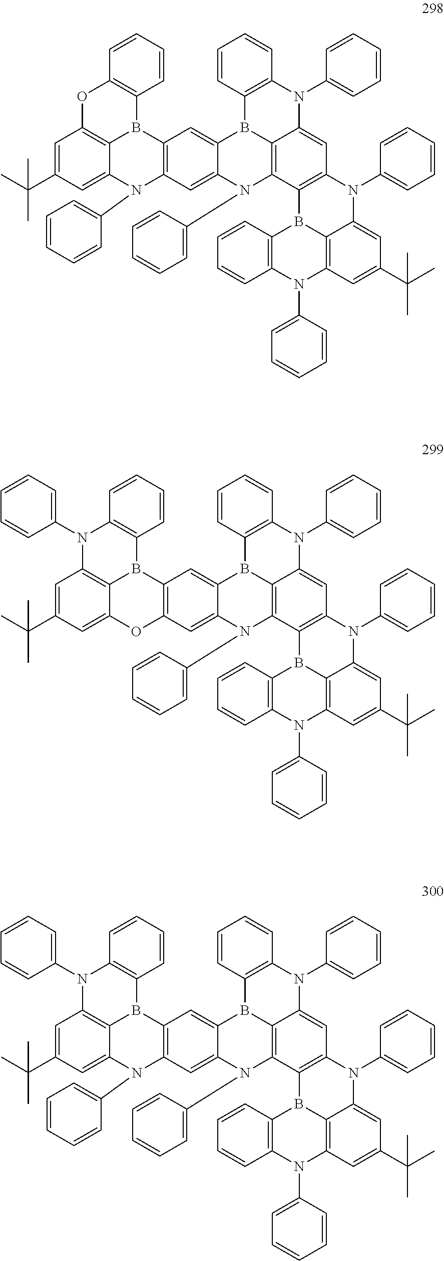 [SMILES: CC(C)(C)c1cc2c3c(c1)N(c1ccccc1)c1cc4c(cc1B3c1ccccc1O2)B1c2ccccc2N(c2ccccc2)c2cc3c(c(c21)N4c1ccccc1)B1c2ccccc2N(c2ccccc2)c2cc(C(C)(C)C)cc(c21)N3c1ccccc1 ; CC(C)(C)c1cc2c3c(c1)N(c1ccccc1)c1ccccc1B3c1cc3c(cc1O2)N(c1ccccc1)c1c2c(cc4c1B1c5ccccc5N(c5ccccc5)c5cc(C(C)(C)C)cc(c51)N4c1ccccc1)N(c1ccccc1)c1ccccc1B32 ; CC(C)(C)c1cc2c3c(c1)N(c1ccccc1)c1cc4c(cc1B3c1ccccc1N2c1ccccc1)B1c2ccccc2N(c2ccccc2)c2cc3c(c(c21)N4c1ccccc1)B1c2ccccc2N(c2ccccc2)c2cc(C(C)(C)C)cc(c21)N3c1ccccc1] 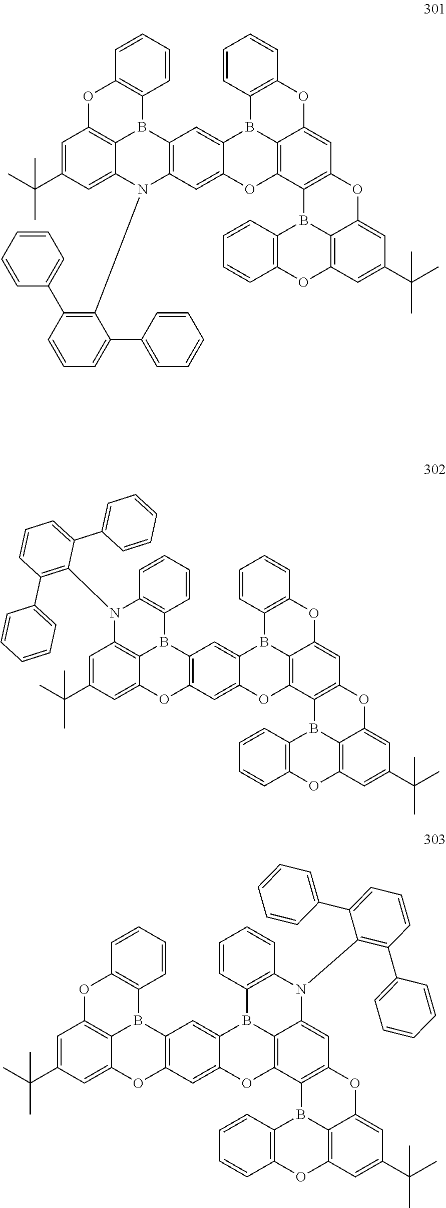 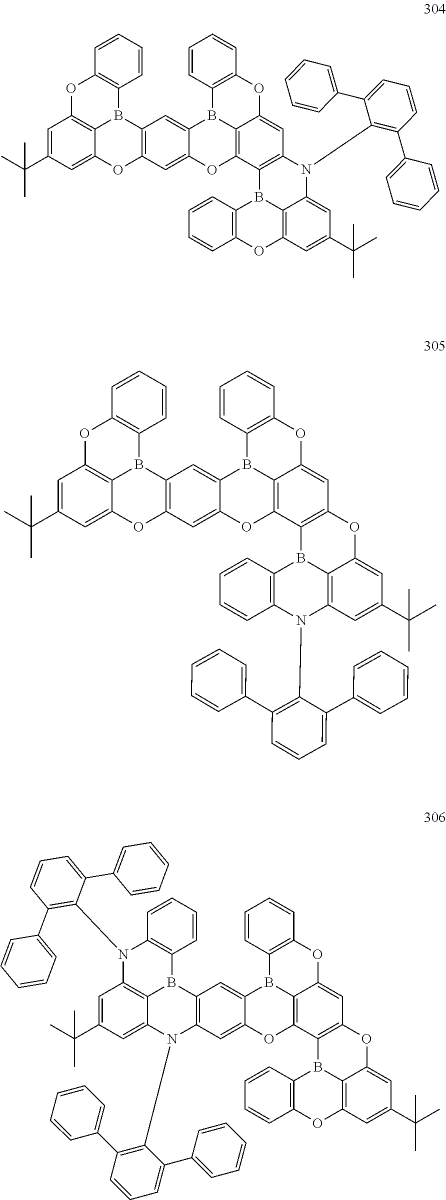 [SMILES: CC(C)(C)c1cc2c3c(c1)Oc1cc4c(cc1B3c1ccccc1O2)B1c2ccccc2Oc2cc3c(c(c21)O4)B1c2ccccc2Oc2cc(C(C)(C)C)cc(c21)N3c1c(-c2ccccc2)cccc1-c1ccccc1 ; CC(C)(C)c1cc2c3c(c1)Oc1cc4c(cc1B3c1ccccc1O2)B1c2ccccc2Oc2cc3c(c(c21)O4)B1c2ccccc2N(c2c(-c4ccccc4)cccc2-c2ccccc2)c2cc(C(C)(C)C)cc(c21)O3 ; CC(C)(C)c1cc2c3c(c1)Oc1cc4c5c(c1B3c1ccccc1O2)Oc1cc2c(cc1B5c1ccccc1O4)B1c3ccccc3N(c3c(-c4ccccc4)cccc3-c3ccccc3)c3cc(C(C)(C)C)cc(c31)N2c1c(-c2ccccc2)cccc1-c1ccccc1] 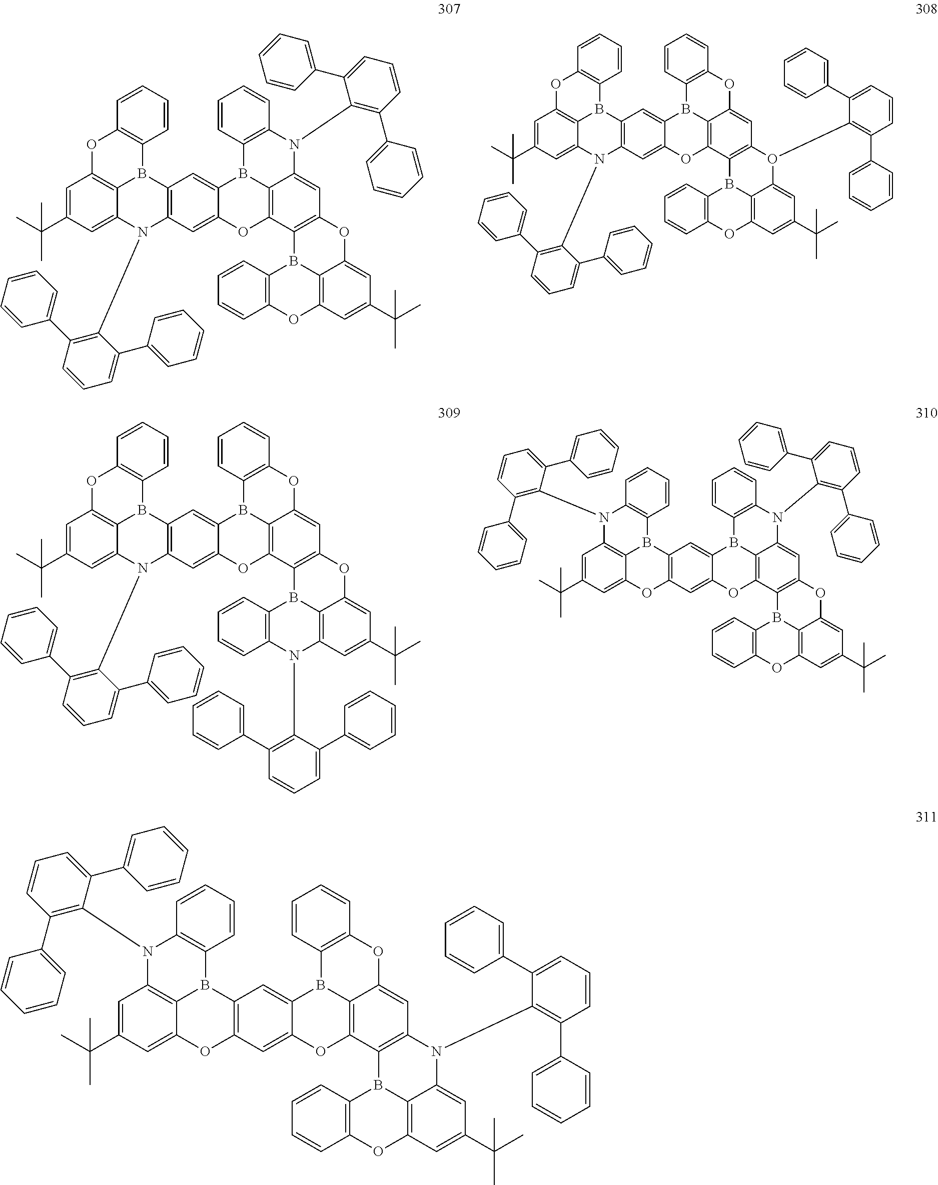 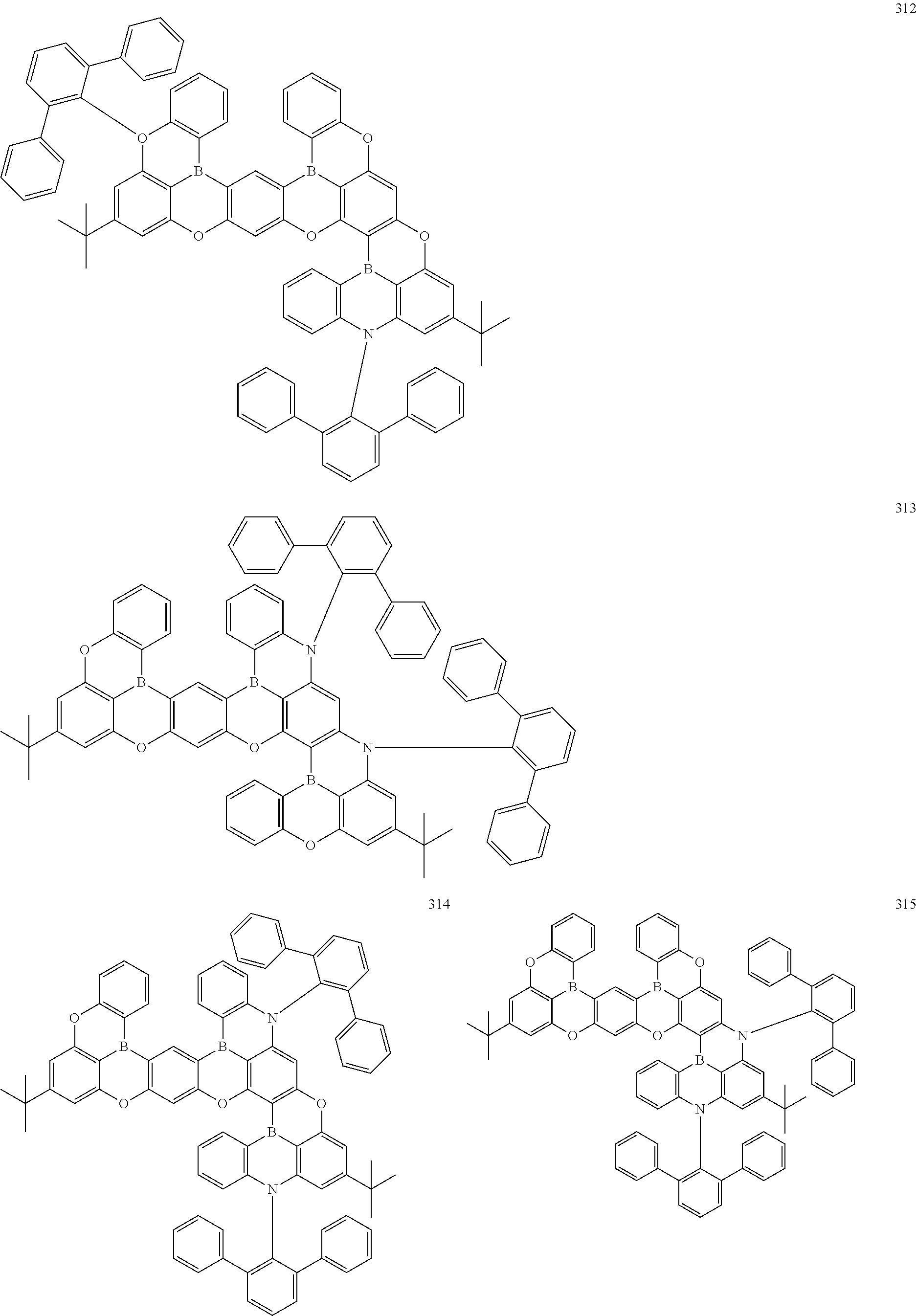 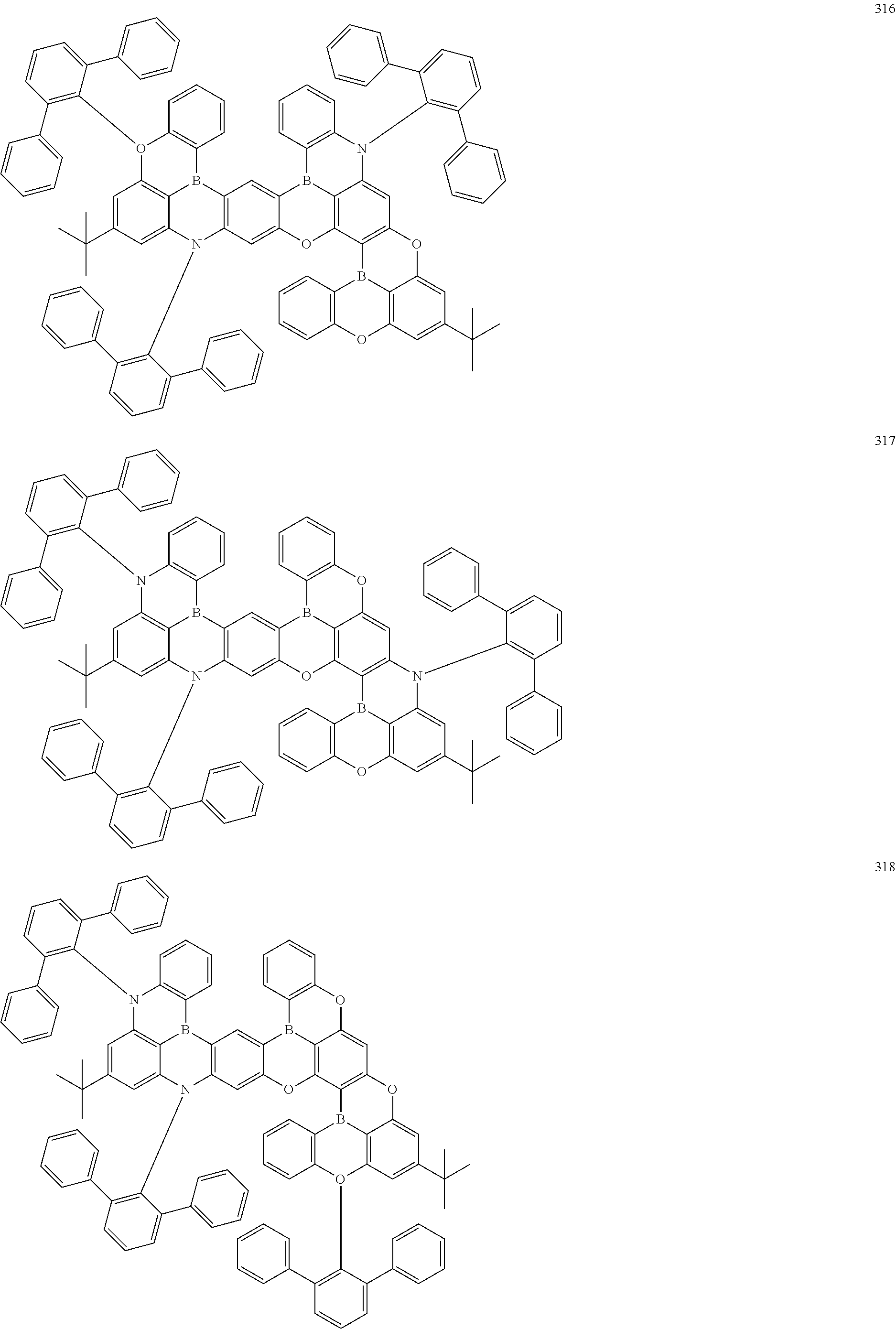 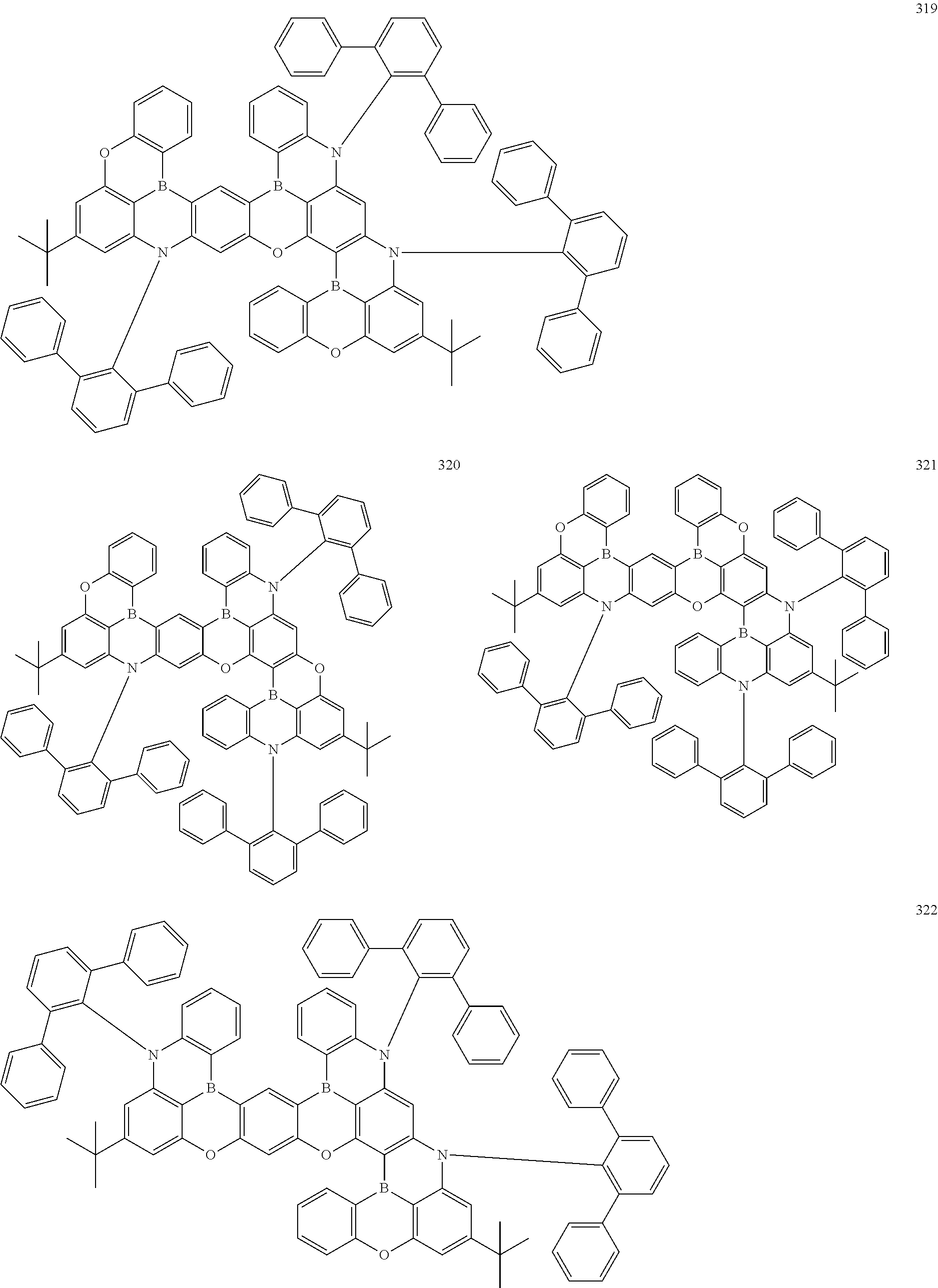 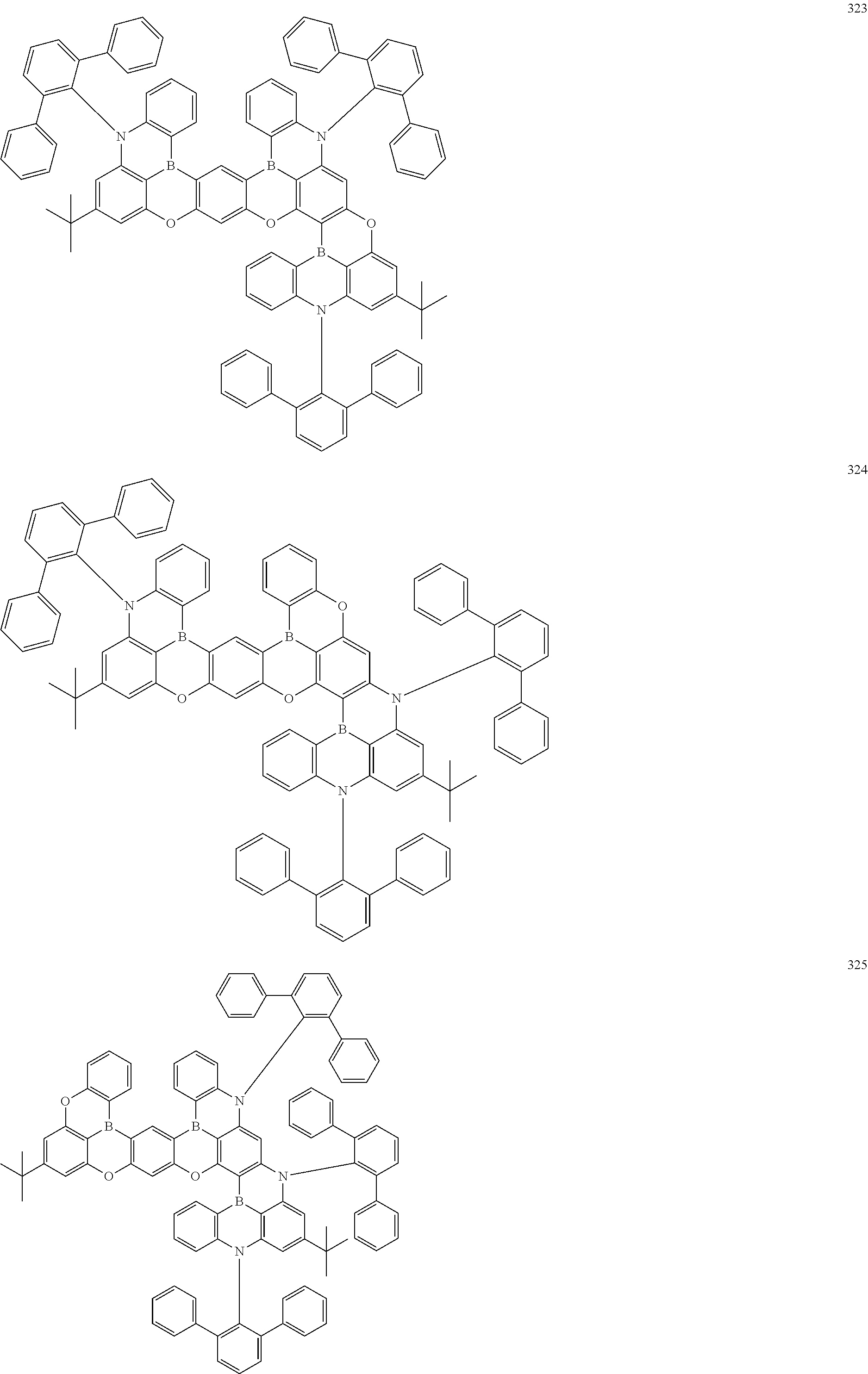 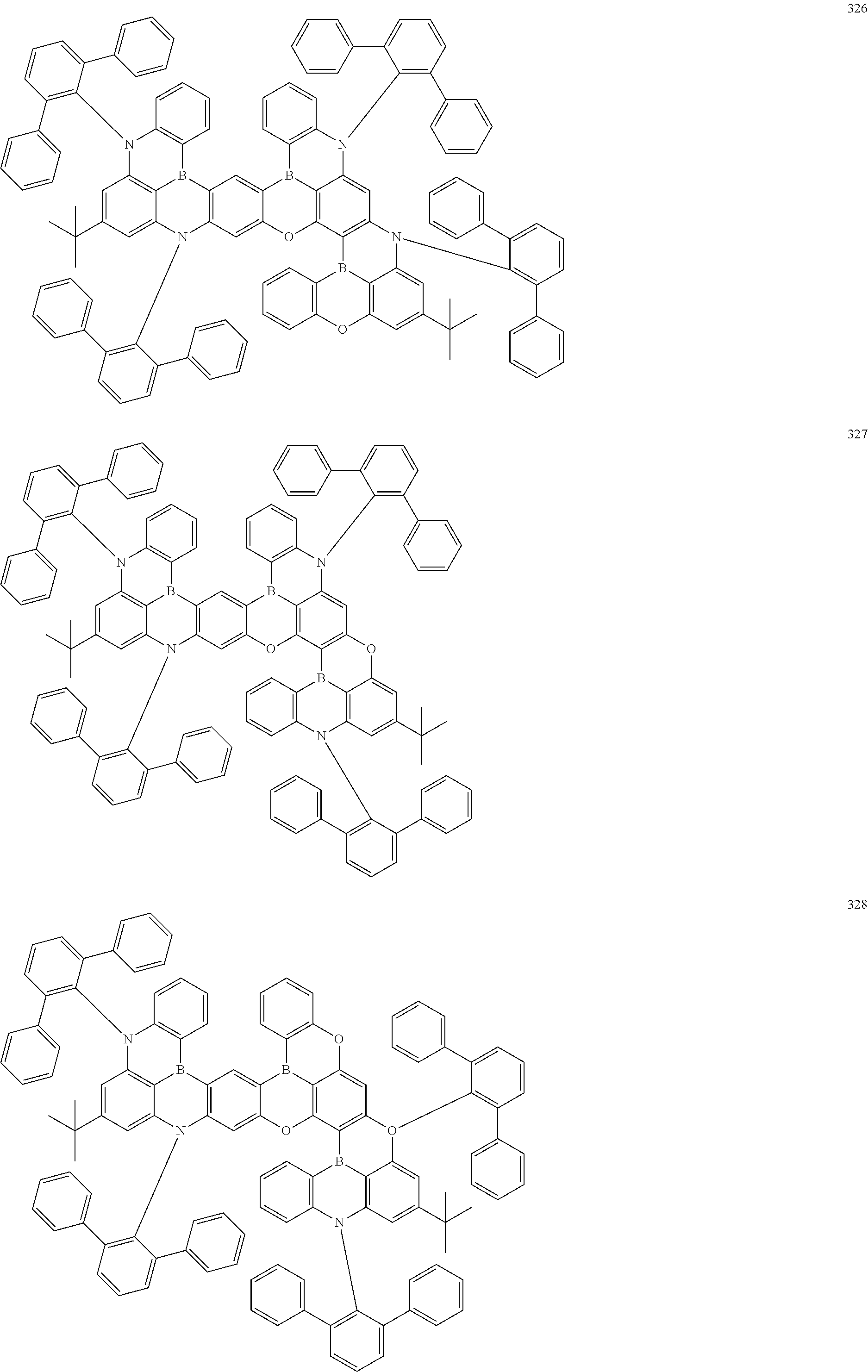 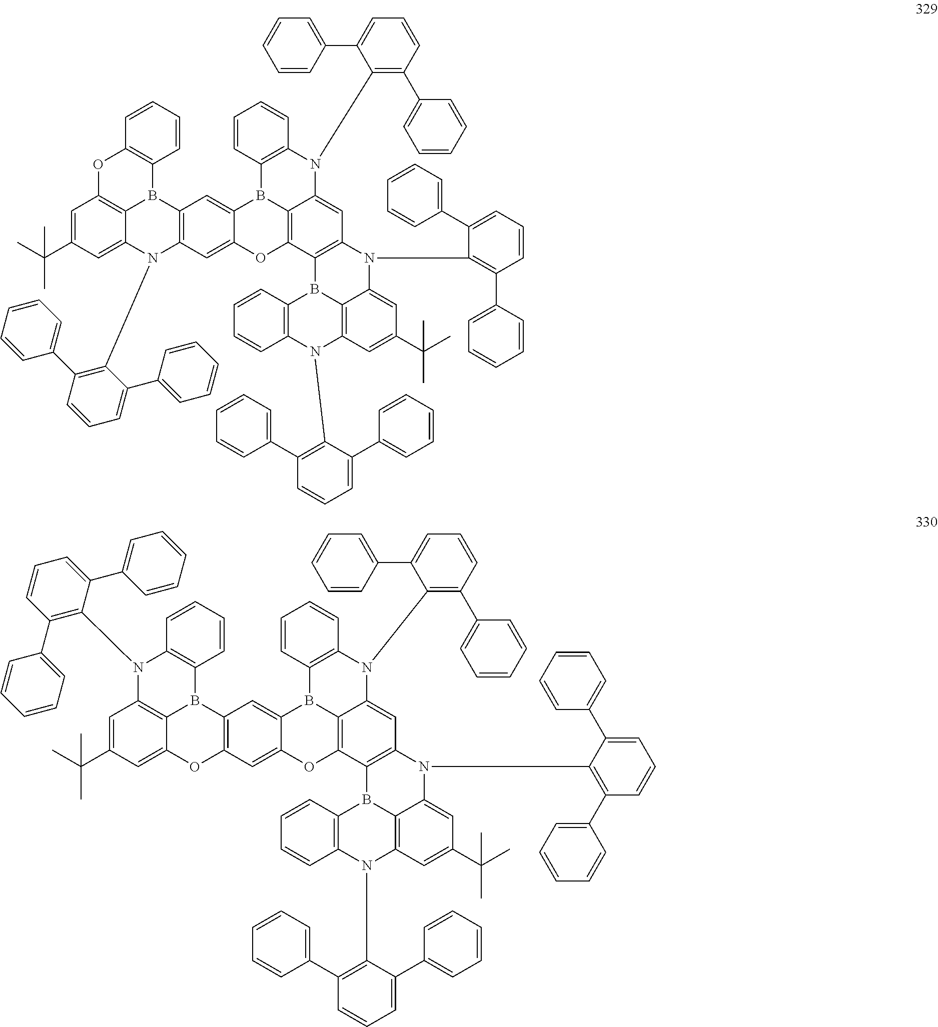 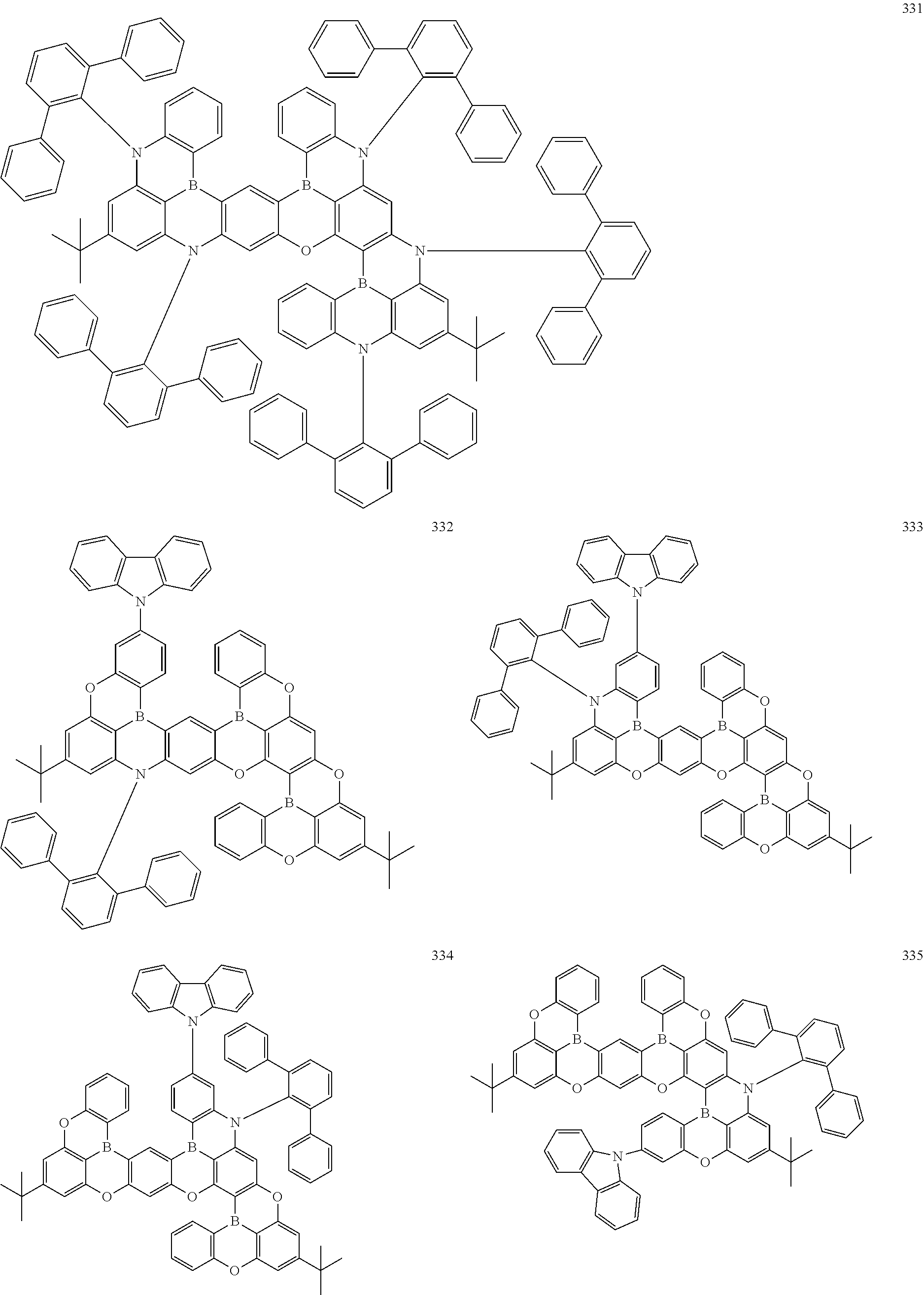 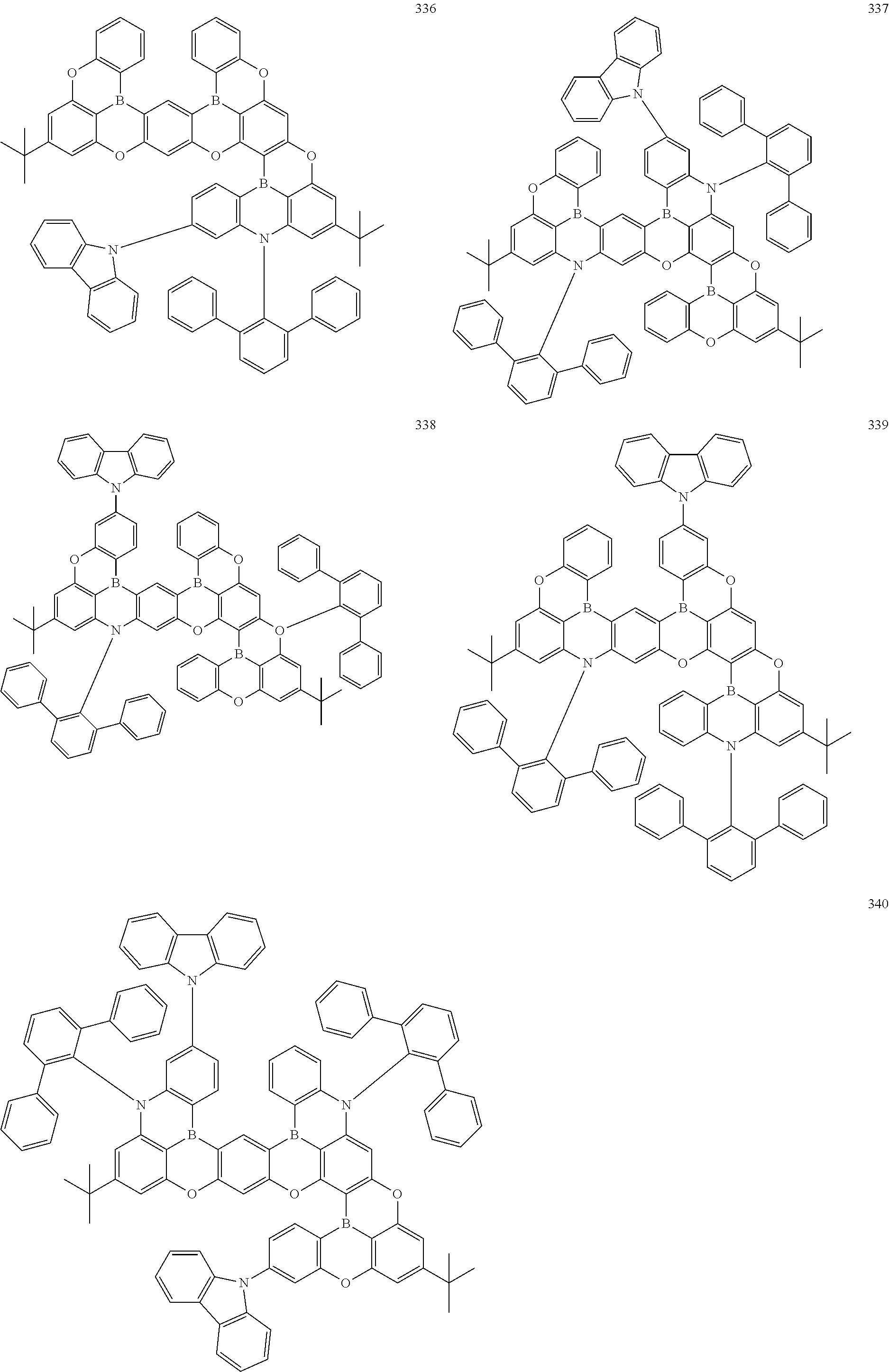 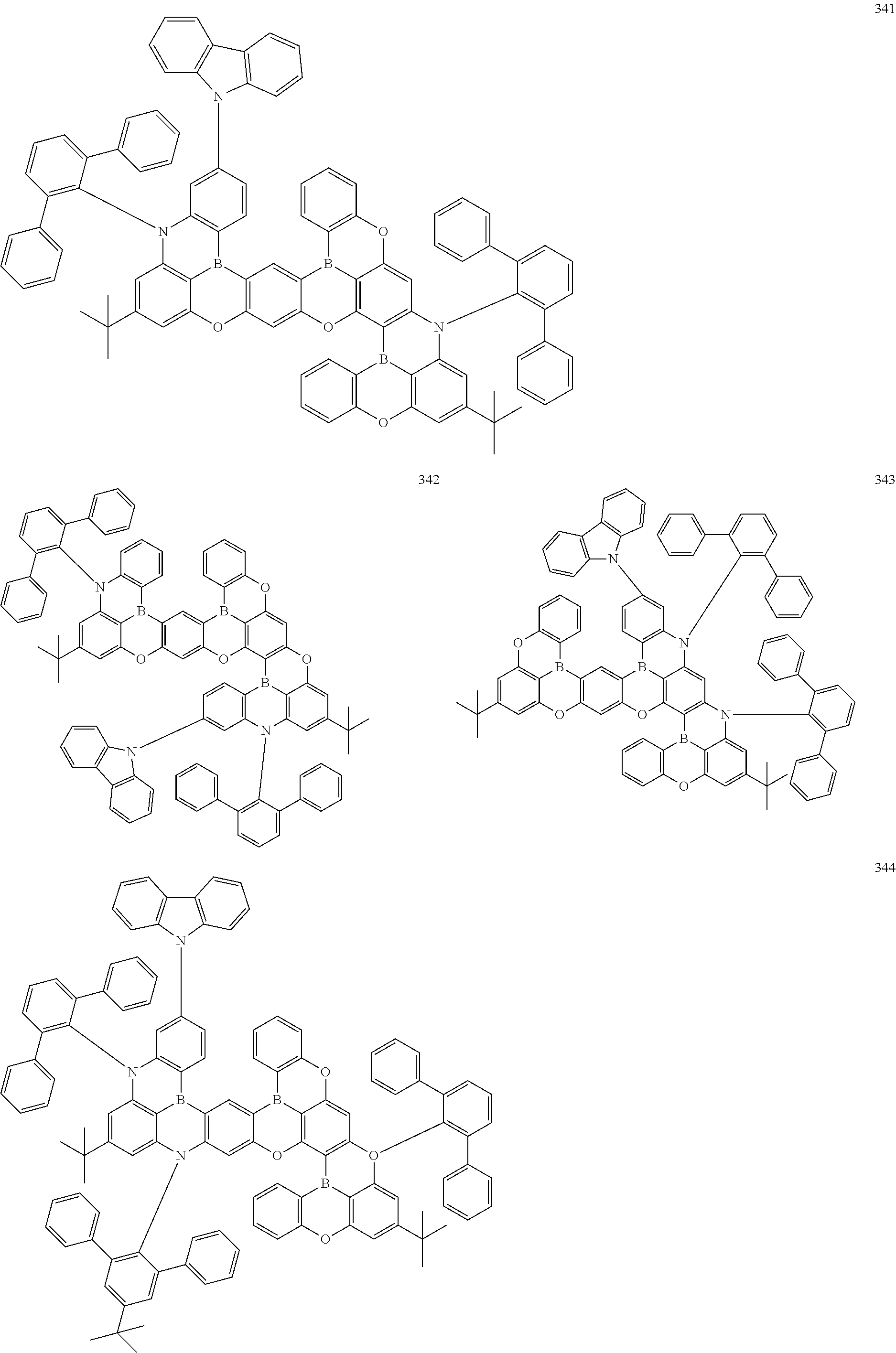 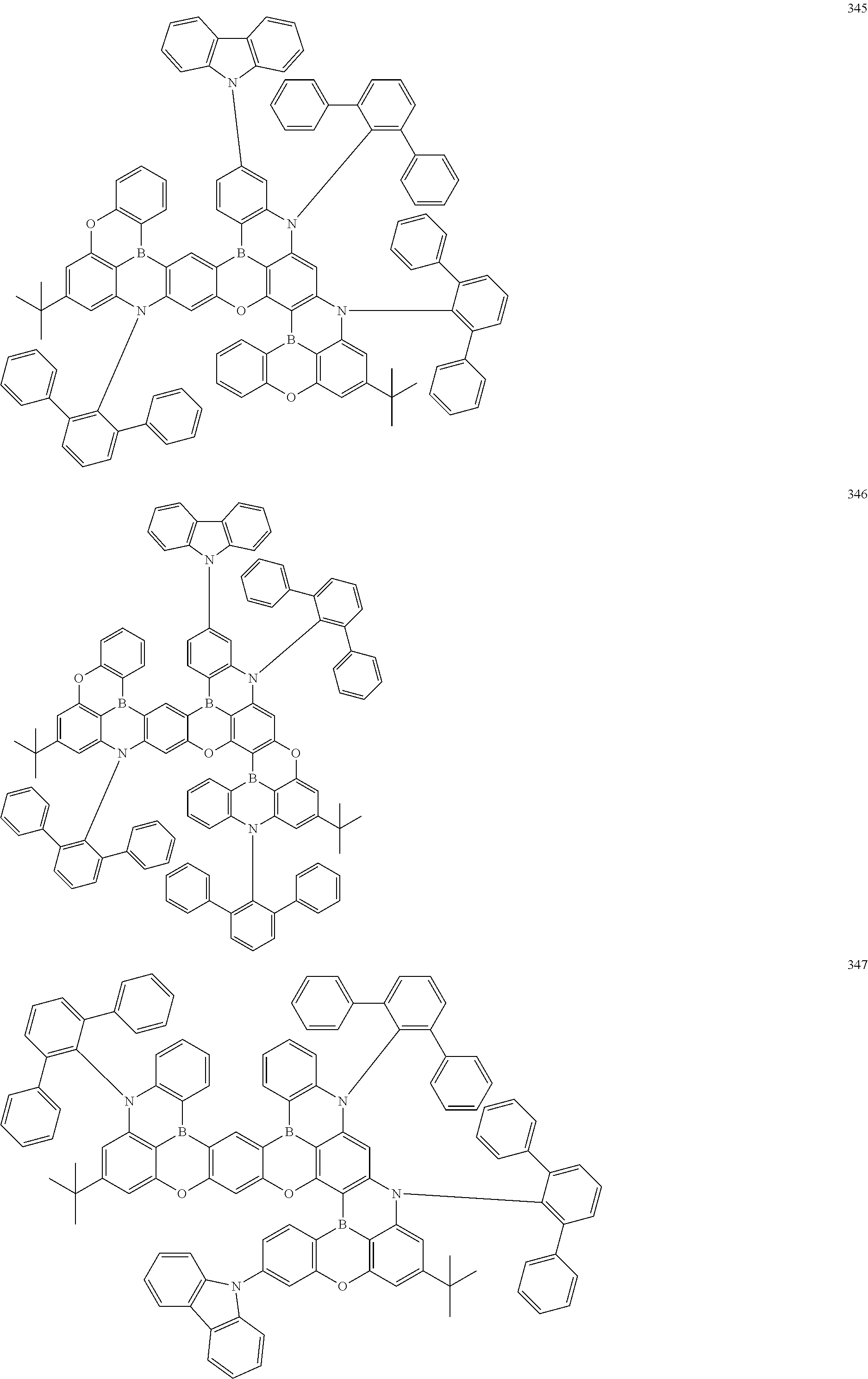 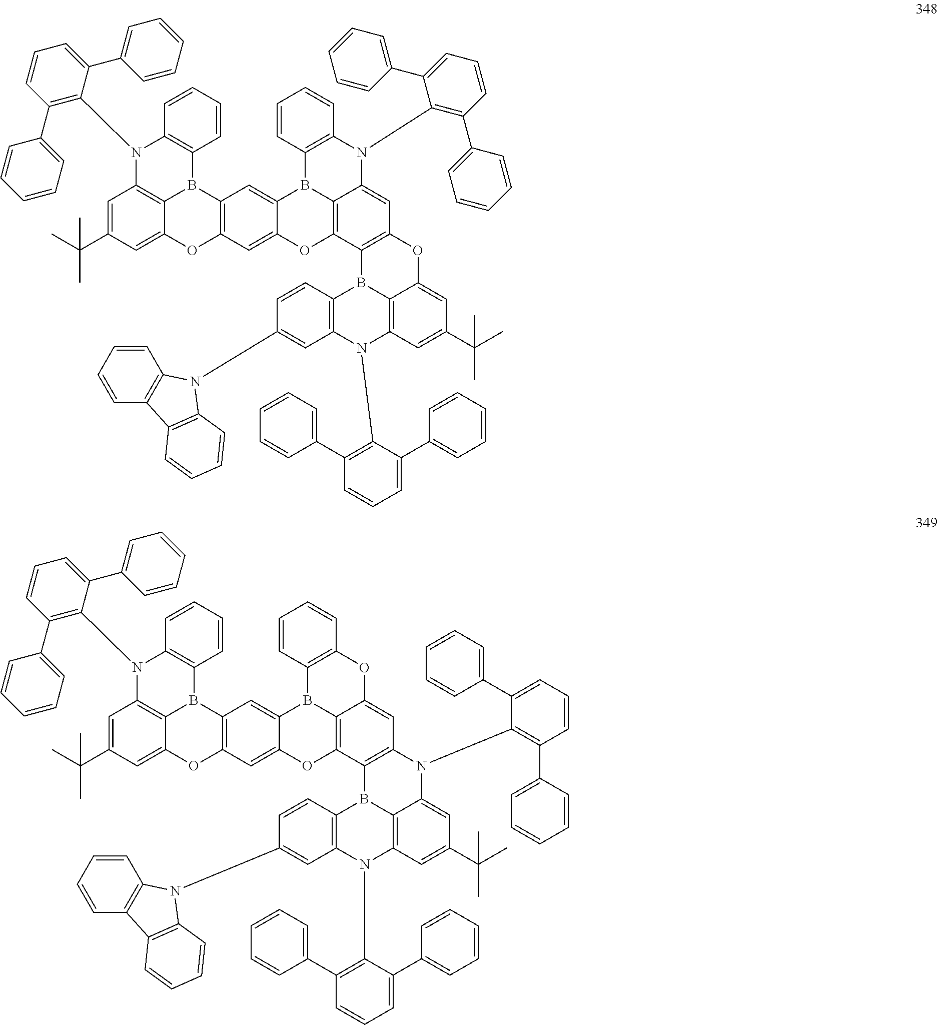 [SMILES: CC(C)(C)c1cc2c3c(c1)N(c1c(-c4ccccc4)cccc1-c1ccccc1)c1ccccc1B3c1cc3c(cc1O2)Oc1c2c(cc4c1B3c1ccccc1N4c1c(-c3ccccc3)cccc1-c1ccccc1)Oc1cc(C(C)(C)C)cc3c1B2c1ccc(-n2c4ccccc4c4ccccc42)cc1N3c1c(-c2ccccc2)cccc1-c1ccccc1 ; CC(C)(C)c1cc2c3c(c1)N(c1c(-c4ccccc4)cccc1-c1ccccc1)c1ccccc1B3c1cc3c(cc1O2)Oc1c2c(cc4c1B1c5ccc(-n6c7ccccc7c7ccccc76)cc5N(c5c(-c6ccccc6)cccc5-c5ccccc5)c5cc(C(C)(C)C)cc(c51)N4c1c(-c4ccccc4)cccc1-c1ccccc1)Oc1ccccc1B32] 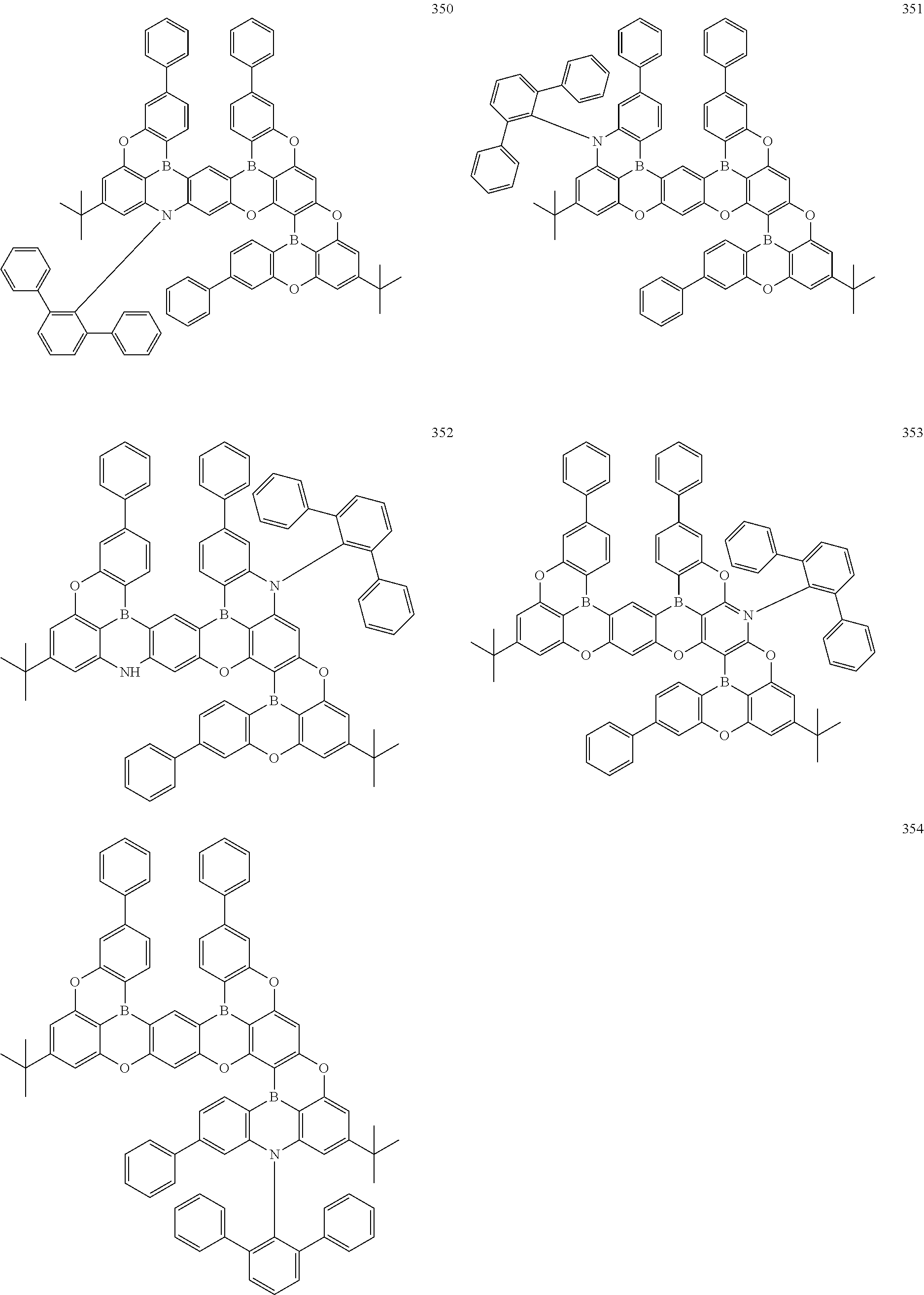 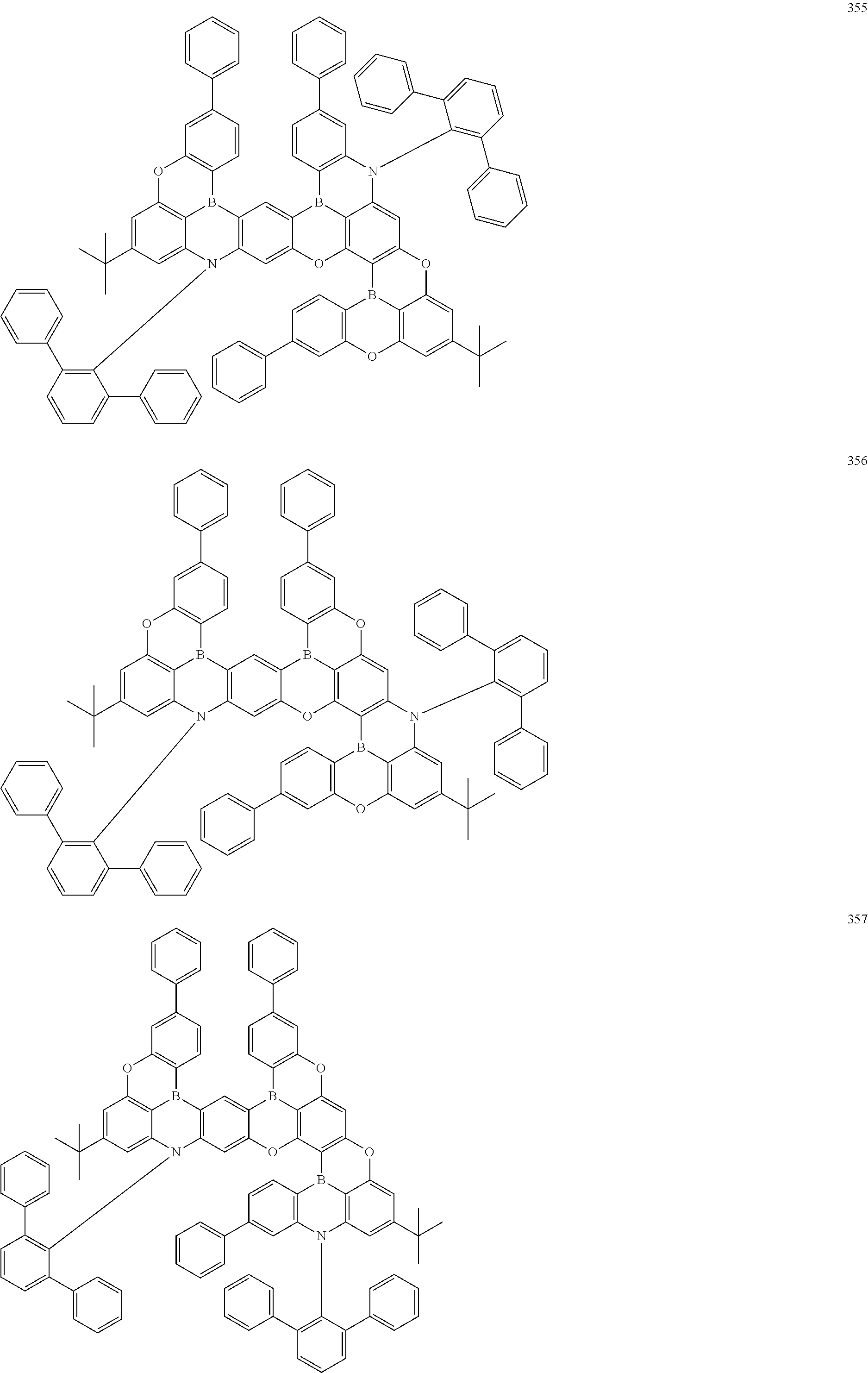 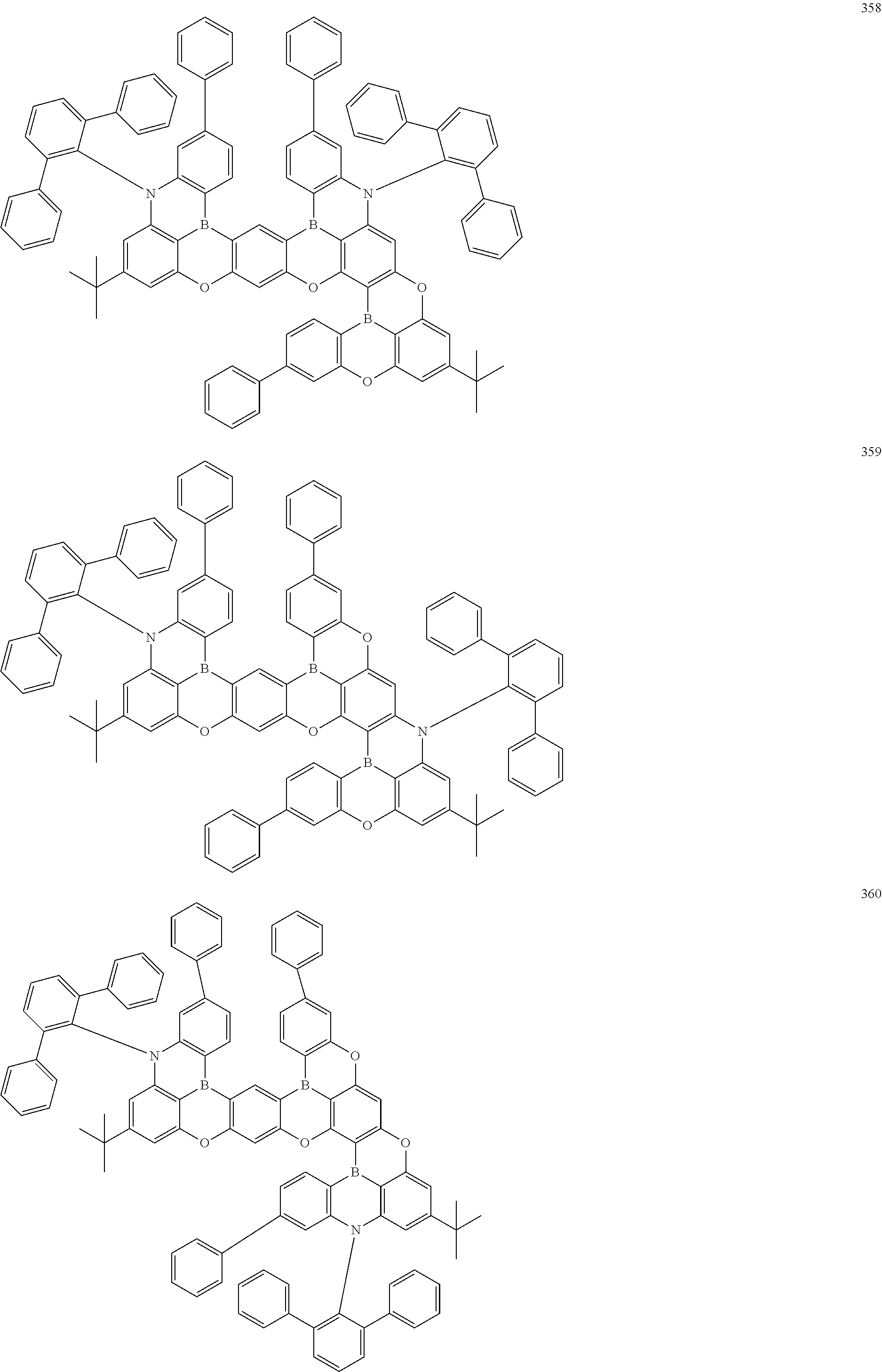 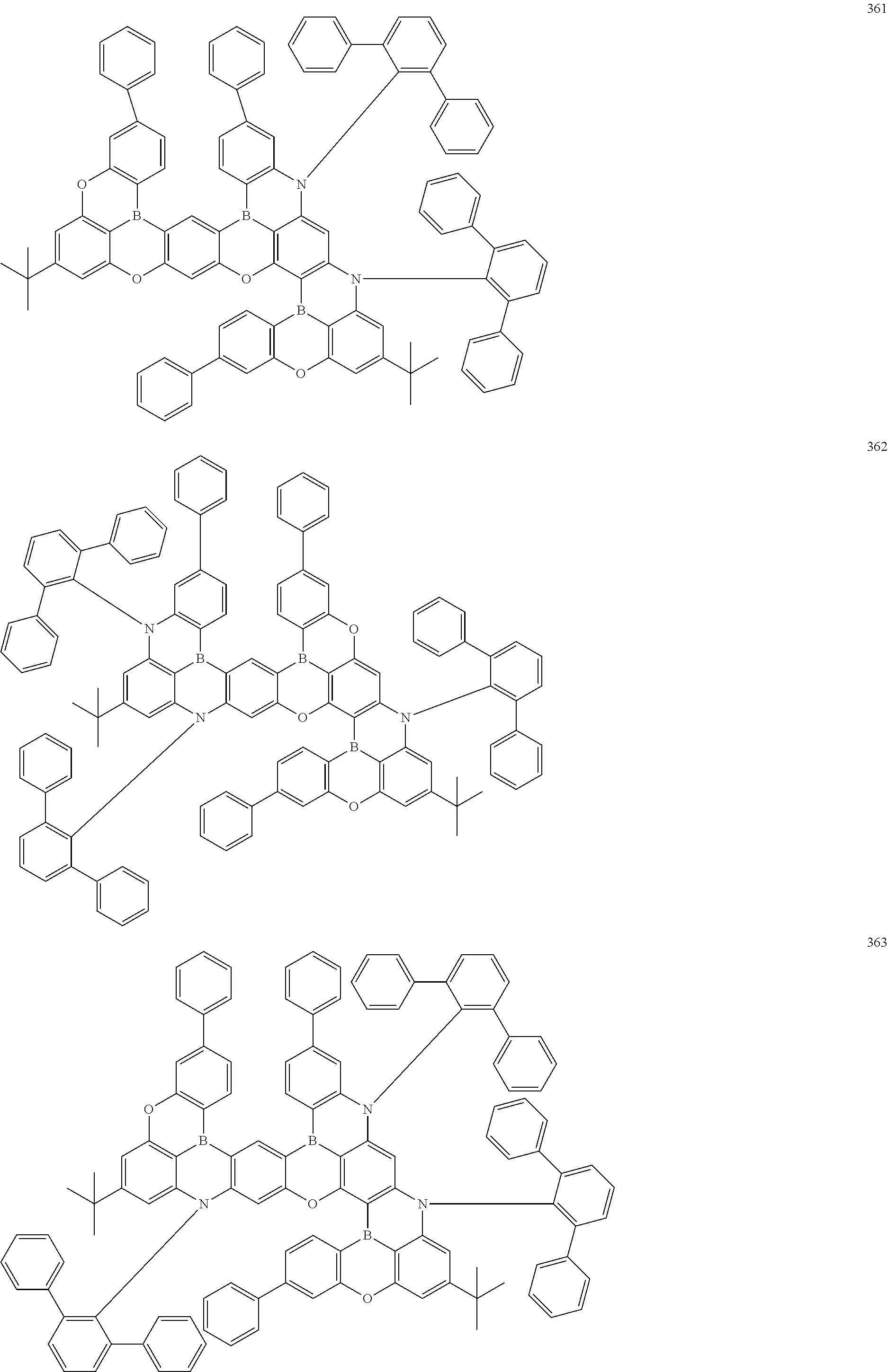 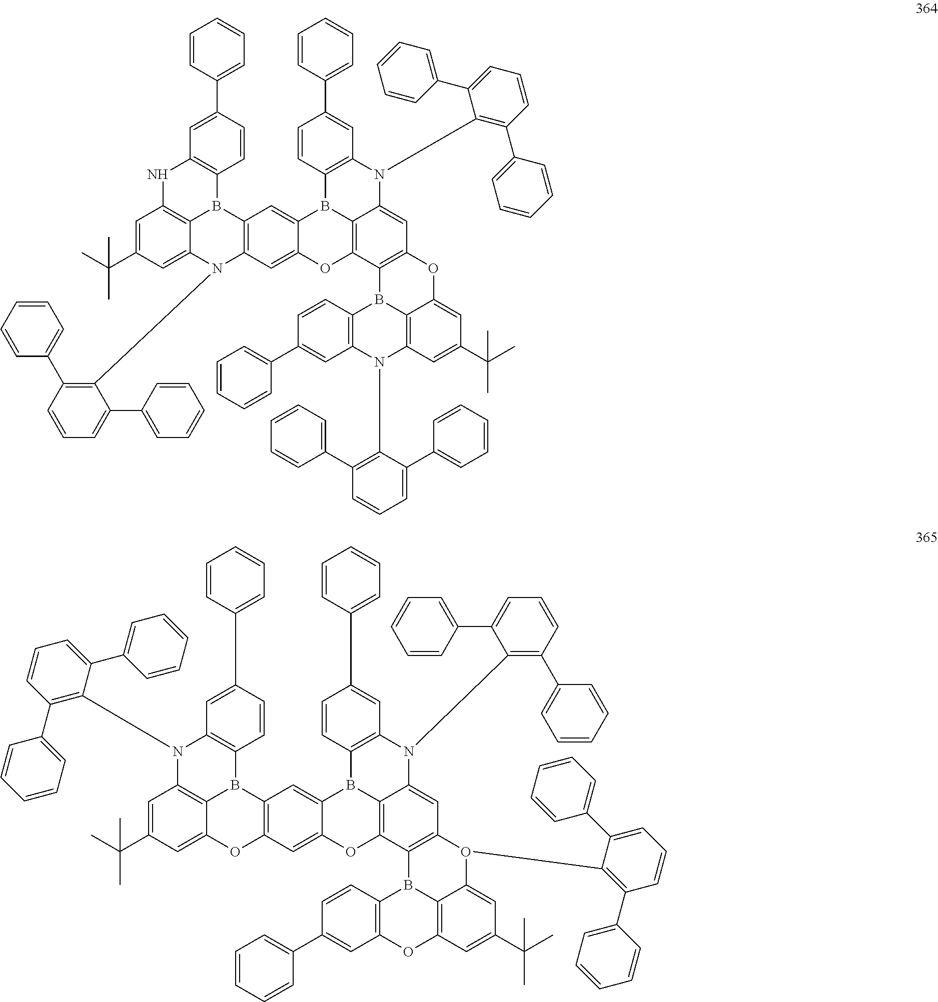 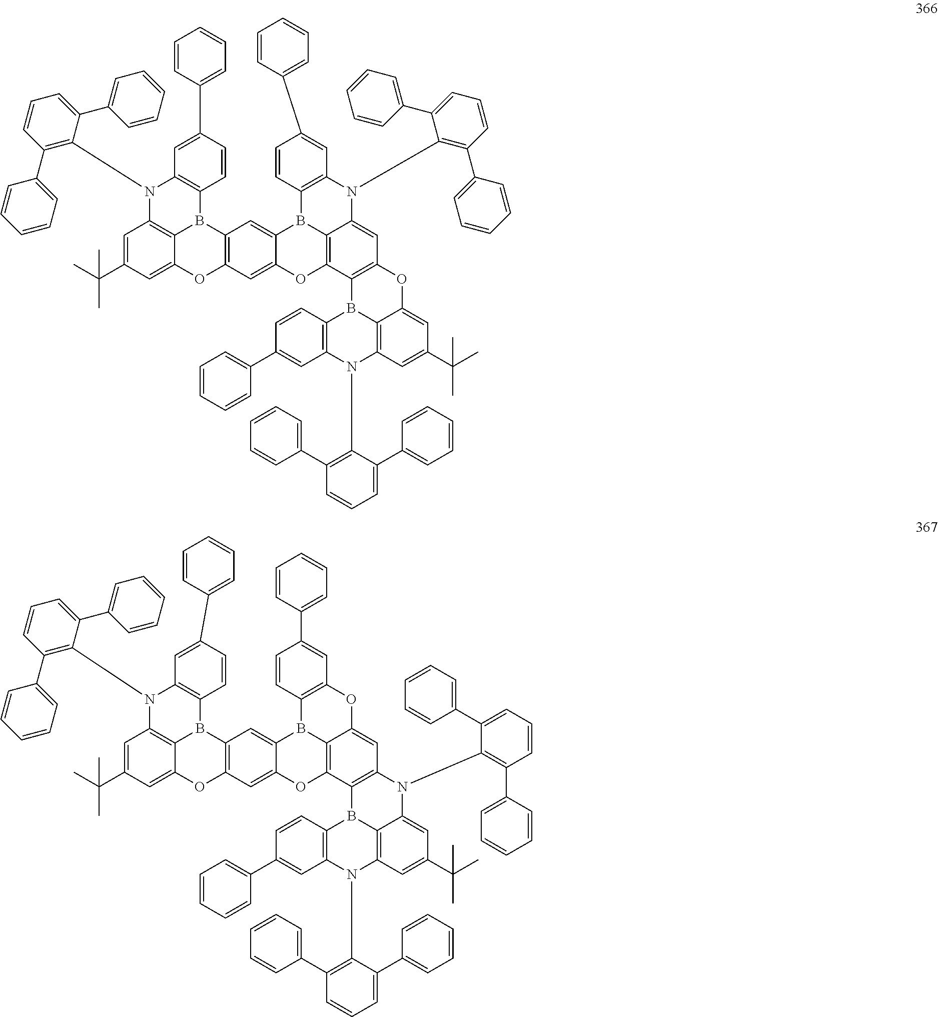 [SMILES: CC(C)(C)c1cc2c3c(c1)N(c1c(-c4ccccc4)cccc1-c1ccccc1)c1cc(-c4ccccc4)ccc1B3c1cc3c(cc1O2)Oc1c2c(cc4c1B3c1ccc(-c3ccccc3)cc1N4c1c(-c3ccccc3)cccc1-c1ccccc1)Oc1cc(C(C)(C)C)cc3c1B2c1ccc(-c2ccccc2)cc1N3c1c(-c2ccccc2)cccc1-c1ccccc1 ; CC(C)(C)c1cc2c3c(c1)N(c1c(-c4ccccc4)cccc1-c1ccccc1)c1cc(-c4ccccc4)ccc1B3c1cc3c(cc1O2)Oc1c2c(cc4c1B1c5ccc(-c6ccccc6)cc5N(c5c(-c6ccccc6)cccc5-c5ccccc5)c5cc(C(C)(C)C)cc(c51)N4c1c(-c4ccccc4)cccc1-c1ccccc1)Oc1cc(-c4ccccc4)ccc1B32] 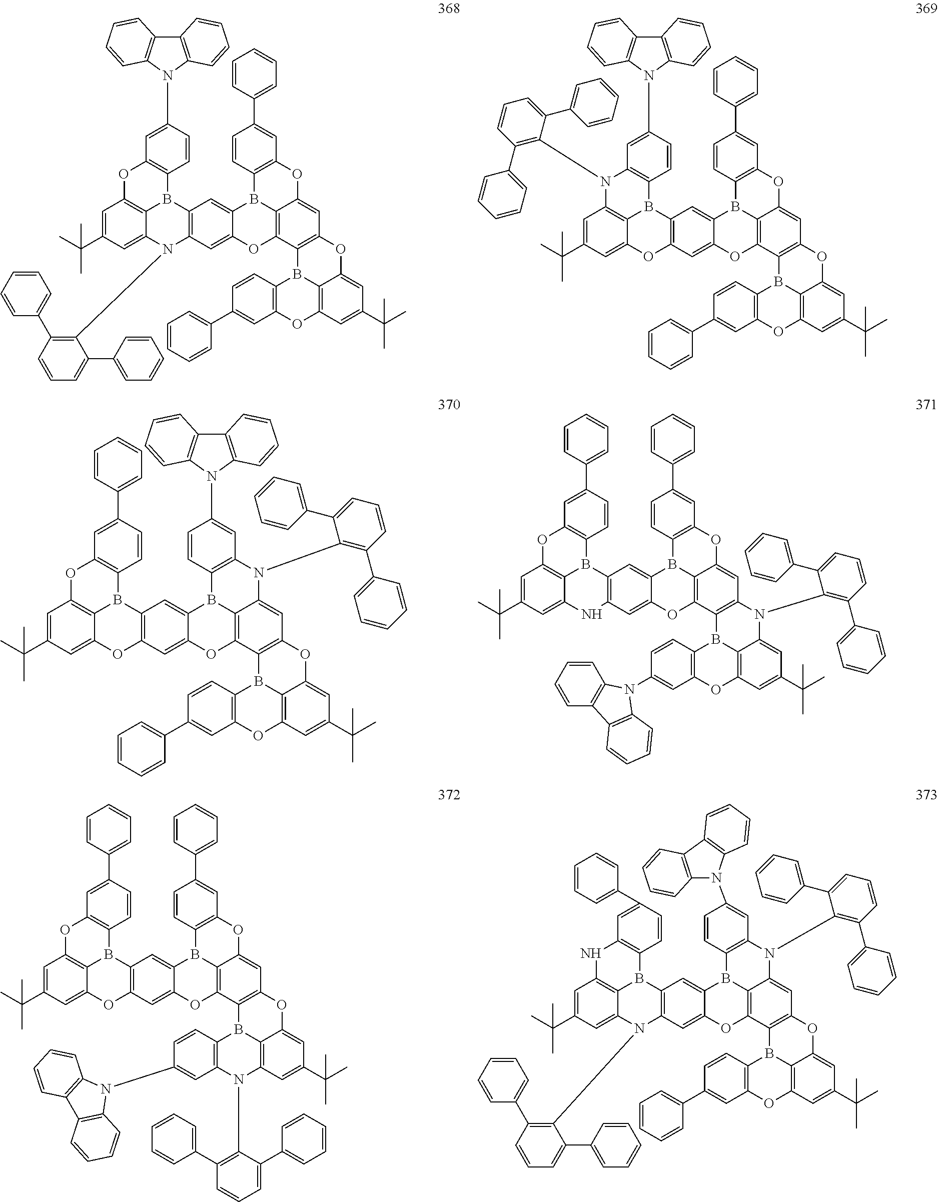 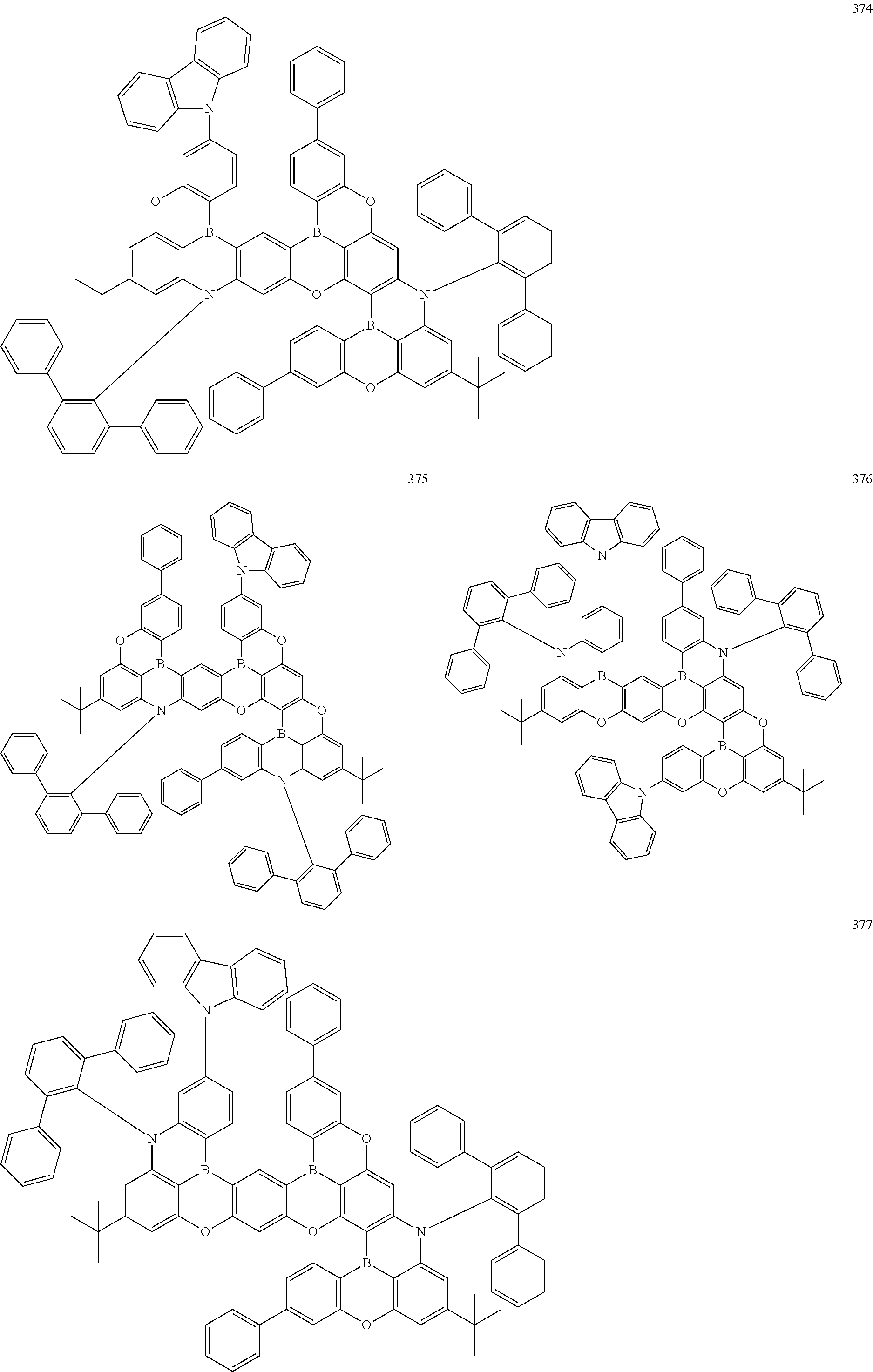 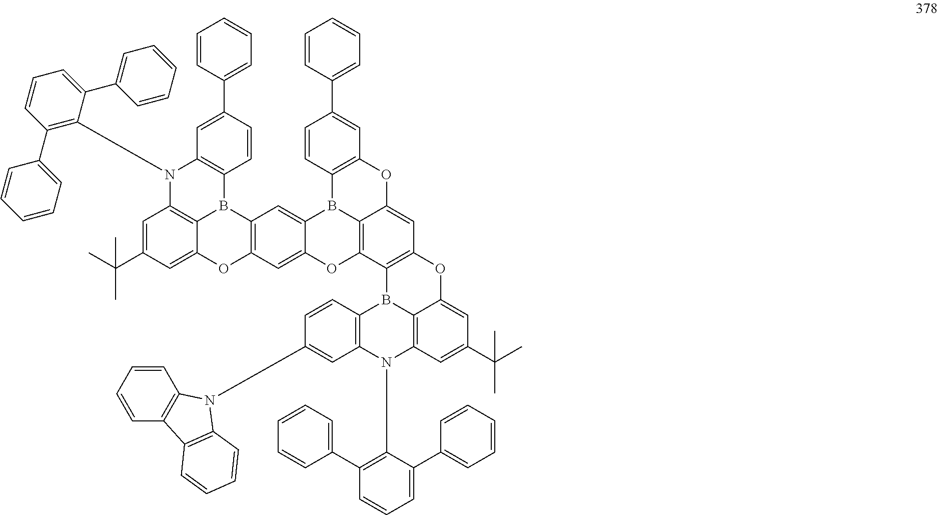 [SMILES: CC(C)(C)c1cc2c3c(c1)N(c1c(-c4ccccc4)cccc1-c1ccccc1)c1cc(-c4ccccc4)ccc1B3c1cc3c(cc1O2)Oc1c2c(cc4c1B1c5ccc(-n6c7ccccc7c7ccccc76)cc5N(c5c(-c6ccccc6)cccc5-c5ccccc5)c5cc(C(C)(C)C)cc(c51)O4)Oc1cc(-c4ccccc4)ccc1B32] 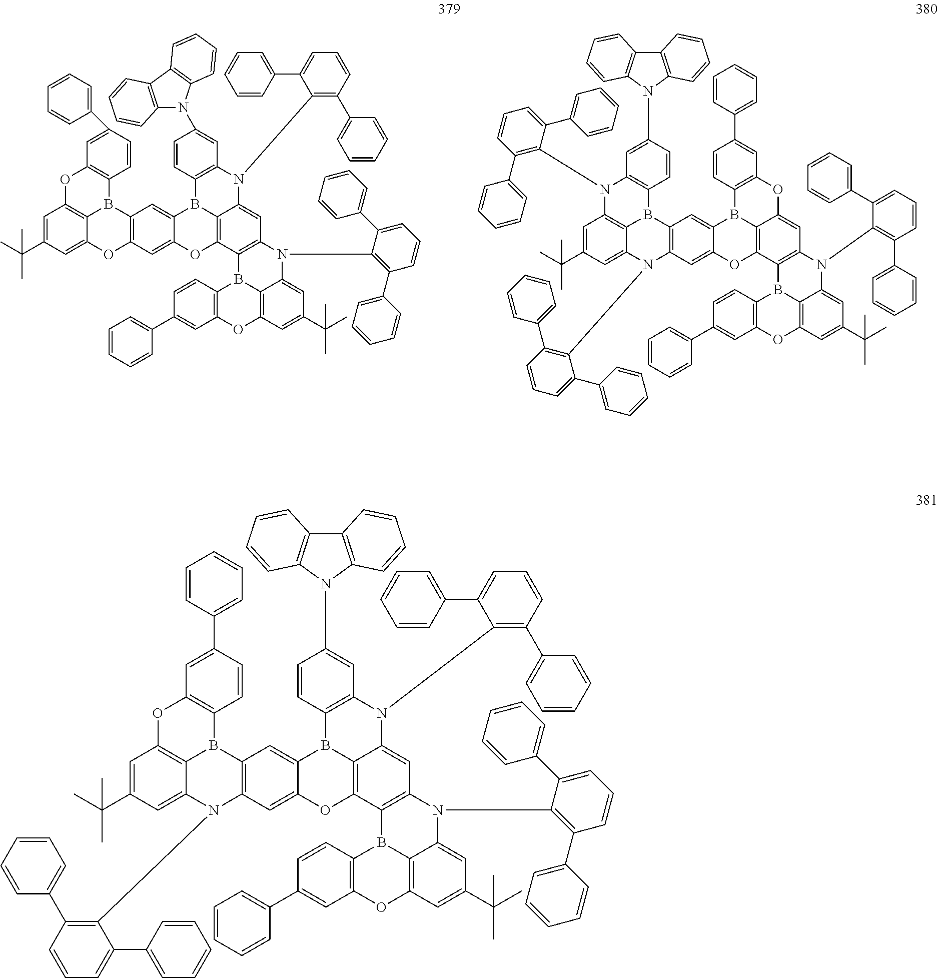 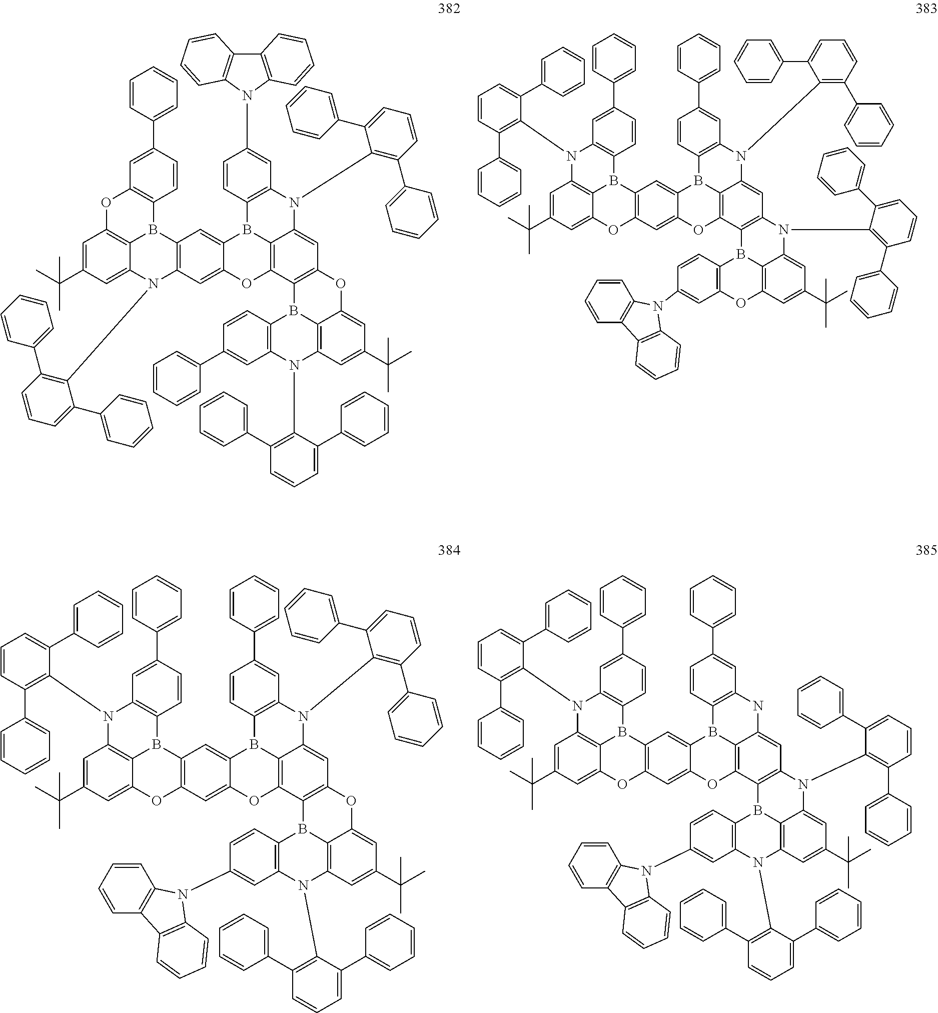 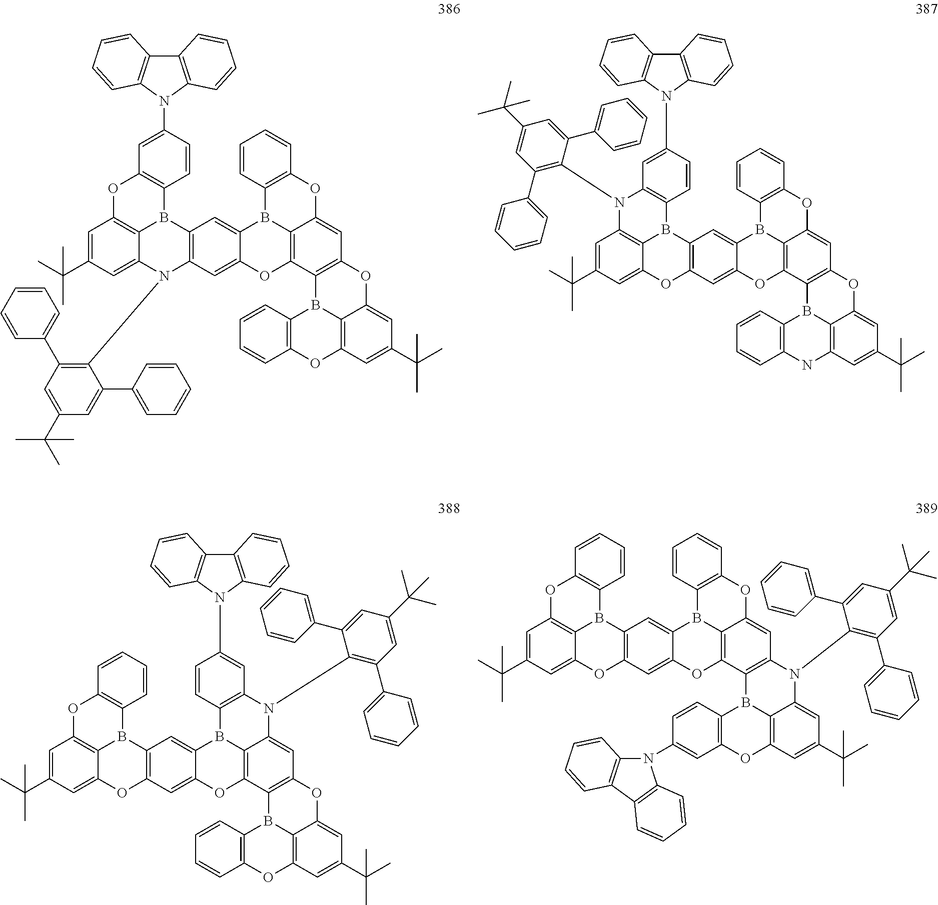 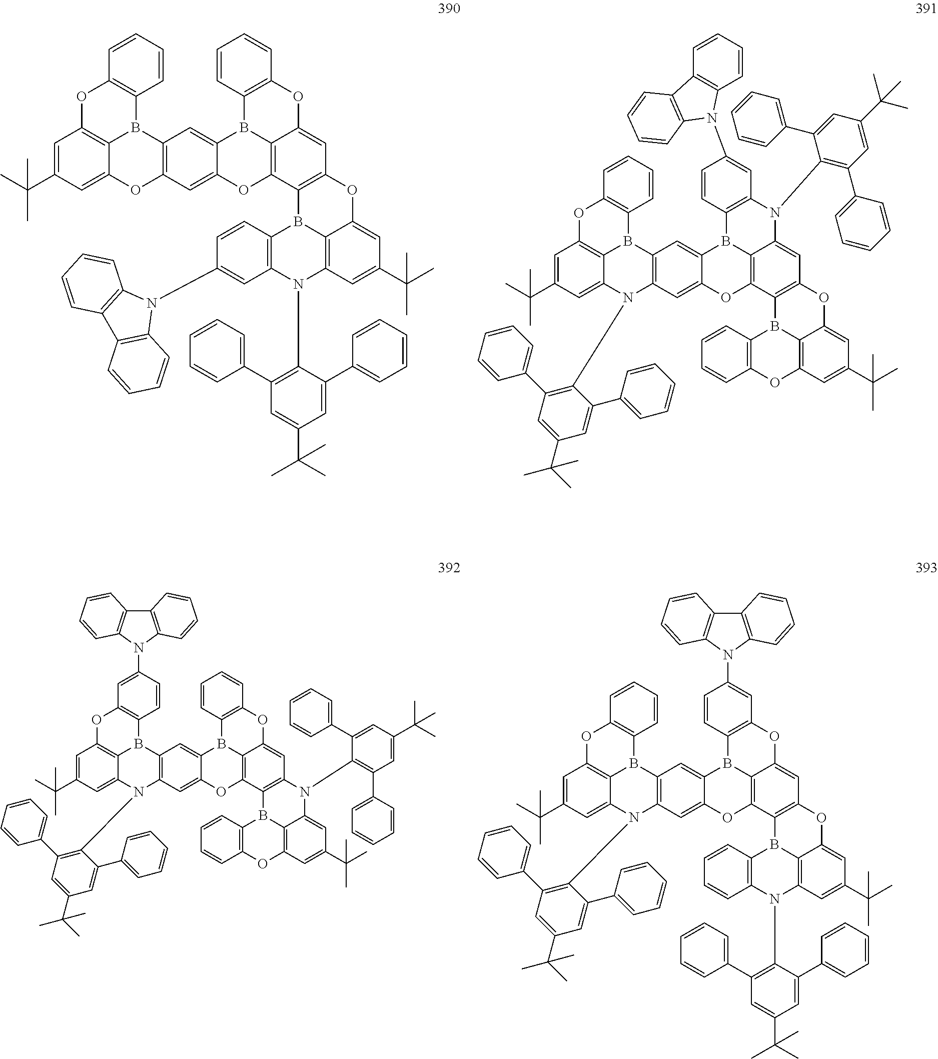 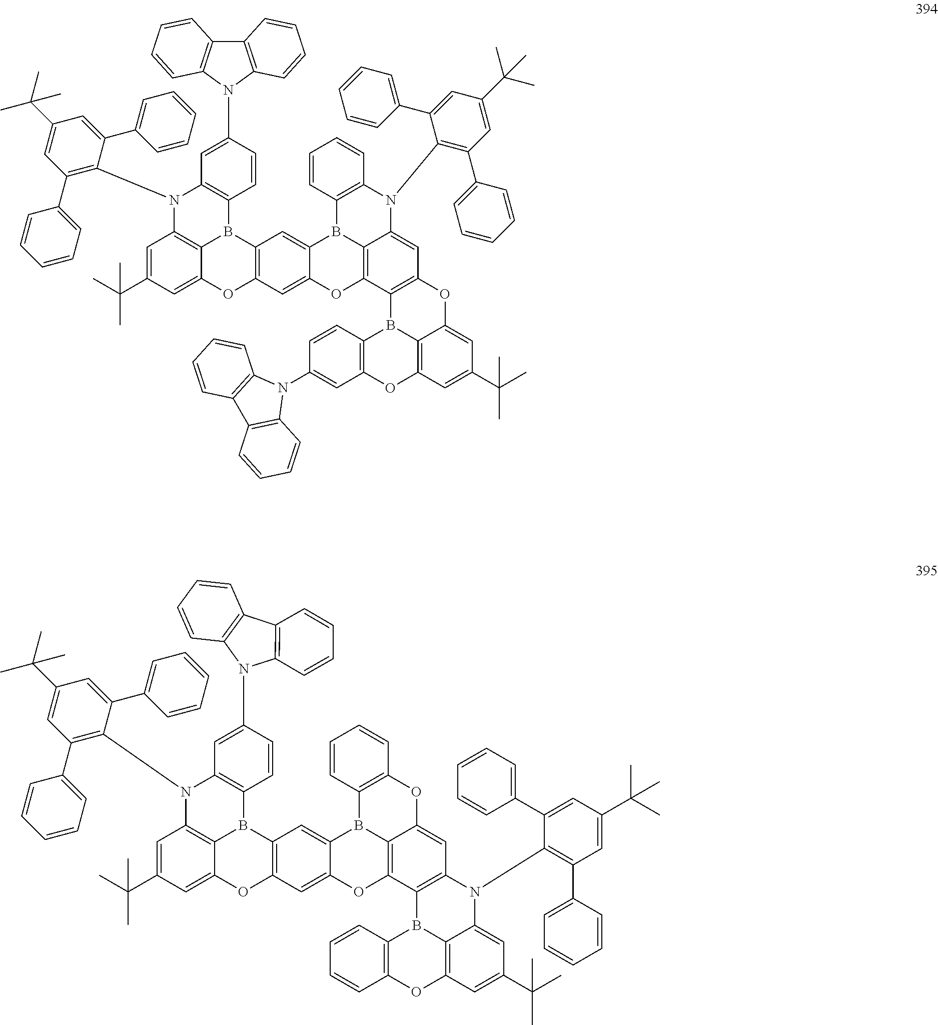 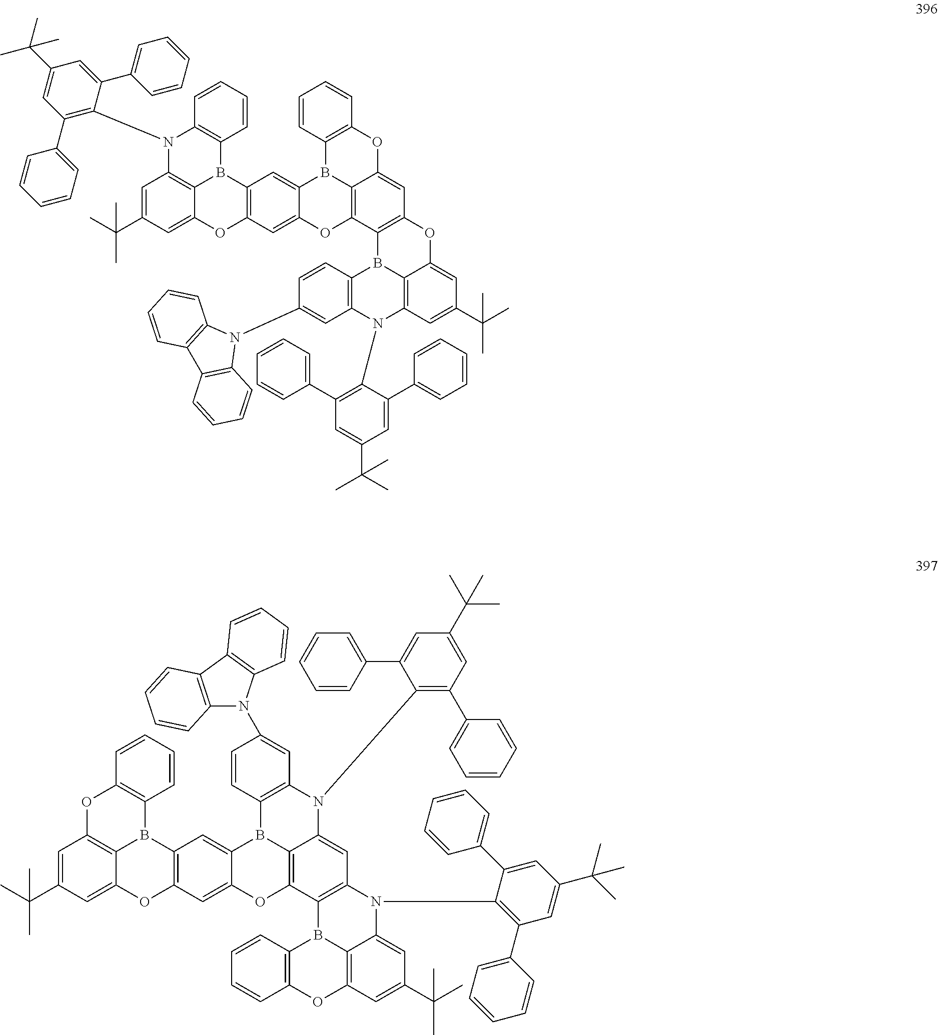 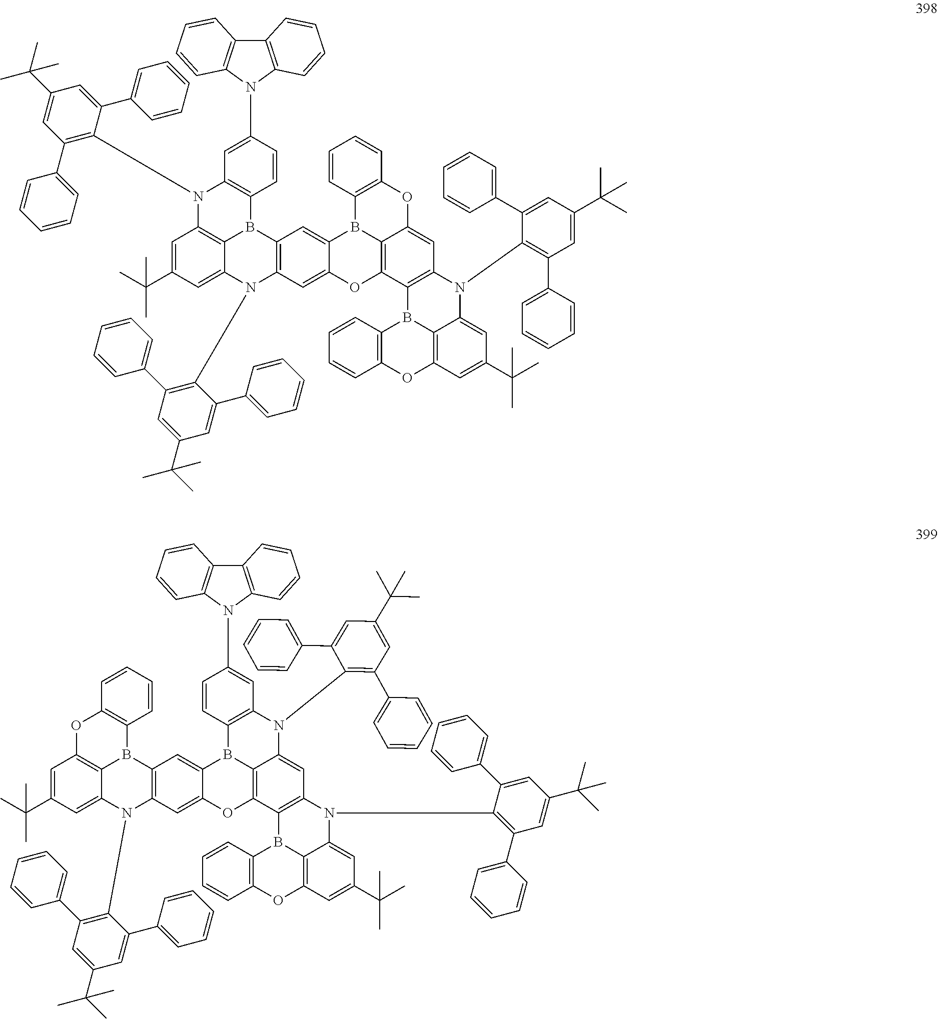 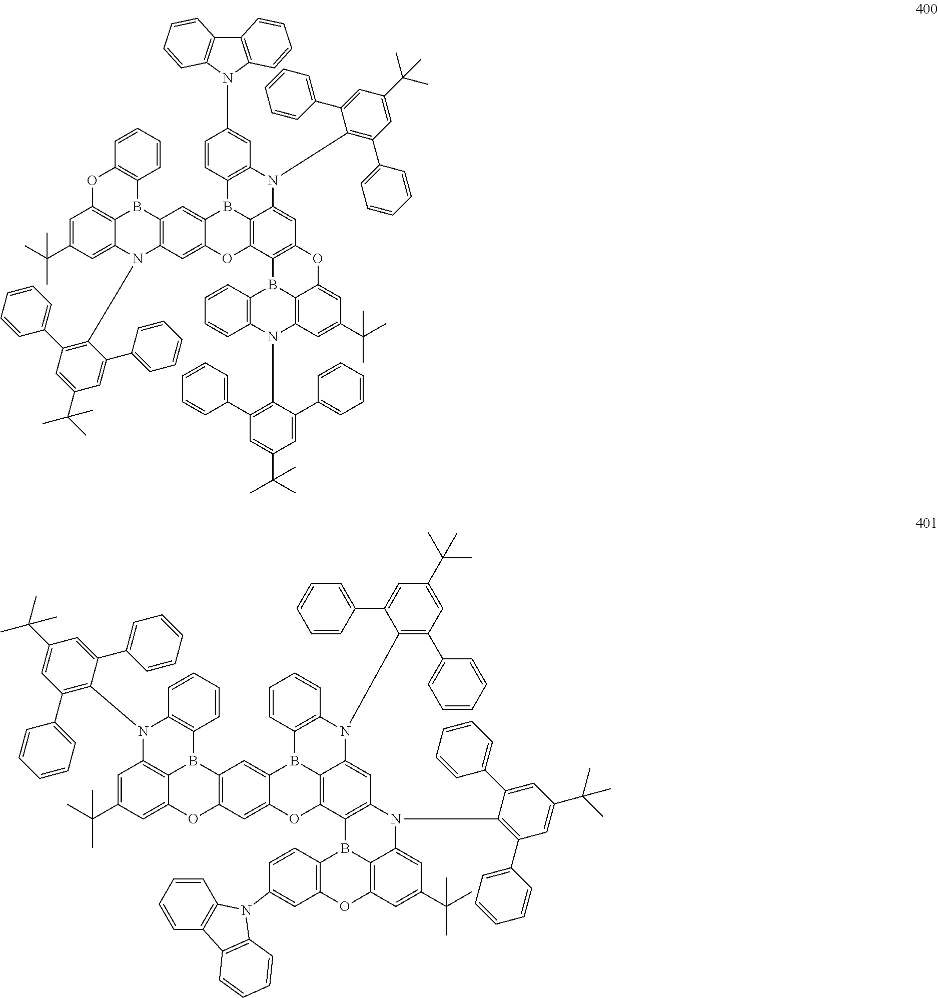 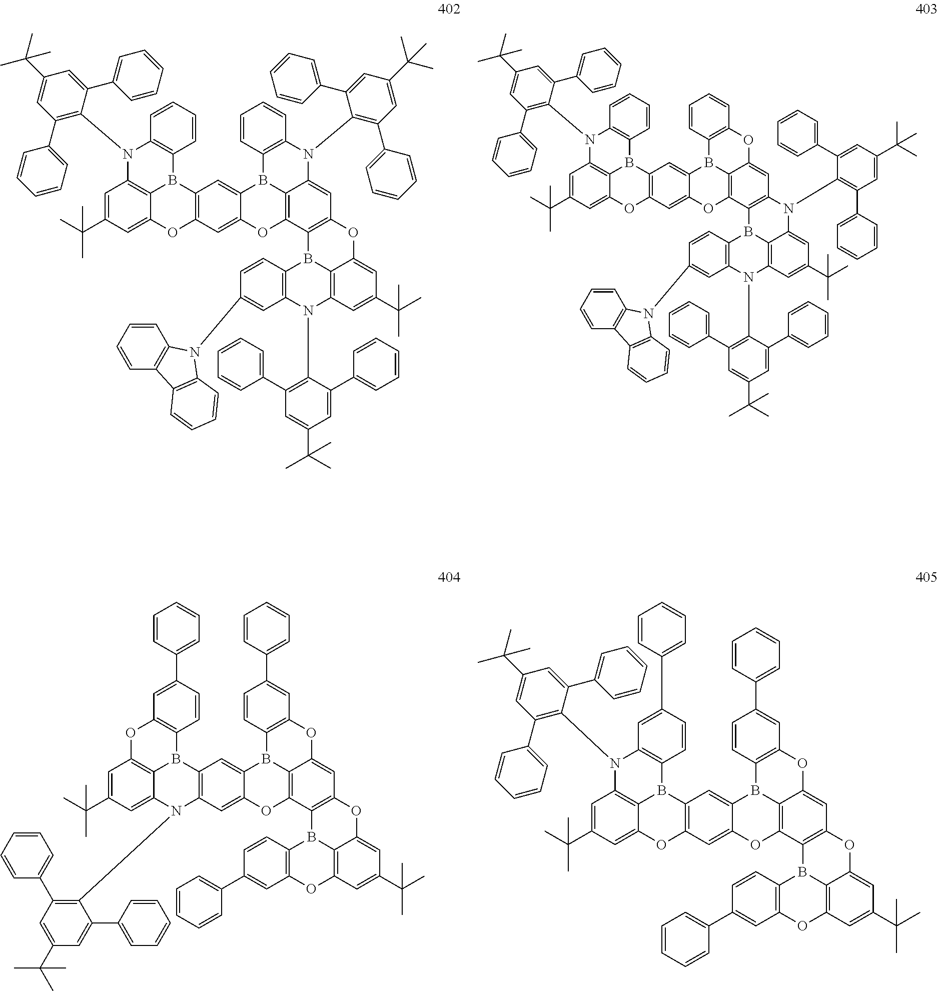 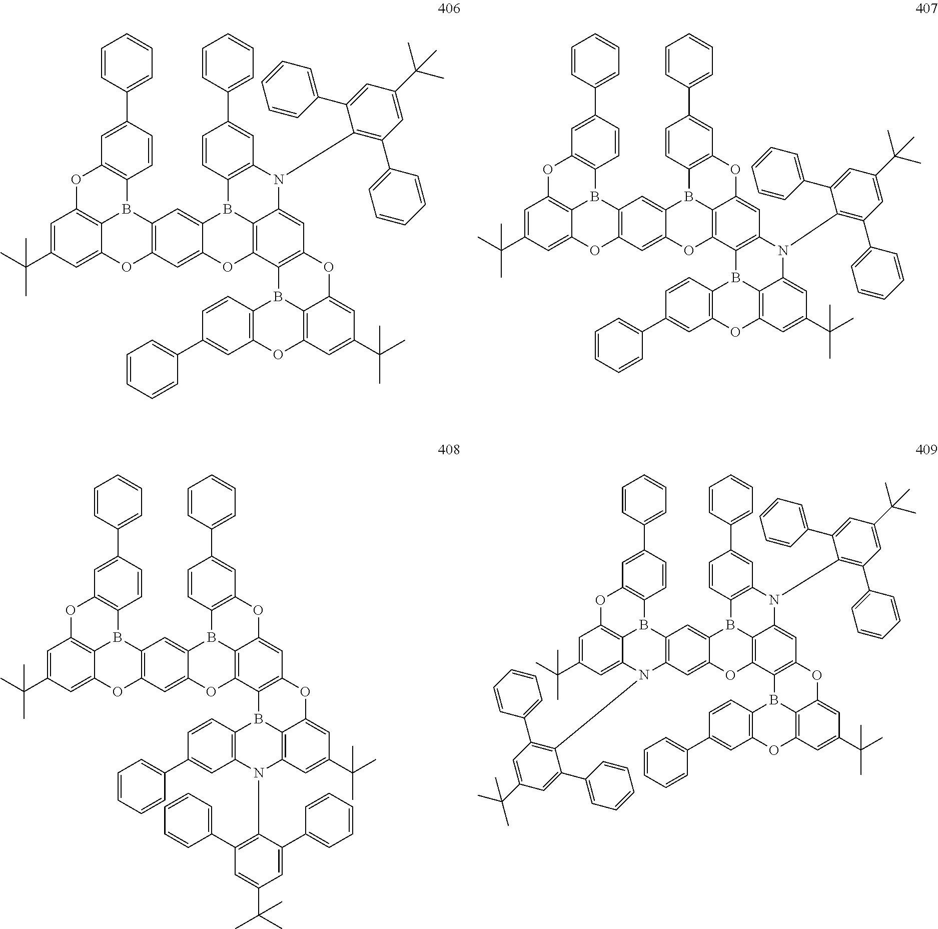 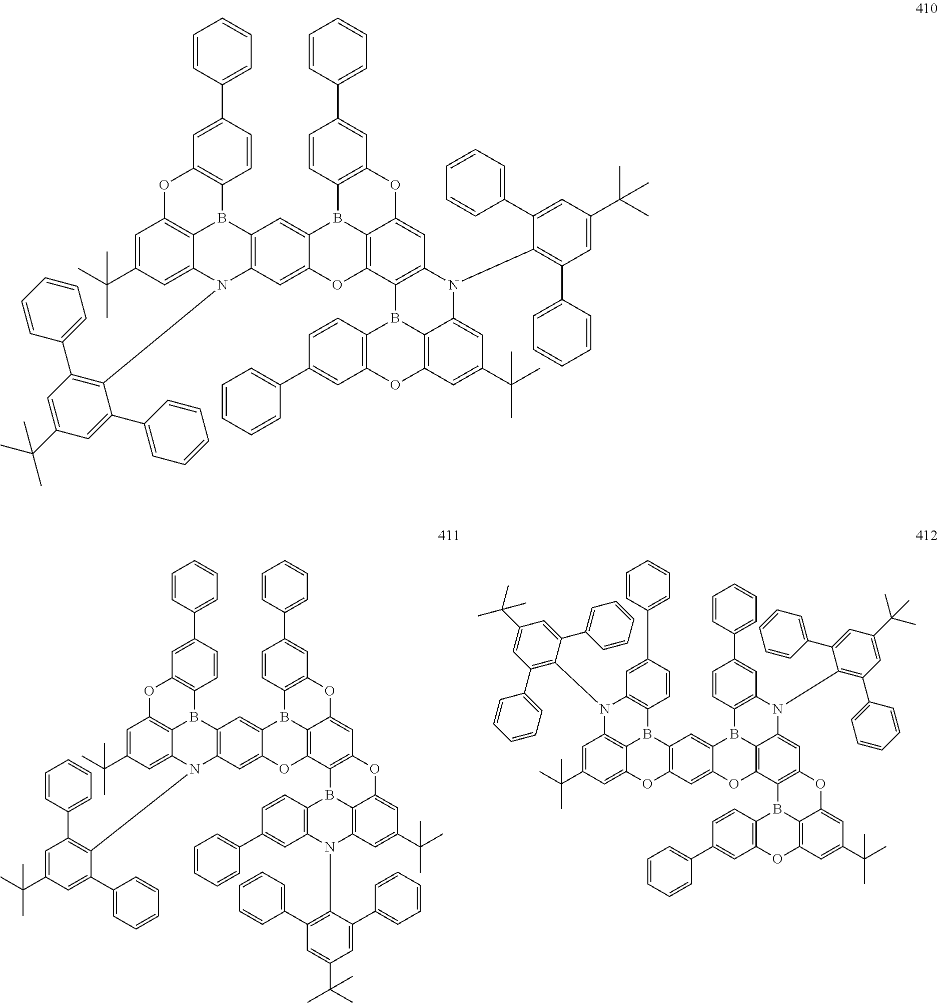 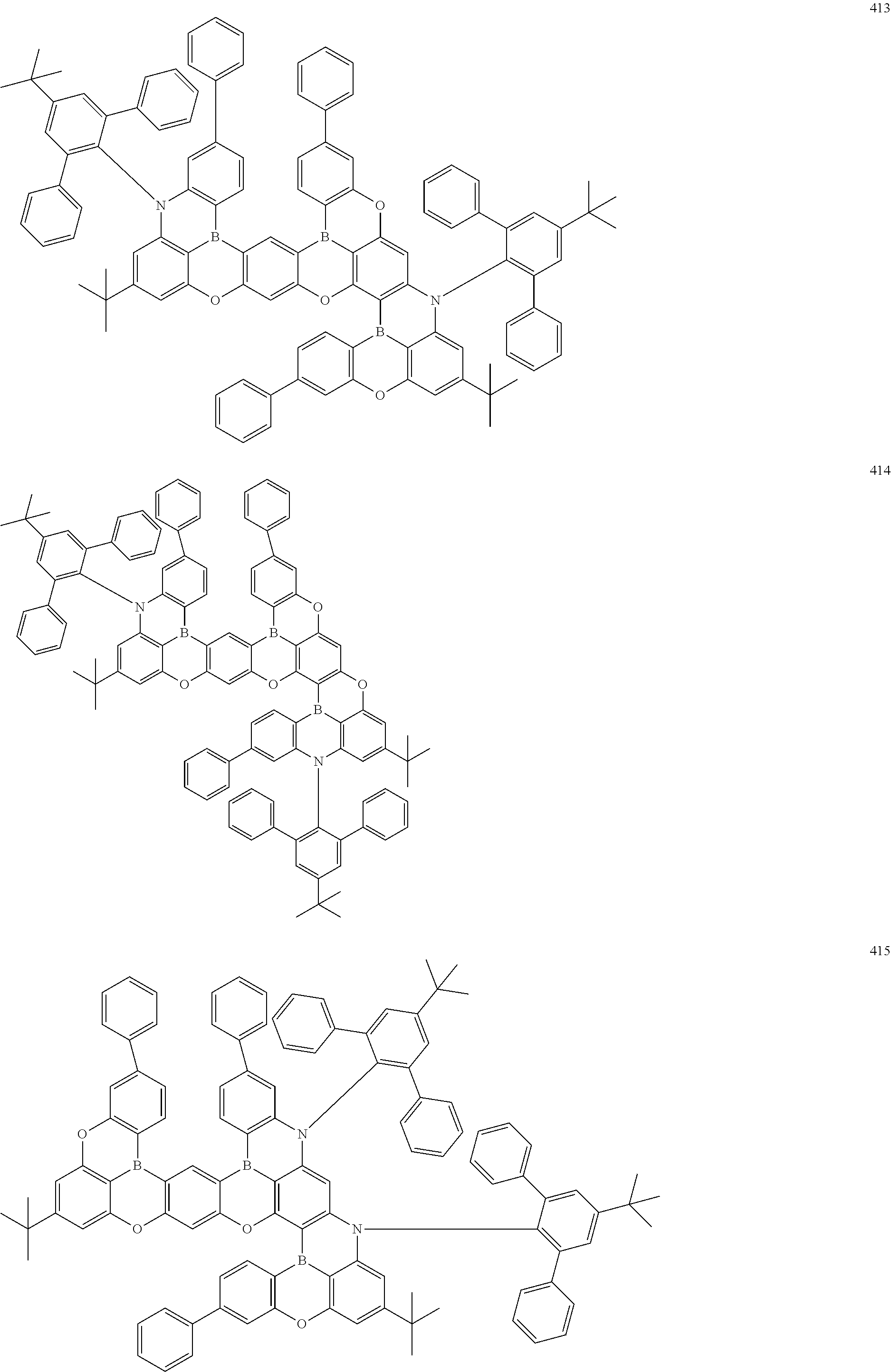 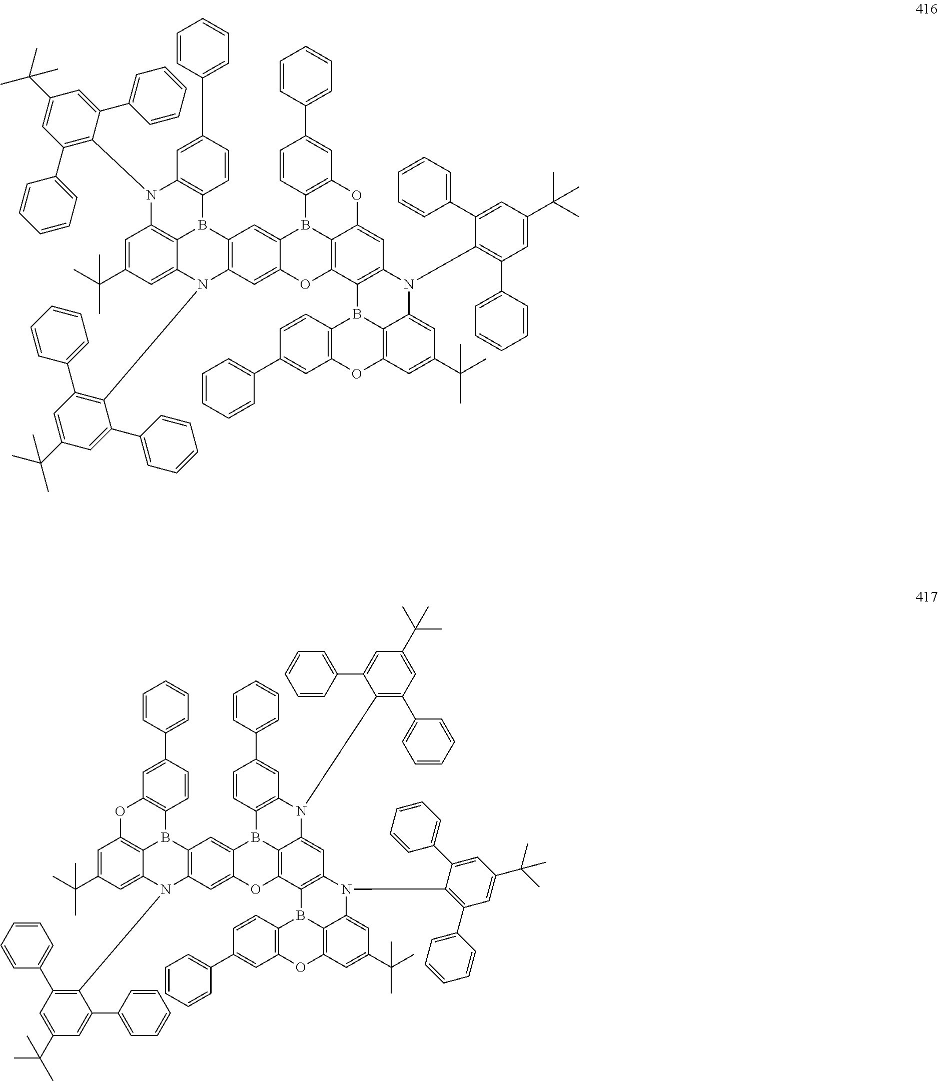 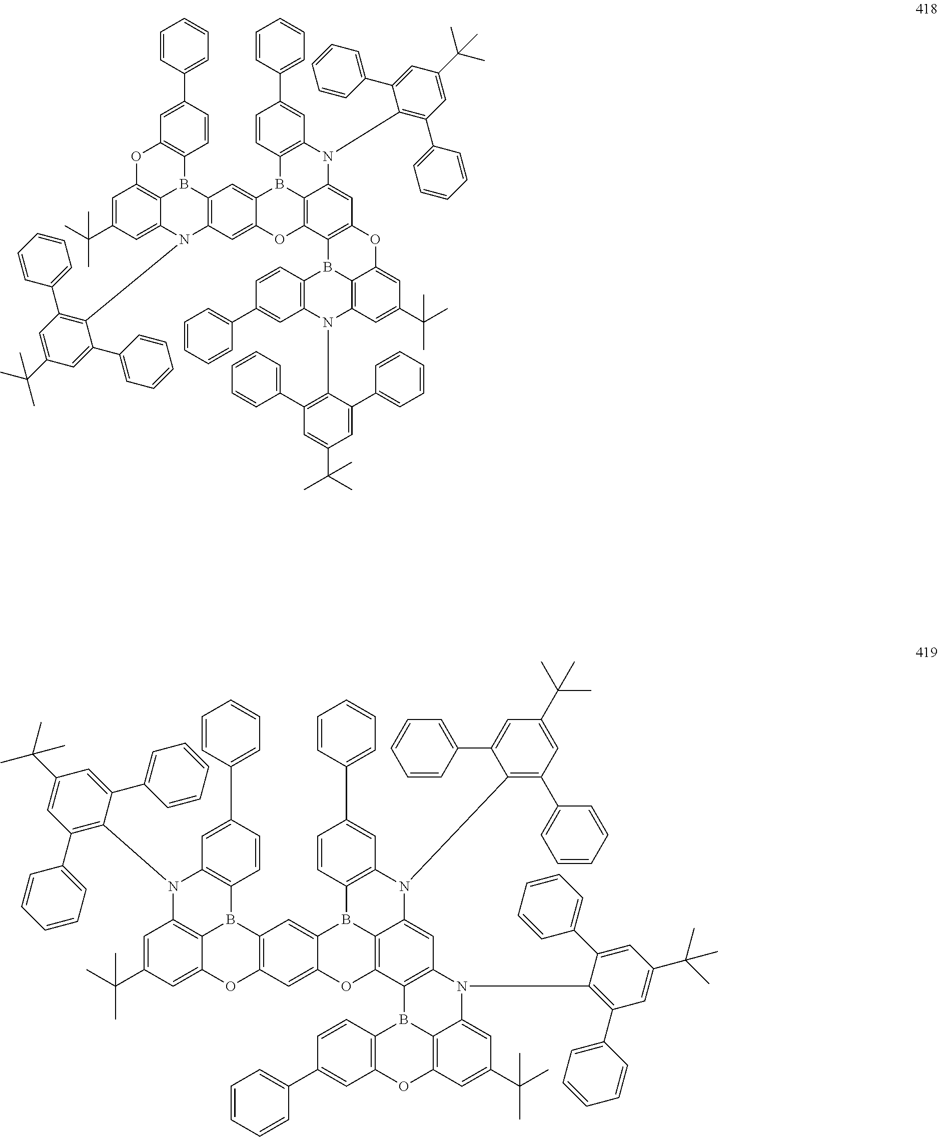 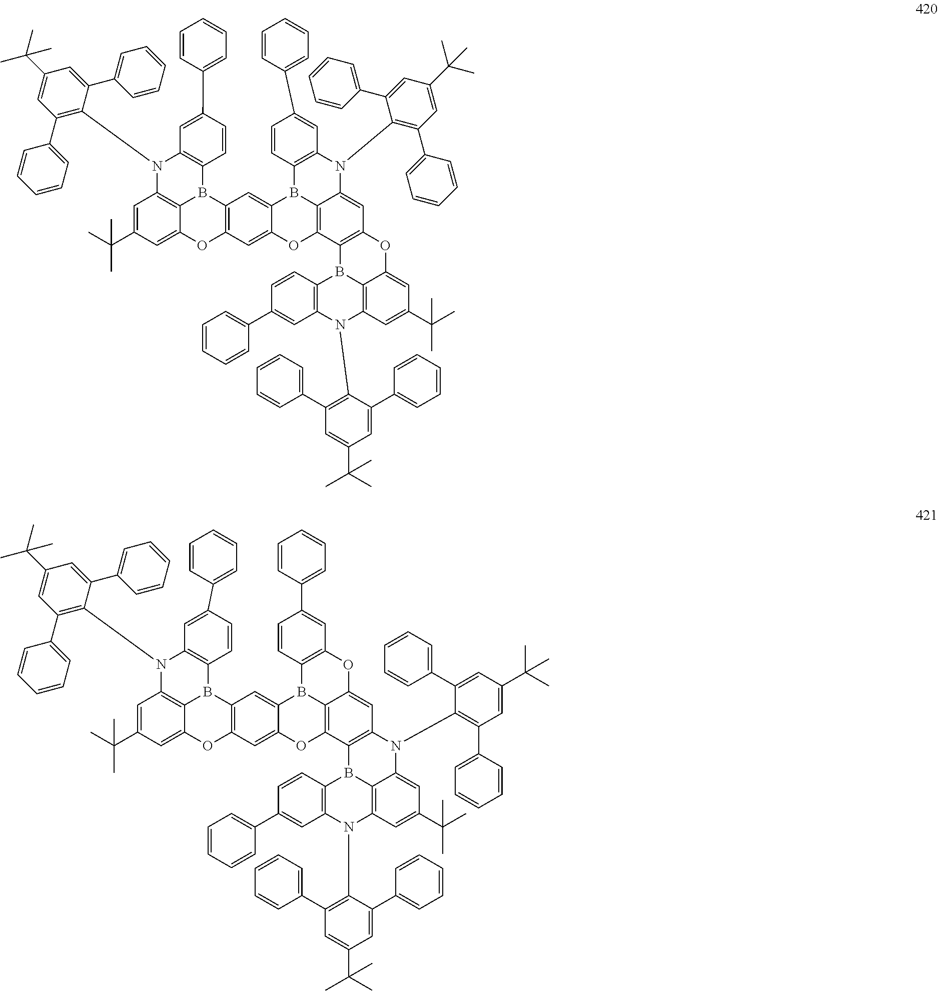 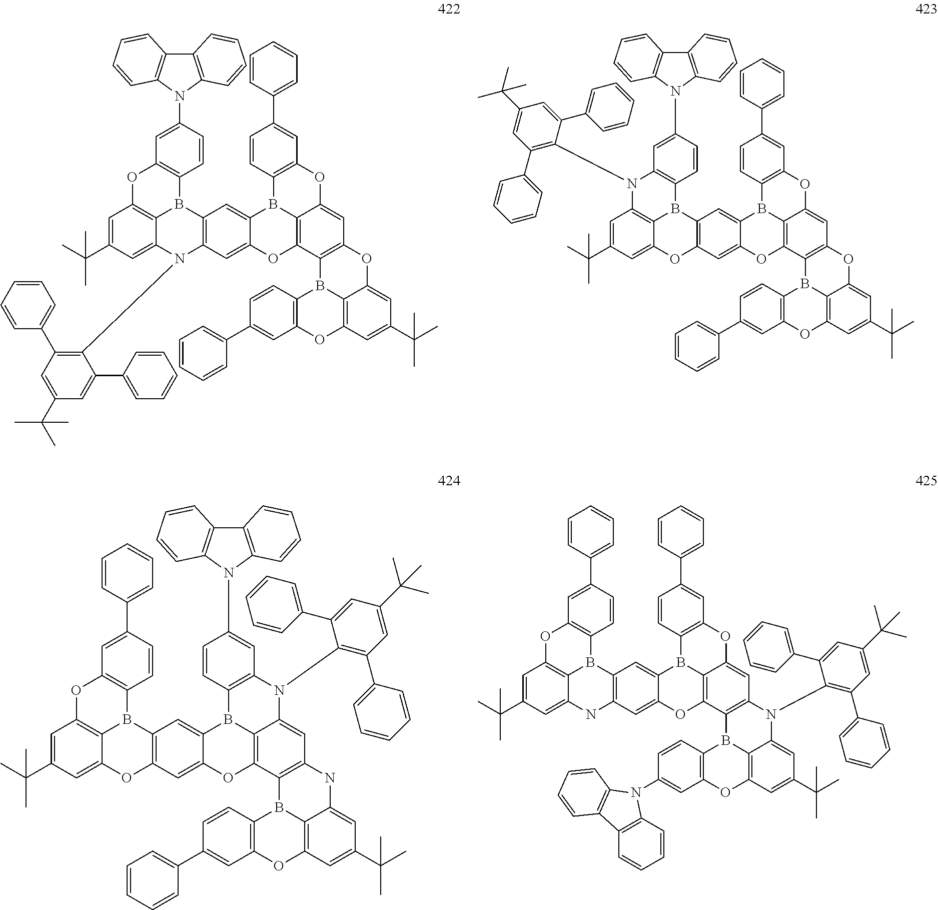 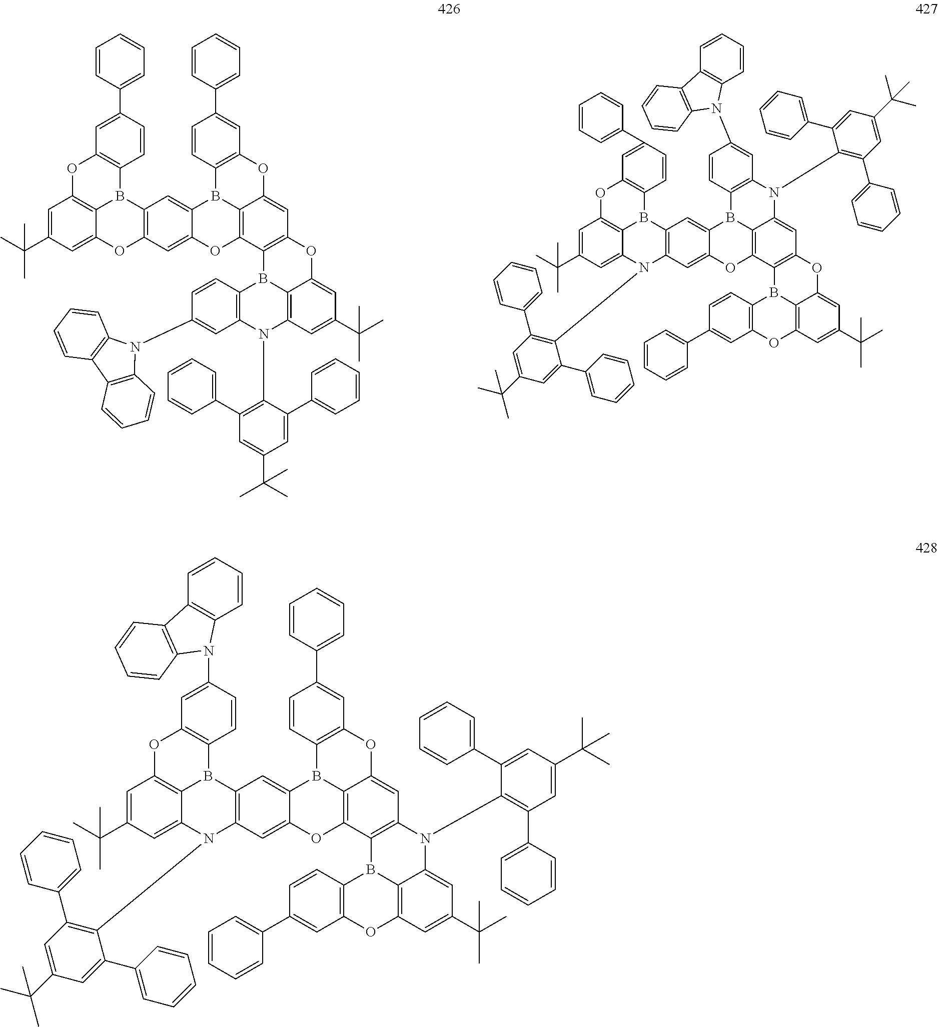 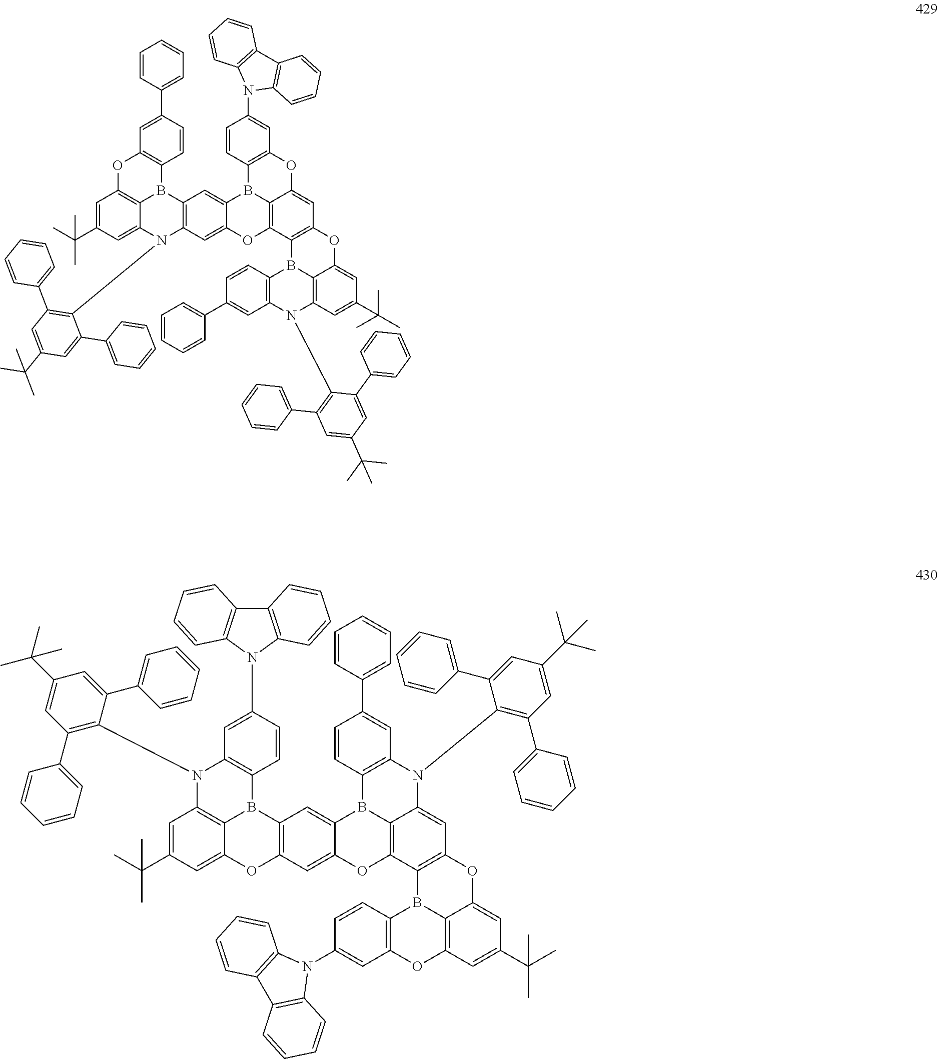 [SMILES: CC(C)(C)c1cc(-c2ccccc2)c(N2c3cc4c(cc3B3c5ccc(-c6ccccc6)cc5Oc5cc(C(C)(C)C)cc2c53)B2c3ccc(-n5c6ccccc6c6ccccc65)cc3Oc3cc5c(c(c32)O4)B2c3ccc(-c4ccccc4)cc3N(c3c(-c4ccccc4)cc(C(C)(C)C)cc3-c3ccccc3)c3cc(C(C)(C)C)cc(c32)O5)c(-c2ccccc2)c1 ; CC(C)(C)c1cc2c3c(c1)Oc1cc4c5c(c1B3c1ccc(-n3c6ccccc6c6ccccc63)cc1O2)Oc1cc2c(cc1B5c1ccc(-c3ccccc3)cc1N4c1c(-c3ccccc3)cc(C(C)(C)C)cc1-c1ccccc1)B1c3ccc(-n4c5ccccc5c5ccccc54)cc3N(c3c(-c4ccccc4)cc(C(C)(C)C)cc3-c3ccccc3)c3cc(C(C)(C)C)cc(c31)O2] 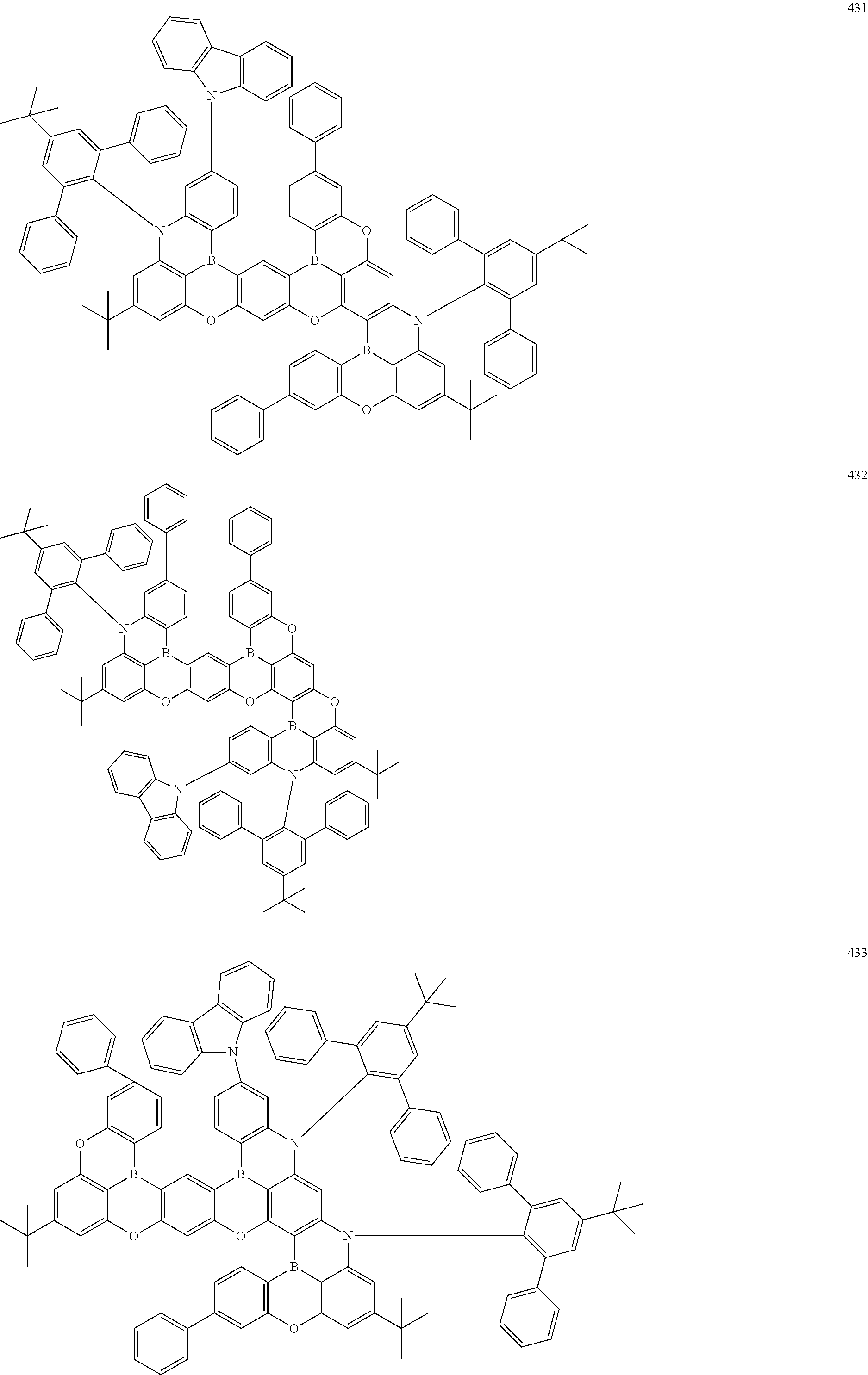 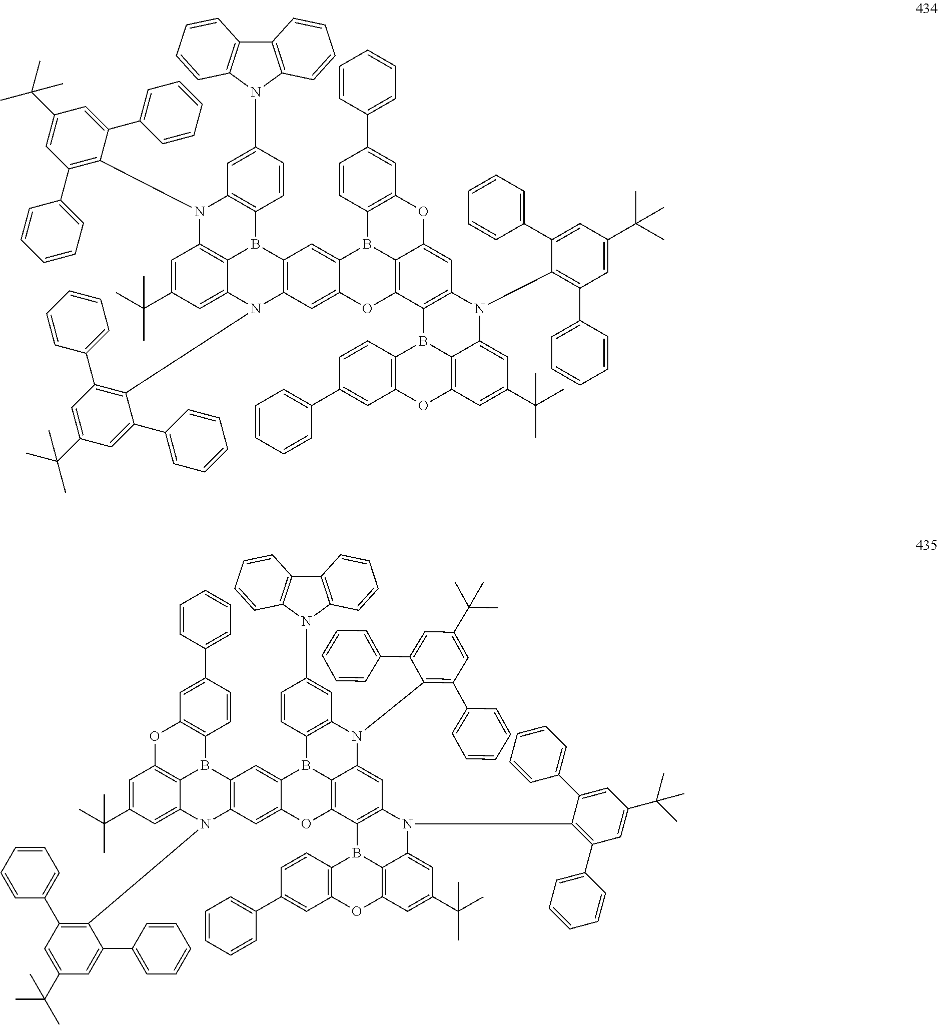 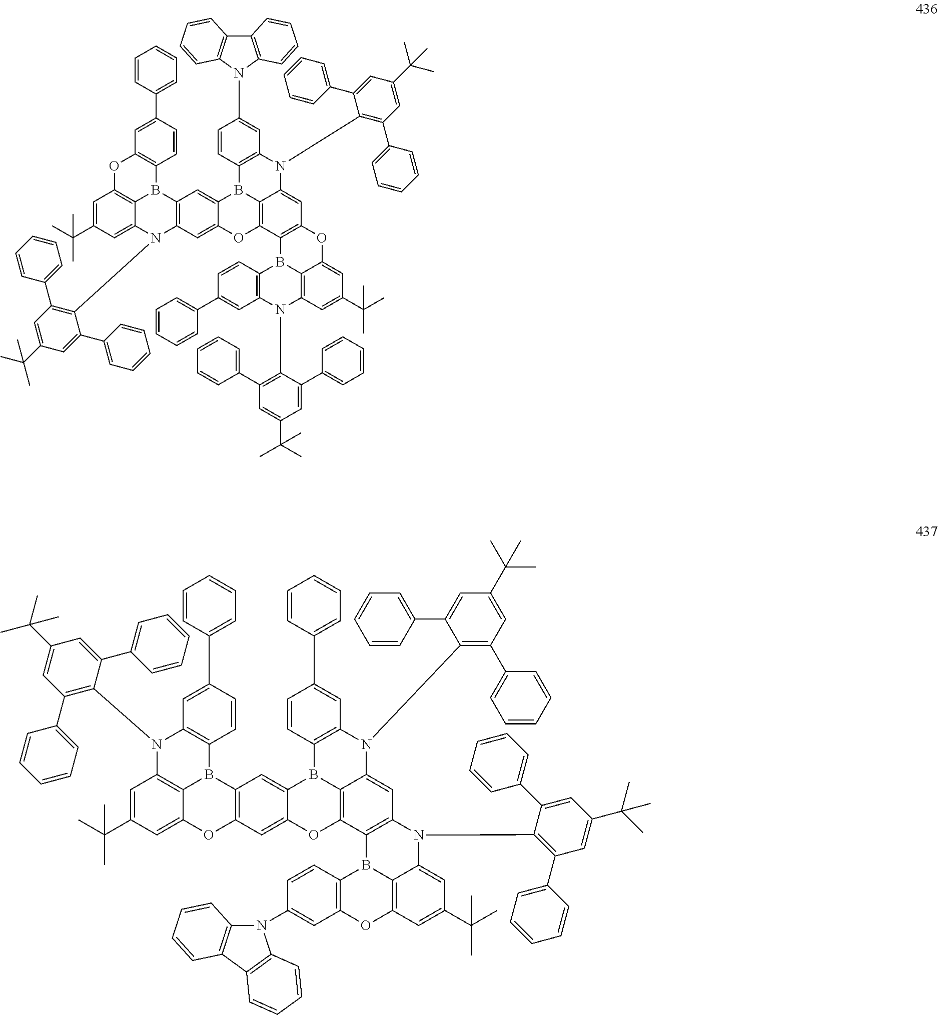 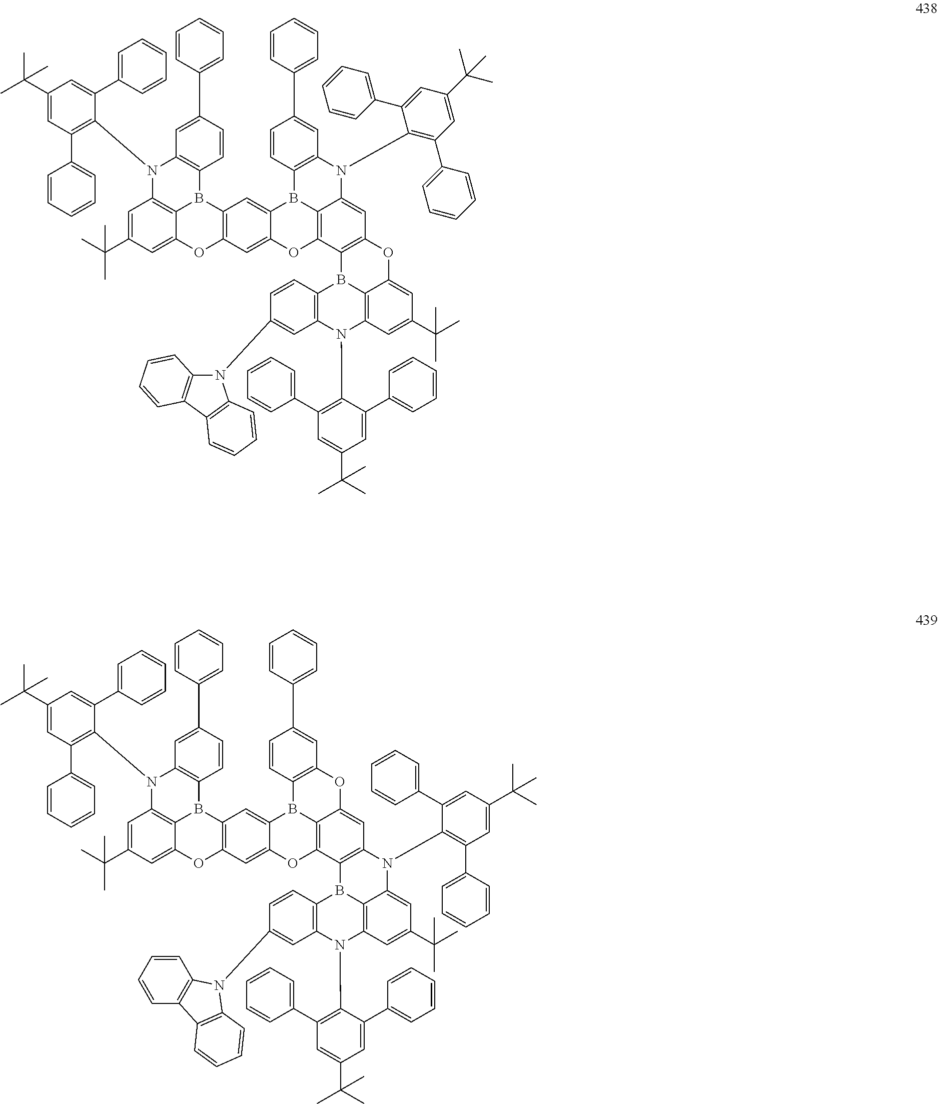 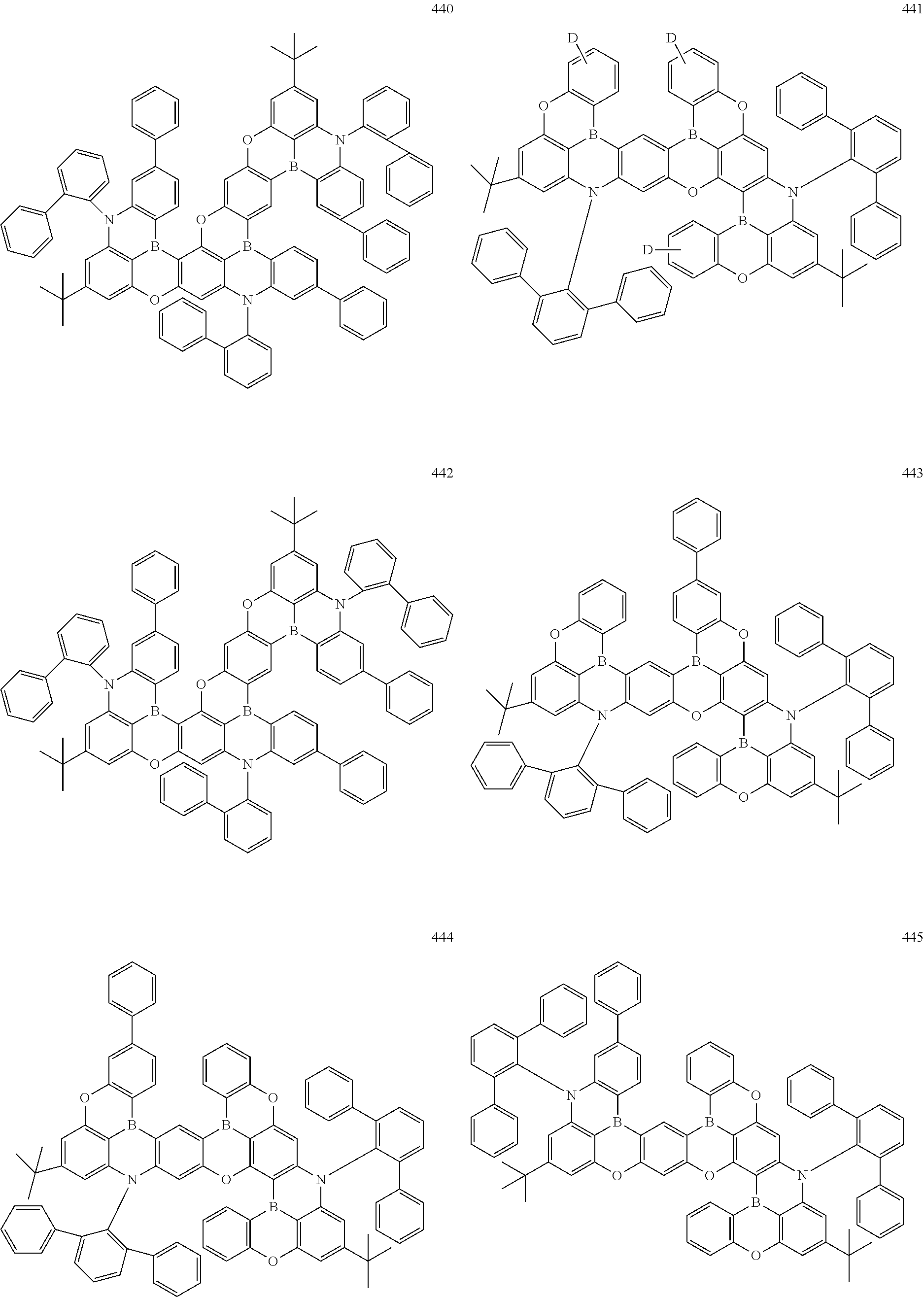 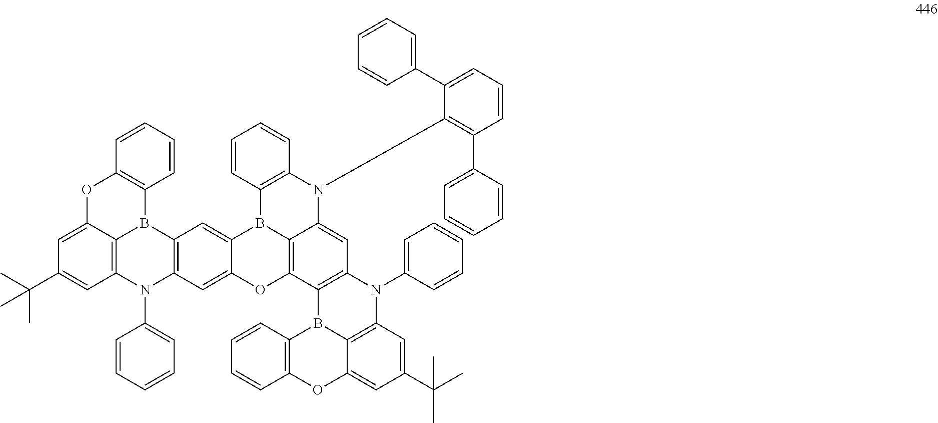 [SMILES: CC(C)(C)c1cc2c3c(c1)N(c1ccccc1)c1cc4c(cc1B3c1ccccc1O2)B1c2ccccc2N(c2c(-c3ccccc3)cccc2-c2ccccc2)c2cc3c(c(c21)O4)B1c2ccccc2Oc2cc(C(C)(C)C)cc(c21)N3c1ccccc1]
in Compound Group 1, “D” being deuterium.

16. A fused polycyclic compound represented by Formula 1: 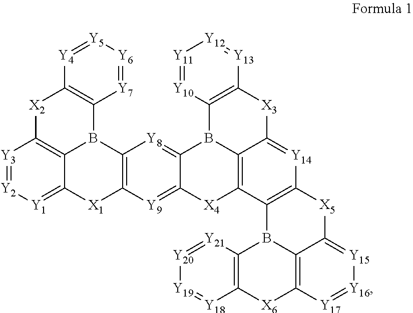
wherein, in Formula 1,
X₁ to X₆ are each independently O, S, or NRₓ,
Y₁ to Y₂₁ are each independently N or CR_{y},
Rₓ is a substituted or unsubstituted aryl group having 6 to 30 ring-forming carbon atoms or a substituted or unsubstituted heteroaryl group having 2 to 30 ring-forming carbon atoms, and
R_{y} is hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

17. The fused polycyclic compound of claim 16, wherein the fused polycyclic compound represented by Formula 1 is represented by Formula 2: 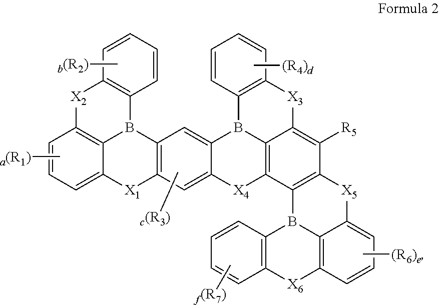
in Formula 2,
R₁ to R₇ being each independently hydrogen, deuterium, a halogen, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a and e being each independently an integer of 0 or greater and 3 or less,
b, d, and f being each independently an integer of 0 or greater and 4 or less,
c being an integer of 0 or greater and 2 or less, and
X₁ to X₆ being the same as defined in Formula 1.

18. The fused polycyclic compound of claim 16, wherein the fused polycyclic compound represented by Formula 1 is represented by Formula 3: 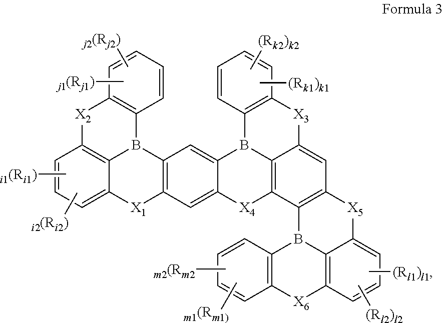
in Formula 3,
Rᵢ₁, Rⱼ₁, Rₖ₁, Rₗ₁, and Rₘ₁ being each independently hydrogen or deuterium,
Rᵢ₂, Rⱼ₂, Rₖ₂, Rₗ₂, and Rₘ₂ being each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
i1 and l1 being each independently an integer of 0 or greater and 3 or less,
j1, k1, and m1 being each independently an integer of 0 or greater and 4 or less,
i2, j2, k2, l2, and m2 being each independently 0 or 1, and
X₁ to X₆ being the same as defined in Formula 1.

19. The fused polycyclic compound of claim 16, wherein the fused polycyclic compound represented by Formula 1 is represented by Formula 4: 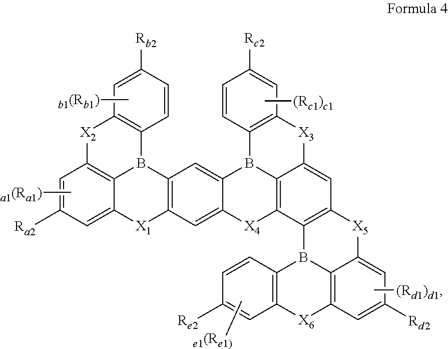
in Formula 4,
Rₐ₁, Rₐ₂, R_{b1}, R_{b2}, R_{c1}, R_{c2}, R_{d1}, R_{d2}, Rₑ₁, and Rₑ₂ being each independently hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a1 and d1 being each independently an integer of 0 or greater and 2 or less,
b1, c1, and e1 being each independently an integer of 0 or greater and 3 or less, and
X₁ to X₆ being the same as defined in Formula 1.

20. The fused polycyclic compound of claim 16, wherein the fused polycyclic compound represented by Formula 1 is any one selected from among compounds in Compound Group 1: 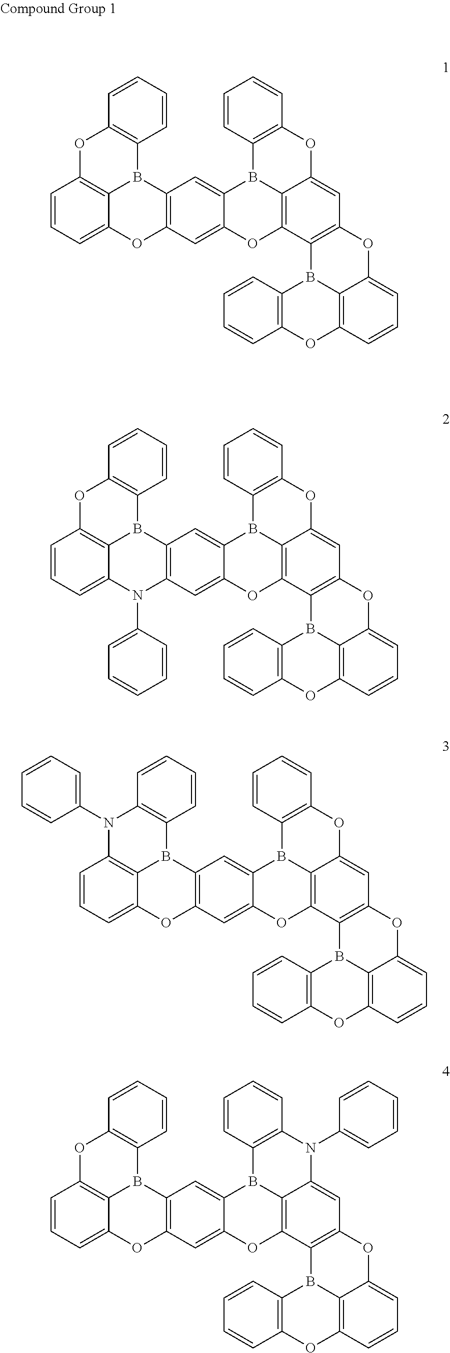 [SMILES: c1ccc2c(c1)Oc1cccc3c1B2c1cc2c(cc1O3)Oc1c3c(cc4c1B1c5ccccc5Oc5cccc(c51)O4)Oc1ccccc1B23 ; c1ccc(N2c3cc4c(cc3B3c5ccccc5Oc5cccc2c53)B2c3ccccc3Oc3cc5c(c(c32)O4)B2c3ccccc3Oc3cccc(c32)O5)cc1 ; c1ccc(N2c3ccccc3B3c4cc5c(cc4Oc4cccc2c43)Oc2c3c(cc4c2B2c6ccccc6Oc6cccc(c62)O4)Oc2ccccc2B53)cc1 ; c1ccc(N2c3ccccc3B3c4cc5c(cc4Oc4c6c(cc2c43)Oc2cccc3c2B6c2ccccc2O3)Oc2cccc3c2B5c2ccccc2O3)cc1] 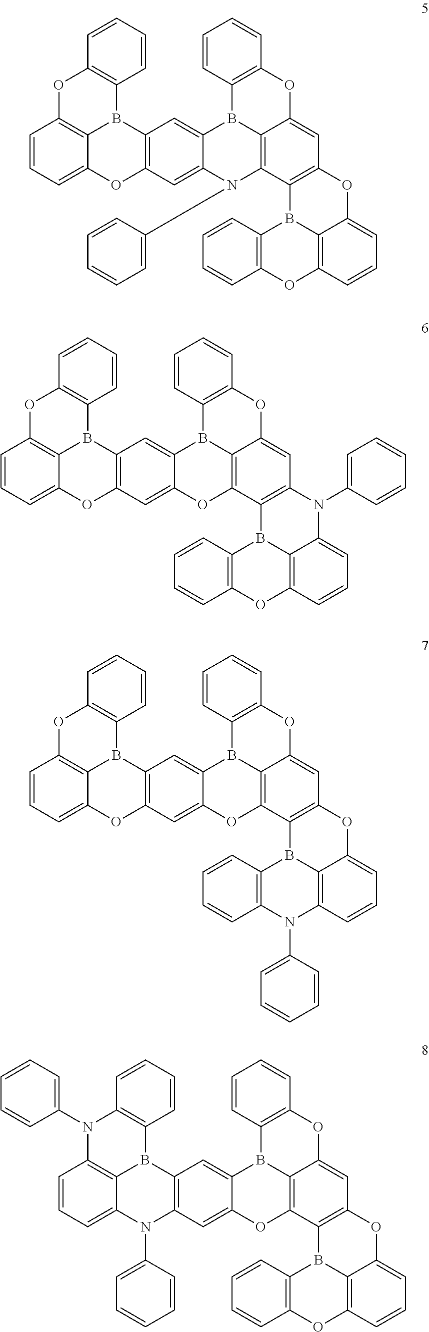 [SMILES: c1ccc(CCN2c3cc4c(cc3B3c5ccccc5Oc5cc6c(c2c53)B2c3ccccc3Oc3cccc(c32)O6)B2c3ccccc3Oc3cccc(c32)O4)cc1 ; c1ccc(N2c3cccc4c3B(c3ccccc3O4)c3c2cc2c4c3Oc3cc5c(cc3B4c3ccccc3O2)B2c3ccccc3Oc3cccc(c32)O5)cc1 ; c1ccc(N2c3ccccc3B3c4c(cccc42)Oc2cc4c5c(c23)Oc2cc3c(cc2B5c2ccccc2O4)B2c4ccccc4Oc4cccc(c42)O3)cc1 ; c1ccc(N2c3ccccc3B3c4cc5c(cc4N(c4ccccc4)c4cccc2c43)Oc2c3c(cc4c2B2c6ccccc6Oc6cccc(c62)O4)Oc2ccccc2B53)cc1] 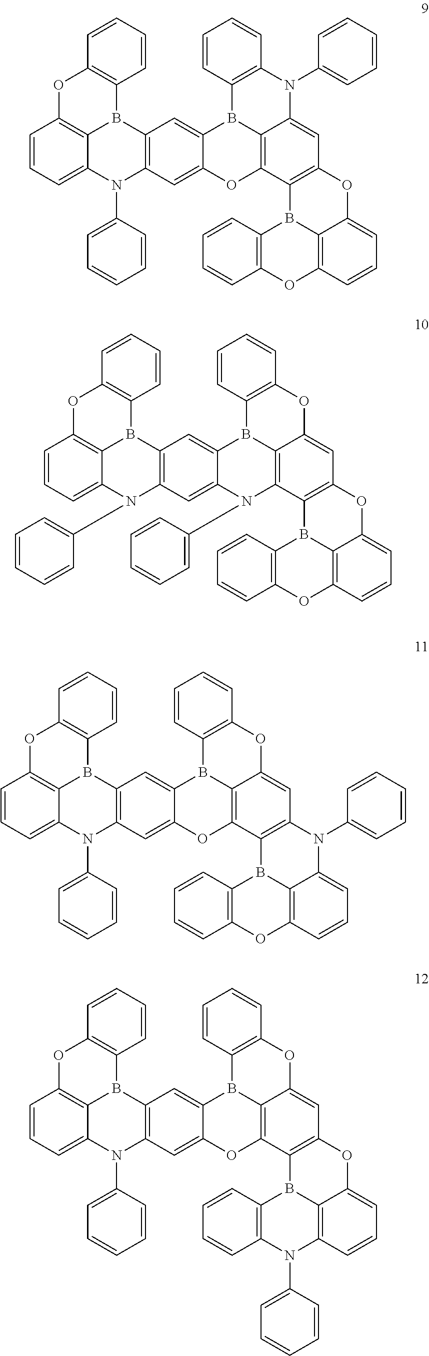 [SMILES: c1ccc(N2c3cc4c(cc3B3c5ccccc5Oc5cccc2c53)B2c3ccccc3N(c3ccccc3)c3cc5c(c(c32)O4)B2c3ccccc3Oc3cccc(c32)O5)cc1 ; c1ccc(CN2c3cc4c(cc3B3c5ccccc5Oc5cccc2c53)B2c3ccccc3Oc3cc5c(c(c32)N4Cc2ccccc2)B2c3ccccc3Oc3cccc(c32)O5)cc1 ; c1ccc(N2c3cc4c(cc3B3c5ccccc5Oc5cccc2c53)B2c3ccccc3Oc3cc5c(c(c32)O4)B2c3ccccc3Oc3cccc(c32)N5c2ccccc2)cc1 ; c1ccc(N2c3cc4c(cc3B3c5ccccc5Oc5cccc2c53)B2c3ccccc3Oc3cc5c(c(c32)O4)B2c3ccccc3N(c3ccccc3)c3cccc(c32)O5)cc1] 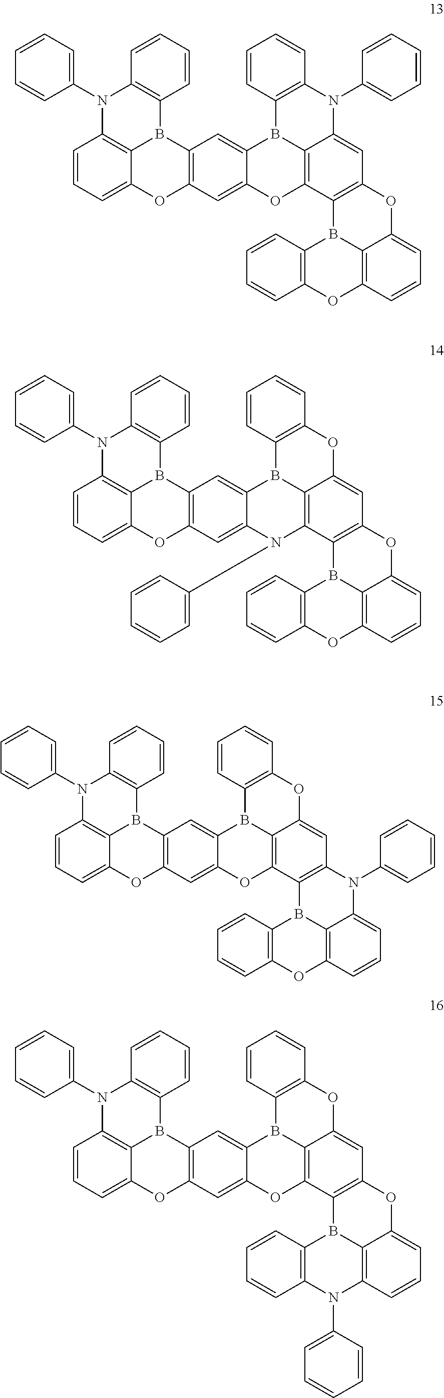 [SMILES: c1ccc(N2c3ccccc3B3c4cc5c(cc4Oc4cccc2c43)Oc2c3c(cc4c2B5c2ccccc2N4c2ccccc2)Oc2cccc4c2B3c2ccccc2O4)cc1 ; c1ccc(CCN2c3cc4c(cc3B3c5ccccc5Oc5cc6c(c2c53)B2c3ccccc3Oc3cccc(c32)O6)B2c3ccccc3N(c3ccccc3)c3cccc(c32)O4)cc1 ; c1ccc(N2c3ccccc3B3c4cc5c(cc4Oc4cccc2c43)Oc2c3c(cc4c2B2c6ccccc6Oc6cccc(c62)N4c2ccccc2)Oc2ccccc2B53)cc1 ; c1ccc(N2c3ccccc3B3c4cc5c(cc4Oc4cccc2c43)Oc2c3c(cc4c2B2c6ccccc6N(c6ccccc6)c6cccc(c62)O4)Oc2ccccc2B53)cc1] 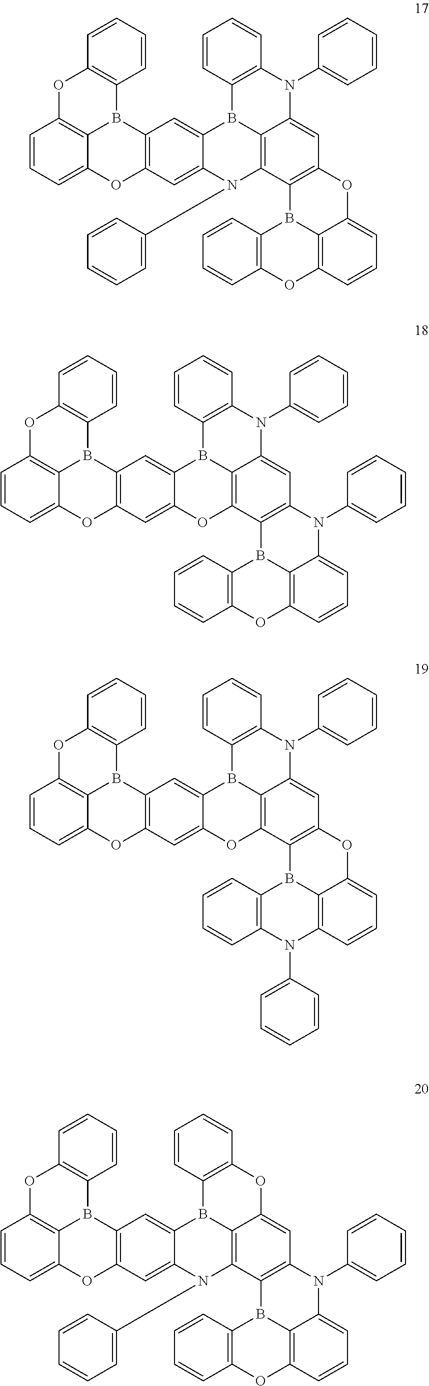 [SMILES: c1ccc(CCN2c3cc4c(cc3B3c5ccccc5N(c5ccccc5)c5cc6c(c2c53)B2c3ccccc3Oc3cccc(c32)O6)B2c3ccccc3Oc3cccc(c32)O4)cc1 ; c1ccc(N2c3ccccc3B3c4cc5c(cc4Oc4c3c2cc2c4B3c4ccccc4Oc4cccc(c43)N2c2ccccc2)Oc2cccc3c2B5c2ccccc2O3)cc1 ; c1ccc(N2c3ccccc3B3c4c(cccc42)Oc2cc4c5c(c23)Oc2cc3c(cc2B5c2ccccc2N4c2ccccc2)B2c4ccccc4Oc4cccc(c42)O3)cc1 ; c1ccc(CCN2c3cc4c(cc3B3c5ccccc5Oc5cc6c(c2c53)B2c3ccccc3Oc3cccc(c32)N6c2ccccc2)B2c3ccccc3Oc3cccc(c32)O4)cc1] 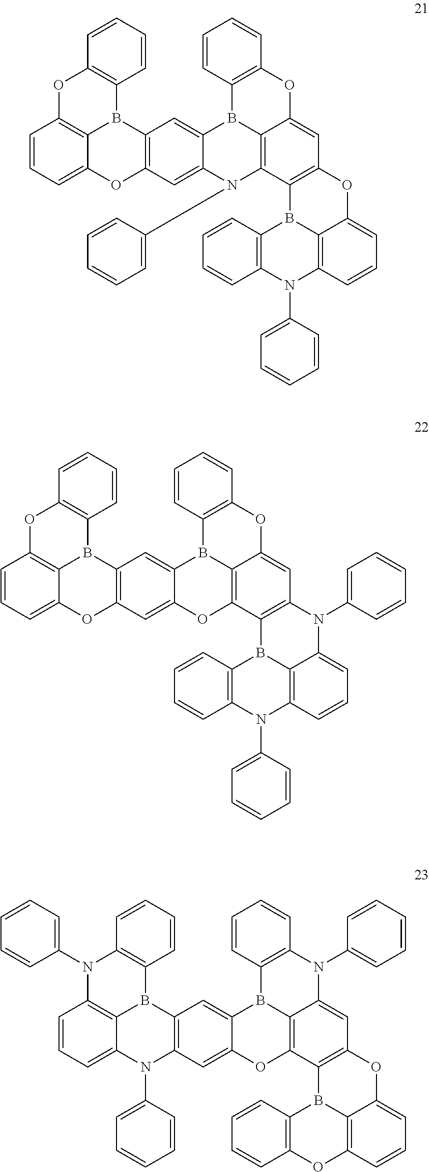 [SMILES: c1ccc(CCN2c3cc4c(cc3B3c5ccccc5Oc5cc6c(c2c53)B2c3ccccc3N(c3ccccc3)c3cccc(c32)O6)B2c3ccccc3Oc3cccc(c32)O4)cc1 ; c1ccc(N2c3ccccc3B3c4c2cccc4N(c2ccccc2)c2cc4c5c(c23)Oc2cc3c(cc2B5c2ccccc2O4)B2c4ccccc4Oc4cccc(c42)O3)cc1 ; c1ccc(N2c3ccccc3B3c4cc5c(cc4N(c4ccccc4)c4cccc2c43)Oc2c3c(cc4c2B5c2ccccc2N4c2ccccc2)Oc2cccc4c2B3c2ccccc2O4)cc1] 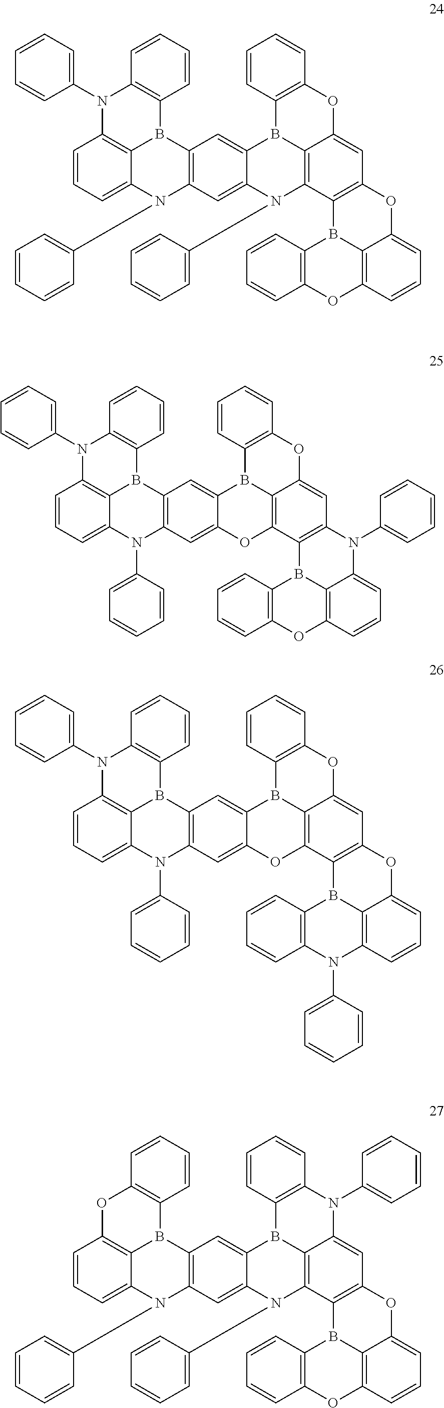 [SMILES: c1ccc(CCN2c3cc4c(cc3B3c5ccccc5N(c5ccccc5)c5cccc2c53)B2c3ccccc3Oc3cc5c(c(c32)N4CCc2ccccc2)B2c3ccccc3Oc3cccc(c32)O5)cc1 ; c1ccc(N2c3ccccc3B3c4cc5c(cc4N(c4ccccc4)c4cccc2c43)Oc2c3c(cc4c2B2c6ccccc6Oc6cccc(c62)N4c2ccccc2)Oc2ccccc2B53)cc1 ; c1ccc(N2c3ccccc3B3c4c(cccc42)Oc2cc4c5c(c23)Oc2cc3c(cc2B5c2ccccc2O4)B2c4ccccc4N(c4ccccc4)c4cccc(c42)N3c2ccccc2)cc1 ; c1ccc(CCN2c3cc4c(cc3B3c5ccccc5Oc5cccc2c53)B2c3ccccc3N(c3ccccc3)c3cc5c(c(c32)N4CCc2ccccc2)B2c3ccccc3Oc3cccc(c32)O5)cc1] 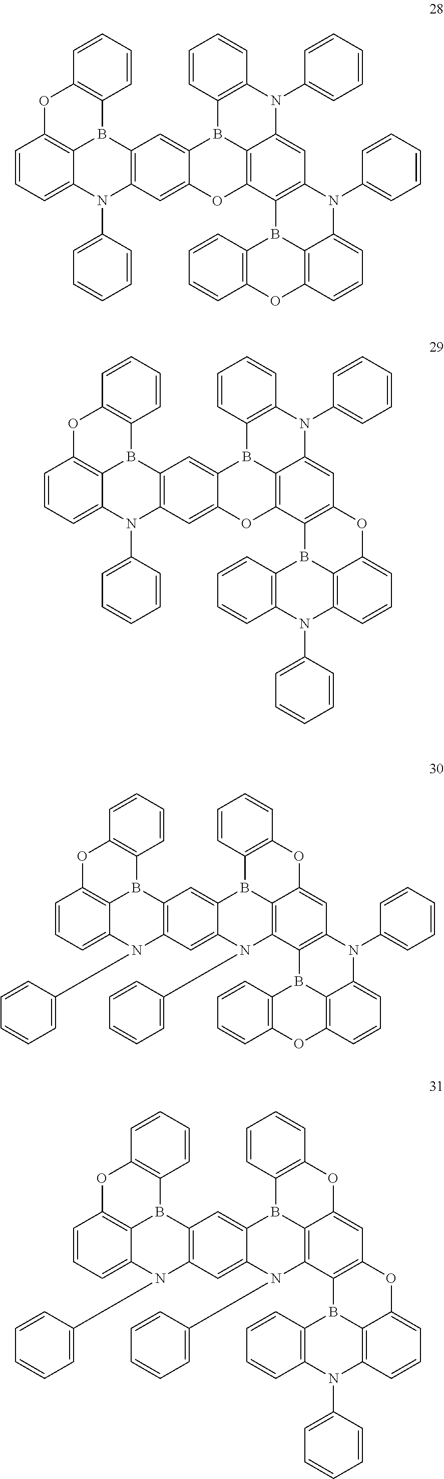 [SMILES: c1ccc(N2c3cc4c(cc3B3c5ccccc5Oc5cccc2c53)B2c3ccccc3N(c3ccccc3)c3cc5c(c(c32)O4)B2c3ccccc3Oc3cccc(c32)N5c2ccccc2)cc1 ; c1ccc(N2c3cc4c(cc3B3c5ccccc5Oc5cccc2c53)B2c3ccccc3N(c3ccccc3)c3cc5c(c(c32)O4)B2c3ccccc3N(c3ccccc3)c3cccc(c32)O5)cc1 ; c1ccc(CCN2c3cc4c(cc3B3c5ccccc5Oc5cccc2c53)B2c3ccccc3Oc3cc5c(c(c32)N4CCc2ccccc2)B2c3ccccc3Oc3cccc(c32)N5c2ccccc2)cc1 ; c1ccc(CCN2c3cc4c(cc3B3c5ccccc5Oc5cccc2c53)B2c3ccccc3Oc3cc5c(c(c32)N4CCc2ccccc2)B2c3ccccc3N(c3ccccc3)c3cccc(c32)O5)cc1] 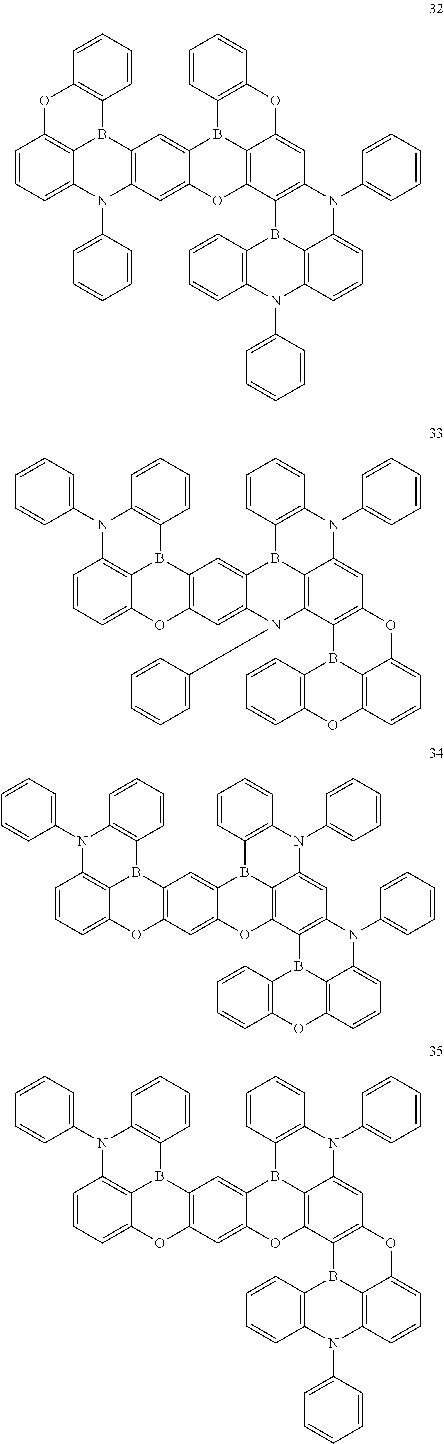 [SMILES: c1ccc(N2c3cc4c(cc3B3c5ccccc5Oc5cccc2c53)B2c3ccccc3Oc3cc5c(c(c32)O4)B2c3ccccc3N(c3ccccc3)c3cccc(c32)N5c2ccccc2)cc1 ; c1ccc(CCN2c3cc4c(cc3B3c5ccccc5N(c5ccccc5)c5cc6c(c2c53)B2c3ccccc3Oc3cccc(c32)O6)B2c3ccccc3N(c3ccccc3)c3cccc(c32)O4)cc1 ; c1ccc(N2c3ccccc3B3c4cc5c(cc4Oc4cccc2c43)Oc2c3c(cc4c2B2c6ccccc6Oc6cccc(c62)N4c2ccccc2)N(c2ccccc2)c2ccccc2B53)cc1 ; c1ccc(N2c3ccccc3B3c4cc5c(cc4Oc4cccc2c43)Oc2c3c(cc4c2B5c2ccccc2N4c2ccccc2)Oc2cccc4c2B3c2ccccc2N4c2ccccc2)cc1] 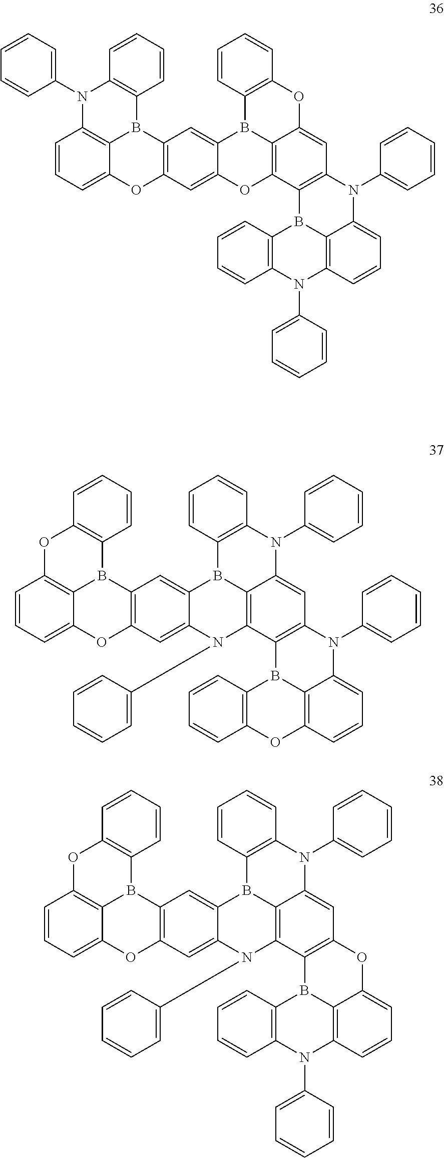 [SMILES: c1ccc(N2c3ccccc3B3c4cc5c(cc4Oc4cccc2c43)Oc2c3c(cc4c2B2c6ccccc6N(c6ccccc6)c6cccc(c62)N4c2ccccc2)Oc2ccccc2B53)cc1 ; c1ccc(CCN2c3cc4c(cc3B3c5ccccc5N(c5ccccc5)c5cc6c(c2c53)B2c3ccccc3Oc3cccc(c32)N6c2ccccc2)B2c3ccccc3Oc3cccc(c32)O4)cc1 ; c1ccc(CCN2c3cc4c(cc3B3c5ccccc5N(c5ccccc5)c5cc6c(c2c53)B2c3ccccc3N(c3ccccc3)c3cccc(c32)O6)B2c3ccccc3Oc3cccc(c32)O4)cc1] 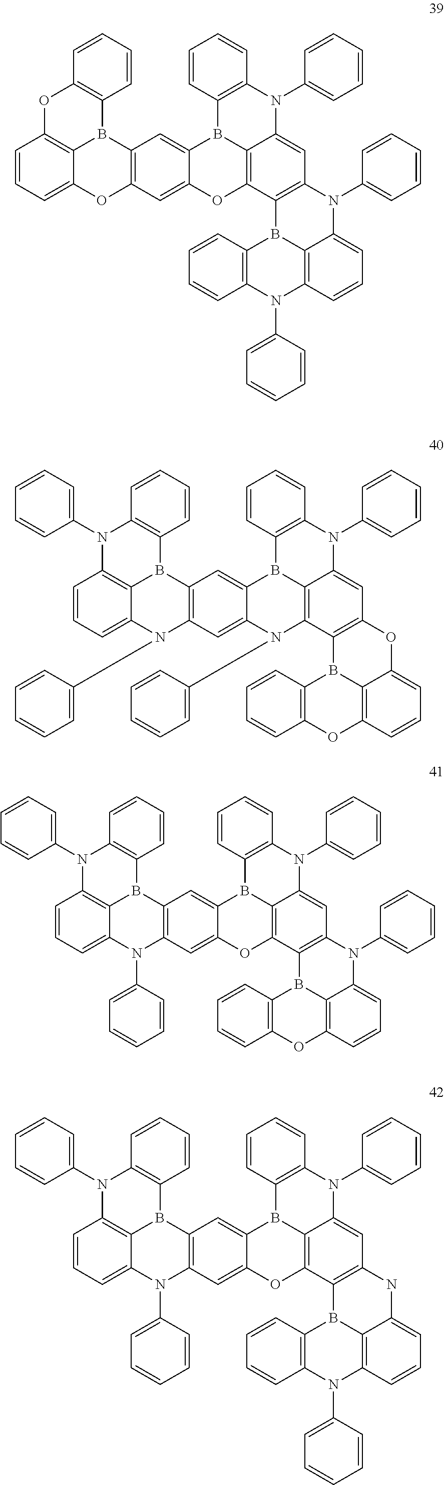 [SMILES: c1ccc(N2c3ccccc3B3c4c2cccc4N(c2ccccc2)c2cc4c5c(c23)Oc2cc3c(cc2B5c2ccccc2N4c2ccccc2)B2c4ccccc4Oc4cccc(c42)O3)cc1 ; c1ccc(CCN2c3cc4c(cc3B3c5ccccc5N(c5ccccc5)c5cccc2c53)B2c3ccccc3N(c3ccccc3)c3cc5c(c(c32)N4CCc2ccccc2)B2c3ccccc3Oc3cccc(c32)O5)cc1 ; c1ccc(N2c3ccccc3B3c4cc5c(cc4N(c4ccccc4)c4cccc2c43)Oc2c3c(cc4c2B2c6ccccc6Oc6cccc(c62)N4c2ccccc2)N(c2ccccc2)c2ccccc2B53)cc1 ; c1ccc(N2c3ccccc3B3c4c(cccc42)Nc2cc4c5c(c23)Oc2cc3c(cc2B5c2ccccc2N4c2ccccc2)B2c4ccccc4N(c4ccccc4)c4cccc(c42)N3c2ccccc2)cc1] 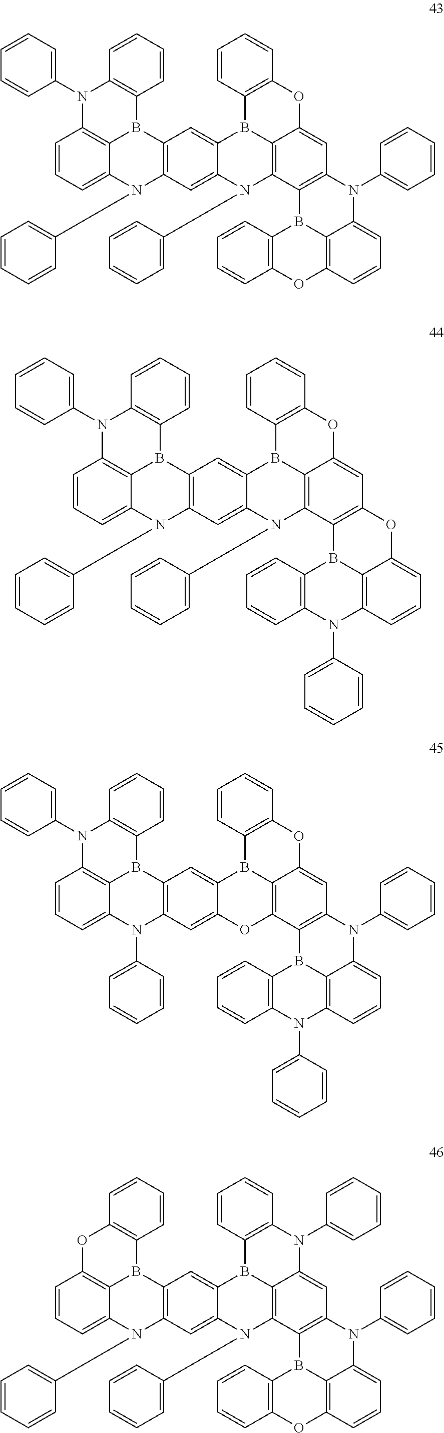 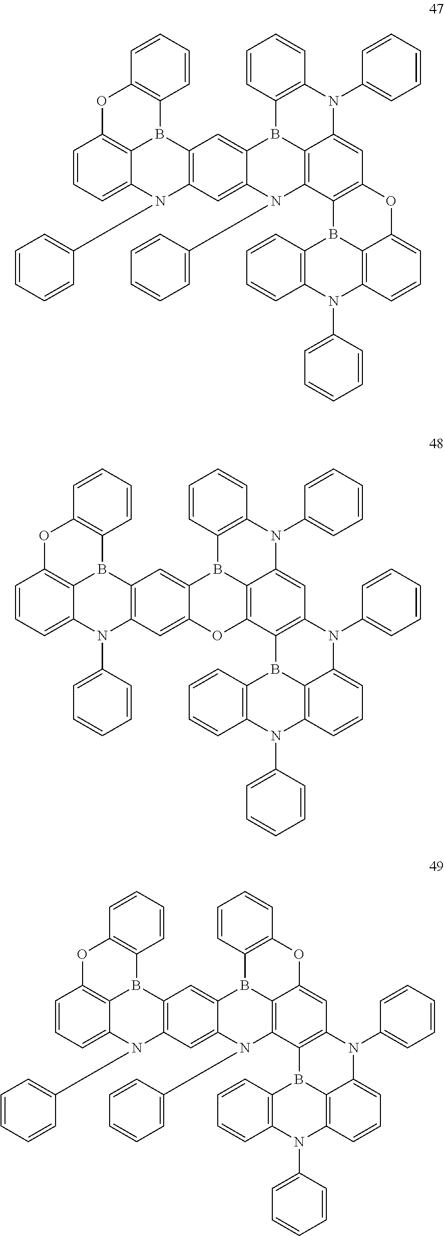 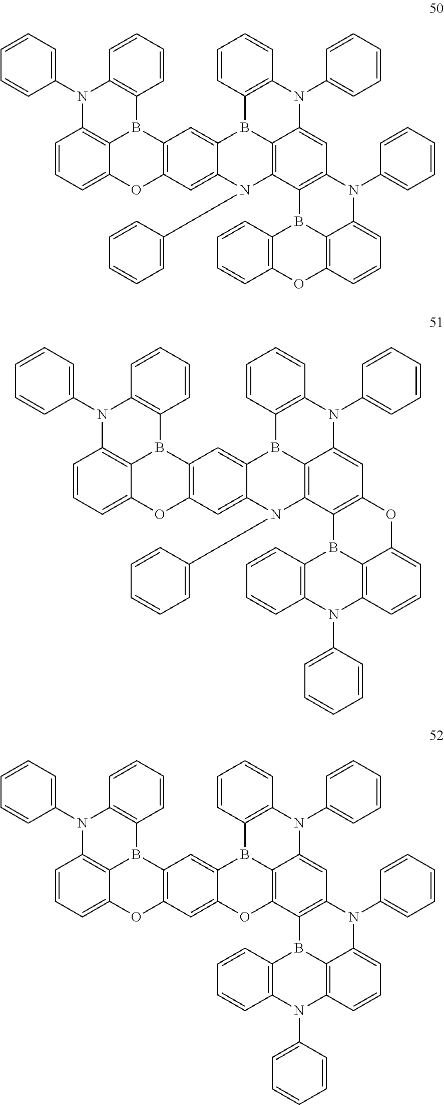 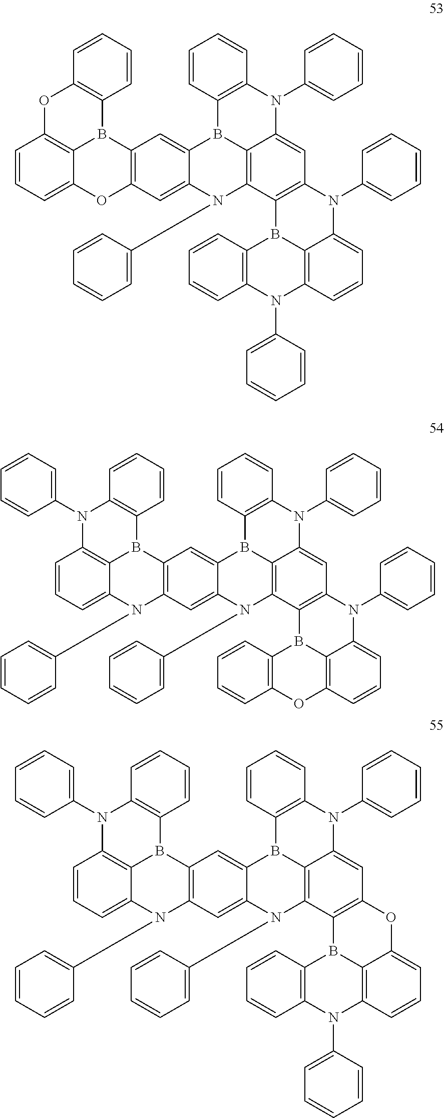 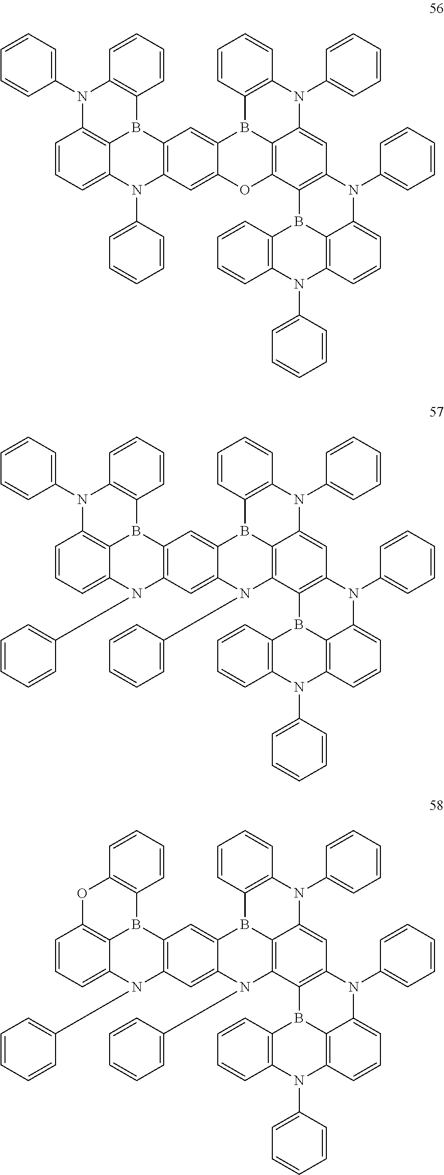 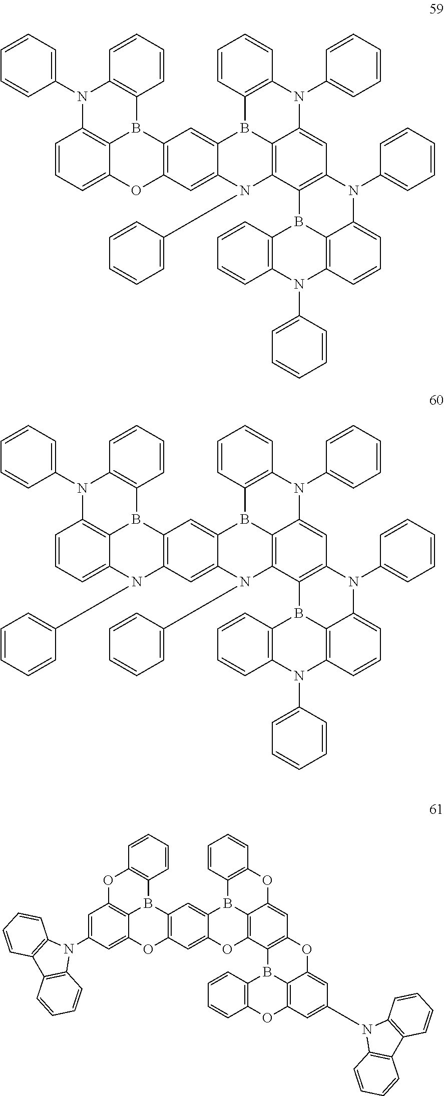 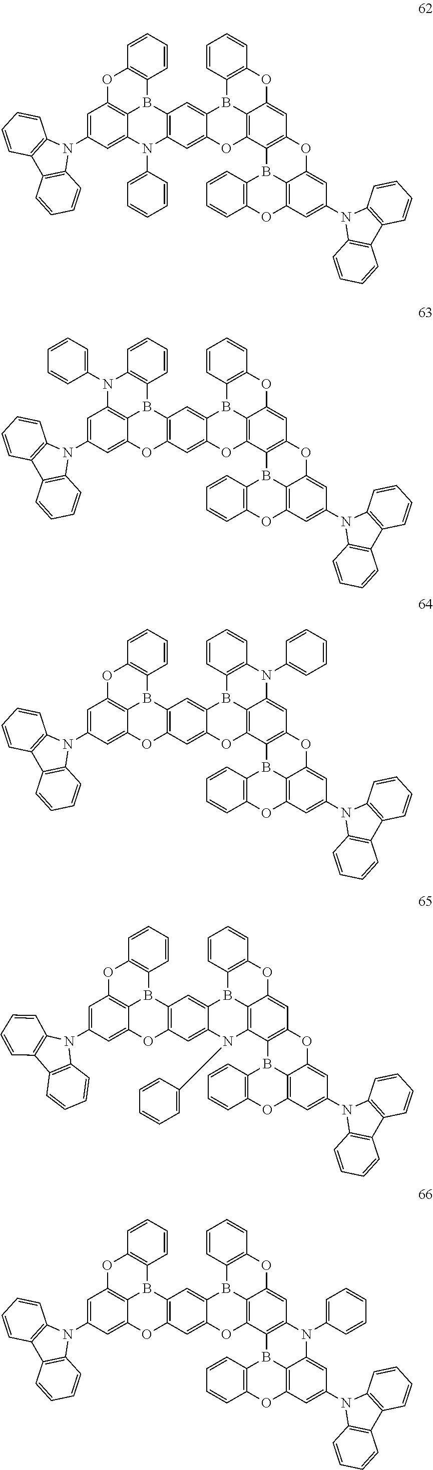 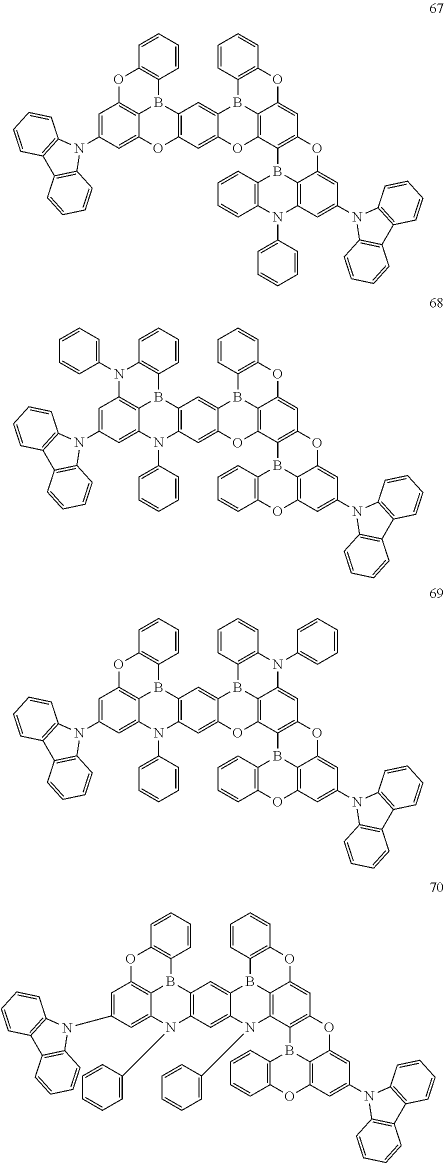 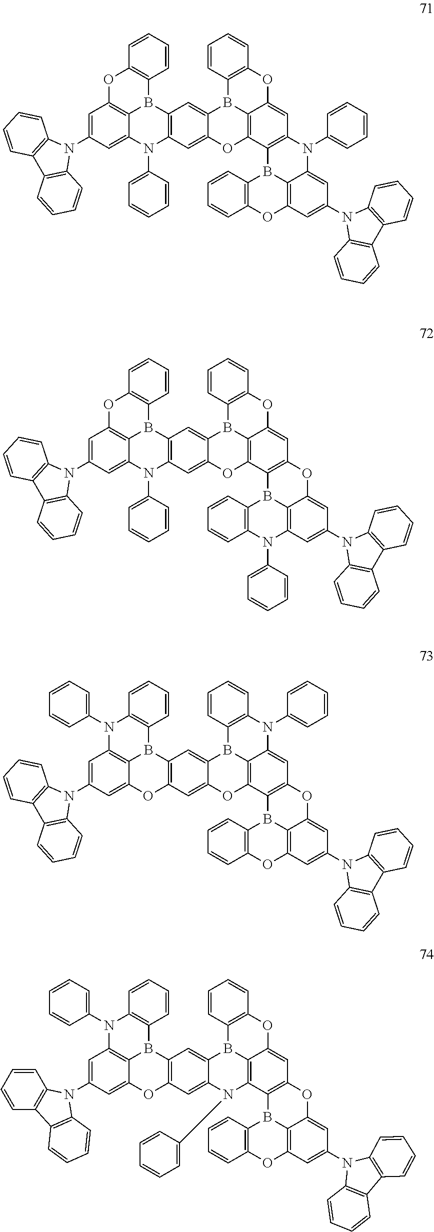 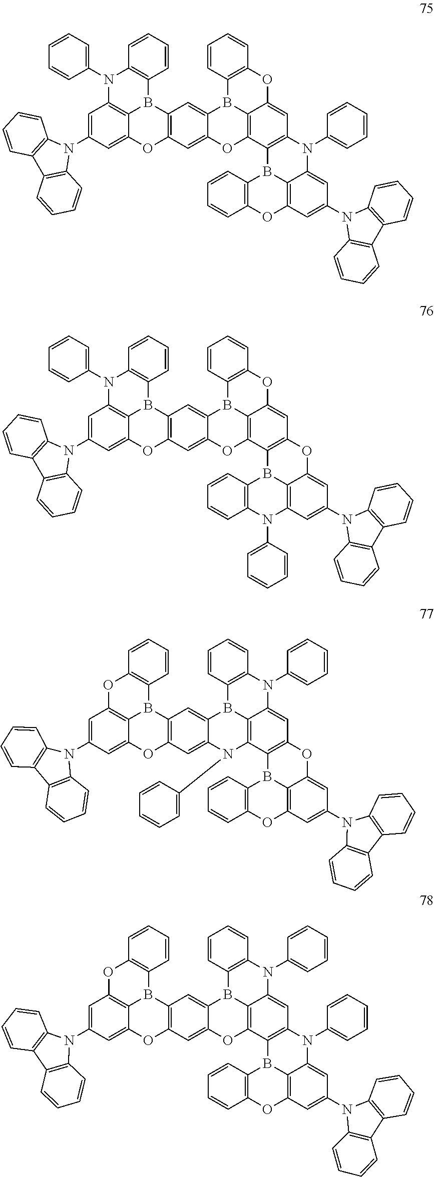 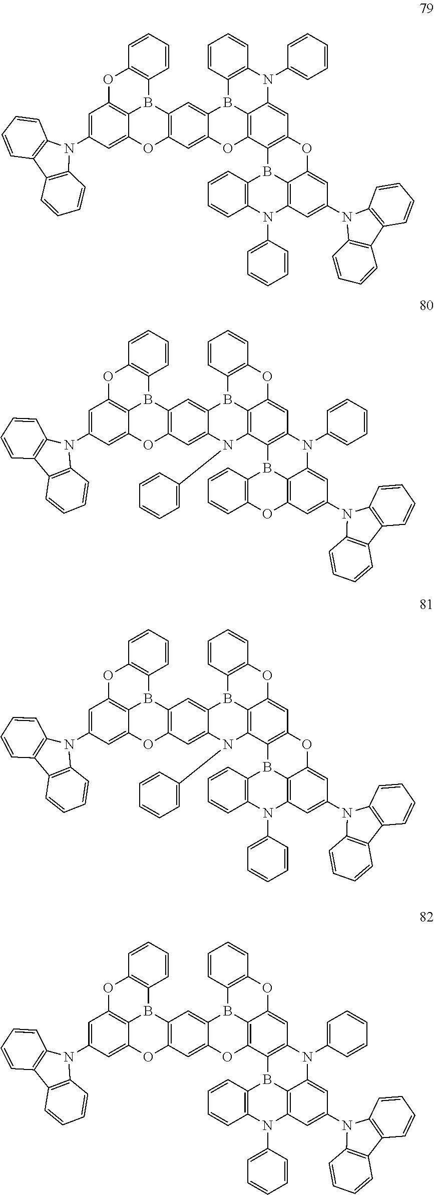 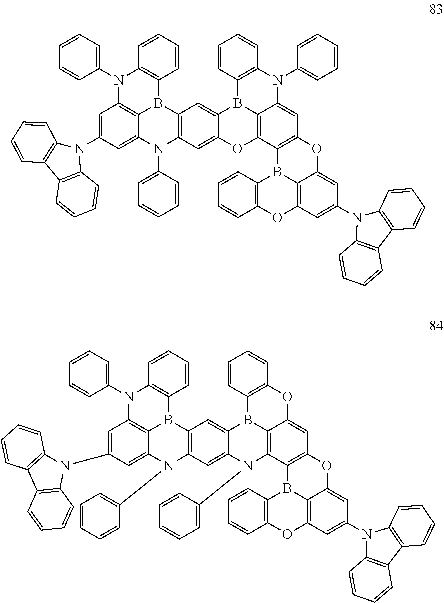 [SMILES: c1ccc(N2c3ccccc3B3c4cc5c(cc4N(c4ccccc4)c4cc(-n6c7ccccc7c7ccccc76)cc2c43)Oc2c3c(cc4c2B5c2ccccc2N4c2ccccc2)Oc2cc(-n4c5ccccc5c5ccccc54)cc4c2B3c2ccccc2O4)cc1 ; c1ccc(N2c3ccccc3B3c4cc5c(cc4N(c4ccccc4)c4cc(Cn6c7ccccc7c7ccccc76)cc2c43)N(c2ccccc2)c2c3c(cc4c2B2c6ccccc6Oc6cc(-n7c8ccccc8c8ccccc87)cc(c62)O4)Oc2ccccc2B53)cc1] 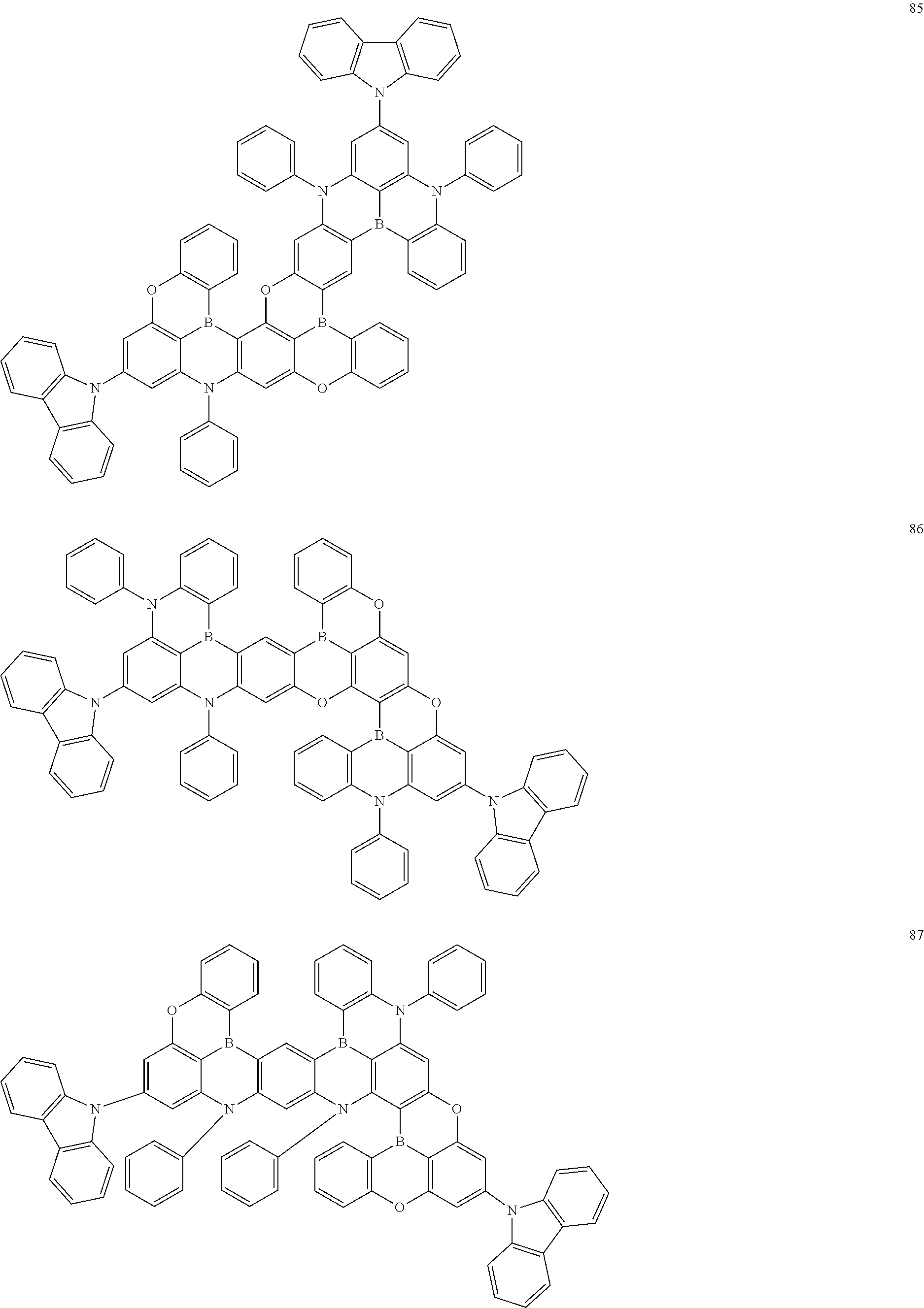 [SMILES: c1ccc(N2c3ccccc3B3c4cc5c(cc4N(c4ccccc4)c4cc(-n6c7ccccc7c7ccccc76)cc2c43)Oc2c3c(cc4c2B2c6ccccc6Oc6cc(-n7c8ccccc8c8ccccc87)cc(c62)N4c2ccccc2)Oc2ccccc2B53)cc1 ; c1ccc(N2c3ccccc3B3c4c(cc(-n5c6ccccc6c6ccccc65)cc42)Oc2cc4c5c(c23)Oc2cc3c(cc2B5c2ccccc2O4)B2c4ccccc4N(c4ccccc4)c4cc(-n5c6ccccc6c6ccccc65)cc(c42)N3c2ccccc2)cc1 ; c1ccc(N2c3cc4c(cc3B3c5ccccc5Oc5cc(-n6c7ccccc7c7ccccc76)cc2c53)B2c3ccccc3N(c3ccccc3)c3cc5c(c(c32)N4c2ccccc2)B2c3ccccc3Oc3cc(-n4c6ccccc6c6ccccc64)cc(c32)O5)cc1] 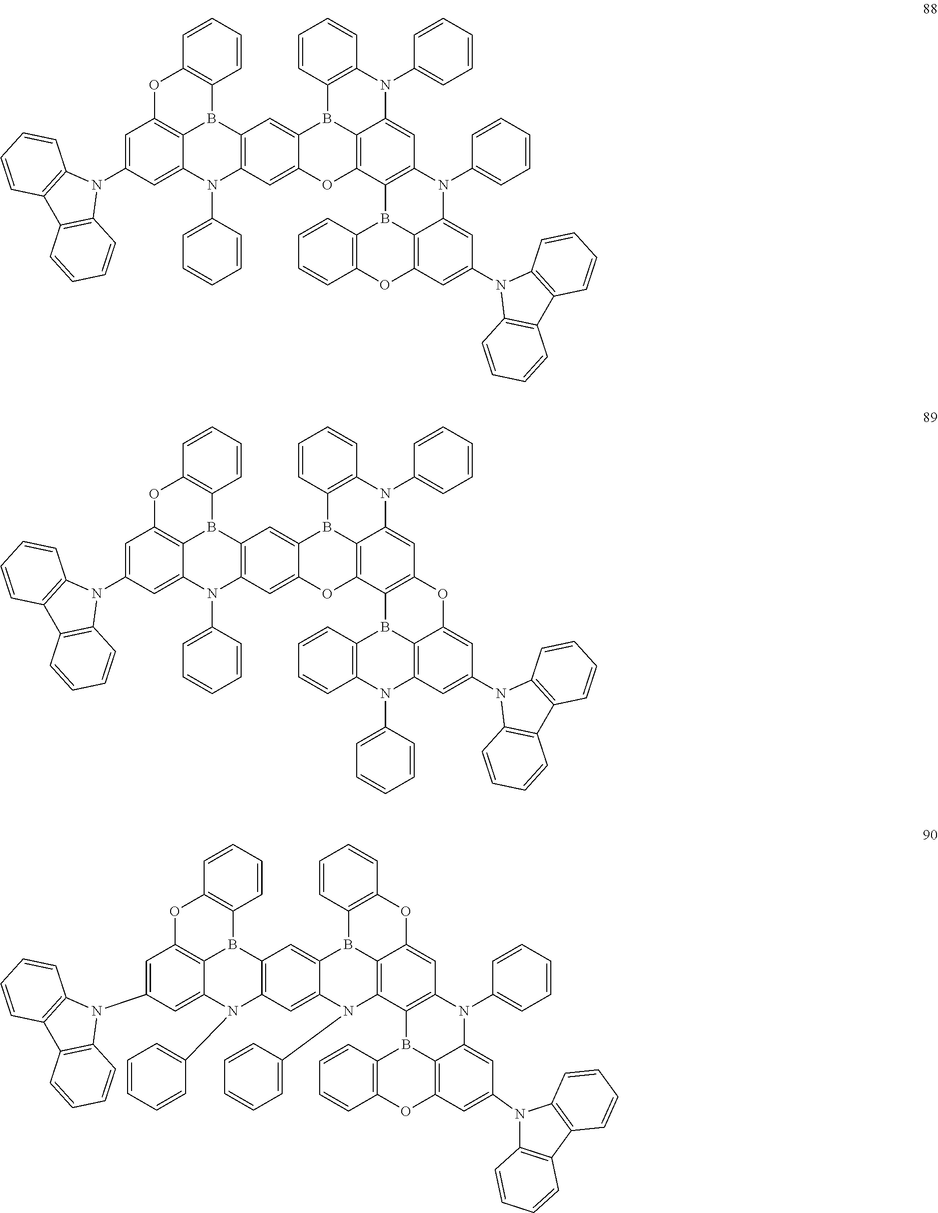 [SMILES: c1ccc(N2c3cc4c(cc3B3c5ccccc5Oc5cc(-n6c7ccccc7c7ccccc76)cc2c53)B2c3ccccc3N(c3ccccc3)c3cc5c(c(c32)O4)B2c3ccccc3Oc3cc(-n4c6ccccc6c6ccccc64)cc(c32)N5c2ccccc2)cc1 ; c1ccc(N2c3cc4c(cc3B3c5ccccc5Oc5cc(-n6c7ccccc7c7ccccc76)cc2c53)B2c3ccccc3N(c3ccccc3)c3cc5c(c(c32)O4)B2c3ccccc3N(c3ccccc3)c3cc(-n4c6ccccc6c6ccccc64)cc(c32)O5)cc1 ; c1ccc(N2c3cc4c(cc3B3c5ccccc5Oc5cc(-n6c7ccccc7c7ccccc76)cc2c53)B2c3ccccc3Oc3cc5c(c(c32)N4c2ccccc2)B2c3ccccc3Oc3cc(-n4c6ccccc6c6ccccc64)cc(c32)N5c2ccccc2)cc1] 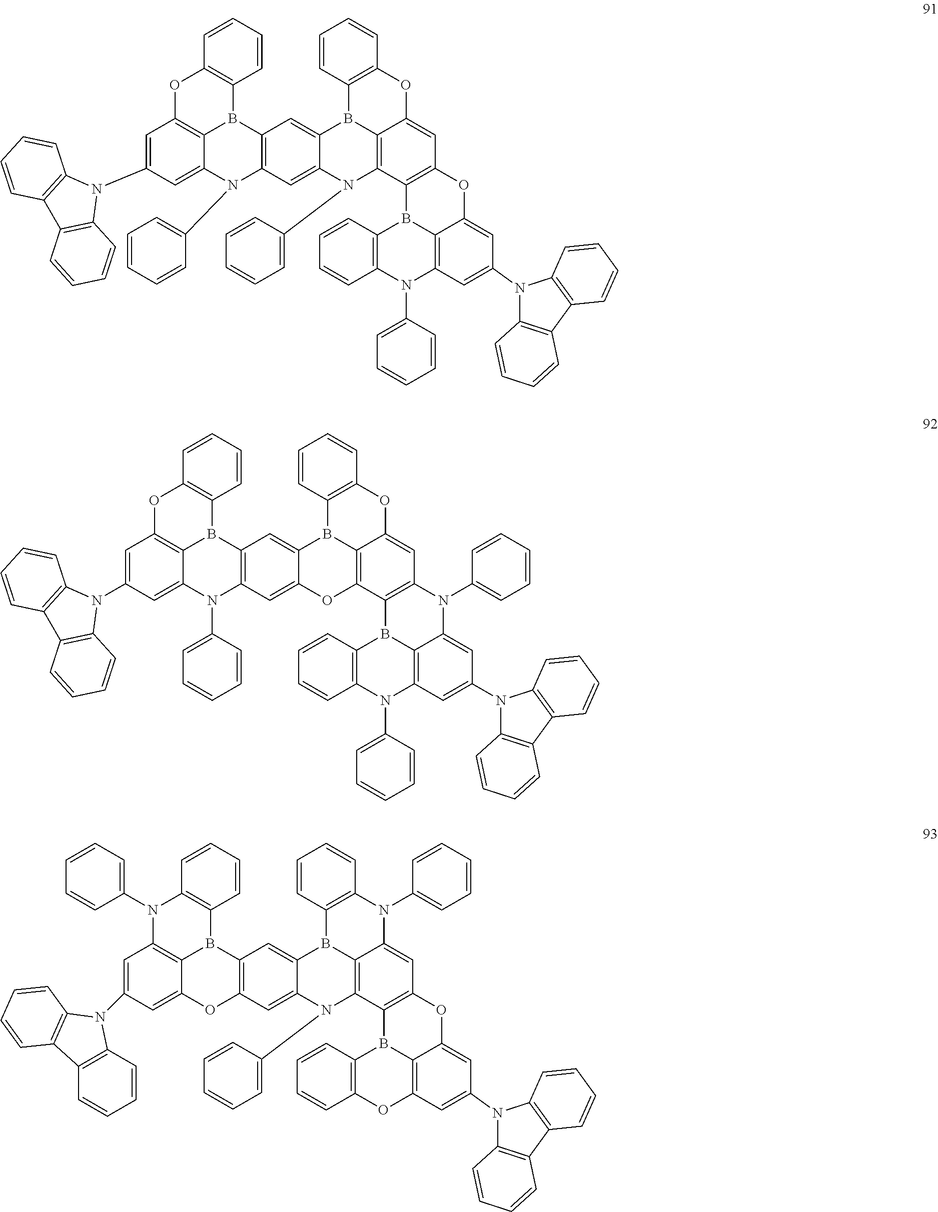 [SMILES: c1ccc(N2c3cc4c(cc3B3c5ccccc5Oc5cc(-n6c7ccccc7c7ccccc76)cc2c53)B2c3ccccc3Oc3cc5c(c(c32)N4c2ccccc2)B2c3ccccc3N(c3ccccc3)c3cc(-n4c6ccccc6c6ccccc64)cc(c32)O5)cc1 ; c1ccc(N2c3cc4c(cc3B3c5ccccc5Oc5cc(-n6c7ccccc7c7ccccc76)cc2c53)B2c3ccccc3Oc3cc5c(c(c32)O4)B2c3ccccc3N(c3ccccc3)c3cc(-n4c6ccccc6c6ccccc64)cc(c32)N5c2ccccc2)cc1 ; c1ccc(N2c3ccccc3B3c4cc5c(cc4Oc4cc(-n6c7ccccc7c7ccccc76)cc2c43)N(c2ccccc2)c2c3c(cc4c2B5c2ccccc2N4c2ccccc2)Oc2cc(-n4c5ccccc5c5ccccc54)cc4c2B3c2ccccc2O4)cc1] 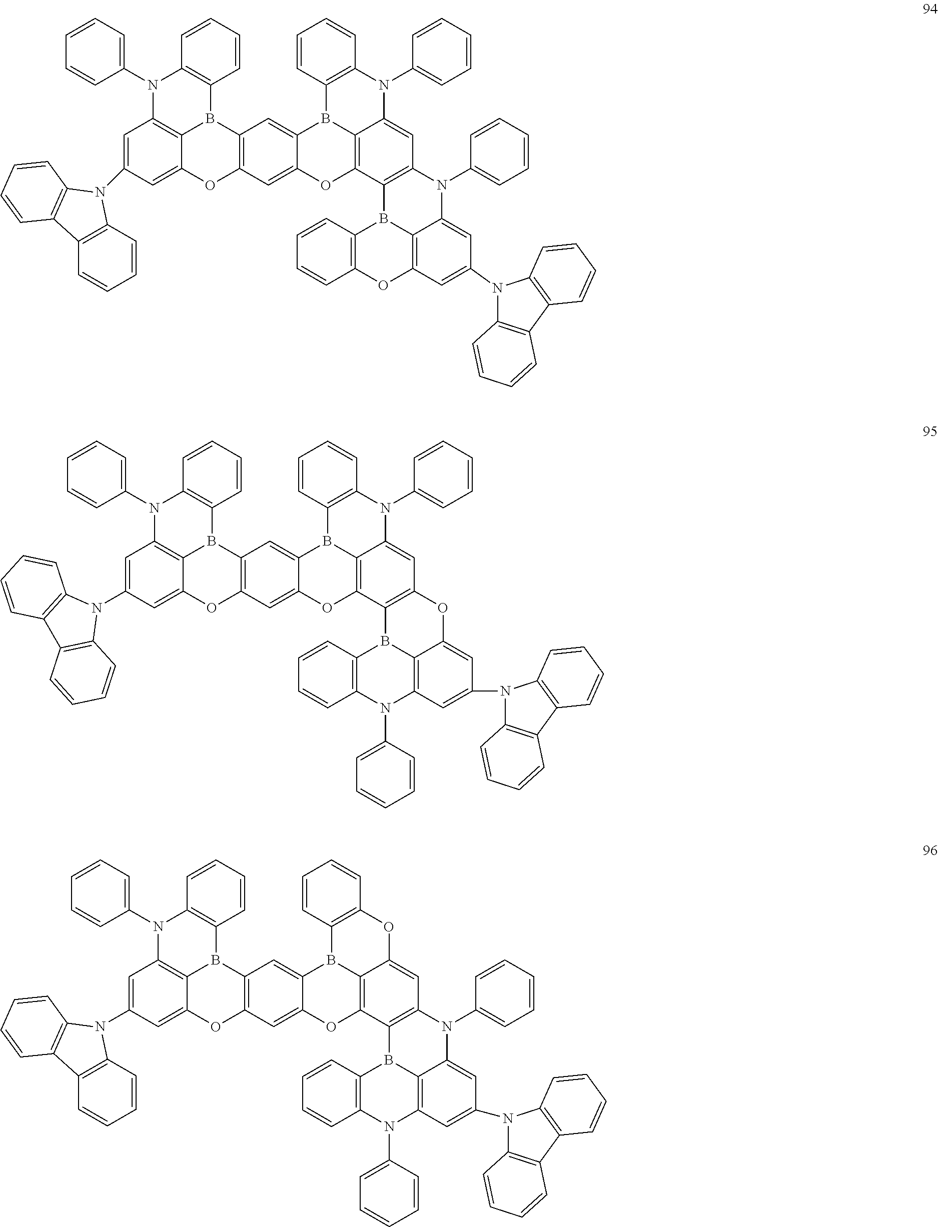 [SMILES: c1ccc(N2c3ccccc3B3c4cc5c(cc4Oc4cc(-n6c7ccccc7c7ccccc76)cc2c43)Oc2c3c(cc4c2B2c6ccccc6Oc6cc(-n7c8ccccc8c8ccccc87)cc(c62)N4c2ccccc2)N(c2ccccc2)c2ccccc2B53)cc1 ; c1ccc(N2c3ccccc3B3c4cc5c(cc4Oc4cc(-n6c7ccccc7c7ccccc76)cc2c43)Oc2c3c(cc4c2B5c2ccccc2N4c2ccccc2)Oc2cc(-n4c5ccccc5c5ccccc54)cc4c2B3c2ccccc2N4c2ccccc2)cc1 ; c1ccc(N2c3ccccc3B3c4cc5c(cc4Oc4cc(-n6c7ccccc7c7ccccc76)cc2c43)Oc2c3c(cc4c2B2c6ccccc6N(c6ccccc6)c6cc(-n7c8ccccc8c8ccccc87)cc(c62)N4c2ccccc2)Oc2ccccc2B53)cc1] 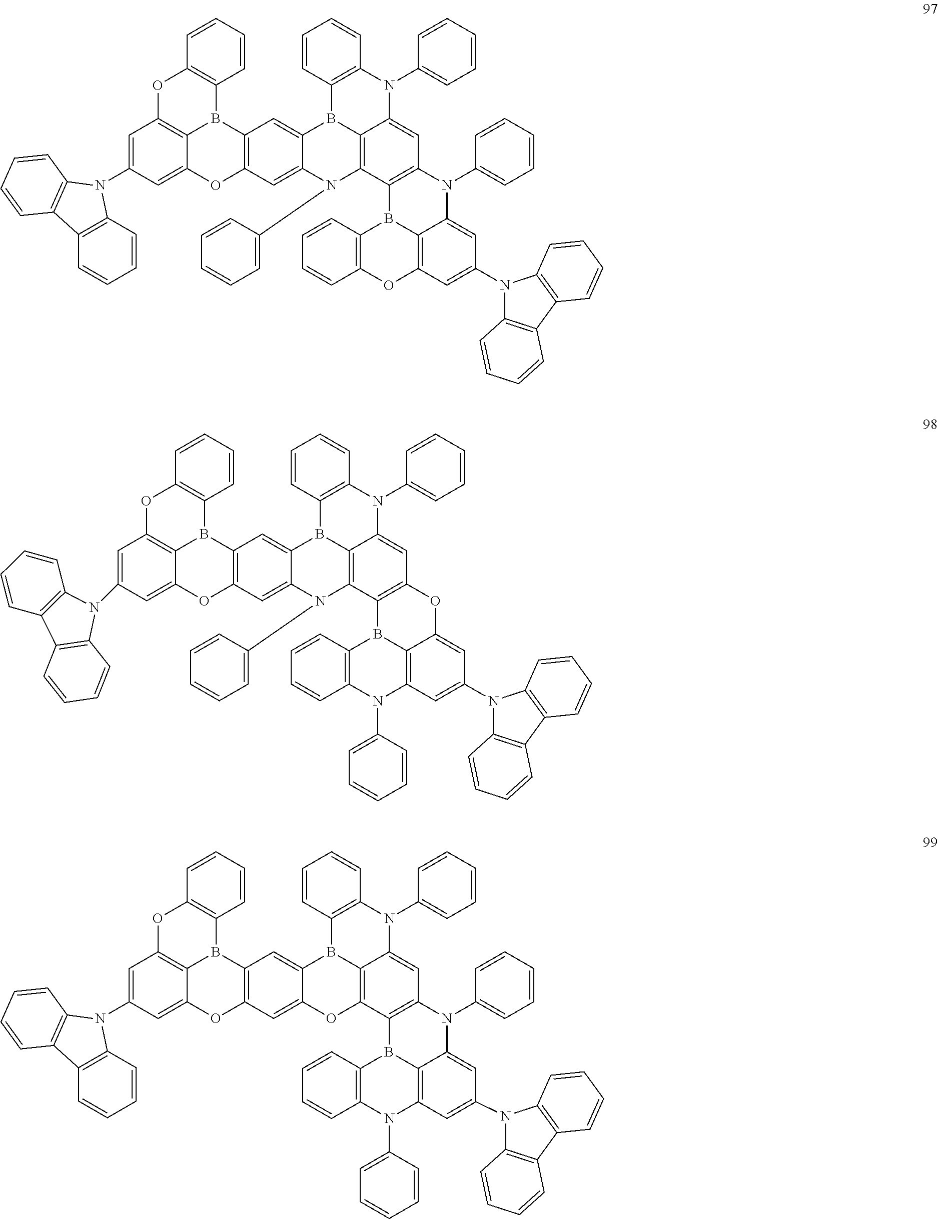 [SMILES: c1ccc(N2c3ccccc3B3c4cc5c(cc4N(c4ccccc4)c4c3c2cc2c4B3c4ccccc4Oc4cc(-n6c7ccccc7c7ccccc76)cc(c43)N2c2ccccc2)Oc2cc(-n3c4ccccc4c4ccccc43)cc3c2B5c2ccccc2O3)cc1 ; c1ccc(N2c3ccccc3B3c4c(cc(-n5c6ccccc6c6ccccc65)cc42)Oc2cc4c5c(c23)N(c2ccccc2)c2cc3c(cc2B5c2ccccc2N4c2ccccc2)B2c4ccccc4Oc4cc(-n5c6ccccc6c6ccccc65)cc(c42)O3)cc1 ; c1ccc(N2c3ccccc3B3c4c2cc(-n2c5ccccc5c5ccccc52)cc4N(c2ccccc2)c2cc4c5c(c23)Oc2cc3c(cc2B5c2ccccc2N4c2ccccc2)B2c4ccccc4Oc4cc(-n5c6ccccc6c6ccccc65)cc(c42)O3)cc1] 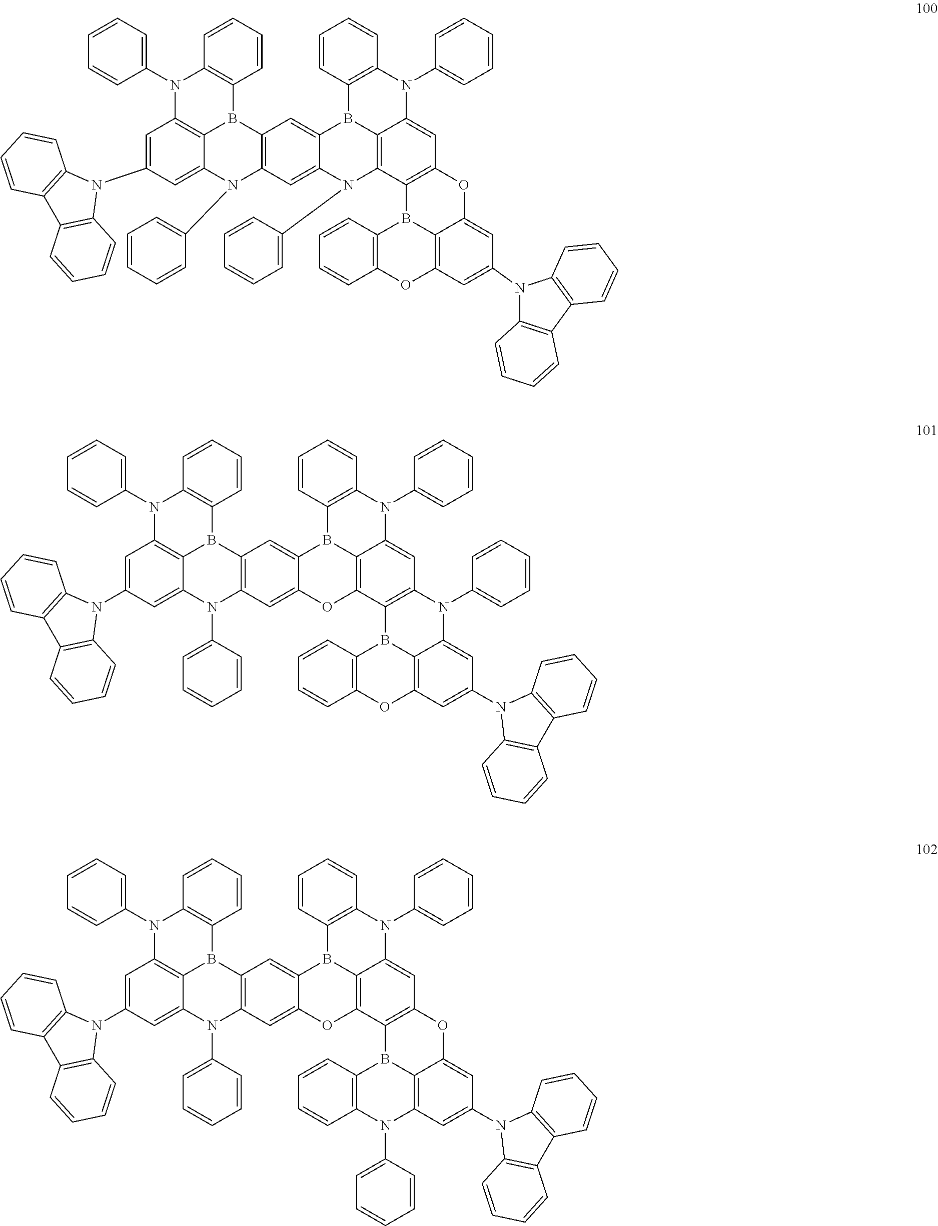 [SMILES: c1ccc(N2c3ccccc3B3c4cc5c(cc4N(c4ccccc4)c4cc(-n6c7ccccc7c7ccccc76)cc2c43)N(c2ccccc2)c2c3c(cc4c2B5c2ccccc2N4c2ccccc2)Oc2cc(-n4c5ccccc5c5ccccc54)cc4c2B3c2ccccc2O4)cc1 ; c1ccc(N2c3ccccc3B3c4cc5c(cc4N(c4ccccc4)c4cc(-n6c7ccccc7c7ccccc76)cc2c43)Oc2c3c(cc4c2B2c6ccccc6Oc6cc(-n7c8ccccc8c8ccccc87)cc(c62)N4c2ccccc2)N(c2ccccc2)c2ccccc2B53)cc1 ; c1ccc(N2c3ccccc3B3c4c(cc(-n5c6ccccc6c6ccccc65)cc42)Oc2cc4c5c(c23)Oc2cc3c(cc2B5c2ccccc2N4c2ccccc2)B2c4ccccc4N(c4ccccc4)c4cc(-n5c6ccccc6c6ccccc65)cc(c42)N3c2ccccc2)cc1] 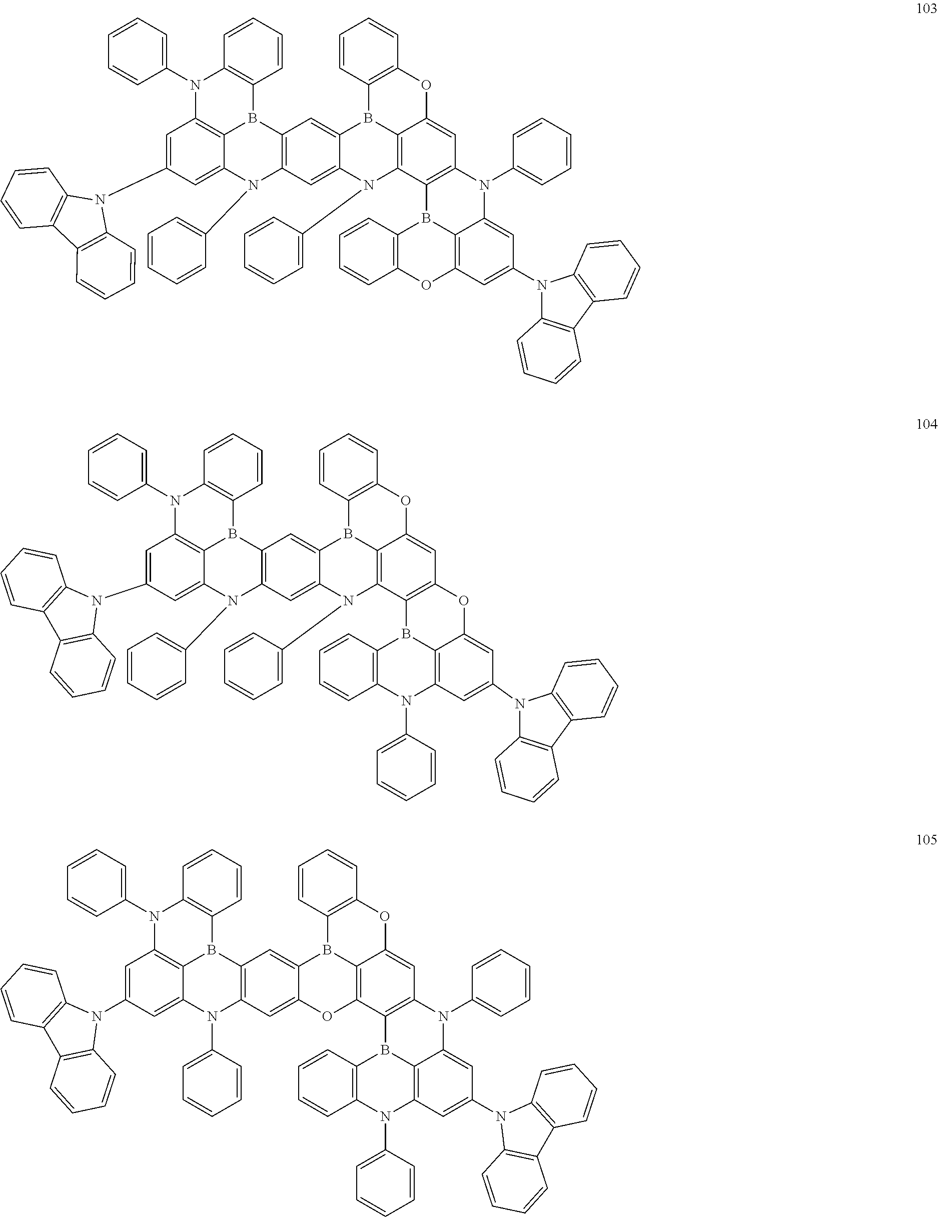 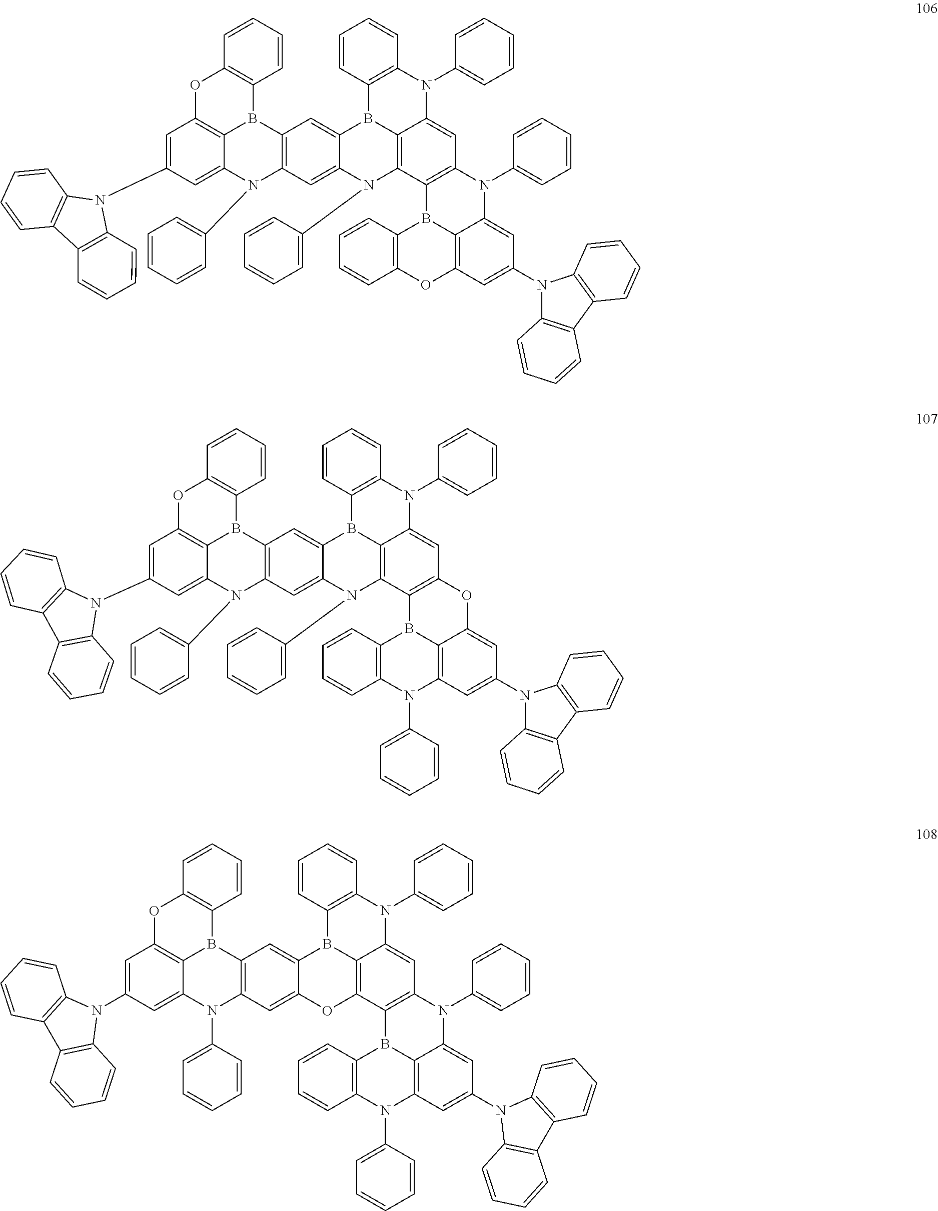 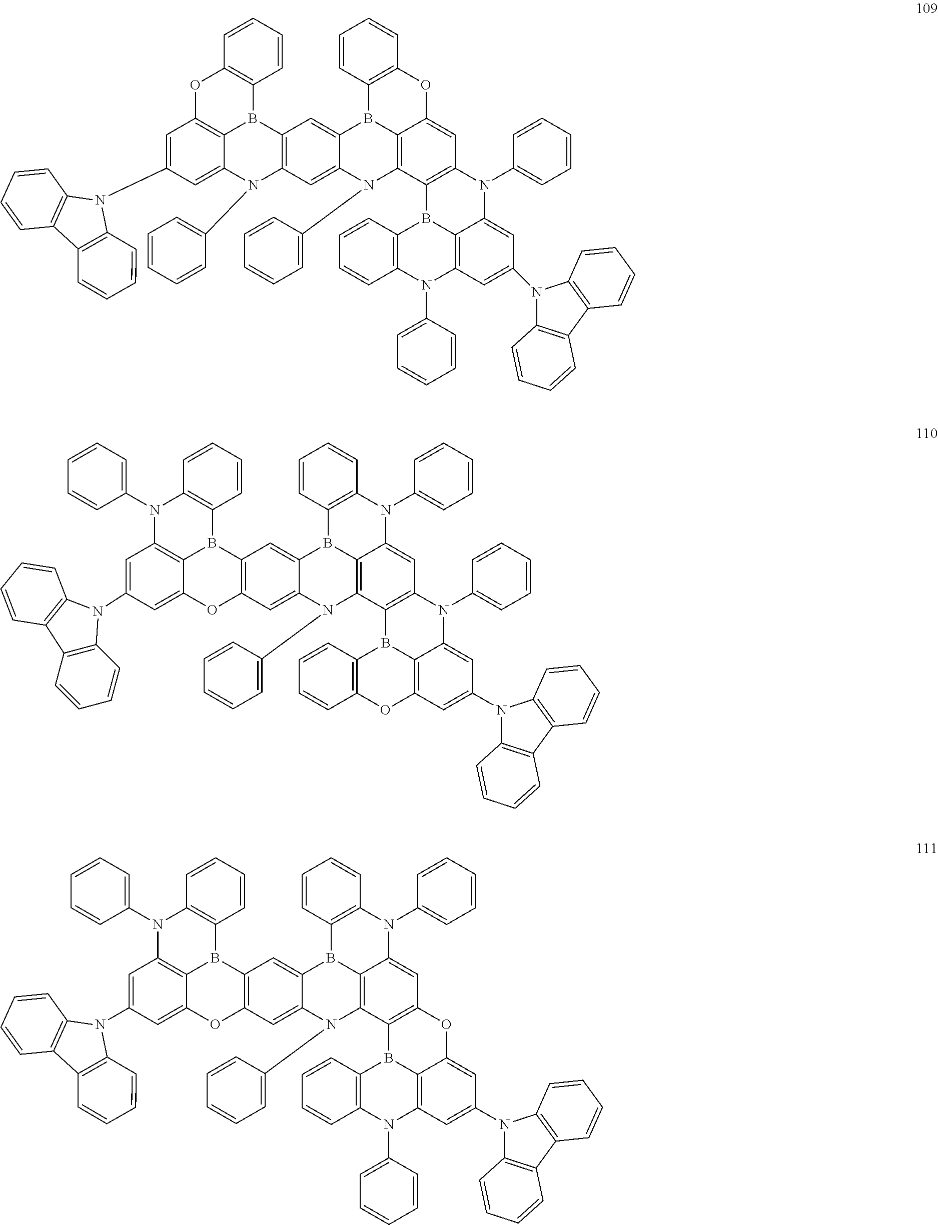 [SMILES: c1ccc(N2c3cc4c(cc3B3c5ccccc5Oc5cc(-n6c7ccccc7c7ccccc76)cc2c53)B2c3ccccc3Oc3cc5c(c(c32)N4c2ccccc2)B2c3ccccc3N(c3ccccc3)c3cc(-n4c6ccccc6c6ccccc64)cc(c32)N5c2ccccc2)cc1 ; c1ccc(N2c3ccccc3B3c4cc5c(cc4Oc4cc(-n6c7ccccc7c7ccccc76)cc2c43)N(c2ccccc2)c2c3c(cc4c2B2c6ccccc6Oc6cc(-n7c8ccccc8c8ccccc87)cc(c62)N4c2ccccc2)N(c2ccccc2)c2ccccc2B53)cc1 ; c1ccc(N2c3ccccc3B3c4cc5c(cc4Oc4cc(-n6c7ccccc7c7ccccc76)cc2c43)N(c2ccccc2)c2c3c(cc4c2B5c2ccccc2N4c2ccccc2)Oc2cc(-n4c5ccccc5c5ccccc54)cc4c2B3c2ccccc2N4c2ccccc2)cc1] 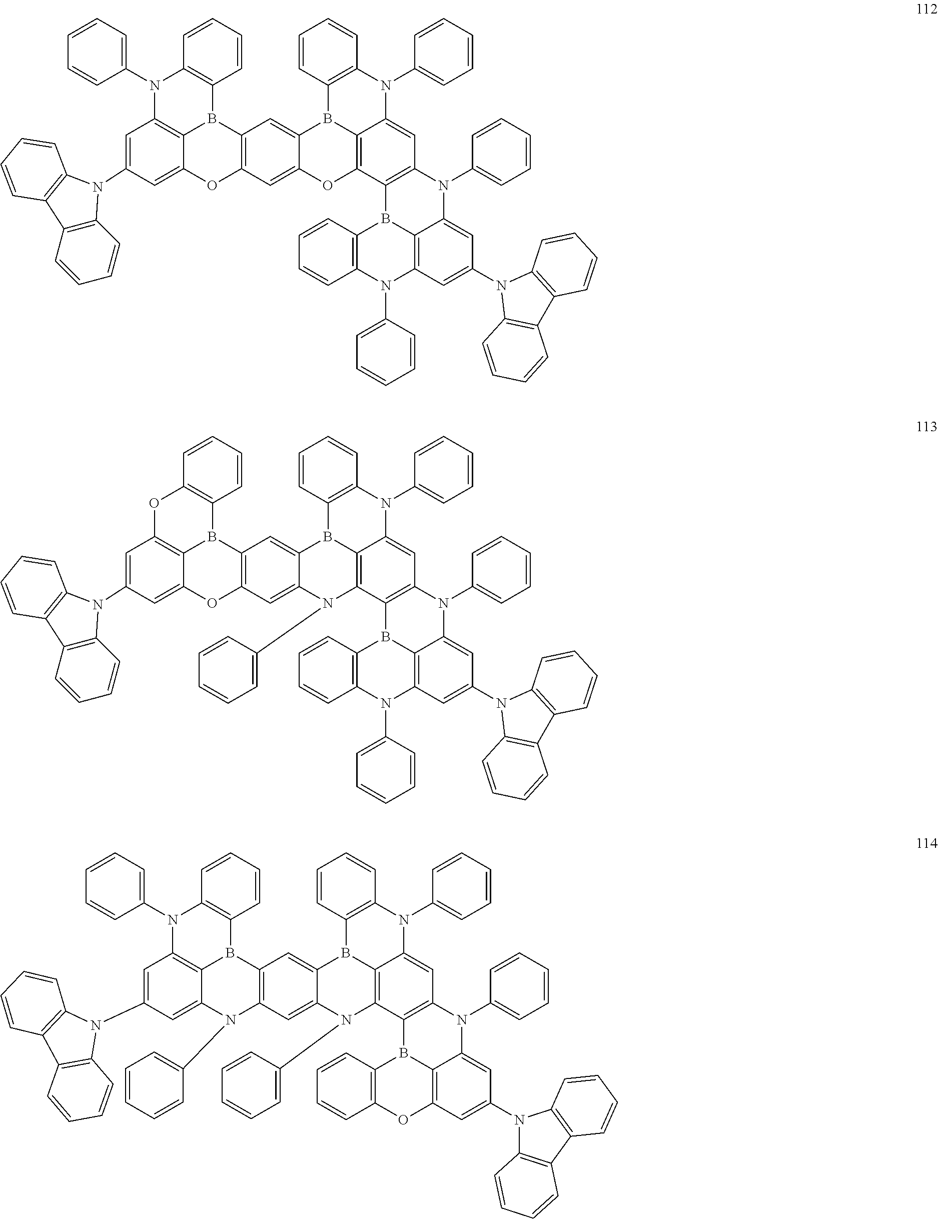 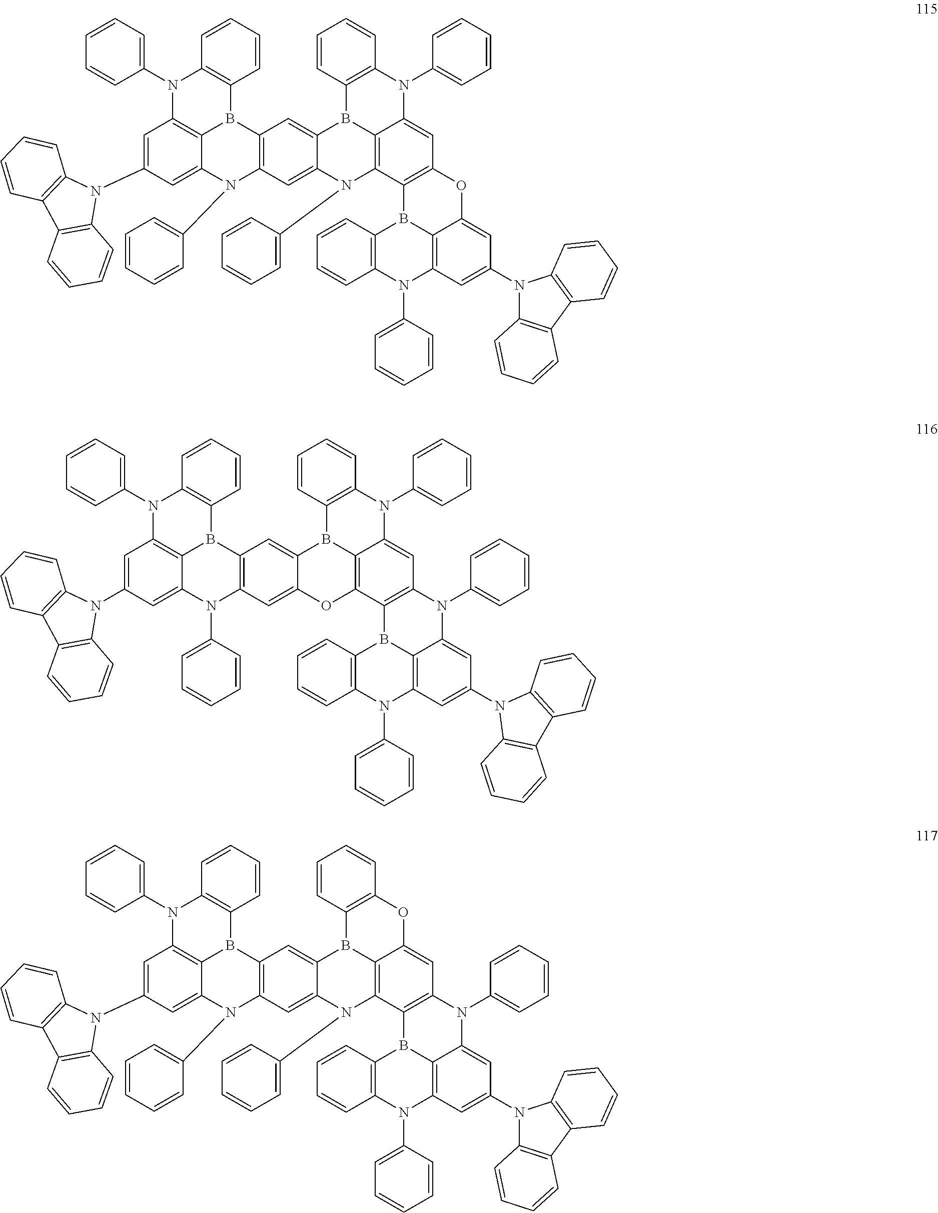 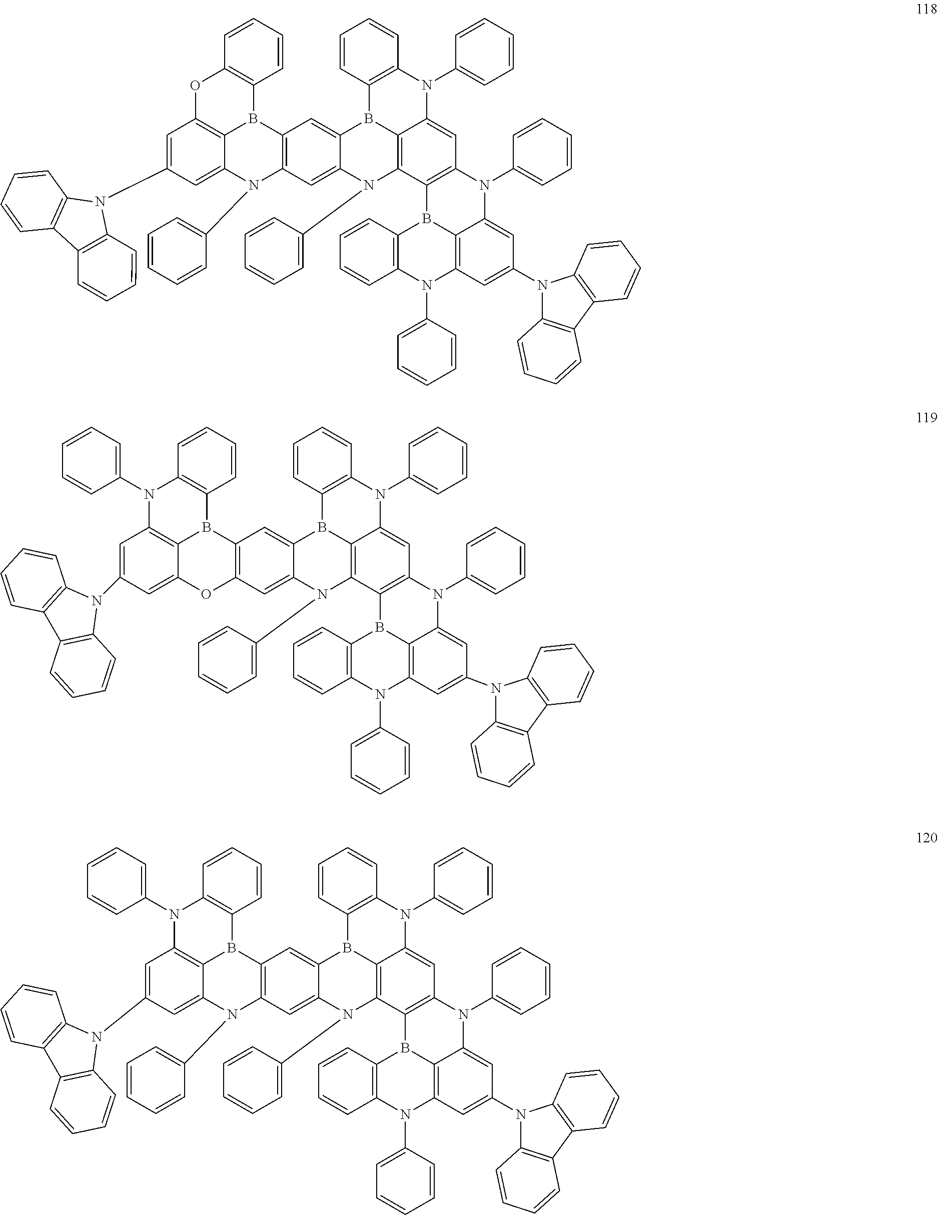 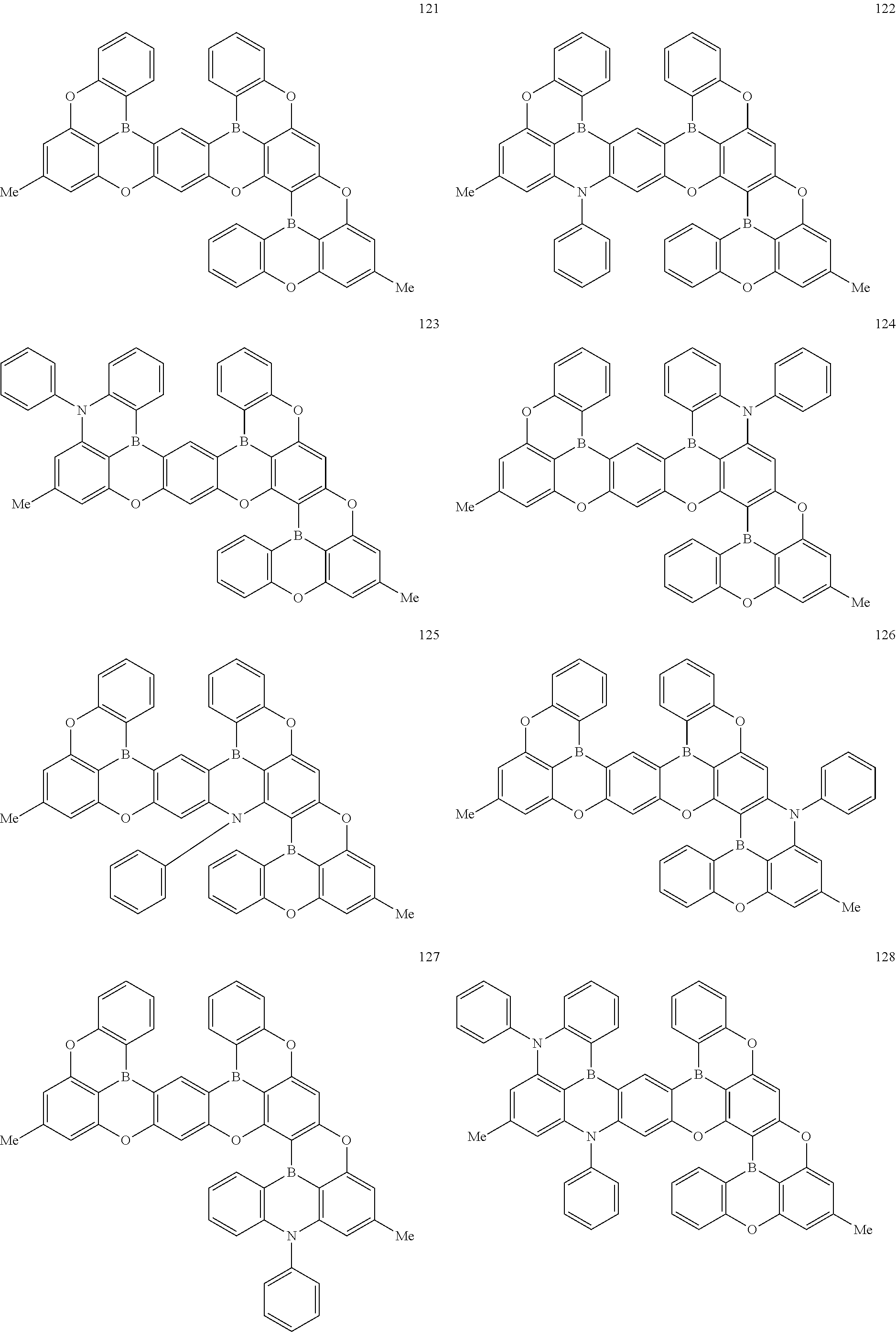 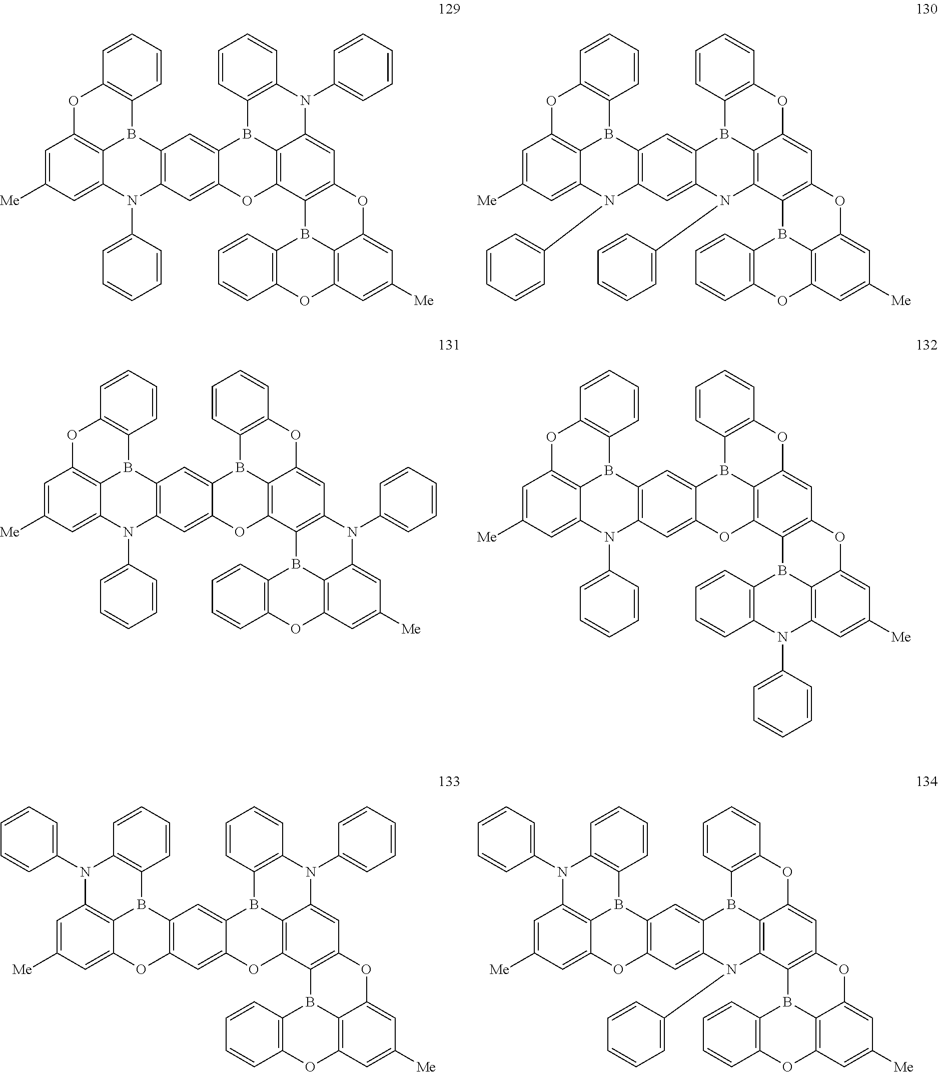 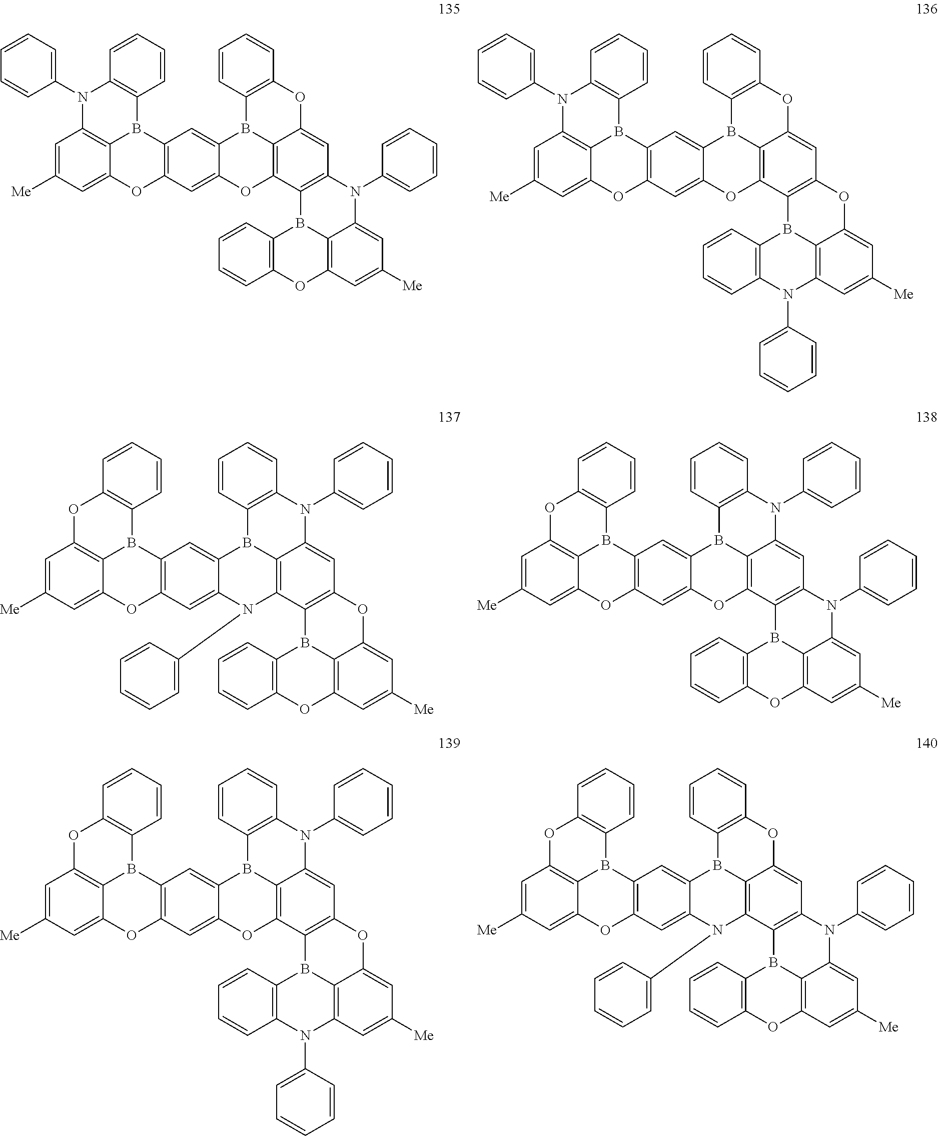 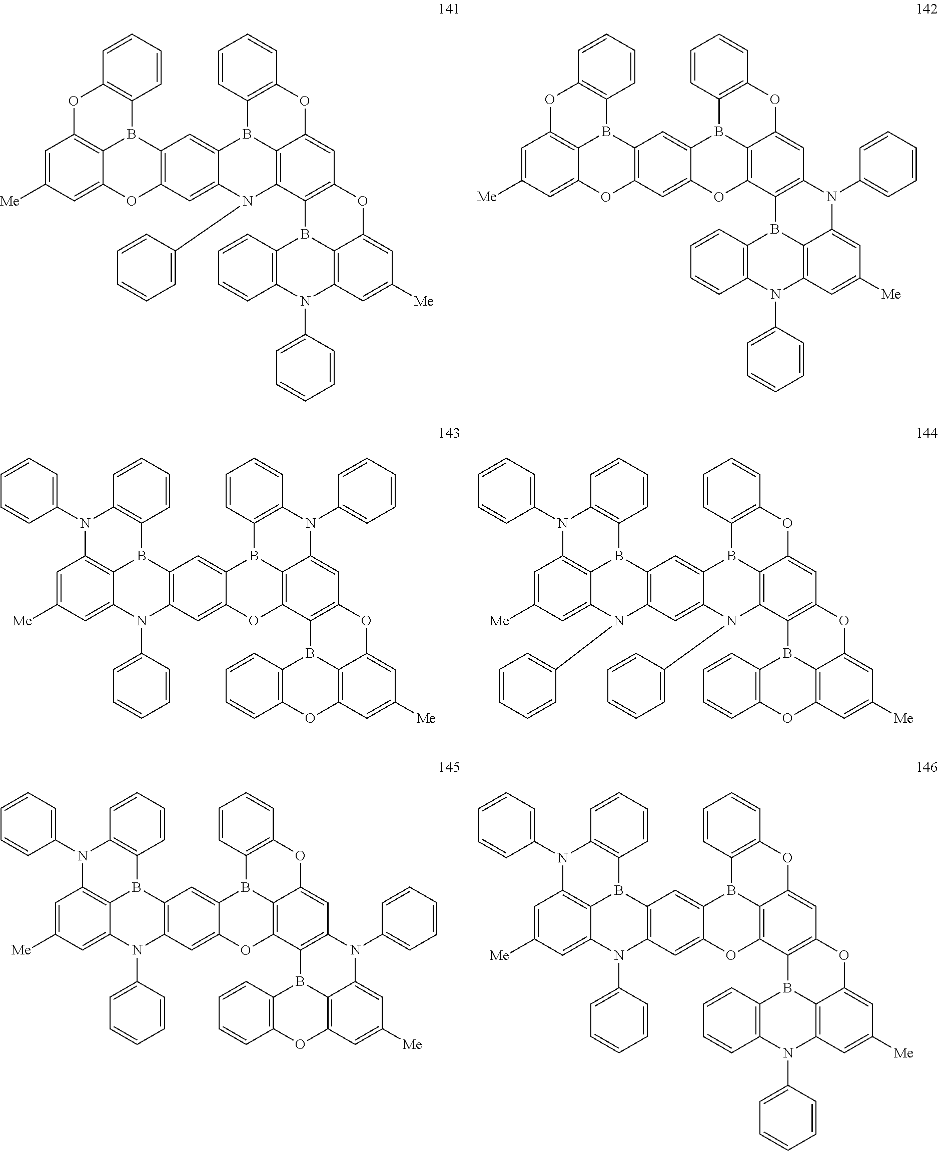 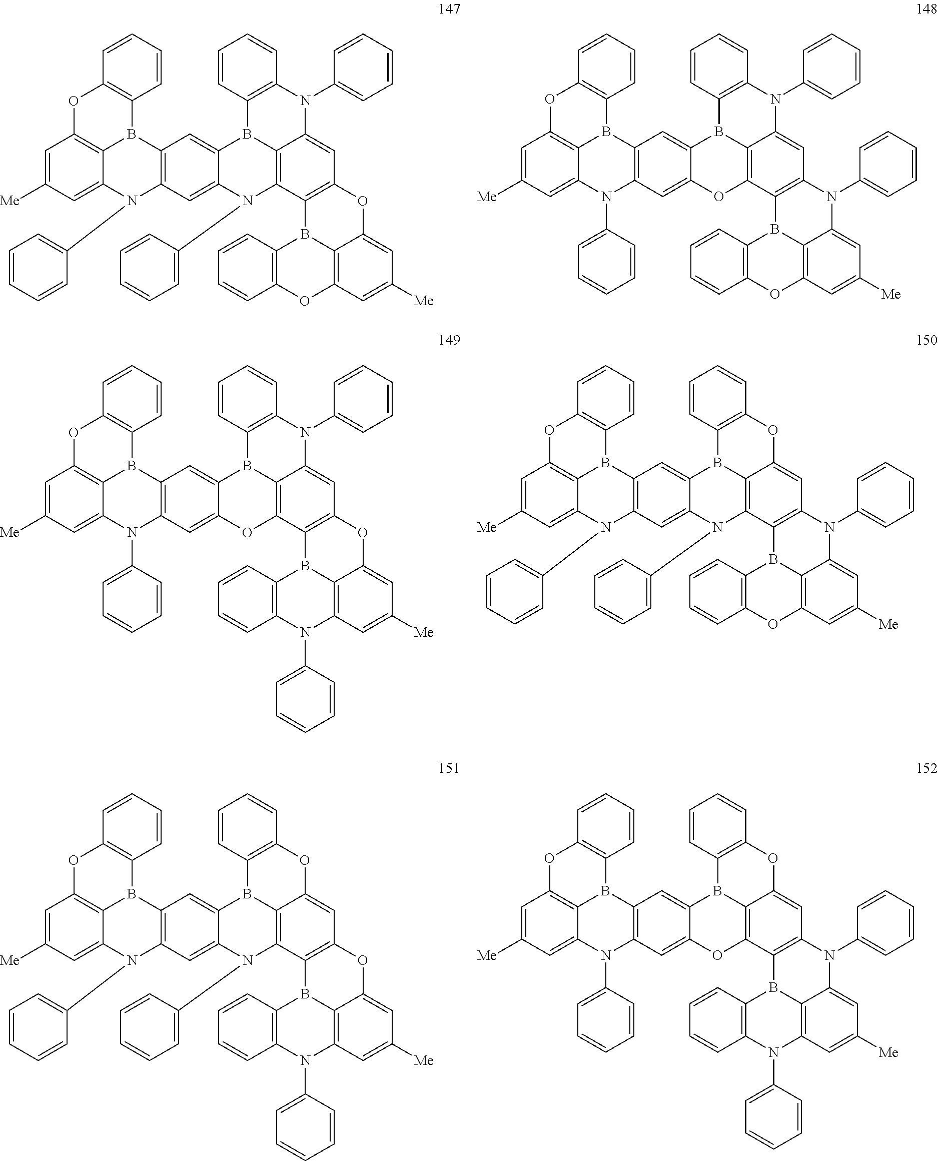 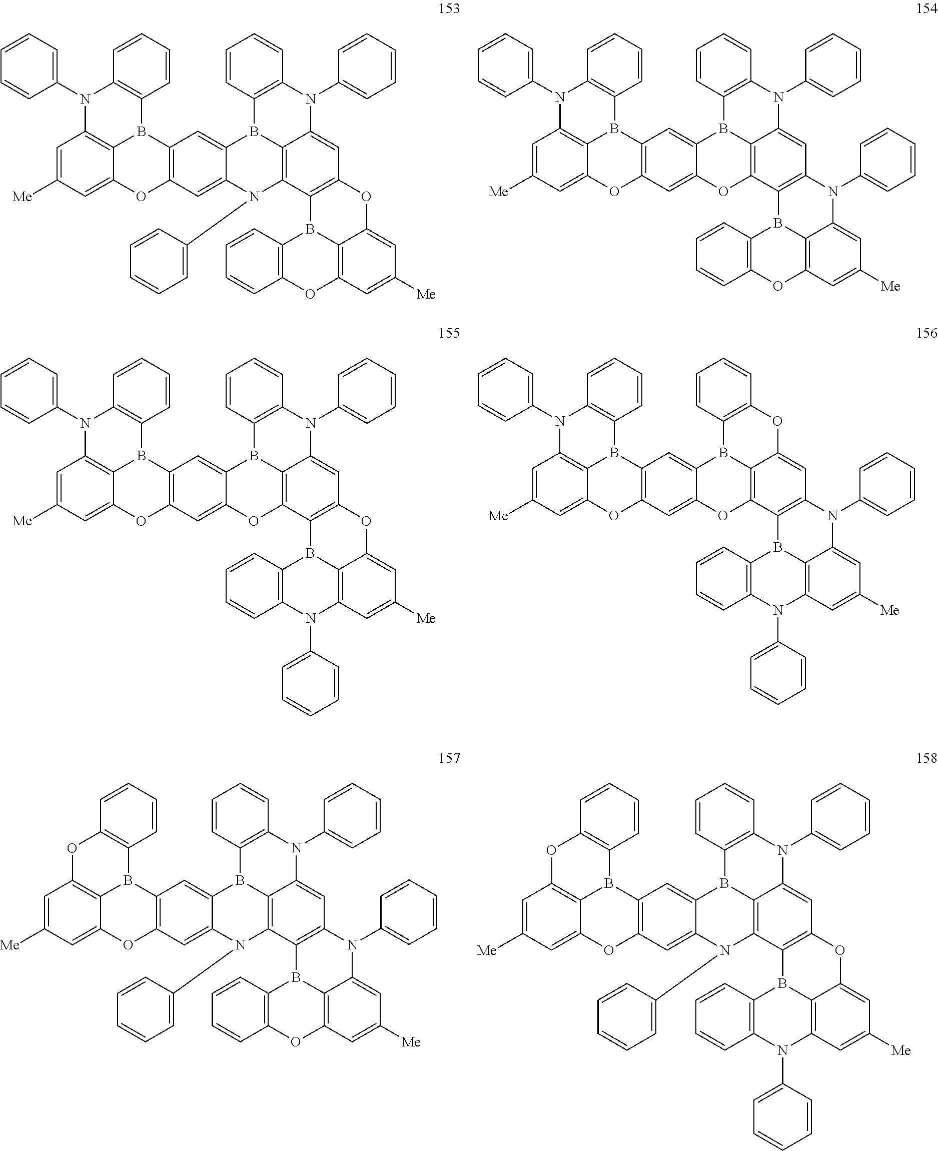 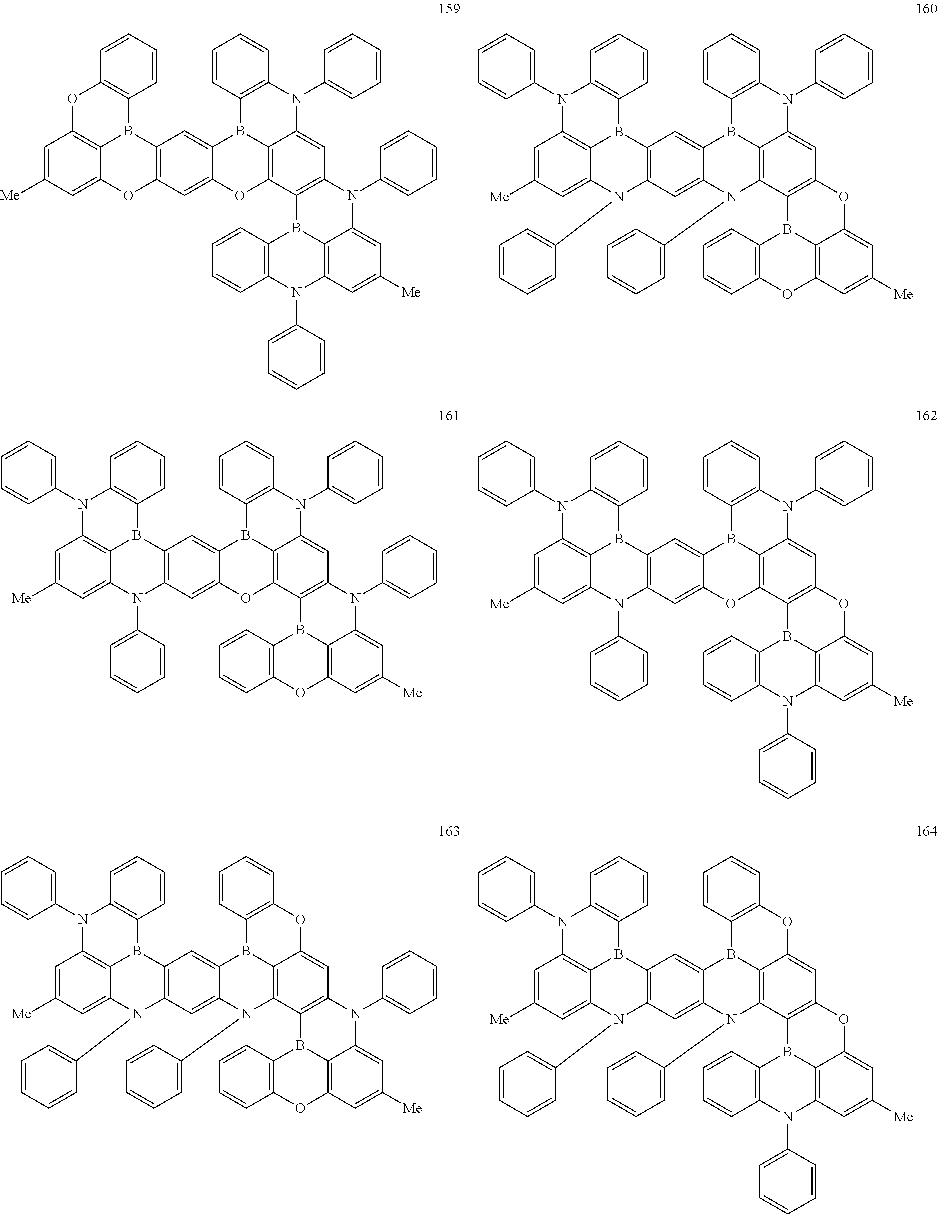 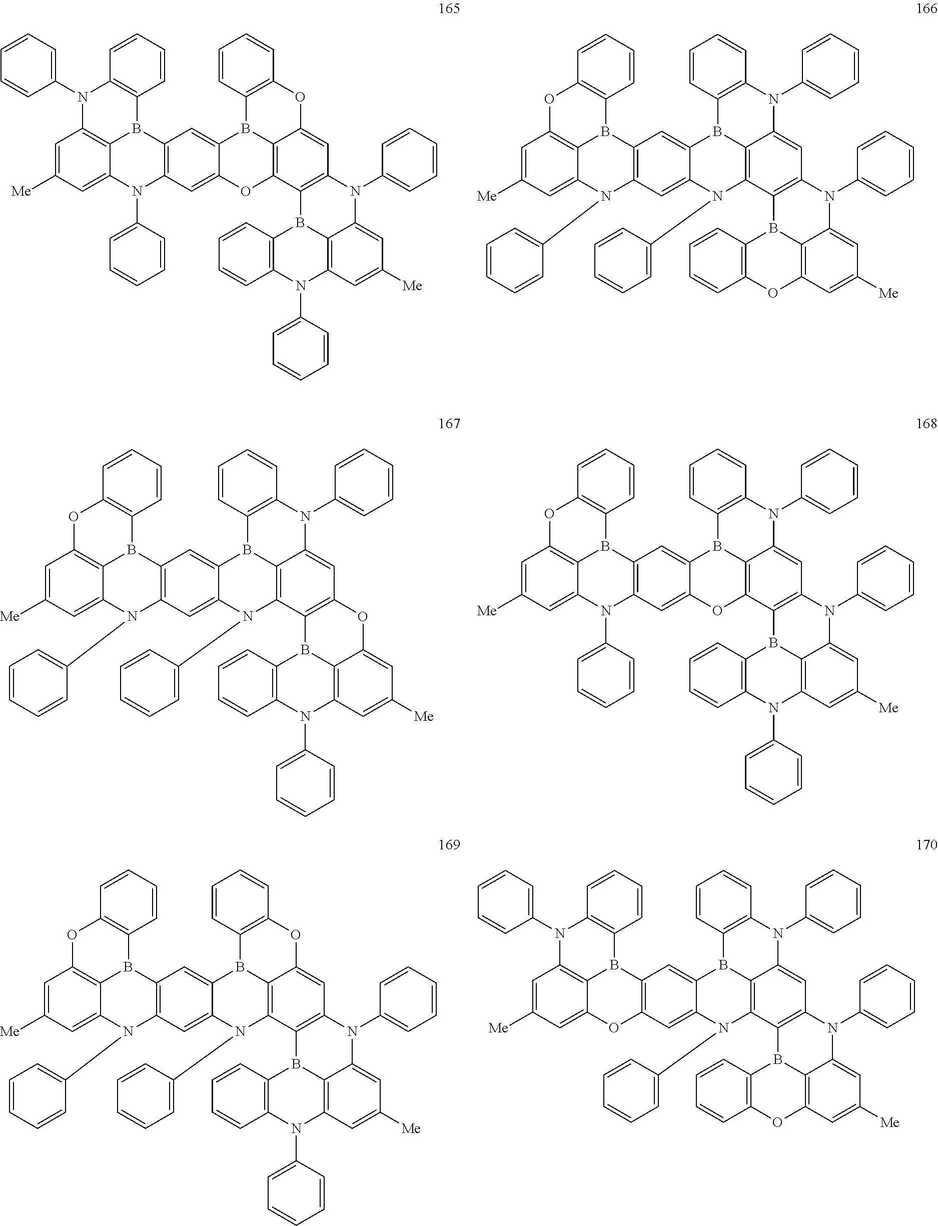 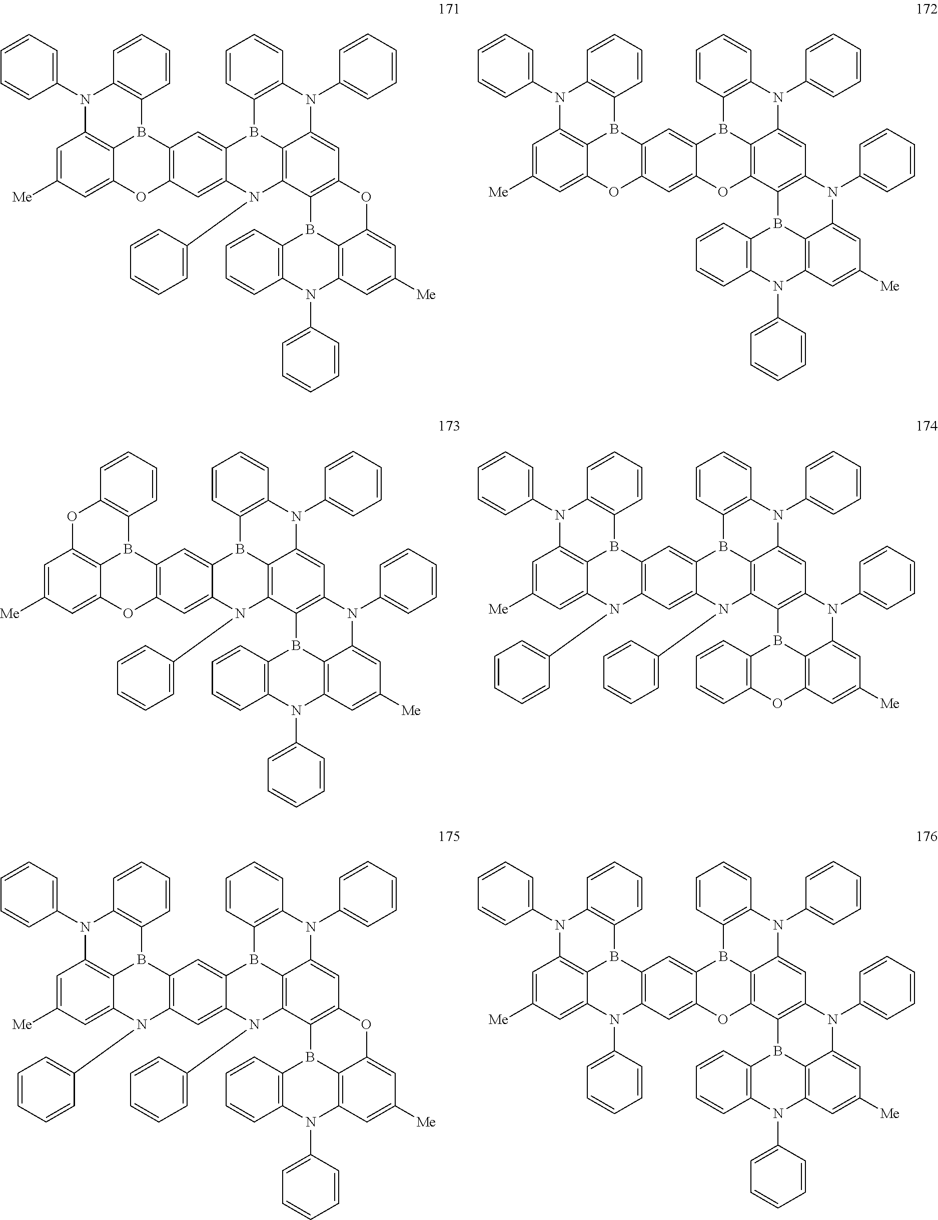 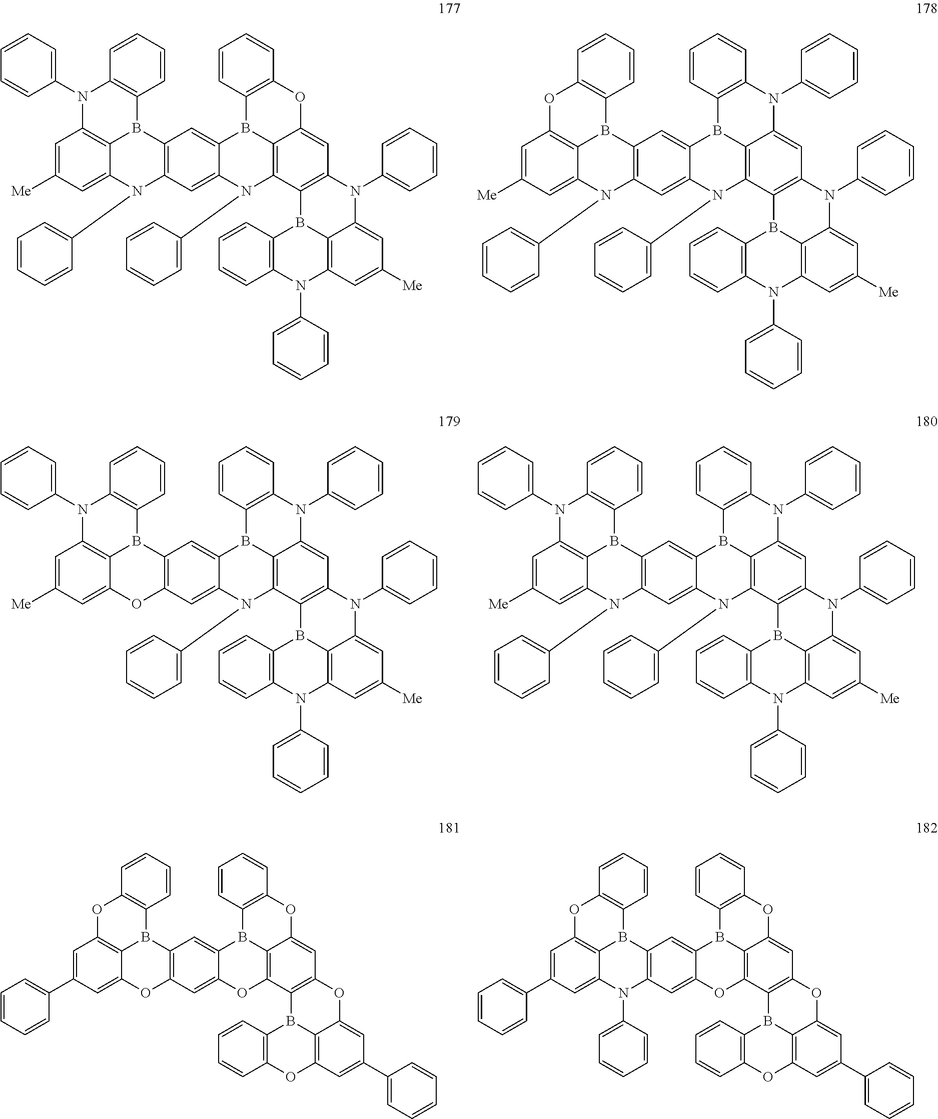 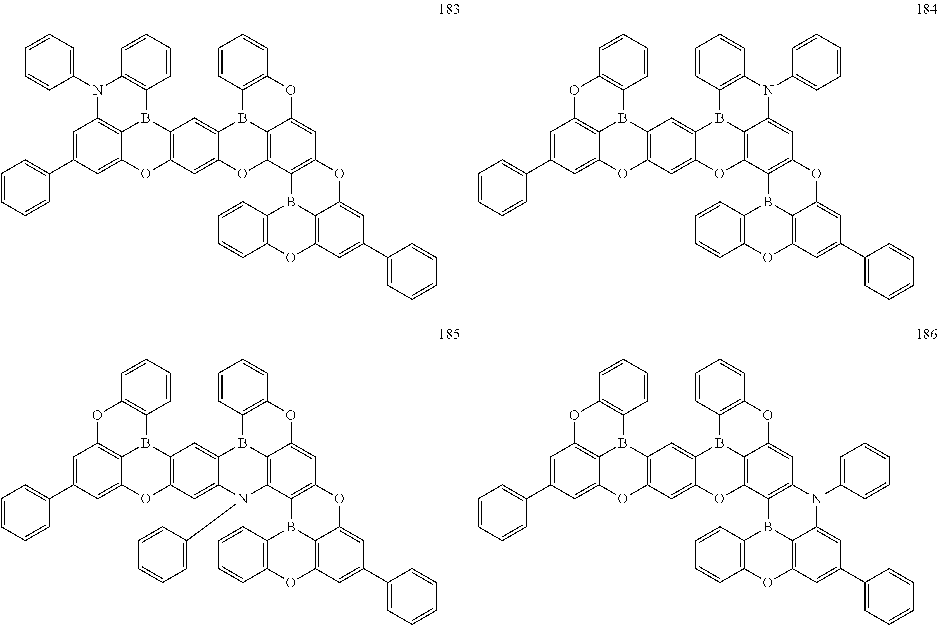 [SMILES: c1ccc(-c2cc3c4c(c2)Oc2cc5c6c(c2B4c2ccccc2O3)Oc2cc3c(cc2B6c2ccccc2O5)B2c4ccccc4N(c4ccccc4)c4cc(-c5ccccc5)cc(c42)O3)cc1 ; c1ccc(-c2cc3c4c(c2)Oc2cc5c(cc2B4c2ccccc2O3)B2c3ccccc3N(c3ccccc3)c3cc4c(c(c32)O5)B2c3ccccc3Oc3cc(-c5ccccc5)cc(c32)O4)cc1 ; c1ccc(-c2cc3c4c(c2)Oc2cc5c(cc2B4c2ccccc2O3)B2c3ccccc3Oc3cc4c(c(c32)N5c2ccccc2)B2c3ccccc3Oc3cc(-c5ccccc5)cc(c32)O4)cc1 ; c1ccc(-c2cc3c4c(c2)Oc2cc5c(cc2B4c2ccccc2O3)B2c3ccccc3Oc3cc4c(c(c32)O5)B2c3ccccc3Oc3cc(-c5ccccc5)cc(c32)N4c2ccccc2)cc1] 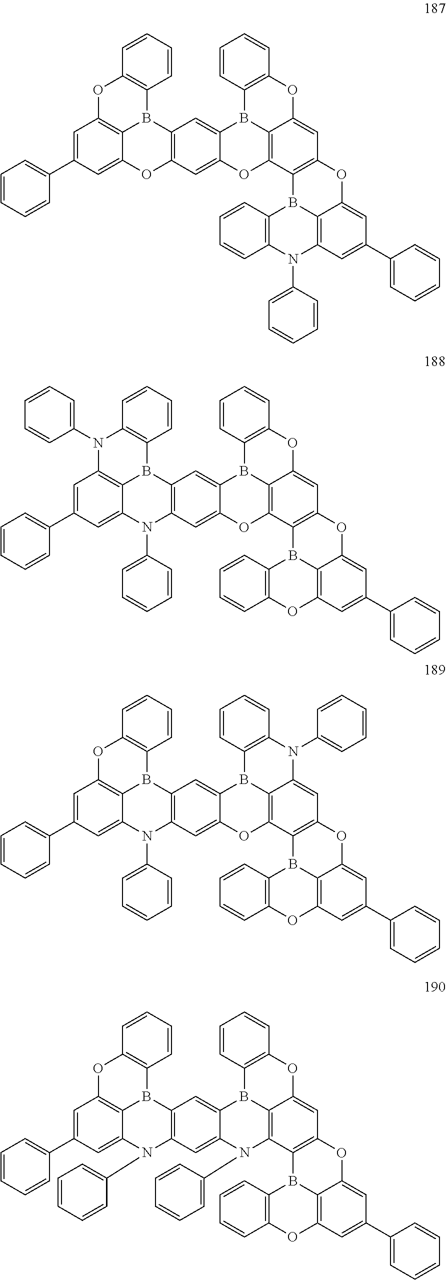 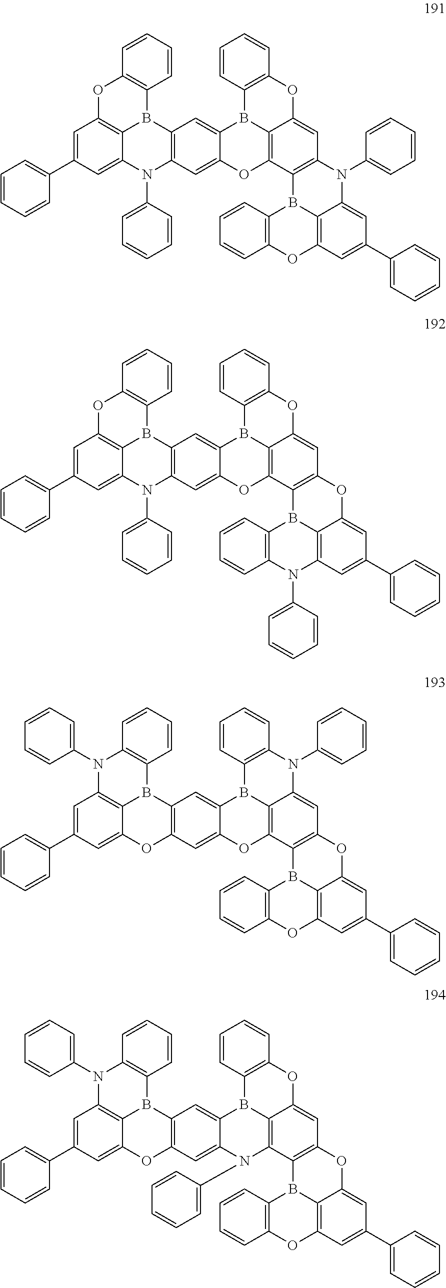 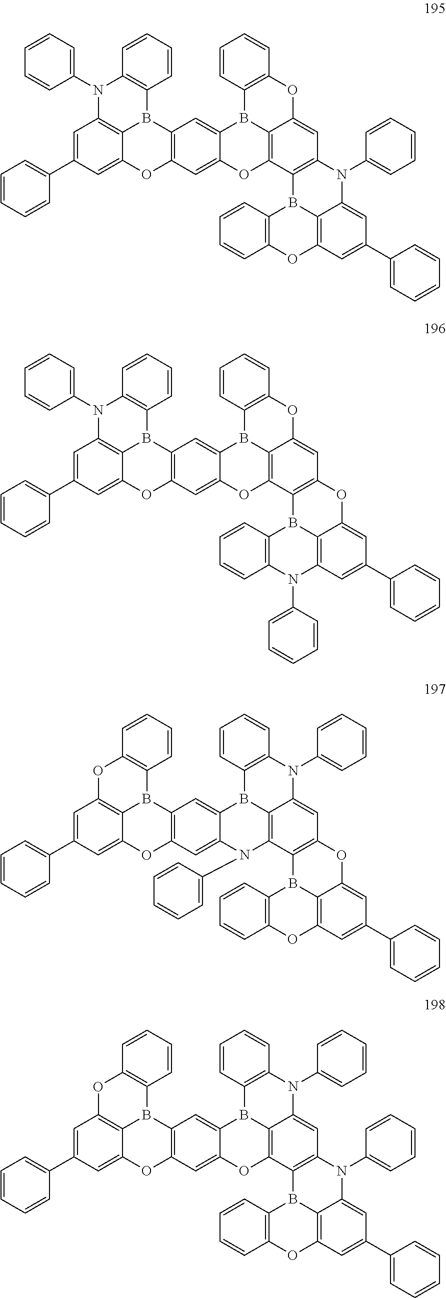 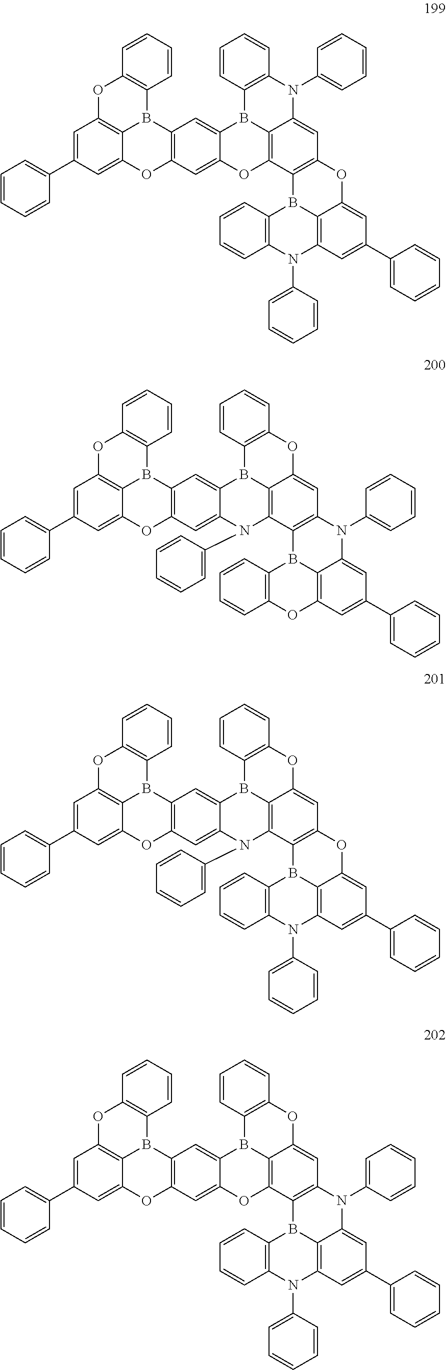 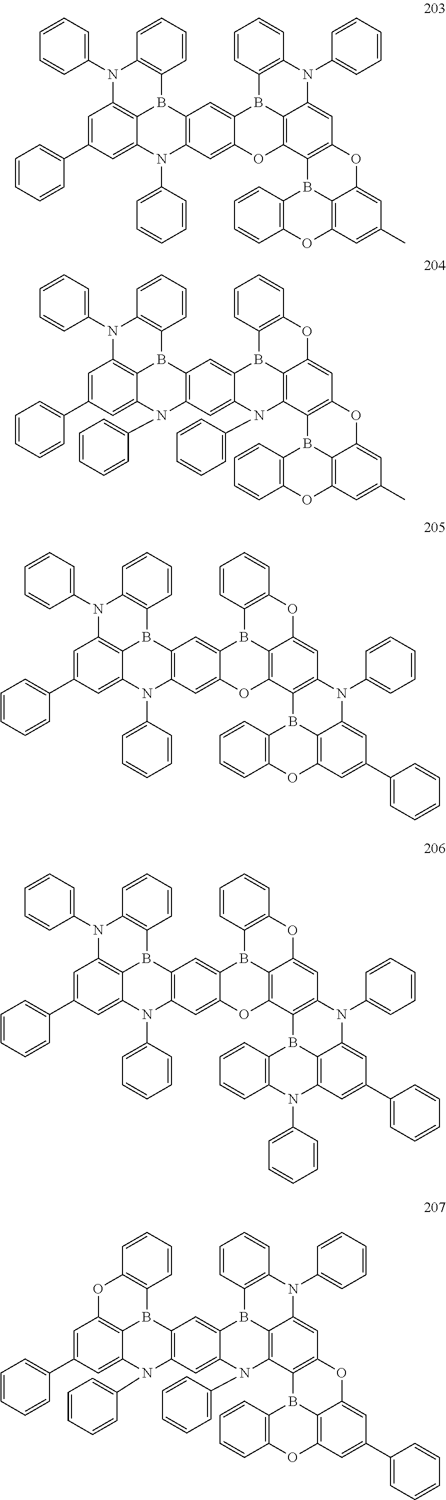 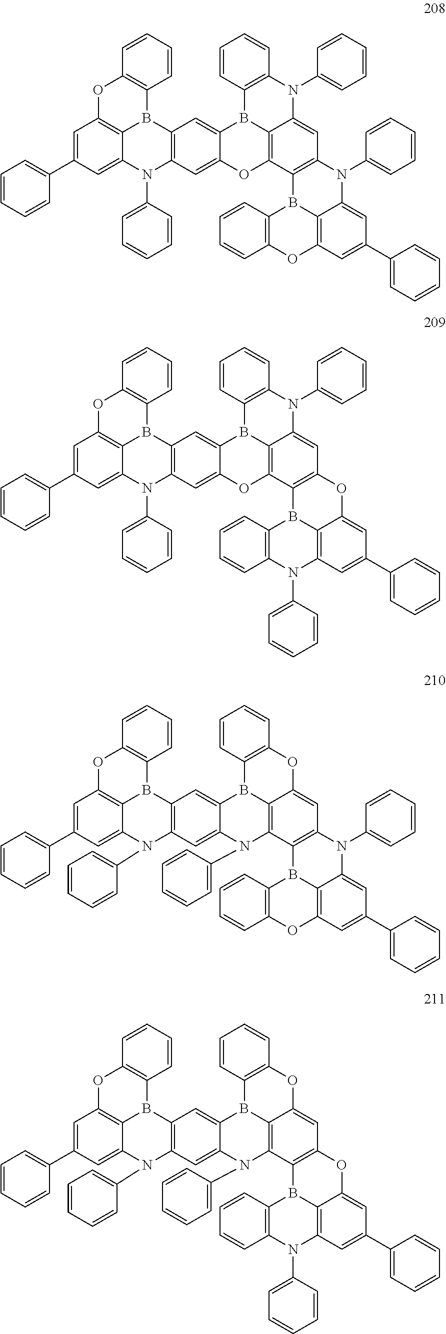 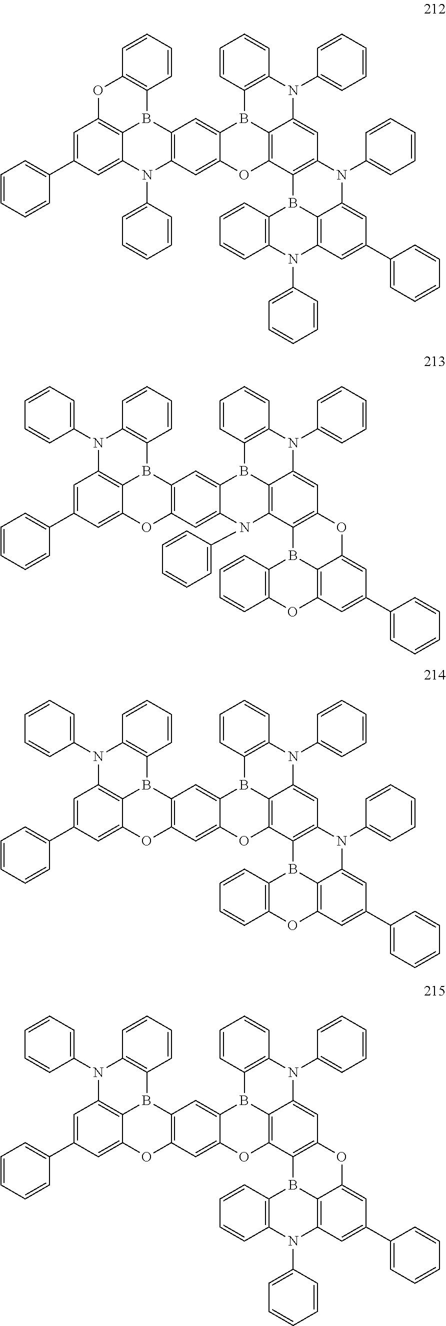 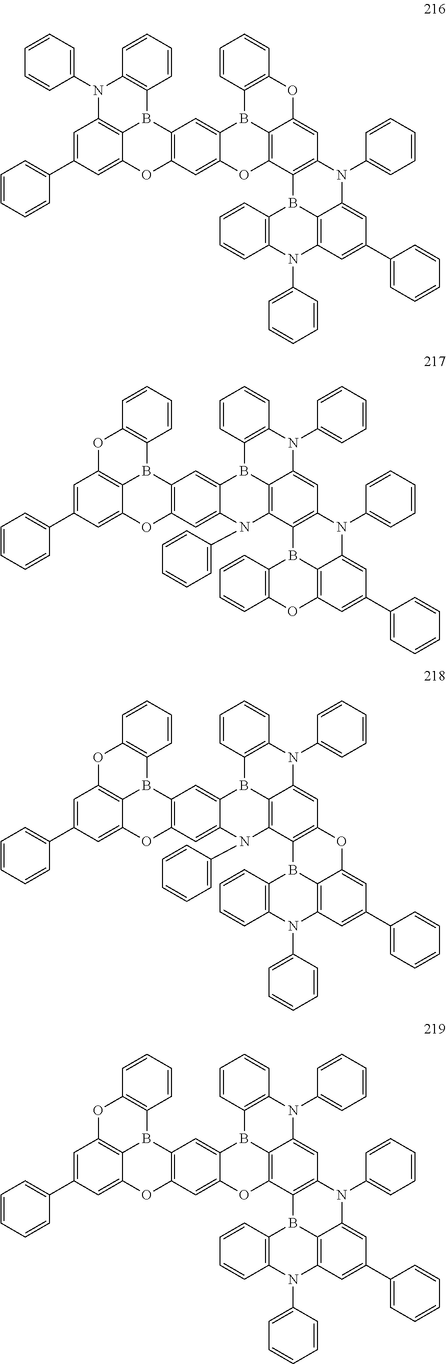 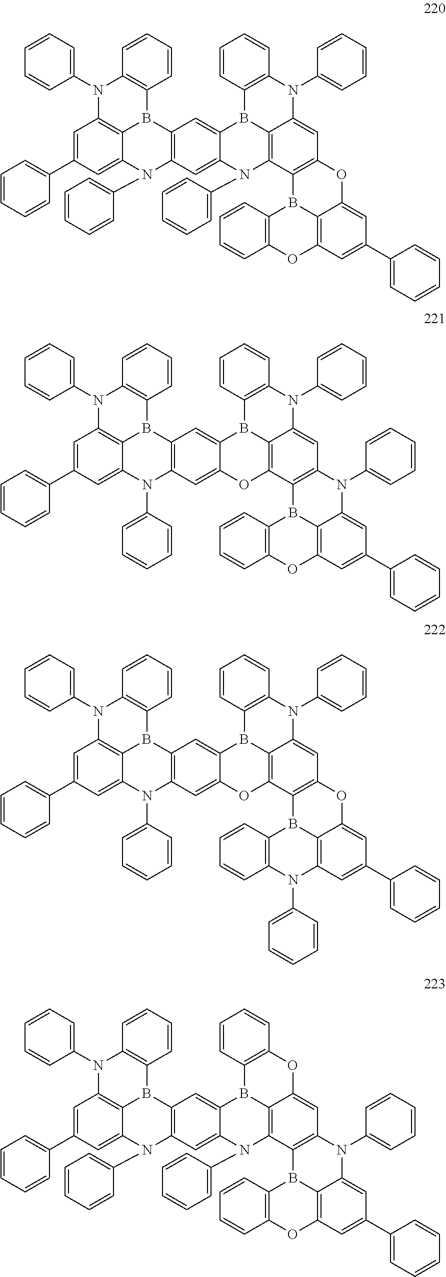 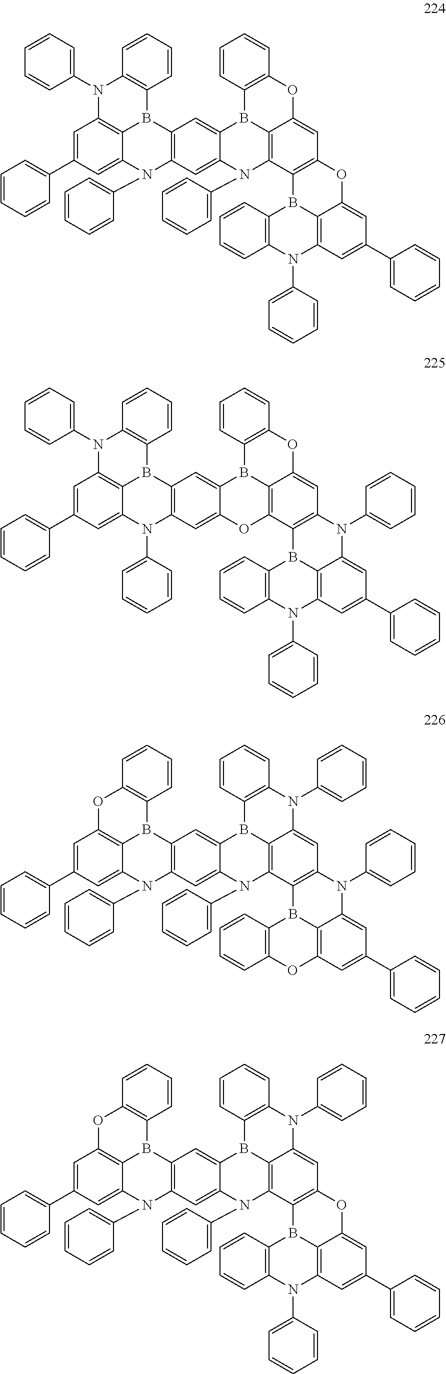 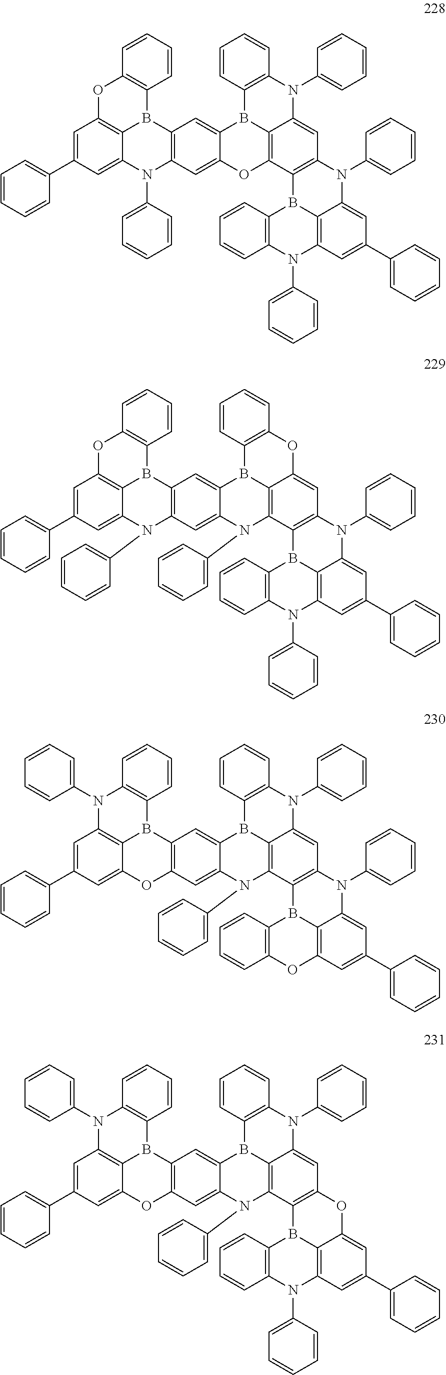 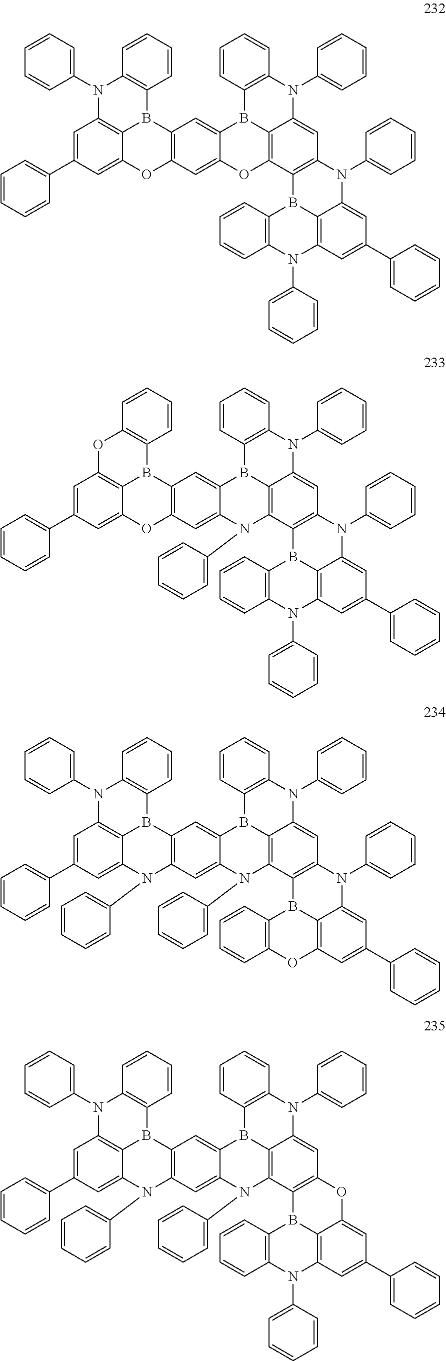 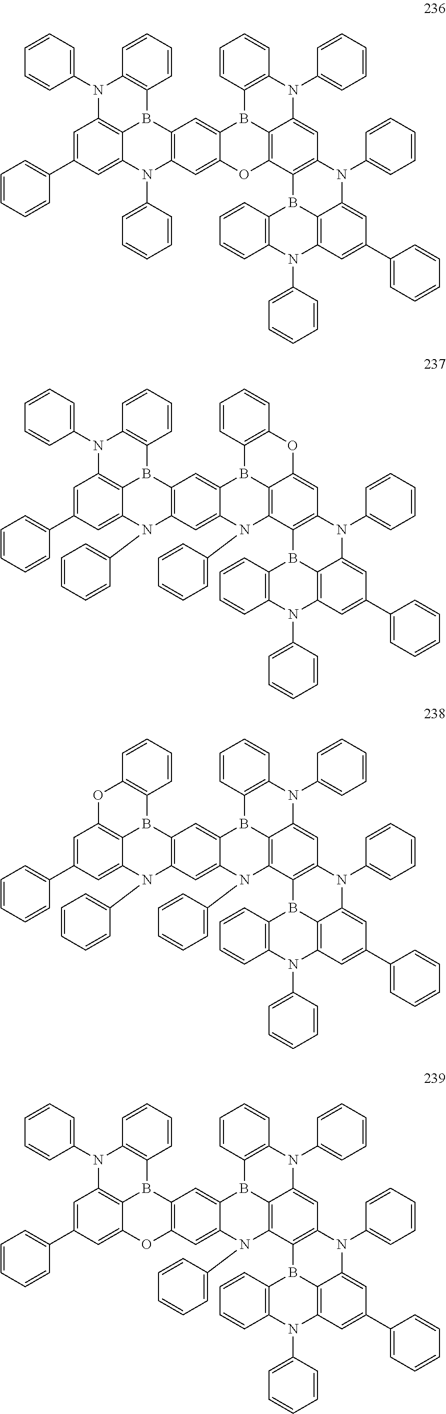 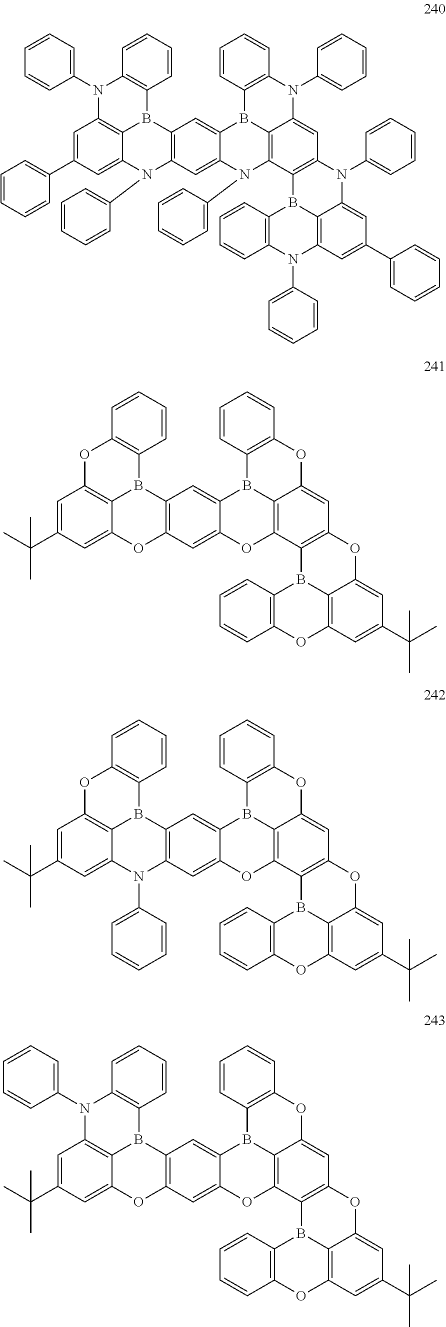 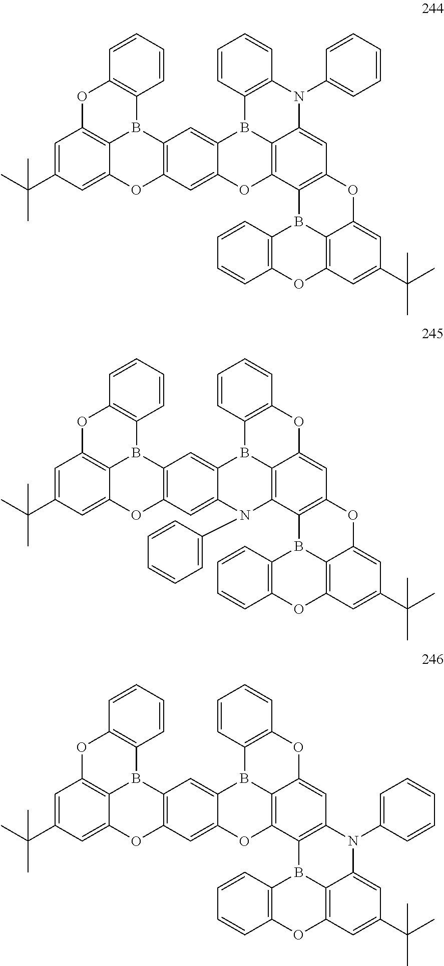 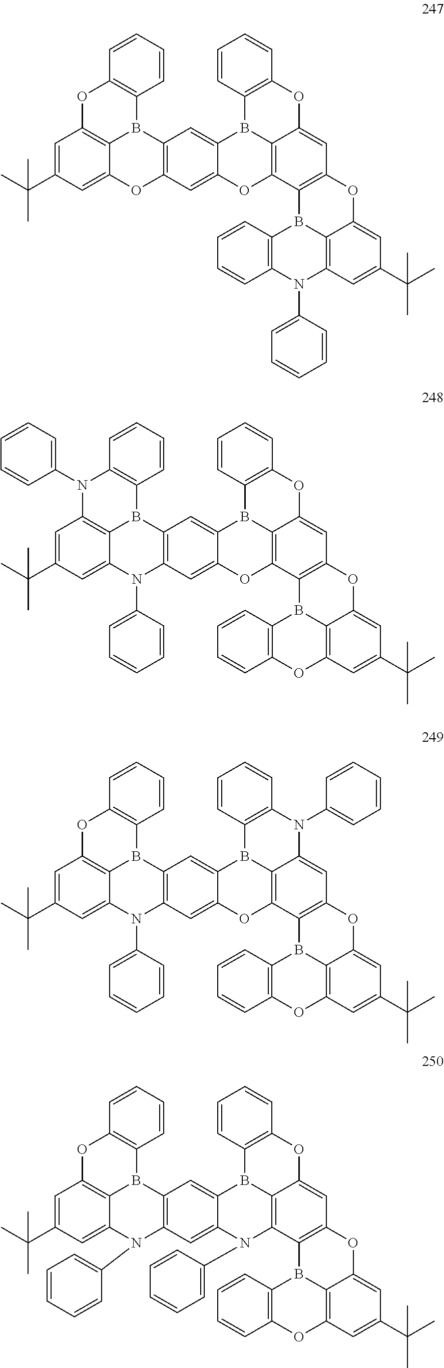 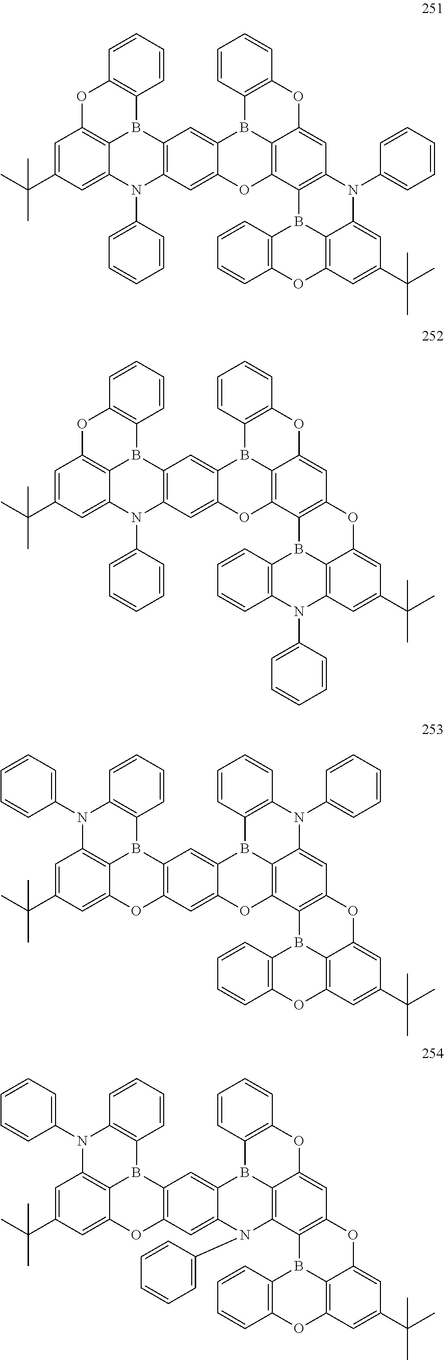 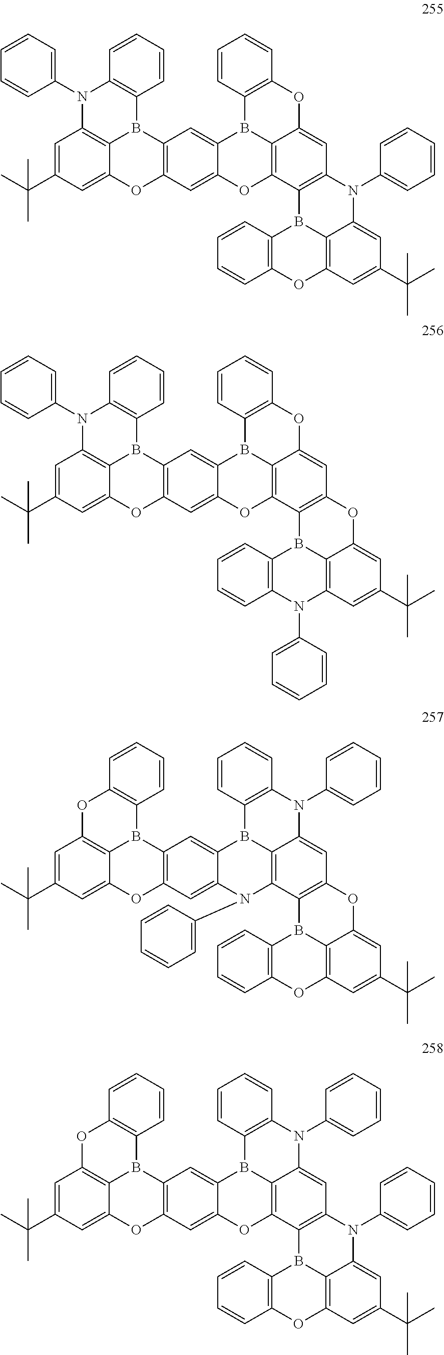 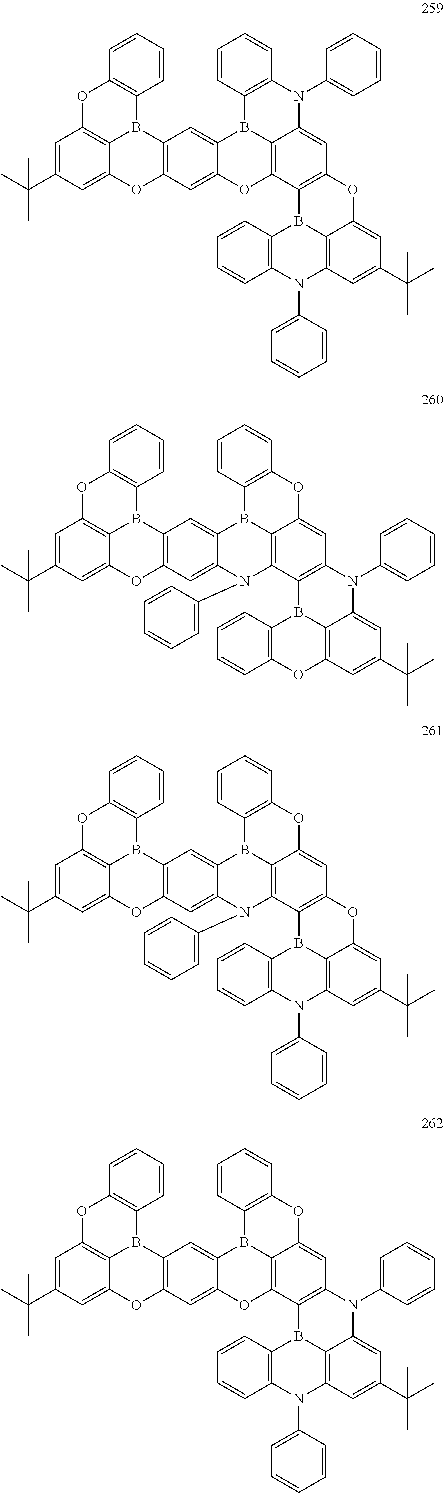 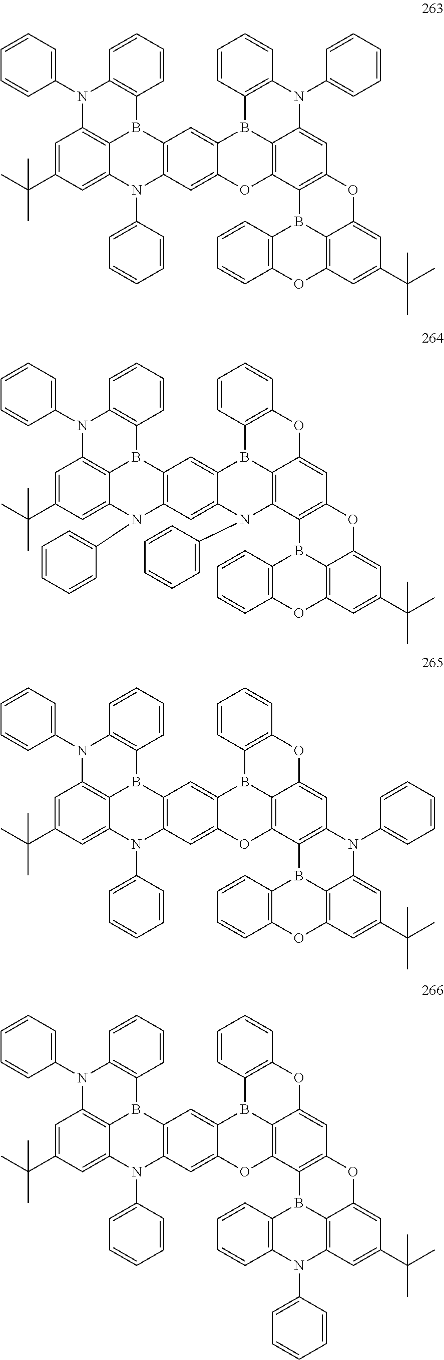 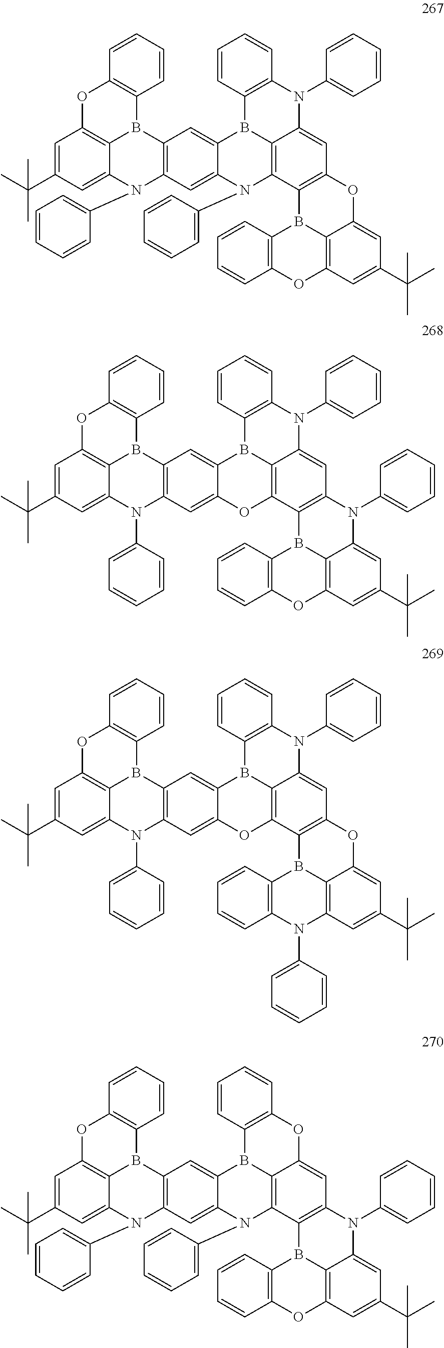 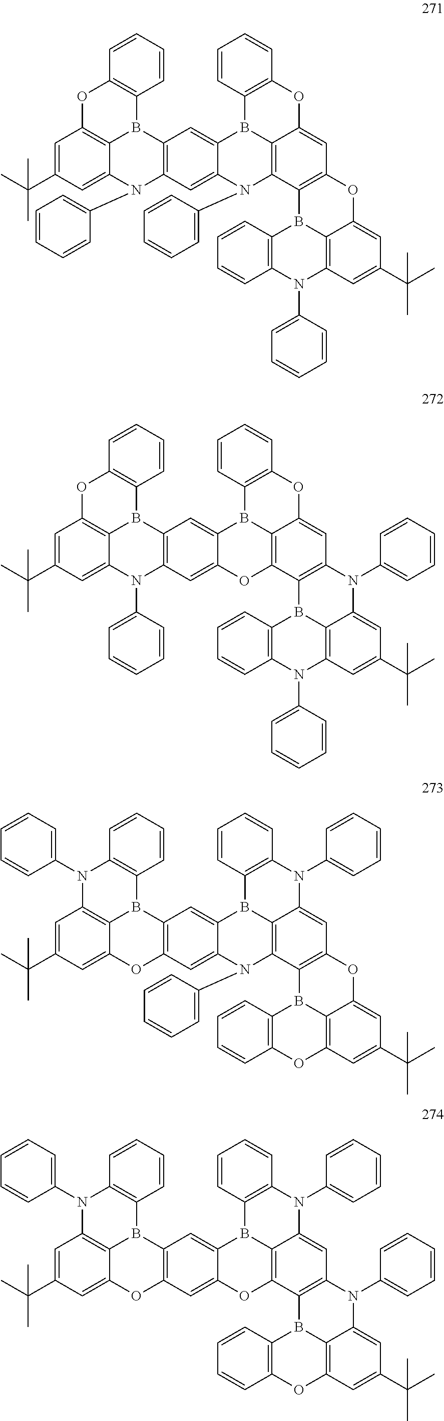 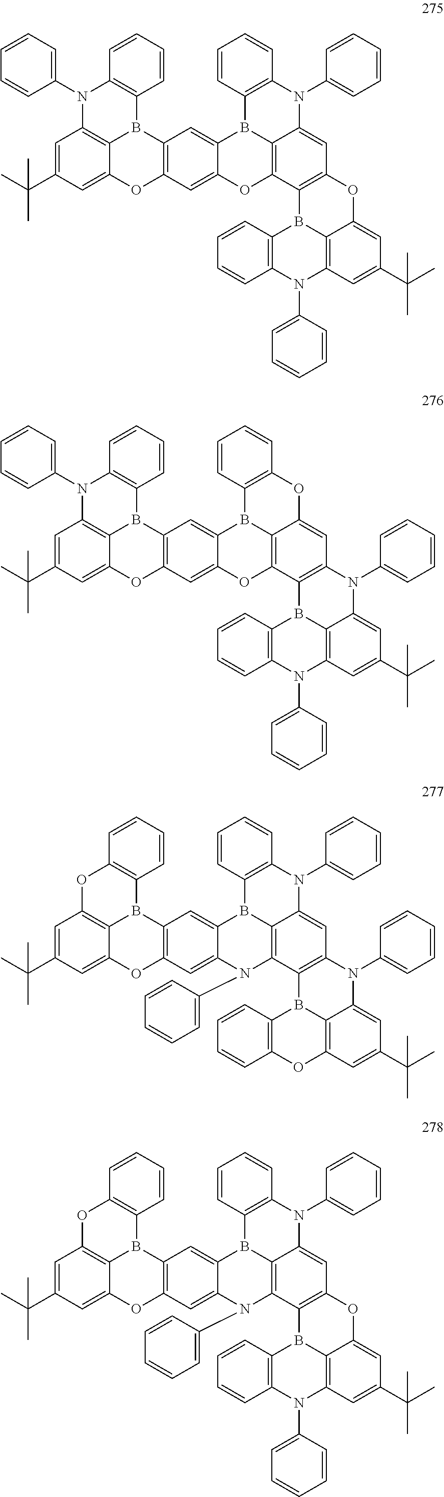 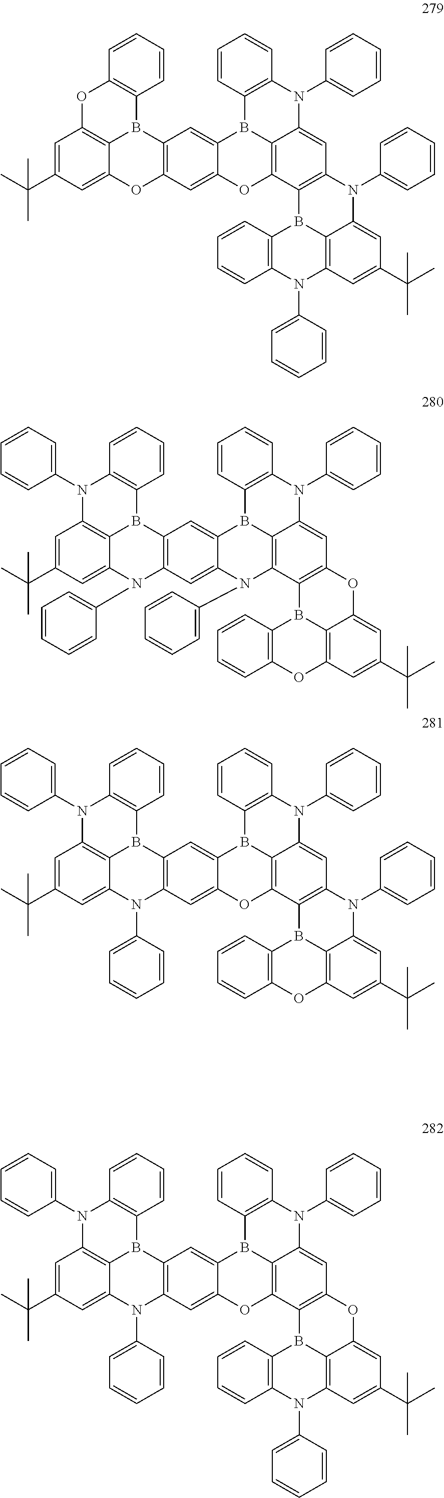 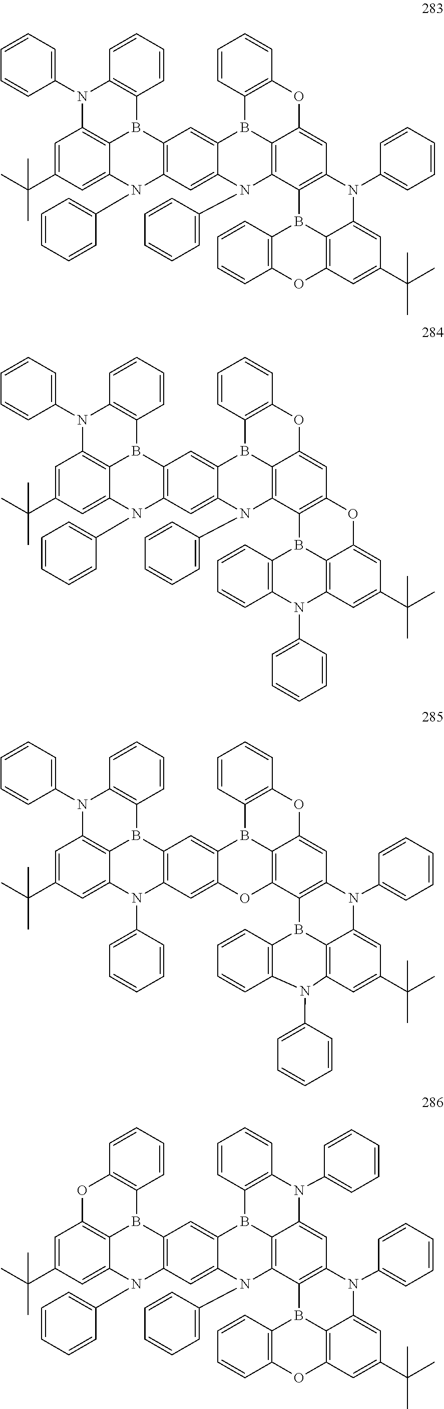 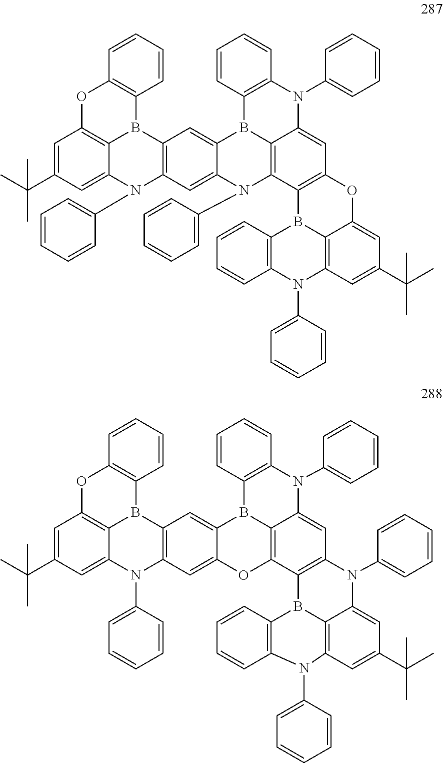 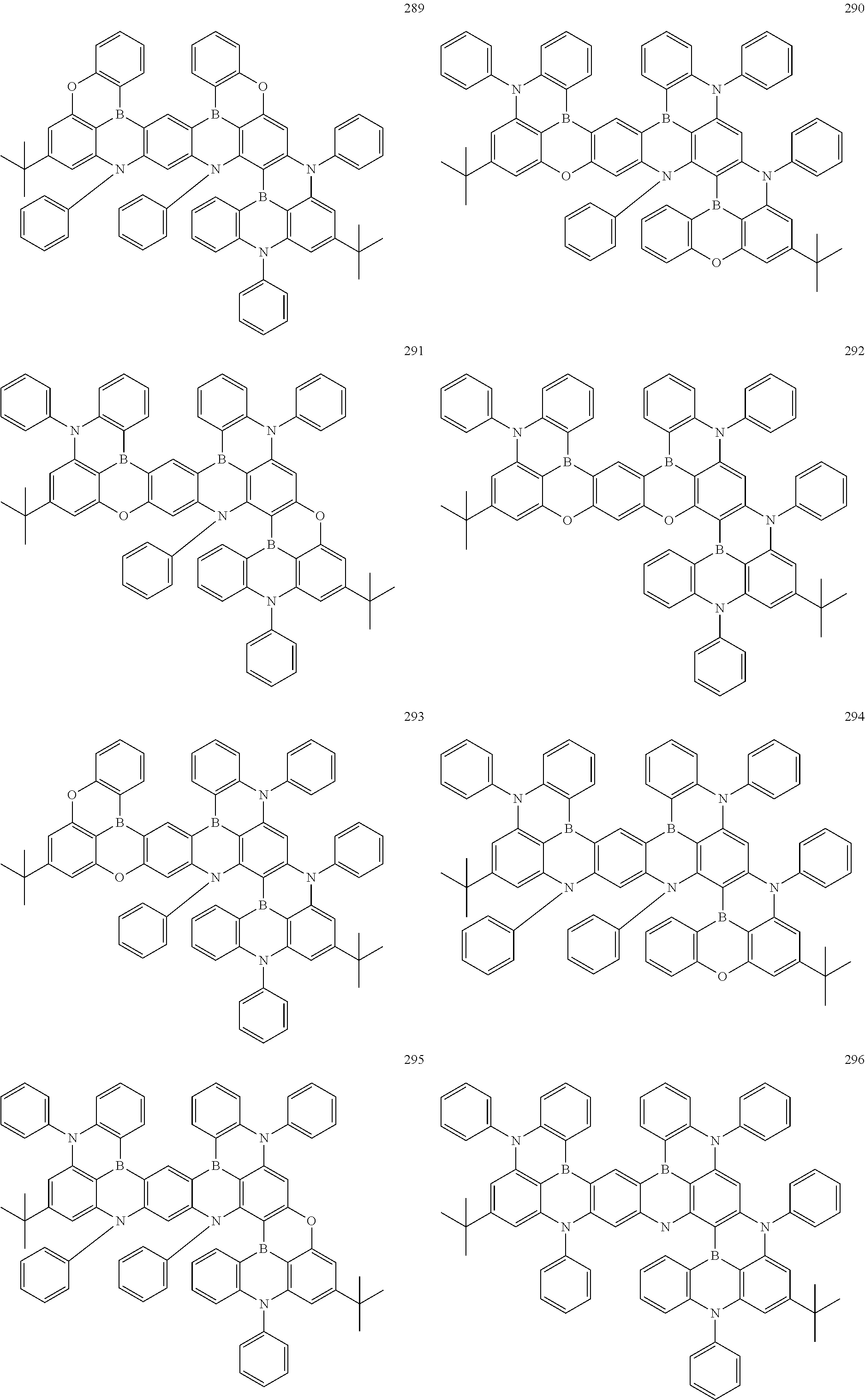 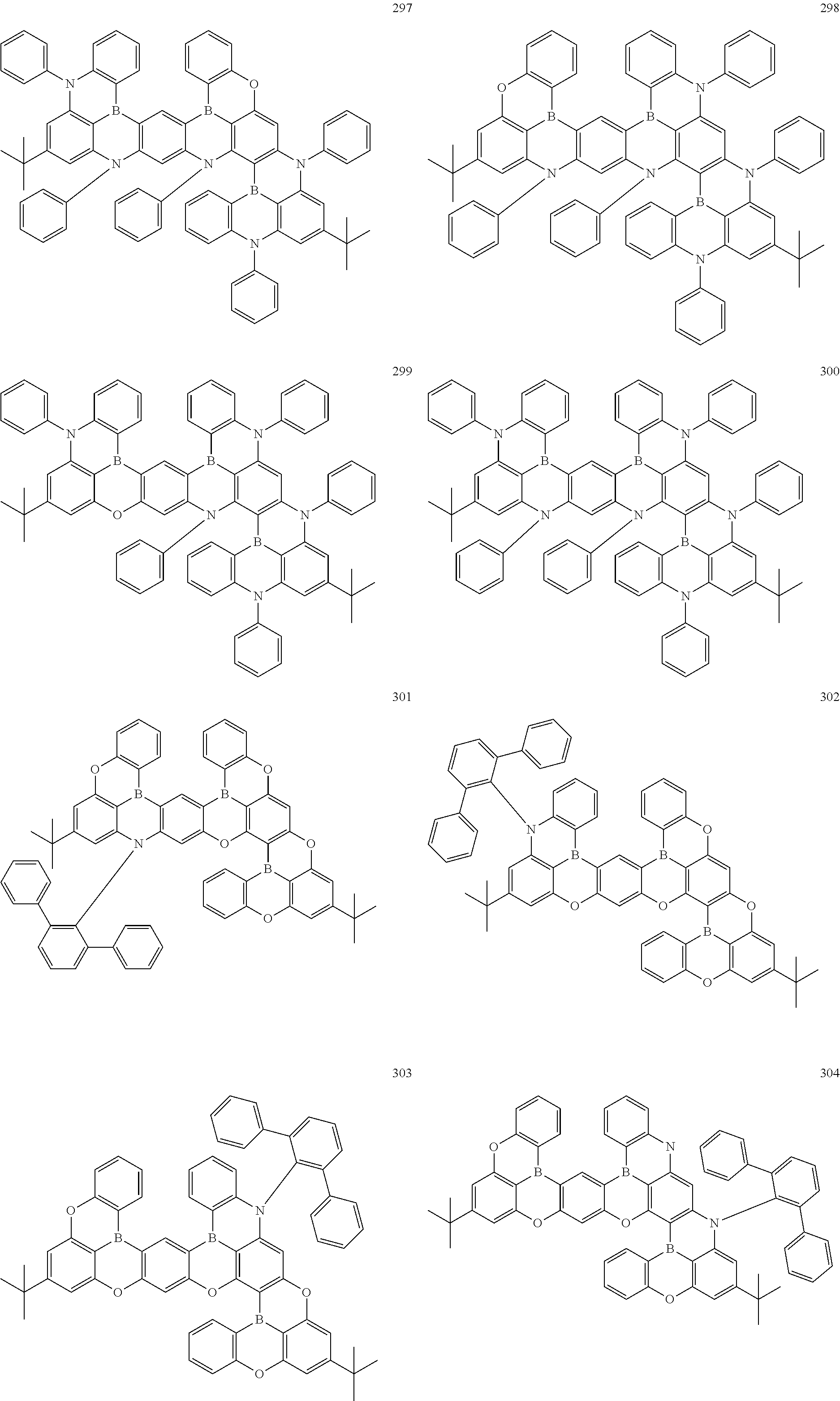 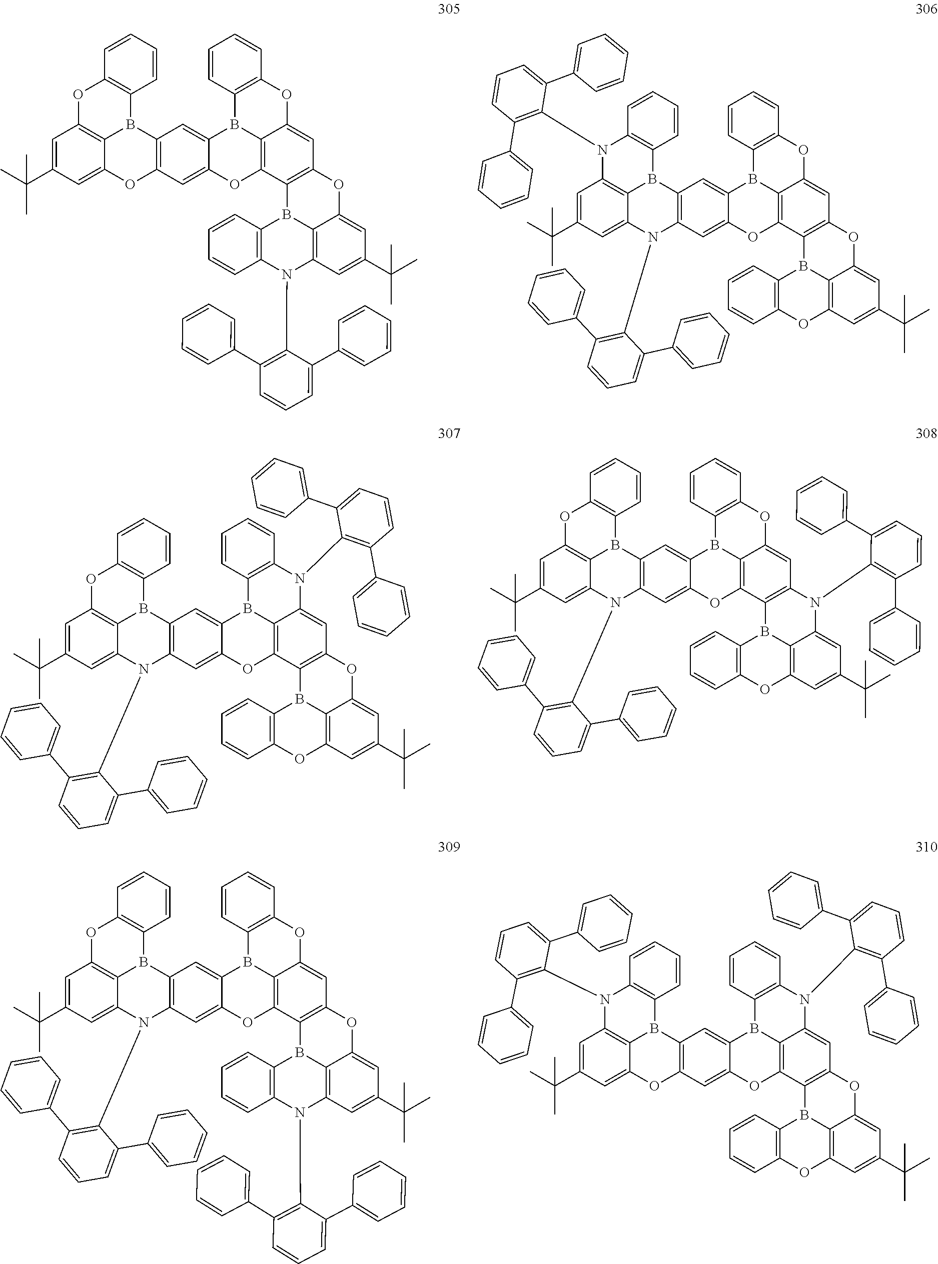 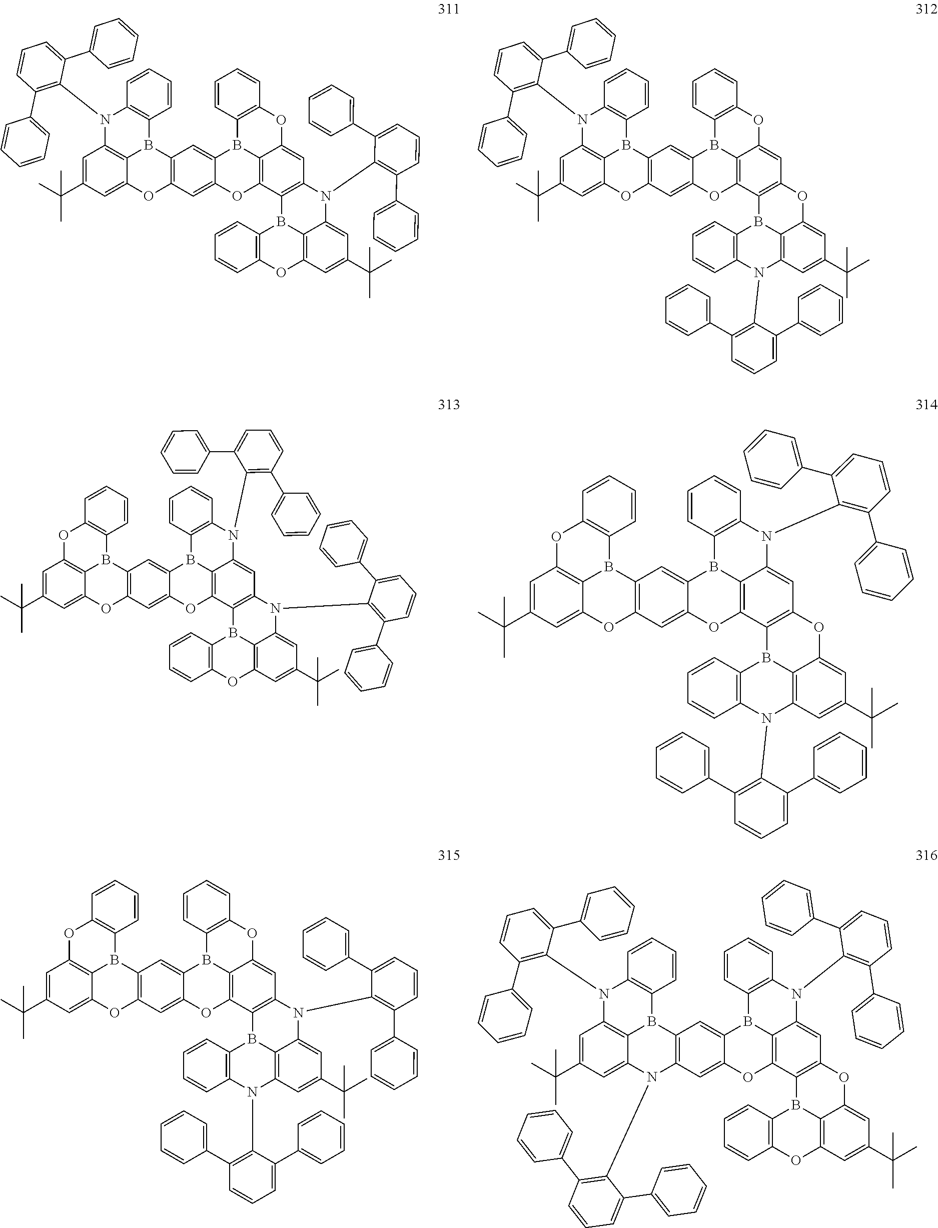 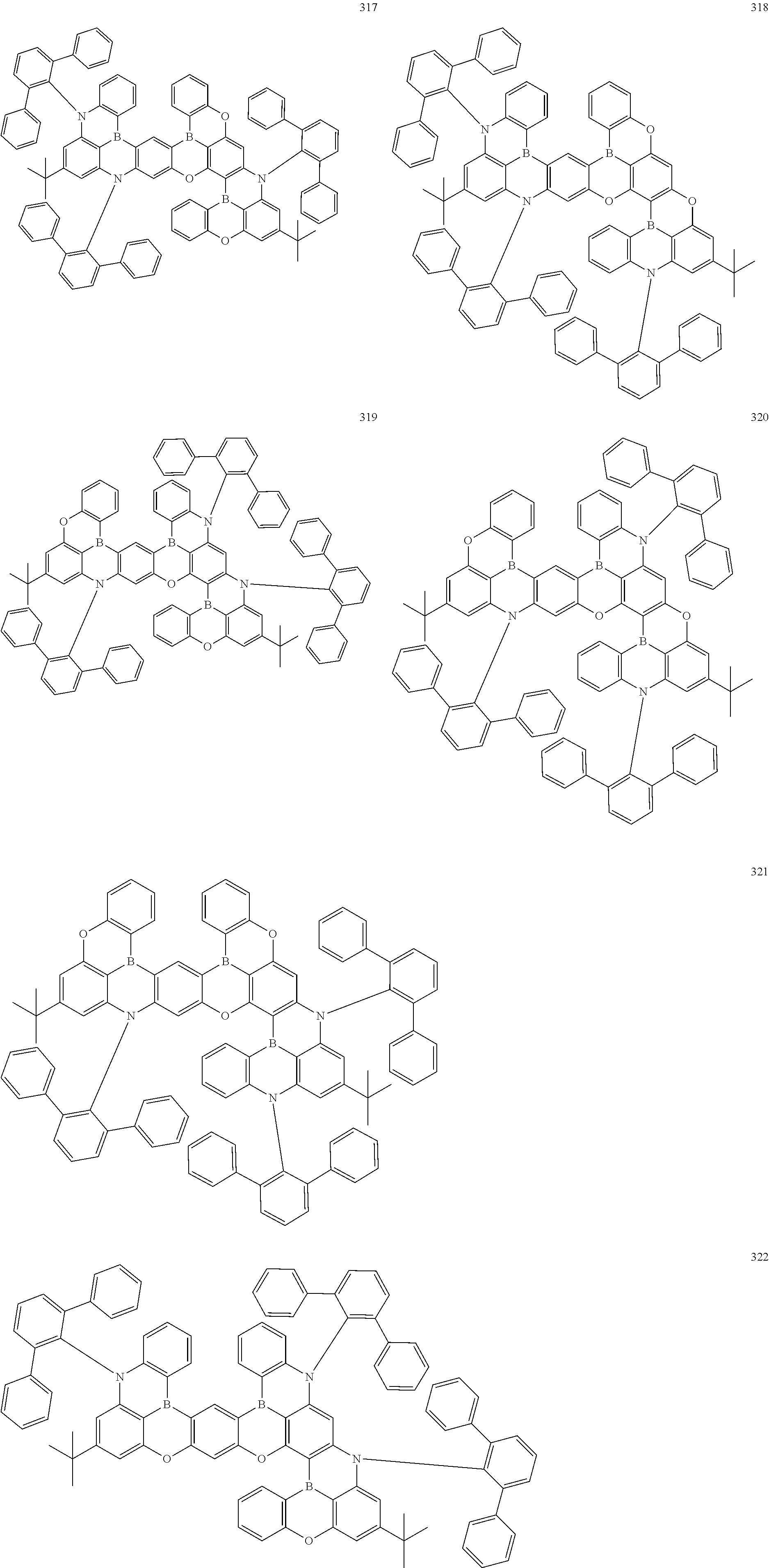 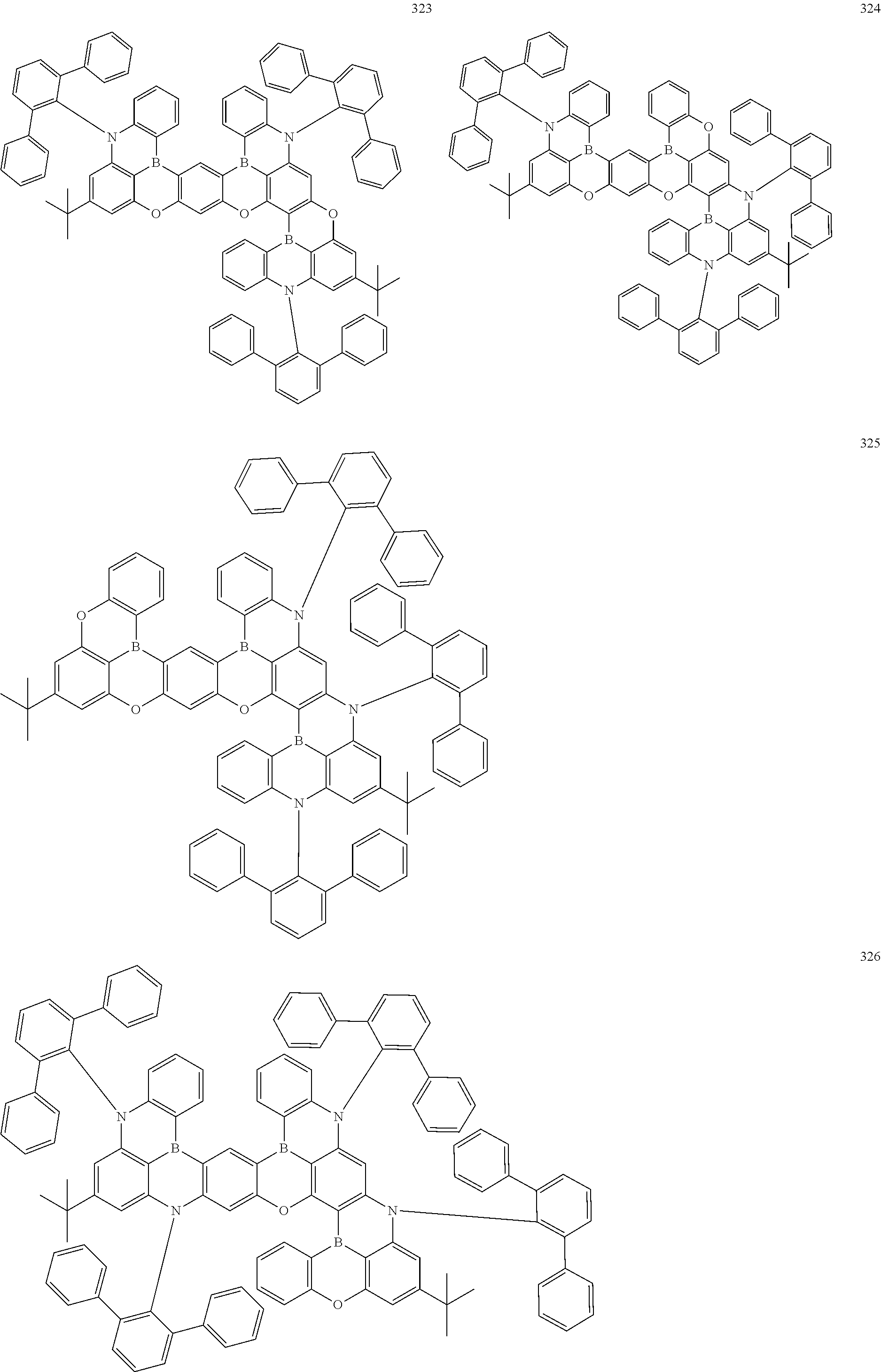 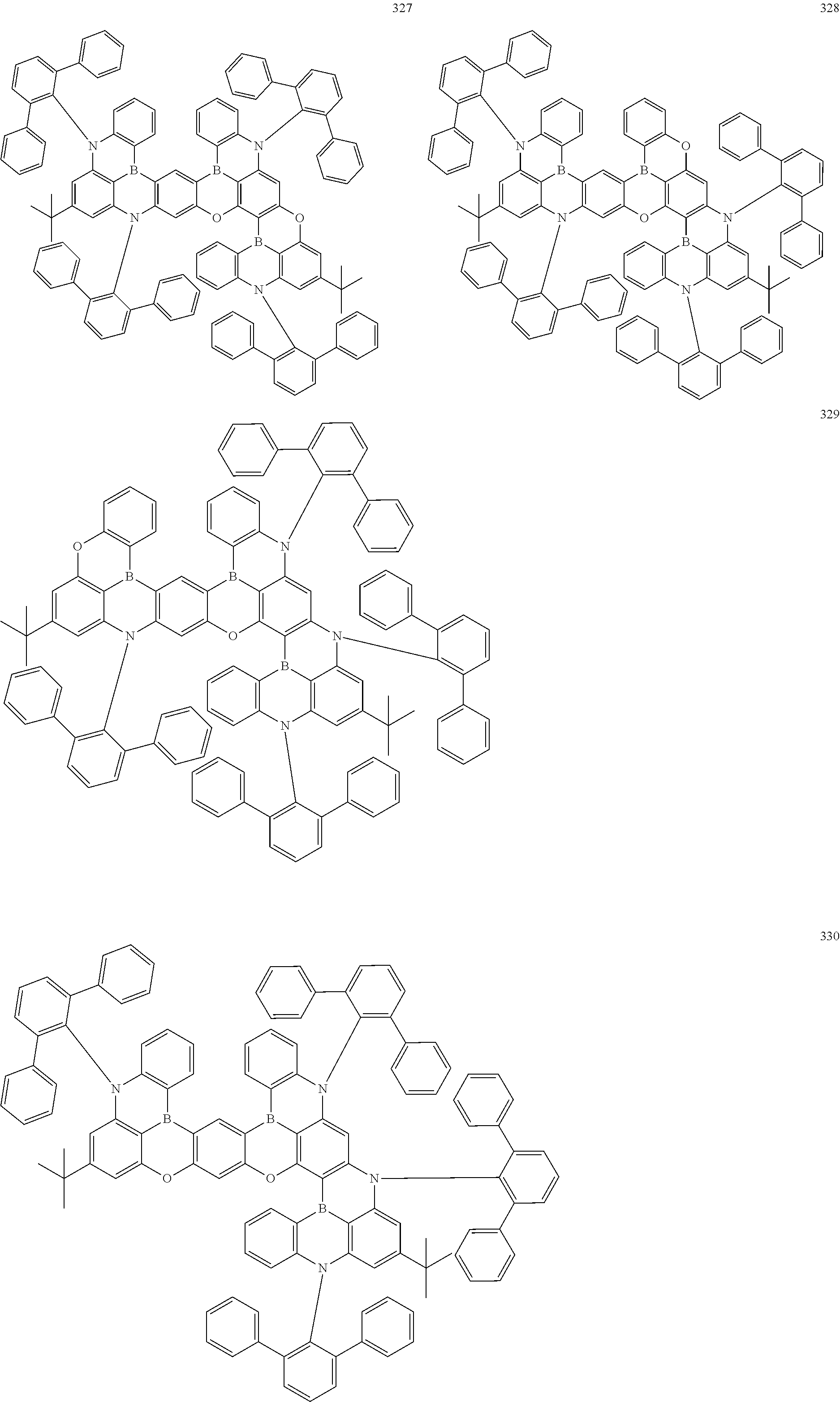 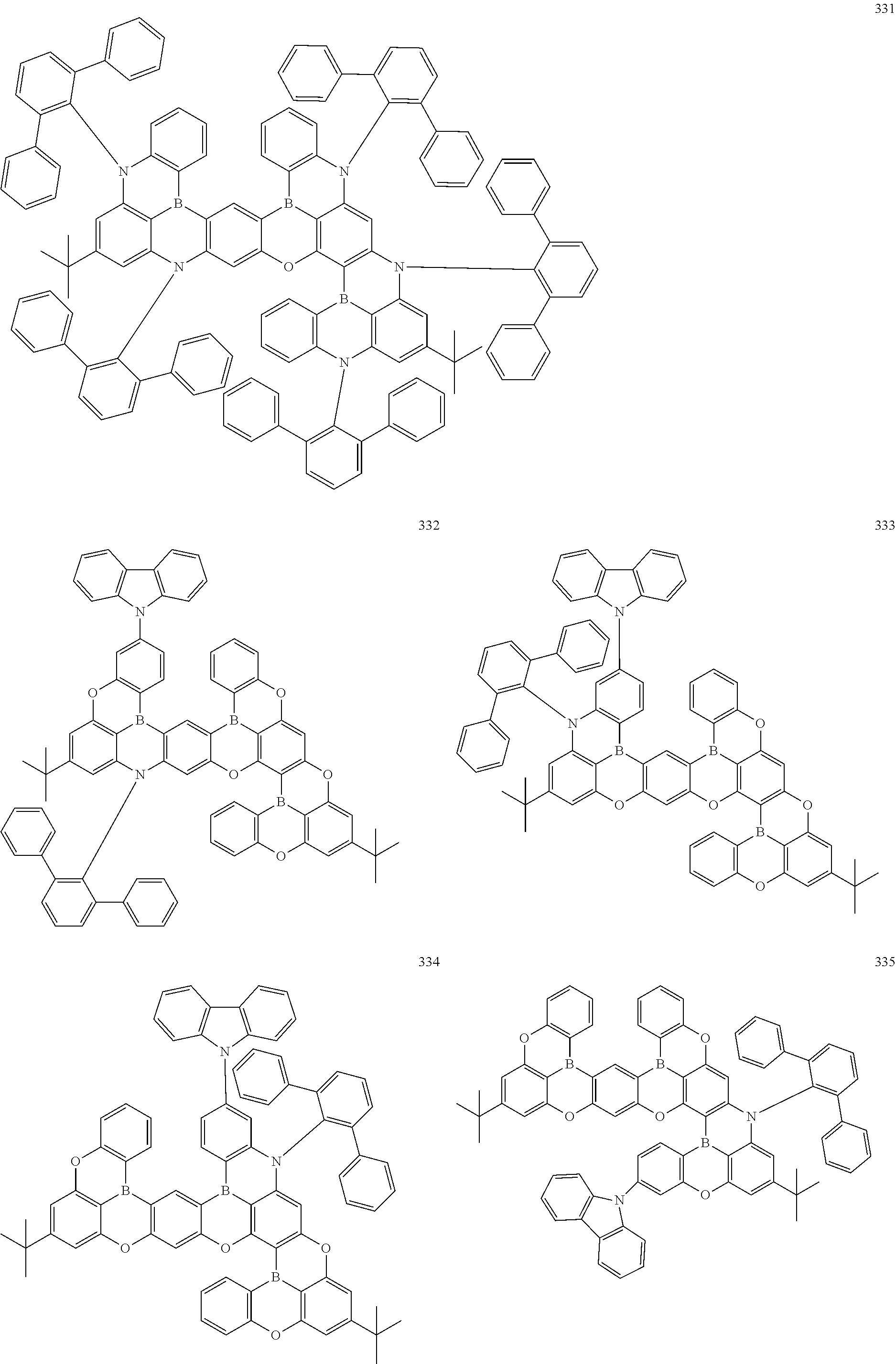 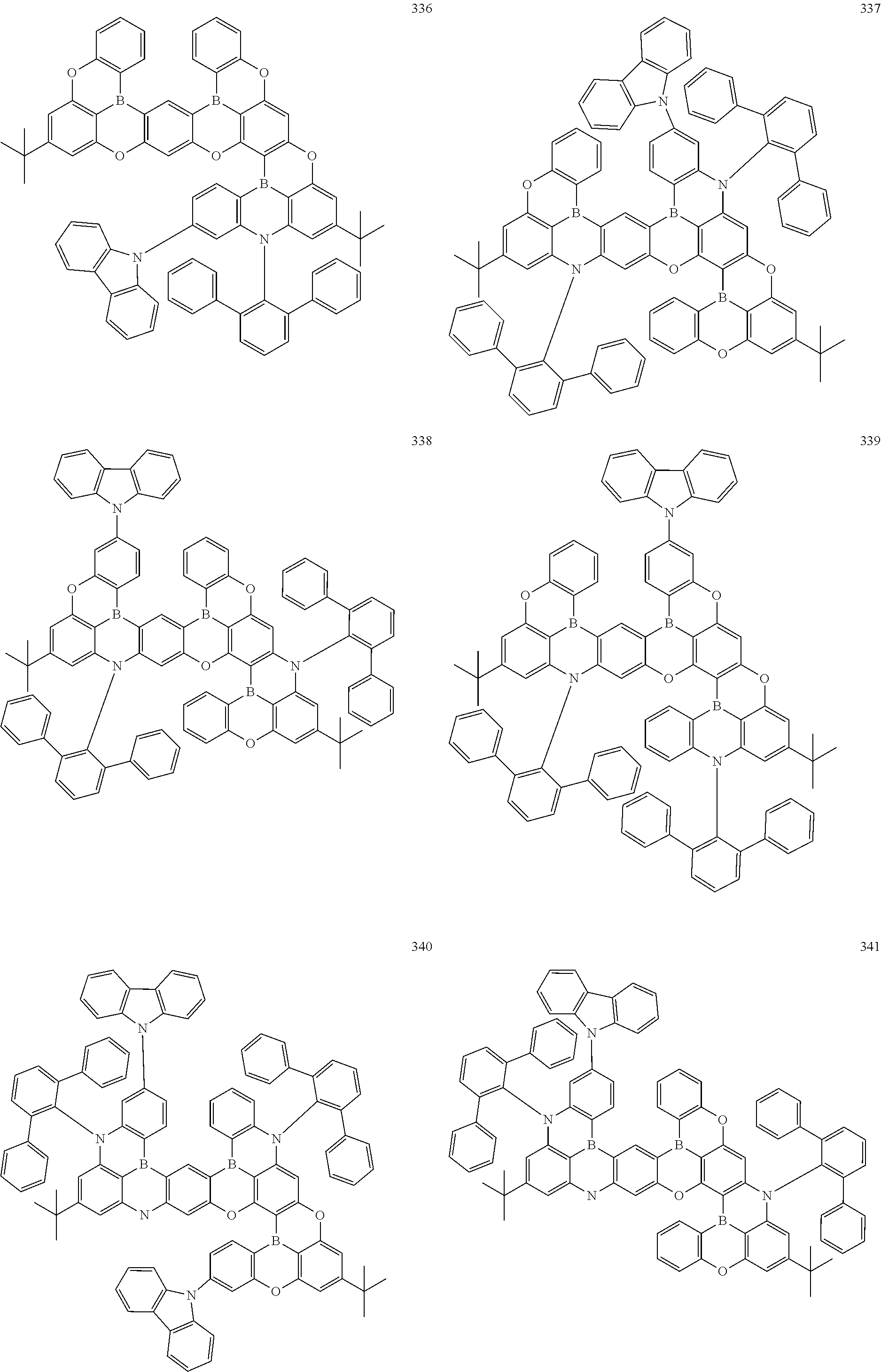 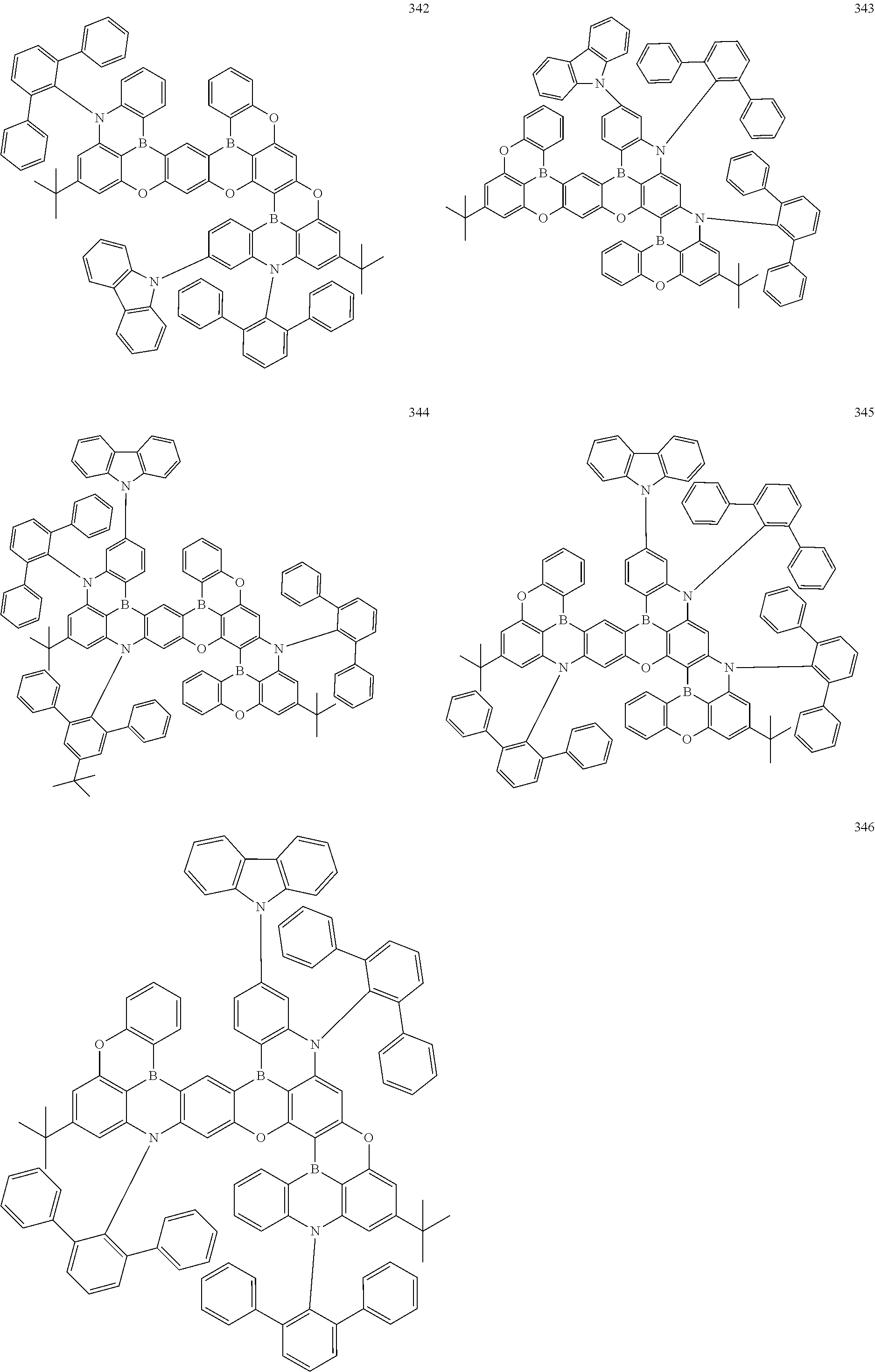 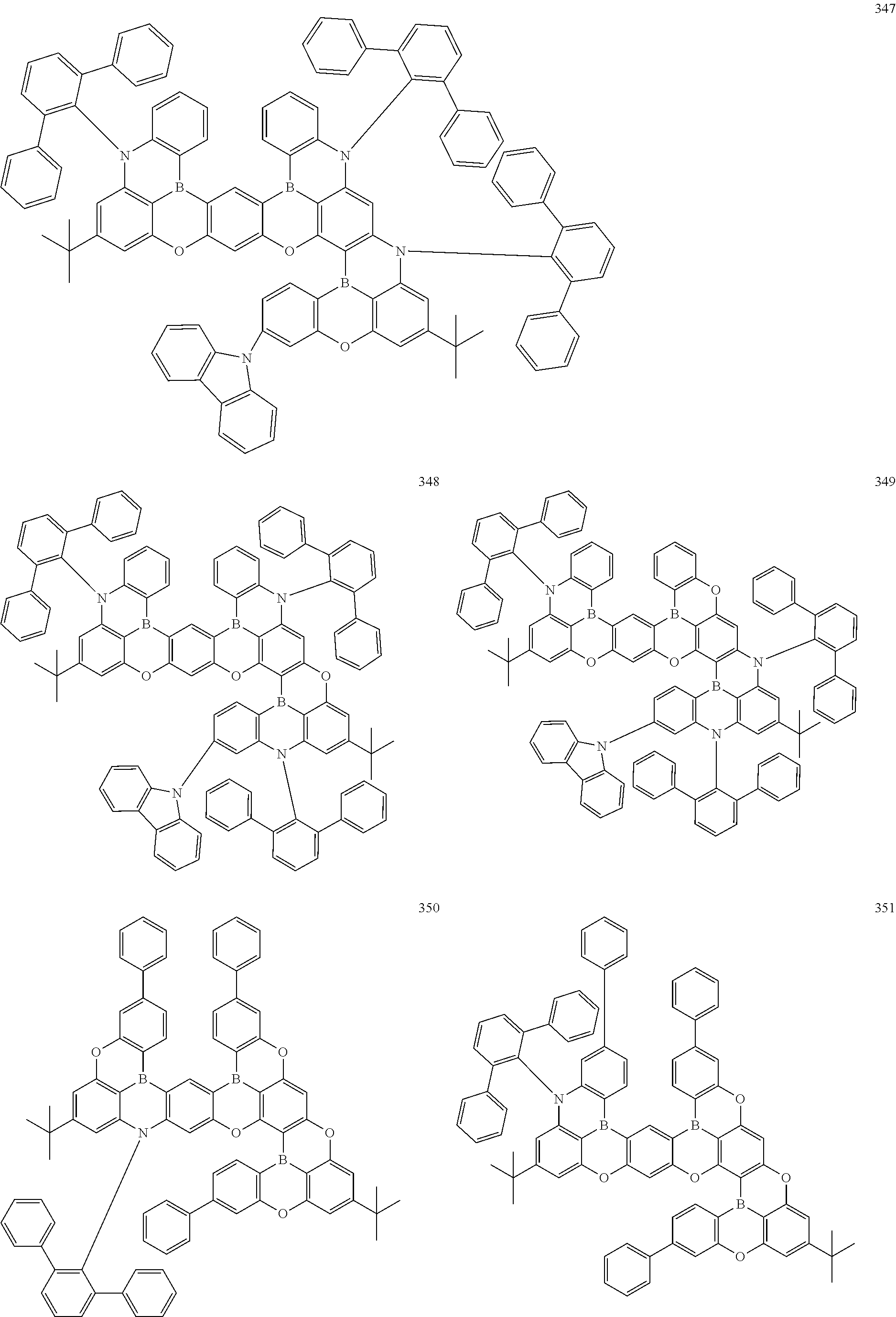 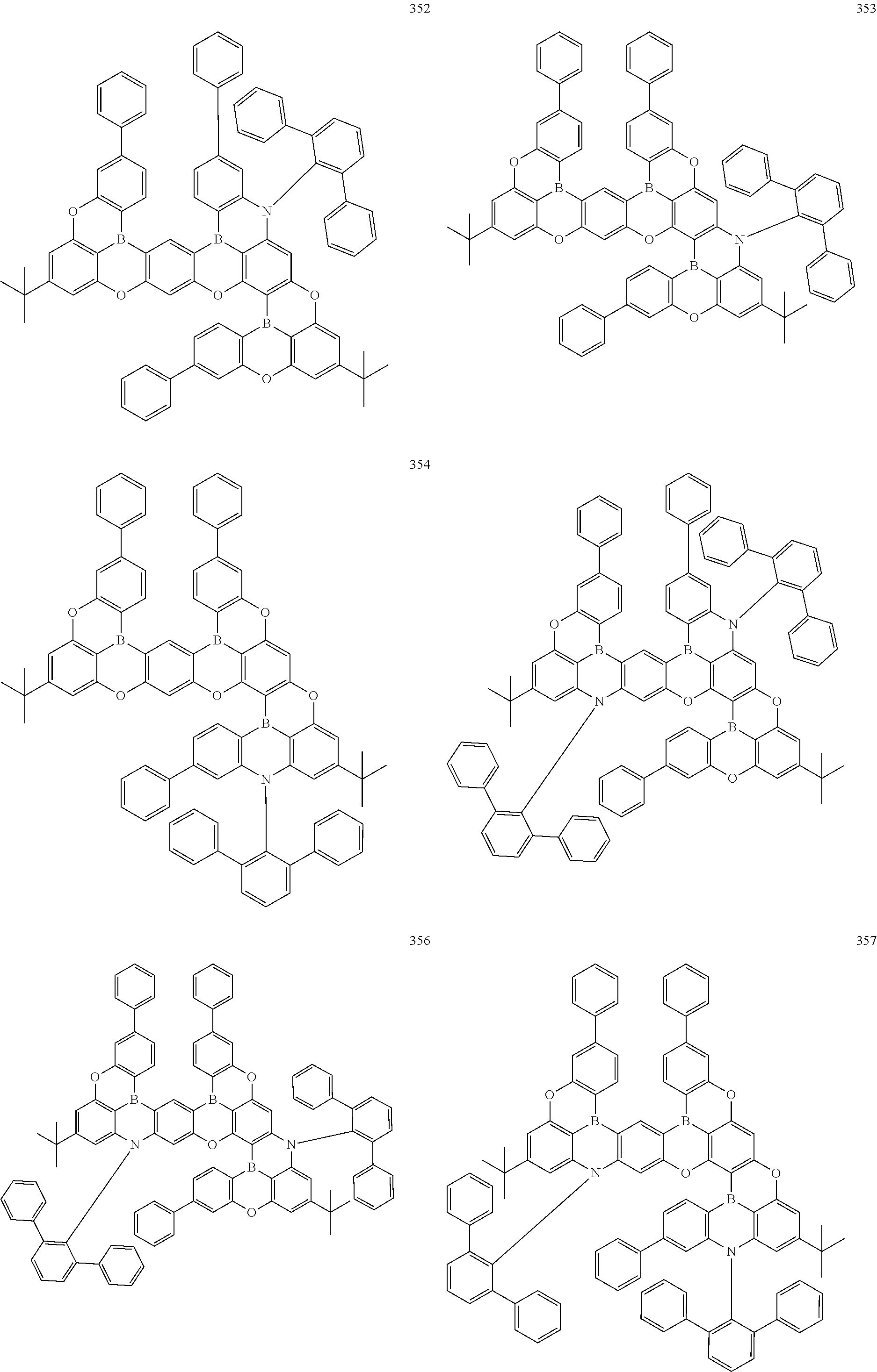 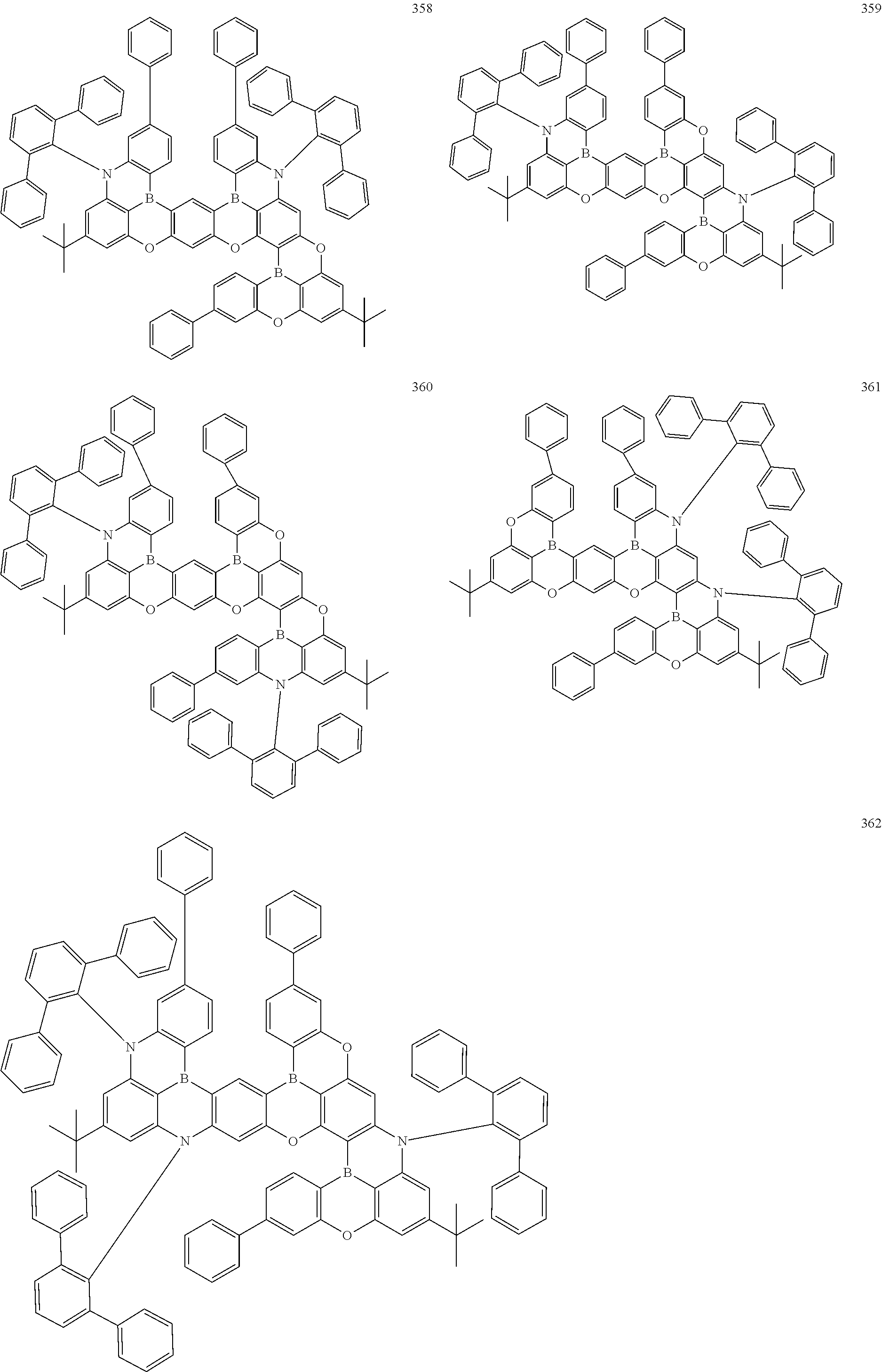 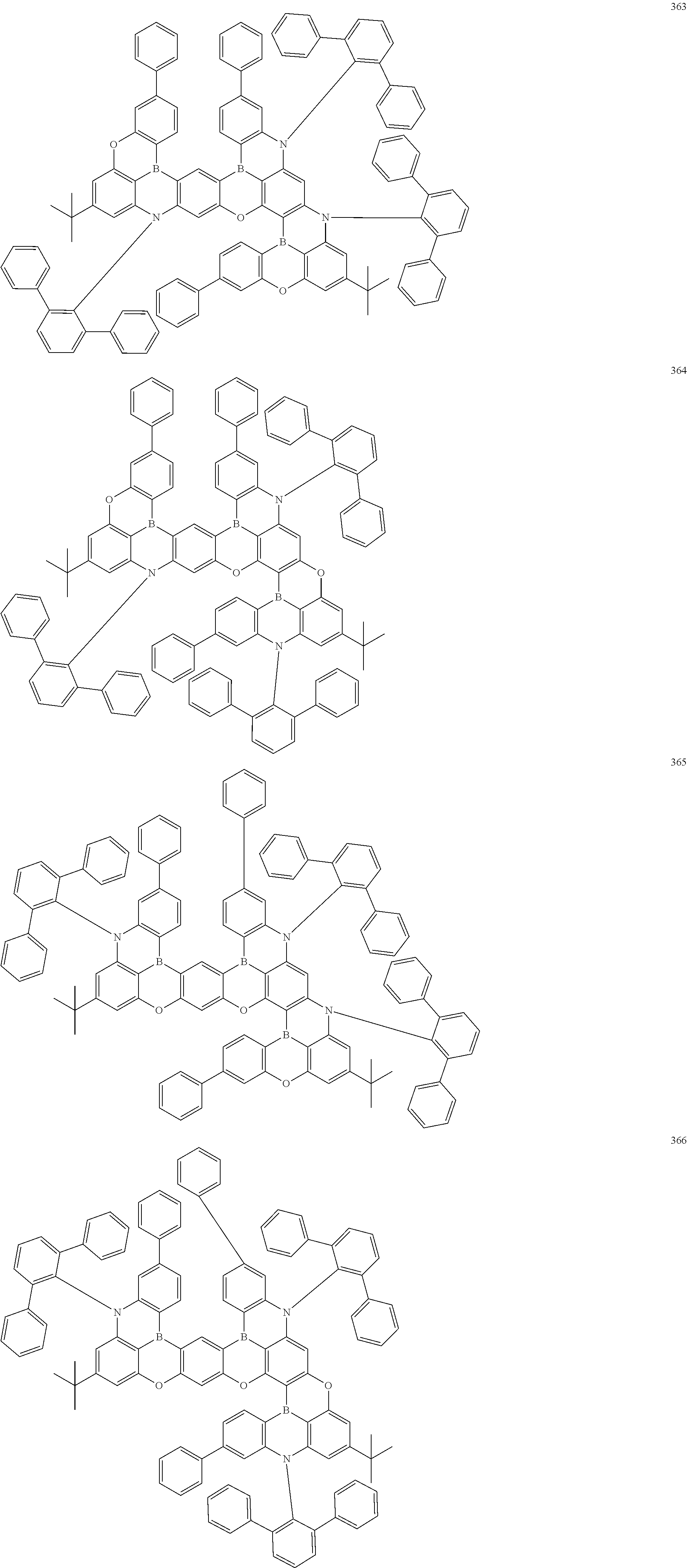 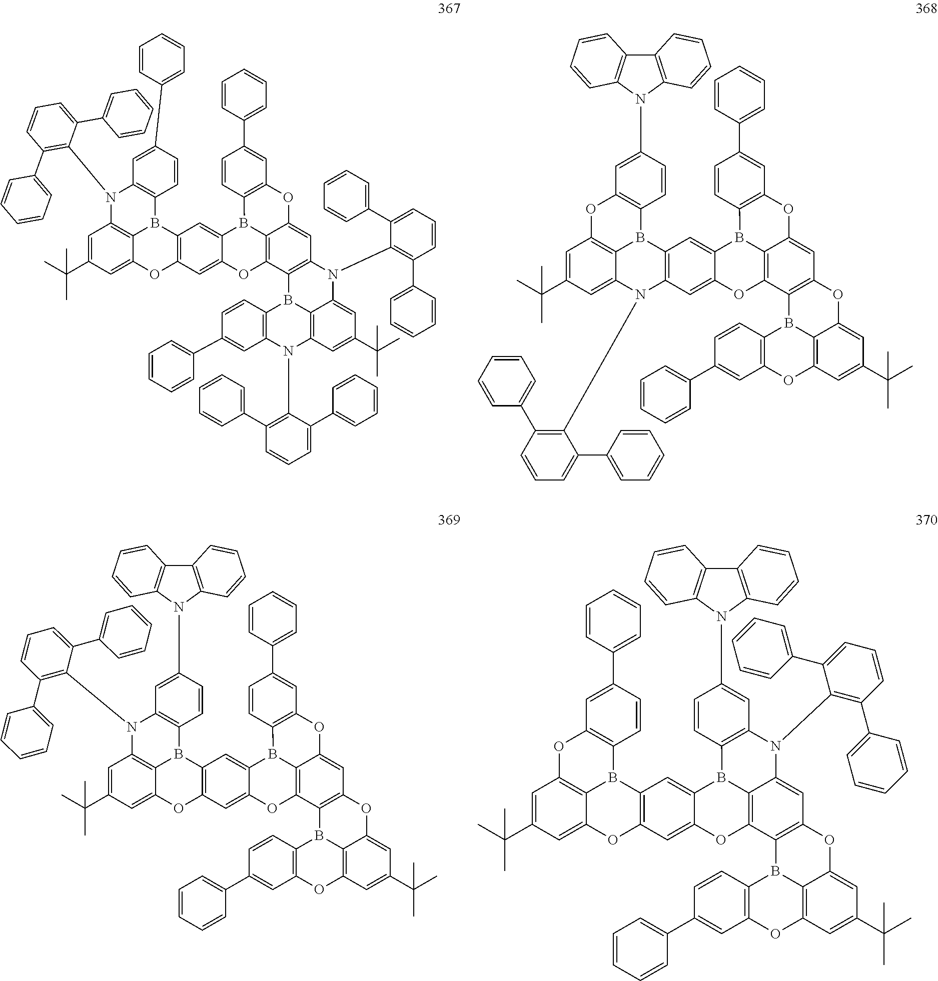 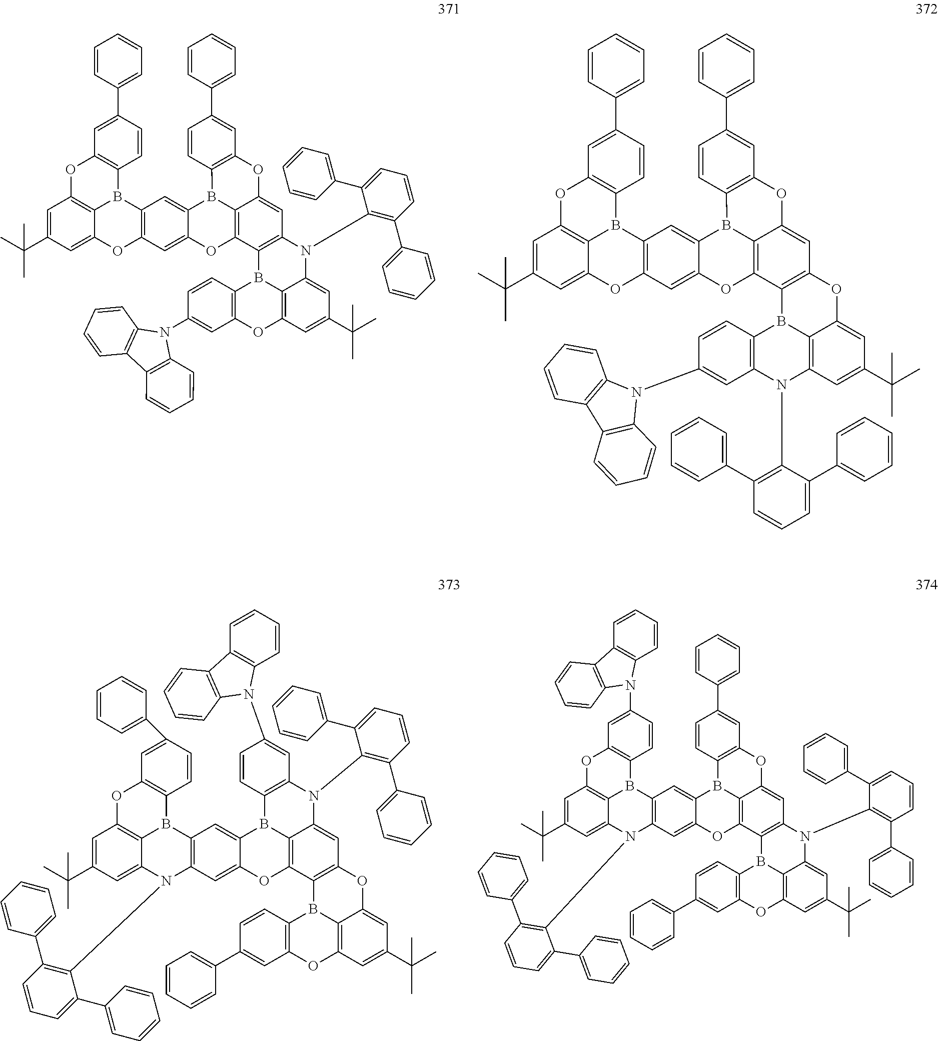 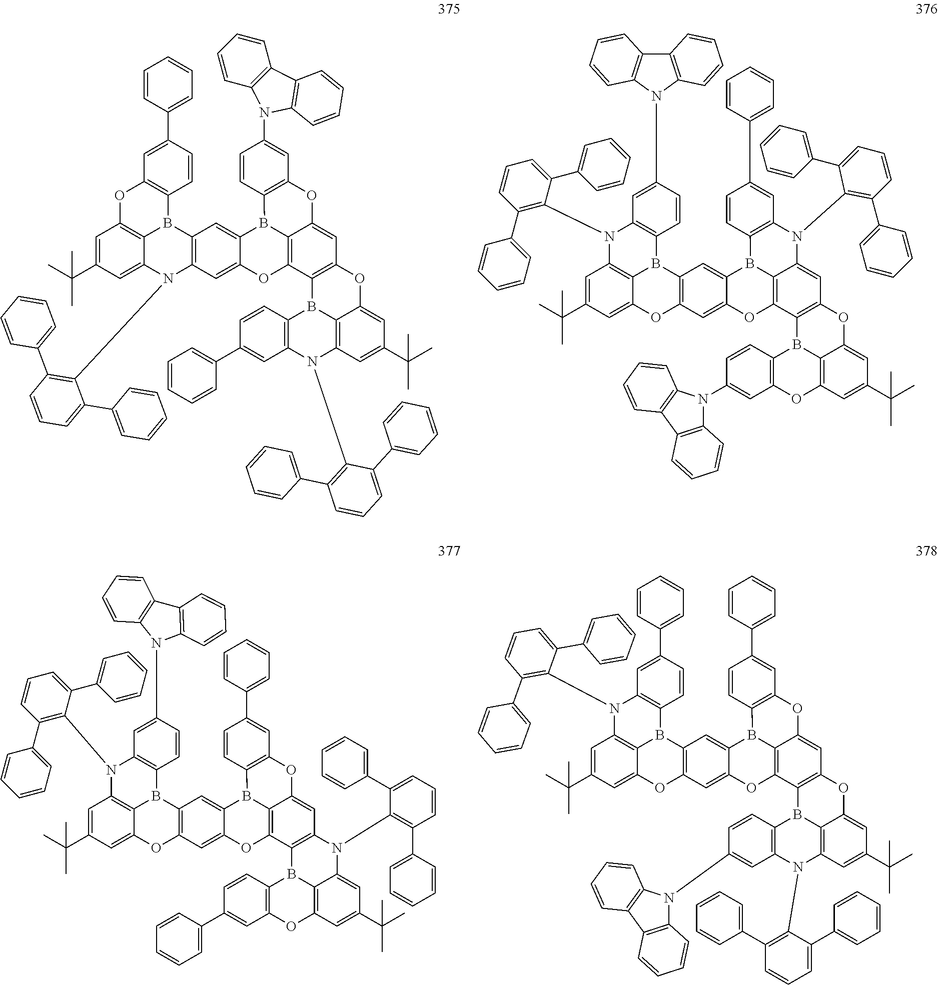 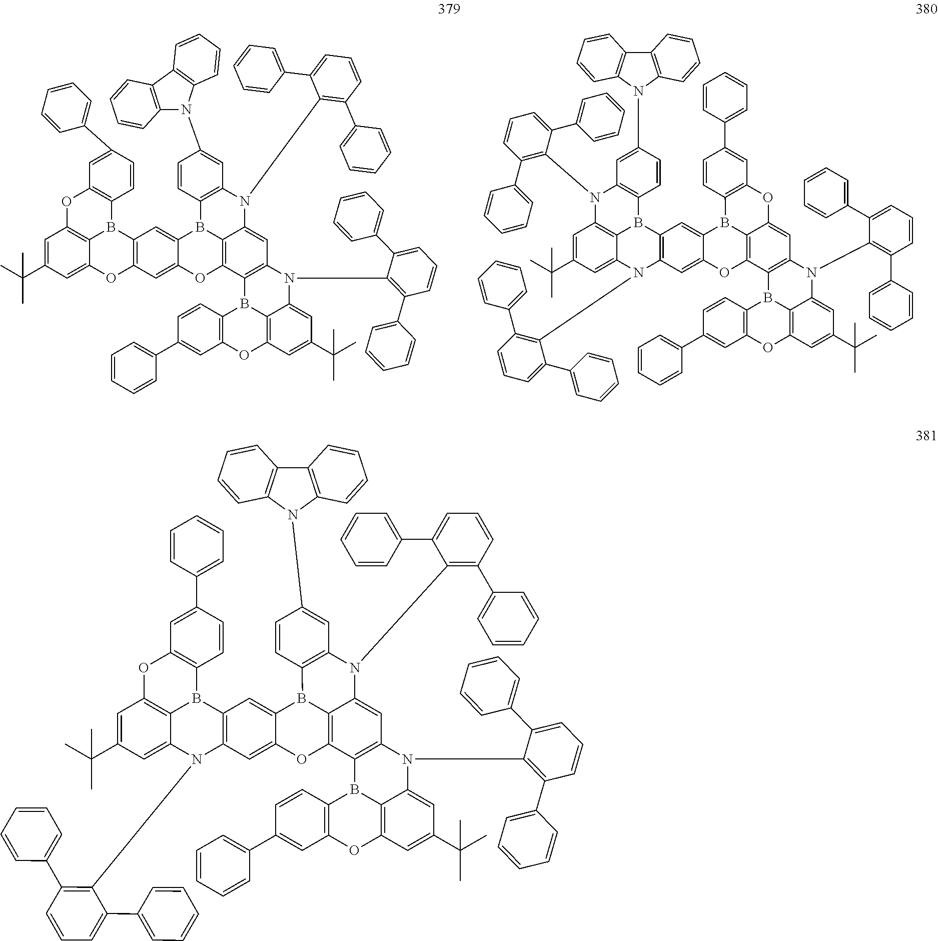 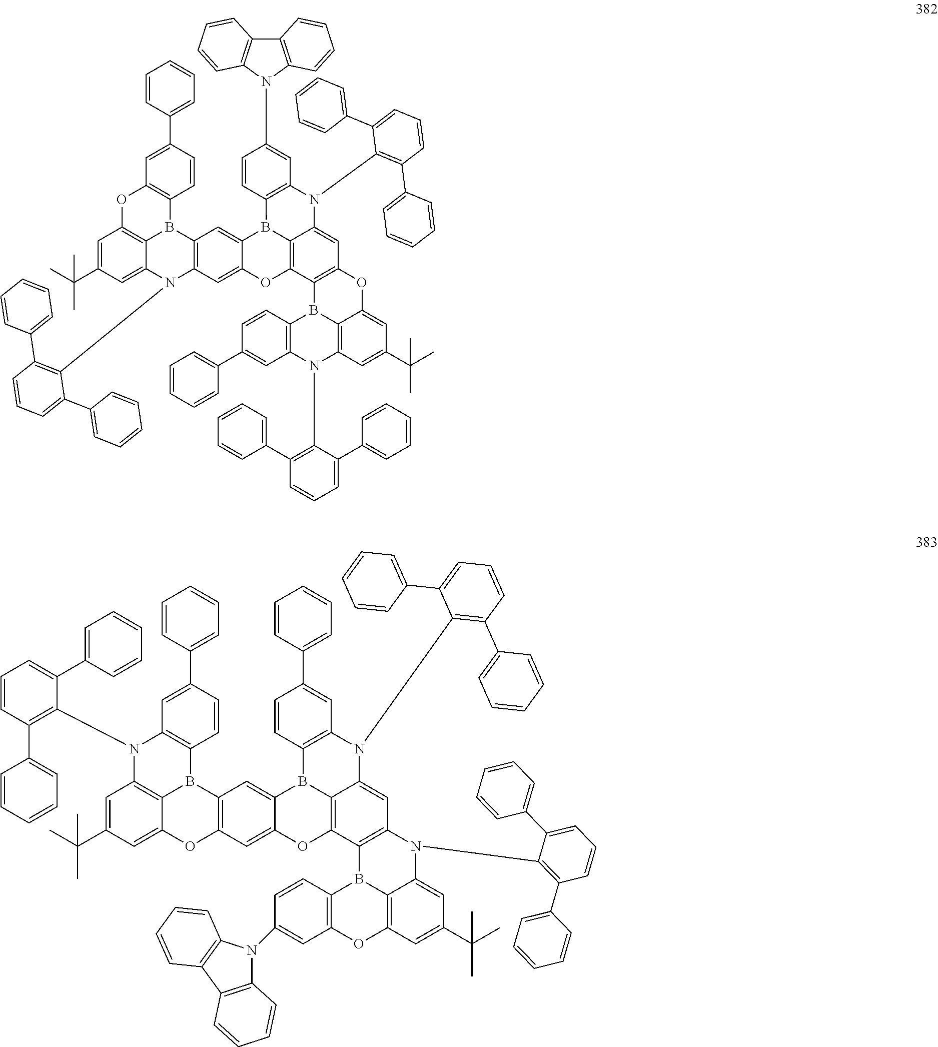 [SMILES: CC(C)(C)c1cc2c3c(c1)N(c1c(-c4ccccc4)cccc1-c1ccccc1)c1cc4c(cc1B3c1ccc(-c3ccccc3)cc1O2)B1c2ccc(-n3c5ccccc5c5ccccc53)cc2N(c2c(-c3ccccc3)cccc2-c2ccccc2)c2cc3c(c(c21)O4)B1c2ccc(-c4ccccc4)cc2N(c2c(-c4ccccc4)cccc2-c2ccccc2)c2cc(C(C)(C)C)cc(c21)O3 ; CC(C)(C)c1cc2c3c(c1)N(c1c(-c4ccccc4)cccc1-c1ccccc1)c1cc(-c4ccccc4)ccc1B3c1cc3c(cc1O2)Oc1c2c(cc4c1B1c5ccc(-n6c7ccccc7c7ccccc76)cc5Oc5cc(C(C)(C)C)cc(c51)N4c1c(-c4ccccc4)cccc1-c1ccccc1)N(c1c(-c4ccccc4)cccc1-c1ccccc1)c1cc(-c4ccccc4)ccc1B32] 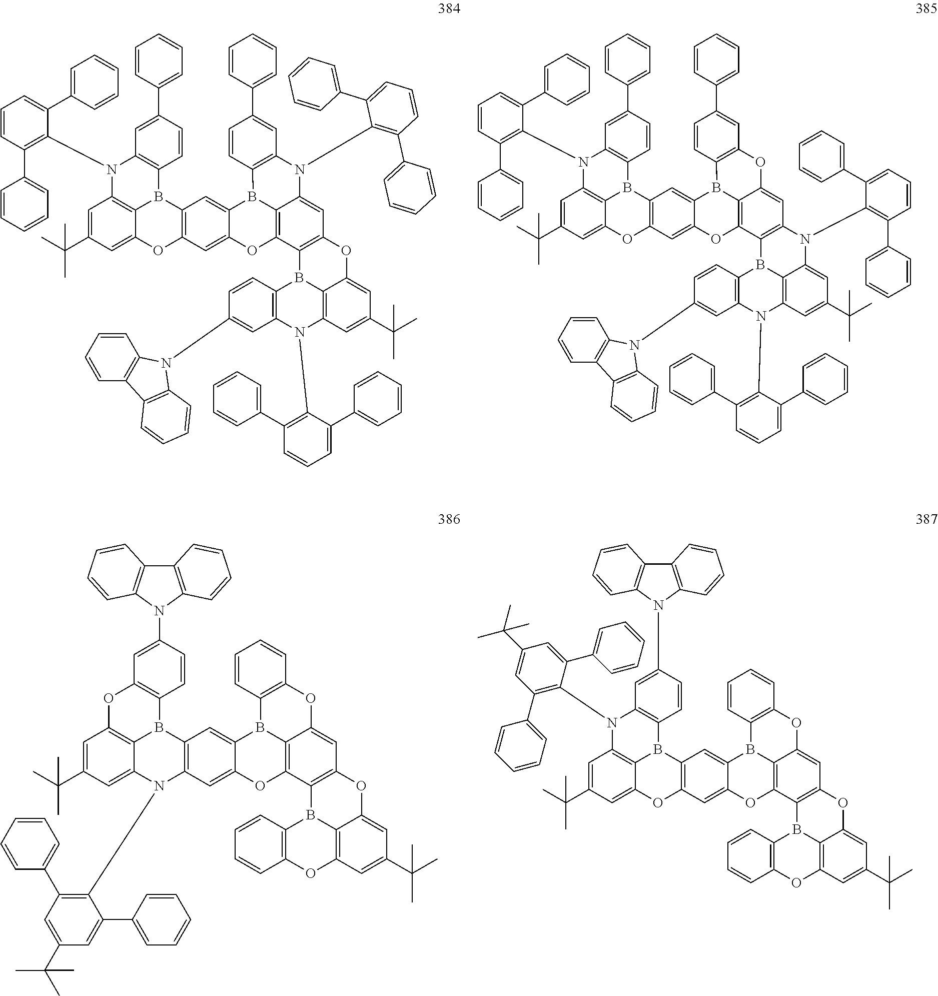 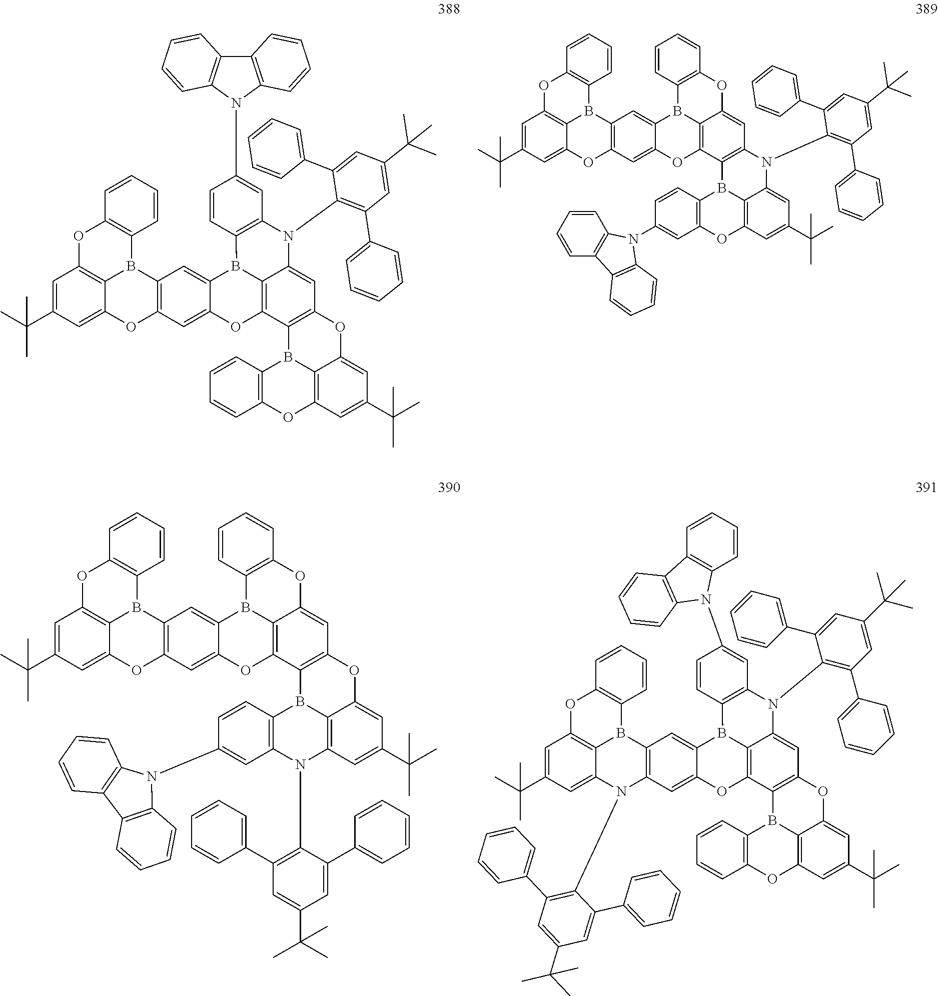 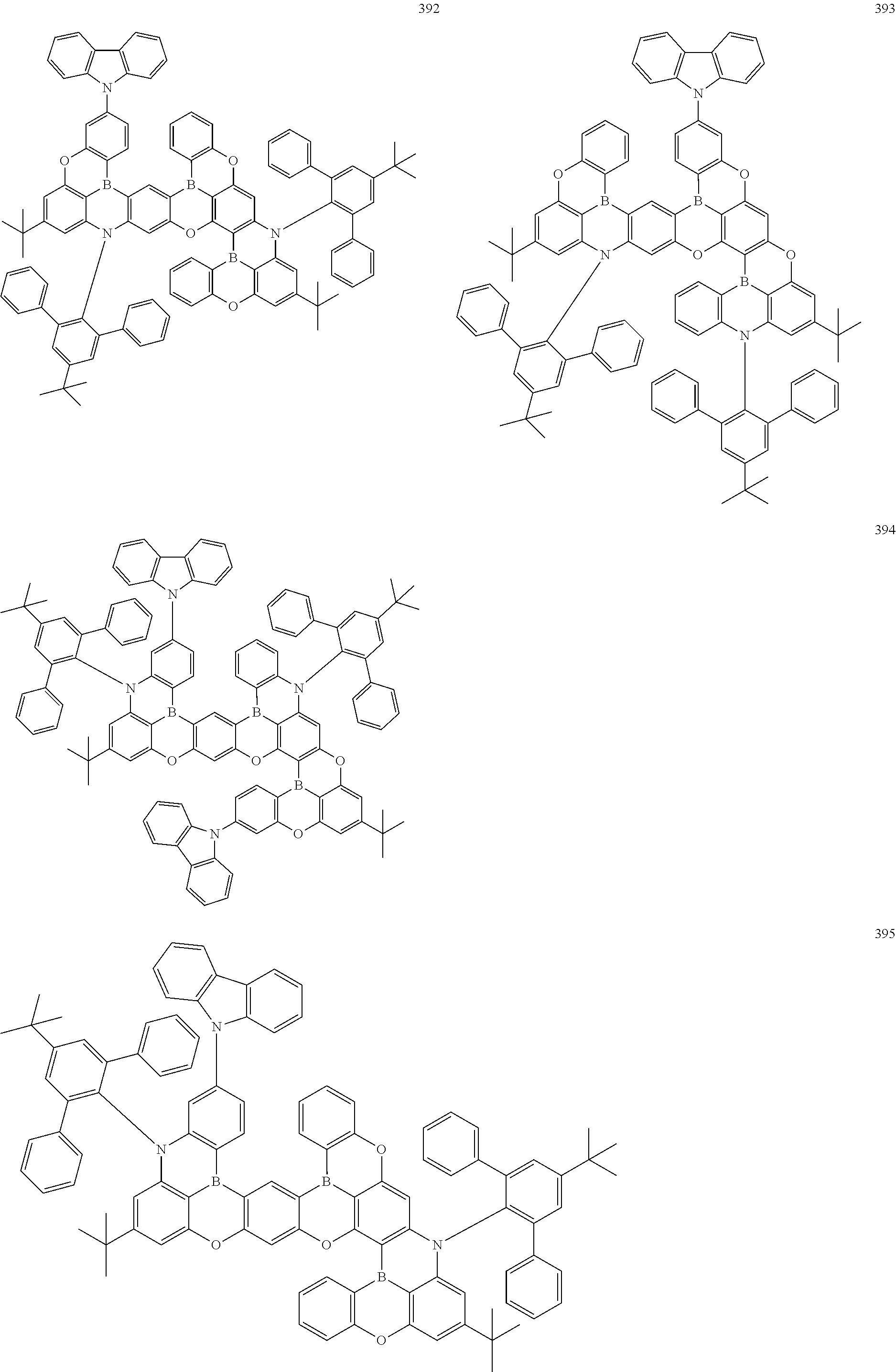 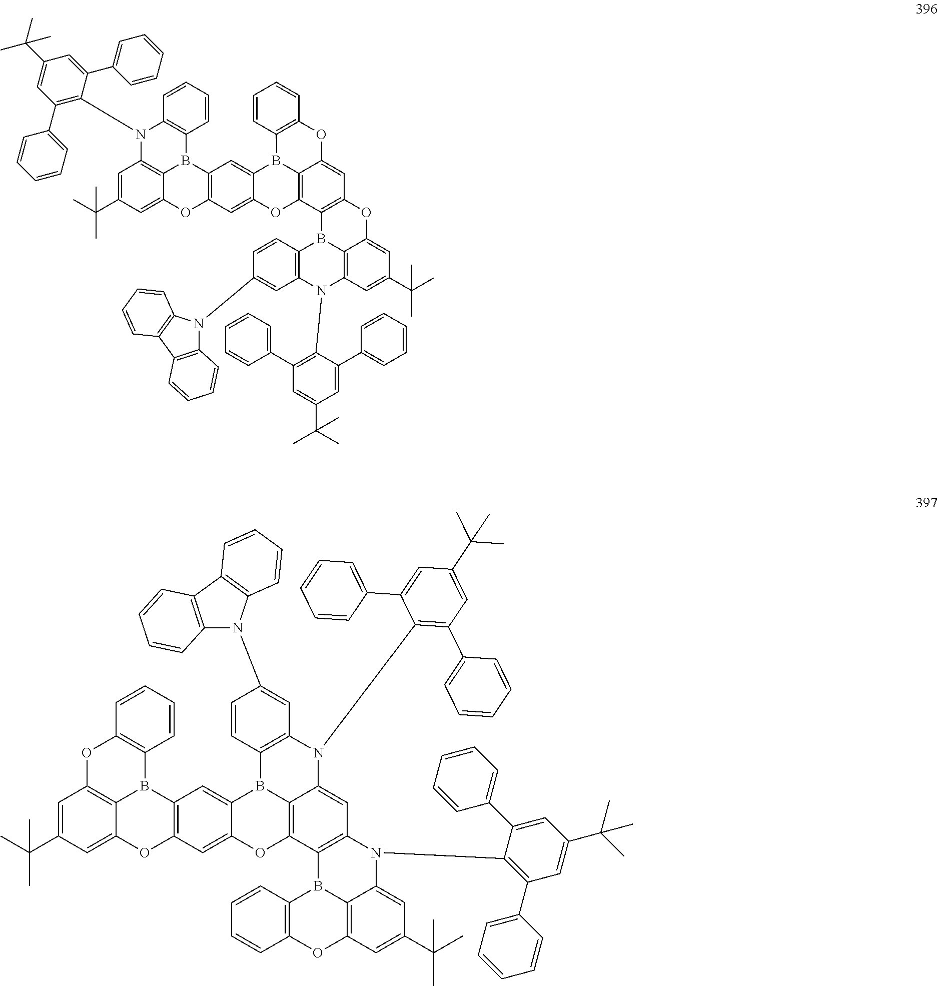 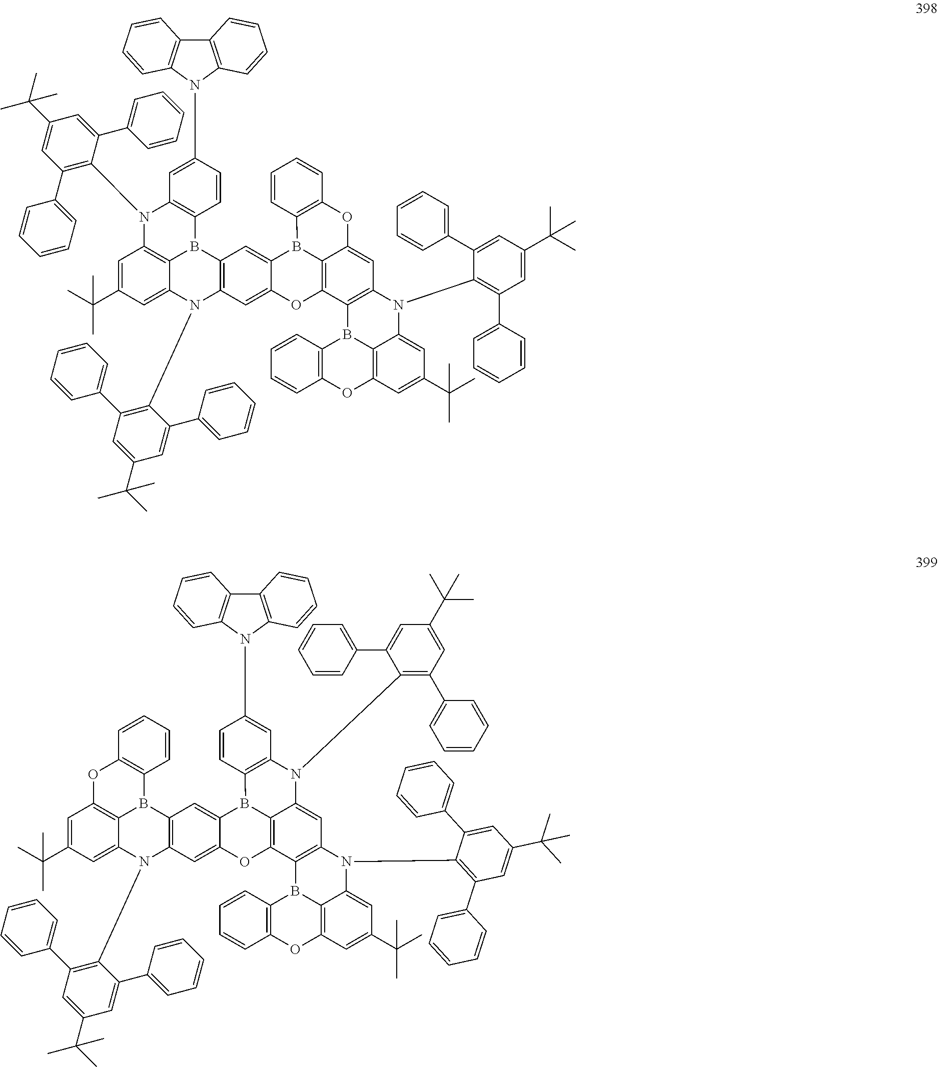 [SMILES: CC(C)(C)c1cc(-c2ccccc2)c(N2c3cc(-n4c5ccccc5c5ccccc54)ccc3B3c4cc5c(cc4N(c4c(-c6ccccc6)cc(C(C)(C)C)cc4-c4ccccc4)c4cc(C(C)(C)C)cc2c43)Oc2c3c(cc4c2B2c6ccccc6Oc6cc(C(C)(C)C)cc(c62)N4c2c(-c4ccccc4)cc(C(C)(C)C)cc2-c2ccccc2)Oc2ccccc2B53)c(-c2ccccc2)c1 ; CC(C)(C)c1cc(-c2ccccc2)c(N2c3cc4c(cc3B3c5ccccc5Oc5cc(C(C)(C)C)cc2c53)B2c3ccc(-n5c6ccccc6c6ccccc65)cc3N(c3c(-c5ccccc5)cc(C(C)(C)C)cc3-c3ccccc3)c3cc5c(c(c32)O4)B2c3ccccc3Oc3cc(C(C)(C)C)cc(c32)N5c2c(-c3ccccc3)cc(C(C)(C)C)cc2-c2ccccc2)c(-c2ccccc2)c1] 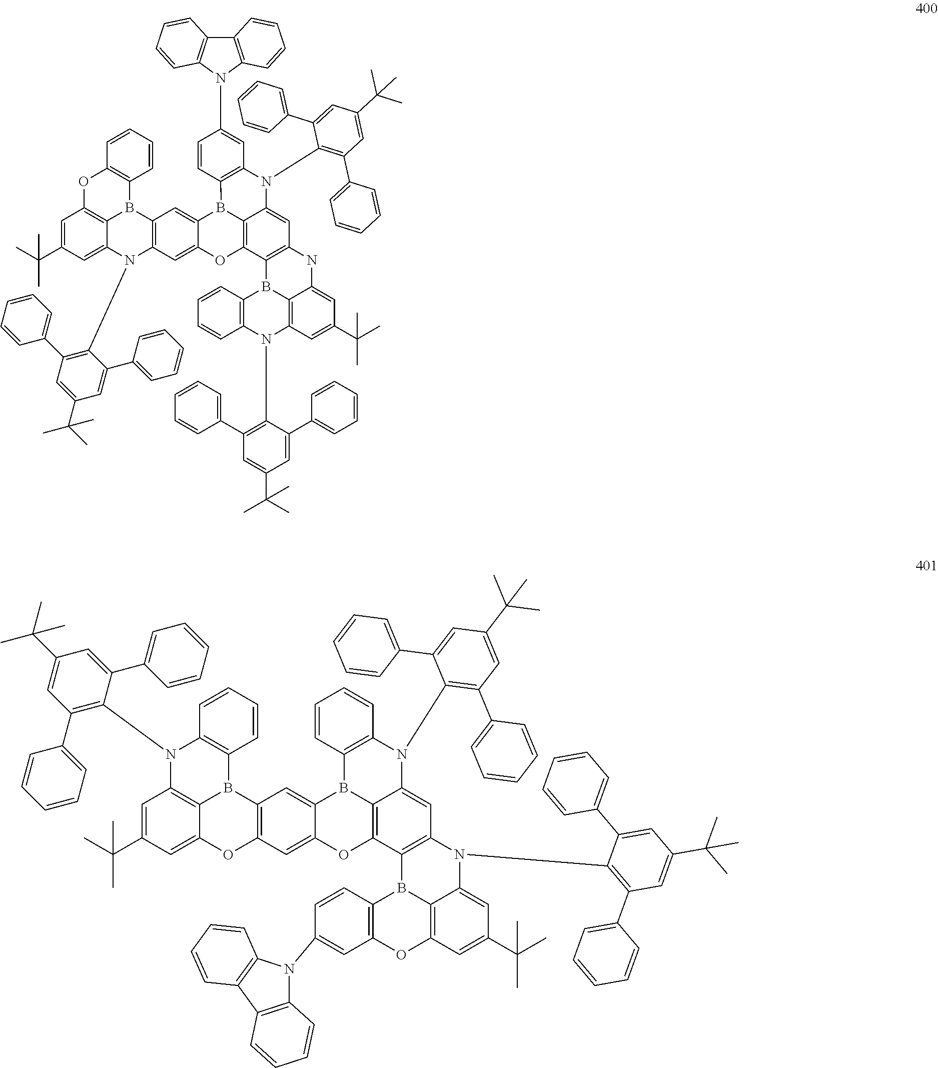 [SMILES: CC(C)(C)c1cc(-c2ccccc2)c(N2c3ccccc3B3c4c(cc(C(C)(C)C)cc42)Nc2cc4c5c(c23)Oc2cc3c(cc2B5c2ccc(-n5c6ccccc6c6ccccc65)cc2N4c2c(-c4ccccc4)cc(C(C)(C)C)cc2-c2ccccc2)B2c4ccccc4Oc4cc(C(C)(C)C)cc(c42)N3c2c(-c3ccccc3)cc(C(C)(C)C)cc2-c2ccccc2)c(-c2ccccc2)c1 ; CC(C)(C)c1cc(-c2ccccc2)c(N2c3ccccc3B3c4cc5c(cc4Oc4cc(C(C)(C)C)cc2c43)Oc2c3c(cc4c2B2c6ccc(-n7c8ccccc8c8ccccc87)cc6Oc6cc(C(C)(C)C)cc(c62)N4c2c(-c4ccccc4)cc(C(C)(C)C)cc2-c2ccccc2)N(c2c(-c4ccccc4)cc(C(C)(C)C)cc2-c2ccccc2)c2ccccc2B53)c(-c2ccccc2)c1] 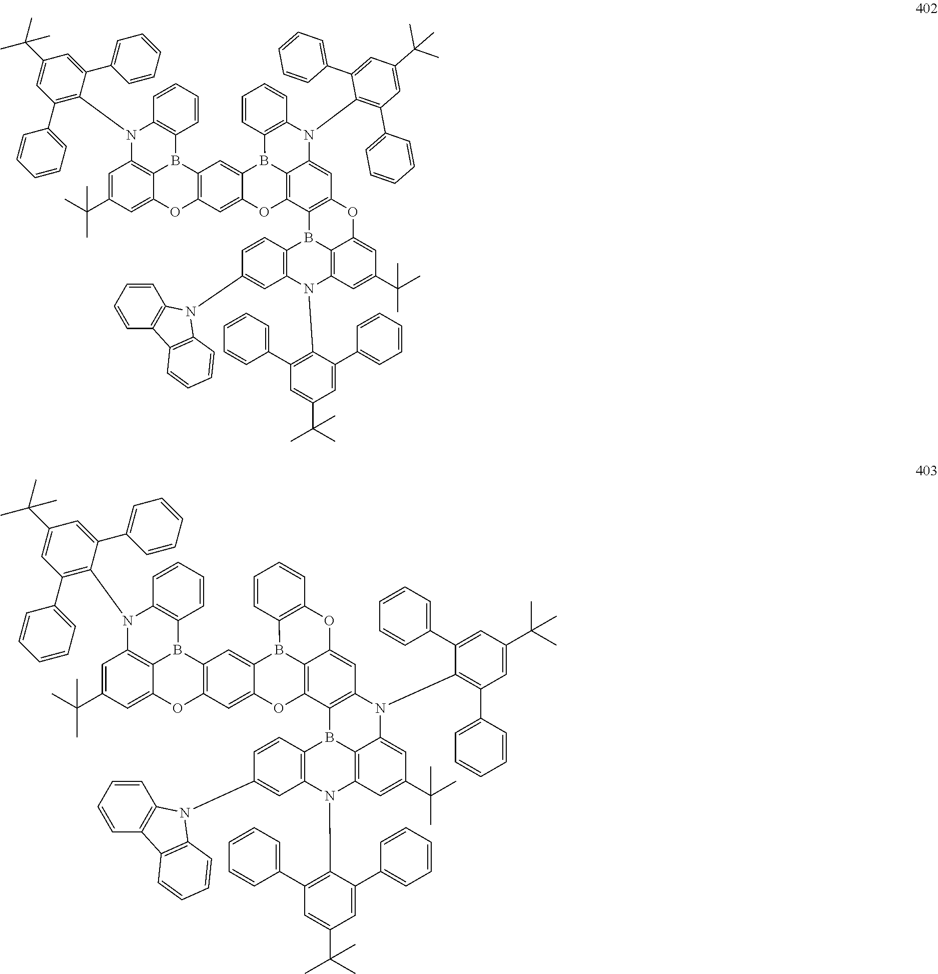 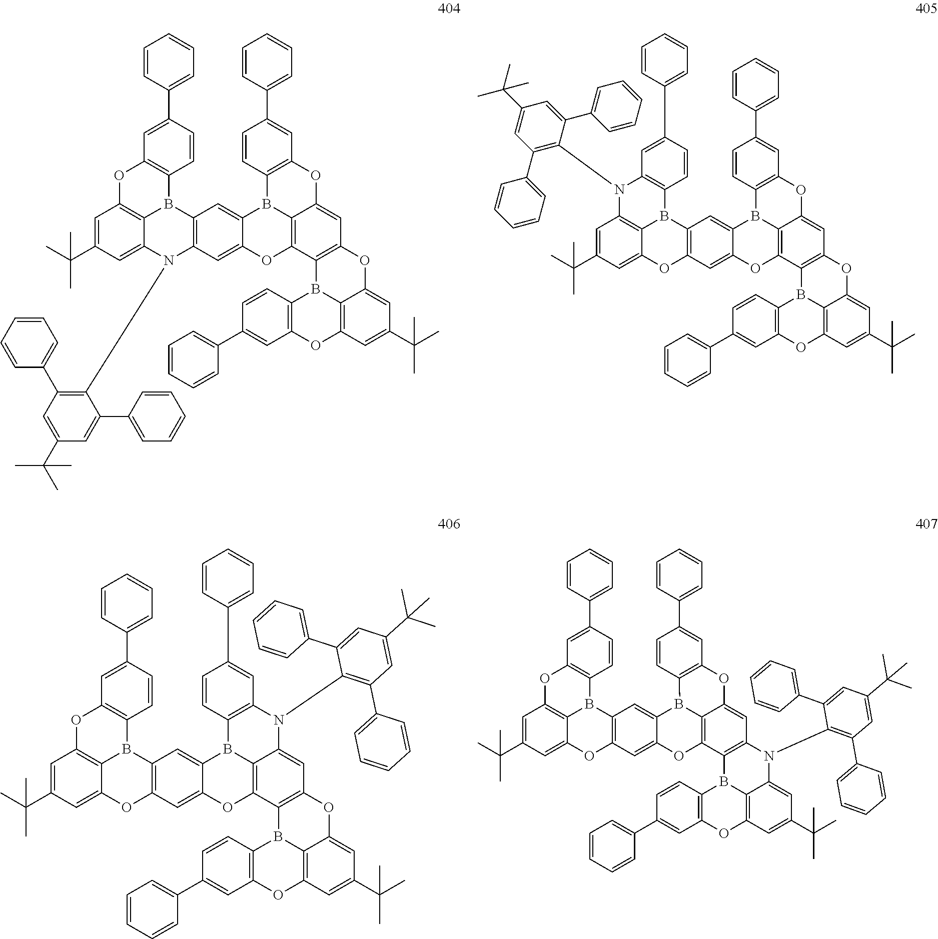 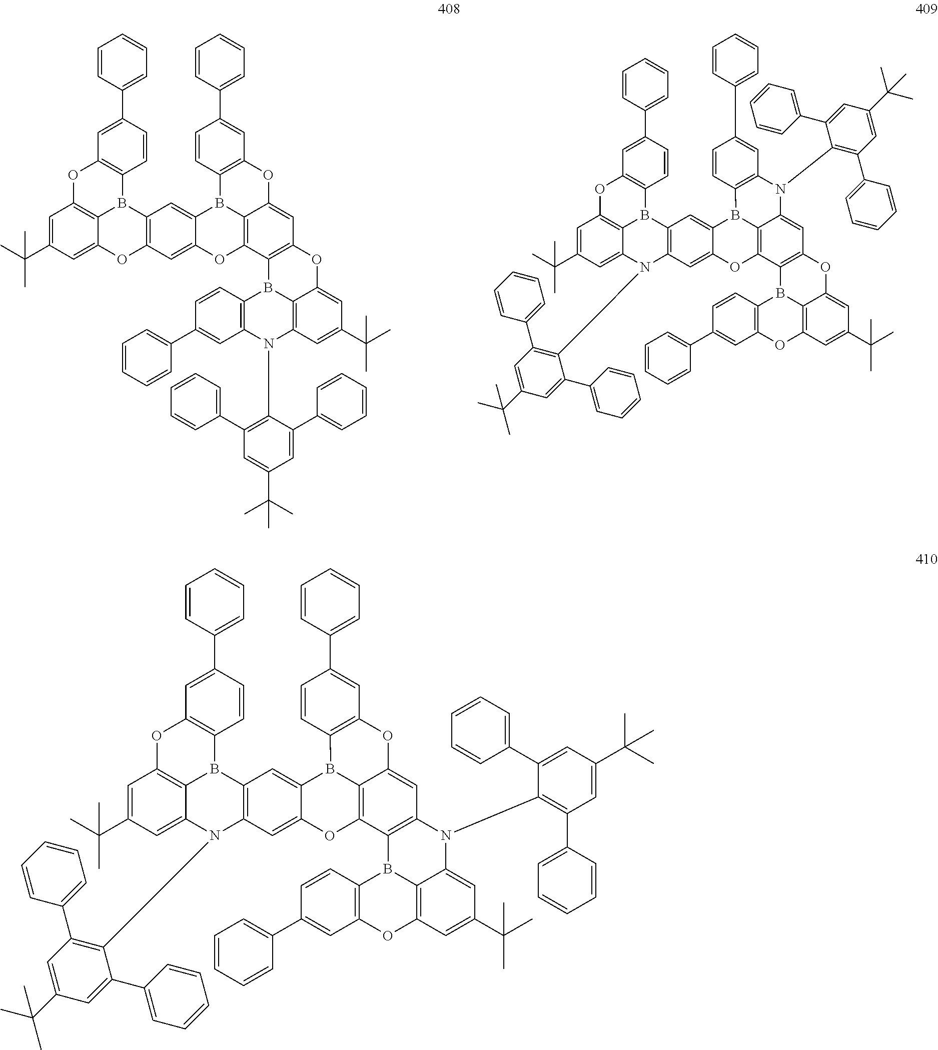 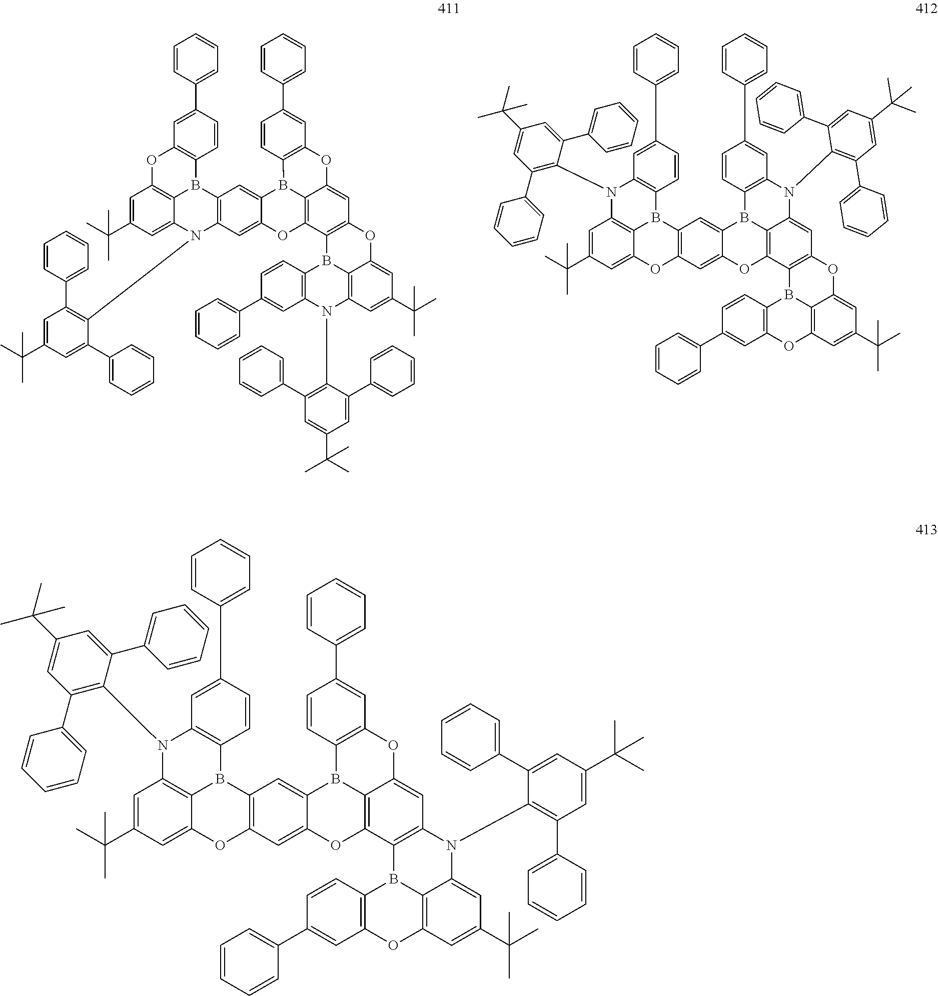 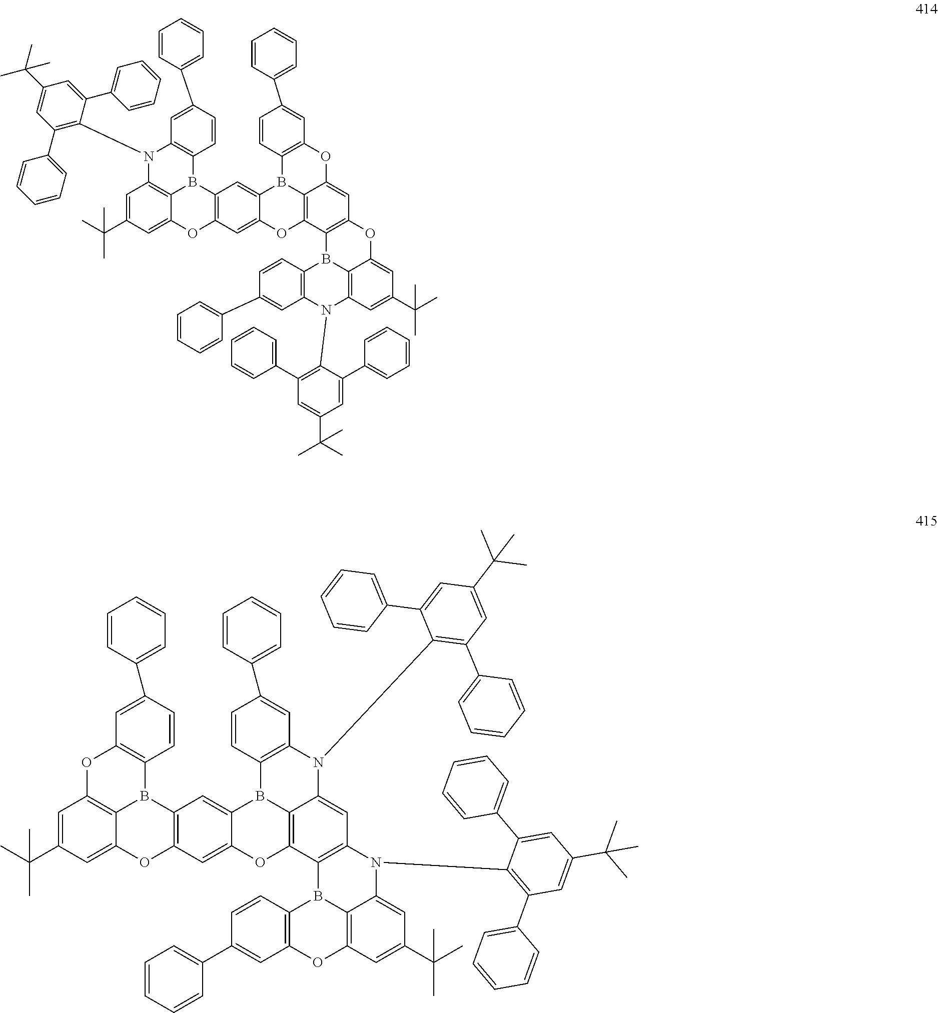 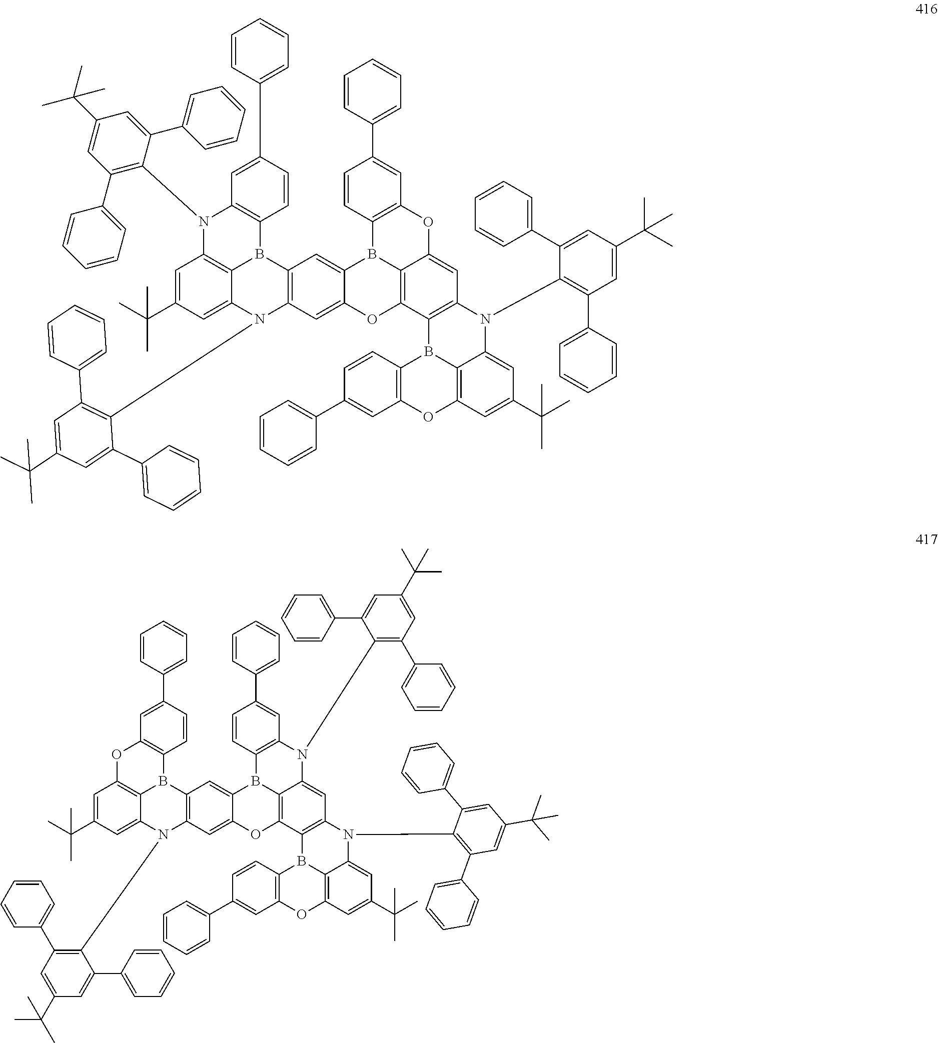 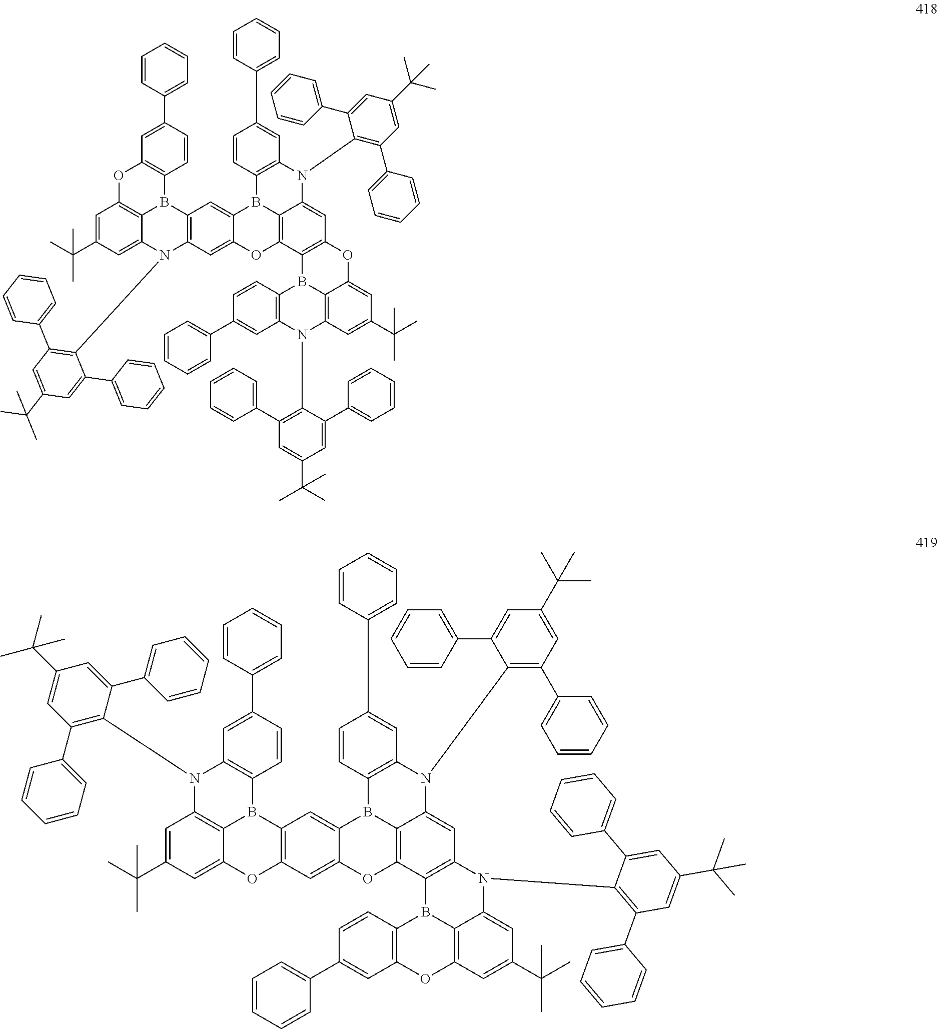 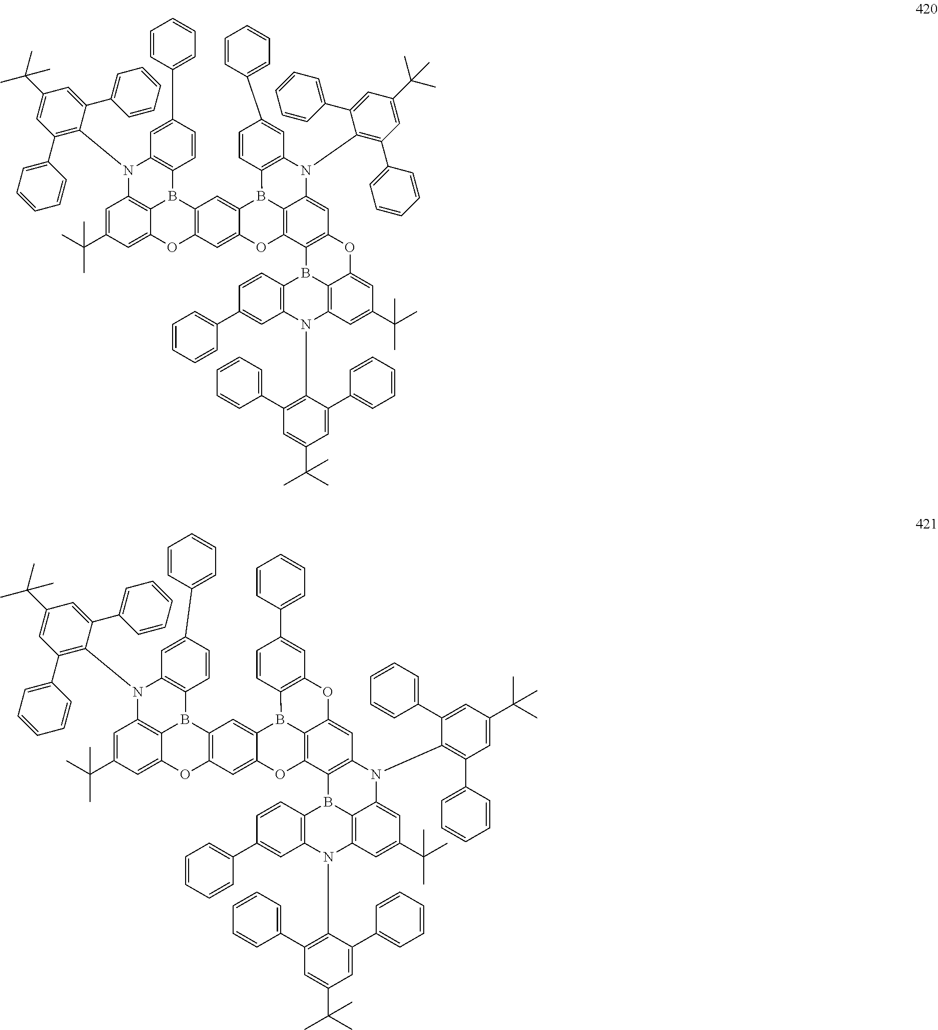 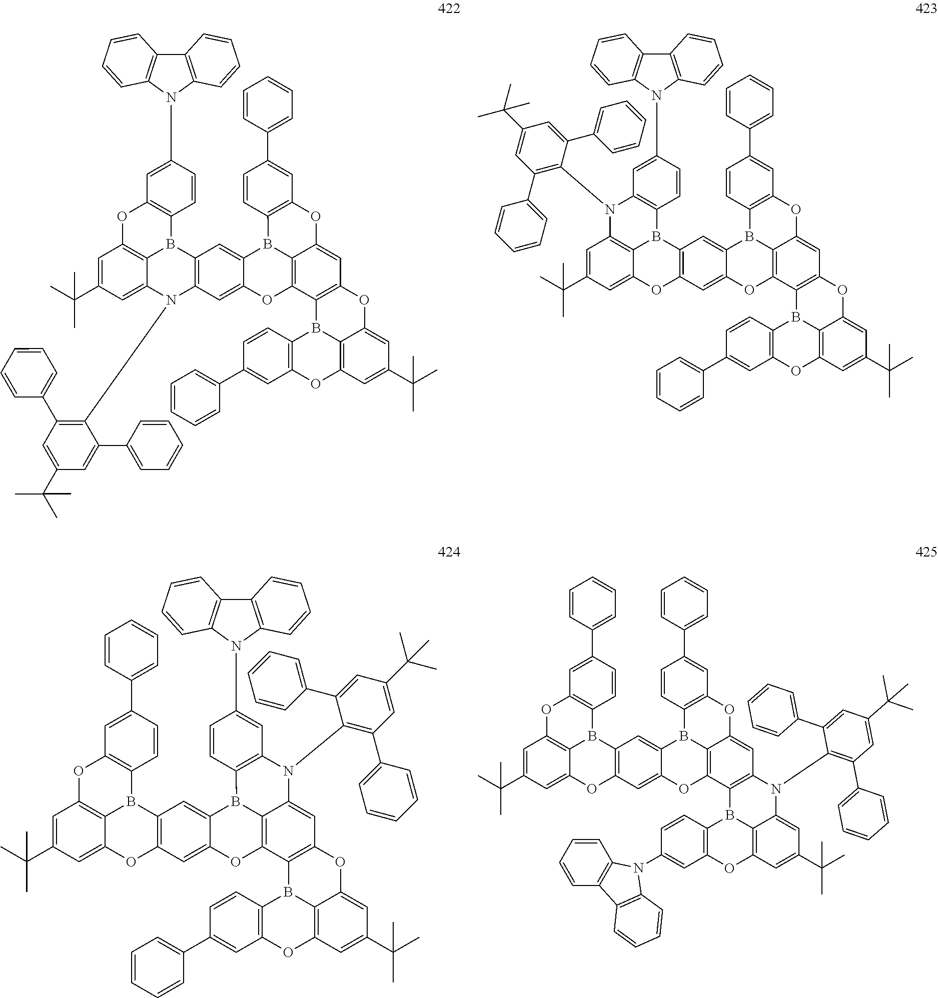 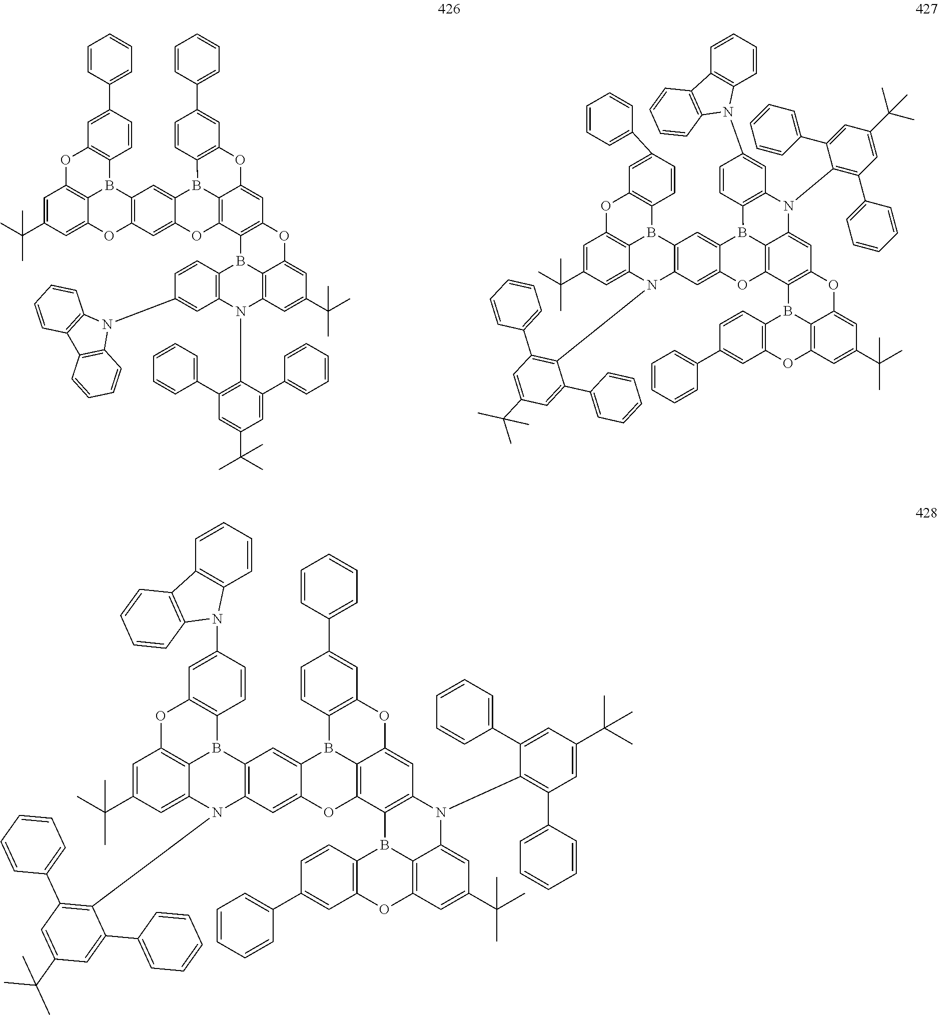 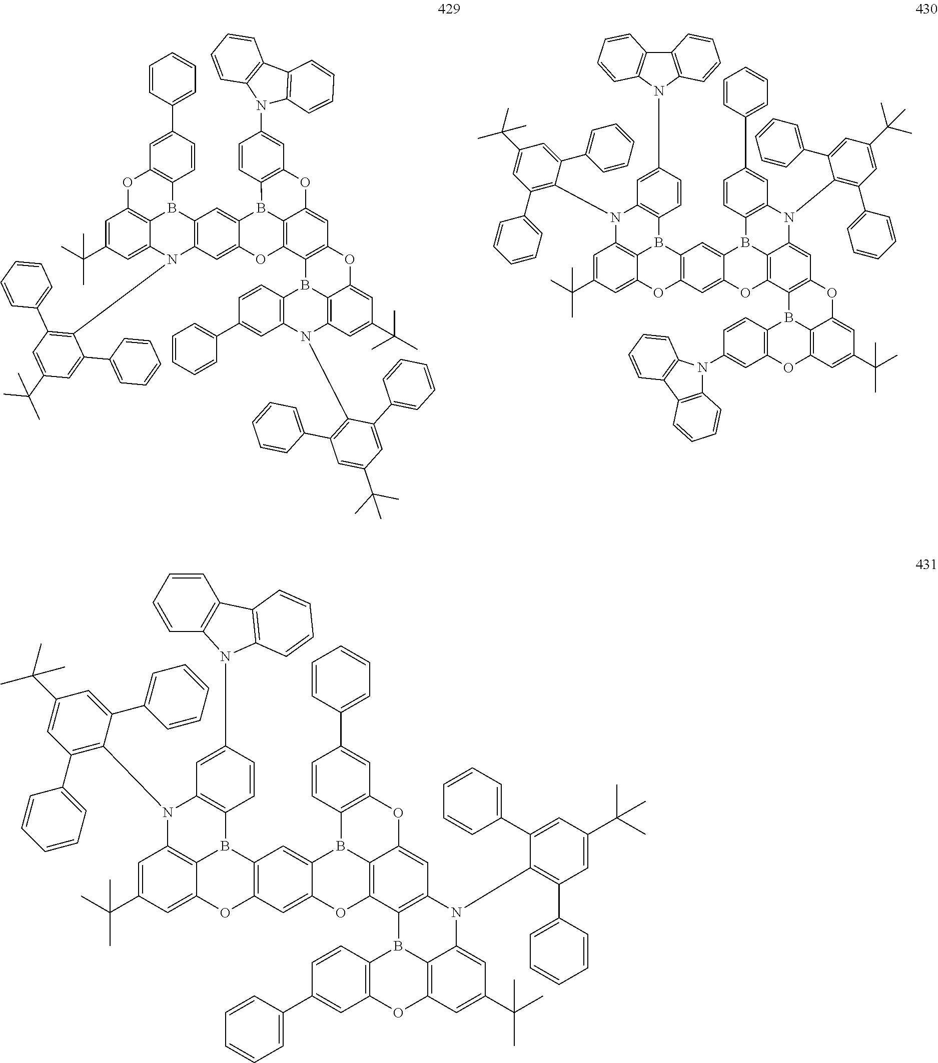 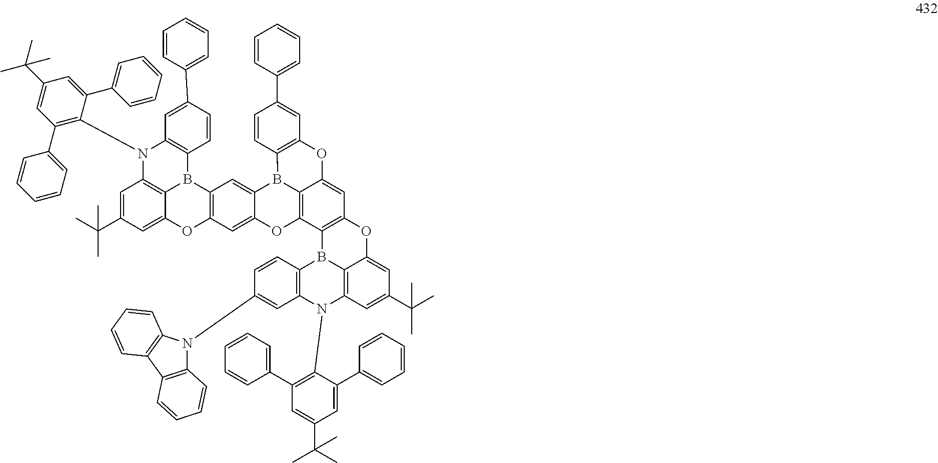 [SMILES: CC(C)(C)c1cc(-c2ccccc2)c(N2c3cc(-c4ccccc4)ccc3B3c4cc5c(cc4Oc4cc(C(C)(C)C)cc2c43)Oc2c3c(cc4c2B2c6ccc(-n7c8ccccc8c8ccccc87)cc6N(c6c(-c7ccccc7)cc(C(C)(C)C)cc6-c6ccccc6)c6cc(C(C)(C)C)cc(c62)O4)Oc2cc(-c4ccccc4)ccc2B53)c(-c2ccccc2)c1] 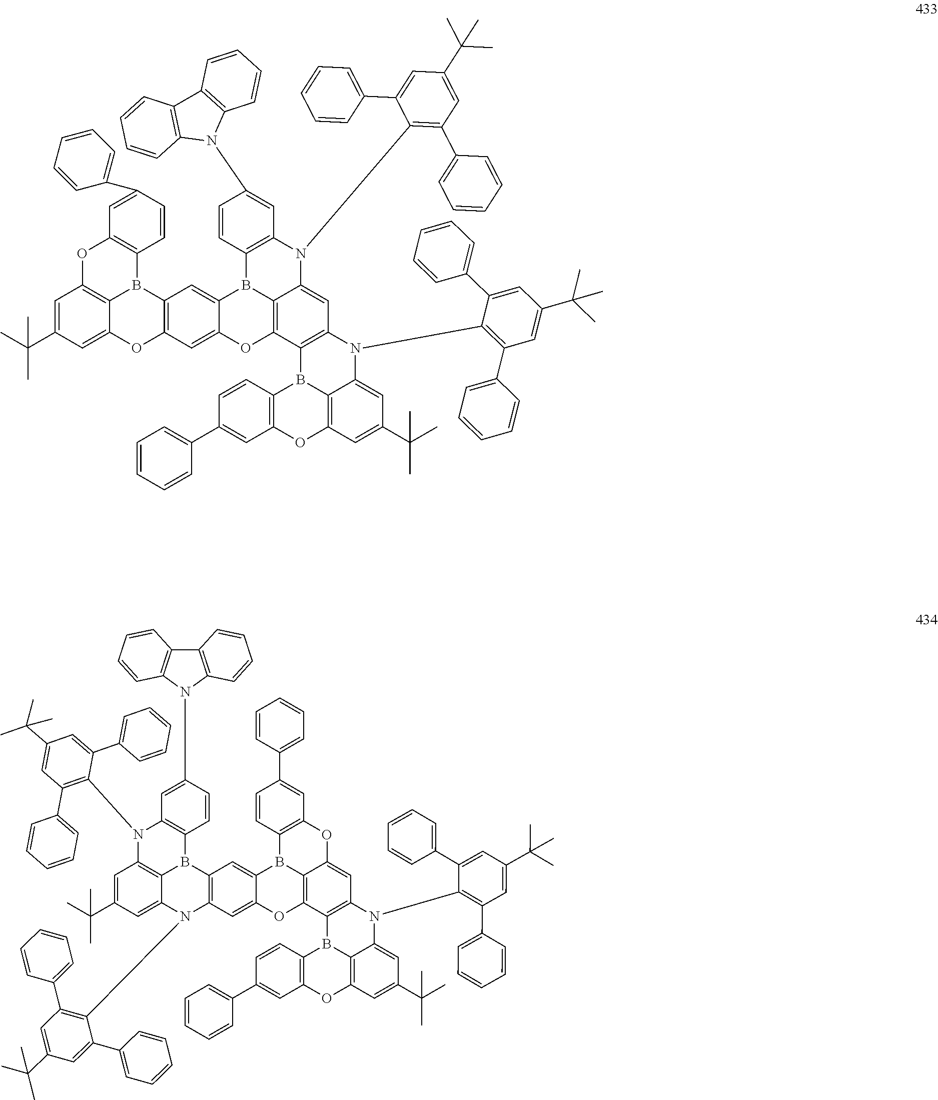 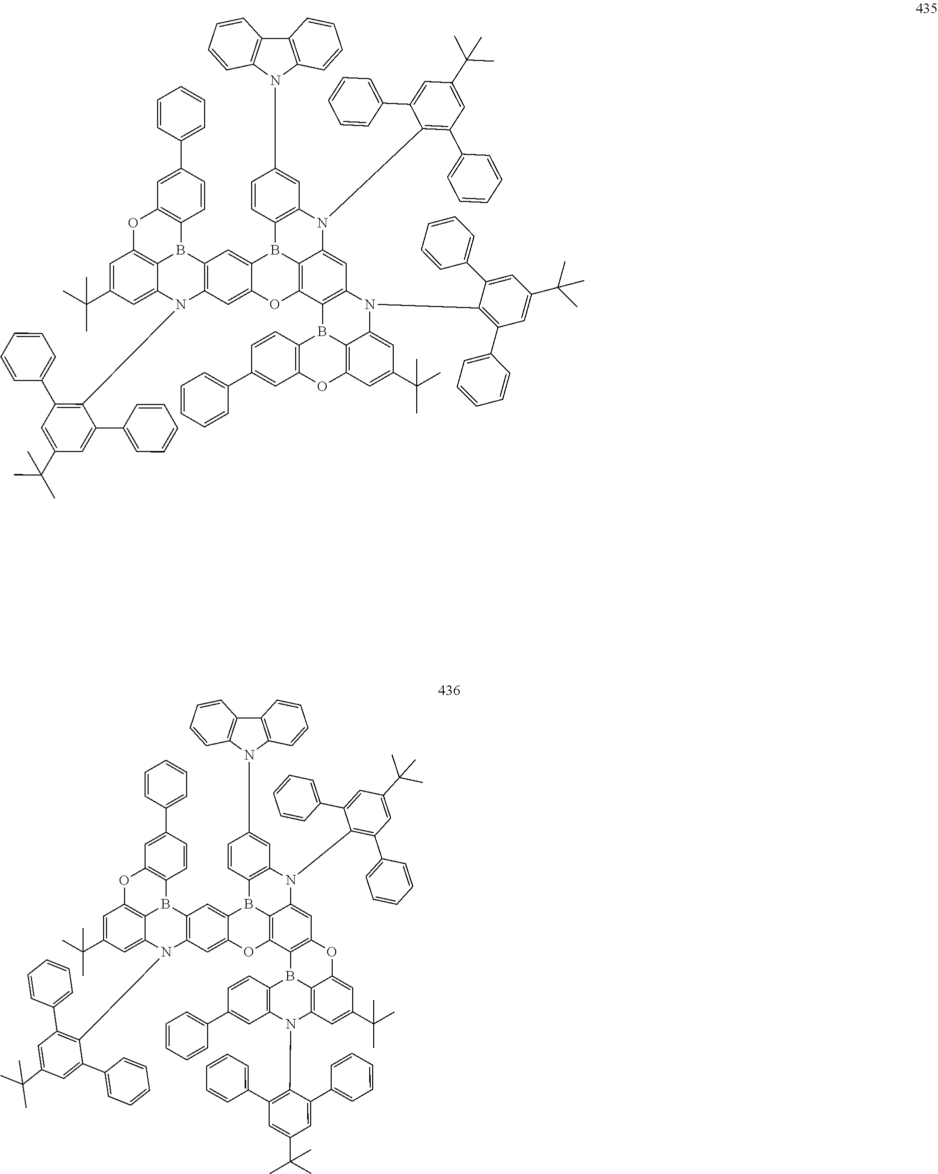 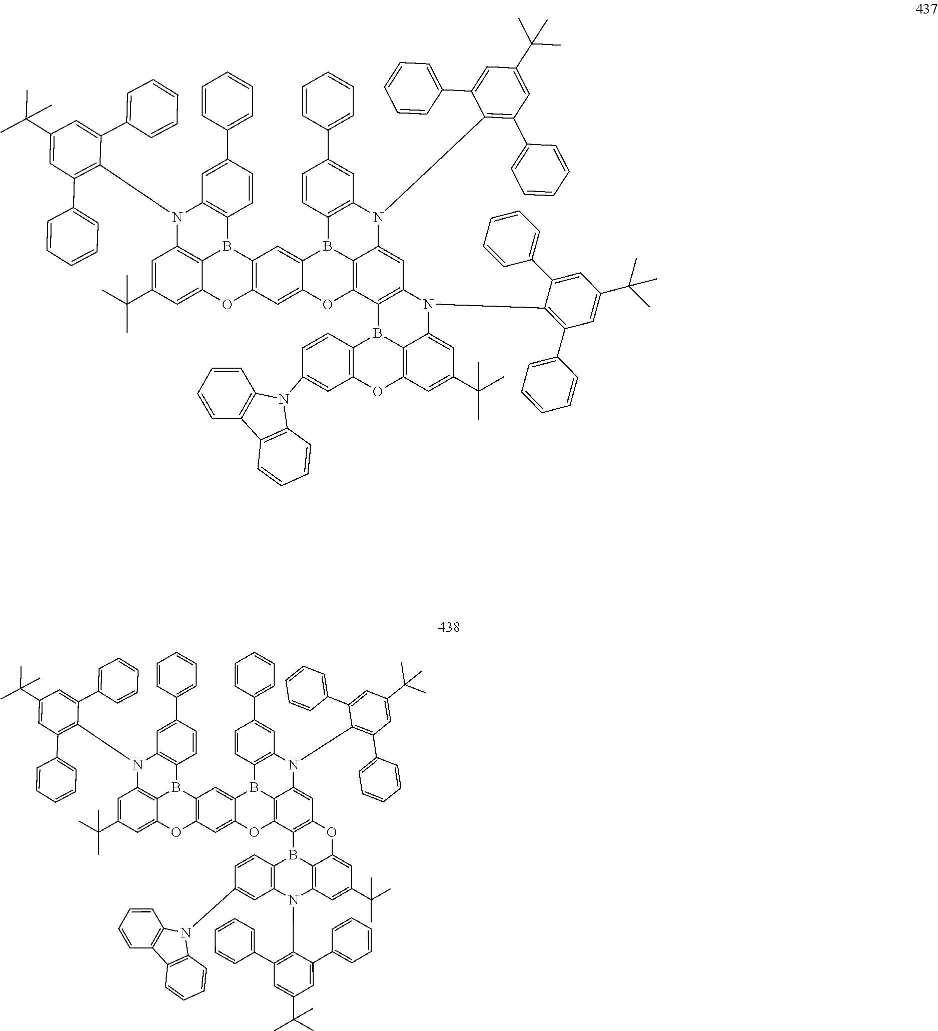 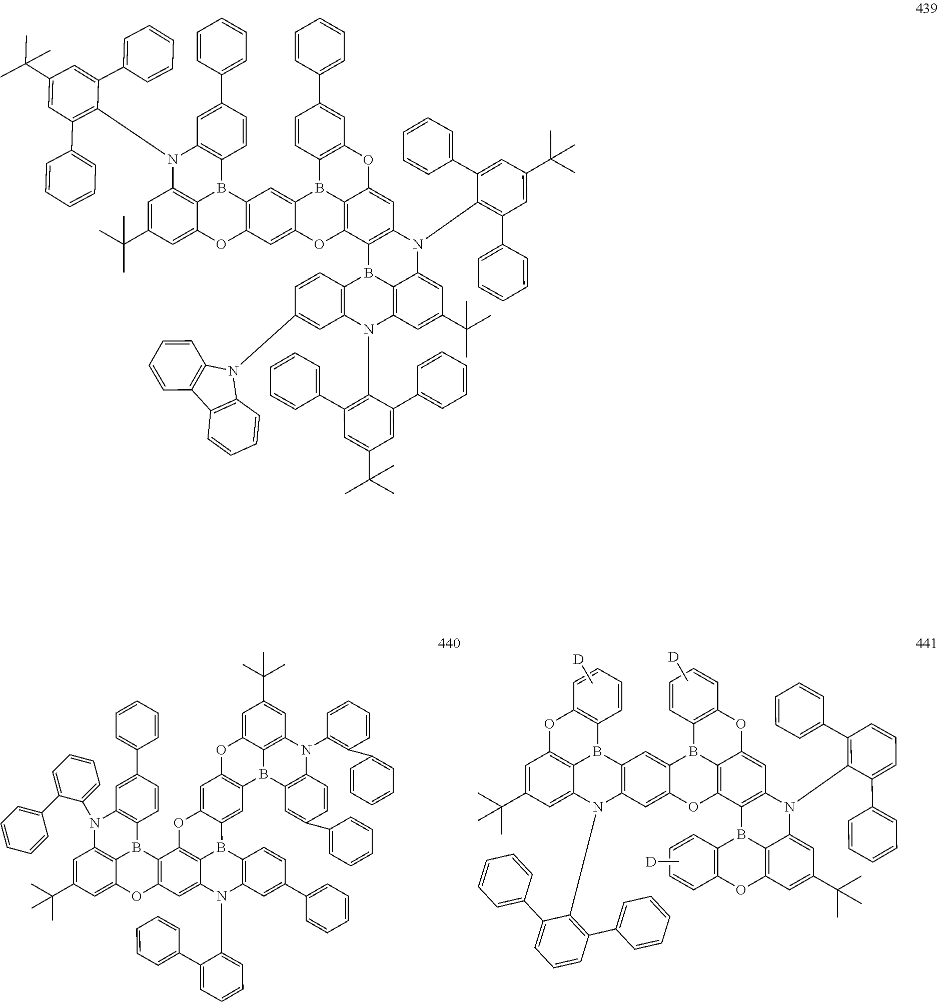 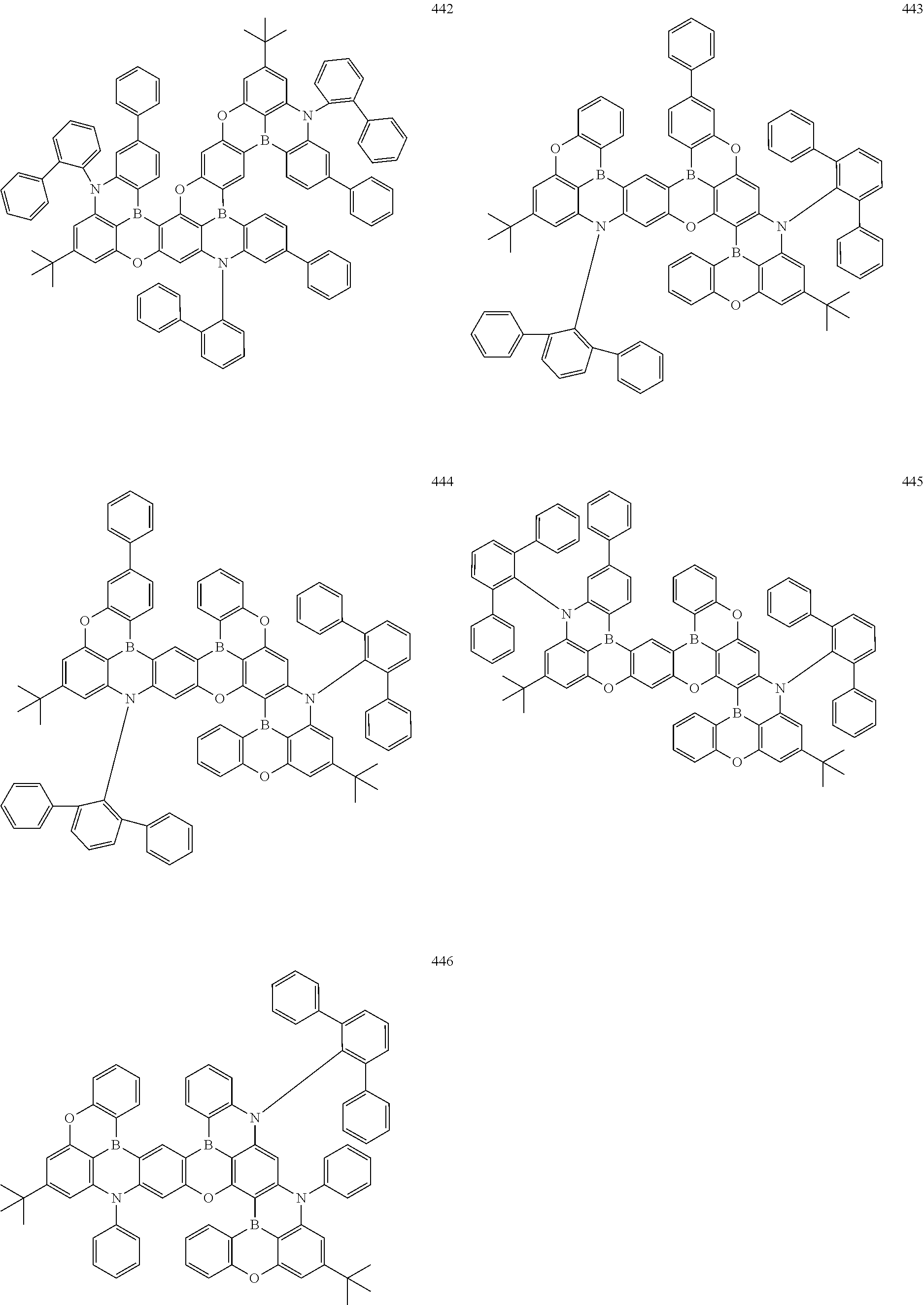
in Compound Group 1, D being deuterium.
